(19) United States
(12) Patent Application Publication
(10) Pub. No.: US 2004/0226502 A1
(43) Pub. Date: Nov. 18, 2004

(54) Crystal structure of 2c-methyl-d-erythritol 2,4-cyclodiphosphate synthase

(76) Inventors: Adelbert Bacher, Garching (DE); Stefan Hecht, Dietersheim (DE); Robert Huber, Germering (DE); Johannes Kaiser, Garching (DE); Felix Rohdich, Zolling (DE); Stefan Steinbacher, Munchen (DE)

Correspondence Address: MYERS BIGEL SIBLEY & SAJOVEC, PO BOX 37428, RALEIGH, NC, 27627, US

(21) Appl. No.: 10/478,284

(22) PCT Filed: May 13, 2002
(86) PCT No.: PCT/EP02/05238

Related U.S. Application Data
(60) Provisional application No. 60/293,875, filed on May 25, 2001.

(30) Foreign Application Priority Data
May 15, 2001 (DE) 101 23 597.6

(51) Int. Cl. C30B 1/00

(52) U.S. Cl. 117/2

(57) ABSTRACT

This invention discloses the crystal structure of 2C-methyl-D-erythritol 2,4-cyclodiphosphate synthase and crystal structures of said synthase with 4-diphosphocytidyl-2C-methyl-D-erythritol, 4-diphosphocytidyl-2C-methyl-D-erythritol 2-phosphate, cytidine monophosphate, cytidine diphosphate, cytidine and a combination of cytidine monophosphate and 2C-methyl-D-erythritol 2,4-cyclodiphosphate; with or without zinc. Further, computer-aided methods of identifying inhibitors of said synthase and inhibitors are provided.

### FIELD OF THE INVENTION

The present invention relates to isoprenoid biosynthesis and notably to 2C-methyl-D-erythritol 2,4-cyclodiphosphate synthases involved in that pathway and inhibitors of 2C-methyl-D-erythritol 2,4-cyclodiphosphate synthases, that may be used as antibiotics against pathogenic eubacteria and the protozoon Plasmodium falciparum. More specifically, the present invention relates to the crystal structure of 2C-methyl-D-erythritol 2,4-cyclodiphosphate synthase of E. coli in complex with substrate, substrate analogs and products and to methods of designing and identifying inhibitors of this enzyme. Moreover, the present invention relates to novel inhibitors detectable by said methods as well as compositions and processes for inhibiting the synthesis of isoprenoids and for controlling the growth of organisms based on said inhibitors. The

### BACKGROUND OF THE INVENTION

By the classical research of Bloch, Cornforth, Lynen and co-workers, isopentenyl pyrophosphate (IPP) and dimethylallyl pyrophosphate (DMAPP) have become established as key intermediates in the biosynthesis of isoprenoids via mevalonate. Bacterial, plants and the protozoon Plasmodium falciparum synthesize isoprenoids by an alternative pathway via 1-deoxy-D-xylulose 5-phosphate. This non-mevalonate pathway has so far only been partially explored (FIG. 1). For a better understanding of these aspects of the invention, the pathway shall be briefly explained. It can be conceptualized to consist of three segments:

In a first pathway segment shown in FIG. 1 pyruvate (1) is condensed with glyceraldehyde 3-phosphate (2) to 1-deoxy-D-xylulose 5-phosphate (DXP) (3). Subsequently, DXP is converted into 2C-methyl-D-erythritol 4-phosphate (MEP) (4) by a two-step reaction comprising a rearrangement and a reduction. This established the 5-carbon isoprenoid skeleton.

In the subsequent segment of the non-mevalonate pathway (FIG. 1), MEP (4) is first condensed with CTP to 4-diphosphocytidyl-2C-methyl-D-erythritol (CDP-ME) (5) by 4-diphosphocytidyl-2C-methyl-D-erythritol synthase (PCT/EP00/07548). CDP-ME (5) is subsequently ATP-dependent phosphorylated by 4-diphosphocytidyl-2C-methyl-D-erythritol kinase yielding 4-diphosphocytidyl-2C-methyl-D-erythritol 2-phosphate (CDP-MEP) (6). The intermediate is subsequently converted into 2C-methyl-D-erythritol 2,4-cyclodiphosphate (cMEPP) (7) by 2C-methyl-D-erythritol 2,4-cyclodiphosphate synthase. These three enzymatic steps form a biosynthetic unit which activates the isoprenoid C₅-skeleton for the third pathway segment (Rohdich et al., 1999; Lüttgen et al., 2000; Herz et al., 2000).

For numerous pathogenic eubacteria as well as for the malaria parasite P. falciparum, the enzymes involved in the non-mevalonate pathway are essential. The intermediates of the non-mevalonate pathway can not be assimilated from the environment by pathogenic eubacteria and P. falciparum. The enzymes of the alternative isoprenoid pathway do not occur in mammalia which synthesize their isoprenoids and terpenoids exclusively via the mevalonate pathway. Moreover, the idiosyncratic nature of the reactions in this pathway reduces the risk of cross-inhibitions with other, notably mammalian enzymes. Therefore, the enzymes of the alternative pathway seemed to be specially suited as targets for novel agents against pathogenic bacteria and protozoa. Among the enzymes of the non-mevalonate pathway, 2C-methyl-D-erythritol 2,4-cyclodiphosphate synthase seems to be especially suited for the development of new inhibitors, because its reaction mechanism and reaction product are unique in animal and plant kingdoms and numerous possibilities for the design of transition state and intermediate analogues are opened. To aid in finding inhibitors of the non-mevalonate pathway, a crystal structure of 2C-methyl-D-erythritol 2,4-cyclodiphosphate synthase is highly desired.

Therefore, it is an object of this invention to provide crystals comprising 2C-methyl-D-erythritol 2,4-cyclodiphosphate synthase suitable for three-dimensional structure elucidation by crystallographic means and methods for obtaining such crystals.

Further, it is an object of this invention to provide methods for identifying inhibitors of 2C-methyl-D-erythritol 2,4-cyclodiphosphate synthase based on the 3D structure of said synthase.

It is another object of this invention to provide compounds which are inhibitors of 2C-methyl-D-erythritol 2,4-cyclodiphosphate synthase.

### SUMMARY OF THE INVENTION

These Objects are Achieved by:

A crystal which comprises the protein 2C-methyl-D-erythritol 2,4-cyclodiphosphate synthase with or without zinc. The crystal preferably has the cubic space group I 2(1)3 and a unit cell with a=144.5±2 Å. This crystal preferably diffracts x-rays effectively for the determination of the atomic coordinates of the protein to a resolution better than 5 Å, more preferably better than 3.5 Å. The crystal may comprise an organic compound selected from the group of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate.

A method of growing a crystal comprising the protein 2C-methyl-D-erythritol 2,4-cyclodiphosphate synthase and zinc by vapor diffusion uses a reservoir solution containing 0.1 M HEPES pH 7.5 and 2 M ammonium formate.

Use of a crystal as described above for the determination of the three-dimensional structure of the protein 2C-methyl-D-erythritol 2,4-cyclodiphosphate synthase or the three-dimensional structure of said synthase in complex with a compound selected from the group of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate; with or without zinc.

A data storage device having stored thereon atomic coordinates of the three-dimensional structure of the protein 2C-methyl-D-erythritol 2,4-cyclodiphosphate synthase or of the three-dimensional structure of said protein in complex with a compound selected from the group of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate; with or without zinc.

A method of using 2C-methyl-D-erythritol 2,4-cyclodiphosphate synthase and atomic coordinates of the three-dimensional structure of said synthase or of a complex of said synthase with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate, with or without zinc, derived from a crystal structure determination in an inhibitor-screening assay, comprising:

(a) selecting a potential inhibitor by performing rational drug design using said atomic coordinates in conjunction with computer modelling;

(b) contacting the potential inhibitor with said synthase with or without zinc; and

(c) detecting binding of the potential inhibitor to said synthase or detecting inhibition of enzymatic activity of said synthase by the potential inhibitor.

Binding may be detected by soaking the crystal with the potential inhibitor or by growing the crystal in the presence of the potential inhibitor and determining the three-dimensional structure of the complex comprising the synthase and the potential inhibitor with or without zinc.

A method of identifying a potential inhibitor of 2C-methyl-D-erythritol 2,4-cyclodiphosphate synthase by determining binding interactions between the potential inhibitor and a set of binding interaction sites in a binding cavity of said synthase complexed with a compound selected from the group consisting of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate, with or without zinc, comprising

(a) generating the binding cavity on a computer screen,

(b) generating potential inhibitors with their spatial structure on the computer screen, and

(c) selecting potential inhibitors that can bind to at least 3 amino acid residues without steric interference.

A computer-assisted method for identifying potential inhibitors of the protein 2C-methyl-D-erythritol 2,4-cyclodiphosphate synthase using a programmed computer comprising a processor, a data storage system, a data input device, and a data output device, comprising the following steps:

(a) inputting into the programmed computer through said input device data comprising: atomic coordinates of a subset of the atoms of a complex of said protein with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate, with or without zinc, thereby generating a criteria data set;

(b) comparing, using said processor, the criteria data set to a computer data base of low-molecular weight organic chemical structures stored in the data storage system; and

(c) selecting from said data base, using computer methods, a chemical structure having a portion that is structurally complementary to the criteria data set pertaining to the protein and/or structurally similar to the criteria data set pertaining to a compound of said group and being free of steric interference with the protein.

A computer-assisted method for identifying potential inhibitors of the protein 2C-methyl-D-erythritol 2,4-cyclodiphosphate synthase using a programmed computer comprising a processor, a data storage system, a data input device, and a data output device, comprising the following steps:

(a) inputting into the programmed computer through said input device data comprising: atomic coordinates of a subset of the atoms of a complex of said protein with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate with or without zinc, thereby generating a criteria data set; and

(b) constructing, using computer methods, a model of a chemical structure having a portion that is structurally complementary to the criteria data set pertaining to the protein and/or structurally similar to the criteria data set pertaining to a compound of said group and being free of steric interference with the protein.

A method of identifying a candidate inhibitor capable of binding to and inhibiting the enzymatic activity of 2C-methyl-D-erythritol 2,4-cyclodiphosphate synthase, said method comprising the following steps:

(a) introducing into a computer information derived from atomic coordinates defining a conformation of the active site of said synthase or a complex of said synthase with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol or a combination of cytidine monophosphate and 2C-methyl-D-erythritol 2,4-cyclodiphosphate; with or without zinc, based on three-dimensional structure determination, whereby said program utilizes or displays on the computer screen the structures of said conformation;

(b) generating a three-dimensional representation of at least one of the three pockets of the active site of said synthase and/or a compound of said group by said computer program on a computer screen;

(c) superimposing a model of a candidate inhibitor on the representation of at least one pocket of the active site and/or a compound of said group;

(d) assessing the possibility of bonding and the absence of steric interference of the candidate inhibitor with the active site of the protein;

(e) incorporating said candidate compound in an activity assay of said synthase; and

(f) determining whether said candidate compound inhibits enzymatic activity of said synthase.

In the above methods, the atomic coordinates are preferably determined to a resolution of at least 4 Å, more preferably better than 3 Å, and potential inhibitors are selected that can bind to at least 5 binding sites of the synthase.

Finally, a compound is provided having a chemical structure obtained or obtainable by the above methods, said compound being an inhibitor of 2C-methyl-D-erythritol 2,4-cyclodiphosphate synthase.

It has been surprisingly found that protein crystals of 2C-methyl-D-erythritol 2,4-cyclodiphosphate synthase from E. coli can be obtained using the procedures disclosed herein. These crystals are of high quality and are suitable for crystallographic structure determination. According to methods known in the art, the three-dimensional structure of said synthase has been determined (see examples) from a crystal containing zinc and designated “nat2”.

It has been surprisingly found that 2C-methyl-D-erythritol 2,4-cyclodiphosphate synthase tightly binds one zinc ion per monomer of the synthase. This fact provides invaluable information for the understanding of the reaction mechanism of the synthase which in turn is helpful for the rational design of potential inhibitors. Moreover, said synthase forms trimers and the regions on the surface of the monomers involved in interaction with other monomers have been identified.

Furthermore, the 3D structure of 2C-methyl-D-erythritol 2,4-cyclodiphosphate synthase has been determined from crystals soaked with

(a) cytidine diphosphate (CDP) and magnesium ions giving a crystal named “mgcdp2”;

(b) 4-diphosphocytidyl-2C-methyl-D-erythritol giving a crystal named “msubop”;

(c) 4-diphosphocytidyl-2C-methyl-D-erythritol 2-phosphate and EDTA giving a crystal named “subs”;

(d) 4-diphosphocytidyl-2C-methyl-D-erythritol 2-phosphate in the presence of zinc, which is converted by the synthase to cytidine monophosphate (CMP) and 2C-methyl-D-erythritol 2,4-cyclodiphosphate. This crystal is named “sub2”.

(e) cytidine giving a crystal named “cyt”.

In all these cases, the indicated compounds were identified in electron densities of the respective structures.

Surprisingly, the substrate 4-diphosphocytidyl-2C-methyl-D-erythritol 2-phosphate has been found to bind well-ordered to the synthase without conversion to the products under conditions where bivalent metal ions are complexed by EDTA (crystal subs), thereby identifying the active site of the enzyme. Moreover, the substrate analogs, fragments and products CMP, CDP, cytidine and 4-diphosphocytidyl-2C-methyl-D-erythritol were found to bind to the crystallised synthase, allowing a detailed mapping of active site regions and residues which are responsible for binding certain substrate of product moieties. Specific functions could be assigned to specific active site amino acid residues. Even more surprisingly, it has been found that the substrate is coordinated by amino acid residues from two monomers of the trimeric synthase. Magnesium ions are known to be required for the catalytic activity of said synthase. Herein, the location of a magnesium ion has been identified in the complex of the synthase and CDP.

On the basis of the crystal structure data and the alignment of putative 2C-methyl-D-erythritol 2,4-cyclodiphosphate synthases from various organisms (FIG. 3), site-directed mutants of the E. coli synthase were prepared and the essential function of certain amino acids could be confirmed. This further highlights the usefulness of knowing the three-dimensional structure of a protein for understanding and manipulating the function of a protein in a rational way.

Taken together, the three-dimensional structure information disclosed herein has allowed to design methods for identifying potential inhibitors of the synthase employing computer methods of rational drug design and computer modeling. Preferably, structural information of active site residues and/or of bound substrate and/or substrate fragments and products are used for the rational design/computer modelling of potential inhibitors. Potential inhibitors may then be synthesized and their inhibitory potential be tested experimentally. This approach allows the direct design or identification of an inhibitor or reduces the number of compounds which have to be synthesized and to be tested for their inhibitory potential experimentally, since only structures found to be promising in silico are further pursued experimentally. Inhibitors obtained by the methods of this invention may be used as antibiotics against bacteria or protozoa, notably the malaria parasite P. falciparum or as herbicides.

Once a suitable inhibitor of the synthase has been found, inhibitor-resistant mutants of the synthase may be designed using the 3D structures disclosed herein.

The accuracy of the coordinates of a protein crystal structure depends on the resolution of the diffraction data used in refinement. The resolution should be such that amino acid side chains in well-ordered regions of the protein can be seen in the electron density maps. The resolution should be at least 5 Å, preferably better than 4 Å, and most preferably at least 3.0 Å. The coordinates provided herein contain experimental error and are limited by the resolution of the diffraction data. Crystallisation conditions may be further improved according to known approaches in protein crystallisation, diffraction data to better resolution may be measured and more accurate coordinates may be obtained. This may e.g. be achieved by using synchrotron radiation, optionally in combination with cryo-crystallography. It has been found that the crystals used herein can easily be frozen by liquid nitrogen. Using the atomic coordinates disclosed herein as starting structure, such an improved structure may be easily obtained. This will change the numerical values of the coordinates in table 2 to some extent but the fold of 2C-methyl-D-erythritol 2,4-cydodiphosphate synthase will remain the same. All 3D structures of the synthase with atomic coordinates the numerical values of which differ only within experimental or computational error, due to a different choice of the coordinate system, due to different experimental conditions or due to a different quality of experimental data are also comprised by the present invention. The same applies to 3D structures derived from different crystal forms or to 3D structures determined by experimental approaches different from crystallography such as NMR or electron microscopy.

Upon binding of a molecule to said synthase, the structure of the synthase may undergo changes. Often, such changes are limited to amino acid side chain conformations but whole groups of amino acids including their peptide back bone may move as well, particularly amino acids in a flexible loop. Such altered conformations are also comprised by this invention as long as the overall fold of the protein remains the same. The six structures disclosed herein provide a framework of conformational states assumable by the synthase in the absence and presence of substrate, substrate analogs and products. When performing rational drug design or computer modelling, at least the conformation of amino acid side chains will also be varied in the process of finding a potential inhibitor. Preferred and less-preferred side chain conformations (torsion angles) are known in the art.

Herein, the E. coli protein has been used to determine the structure of 2C-methyl-D-erythritol 2,4-cyclodiphosphate synthase. This invention relates also to said synthases from other organisms. Although orthologous proteins from various organisms may differ considerably in the primary structure (compare sequence alignment of FIG. 3), the fold and active site architecture typically remain essentially the same; Active site residues necessary for the function of a protein are conserved. As a consequence, inhibitors found according to the methods of this invention using the 3D structure of 2C-methyl-D-erythritol 2,4-cyclodiphosphate synthase from E. coli will also be inhibitors of orthologous synthases from organisms other than E. coli. This invention therefore comprises proteins with root mean square deviations from the E. coli synthase structure over protein backbone atoms or better over all non-hydrogen atoms of not more than 3 Å, preferably not more than 2 Å and most preferably not more than 1 Å. The 3D structures of such related proteins may easily be obtained by homology modeling using the 3D structures of this invention. Practically, other proteins comprised by this invention may be those whose crystal structures can be solved by molecular replacement using the coordinates of the E. coli synthase of this invention.

The crystals used herein belong to the cubic space group I2(1)3 with unit cell parameter a≈144.5 Å. However, other crystal forms may also be used to determine the 3D structure of the synthase if they are of sufficient quality for diffraction experiments. A structure from another crystal form may preferably be solved using molecular replacement with the atomic coordinates disclosed herein as a starting model. The structure of the synthase as determined from another crystal form may differ to some extent from the structures disclosed herein. Such differences will however be limited essentially to surface amino acid residues involved in crystal packing. The crystals of space group I2(1)3 used herein feature the important advantage that the active site of the synthase is easily accessible to substrate and analogs thereof or inhibitors, which allows soaking experiments and the determination of the synthase in complex with low molecular weigth organic compounds. The synthase used for crystallisation optionally contains zinc in order to be in an active form. Extra zinc may be added during crystallisation.

Crystallisation may be done by any method known in the art like batch methods or vapour diffusion methods. Hanging- or sitting-drop vapour diffusion methods are preferred. The 3D structure of the synthase in complex with an inhibitor may be solved by preparing a crystal containing the synthase in complex with the inhibitor. This may be achieved by co-crystallizing the synthase with the inhibitor or by soaking a crystal of the synthase not containing an inhibitor in mother liquor containing an excess of the inhibitor of interest for a suitable time. Prior to collection of diffraction data, crystals may be frozen according to known methods of cryo-crystallography, preferably after treatment of the crystal with a suitable cryo protectant.

After the structure of the synthase has been solved and refined, the atomic coordinates may be stored on a computer-readable-data storage device for further use.

### SHORT DESCRIPTION OF THE FIGURES, TABLES, ENCLOSED CD-ROM and ANNEXES

FIG. 1:

Biosynthesis of both isoprenoid precursors isopentenyl pyrophosphate and dimethylallyl pyrophosphate via the alternative pathway.

FIG. 2:

Enzyme activities of 2C-methyl-D-erythritol 2,4-cyclodiphosphate synthase of E. coli.

FIG. 3:

Alignment of amino acid sequences of putative 2C-Methyl-D-erythritol-2,4-cyclodiphosphate synthases from various organisms. A, Streptomyces sp.; B, Mycobacterium tuberculosis; C, Haemophilus influenzae; D, . coli; E, Vibrio cholerae; F, Pseudomonas aeruginosa; G, B. subtilis; H, Neisseria meningitidis; I, Xylella fastidiosa; J, Synechocystis sp.; K, Buchnera sp.; L, Aquifex aeolicus; M, A. thaliana; N, Thermotoga maritima; O, Deinococcus radiodurans; P, P. falciparum; Q, Chiamydia muridarum.

FIG. 4: Overall fold of the monomer

(A) Stereo ribbon representation of the structure of the 2C-methyl-D-erythritol 2,4-cyclodiphosphate synthase monomer. The four-stranded β-sheet is shown in yellow, the smaller two-stranded β-sheet in orange, α-helices are depicted in red. The bound zinc ion is shown as a pink ball including the coordinating side chains of Asp8, His10 and His42. (B) Cα-trace of the 2C-methyl-D-erythritol 2,4-cyclodiphosphate synthase monomer. Every tenth amino acid is shown as a black ball.

FIG. 5: Overall fold of the trimer

(A) Stereo side view of the 2C-methyl-D-erythritol 2,4-cyclodiphosphate synthase trimer perpendicular to the trimer axis. The view goes onto the CDP binding site. The monomers are shown in blue, green and ochre. CDP is depicted as a stick model in red. (B) View along the threefold axis. The N- and C-termini point away from the viewer.

FIG. 6: Active site structure

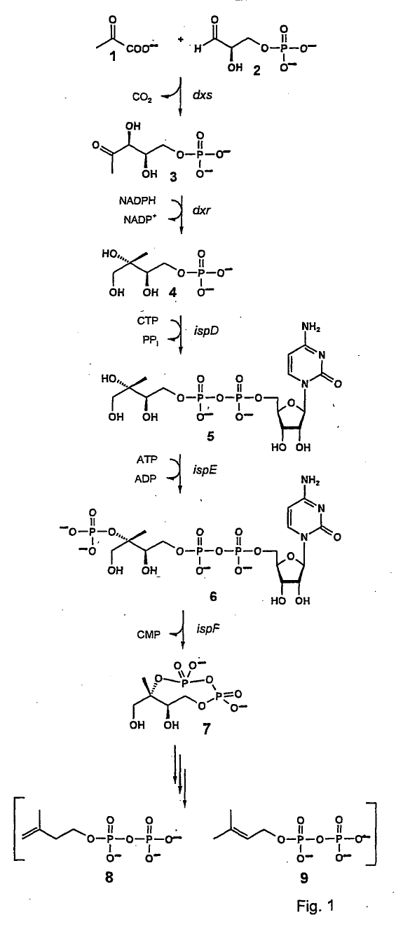

The substrate binding site/active site is composed of two subunits (in ochre and green). CDP is shown as a ball and stick model in dark green. A magnesium ion depicted as a gray ball is liganded by Glu 135 and bridges the α- and β-phosphate of CDP. The phosphate of CDP is bound to a zinc ion (pink ball) coordinated by Asp8, His 10 and His42. Two sequence motifs are involve in substrate binding: the KATTTE-motif (residues 130 to 135) at the C-terminal half of β-strand S5 that contributes Ala131, Thr133 and Glu135 to substrate binding and the DIG-motif (residues 56 to 58) at the N-terminus of α-helix H2 where Asp56 and Gly58 contact the ribose. The presumable binding site for the 2C-methyl-D-erythritol 2-phosphate moiety is formed by Ile57, Leu76, Ser35 adjacent main chain atoms and completed by the loop from Pro62 to Ala71 including Asp63 (shown in red).

FIG. 7: Electrostatic and surface properties of the active site. The colour scale goes from blue (negative potential) via green to red (positive potential).

(A) The active site/substrate binding site consists of three subsites designated I, II and III. The central subsite I accommodates the ribosyl 5′-diphosphate of CDP: (B) The potential subsite for the 2C-methyl-D-erythritol 2-phosphate-moiety is flanked by the highly conserved Ile57 and Ser35. (C) The subsite for the cytidyl-moiety is formed by Lys104, Leu106, Ala131 and Thr133.

FIG. 8

Schematic two-dimensional representation of product binding from the model of complex structure sub2. Interactions of protein residues with CMP and 2C-methyl-D-erythritol 2,4-cyclodiphosphate are depicted as dotted lines along with the nomenclature of product atoms as used in the coordinate file of structure sub2. Distances are given in Å.

FIG. 9:

DNA and deduced amino acid sequences of the ispF gene of Escherichia coli. The positions and directions of oligonucleotides used in PCR reactions for the construction of expression vectors for the expression of the site directed 2C-methyl-D-erythritol 2,4-cyclodiphosphate synthase mutant proteins D8S, H10S and H42S are indicated by arrows.

Table 1 shows statistics of data collection and refinement of the six structures disclosed herein.

Table 2 gives coordinates of atoms within 10 Å of the bound ligands of structure sub2.

Annexes 1 to 6 are printouts of coordinate files of structures cyt, mgcdp2, nat2, sub2, subop and subs, respectively.

Structure sub2 was deposited with the protein data bank (PDB) and can be accessed via www.rcsb.org/pdb using entry number 1JY8.

### DETAILED DESCRIPTION OF THE INVENTION

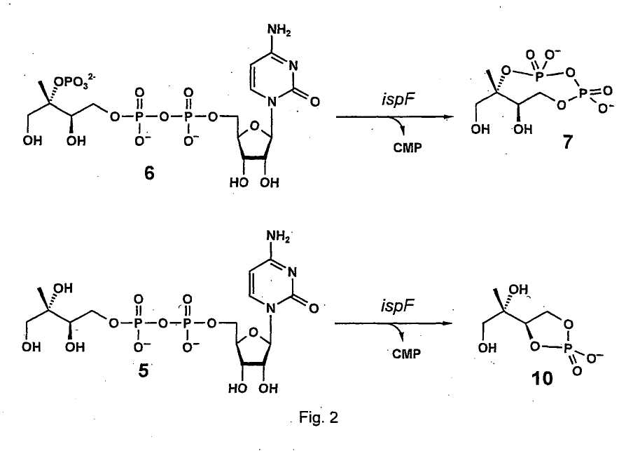

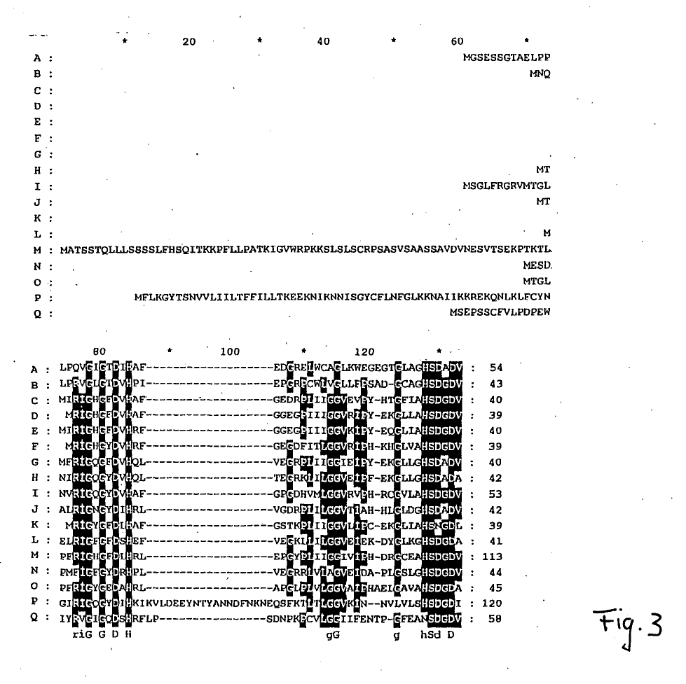

2C-methyl-D-erythritol 2,4-cyclodiphosphate synthase specified by the ispF gene from E. coli catalyzes the cyclization of 4-diphosphocytidyl-2C-methyl-D-erythritol 2-phosphate 6 to 2C-methyl-D-erythritol 2, 4-cyclodiphosphate 7 (FIG. 2). With lower rate, 2C-methyl-D-erythritol 2,4-cyclodiphosphate synthase also converts 4-diphosphocytidyl-2C-methyl-D-erythritol 5 into 2C-methyl-D-erythritol 3,4-cyclomonophosphate 10 (Herz et al. 2000). Monomeric 2C-methyl-D-erythritol 2,4-cyclodiphosphate synthase from E. coli has a molecular weight of 17 kDa (corresponding to 159 amino acids) (Herz et al. 2000). Magnesium ions are necessary for the catalytic activity. The K_{M} and vₘₐₓ values of the E. coli enzyme are 37 μM and 76 μmol mg⁻¹ min⁻¹, respectively, with 4-diphosphocytidyl-2C-methyl-D-erythritol 2-phosphate as substrate.

### 3D Structure Solution

2C-methyl-D-erythritol 2,4-cyclodiphosphate synthase was crystallized in the cubic space group I2(1)3 with a=144.2 Å (in structure nat2). The solvent content is about 84%. A native data set was collected on a rotating anode generator equipped with an MARresearch Image Plate detector up to a resolution of 2.85 Å. Details and statistics of data collection are given in Table 1. For structure solution, a native crystal was incubated with 2 mM mercury(II) acetate in mother liquor for one hour yielding an isomorphous derivative crystal With a single heavy atom site in the asymmetric unit. Heavy atom parameters were refined and phases calculated with the program MLPHARE (Collaborative Computational Project No. 4, 1994). The phasing power was 1.0 (25 to 3.6 Å) with a figure of merit of 0.27 in a resolution range from 20 to 3.6 Å. Phases were improved by solvent flattening using the program DM (Collaborative Computational Project No. 4, 1994). An atomic model was built with the program MAIN (Turk, 1992) and refined with the program X-PLOR (Brünger et al., 1998). The model comprises residues Met1 to Ile155. The electron density is continuous throughout the model with the exception of a short break between Phe61 and Pro62 in a loop structure comprising Phe61 to Lys69. The model of structure nat2 has been refined to an R-value of 22.6% and a free R value of 23.7% calculated with 5% of the reflections in the resolution range 20.0 to 2.85 Å (Table 1).

The following substrate, substrate analoge and product complexes were determined in order to determine binding of these molecules to the synthase:

subop: a crystal soaked with 10 mM 4-diphosphocytidyl-2C-methyl-D-erythritol. The zinc atom the water or hydroxyl-group at the zinc is replaced by an oxygen of the beta-phosphate of the diphosphocytidyl-moiety.

subs: a crystal soaked with 10 mM 4-diphosphocytidyl-2C-methyl-D-erythritol 2-phosphate and 10 mM EDTA, that contains no zinc.

sub2: a crystal soaked with 10 mM 4-diphosphocytidyl-2C-methyl-D-erythritol 2-phosphate, that containes zinc and the products CMP and 2C-methyl-D-erythritol 2,4-cyclodiphosphate.

mgcdp2: a crystal soaked with 2 mM CDP and 5 mM MgCl2

cyt: a crystal soaked with 10 mM cytidine

Statistics on data collection and refinement for these crystals/structures of the invention are given in Table 1. These structures were determined using the nat2 structure as starting model. Initially a rigid body refinement was carried out followed by positional refinement. Then the substrate, substrate analoge or product molecules were build into the electron density of difference electron density maps, again followed by refinement of atom positions and B-factors.

### Overall Description of the 3D Structure

2C-methyl-D-erythritol 2,4-cyclodiphosphate synthase forms bell-shaped homotrimers with overall dimensions of about 40 Å in height and between 40 and 60 Å in diameter. These molecular trimers are generated by the crystallographic threefold axis from monomers of 17 kDa that represent the asymmetric unit of the crystal. The overall appearance of the trimer is compact but the molecule shows pronounced loop structures surrounding a zinc binding site at the wider end of the trimer opposite to the location of the N- and C-termini. The latter are in direct neighbourhood within each monomer. Analysis of the secondary structure of 2C-methyl-D-erythritol 2,4-cyclodiphosphate synthase with the program STRIDE (Frishman & Argos, 1995) shows a content of regular secondary structure of 26.5% β-strand and 28.4% α-helix. The secondary structural elements are depicted in FIG. 4 along with the used nomenclature. In the Ramachandran plot, 72.2% of the residues were found in the most favourable, 19.0% in the favourable and 4.8% in the generously allowed region as indicated by the program PROCHECK (Laskowski et al., 1993). The general correctness of the model was further attested by the ‘omit’ density which appeared for the zinc ion and the substrate-like CDP molecule.

### Detailed Description of the Monomer

Each monomer consists of a large four-stranded β-sheet comprised of β-strands S1 and S4 to S6, a small two-stranded β-sheet formed by S2 and S3 and four α-helices H1 to H4 (FIG. 4). The four-stranded β-sheet with the topology 1-4-2-3 and strand directions up-down-up-up is located towards the trimer contacts with strands that run parallel to the trimer axis. α-helices H1 and H4 pack onto this β-sheet which in turn serve as support for α-helix H3. The small β-sheet which is inserted between β-strand S1 and α-helix H1 is oriented towards the solvent and packs on one end of the large β-sheet and between α-helices H1 and H4. α-helix H2 constitutes a single α-helical turn within a loop structure connecting α-helices H1 and H3. The coil region between α-helices H2 and H3 caps a pronounces cavity above the zinc binding site and displays considerable flexibility a shown by the relatively weak electron density and elevated temperature factors.

2C-methyl-D-erythritol 2,4-cyclodiphosphate synthase shares a structural module comprising the four-stranded β-sheet and two α-helices in the same topology with a number of proteins including the YjgF gene product (Volz, 1999)(PDB entry: 1QU9) (rmsd 3.1 Å for 82 Cα-positions), phosphoribosyl-aminoimidazole synthetase (Li et al., 1999)(1CLI) (rmsd 3.1 Å for 94 Cα-positions) or chorismate mutase (Chook et al., 1993)(2CHS) (rmsd 4.0Å for 73 Cα-positions). YjgF shows an extension of 25 amino acids at the N-terminus compared to 2C-methyl-D-erythritol 2,4-cyclodiphosphate synthase that form two additional β-strands, whereas chorismate mutase has a C-terminal extension that creates only one additional β-strand. Interestingly, 2C-methyl-D-erythritol 2,4-cyclodiphosphate synthase, YjgF and chorismate mutase form trimers where the monomer orientation displays a significant tilt due to packing of the additional b-strands.

In addition, glutamine phosphoribosylpyrophosphate amidotransferase (Muchmore et al., 1998)(1ECF), 5-carboxymethyl-2-hydroxymuconate isomerase (Subramanya et al., 1996)(1OTG) or zinc-dependent cytidine deaminase (Xiang et al., 1995)(1CTT) show also a four-stranded β-sheet with two α-helices packed on one side, however with different topologies within the β-sheet, or a three-stranded β-sheet as in the case of the ribosomal protein L22 (Unge et a., 1998)(1BXE).

### Detailed Description of the Trimer

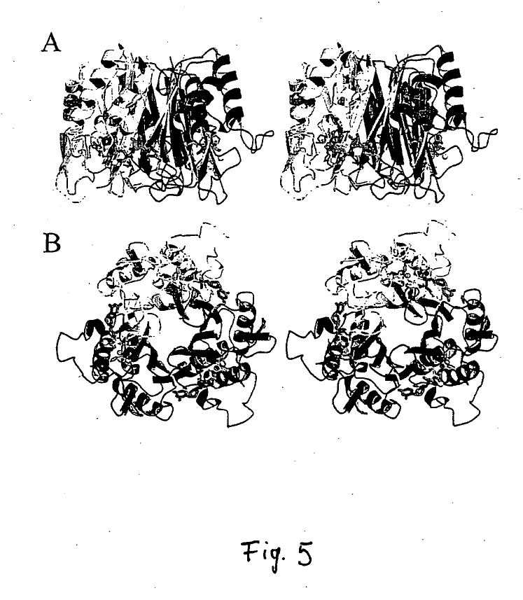

2C-methyl-D-erythritol 2,4-cyclodiphosphate synthase forms trimers that are generated by an exact crystallographic three-fold axis from the monomers (FIG. 5). The main trimer contacts are formed between the backside of the central four-stranded β-sheets, especially the terminal β-strands S1 and S5. They pack edge on against those of the neighbouring molecules in an almost perpendicular fashion so that no continuous β-barrel is formed from the β-sheets. The edge of β-strand S5 is exposed to the solvent where its C-terminal half contributes to binding of the CDP-moiety of the substrate. The contact between the β-sheets involves hydrophobic interactions (Ile3, Phe7, Val9, Ile99, Phe139, Ile146, Val151, Leu153) but also three internal salt bridges formed between Glu149 and His5 are present in the centre of each β-sheet. These contacts are closer at the C- and N-termini of the trimer whereas the contacts on the opposite side are mainly mediated by the loop that connects β-strands S5 and S6.

### The Zinc Binding Site

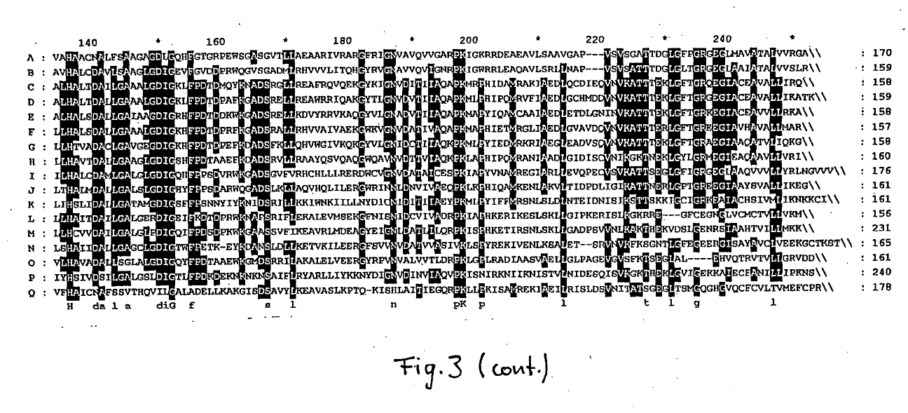

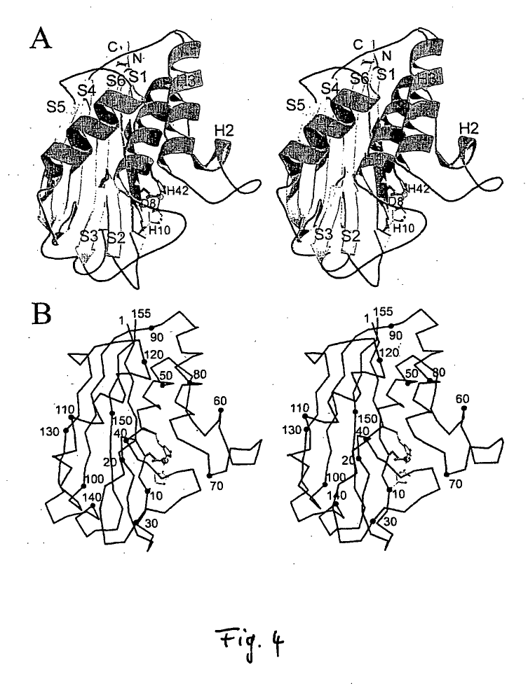

During structure analysis of the nat2 structure, it became apparent that a metal ion was coordinated in a distorted tetrahedral geometry by Asp8, His10 and His42 which represent highly conserved residues within the protein family (FIG. 3). Asp8 appears as a bidentate ligand, His10 binds via N_{ε} and His42 via N_{δ}. The fourth ligand, presumably a water molecule (or hydroxyl ion) in the absence of substrate, can be replaced by chloride as observed in crystals grown from NaCl at pH 9.0 or by the β-phosphate of the substrates CDP-moiety. This ion was identified as tightly bound zinc by atomic absorption spectroscopy as described in the example section. About 0.9 mol zinc were found per mol of synthase monomer. The importance of this zinc ion and of its ligands for the catalytic activity of the synthase was demonstrated by the site-directed mutants Asp8Ser, His10Ser and His42Ser which were all enzymatically inactive. It should be noted that no extra zinc was added in any step from bacterial growth, to protein purification to crystallization for the preparation of the native nat2 crystal.

### Identification of the Active Site—Complex with Mg-CDP (Structure mgcdp2)

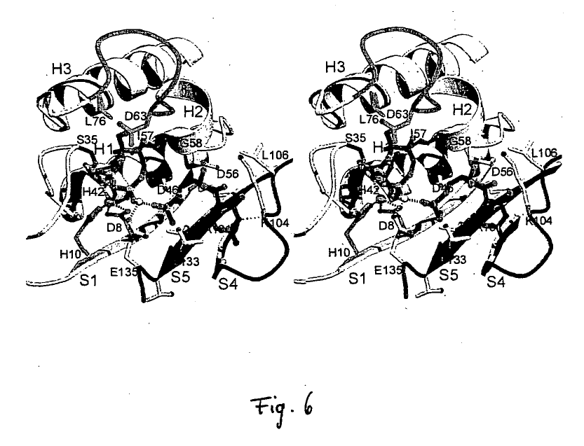

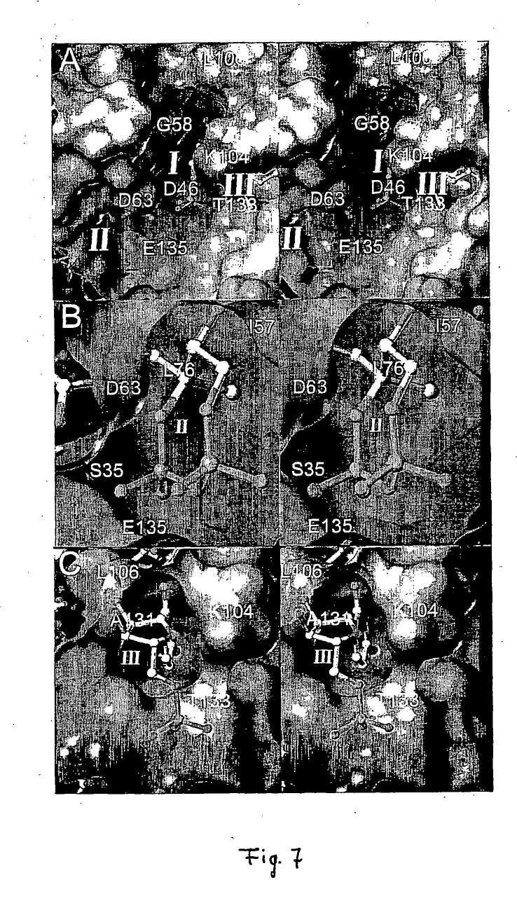

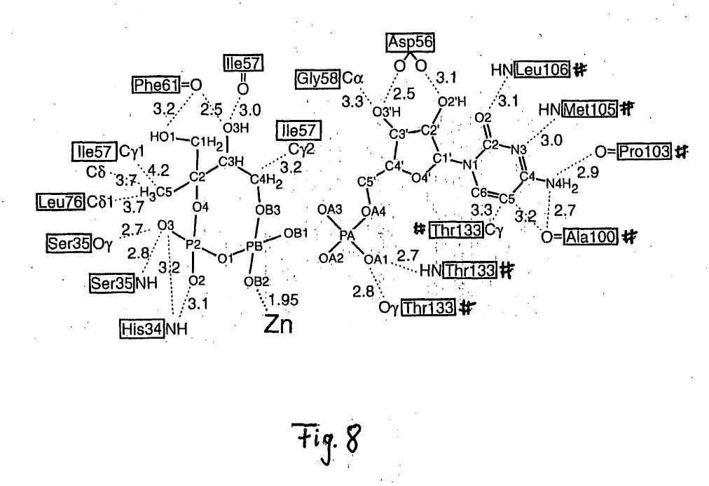

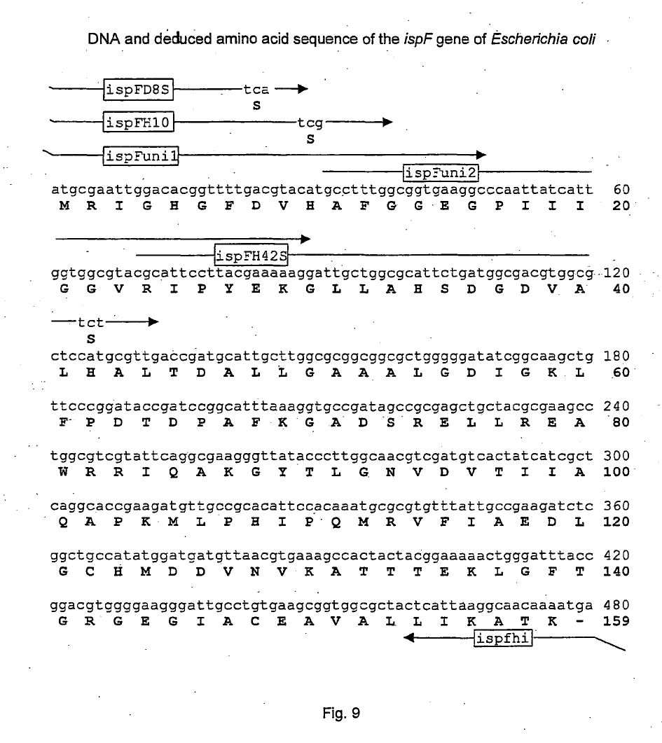

The active site was first identified in the structure of the complex between the synthase and cytidine diphosphate (CDP) both in the presence and the absence of magnesium ions (FIG. 6). CDP is a substructure of the substrate 4-diphosphocytidyl-2C-methyl-D-erythritol 2-phosphate. In the crystal form used herein, there are no crystal contacts to symmetry related trimers. This renders this crystal forms particularly suitable for soaking in or cocrystallizing the synthase with potential inhibitors, substrates or substrate analogs without disturbing crystal packing. In this respect, the high solvent content is advantageous as well.

The binding site for the elongated substrate molecule extends over two adjacent monomers. A pronounced and richly structured cavity that accommodates the substrate is formed opposite to the location of the N- and C-termini of the synthase. It involved the α-helices H1, H2 and adjacent residues, the N-terminus of H3 and parts of the loop connecting H2 and H3 of one molecule and the C-termini of strands S4 and S5 and the loop connecting S4 and α-helix H4 of another molecule. The active site itself is located in the vicinity of the zinc-ion where the β-phosphate of CDP is bound. This phosphate has replaced the water (or hydroxide) as the fouth ligand to the zinc ion, which renders it more nucleophilic. It follows that in the reaction of the synthase with its natural substrate, it will be the phosphate corresponding to the β-phosphate group of CDP that will be attacked by the terminal phosphate group of the substrate as a nucleophile to form the cyclic diphosphate. Therefore, residues in proximity are expected to directly contribute to the enzymatic reaction. Residues near the zinc-ion include the highly conserved residues Ser35, Asp46 and Ile57. The active site is capped by a rather flexible segment comprising residues Pro62 to Ala71 including Asp63 which points towards the β-phosphate of CDP and to Ser35, suggesting a role in catalysis although it is not strictly conserved. Consequently, this flexible segment is better ordered in the complex than in the apo structure. From the position of the β-phosphate of CDP it can be predicted that the 2-methyl-D-erythritol 2-phosphate-moiety of the substrate will be bound in the vicinity of Ser35 and Ile57 and will be in contact to the above mentioned flexible loop.

### The KATTTE-Motif

The β-phosphate of CDP is anchored to the zinc-ion and completes its co-ordination sphere. The α-phosphate is bound by Thr133# (#denotes from another subunit, generated by threefold symmetry) of the KATTTE sequence motif (residues 130 to 135) located at the C-terminal end of β-strand S6. Lys130# forms an internal salt-bridge to Asp95# of the neighbouring β-strand S5 but has no contact to the substrate. The side-chain of Ala131# points onto the side-face of the cytidyl-moiety and thereby helps to position the substrate. The side chain of Thr133# contacts the α-phosphate of the CDP molecule whereas Thr134# is buried in the interior of the protein. In addition, Thr133# supports the cytidyl-moiety, which is further bound by contacts to the side-chains of Lys104# and Leu106#, the latter being badly defined by electron density. N3 forms an H-bond to the peptide amide between Lys104# and Met105#. Glu135# functions as the protein ligand to the magnesium ion that bridges the α- and β-phosphates of CDP.

### The DIG-Motif

The 2′- and 3′-hydroxyl groups of the CDP-ribose are bound to the carbonyl oxygen of Ala131# and by polar contacts to the carboxylate group Asp56 and van der Waals contacts to Gly58. Residue Ile57 forms one side of the cavity surrounding the zinc-ion where the 2C-methyl-D-erythritol 2-phosphate-moiety of substrate will presumably be located. Together these residues form the conserved DIG-motif (residues 56 to 58). The mutant Asp56Ser shows a decreased activity of 35% as compared to the native enzyme which indicates the importance of that contact to the CD β-ribose for binding but also that Asp56 is not directly involved in the enzymatic mechanism.

The cytidyl-moiety binds to a pocket formed by the C-terminal ends of the β-strands S4 and S5 and the loop structure that connects β-strand S4 and α-helix H4.

### Properties of the Active Site/Substrate Binding Site

Based on the mgcdp2 structure, the active site/substrate binding site can be subdivided into three distinct pockets (FIG. 7): a central pocket that surrounds the ribosyl 5′-diphosphate of CDP (pocket I), a pocket where the 2C-methyl-D-erythritol 2-phosphate-moiety of substrate will bind presumalby (pocket II), and a pocket for the cytidyl-moiety (pocket III). Pocket II is capped by a relatively flexible loop (Pro62 to Ala71) which suggests an induced fit mechanism for the binding of that substrate part. This pocket shows both hydrophobic (Ile57, Leu76) and hydrophilic (Ser35, Ser73 and Asp63) side chains in addition to polar backbone atoms of the contributing amino-acid chain. In contrast, the central and cytidyl-pocket appear rather static and show only minor changes in side chain orientation upon CDP binding for Glu136 and Leu106. The central pocket (I) is deep with the highly conserved Asp46 at its base which is surrounded by Asp56, Gly58 and Ile57. The front entrance to the central cavity is framed by Lys104, The133, Glu135 and Asp63. The cytidyl-moiety is bound to pocket III formed by Ala131, Thr133, Lys104 and Leu106. It is not stacked between side chains but packs only with one face against Ala131.

Further, important information is drawn from the other complex structures. The complexes allow the description of interaction sites in pocket II which binds 2C-methyl-D-erythritol 2,4-cyclodiphosphate coordinated to zinc and in pocket III where the cytidyl-moiety is anchored. The central pocket I adjacent to the ribose and the diphosphate moiety of CDP is filled by three water molecules (number 506, 507 and 511 in structure sub2).

Based on the interactions observed in the product complex sub2 a pharmacophore can be described that mimics parts of the substrate and/or product. In detail, the following interaction sites of a potential inhibitor for substrate-like inhibitor molecules can be deduced. These interaction sites may interact with interaction sites of the active site of the synthase. Some of the interactions involved are schematically depicted in FIG. 8.

Cytosine (Provides Four Interaction Sites):

carbonyl oxygen at positions 2,

nitrogen N3,

the amino group in position 4 and

the carbon C5.

These interaction sites interact in a precise H-bonded network and van der Waals contacts with Leu106, Met105, Pro103, Ala100 and Thr133.

Ribose (Two Interaction Sites):

C2 and C3 hydroxyl groups bind to the carboxylate group of Asp56, the C3 hydroxyl group forms a van der Waals contact to Cα of Gly58

CMP Alpha-Phosphate (One Interaction Site):

contacts the side-chain of Thr133 and a solvent molecule (507) in subsite I.

Cyclodiphosphate Product (Six Interaction Sites, See Also FIG. 8).

hydrophobic sites at C4 and C5 interacting with the side chains of Ile57 and Leu76 (FIG. 8). Ile57 is highly conserved.

hydrophilic sites at the 1-hydroxyl and 3-hydroxyl-groups interacting with Phe61, Ile57

a hydrophilic/charged site at the P2 phosphate forming hydrogen bonds to His34 and Ser35. In the absence of substrate this site is occupied by a water molecule.

the beta-phosphate PB which is a ligand to the zinc ion.

A potential inhibitor molecule may have moieties corresponding to at least three of these interaction sites, especially the hydrogen-bonding network of the cytidyl-moiety, a zinc ligand like the PB phosphate (or similar ligands like carboxylate or a hydroxamic acid moiety) and hydrophobic sites binding the C5-methyl group.

In addition to these interactions, subsite I that is not occupied by any of the analysed ligand molecules but filled with three water molecules may be used by an inhibitor molecule for interactions.

The crystals/structures subs, sub2 and cyt demonstrate that coordination to the zinc ioin is not essential for binding as the substructures cytidine or CMP have considerable affinity for the protein. The bound 2C-methyl-D-erythritol 2,4-cyclodiphosphate in the crystal sub2 shows that coordination of the zinc ion and the interactions described above in subsite II are also sufficient for binding.

### Propeties of the Site-Directed Mutants IsPF-D8S, IspF-H10S and IspF-H42S

For confirmation of the crystal structure data the recombinant His-tagged site-directed mutant proteins IspF-D8S, IspF-H10 and IspF-H42S were prepared as described in the example section. As already described above, the amino acid residues Asp8, His10 and His42 are the coordinating ligands for the zinc-ion in the active site. The three site-directed mutants show less than 1% activitity as compared to the recombinant His-tagged wild-type protein. Moreover, atomic absorption spectroscopy experiments show that these mutants contain less than 0.2 mol Zn per monomer of the synthase. These results clearly demonstrate for the first time that zinc is essential for the catalytic activity of this synthase.

### Methods of Selecting or Identifying Potential Inhibitors of 2C-Methyl-D-erythritol 2,4-Cyclodiphosphate Synthase

The binding mode of CDP and of the other substrate analogs to the synthase indicates that they might be competitive inhibitors of the synthase. Other potential inhibitors may be identified using the structural information and the methods provided herein. Preferably, potential inhibitors are selected by their potential of binding to the active site. The active site comprises the three binding pockets I, II and III described above. Compounds which bind to at least one of these pockets can be expected to compete with binding of the substrate thus functioning as competitive inhibitors of the synthase. When selecting a potential inhibitor by rational drug design or computer modeling, the 3D structure of the synthase is loaded from a data storage device into a computer memory and may be displayed (generated) on a computer screen using a suitable computer program. Preferably, only a subset of interest of the coordinates of the whole structure of the synthase is loaded in the computer memory or displayed on the computer screen. This subset of interest may comprise the coordinates of active site residues and/or those which make up a binding cavity (pocket) of the synthase and the above mentioned zinc ion. This subset may be called a criteria data set; this subset of atoms may be used for designing an inhibitor. It may contain amino acid residues of more than one synthase monomer and may comprise at least some of the following amino acid residues:

Ala131# contacting the face of the cytidyl moiety;

Ala131# bonding with its carbonyl oxygen to at least one of the 2′-and 3′-hydroxyl groups of the cytidyl moiety;

Asp56 making a hydrogen bond with its carboxyl group to at least one of the 2′-and 3′-hydroxyl groups of the cytidyl moiety;

Gly58 making van der Waals contact with its Cα to at least one of the the 2′-and 3′-hydroxyl groups of the cytidyl moiety;

peptide group between Lys104# and Met105# hydrogen bonding to N3 of the cytidyl moiety;

Thr133# supporting the cytidyl moiety and hydrogen bonding with its γ-O or its backbone NH to the α-phosphate;

Lys104# contacting with its side chain the cytidyl moiety;

Leu106# contacting with its side chain the cytidyl moiety;

Leu106# hydrogen bonding with its NH to the-carbonyl oxygen of the cytidyl moiety;

Asp63 binding to the β-phosphate of cytidine diphosphate;

His34 hydrogen bonding with its backbone NH group to at least one oxygen atom of the P2 phosphate group of 2C-methyl-D-erythritol 2,4-cyclodiphosphate;

Ser35 hydrogen bonding with its backbone NH group to one oxygen atom of the P2 phosphate group;

Ser35 hydrogen bonding with its γ-OH to one of the oxygen atoms of the P2 phosphate group;

Leu76 making a van der Waals contact with its δ-C to the 2-methyl group;

Ile57 making a van der Waals contact with δ-C to the 2-methyl group;

Ile57 making a van der Waals contact with γ-C to the 2-methyl group;

Phe61 hydrogen bonding with its backbone carbonyl oxygen to the 1-hydroxyl group;

Phe61 hydrogen bonding with its backbone carbonyl oxygen to the 3-hydroxyl group;

Ile57 hydrogen bonding with its backbone carbonyl oxygen to the 3-hydroxyl group;

Ile57 making van der Waals contact with its γ-C to the carbon at the 4-position;

Pro100# hydrogen bonding with its backbone carbonyl oxygen to the amino group of the cytidyl moiety;

Ala100# hydrogen bonding with its backbone carbonyl oxygen to the amino group of the cytidyl moiety;

Ala100# supporting with its backborie carbonyl oxygen the C5 position of the cytidyl moiety.

Amino acids not denoted by # belong to one subunit and those denoted by # belong to another subunit.

A potential inhibitor may then be designed de novo by rational drug design in conjunction with computer modelling. Models of chemical structures or molecule fragments may be generated on a computer screen using information derived from known low-molecular weight organic chemical structures stored in a computer data base or are built using the general knowledge of an organic chemist regarding bonding types, conformations etc. Suitable computer programs may aid in this process in order to build chemical structures of realistic geometries. Chemical structures or molecule fragments may be selected and/or used to construct a potential inhibitor such that favorable interactions to said subset or criteria data set become possible. The more favorable interactions become possible, the stronger the potential inhibitor will bind to the synthase. Preferably, favorable interactions to at least three amino acid residues should become possible. Favorable interactions are any non-covalent attractive forces which may exist between chemical structures such as hydrophobic or van-der-Waals interactions and polar interactions such as hydrogen bonding, salt-bridges etc. Unfavorable interactions such as hydrophobic-hydrophilic interactions should be avoided but may be accepted if they are weaker than the sum of the attractive forces. Steric interference such as clashes or overlaps of portions of the inhibitor being selected or constructed with protein moieties will prevent binding unless resolvable by conformational changes. The binding strength of a potential inhibitor thus created may be assessed by comparing favorable and unfavorable interactions on the computer screen or by using computational methods implemented in, commercial computer programs.

Conformational freedom of the potential inhibitor and amino acid side chains of the synthase should be taken into account. Accessible conformations of a potential inhibitor may be determined using known rules of molecular geometry, notably torsion angles, or computationally using computer programs having implemented procedures of molecular mechanics and/or dynamics or quantum mechanics or combinations thereof.

A potential inhibitor is at least partially complementary to at least a portion of the active site of the synthase in terms of shape and in terms of hydrophilic or hydrophobic properties.

Databases of chemical structures (e.g. Cambridge structural database or from Chemical Abstracts Service; for a review see: Rusinko (1993) Chem. Des. Auto. News 8, 44-47) may be used to varying extents. In a totally automatic embodiment, all structures in a data base may be compared to the active site or to the binding pockets of the synthase for complementarity and lack of steric interference computationally using the processor of the computer and a suitable computer program. In this case, computer modeling which comprises manual user interaction at a computer screen may not be necessary. Alternatively, molecular fragments may be selected from a data base and assembled or constructed on a computer screen e.g. manually. Also, the ratio of automation to manual interaction by a person skilled in the art in the process of selecting may vary a lot. As computer programs for drug design and docking of molecules to each other become better, the need for manual interaction decreases.

A preferred approach of selecting or identifying potential inhibitors of the synthase makes use of the structure of the synthase-CDP complex of this invention. CDP is a fragment of the natural substrate and is a competitive inhibitor of the synthase as it binds to a portion of the active site. A potential inhibitor may be more easily found based on the structure and conformation of CDP bound to the active site of the synthase than based on complementarity to the active site. Thus, CDP may be a determinant of the structure of an inhibitor. Analogously to the principles of drug design and computer modeling outlined above, chemical structures or fragments thereof may be selected or constructed based on similarity to the structure of CDP bound to the synthase. CDP may even be used as a starting inhibitor. Models of chemical structures taken from a data base or constructed by modeling on the computer screen may be added to CDP. Alternatively, fragments of CDP may be exchanged by other fragments or chemical structures in order to improve the inhibitory function and/or in order to improve the suitability of the potential inhibitor thus obtained for pharmaceutical purposes. Putative inhibitors so obtained are 4-diphosphocytidyl-erythritol or 5-diphosphocytidyl-ribitol and derivatives, notably the 2-phosphates from these compounds.

The binding mode of CDP to the synthase and the information derivable therefrom regarding the mechanism of the reaction catalyzed by the synthase may be used to design inhibitors. Preferably, the zinc ion or the magnesium ion are used in such considerations.

Potential inhibitors may be selected or designed such that they interfere with said zinc or said magnesium ion. Such inhibitors may e.g. prevent binding of these metal ions or they may chelate them out of the synthase.

Another preferred approach is the design of mechanism-based inhibitors like suicide inhibitors which modify the synthase when turning over with the inhibitor.

Possible approaches for rational drug design are described extensively in the literature. See e.g. Meng et al. (1992) J. Comp. Chem. 505-524; Cohen et al. (1990) J. Med. Chem. 33, 883-894; Navia and Murcko (1992) Current Opinion in Structural Biology, 202-210, A. Parrill: rational drug design, ACS symposium series 719, American Chemical Society, 1999, Washington DC; Chemical and structural approaches to rational drug design, eds.: D. Weiner and W. Williams, CRC Press, 1995, Boca Raton.

Programs usable for computer modelling include Quanta (Molecular Simulations, Inc.) and Sibyl (Tripos Associates). Other useful programs are Autodock (Scripps Research Institute, La Jolla, described in Goodsell and Olsen (1990) Proteins: Structure, Function and Genetics, 8, 195-201), Dock (University of California, San Francisco, described in: Kuntz et al. (1982) J. Mol. Biol. 161, 269-288.

### Experimental Assessment of Potential Inhibitors

Potential inhibitors may be assessed experimentally for binding to the synthase and/or for their inhibitory action on the catalytic activity of the synthase. The potential inhibitors can be synthesized according to the methods or organic chemistry. Preferably, compounds from a database have been selected without remodelling, since their synthesis may already be known. In any event, the synthetic effort needed to find an inhibitor is greatly reduced by the achievements of this invention due to the preselection of promising inhibitors by the above methods. Binding of a potential inhibitor may be determined after contacting the potential inhibitor with the synthase. This may be done crystallographically by soaking a crystal of the synthase with the potential inhibitor or by cocrystallisation and determining the crystal structure of the complex. Preferably, binding may be measured in solution according to methods known in the art. More preferably, inhibition of the catalytic activity of the synthase by the inhibitor is determined e.g. using the assays described in the examples section.

The activity of the synthase may be measured by determining the consumption of 4-diphosphocytidyl-2C-methyl-D-erythritol 2-phosphate and/or formation of 2C-methyl-D-erythritol 3,4-cyclopyrophosphate. Alternatively, consumption of 4-diphosphocytidyl-2C-methyl-D-erythritol and/or production of 2C-methyl-D-erythritol 3,4-cyclomonophosphate may be determined. The measurement may be carried out either directly with the reaction mixture or after the separation of the reaction mixture by chromatography, such as HPLC. The reaction should preferably be carried out at a pH of 5.5 to 9, preferably 7 to 8.5, in the presence of Mn²⁺ or Mg²⁺. Extra zinc may also be added. The temperature is preferably in the range of ±10° C. from the optimum temperature. The start of this reaction can be timed by the addition of the last of the essential components e.g. the synthase or substrate. The reaction can be stopped by methanol, chelating agents, like EDTA or acids like trichloro acetic acid. The activity of the synthase may be expressed as the amount of substrate comsumed or product produced in a specified period of time and under specified conditions. It may be advantageous to label the substrate by 32-phosphorous, 14-carbon, 13-carbon, deuterium or tritium in order to measure substrate consumption or product formation by a radio detector. These labeling types may be used alone or in any combination. Preparation of labeled substrates and their use in activity assays is described in detail in WO 01/11055.

Inhibition by potential inhibitor may be determined by repeating an activity assay in the presence of a predetermined concentration of a potential inhibitor and comparing the obtained activities of the synthase. An inhibitor may be tested at several different concentrations. Further, the type of inhibition e.g. competitive, non-competitive, un-competitive or irreversible may be determined according to known methods. Assays are known from WO 01/11055.

The asymmetric unit of the crystal of space group I2(1)3 of this invention contains one monomer of the synsthase. The functional trimer which is also present in solution is generated by the symmetry operations (x,y,z), (y,z,x) and (z,x,y). Therefore three substrate binding sites/active sites are present in the trimer. Two subunits contribute to each substrate binding site.

The invention will now be described in detail with reference to specific examples.

### EXAMPLE 1

### Production of an Expression Clone and Construction of an Expression Vector for the Expression of 2C-methyl-D-erythritol 2,4-cyclodiphosphate synthase (IsPF)

The E. coil ORF ispF (accession no. gb AE000358) from bp position 6231 to 6754 is amplified by PCR using chromosomal E. coli DNA as template. Chromosomal DNA from Escherichia coil strain XL1-Blue (Bullock et al. 1987; commercial source: Stratagene, LaJolla, Calif., USA) is isolated according to a method described by Meade et al., 1982.

The reaction mixture contains 10 pmol of the primer 5′-GAGAAGGATCCATGCGAATTGGACACGGTTTTGACG-3′, 10 pmol of the primer 5′-TATTATCTGCAGCCTTGCGGTTTACCGTGGAGG-3′, 20 ng of chromosomal DNA, 2 U of Taq DNA polymerase (Eurogentec, Seraing, Belgium) and 20 nmol of dNTPs in a total volume of 100 μl containing 1.5 mM MgCl₂, 50 mM KCl, 10 mM Tris-hydrochloride, pH 8.8 and 0.1% (w/w) Triton X-100.

The mixture is denaturated for 5 min at 94° C. Then 30 PCR cycles for 30 sec at 94° C., 45 sec at 50° C. and 45 sec at 72° C. followed. After further incubation for 7 min at 72° C., the mixture is cooled to 4° C. An aliquot of 2 μl is subjected to agarose gel electrophoresis.

The PCR amplificate is purified with the PCR purification kit from Qiagen (Hilden, Germany).

1.0 μg of the vector pQE30 (Qiagen) and 0.5 μg of the purified PCR product are digested in order to produce DNA fragments with overlapping ends. Each restriction mixture contains 10 μl of NEB3 buffer from New England Biolabs (NEB), 100 U of BamHI (NEB), 100 U of Pstl (NEB) in a total volume of 100 μl and is incubated for 3 h at 37° C. Digested vector DNA and PCR product are purified using the PCR purification kit from Qiagen.

20 ng of the vector DNA and 13 ng of the purified PCR product are ligated together with 1 U of T4-Ligase (Gibco), 2 μl of T4-Ligase buffer (Gibco) in a total volume of 10 μl, yielding the plasmid pQEispF. The ligation mixture is incubated for 2 h at 25° C. 1 μl of the ligation mixture is transformed into electrocompetent E. coli XL1-Blue cells according to a method described by Dower et al., 1988. The plasmid pQEispF is isolated with the plasmid isolation kit from Qiagen.

The DNA insert of the plasmid pQEispF is sequenced by the automated dideoxynucleotide method (Sanger et al., 1992) using an ABI Prism 377™ DNA sequencer from Perkin Elmer (Norwalk, USA) with the ABI Prism™ Sequencing Analysis Software from Applied Biosystems Divisions (Foster city, USA). It is identical with the DNA sequence of the database entry (gb AE000358). The 5′-end of the DNA insert carries the coding region for 6 histidine residues.

The DNA sequence and corresponding amino acid sequence of the ispF gene of E. coli are shown in FIG. 9.

### EXAMPLE 2

### Production of an Expression Clone and Construction of an Expression Vector for the Expression of the Site Directed 2C-methyl-D-erythritol 2,4-cycloditohosphate synthase mutant Asp8Ser

A DNA fragment containing the ispF gene carrying the D8S mutation is generated by PCR using the plasmid pQEispF as template (FIG. 9).

The reaction mixture contains 10 pmol of primer ispFD8S 5′-CCTGACGGATCCATGCGAATTGGACACGGTTTTTCAGTAC-3′, 10 pmol of the primer ispFhi 5′-TATCAACTGCAGTCATTTTGTTGCCTTAATGAG-3′, 2 ng of pQEispF DNA, 2 U of Taq DNA polymerase (Eurogentec, Seraing, Belgium) and 20 nmol of dNTPs in a total volume of 100 μl containing 1.5 mM MgCl₂, 50 mM KCl, 10 mM Tris-hydrochloride, pH 8.8 and 0.1% (w/w) Triton X-100.

The mixture is denaturated for 5 min at 94° C. Then 30 PCR cycles for 30 sec at 94° C., 45 sec at 50° C. and 45 sec at 72° C. follow. After further incubation for 7 min at 72° C., mixture is cooled to 4° C. An aliquot of 2 μl is subjected to agarose gel electrophoresis.

The PCR amplificate is purified with the PCR purification kit from Qiagen (Hilden, Germany). 1.0 μg of the vector pQE30 (Qiagen) and 0.5 μg of the purified PCR product are digested in order to produce DNA fragments with overlapping ends. Each restriction mixture contains 10 μl of NEB3 buffer from New England Biolabs (NEB), 100 U of BamHI (NEB), 100 U of Pstl (NEB) in a total volume of 100 μl and is incubated for 3 h at 37° C. Digested vector DNA and PCR product are purified using the PCR purification kit from Qiagen.

20 ng of the vector DNA and 12 ng of the purified PCR product are ligated together with 1 U of T4-Ligase (Gibco), 2 μl of T4-Ligase buffer (Gibco) in a total volume of 10 μl, yielding the plasmid pQEispFD8S. The ligation mixture is incubated for 2 h at 25° C. 1 μl of the ligation mixture is transformed into electrocompetent E. coli XL1-Blue cells. The plasmid pQEispFD8S is isolated with the plasmid isolation kit from Qiagen.

The DNA insert of the plasmid pQEispFDBS is sequenced and is found to be as expected (FIG. 9). The 5′-end of the DNA insert carries the coding region for 6 histidine residues.

### EXAMPLE 3

### Production of an Expression Clone and Construction of an Expression Vector for the Expression of the Site Directed 2C-methyl-D-erythritol 2,4-cyclodiphosphate synthase mutant His10Ser

A DNA fragment containing the ispF gene carrying the H10S mutation is generated by PCR using the plasmid pQEispF as template (FIG. 9).

The reaction mixture contains 10 pmol of primer ispFH10S 5′-CCTGACGGATCCATGCGAATTGGACACGGTTTTGACGTATCGGCCTTTGG-3′, 10 pmol of the primer ispFhi 5′-TATCAACTGCAGTCATTTTGTTGCCTTAATGAG-3′, 2 ng of pQEispF DNA, 2 U of Taq DNA polymerase (Eurogentec, Seraing, Belgium) and 20 nmol of dNTPs in a total volume of 100 μl containing 1.5 mM MgCl₂, 50 mM KCl, 10 mM Tris-hydrochloride, pH 8.8 and 0.1% (w/w) Triton X-100.

The mixture is denaturated for 5 min at 94° C. Then 30 PCR cycles for 30 sec at 94° C., 45 sec at 50° C. and 45 sec at 72° C. follow. After further incubation for 7 min at 72° C., the mixture is cooled to 4° C. An aliquot of 2 μl is subjected to agarose gel electrophoresis.

The PCR amplificate is purified with the PCR purification kit from Qiagen.

1.0 μg of the vector pQE30 (Qiagen) and 0.5 μl of the purified PCR product are digested in order to produce DNA fragments with overlapping ends. Each restriction mixture contains 10 μl of NEB3 buffer from New England Biolabs (NEB), 100 U of BamHI (NEB), 100 U of Pstl (NEB) in a total volume of 100 μl and is incubated for 3 h at 37° C. Digested vector DNA and PCR product are purified using the PCR purification kit from Qiagen.

20 ng of the vector DNA and 12 ng of the purified PCR product are ligated together with 1 U of T4-Ligase (Gibco), 2 μl of T4-Ligase buffer (Gibco) in a total volume of 10 μl, yielding the plasmid pQEispFH10S. The ligation mixture is incubated for 2 h at 25° C. 1 μl of the ligation mixture is transformed into electrocompetent E. coli XL1-Blue cells. The plasmid pQEispFH10S is isolated with the plasmid isolation kit from Qiagen.

The DNA insert of the plasmid pQEispFH10S is sequenced and is found to be as expected (FIG. 9). The 5′-end of the DNA insert carries the coding region for 6 histidine residues.

### EXAMPLE 4

### Production of an Expression Clone and Construction of an Expression Vector for the Expression of the Site Directed 2C-methyl-D-erythritol 2,4-cyclodiphosphate synthase mutant His42Ser

A DNA fragment containing the ispF gene carrying the H42S mutation is generated by PCR using the plasmid pQEispF as template (FIG. 9).

The reaction mixture contains 10 pmol of primer ispFH42S 5′-CGCATTCCTTACGAAAAAGGATTGCTGGCGCATTCTGATGGCGACGTGGCGCTCTCTGCGTTG-3′, 10 pmol of the primer ispFhi 5′-TATCAACTGCAGTCATTTTGTTGCCTTAATGAG-3′, 2 ng of pQEispF DNA, 2 U of Taq DNA polymerase (Eurogentec, Seraing, Belgium) and 20 nmol of dNTPs in a total volume of 100 μl containing 1.5 mM MgCl₂, 50 mM KCl, 10 mM Tris-hydrochloride, pH 8.8 and 0.1% (w/w) Triton X-100.

The mixture is denaturated for 5 min at 94° C. Then 30 PCR cycles for 30 sec at 94° C., 45 see at 50° C. and 45 sec at 72° C. follow. After further incubation for 7 min at 72° C., the mixture is cooled to 4° C. An aliquot of 2 μl is subjected to agarose gel electrophoresis.

The PCR amplificate is purified with the PCR purification kit from Qiagen.

The PCR amplificate is used as template for a second PCR reaction. The reaction mixture contained 25 pmol of primer is pFuni2 5′-GCCTTTGGCGGTGAAGGCCCAATTATCATTGGTGGCGTACGCATTCCTTACGAAAAAGG-3′, 25 pmol of primer ispFhi 5′-TATCAACTGCAGTCATTTTGTTGCCTTAATGAG-3′, 2 μl, of the first PCR amplification, 2U of Taq DNA polymerase (Eurogentec, Seraing, Belgium) and 20 nmol of dNTPs in a total volume of 100 μl containing 1.5 mM MgCl₂, 50 mM KCl, 10 mM Tris-hydrochloride, pH 8.8 and 0.1% (w/w) Triton X-100.

The mixture is denaturated for 3 min at 95° C. Then 40 PCR cycles for 45 sec at 94° C., 45 sec at 50° C. and 60 sec at 72° C. follow. After further incubation for 20 min at 72° C., the mixture cooled to 4° C. An aliquot of 2 μl is subjected to agarose gel electrophoresis. An aliquot of 2 μl is subjected to agarose gel electrophoresis.

The PCR amplificate is purified with the PCR purification kit from Qiagen.

The PCR amplificate is used as template for a second PCR reaction. The reaction mixture contained 25 pmol of primer is pFuni1 5′-CCTGACGGATCCATGCGAATTGGACACGGTTTTGACGTACATGCCTTTGGCGGTGAA-3′, 25 pmol of primer ispFhi 5′-TATCAACTGCAGTCATTTTGTTGCCTTAATGAG-3′, 2 μl of the second PCR amplification, 2U of Taq DNA polymerase (Eurogentec, Seraing, Belgium) and 20 nmol of dNTPs in a total volume of 100 μl containing 1.5 mM MgCl₂, 50 mM KCl, 10 mM Tris-hydrochloride, pH 8.8 and 0.1% (w/w) Triton X-100.

The mixture is denaturated for 3 min at 95° C. Then 40 PCR cycles for 45 sec at 94° C., 45 sec at 50° C. and 60 sec at 72° C. follow. After further incubation for 20 min at 72° C., the mixture is cooled to 4° C. An aliquot of 2 μl is subjected to agarose gel electrophoresis. An aliquot of 2 μl is subjected to agarose gel electrophoresis.

The PCR amplificate is purified with the PCR purification kit from Qiagen.

1.0 μg of the vector pQE30 (Qiagen) and 0.5 μg of the purified PCR product are digested in order to produce DNA fragments with overlapping ends. Each restriction mixture contains 10 μl of NEB3 buffer from New England Biolabs (NEB), 100 U of BamHI (NEB), 100 U of Pstl (NEB) in a total volume of 100 μl and is incubated for 3 h at 37° C. Digested vector DNA and PCR product are purified using the PCR purification kit from Qiagen.

20 ng of the vector DNA and 12 ng of the purified PCR product are ligated together with 1 U of T4-Ligase (Gibco), 2 μl of T4-Ligase buffer (Gibco) in a total volume of 10 μl, yielding the plasmid pQEispFH42S. The ligation mixture is incubated for 2 h at 25° C. 1 μl of the ligation mixture is transformed into electrocompetent E. coli XL1-Blue cells. The plasmid pQEispFH42S is isolated with the plasmid isolation kit from Qiagen.

The DNA insert of the plasmid pQEispFH42S is sequenced and is found to be as expected (FIG. 9). The 5′-end of the DNA insert carries the coding region for 6 histidine residues.

### EXAMPLE 5

### Determination of 2C-methyl-D-erythritol 2,4-cyclodiphosphate synthase activity

Assay mixtures contain 50 mM potassium phosphate, pH 7.0, 2 mM DTT, 2 mM MgCl₂, 1 mM 4-diphosphocytidyl-2C-methyl-D-erythritol 2-phosphate and protein in a total volume of 100 μl. The mixtures are incubated at 37° C. for 20 min. The reactions are terminated by adding EDTA at a final concentration of 4 mM. The samples are centrifuged and the supernatant is analyzed by HPLC using a column of Multospher 120 RP 18-AQ-5 (4.6×250 mm, CS-Chromatographic Service Gmbh) that has been equilibrated and run with Gradient No. 3 at a flow rate 1 ml min⁻¹ (see below). The effluent is monitored photometrically (270 nm).

One unit of 2C-methyl-D-erythritol 2,4-cyclodiphosphate synthase activity is defined as the amount of protein which produced 1 μmol min⁻¹ of CMP.

Column: Multospher 120 RP 18-5 AQ, 250×4.6 mm, particle size 5 μm (CS: Chromatographic Service GmbH, Langerwehe, Germany)

| | | |
|---|---|---|
| Mobile phase: | Eluent A | 10 mM TBAS in distilled H₂O |
| | Eluent B | 10 mM TBAS in 70% (v/v) Methanol |

Gradient No.3

| Time (min) | A[%] | B[%] |
|---|---|---|
| 0 | 100 | 0 |
| 20 | 40 | 60 |
| 25 | 0 | 100 |
| 26 | 100 | 0 |
| 30 | 100 | 0 |

### EXAMPLE 6

### Purification of 2C-methyl-D-erythritol 2,4-cyclodiphosphate synthase and Site-directed Mutants Thereof

The procedure described herein is used for the purification of 2C-methyl-D-erythritol 2,4-cyclodiphosphate synthase and the site directed mutant proteins DBS, H10S and H42S.

Cells of the recombinant E. coli strain XL1-pQEispF (7.3 g) are suspended in 35 ml of standard buffer (20 mM potassium phosphate pH 7.0, 0.5 M NaCl) containing 20 mM imidazole. Cell extract is performed by ultrasonication. The suspension is centrifuged at 16,000 rpm for 30 min. The supernatant was collected. The cell extract (806 mg) was loaded on top of a Ni²⁺-Chelating Sepharose column (1.6×6.0 cm, Amersham Pharmacia Biotech) which has been equilibrated with 20 mM imidazole in standard buffer at a flow rate of 3 ml min⁻¹. The column is washed with 100 ml of 20 mM imidazole in standard buffer. The enzyme is eluted by a linear gradient of 20-500 mM imidazole in buffer D (total volume 300 ml). The enzyme is eluted at 100-200 mM imidazole. Fractions are combined according to SDS-PAGE. The 2C-methyl-D-erythritol 2,4-cyclodiphosphate synthase protein migrates as a single band at a molecular mass of about 17 kDa. The pooled fractions are desalted on HiPrep desalting column (size 2.6×10 cm, Amersham Pharmacia Biotech) at a flow rate of 5 ml min⁻¹. The protein is eluted at a volume of 15 ml. Protein fractions are pooled.

### EXAMPLE 7

### Flame Atomic Absorption Spectrometry (Flame-AAS) of 2C-methyl-D-erythritol 2,4-cyclodiphosphate synthase and Site-directed Mutants Thereof

The protein mixture is diluted with water and 6 M HCl to a final concentration of 200 nM and a final concentration of 2 M. The aqueous solution is then incubated at 90° C. for 5 hours. 2 ml of this solution per measurement are then taken up by an Unicam 91.9 Flame-AAS. For the acquiration of one datapoint usually 3 measurments are averaged. To determine the background emission of amino acids, a peptone solution has been prepared and measured using similar procedures.

### EXAMPLE 8

Crystallization of 2C-methyl-D-erythritol 2,4-cyclodiphosphate synthase

The protein solution contains 20 mM potassium phosphate pH 7.0 and 10 mg ml⁻¹ of purified recombinant 2C-methyl-D-erythritol 2,4-cyclodiphosphate synthase from recombinant E. coli. This solution is then applied onto a crystallization plate (CCLEAR-D/1, Douglas instruments, UK) and mixed 1:1 with a crystallization buffer containing 0.1 M HEPES pH 7.5 and 2 M ammonium formate. This mixture is then supported with ten times of volume of a base buffer, similar to the precipitation buffer. The crystallization plate is then sealed with Crystal-Clear® tape and stored in a climate regulated room.

Micro and macro seeding techniques were then employed in order to produce more crystals.

### EXAMPLE 9

### Cryo-protection and Freezing of Crystals and Data Collection

Crystals containing the synthase and zinc were incubated for one hour with about 5 mM of a ligand in mother liquor containing 2M ammonium formate, 0.1M HEPES/NaOH at pH 7.0 and 20% D-(−)-2,3-butanediole (purchased from FLUKA) as a cryo-protectant. Crystals were mounted in a nylon-loop and flash frozen in a stream of nitrogen at 100Kelvin with an Oxford cryo stream. The quality of the crystals was not reduced by freezing and the mosaicity was only slightly increased from about 0.3° to 0.5°. Diffraction data were measured at that temperature without any indication of radiation damage.

### EXAMPLE 10

### Soaking of 2C-methyl-D-erythritol 2,4-cyclodiphosphate synthase crystals with Mg-CDP

In order to obtain a crystal structure of 2C-methyl-D-erythritol 2,4-cyclodiphosphate synthase in complex with CDP, the synthase was crystallized according to example 8. A crystal of suitable size was then soaked in crystallization buffer (see example 8) further containing 5 mM CDP and 5 mM MgCl₂.

### EXAMPLE 11

### Structure Solution of 2C-methyl-D-erythritol 2,4-cyclodiphosphate synthase

2C-methyl-D-erythritol 2,4-cyclodiphosphate synthase was crystallized in the cubic space group I2(1)3 with a=144.15 Å. A native data set was collected on a rotating anode generator equipped with an MARresearch Image Plate detector at room temperature. The overall R_{marge} was 7.4% in the resolution range 20.0 to 2.85 Å and 40.1% in the outermost resolution shell. These date were 99.7% complete with a mean redundancy of 4.3 (Table 1). For structure solution a crystal was incubated with 2 mM mercury-(II)-acetate in mother liquor for one hour yielding an isomorphous derivative with a single heavy atom binding site in the asymmetric unit. The isomorphous difference was 25.3% in the resolution range 25.0 to 3.6 Å. This derivative was interpreted with the program SHELXS (Sheldrick et al., 1993). Heavy atom parameters were refined and phases calculated with the program MLPHARE (Collaborative Computational Project No. 4, 1994). The phasing power was 1.0 (25 to 3.6 Å) with a figure of merit of 0.27. Phases were improved by solvent flattening using the program DM (Collaborative Computational Project No. 4, 1994) along with phase extension. An atomic model was built with the program MAIN (Turk, 1992) and refined with the program XPLOR (Brünger et al., 1998). The model comprises residues Met1 to Ile155. The electron density is continuous throughout the model with the exception of a short break between Phe61 and Pro62 in a loop structure comprising Phe61 to Lys69. Refinement data and statistics are given in Table 1.

### EXAMPLE 12

### Structure Solution of 2C-methyl-D-erythritol 2,4-cyclodiphosphate synthase in Complex with CDP

The starting model for the determination of the structure of the complex was the structure of the synthase without a substrate analoge. Initially a rigid body refinement of the starting model using F_{obs} from a crystal cocrystallized with CDP was carried out followed by several cycles of positional refinement with X-PLOR against the new F_{obs}. In electron density maps, the elongated structure of CDP was discernible and was modeled into the density. After further refinement cycles, a spherical electron density was found in coordinating distance to the phosphate groups of CDP and was interpreted as a magnesium ion.

### EXAMPLE 13

### Screening for 2C-methyl-D-erythritol 2,4-cyclodiohosphate synthase activity

Synthase activity is screened for by a radiochemical method. Assay mixtures contained 100 mM tris hydrochloride pH 8.0, 10 mM MnCl₂, 14 nCi of [2-¹⁴C]4-diphosphocytidyl-2C-methyl-D-erythritol and 2 μg of the synthase from recombinant E. coli. They are incubated at 37° C. for 30 min. After centrifugation, aliquots are spotted on Sil-NHR thin layer plates which are developed with a mixture of n-propanollethyl acetate/H₂O (6:1:3, v/v). The radiochromatogram is monitored and evaluated by Phosphor Imager (Storm 860, Molecular Dynamics,USA). The R_{f} value of the synthase product is 0.5. This screening method can be carried out in the presence or absence of prospective inhibitors.

### Screening of Synthase Activity by NMR

A solution containing 100 mM Tris HCl pH 8.0, 10 mM MnCl₂, 5 mM of 4-diphosphocytidyl-2C-methyl-D-erythritol and 0.1 mg of synthase from recombinant E. coli are incubated at 37° C. for 1 h. The reaction is monitored by ³¹P-NMR. ³¹P-NMR spectra are recorded using a AC 250 spectrometer from Bruker at a transmitter frequency of 101.3 MHz. The chemical shifts are referenced to external 85% H₃PO₄. The screening method is carried out in the presence or absence of prespective inhibitors by measuring the residual starting material and comparing the results.

The product 2C-methyl-D-erythritol 3,4-cyclomonophosphate displays one ³¹P singlet at +21.7 (see WO 01/11055 for an NMR characterization of this product). Synthase activity can therefore also be determined by measuring this signal for determining the amount of product.

### Literature

Brünger, A. T., Adams, P. D., Clore, G. M., DeLano, W. L., Gros, P., Grosse-Kunstleve, R. W., Jiang, J. S., Kuszewski, J., Nilges, M., Pannu, N. S., Read, R. J., Rice, L. M., Simonson, T. & Warren, G. L. (1998). Crystallography & NMR system: A new software suite for macromolecular structure determination. Acta Crystallogr. D54, 905-921.

Bullock, W. O.; Fernandez, J. M., & Short, J. M. (1987). XL1-Blue: a high efficiency plasmid transforming recA Escherichia coli with β-galactosidase selection. BioTechniques 5, 376-379.

Chook, Y. M., Ke, H. & Lipscomb, W. N. (1993). Crystal structures of the monofunctional chorismate mutase from Bacillus subtilis and its complex with a transition state analog. Proc. Natl. Acad. Sci. USA 90, 8600-8603.

Collaborative Computational Project No. 4. (1994). The CCP4 suite: programs for protein crystallography. Acta Crystalogr. D50, 760-763.

Dower, W. J., Miller, J. F., & Ragsdale, C. (1988) High efficiency transformation of E. coli by high voltage, electroporation. Nucleic Acids Res. 16, 6127-6145.

Frishman, D. & Argos, P. (1995). Knowledge-based protein secondary structure assignment. Proteins 23, 566-579.

Herz, S., Wungsintaweekul, J., Schuhr, C. A., Hecht, S., Lüttgen, H., Sagner, S., Fellermeier, M., Eisenreich, W., Zenk, M. H., Bacher, A. & Rohdich, F. (2000). Biosynthesis of terpenoids: YgbB protein converts 4-diphosphocytidyl-2C-methyl-D-erythritol 2-phosphate to 2C-methyl-D-erythritol 2,4-cyclodiphosphate. Proc. Natl. Acad. Sci. USA 97, 2486-2490.

Laskowski, R. A., MacArthur, M. W., Moss, D. S. & Thornton, J. M. (1993). PROCHECK: a program to check the stereochemical quality of protein structures. J. Appl. Crystallogr. 26, 283-291.

Li, C., Kappock, T. J., Stubbe, J., Weaver, T. M. & Ealick, S. E. (1999). X-ray crystal structure of aminoimidazole ribonucleotide synthetase (Purm), from the Escherichia coli purine biosynthetic pathway at 2.5 A Resolution. Structure 7, 1155-166.

Lüttgen, H., Rohdich, F., Herz, S., Wungsintaweekul, J., Hecht, S., Schuhr, C. A, Fellermeier, M., Sagner, S., Zenk, M. H., Bacher, A. & Eisenreich, W. (2000). Biosynthesis of terpenoids: YchB protein of Escherichia Coli phosphorylates the 2-hydroxy group of 4-diphosphocytidyl-2C-methyl-D-erythritol. Proc. Natl. Acad. Sci. USA 97, 1062-1067.

Meade, H. M., Long, S. R., Ruvkun, C. B., Brown, S. E., & Auswald, F. M. (1982). Physical and genetic characterization of symbiotic and auxotrophic mutants of Rhizobium meliloti induced by transposon Tn5 mutagenis. J. Bacteriol. 149, 114-122.

Muchmore, C. R., Krahn, J. M., Kim, J. H., Zalkin, H. & Smith, J. L. (1998). Crystal structure of glutamine phosphoribosylpyrophosphate amidotransferase from Escherichia coli. Protein Science 7, 39-51.

Rohdich, F., Wungsintaweekul, J., Fellermeier, M., Sagner, S., Herz, S., Kis, K., Eisenreich, W., Bacher, A & Zenk, M. H. (1999). Cytidine 5′-triphosphate biosynthesis of isoprenoids: YgbP protein of Escherichia coli catalyzes the formation of 4-diphosphocytidyl-2C-methylerythritol. Proc. Natl. Acad. Sci. USA 96, 11758-11763.

Sanger, F., Nicklen, S., & Coulson, A. R. (1992). DNA sequencing with chain-terminating inhibitors. 1977. Biotechnology 24, 104-8.

Sheldrick, G. M., Dauter, Z., Wilson, K. S., Hope, H. & Sieker, L. C. (1993). The application of direct methods of patterson interpretation to high-resolution native protein data. Acta Crystallogr. D49, 18-23.

Subramanya, H. S., Roper, D. I., Dauter, Z., Dodson, E. J., Davies, G. J., Wilson, K. S. & Wigley, D. B. (1996). Enzymatic ketonization of 2-hydroxymuconate: specificity and mechanism investigated by the crystal structures of two isomerases. Biochemistry 35, 792-802.

Turk, D. (1992). Weiterentwicklung eines Programms für Molekülgraphik und Elektronendichte-Manipulation und seine Anwendung auf verschiedene Protein-Strukturaufklärungen, TU München.

Unge, J., Berg, A., Al-Kharadaghi, S., Nikulin, A., Nikonov, S., Davydova, N., Nevskaya, N., Garber, M. & Liljas, A. (1998). The crystal structure of ribosomal protein L22 from Thermus thermophilus: insights into the mechanism of erythromycin resistance. Structure 6, 1577-1586.

Volz, K. (1999). A test case for structure-based functional assignment: The 1.2 Å crystal structure of the yjgF gene product from Escherichia coli. Protein Science 8, 2428-2437. Xiang, S., Short, S. A., Wolfenden, R. & Carter, R. C. (1995). Transition-state selectivity for a single hydroxyl group during catalysis by cytidine deaminase. Biochemistry 34(34), 4516-4523.

TABLE 1
Statistics for data collection and refinement

| Crystal | nat2 | mgcdp2 | subop | subs | sub2 | cyt |
|---|---|---|---|---|---|---|
| Data collection | | | | | | |
| Cell constant a (Å) | 144.15 | 144.66 | 144.81 | 145.01 | 144.63 | 144.70 |
| (a = b = c, α = β = γ = 90°) | | | | | | |
| Resolution range (Å) | 20 to 2.85 | 25 to 2.5 | 20 to 2.8 | 20 to 3.2 | 25 to 2.5 | 25 to 2.9 |
| Reflections observed | 49159 | 54965 | 46385 | 20929 | 66701 | 31246 |
| Unique reflections | 11403 | 17015 | 12586 | 8183 | 17106 | 10634 |
| R_{merge}^{a} overall (%) | 7.4 | 6.4 | 7.5 | 10.6 | 6.3 | 6.7 |
| R_{merge}^{a} outermost shell (%) | 40.1 | 39.4 | 42.6 | 44.6 | 40.9 | 37.7 |
| Completeness overall (%) | 97.4 | 97.3 | 99.8 | 96.7 | 98.1 | 98.8 |
| Completeness outermost shell (%) | 99.7 | 97.1 | 99.9 | 96.4 | 99.8 | 99.0 |
| Temperature factor from Wilson plot (Å²) | 77.8 | 50.8 | 73.2 | 64.3 | 60.3 | 84.7 |

Refinement

| | | | | | | |
|---|---|---|---|---|---|---|
| Reflections used for refinement | 10861 | 16531 | 12023 | 7672 | 16521 | 10075 |
| (8.0Å to high resolution limit) | | | | | | |
| R value^{b} final model (%) | 22.6 | 24.0 | 23.3 | 20.6 | 20.1 | 22.1 |
| R_{free}^{c} value final model | 23.7 | 26.0 | 26.4 | 25.4 | 25.5 | 25.9 |

Rms deviations

| | | | | | | |
|---|---|---|---|---|---|---|
| bond lengths (Å) | 0.012 | 0.011 | 0.010 | 0.011 | 0.009 | 0.011 |
| bond angles (°) | 1.84 | 1.88 | 1.85 | 1.84 | 1.81 | 1.91 |
| dihedral angles (°) | 22.6 | 23.0 | 22.40 | 22.0 | 22.4 | 21.97 |
| improper angles (°) | 1.23 | 1.34 | 1.23 | 1.24 | 1.18 | 1.25 |
| Ramachandran-plot: residues in | | | | | | |
| most favoured: | 93.0 | 89.8 | 93.7 | 86.6 | 92.1 | 88.2 |
| additional allowed: | 6.3 | 10.2 | 6.3 | 13.4 | 7.1 | 11.0 |
| generously allowed: | 0.8 | 0.0 | 0.0 | 0.0 | 0.8 | 0.8 |
| disallowed: regions | 0.0 | 0.0 | 0.0 | 0.0 | 0.0 | 0.0 |
| RMSD for bond B restraints (Å²) | 2.85 | 2.7 | 2.8 | 2.6 | 2.3 | 2.9 |
| Temperature factors (Å²) | protein: | protein: 32.7 | protein: 38.4 | protein: 43.0 | protein: 36.1 | protein: 46.7 |
| | 41.5 | Zn: 36.9 | Zn: 46.5 | sub: 59.7 | Zn: 36.1 | Zn: 57.7 |
| | Zn: 51.3 | Mg: 50.2 | subs: 52.5 | | subs: 46.7 | cytidine: 43.2 |
| | | CDP: 32.0 | | | solvent: 54.5 (72 | |
| | | | | | water molecules) | |

^{a}R_{merge} = Σ(I − <I>)/ΣI
^{b}R= Σ(|F_{obs}| − |F_{calc}|)/Σ|F_{obs}|
^{c}R_{free} was calculated with 5% of the observed reflections which were omitted from the refinement and F-value calculation

TABLE 2
Coordinates of atoms within 10 Å of the bound ligands of structure sub2.

| | | | | | | | | | | |
|---|---|---|---|---|---|---|---|---|---|---|
| ATOM | 1360 | CE1 | PHE | 12 | 17.314 | 0.147 | 20.994 | 1.00 | 26.02 | A |
| ATOM | 1361 | CE2 | PHE | 12 | 15.489 | 1.232 | 19.888 | 1.00 | 24.00 | A |
| ATOM | 1362 | CZ | PHE | 12 | 16.272 | 1.061 | 21.014 | 1.00 | 25.64 | A |
| ATOM | 1397 | CG1 | ILE | 18 | 20.556 | −0.394 | 25.688 | 1.00 | 27.99 | A |
| ATOM | 1398 | CD1 | ILE | 18 | 19.431 | 0.531 | 25.327 | 1.00 | 30.35 | A |
| ATOM | 1411 | CB | ILE | 20 | 22.696 | 3.946 | 27.295 | 1.00 | 28.08 | A |
| ATOM | 1412 | CG2 | ILE | 20 | 22.445 | 5.441 | 27.168 | 1.00 | 27.99 | A |
| ATOM | 1413 | CG1 | ILE | 20 | 21.954 | 3.241 | 26.155 | 1.00 | 28.59 | A |
| ATOM | 1414 | CD1 | ILE | 20 | 22.281 | 3.779 | 24.767 | 1.00 | 27.82 | A |
| ATOM | 1445 | CB | ILE | 25 | 20.290 | −0.580 | 29.494 | 1.00 | 25.24 | A |
| ATOM | 1446 | CG2 | ILE | 25 | 18.791 | −0.553 | 29.629 | 1.00 | 24.77 | A |
| ATOM | 1447 | CG1 | ILE | 25 | 20.949 | 0.529 | 30.311 | 1.00 | 23.49 | A |
| ATOM | 1448 | CD1 | ILE | 25 | 20.596 | 1.911 | 29.856 | 1.00 | 20.35 | A |
| ATOM | 1461 | CG | TYR | 27 | 15.844 | −2.675 | 24.571 | 1.00 | 33.62 | A |
| ATOM | 1462 | CD1 | TYR | 27 | 14.609 | −2.362 | 25.134 | 1.00 | 31.53 | A |
| ATOM | 1463 | CE1 | TYR | 27 | 13.612 | −1.753 | 24.380 | 1.00 | 33.64 | A |
| ATOM | 1464 | CD2 | TYR | 27 | 16.057 | −2.363 | 23.227 | 1.00 | 34.10 | A |
| ATOM | 1465 | CE2 | TYR | 27 | 15.066 | −1.756 | 22.466 | 1.00 | 33.94 | A |
| ATOM | 1466 | CZ | TYR | 27 | 13.847 | −1.455 | 23.047 | 1.00 | 33.03 | A |
| ATOM | 1467 | OH | TYR | 27 | 12.858 | −0.869 | 22.289 | 1.00 | 35.70 | A |
| ATOM | 1983 | C | VAL | 96 | 21.845 | 14.549 | 28.317 | 1.00 | 21.82 | A |
| ATOM | 1984 | O | VAL | 96 | 21.189 | 14.496 | 29.359 | 1.00 | 23.75 | A |
| ATOM | 1985 | N | THR | 97 | 21.290 | 14.431 | 27.117 | 1.00 | 21.11 | A |
| ATOM | 1986 | CA | THR | 97 | 19.863 | 14.200 | 26.948 | 1.00 | 22.07 | A |
| ATOM | 1987 | CB | THR | 97 | 19.179 | 15.407 | 26.293 | 1.00 | 24.54 | A |
| ATOM | 1988 | OG1 | THR | 97 | 19.487 | 16.595 | 27.038 | 1.00 | 29.07 | A |
| ATOM | 1989 | CG2 | THR | 97 | 17.668 | 15.215 | 26.256 | 1.00 | 20.95 | A |
| ATOM | 1990 | C | THR | 97 | 19.686 | 13.013 | 26.021 | 1.00 | 24.03 | A |
| ATOM | 1991 | O | THR | 97 | 20.013 | 13.111 | 24.836 | 1.00 | 24.95 | A |
| ATOM | 1992 | N | ILE | 98 | 19.245 | 11.884 | 26.575 | 1.00 | 24.06 | A |
| ATOM | 1993 | CA | ILE | 98 | 18.998 | 10.659 | 25.809 | 1.00 | 25.64 | A |
| ATOM | 1994 | CB | ILE | 98 | 19.161 | 9.419 | 26.687 | 1.00 | 26.46 | A |
| ATOM | 1995 | CG2 | ILE | 98 | 18.879 | 8.155 | 25.886 | 1.00 | 24.22 | A |
| ATOM | 1996 | CG1 | ILE | 98 | 20.574 | 9.391 | 27.266 | 1.00 | 27.56 | A |
| ATOM | 1997 | CD1 | ILE | 98 | 20.727 | 8.445 | 28.417 | 1.00 | 27.49 | A |
| ATOM | 1998 | C | ILE | 98 | 17.566 | 10.710 | 25.280 | 1.00 | 26.81 | A |
| ATOM | 1999 | O | ILE | 98 | 16.619 | 10.966 | 26.029 | 1.00 | 30.64 | A |
| ATOM | 2000 | N | ILE | 99 | 17.404 | 10.485 | 23.990 | 1.00 | 25.35 | A |
| ATOM | 2001 | CA | ILE | 99 | 16.090 | 10.556 | 23.381 | 1.00 | 24.37 | A |
| ATOM | 2002 | CB | ILE | 99 | 16.123 | 11.510 | 22.165 | 1.00 | 23.31 | A |
| ATOM | 2003 | CG2 | ILE | 99 | 14.762 | 11.632 | 21.538 | 1.00 | 23.17 | A |
| ATOM | 2004 | CG1 | ILE | 99 | 16.589 | 12.898 | 22.614 | 1.00 | 23.59 | A |
| ATOM | 2005 | CD1 | ILE | 99 | 17.147 | 13.748 | 21.512 | 1.00 | 19.94 | A |
| ATOM | 2006 | C | ILE | 99 | 15.718 | 9.150 | 22.968 | 1.00 | 25.25 | A |
| ATOM | 2007 | O | ILE | 99 | 16.213 | 8.637 | 21.964 | 1.00 | 24.57 | A |
| ATOM | 2008 | N | ALA | 100 | 14.875 | 8.515 | 23.773 | 1.00 | 26.25 | A |
| ATOM | 2009 | CA | ALA | 100 | 14.447 | 7.152 | 23.509 | 1.00 | 26.65 | A |
| ATOM | 2010 | CB | ALA | 100 | 15.436 | 6.183 | 24.119 | 1.00 | 25.30 | A |
| ATOM | 2011 | C | ALA | 100 | 13.049 | 6.870 | 24.051 | 1.00 | 29.75 | A |
| ATOM | 2012 | O | ALA | 100 | 12.674 | 7.339 | 25.130 | 1.00 | 30.24 | A |
| ATOM | 2013 | N | GLN | 101 | 12.273 | 6.121 | 23.274 | 1.00 | 30.65 | A |
| ATOM | 2014 | CA | GLN | 101 | 10.922 | 5.731 | 23.661 | 1.00 | 30.21 | A |
| ATOM | 2015 | CB | GLN | 101 | 10.203 | 5.140 | 22.438 | 1.00 | 31.90 | A |
| ATOM | 2016 | CG | GLN | 101 | 8.685 | 5.058 | 22.545 | 1.00 | 32.46 | A |
| ATOM | 2017 | CD | GLN | 101 | 8.035 | 6.409 | 22.794 | 1.00 | 34.14 | A |
| ATOM | 2018 | OE1 | GLN | 101 | 7.104 | 6.518 | 23.588 | 1.00 | 36.30 | A |
| ATOM | 2019 | NE2 | GLN | 101 | 8.524 | 7.445 | 22.118 | 1.00 | 34.90 | A |
| ATOM | 2020 | C | GLN | 101 | 11.073 | 4.672 | 24.761 | 1.00 | 30.27 | A |
| ATOM | 2021 | O | GLN | 101 | 10.335 | 4.650 | 25.759 | 1.00 | 32.28 | A |
| ATOM | 2022 | N | ALA | 102 | 12.059 | 3.805 | 24.564 | 1.00 | 28.45 | A |
| ATOM | 2023 | CA | ALA | 102 | 12.383 | 2.732 | 25.491 | 1.00 | 27.28 | A |
| ATOM | 2024 | CB | ALA | 102 | 11.431 | 1.578 | 25.299 | 1.00 | 24.64 | A |
| ATOM | 2025 | C | ALA | 102 | 13.802 | 2.311 | 25.137 | 1.00 | 27.53 | A |
| ATOM | 2026 | O | ALA | 102 | 14.233 | 2.488 | 23.997 | 1.00 | 28.45 | A |
| ATOM | 2027 | N | PRO | 103 | 14.528 | 1.689 | 26.077 | 1.00 | 28.94 | A |
| ATOM | 2028 | CD | PRO | 103 | 15.838 | 1.074 | 25.767 | 1.00 | 27.65 | A |
| ATOM | 2029 | CA | PRO | 103 | 14.089 | 1.364 | 27.440 | 1.00 | 27.92 | A |
| ATOM | 2030 | CB | PRO | 103 | 15.084 | 0.287 | 27.858 | 1.00 | 27.03 | A |
| ATOM | 2031 | CG | PRO | 103 | 16.348 | 0.674 | 27.110 | 1.00 | 26.85 | A |
| ATOM | 2032 | C | PRO | 103 | 14.092 | 2.572 | 28.376 | 1.00 | 29.67 | A |
| ATOM | 2033 | O | PRO | 103 | 14.400 | 3.686 | 27.957 | 1.00 | 32.19 | A |
| ATOM | 2034 | N | LYS | 104 | 13.674 | 2.372 | 29.619 | 1.00 | 30.26 | A |
| ATOM | 2035 | CA | LYS | 104 | 13.647 | 3.451 | 30.600 | 1.00 | 30.53 | A |
| ATOM | 2036 | CB | LYS | 104 | 12.811 | 3.028 | 31.806 | 1.00 | 33.62 | A |
| ATOM | 2037 | CG | LYS | 104 | 12.137 | 4.173 | 32.536 | 1.00 | 40.28 | A |
| ATOM | 2038 | CD | LYS | 104 | 11.063 | 4.806 | 31.664 | 1.00 | 46.67 | A |
| ATOM | 2039 | CE | LYS | 104 | 10.471 | 6.080 | 32.281 | 1.00 | 51.22 | A |
| ATOM | 2040 | NZ | LYS | 104 | 9.581 | 6.794 | 31.291 | 1.00 | 54.74 | A |
| ATOM | 2041 | C | LYS | 104 | 15.093 | 3.710 | 31.027 | 1.00 | 31.13 | A |
| ATOM | 2042 | O | LYS | 104 | 15.796 | 2.795 | 31.450 | 1.00 | 31.65 | A |
| ATOM | 2043 | N | MET | 105 | 15.539 | 4.954 | 30.928 | 1.00 | 30.78 | A |
| ATOM | 2044 | CA | MET | 105 | 16.908 | 5.289 | 31.276 | 1.00 | 28.60 | A |
| ATOM | 2045 | CB | MET | 105 | 17.417 | 6.414 | 30.381 | 1.00 | 27.58 | A |
| ATOM | 2046 | CG | MET | 105 | 17.337 | 6.123 | 28.911 | 1.00 | 27.10 | A |
| ATOM | 2047 | SD | MET | 105 | 18.378 | 4.738 | 28.465 | 1.00 | 29.30 | A |
| ATOM | 2048 | CE | MET | 105 | 17.915 | 4.476 | 26.749 | 1.00 | 23.71 | A |
| ATOM | 2049 | C | MET | 105 | 17.090 | 5.716 | 32.711 | 1.00 | 29.67 | A |
| ATOM | 2050 | O | MET | 105 | 18.133 | 5.468 | 33.303 | 1.00 | 31.16 | A |
| ATOM | 2051 | N | LEU | 106 | 16.066 | 6.334 | 33.280 | 1.00 | 31.18 | A |
| ATOM | 2052 | CA | LEU | 106 | 16.139 | 6.866 | 34.642 | 1.00 | 32.29 | A |
| ATOM | 2053 | CB | LEU | 106 | 14.751 | 7.321 | 35.122 | 1.00 | 34.54 | A |
| ATOM | 2054 | CG | LEU | 106 | 14.705 | 8.141 | 36.423 | 1.00 | 36.02 | A |
| ATOM | 2055 | CD1 | LEU | 106 | 15.605 | 9.371 | 36.341 | 1.00 | 36.26 | A |
| ATOM | 2056 | CD2 | LEU | 106 | 13.284 | 8.557 | 36.701 | 1.00 | 37.24 | A |
| ATOM | 2057 | C | LEU | 106 | 16.840 | 6.041 | 35.725 | 1.00 | 31.14 | A |
| ATOM | 2058 | O | LEU | 106 | 17.700 | 6.551 | 36.439 | 1.00 | 32.97 | A |
| ATOM | 2059 | N | PRO | 107 | 16.485 | 4.765 | 35.870 | 1.00 | 29.97 | A |
| ATOM | 2060 | CD | PRO | 107 | 15.406 | 4.003 | 35.222 | 1.00 | 29.86 | A |
| ATOM | 2061 | CA | PRO | 107 | 17.145 | 3.964 | 36.904 | 1.00 | 30.08 | A |
| ATOM | 2062 | CB | PRO | 107 | 16.344 | 2.663 | 36.880 | 1.00 | 29.81 | A |
| ATOM | 2063 | CG | PRO | 107 | 15.831 | 2.594 | 35.471 | 1.00 | 28.63 | A |
| ATOM | 2064 | C | PRO | 107 | 18.630 | 3.711 | 36.672 | 1.00 | 29.61 | A |
| ATOM | 2065 | O | PRO | 107 | 19.361 | 3.330 | 37.590 | 1.00 | 31.63 | A |
| ATOM | 2066 | N | HIS | 108 | 19.075 | 3.917 | 35.444 | 1.00 | 29.45 | A |
| ATOM | 2067 | CA | HIS | 108 | 20.468 | 3.685 | 35.085 | 1.00 | 28.69 | A |
| ATOM | 2068 | CB | HIS | 108 | 20.512 | 3.039 | 33.712 | 1.00 | 28.22 | A |
| ATOM | 2069 | CG | HIS | 108 | 19.661 | 1.820 | 33.606 | 1.00 | 27.30 | A |
| ATOM | 2070 | CD2 | HIS | 108 | 18.446 | 1.630 | 33.047 | 1.00 | 26.75 | A |
| ATOM | 2071 | ND1 | HIS | 108 | 20.029 | 0.608 | 34.150 | 1.00 | 28.84 | A |
| ATOM | 2072 | CE1 | HIS | 108 | 19.073 | −0.279 | 33.930 | 1.00 | 27.04 | A |
| ATOM | 2073 | NE2 | HIS | 108 | 18.102 | 0.318 | 33.262 | 1.00 | 30.85 | A |
| ATOM | 2074 | C | HIS | 108 | 21.321 | 4.944 | 35.083 | 1.00 | 29.30 | A |
| ATOM | 2075 | O | HIS | 108 | 22.551 | 4.887 | 35.004 | 1.00 | 30.33 | A |
| ATOM | 2076 | N | ILE | 109 | 20.674 | 6.089 | 35.195 | 1.00 | 29.22 | A |
| ATOM | 2077 | CA | ILE | 109 | 21.394 | 7.338 | 35.176 | 1.00 | 28.21 | A |
| ATOM | 2078 | CB | ILE | 109 | 20.402 | 8.496 | 35.036 | 1.00 | 26.19 | A |
| ATOM | 2079 | CG2 | ILE | 109 | 21.037 | 9.813 | 35.447 | 1.00 | 23.27 | A |
| ATOM | 2060 | CG1 | ILE | 109 | 19.893 | 8.481 | 33.582 | 1.00 | 25.41 | A |
| ATOM | 2081 | CD1 | ILE | 109 | 18.679 | 9.316 | 33.294 | 1.00 | 22.28 | A |
| ATOM | 2082 | C | ILE | 109 | 22.470 | 7.513 | 36.260 | 1.00 | 29.56 | A |
| ATOM | 2085 | CD | PRO | 110 | 20.887 | 6.701 | 38.070 | 1.00 | 30.02 | A |
| ATOM | 2104 | SD | MET | 112 | 23.056 | 6.809 | 31.278 | 1.00 | 25.13 | A |
| ATOM | 2105 | CE | MET | 112 | 21.944 | 5.476 | 31.057 | 1.00 | 22.48 | A |
| ATOM | 2231 | ND2 | ASN | 128 | 21.001 | 16.794 | 33.841 | 1.00 | 31.36 | A |
| ATOM | 2234 | N | VAL | 129 | 22.726 | 13.668 | 33.353 | 1.00 | 24.69 | A |
| ATOM | 2235 | CA | VAL | 129 | 22.195 | 12.881 | 32.245 | 1.00 | 23.70 | A |
| ATOM | 2236 | CB | VAL | 129 | 22.696 | 11.412 | 32.248 | 1.00 | 21.95 | A |
| ATOM | 2237 | CG1 | VAL | 129 | 22.096 | 10.674 | 31.081 | 1.00 | 18.56 | A |
| ATOM | 2239 | C | VAL | 129 | 20.677 | 12.876 | 32.425 | 1.00 | 25.23 | A |
| ATOM | 2240 | O | VAL | 129 | 20.180 | 12.829 | 33.558 | 1.00 | 24.42 | A |
| ATOM | 2241 | N | LYS | 130 | 19.935 | 12.980 | 31.332 | 1.00 | 24.56 | A |
| ATOM | 2242 | CA | LYS | 130 | 18.484 | 12.953 | 31.435 | 1.00 | 25.99 | A |
| ATOM | 2243 | CB | LYS | 130 | 17.909 | 14.366 | 31.514 | 1.00 | 28.08 | A |
| ATOM | 2244 | CG | LYS | 130 | 17.922 | 15.142 | 30.219 | 1.00 | 31.65 | A |
| ATOM | 2245 | CD | LYS | 130 | 17.465 | 16.574 | 30.450 | 1.00 | 31.66 | A |
| ATOM | 2246 | CE | LYS | 130 | 18.568 | 17.409 | 31.046 | 1.00 | 29.76 | A |
| ATOM | 2247 | NZ | LYS | 130 | 19.659 | 17.570 | 30.045 | 1.00 | 27.46 | A |
| ATOM | 2248 | C | LYS | 130 | 17.952 | 12.216 | 30.229 | 1.00 | 26.66 | A |
| ATOM | 2249 | O | LYS | 130 | 18.725 | 11.859 | 29.338 | 1.00 | 28.90 | A |
| ATOM | 2250 | N | ALA | 131 | 16.651 | 11.955 | 30.206 | 1.00 | 26.92 | A |
| ATOM | 2251 | CA | ALA | 131 | 16.049 | 11.251 | 29.085 | 1.00 | 23.86 | A |
| ATOM | 2252 | CB | ALA | 131 | 15.967 | 9.765 | 29.385 | 1.00 | 22.73 | A |
| ATOM | 2253 | C | ALA | 131 | 14.670 | 11.807 | 28.783 | 1.00 | 24.68 | A |
| ATOM | 2254 | O | ALA | 131 | 14.085 | 12.519 | 29.600 | 1.00 | 23.54 | A |
| ATOM | 2255 | N | THR | 132 | 14.201 | 11.552 | 27.568 | 1.00 | 25.97 | A |
| ATOM | 2256 | CA | THR | 132 | 12.877 | 11.967 | 27.124 | 1.00 | 26.10 | A |
| ATOM | 2257 | CB | THR | 132 | 12.828 | 13.452 | 26.697 | 1.00 | 27.03 | A |
| ATOM | 2258 | OG1 | THR | 132 | 11.461 | 13.837 | 26.503 | 1.00 | 29.47 | A |
| ATOM | 2259 | CG2 | THR | 132 | 13.593 | 13.684 | 25.387 | 1.00 | 24.88 | A |
| ATOM | 2260 | C | THR | 132 | 12.512 | 11.094 | 25.933 | 1.00 | 28.23 | A |
| ATOM | 2261 | O | THR | 132 | 13.390 | 10.531 | 25.275 | 1.00 | 30.55 | A |
| ATOM | 2262 | N | THR | 133 | 11.217 | 10.916 | 25.705 | 1.00 | 29.76 | A |
| ATOM | 2263 | CA | THR | 133 | 10.739 | 10.135 | 24.570 | 1.00 | 29.38 | A |
| ATOM | 2264 | CB | THR | 133 | 9.517 | 9.240 | 24.924 | 1.00 | 28.88 | A |
| ATOM | 2265 | OG1 | THR | 133 | 8.375 | 10.064 | 25.172 | 1.00 | 29.30 | A |
| ATOM | 2266 | CG2 | THR | 133 | 9.772 | 8.381 | 26.143 | 1.00 | 27.35 | A |
| ATOM | 2267 | C | THR | 133 | 10.226 | 11.199 | 23.609 | 1.00 | 31.22 | A |
| ATOM | 2268 | O | THR | 133 | 10.081 | 12.369 | 23.991 | 1.00 | 29.70 | A |
| ATOM | 2269 | N | THR | 134 | 9.982 | 10.813 | 22.364 | 1.00 | 32.68 | A |
| ATOM | 2270 | CA | THR | 134 | 9.431 | 11.747 | 21.395 | 1.00 | 32.99 | A |
| ATOM | 2271 | CB | THR | 134 | 10.172 | 11.671 | 20.061 | 1.00 | 31.58 | A |
| ATOM | 2272 | OG1 | THR | 134 | 10.319 | 10.300 | 19.680 | 1.00 | 33.34 | A |
| ATOM | 2273 | CG2 | THR | 134 | 11.545 | 12.304 | 20.191 | 1.00 | 30.28 | A |
| ATOM | 2274 | C | THR | 134 | 7.932 | 11.437 | 21.214 | 1.00 | 34.41 | A |
| ATOM | 2275 | O | THR | 134 | 7.360 | 11.675 | 20.147 | 1.00 | 36.43 | A |
| ATOM | 2276 | N | GLU | 135 | 7.317 | 10.887 | 22.267 | 1.00 | 33.19 | A |
| ATOM | 2277 | CA | GLU | 135 | 5.894 | 10.539 | 22.285 | 1.00 | 33.15 | A |
| ATOM | 2278 | CB | GLU | 135 | 5.049 | 11.814 | 22.377 | 1.00 | 34.19 | A |
| ATOM | 2279 | CG | GLU | 135 | 5.467 | 12.785 | 23.484 | 1.00 | 38.74 | A |
| ATOM | 2280 | CD | GLU | 135 | 5.037 | 12.356 | 24.875 | 1.00 | 42.35 | A |
| ATOM | 2281 | OE1 | GLU | 135 | 5.454 | 13.003 | 25.860 | 1.00 | 45.39 | A |
| ATOM | 22B2 | OE2 | GLU | 135 | 4.262 | 11.393 | 25.003 | 1.00 | 45.66 | A |
| ATOM | 2283 | C | GLU | 135 | 5.432 | 9.691 | 21.089 | 1.00 | 32.18 | A |
| ATOM | 2284 | O | GLU | 135 | 4.454 | 10.019 | 20.420 | 1.00 | 31.74 | A |
| ATOM | 2285 | N | LYS | 136 | 6.133 | 8.594 | 20.832 | 1.00 | 31.68 | A |
| ATOM | 2286 | CA | LYS | 136 | 5.813 | 7.697 | 19.723 | 1.00 | 31.84 | A |
| ATOM | 2287 | CB | LYS | 136 | 4.390 | 7.166 | 19.848 | 1.00 | 33.28 | A |
| ATOM | 2288 | CG | LYS | 136 | 4.159 | 6.241 | 21.023 | 1.00 | 36.29 | A |
| ATOM | 2294 | N | LEU | 137 | 6.398 | 9.572 | 18.285 | 1.00 | 30.53 | A |
| ATOM | 2318 | CA | THR | 140 | 12.811 | 7.171 | 18.087 | 1.00 | 29.27 | A |
| ATOM | 2319 | CB | THR | 140 | 13.272 | 8.423 | 18.879 | 1.00 | 26.16 | A |
| ATOM | 2320 | OG1 | THR | 140 | 12.611 | 9.580 | 18.343 | 1.00 | 32.68 | A |
| ATOM | 2321 | CG2 | THR | 140 | 14.777 | 8.613 | 18.772 | 1.00 | 21.89 | A |
| ATOM | 2322 | C | THR | 140 | 11.461 | 6.684 | 18.644 | 1.00 | 30.26 | A |
| ATOM | 2323 | O | THR | 140 | 11.398 | 5.673 | 19.348 | 1.00 | 32.42 | A |
| ATOM | 2324 | N | GLY | 141 | 10.389 | 7.404 | 18.307 | 1.00 | 30.28 | A |
| ATOM | 2325 | CA | GLY | 141 | 9.057 | 7.058 | 18.765 | 1.00 | 27.95 | A |
| ATOM | 2354 | C | GLY | 145 | 16.725 | 4.673 | 18.433 | 1.00 | 26.68 | A |
| ATOM | 2355 | O | GLY | 145 | 15.654 | 5.042 | 18.916 | 1.00 | 29.22 | A |
| ATOM | 2356 | N | ILE | 146 | 17.906 | 5.043 | 18.912 | 1.00 | 26.69 | A |
| ATOM | 2357 | CA | ILE | 146 | 18.043 | 5.955 | 20.043 | 1.00 | 26.50 | A |
| ATOM | 2358 | CB | ILE | 146 | 18.733 | 5.275 | 21.264 | 1.00 | 25.26 | A |
| ATOM | 2359 | CG2 | ILE | 146 | 18.969 | 6.276 | 22.370 | 1.00 | 27.32 | A |
| ATOM | 2360 | CG1 | ILE | 146 | 17.858 | 4.159 | 21.823 | 1.00 | 25.91 | A |
| ATOM | 2361 | CD1 | ILE | 146 | 18.446 | 3.487 | 23.050 | 1.00 | 26.47 | A |
| ATOM | 2362 | C | ILE | 146 | 18.903 | 7.118 | 19.573 | 1.00 | 26.22 | A |
| ATOM | 2364 | N | ALA | 147 | 18.549 | 8.320 | 19.992 | 1.00 | 25.37 | A |
| ATOM | 2367 | C | ALA | 147 | 19.810 | 10.047 | 20.939 | 1.00 | 24.10 | A |
| ATOM | 2368 | O | ALA | 147 | 19.381 | 9.597 | 22.002 | 1.00 | 26.14 | A |
| ATOM | 2470 | OHH | SOL | 510 | 15.399 | −1.988 | 30.943 | 1.00 | 46.57 | A |
| ATOM | 2475 | OHH | SOL | 515 | 5.067 | 7.879 | 24.779 | 1.00 | 53.99 | A |
| ATOM | 2481 | OHH | SOL | 521 | 9.757 | 5.702 | 28.954 | 1.00 | 69.84 | A |
| ATOM | 2483 | OHH | SOL | 524 | 9.787 | 1.438 | 21.253 | 1.00 | 38.76 | A |
| ATOM | 2491 | OHH | SOL | 532 | 17.691 | 12.757 | 35.616 | 1.00 | 46.29 | A |
| ATOM | 2493 | OHH | SOL | 535 | 12.858 | 2.239 | 21.394 | 1.00 | 42.02 | A |
| ATOM | 2496 | OHH | SOL | 538 | 12.112 | −0.139 | 29.683 | 1.00 | 53.96 | A |
| ATOM | 2505 | OHH | SOL | 549 | 11.208 | −1.632 | 27.508 | 1.00 | 56.30 | A |
| ATOM | 2513 | OHH | SOL | 560 | 7.130 | 3.066 | 25.196 | 1.00 | 61.58 | A |
| ATOM | 2534 | OHH | SOL | 592 | 9.715 | 2.253 | 28.640 | 1.00 | 61.78 | A |
| ATOM | 2580 | N | PHE | 7 | 15.414 | 18.977 | 25.681 | 1.00 | 26.44 | A |
| ATOM | 2581 | CA | PHE | 7 | 14.727 | 18.655 | 24.437 | 1.00 | 26.21 | A |
| ATOM | 2582 | CB | PHE | 7 | 15.564 | 17.696 | 23.578 | 1.00 | 25.04 | A |
| ATOM | 2583 | CG | PHE | 7 | 14.849 | 17.211 | 22.335 | 1.00 | 26.03 | A |
| ATOM | 2585 | CD2 | PHE | 7 | 14.230 | 15.964 | 22.309 | 1.00 | 27.92 | A |
| ATOM | 2587 | CE2 | PHE | 7 | 13.525 | 15.528 | 21.184 | 1.00 | 26.33 | A |
| ATOM | 2589 | C | PHE | 7 | 13.409 | 17.994 | 24.814 | 1.00 | 27.17 | A |
| ATOM | 2590 | O | PHE | 7 | 13.383 | 17.152 | 25.715 | 1.00 | 29.65 | A |
| ATOM | 2591 | N | ASP | 8 | 12.321 | 18.385 | 24.154 | 1.00 | 27.46 | A |
| ATOM | 2592 | CA | ASP | 8 | 11.013 | 17.794 | 24.429 | 1.00 | 26.30 | A |
| ATOM | 2593 | CB | ASP | 8 | 10.289 | 18.580 | 25.521 | 1.00 | 26.02 | A |
| ATOM | 2594 | CG | ASP | 8 | 9.106 | 17.821 | 26.107 | 1.00 | 29.20 | A |
| ATOM | 2595 | OD1 | ASP | 8 | 8.210 | 18.477 | 26.665 | 1.00 | 30.79 | A |
| ATOM | 2596 | OD2 | ASP | 8 | 9.053 | 16.573 | 26.016 | 1.00 | 28.76 | A |
| ATOM | 2597 | C | ASP | 8 | 10.153 | 17.727 | 23.160 | 1.00 | 28.12 | A |
| ATOM | 2598 | O | ASP | 8 | 10.383 | 18.476 | 22.193 | 1.00 | 28.21 | A |
| ATOM | 2599 | N | VAL | 9 | 9.190 | 16.803 | 23.157 | 1.00 | 27.98 | A |
| ATOM | 2600 | CA | VAL | 9 | 8.272 | 16.589 | 22.035 | 1.00 | 26.18 | A |
| ATOM | 2601 | CB | VAL | 9 | 8.750 | 15.421 | 21.108 | 1.00 | 23.97 | A |
| ATOM | 2602 | CG1 | VAL | 9 | 7.679 | 15.052 | 20.107 | 1.00 | 21.03 | A |
| ATOM | 2603 | CG2 | VAL | 9 | 10.001 | 15.802 | 20.365 | 1.00 | 23.62 | A |
| ATOM | 2604 | C | VAL | 9 | 6.892 | 16.210 | 22.579 | 1.00 | 28.29 | A |
| ATOM | 2605 | O | VAL | 9 | 6.787 | 15.542 | 23.617 | 1.00 | 29.03 | A |
| ATOM | 2606 | N | HIS | 10 | 5.843 | 16.718 | 21.931 | 1.00 | 29.48 | A |
| ATOM | 2607 | CA | HIS | 10 | 4.451 | 16.397 | 22.277 | 1.00 | 29.70 | A |
| ATOM | 2608 | CB | HIS | 10 | 3.829 | 17.402 | 23.251 | 1.00 | 28.20 | A |
| ATOM | 2609 | CG | HIS | 10 | 4.289 | 17.204 | 24.661 | 1.00 | 28.51 | A |
| ATOM | 2610 | CD2 | HIS | 10 | 5.099 | 17.950 | 25.450 | 1.00 | 28.35 | A |
| ATOM | 2611 | ND1 | HIS | 10 | 4.022 | 16.053 | 25.367 | 1.00 | 26.73 | A |
| ATOM | 2612 | CE1 | HIS | 10 | 4.654 | 16.095 | 26.528 | 1.00 | 28.80 | A |
| ATOM | 2613 | NE2 | HIS | 10 | 5.317 | 17.236 | 26.605 | 1.00 | 29.81 | A |
| ATOM | 2614 | C | HIS | 10 | 3.657 | 16.266 | 20.991 | 1.00 | 29.38 | A |
| ATOM | 2615 | O | HIS | 10 | 3.903 | 16.982 | 20.025 | 1.00 | 31.41 | A |
| ATOM | 2616 | N | ALA | 11 | 2.793 | 15.269 | 20.942 | 1.00 | 28.56 | A |
| ATOM | 2617 | CA | ALA | 11 | 2.005 | 15.010 | 19.763 | 1.00 | 28.78 | A |
| ATOM | 2620 | O | ALA | 11 | 0.157 | 16.061 | 20.835 | 1.00 | 32.69 | A |
| ATOM | 2675 | O | ILE | 19 | 2.071 | 25.130 | 25.135 | 1.00 | 31.55 | A |
| ATOM | 2760 | CA | LEU | 31 | −1.193 | 18.914 | 22.240 | 1.00 | 34.62 | A |
| ATOM | 2761 | CB | LEU | 31 | 0.035 | 19.724 | 22.648 | 1.00 | 29.44 | A |
| ATOM | 2762 | CG | LEU | 31 | 0.742 | 20.483 | 21.537 | 1.00 | 26.01 | A |
| ATOM | 2763 | CD1 | LEU | 31 | 1.805 | 21.379 | 22.131 | 1.00 | 29.50 | A |
| ATOM | 2765 | C | LEU | 31 | −1.528 | 17.926 | 23.348 | 1.00 | 35.56 | A |
| ATOM | 2766 | O | LEU | 31 | −2.110 | 18.297 | 24.361 | 1.00 | 36.85 | A |
| ATOM | 2767 | N | LEU | 32 | −1.159 | 16.669 | 23.148 | 1.00 | 37.12 | A |
| ATOM | 2768 | CA | LEU | 32 | −1.396 | 15.618 | 24.132 | 1.00 | 39.24 | A |
| ATOM | 2769 | CB | LEU | 32 | −1.482 | 14.277 | 23.414 | 1.00 | 37.00 | A |
| ATOM | 2770 | CG | LEU | 32 | −2.552 | 14.127 | 22.336 | 1.00 | 38.26 | A |
| ATOM | 2773 | C | LEU | 32 | −0.260 | 15.554 | 25.170 | 1.00 | 42.63 | A |
| ATOM | 2774 | O | LEU | 32 | 0.923 | 15.531 | 24.800 | 1.00 | 45.83 | A |
| ATOM | 2775 | N | ALA | 33 | −0.602 | 15.521 | 26.458 | 1.00 | 44.75 | A |
| ATOM | 2776 | CA | ALA | 33 | 0.402 | 15.425 | 27.526 | 1.00 | 47.26 | A |
| ATOM | 2777 | CB | ALA | 33 | 1.311 | 16.647 | 27.514 | 1.00 | 45.99 | A |
| ATOM | 2778 | C | ALA | 33 | −0.256 | 15.277 | 28.897 | 1.00 | 49.59 | A |
| ATOM | 2779 | O | ALA | 33 | −1.460 | 15.514 | 29.031 | 1.00 | 53.59 | A |
| ATOM | 2780 | N | HIS | 34 | 0.524 | 14.857 | 29.899 | 1.00 | 50.40 | A |
| ATOM | 2781 | CA | HIS | 34 | 0.030 | 14.707 | 31.276 | 1.00 | 49.48 | A |
| ATOM | 2782 | CB | HIS | 34 | 1.118 | 14.095 | 32.172 | 1.00 | 52.23 | A |
| ATOM | 2783 | CG | HIS | 34 | 0.669 | 13.797 | 33.574 | 1.00 | 55.73 | A |
| ATOM | 2784 | CD2 | HIS | 34 | 1.269 | 14.028 | 34.768 | 1.00 | 55.33 | A |
| ATOM | 2785 | ND1 | HIS | 34 | −0.512 | 13.144 | 33.862 | 1.00 | 56.32 | A |
| ATOM | 2786 | CE1 | HIS | 34 | −0.617 | 12.983 | 35.170 | 1.00 | 55.92 | A |
| ATOM | 2787 | NE2 | HIS | 34 | 0.450 | 13.510 | 35.742 | 1.00 | 55.37 | A |
| ATOM | 2788 | C | HIS | 34 | −0.375 | 16.084 | 31.825 | 1.00 | 48.04 | A |
| ATOM | 2789 | O | HIS | 34 | −1.447 | 16.233 | 32.417 | 1.00 | 47.66 | A |
| ATOM | 2790 | N | SER | 35 | 0.513 | 17.064 | 31.655 | 1.00 | 45.72 | A |
| ATOM | 2791 | CA | SER | 35 | 0.302 | 18.443 | 32.088 | 1.00 | 42.28 | A |
| ATOM | 2792 | CB | SER | 35 | 1.655 | 19.103 | 32.385 | 1.00 | 41.47 | A |
| ATOM | 2793 | OG | SER | 35 | 2.417 | 19.299 | 31.196 | 1.00 | 40.82 | A |
| ATOM | 2794 | C | SER | 35 | −0.366 | 19.143 | 30.911 | 1.00 | 41.34 | A |
| ATOM | 2795 | O | SER | 35 | −0.996 | 18.487 | 30.084 | 1.00 | 41.92 | A |
| ATOM | 2796 | N | ASP | 36 | −0.207 | 20.459 | 30.812 | 1.00 | 40.50 | A |
| ATOM | 2797 | CA | ASP | 36 | −0.777 | 21.219 | 29.698 | 1.00 | 39.44 | A |
| ATOM | 2798 | CB | ASP | 36 | −0.792 | 22.716 | 30.014 | 1.00 | 37.49 | A |
| ATOM | 2799 | CG | ASP | 36 | 0.576 | 23.253 | 30.347 | 1.00 | 37.91 | A |
| ATOM | 2800 | OD1 | ASP | 36 | 0.667 | 24.428 | 30.743 | 1.00 | 37.37 | A |
| ATOM | 2801 | OD2 | ASP | 36 | 1.569 | 22.500 | 30.237 | 1.00 | 39.99 | A |
| ATOM | 2802 | C | ASP | 36 | −0.004 | 20.963 | 28.393 | 1.00 | 39.66 | A |
| ATOM | 2803 | O | ASP | 36 | −0.342 | 21.522 | 27.346 | 1.00 | 40.47 | A |
| ATOM | 2804 | N | GLY | 37 | 1.066 | 20.167 | 28.484 | 1.00 | 38.52 | A |
| ATOM | 2805 | CA | GLY | 37 | 1.858 | 19.814 | 27.318 | 1.00 | 33.83 | A |
| ATOM | 2806 | C | GLY | 37 | 2.729 | 20.889 | 26.709 | 1.00 | 32.50 | A |
| ATOM | 2807 | O | GLY | 37 | 3.165 | 20.755 | 25.565 | 1.00 | 33.84 | A |
| ATOM | 2808 | N | ASP | 38 | 3.039 | 21.924 | 27.476 | 1.00 | 29.56 | A |
| ATOM | 2809 | CA | ASP | 38 | 3.871 | 23.012 | 26.987 | 1.00 | 28.09 | A |
| ATOM | 2810 | CB | ASP | 38 | 3.906 | 24.115 | 28.032 | 1.00 | 25.91 | A |
| ATOM | 2811 | CG | ASP | 38 | 4.404 | 25.415 | 27.486 | 1.00 | 27.62 | A |
| ATOM | 2812 | OD1 | ASP | 38 | 5.354 | 25.413 | 26.678 | 1.00 | 30.71 | A |
| ATOM | 2814 | C | ASP | 38 | 5.286 | 22.524 | 26.660 | 1.00 | 29.07 | A |
| ATOM | 2815 | O | ASP | 38 | 6.156 | 22.465 | 27.532 | 1.00 | 31.45 | A |
| ATOM | 2816 | N | VAL | 39 | 5.517 | 22.178 | 25.399 | 1.00 | 29.41 | A |
| ATOM | 2817 | CA | VAL | 39 | 6.813 | 21.664 | 24.952 | 1.00 | 28.18 | A |
| ATOM | 2818 | CB | VAL | 39 | 6.830 | 21.356 | 23.441 | 1.00 | 28.03 | A |
| ATOM | 2819 | CG1 | VAL | 39 | 7.820 | 20.262 | 23.154 | 1.00 | 26.99 | A |
| ATOM | 2820 | CG2 | VAL | 39 | 5.476 | 20.972 | 22.955 | 1.00 | 31.58 | A |
| ATOM | 2821 | C | VAL | 39 | 7.979 | 22.610 | 25.206 | 1.00 | 28.87 | A |
| ATOM | 2822 | O | VAL | 39 | 9.085 | 22.158 | 25.495 | 1.00 | 29.58 | A |
| ATOM | 2823 | N | ALA | 40 | 7.743 | 23.913 | 25.069 | 1.00 | 27.43 | A |
| ATOM | 2824 | CA | ALA | 40 | 8.793 | 24.906 | 25.255 | 1.00 | 26.33 | A |
| ATOM | 2826 | C | ALA | 40 | 9.256 | 25.033 | 26.696 | 1.00 | 27.55 | A |
| ATOM | 2827 | O | ALA | 40 | 10.452 | 25.112 | 26.964 | 1.00 | 30.12 | A |
| ATOM | 2828 | N | LEU | 41 | 8.315 | 25.073 | 27.631 | 1.00 | 28.00 | A |
| ATOM | 2829 | CA | LEU | 41 | 8.686 | 25.204 | 29.028 | 1.00 | 25.15 | A |
| ATOM | 2830 | CB | LEU | 41 | 7.519 | 25.715 | 29.863 | 1.00 | 24.20 | A |
| ATOM | 2834 | C | LEU | 41 | 9.281 | 23.923 | 29.596 | 1.00 | 26.22 | A |
| ATOM | 2835 | O | LEU | 41 | 10.148 | 23.986 | 30.470 | 1.00 | 27.34 | A |
| ATOM | 2836 | N | HIS | 42 | 8.856 | 22.768 | 29.084 | 1.00 | 25.42 | A |
| ATOM | 2837 | CA | HIS | 42 | 9.423 | 21.496 | 29.538 | 1.00 | 25.30 | A |
| ATOM | 2838 | CB | HIS | 42 | 8.715 | 20.303 | 28.915 | 1.00 | 23.59 | A |
| ATOM | 2839 | CG | HIS | 42 | 7.323 | 20.087 | 29.418 | 1.00 | 23.47 | A |
| ATOM | 2840 | CD2 | HIS | 42 | 6.586 | 20.777 | 30.321 | 1.00 | 23.78 | A |
| ATOM | 2841 | ND1 | HIS | 42 | 6.524 | 19.052 | 28.975 | 1.00 | 25.59 | A |
| ATOM | 2842 | CE1 | HIS | 42 | 5.352 | 19.121 | 29.586 | 1.00 | 24.57 | A |
| ATOM | 2843 | NE2 | HIS | 42 | 5.365 | 20.156 | 30.407 | 1.00 | 21.77 | A |
| ATOM | 2844 | C | HIS | 42 | 10.886 | 21.460 | 29.116 | 1.00 | 26.73 | A |
| ATOM | 2845 | O | HIS | 42 | 11.767 | 21.210 | 29.929 | 1.00 | 29.62 | A |
| ATOM | 2846 | N | ALA | 43 | 11.149 | 21.743 | 27.846 | 1.00 | 26.96 | A |
| ATOM | 2847 | CA | ALA | 43 | 12.516 | 21.750 | 27.352 | 1.00 | 25.91 | A |
| ATOM | 2848 | CB | ALA | 43 | 12.540 | 22.094 | 25.895 | 1.00 | 22.86 | A |
| ATOM | 2849 | C | ALA | 43 | 13.336 | 22.755 | 28.159 | 1.00 | 27.38 | A |
| ATOM | 2850 | O | ALA | 43 | 14.436 | 22.438 | 28.619 | 1.00 | 29.77 | A |
| ATOM | 2851 | N | LEU | 44 | 12.784 | 23.944 | 28.382 | 1.00 | 26.03 | A |
| ATOM | 2859 | N | THR | 45 | 12.825 | 23.795 | 31.189 | 1.00 | 30.23 | A |
| ATOM | 2860 | CA | THR | 45 | 12.993 | 23.258 | 32.533 | 1.00 | 30.10 | A |
| ATOM | 2861 | CB | THR | 45 | 11.680 | 22.616 | 33.023 | 1.00 | 30.18 | A |
| ATOM | 2862 | OG1 | THR | 45 | 10.610 | 23.557 | 32.858 | 1.00 | 29.12 | A |
| ATOM | 2863 | CG2 | THR | 45 | 11.783 | 22.218 | 34.497 | 1.00 | 29.79 | A |
| ATOM | 2864 | C | THR | 45 | 14.140 | 22.241 | 32.596 | 1.00 | 30.61 | A |
| ATOM | 2865 | O | THR | 45 | 14.969 | 22.292 | 33.507 | 1.00 | 32.51 | A |
| ATOM | 2866 | N | ASP | 46 | 14.202 | 21.332 | 31.631 | 1.00 | 28.53 | A |
| ATOM | 2867 | CA | ASP | 46 | 15.264 | 20.340 | 31.599 | 1.00 | 27.70 | A |
| ATOM | 2868 | CB | ASP | 46 | 15.056 | 19.374 | 30.437 | 1.00 | 31.90 | A |
| ATOM | 2869 | CG | ASP | 46 | 14.247 | 18.164 | 30.824 | 1.00 | 33.90 | A |
| ATOM | 2870 | OD1 | ASP | 46 | 13.982 | 17.313 | 29.942 | 1.00 | 34.98 | A |
| ATOM | 2871 | OD2 | ASP | 46 | 13.888 | 18.050 | 32.010 | 1.00 | 32.31 | A |
| ATOM | 2889 | CB | LEU | 49 | 16.598 | 20.330 | 35.847 | 1.00 | 26.37 | A |
| ATOM | 2890 | CG | LEU | 49 | 15.281 | 20.770 | 36.482 | 1.00 | 26.75 | A |
| ATOM | 2891 | CD1 | LEU | 49 | 14.187 | 19.720 | 36.320 | 1.00 | 24.67 | A |
| ATOM | 2920 | C | LEU | 54 | 18.424 | 17.133 | 38.584 | 1.00 | 31.59 | A |
| ATOM | 2921 | O | LEU | 54 | 17.373 | 16.711 | 39.063 | 1.00 | 34.28 | A |
| ATOM | 2922 | N | GLY | 55 | 18.916 | 16.673 | 37.444 | 1.00 | 32.54 | A |
| ATOM | 2923 | CA | GLY | 55 | 18.215 | 15.644 | 36.708 | 1.00 | 32.79 | A |
| ATOM | 2924 | C | GLY | 55 | 17.378 | 16.161 | 35.574 | 1.00 | 35.07 | A |
| ATOM | 2925 | O | GLY | 55 | 17.891 | 16.811 | 34.658 | 1.00 | 34.84 | A |
| ATOM | 2926 | N | ASP | 56 | 16.093 | 15.832 | 35.617 | 1.00 | 36.63 | A |
| ATOM | 2927 | CA | ASP | 56 | 15.166 | 16.264 | 34.592 | 1.00 | 37.80 | A |
| ATOM | 2928 | CB | ASP | 56 | 15.212 | 15.330 | 33.369 | 1.00 | 37.51 | A |
| ATOM | 2929 | CG | ASP | 56 | 14.741 | 13.918 | 33.671 | 1.00 | 36.92 | A |
| ATOM | 2930 | OD1 | ASP | 56 | 13.770 | 13.760 | 34.433 | 1.00 | 35.45 | A |
| ATOM | 2931 | OD2 | ASP | 56 | 15.328 | 12.956 | 33.122 | 1.00 | 38.80 | A |
| ATOM | 2932 | C | ASP | 56 | 13.752 | 16.394 | 35.161 | 1.00 | 38.48 | A |
| ATOM | 2933 | O | ASP | 56 | 13.478 | 15.937 | 36.277 | 1.00 | 38.67 | A |
| ATOM | 2934 | N | ILE | 57 | 12.862 | 16.968 | 34.354 | 1.00 | 38.06 | A |
| ATOM | 2935 | CA | ILE | 57 | 11.473 | 17.232 | 34.709 | 1.00 | 36.63 | A |
| ATOM | 2936 | CB | ILE | 57 | 10.744 | 17.987 | 33.550 | 1.00 | 33.47 | A |
| ATOM | 2937 | CG2 | ILE | 57 | 10.316 | 17.035 | 32.445 | 1.00 | 31.29 | A |
| ATOM | 2938 | CG1 | ILE | 57 | 9.516 | 18.709 | 34.068 | 1.00 | 31.65 | A |
| ATOM | 2939 | CD1 | ILE | 57 | 8.865 | 19.543 | 33.014 | 1.00 | 32.03 | A |
| ATOM | 2940 | C | ILE | 57 | 10.683 | 16.007 | 35.148 | 1.00 | 38.59 | A |
| ATOM | 2941 | O | ILE | 57 | 9.933 | 16.077 | 36.115 | 1.00 | 39.40 | A |
| ATOM | 2942 | N | GLY | 58 | 10.886 | 14.876 | 34.480 | 1.00 | 40.97 | A |
| ATOM | 2943 | CA | GLY | 58 | 10.158 | 13.672 | 34.835 | 1.00 | 43.78 | A |
| ATOM | 2944 | C | GLY | 58 | 10.533 | 13.143 | 36.205 | 1.00 | 46.85 | A |
| ATOM | 2945 | O | GLY | 58 | 9.703 | 12.591 | 36.926 | 1.00 | 48.60 | A |
| ATOM | 2946 | N | LYS | 59 | 11.793 | 13.325 | 36.568 | 1.00 | 49.62 | A |
| ATOM | 2947 | CA | LYS | 59 | 12.309 | 12.870 | 37.850 | 1.00 | 51.87 | A |
| ATOM | 2948 | CB | LYS | 59 | 13.826 | 13.018 | 37.852 | 1.00 | 53.55 | A |
| ATOM | 2949 | CG | LYS | 59 | 14.516 | 12.534 | 39.086 | 1.00 | 56.93 | A |
| ATOM | 2950 | CD | LYS | 59 | 15.859 | 13.206 | 39.156 | 1.00 | 60.39 | A |
| ATOM | 2951 | CE | LYS | 59 | 16.653 | 12.776 | 40.366 | 1.00 | 62.70 | A |
| ATOM | 2952 | NZ | LYS | 59 | 17.878 | 13.622 | 40.468 | 1.00 | 67.42 | A |
| ATOM | 2953 | C | LYS | 59 | 11.690 | 13.660 | 39.007 | 1.00 | 52.21 | A |
| ATOM | 2959 | O | LYS | 59 | 11.385 | 13.094 | 40.054 | 1.00 | 53.64 | A |
| ATOM | 2955 | N | LEU | 60 | 11.529 | 14.968 | 38.815 | 1.00 | 51.56 | A |
| ATOM | 2956 | CA | LEU | 60 | 10.938 | 15.852 | 39.823 | 1.00 | 50.00 | A |
| ATOM | 2957 | CB | LEU | 60 | 11.437 | 17.286 | 39.640 | 1.00 | 49.26 | A |
| ATOM | 2958 | CG | LEU | 60 | 12.752 | 17.734 | 40.269 | 1.00 | 51.25 | A |
| ATOM | 2959 | CD1 | LEU | 60 | 13.946 | 16.954 | 39.719 | 1.00 | 51.11 | A |
| ATOM | 2960 | CD2 | LEU | 60 | 12.898 | 19.226 | 40.014 | 1.00 | 51.47 | A |
| ATOM | 2961 | C | LEU | 60 | 9.403 | 15.882 | 39.821 | 1.00 | 49.29 | A |
| ATOM | 2962 | O | LEU | 60 | 8.787 | 16.098 | 40.864 | 1.00 | 49.22 | A |
| ATOM | 2963 | N | PHE | 61 | 8.791 | 15.735 | 38.649 | 1.00 | 48.60 | A |
| ATOM | 2964 | CA | PHE | 61 | 7.338 | 15.771 | 38.537 | 1.00 | 48.74 | A |
| ATOM | 2965 | CB | PHE | 61 | 6.882 | 17.114 | 37.934 | 1.00 | 46.51 | A |
| ATOM | 2966 | CG | PHE | 61 | 7.650 | 18.314 | 38.447 | 1.00 | 45.75 | A |
| ATOM | 2967 | CD1 | PHE | 61 | 7.583 | 18.690 | 39.783 | 1.00 | 43.79 | A |
| ATOM | 2968 | CD2 | PHE | 61 | 8.474 | 19.045 | 37.592 | 1.00 | 45.32 | A |
| ATOM | 2969 | CE1 | PHE | 61 | 8.330 | 19.772 | 40.261 | 1.00 | 43.44 | A |
| ATOM | 2970 | CE2 | PHE | 61 | 9.224 | 20.129 | 38.063 | 1.00 | 44.22 | A |
| ATOM | 2971 | CZ | PHE | 61 | 9.152 | 20.490 | 39.400 | 1.00 | 43.06 | A |
| ATOM | 2972 | C | PHE | 61 | 6.851 | 14.603 | 37.669 | 1.00 | 50.87 | A |
| ATOM | 2973 | O | PHE | 61 | 6.485 | 14.787 | 36.517 | 1.00 | 51.44 | A |
| ATOM | 2974 | N | PRO | 62 | 6.797 | 13.390 | 38.241 | 1.00 | 53.60 | A |
| ATOM | 2975 | CD | PRO | 62 | 7.179 | 13.137 | 39.641 | 1.00 | 54.38 | A |
| ATOM | 2976 | CA | PRO | 62 | 6.372 | 12.139 | 37.600 | 1.00 | 56.25 | A |
| ATOM | 2977 | CB | PRO | 62 | 6.334 | 11.167 | 38.775 | 1.00 | 55.31 | A |
| ATOM | 2978 | CG | PRO | 62 | 7.434 | 11.656 | 39.641 | 1.00 | 53.95 | A |
| ATOM | 2979 | C | PRO | 62 | 5.045 | 12.107 | 36.827 | 1.00 | 59.40 | A |
| ATOM | 2980 | O | PRO | 62 | 4.006 | 12.545 | 37.326 | 1.00 | 59.70 | A |
| ATOM | 2981 | N | ASP | 63 | 5.095 | 11.501 | 35.639 | 1.00 | 63.52 | A |
| ATOM | 2982 | CA | ASP | 63 | 3.942 | 11.320 | 34.746 | 1.00 | 67.07 | A |
| ATOM | 2983 | CB | ASP | 63 | 4.357 | 10.503 | 33.513 | 1.00 | 70.08 | A |
| ATOM | 2984 | CG | ASP | 63 | 4.730 | 11.372 | 32.325 | 1.00 | 75.30 | A |
| ATOM | 2985 | OD1 | ASP | 63 | 5.113 | 12.548 | 32.525 | 1.00 | 79.11 | A |
| ATOM | 2986 | OD2 | ASP | 63 | 4.632 | 10.879 | 31.178 | 1.00 | 76.30 | A |
| ATOM | 2987 | C | ASP | 63 | 2.836 | 10.551 | 35.449 | 1.00 | 68.14 | A |
| ATOM | 2988 | O | ASP | 63 | 1.655 | 10.678 | 35.116 | 1.00 | 68.67 | A |
| ATOM | 2989 | N | THR | 64 | 3.250 | 9.701 | 36.379 | 1.00 | 69.64 | A |
| ATOM | 2990 | CA | THR | 64 | 2.350 | 8.862 | 37.158 | 1.00 | 71.34 | A |
| ATOM | 2991 | CB | THR | 64 | 3.136 | 7.690 | 37.812 | 1.00 | 72.58 | A |
| ATOM | 2992 | OG1 | THR | 64 | 4.304 | 8.192 | 38.483 | 1.00 | 73.91 | A |
| ATOM | 2993 | CG2 | THR | 64 | 3.568 | 6.683 | 36.749 | 1.00 | 73.09 | A |
| ATOM | 2994 | C | THR | 64 | 1.571 | 9.635 | 38.228 | 1.00 | 70.96 | A |
| ATOM | 2995 | O | THR | 64 | 0.366 | 9.427 | 38.404 | 1.00 | 72.17 | A |
| ATOM | 2996 | N | ASP | 65 | 2.260 | 10.536 | 38.922 | 1.00 | 69.78 | A |
| ATOM | 2997 | CA | ASP | 65 | 1.647 | 11.333 | 39.969 | 1.00 | 67.92 | A |
| ATOM | 2998 | CB | ASP | 65 | 2.697 | 12.216 | 40.630 | 1.00 | 68.89 | A |
| ATOM | 2999 | CG | ASP | 65 | 2.212 | 12.836 | 41.923 | 1.00 | 70.13 | A |
| ATOM | 3000 | OD1 | ASP | 65 | 0.994 | 13.069 | 42.064 | 1.00 | 71.39 | A |
| ATOM | 3001 | OD2 | ASP | 65 | 3.057 | 13.091 | 42.807 | 1.00 | 71.48 | A |
| ATOM | 3002 | C | ASP | 65 | 0.525 | 12.182 | 39.381 | 1.00 | 67.48 | A |
| ATOM | 3003 | O | ASP | 65 | 0.766 | 13.103 | 38.591 | 1.00 | 65.87 | A |
| ATOM | 3004 | N | PRO | 66 | −0.725 | 11.876 | 39.764 | 1.00 | 68.09 | A |
| ATOM | 3005 | CD | PRO | 66 | −1.038 | 10.836 | 40.762 | 1.00 | 69.04 | A |
| ATOM | 3006 | CA | PRO | 66 | −1.952 | 12.553 | 39.325 | 1.00 | 68.48 | A |
| ATOM | 3007 | CB | PRO | 66 | −3.051 | 11.725 | 39.990 | 1.00 | 68.61 | A |
| ATOM | 3008 | CG | PRO | 66 | −2.398 | 11.265 | 41.254 | 1.00 | 69.34 | A |
| ATOM | 3009 | C | PRO | 66 | −2.031 | 14.026 | 39.728 | 1.00 | 68.29 | A |
| ATOM | 3010 | O | PRO | 66 | −2.894 | 14.769 | 39.246 | 1.00 | 68.55 | A |
| ATOM | 3011 | N | ALA | 67 | −1.126 | 14.446 | 40.603 | 1.00 | 67.34 | A |
| ATOM | 3012 | CA | ALA | 67 | −1.079 | 15.828 | 41.053 | 1.00 | 67.20 | A |
| ATOM | 3013 | CB | ALA | 67 | −0.128 | 15.949 | 42.227 | 1.00 | 68.19 | A |
| ATOM | 3014 | C | ALA | 67 | −0.623 | 16.744 | 39.912 | 1.00 | 66.93 | A |
| ATOM | 3015 | O | ALA | 67 | −0.897 | 17.950 | 39.903 | 1.00 | 67.19 | A |
| ATOM | 3016 | N | PHE | 68 | 0.065 | 16.157 | 38.941 | 1.00 | 65.52 | A |
| ATOM | 3017 | CA | PHE | 68 | 0.572 | 16.916 | 37.814 | 1.00 | 63.77 | A |
| ATOM | 3018 | CB | PHE | 68 | 1.995 | 16.458 | 37.504 | 1.00 | 61.81 | A |
| ATOM | 3019 | CG | PHE | 68 | 2.851 | 16.310 | 38.725 | 1.00 | 59.89 | A |
| ATOM | 3020 | CD1 | PHE | 68 | 3.478 | 15.106 | 39.008 | 1.00 | 59.01 | A |
| ATOM | 3021 | CD2 | PHE | 68 | 3.014 | 17.372 | 39.607 | 1.00 | 58.70 | A |
| ATOM | 3022 | CE1 | PHE | 68 | 4.257 | 14.962 | 40.153 | 1.00 | 57.86 | A |
| ATOM | 3023 | CE2 | PHE | 68 | 3.790 | 17.236 | 40.753 | 1.00 | 57.41 | A |
| ATOM | 3024 | CZ | PHE | 68 | 4.413 | 16.029 | 41.026 | 1.00 | 57.49 | A |
| ATOM | 3025 | C | PHE | 68 | −0.304 | 16.813 | 36.574 | 1.00 | 63.76 | A |
| ATOM | 3026 | O | PHE | 68 | 0.142 | 17.152 | 35.475 | 1.00 | 64.40 | A |
| ATOM | 3027 | N | LYS | 69 | −1.534 | 16.329 | 36.725 | 1.00 | 63.50 | A |
| ATOM | 3028 | CA | LYS | 69 | −2.409 | 16.219 | 35.565 | 1.00 | 65.34 | A |
| ATOM | 3029 | CB | LYS | 69 | −3.482 | 15.153 | 35.741 | 1.00 | 67.60 | A |
| ATOM | 3030 | CG | LYS | 69 | −4.252 | 14.950 | 34.446 | 1.00 | 72.47 | A |
| ATOM | 3031 | CD | LYS | 69 | −5.478 | 14.094 | 34.620 | 1.00 | 78.38 | A |
| ATOM | 3034 | C | LYS | 69 | −3.070 | 17.554 | 35.232 | 1.00 | 64.26 | A |
| ATOM | 3035 | O | LYS | 69 | −3.791 | 18.122 | 36.054 | 1.00 | 65.40 | A |
| ATOM | 3036 | N | GLY | 70 | −2.855 | 18.018 | 34.003 | 1.00 | 61.40 | A |
| ATOM | 3037 | CA | GLY | 70 | −3.399 | 19.288 | 33.569 | 1.00 | 57.42 | A |
| ATOM | 3038 | C | GLY | 70 | −2.577 | 20.415 | 34.166 | 1.00 | 55.41 | A |
| ATOM | 3039 | O | GLY | 70 | −2.903 | 21.587 | 33.983 | 1.00 | 56.80 | A |
| ATOM | 3040 | N | ALA | 71 | −1.480 | 20.055 | 34.833 | 1.00 | 52.44 | A |
| ATOM | 3041 | CA | ALA | 71 | −0.595 | 21.015 | 35.491 | 1.00 | 50.60 | A |
| ATOM | 3042 | CB | ALA | 71 | 0.616 | 20.289 | 36.108 | 1.00 | 47.83 | A |
| ATOM | 3043 | C | ALA | 71 | −0.125 | 22.159 | 34.587 | 1.00 | 49.05 | A |
| ATOM | 3044 | O | ALA | 71 | 0.074 | 21.980 | 33.379 | 1.00 | 50.42 | A |
| ATOM | 3045 | N | ASP | 72 | 0.017 | 23.335 | 35.187 | 1.00 | 44.70 | A |
| ATOM | 3046 | CA | ASP | 72 | 0.475 | 24.524 | 34.497 | 1.00 | 39.54 | A |
| ATOM | 3051 | C | ASP | 72 | 1.990 | 24.363 | 34.434 | 1.00 | 38.34 | A |
| ATOM | 3052 | O | ASP | 72 | 2.664 | 24.429 | 35.464 | 1.00 | 39.34 | A |
| ATOM | 3053 | N | SER | 73 | 2.537 | 24.143 | 33.242 | 1.00 | 34.94 | A |
| ATOM | 3054 | CA | SER | 73 | 3.978 | 23.981 | 33.111 | 1.00 | 31.43 | A |
| ATOM | 3055 | CB | SER | 73 | 4.368 | 23.704 | 31.667 | 1.00 | 30.77 | A |
| ATOM | 3056 | OG | SER | 73 | 3.937 | 22.413 | 31.269 | 1.00 | 28.57 | A |
| ATOM | 3057 | C | SER | 73 | 4.777 | 25.150 | 33.681 | 1.00 | 31.01 | A |
| ATOM | 3058 | O | SER | 73 | 5.972 | 25.014 | 33.953 | 1.00 | 31.19 | A |
| ATOM | 3059 | N | ARG | 74 | 4.133 | 26.301 | 33.850 | 1.00 | 30.67 | A |
| ATOM | 3070 | N | GLU | 75 | 3.997 | 26.475 | 36.510 | 1.00 | 36.19 | A |
| ATOM | 3077 | C | GLU | 75 | 5.281 | 25.211 | 38.110 | 1.00 | 38.61 | A |
| ATOM | 3079 | N | LEU | 76 | 5.443 | 24.271 | 37.182 | 1.00 | 36.17 | A |
| ATOM | 3080 | CA | LEU | 76 | 6.555 | 23.330 | 37.230 | 1.00 | 33.67 | A |
| ATOM | 3081 | CB | LEU | 76 | 6.384 | 22.231 | 36.181 | 1.00 | 35.59 | A |
| ATOM | 3082 | CG | LEU | 76 | 5.142 | 21.335 | 36.255 | 1.00 | 36.44 | A |
| ATOM | 3083 | CD1 | LEU | 76 | 5.262 | 20.221 | 35.219 | 1.00 | 35.97 | A |
| ATOM | 3084 | CD2 | LEU | 76 | 5.017 | 20.738 | 37.649 | 1.00 | 37.62 | A |
| ATOM | 3085 | C | LEU | 76 | 7.875 | 24.054 | 36.997 | 1.00 | 33.45 | A |
| ATOM | 3086 | O | LEU | 76 | 8.893 | 23.716 | 37.602 | 1.00 | 34.12 | A |
| ATOM | 3087 | N | LEU | 77 | 7.868 | 25.041 | 36.108 | 1.00 | 31.70 | A |
| ATOM | 3088 | CA | LEU | 77 | 9.077 | 25.794 | 35.831 | 1.00 | 31.76 | A |
| ATOM | 3089 | CB | LEU | 77 | 8.850 | 26.770 | 34.677 | 1.00 | 29.77 | A |
| ATOM | 3117 | CB | ALA | 80 | 12.225 | 23.224 | 37.937 | 1.00 | 34.83 | A |
| ATOM | 3630 | O | ILE | 146 | 6.933 | 18.806 | 19.846 | 1.00 | 27.98 | A |
| ATOM | 3638 | CB | CYS | 148 | 10.647 | 22.841 | 22.206 | 1.00 | 26.89 | A |
| ATOM | 3641 | O | CYS | 148 | 13.051 | 20.756 | 22.557 | 1.00 | 26.97 | A |
| ATOM | 3692 | N1 | CMP | 669 | 12.364 | 8.686 | 30.549 | 1.00 | 38.40 | A |
| ATOM | 3693 | C2 | CMP | 669 | 13.280 | 7.627 | 30.697 | 1.00 | 35.68 | A |
| ATOM | 3694 | N3 | CMP | 669 | 13.732 | 6.891 | 29.641 | 1.00 | 33.85 | A |
| ATOM | 3695 | C4 | CMP | 669 | 13.299 | 7.163 | 28.402 | 1.00 | 31.30 | A |
| ATOM | 3696 | C5 | CMP | 669 | 12.400 | 8.196 | 28.191 | 1.00 | 31.13 | A |
| ATOM | 3697 | C6 | CMP | 669 | 11.968 | 8.922 | 29.286 | 1.00 | 34.57 | A |
| ATOM | 3698 | O2 | CMP | 669 | 13.740 | 7.284 | 31.799 | 1.00 | 36.82 | A |
| ATOM | 3699 | N4 | CMP | 669 | 13.748 | 6.423 | 27.394 | 1.00 | 29.67 | A |
| ATOM | 3700 | C1* | CMP | 669 | 12.050 | 9.234 | 31.805 | 1.00 | 42.58 | A |
| ATOM | 3701 | C2* | CMP | 669 | 12.970 | 10.380 | 31.568 | 1.00 | 47.77 | A |
| ATOM | 3702 | O2* | CMP | 669 | 14.186 | 10.165 | 32.303 | 1.00 | 51.39 | A |
| ATOM | 3703 | C3* | CMP | 669 | 12.165 | 11.581 | 32.008 | 1.00 | 46.95 | A |
| ATOM | 3704 | C4* | CMP | 669 | 10.704 | 11.109 | 32.098 | 1.00 | 46.43 | A |
| ATOM | 3705 | O4* | CMP | 669 | 10.761 | 9.730 | 31.773 | 1.00 | 44.13 | A |
| ATOM | 3706 | O3* | CMP | 669 | 12.497 | 11.914 | 33.315 | 1.00 | 47.32 | A |
| ATOM | 3707 | C5* | CMP | 669 | 10.034 | 11.944 | 31.083 | 1.00 | 45.34 | A |
| ATOM | 3708 | O5* | CMP | 669 | 9.238 | 11.092 | 30.258 | 1.00 | 50.10 | A |
| ATOM | 3709 | PA | CMP | 669 | 8.560 | 11.617 | 28.833 | 1.00 | 50.19 | A |
| ATOM | 3710 | O1A | CMP | 669 | 9.312 | 10.986 | 27.655 | 1.00 | 52.54 | A |
| ATOM | 3711 | O2A | CMP | 669 | 7.095 | 11.145 | 28.834 | 1.00 | 52.90 | A |
| ATOM | 3712 | O3A | CMP | 669 | 8.646 | 13.284 | 28.723 | 1.00 | 55.89 | A |
| ATOM | 3713 | ZN | ZN | 300 | 6.895 | 17.558 | 27.745 | 1.00 | 36.09 | A |
| ATOM | 3714 | C4 | CDI | 421 | 4.344 | 16.179 | 34.225 | 1.00 | 47.78 | A |
| ATOM | 3715 | C3 | CDI | 421 | 5.368 | 16.103 | 33.048 | 1.00 | 48.15 | A |
| ATOM | 3716 | OB4 | CDI | 421 | 4.735 | 15.382 | 31.950 | 1.00 | 48.37 | A |
| ATOM | 3717 | PB | CDI | 421 | 4.134 | 15.625 | 30.460 | 1.00 | 50.49 | A |
| ATOM | 3718 | OB2 | CDI | 421 | 3.563 | 14.275 | 29.852 | 1.00 | 48.89 | A |
| ATOM | 3719 | OB3 | CDI | 421 | 2.987 | 16.756 | 30.457 | 1.00 | 45.72 | A |
| ATOM | 3720 | PA | CDI | 421 | 6.563 | 14.965 | 29.544 | 1.00 | 41.22 | A |
| ATOM | 3721 | OA3 | CDI | 421 | 7.209 | 14.553 | 30.965 | 1.00 | 46.68 | A |
| ATOM | 3722 | OA1 | CDI | 421 | 6.256 | 13.700 | 28.652 | 1.00 | 42.46 | A |
| ATOM | 3723 | OA2 | CDI | 421 | 7.472 | 15.975 | 28.721 | 1.00 | 36.91 | A |
| ATOM | 3724 | C1 | CDI | 421 | 7.707 | 15.145 | 32.203 | 1.00 | 47.75 | A |
| ATOM | 3725 | C2 | CDI | 421 | 6.663 | 15.276 | 33.377 | 1.00 | 47.14 | A |
| ATOM | 3726 | O1 | CDI | 421 | 7.389 | 15.876 | 34.454 | 1.00 | 50.89 | A |
| ATOM | 3727 | C5 | CDI | 421 | 5.753 | 17.558 | 32.653 | 1.00 | 46.72 | A |
| ATOM | 3728 | O2 | CDI | 421 | 3.953 | 14.865 | 34.645 | 1.00 | 48.42 | A |
| ATOM | 3729 | OB1 | CDI | 421 | 5.246 | 15.693 | 29.403 | 1.00 | 49.24 | A |
| ATOM | 3731 | OHH | SOL | 501 | 7.989 | 13.687 | 25.725 | 1.00 | 39.44 | A |
| ATOM | 3732 | OHH | SOL | 502 | 2.340 | 26.621 | 30.165 | 1.00 | 35.30 | A |
| ATOM | 3733 | OHH | SOL | 504 | 7.613 | 23.232 | 32.682 | 1.00 | 33.61 | A |
| ATOM | 3734 | OHH | SOL | 506 | 12.781 | 14.480 | 30.595 | 1.00 | 32.91 | A |
| ATOM | 3735 | OHH | SOL | 507 | 10.502 | 15.417 | 28.587 | 1.00 | 36.64 | A |
| ATOM | 3738 | OHH | SOL | 511 | 11.843 | 17.796 | 28.161 | 1.00 | 32.41 | A |
| ATOM | 3739 | OHH | SOL | 512 | 2.498 | 14.032 | 23.548 | 1.00 | 35.90 | A |
| ATOM | 3747 | OHH | SOL | 520 | 1.304 | 21.687 | 39.021 | 1.00 | 65.80 | A |
| ATOM | 3753 | OHH | SOL | 527 | −0.048 | 22.788 | 25.120 | 1.00 | 48.13 | A |
| ATOM | 3757 | OHH | SOL | 531 | 3.365 | 13.208 | 27.540 | 1.00 | 44.73 | A |
| ATOM | 3764 | OHH | SOL | 539 | 6.906 | 18.915 | 43.372 | 1.00 | 66.68 | A |
| ATOM | 3774 | OHH | SOL | 551 | −3.291 | 24.034 | 33.005 | 1.00 | 75.47 | A |
| ATOM | 3776 | OHH | SOL | 555 | 10.474 | 9.846 | 38.866 | 1.00 | 75.90 | A |
| ATOM | 3782 | OHH | SOL | 563 | 4.170 | 9.305 | 41.251 | 1.00 | 66.69 | A |
| ATOM | 3794 | OHH | SOL | 583 | 15.433 | 16.973 | 27.839 | 1.00 | 37.18 | A |
| ATOM | 3797 | OHH | SOL | 586 | 1.956 | 11.593 | 30.373 | 1.00 | 74.17 | A |

Annex 1: Coordinates of structure cyt

| | | | | | | | | | | |
|---|---|---|---|---|---|---|---|---|---|---|
| ATOM | 1 | CB | MET | 1 | 29.965 | 34.378 | 29.582 | 1.00 | 64.68 | A |
| ATOM | 2 | CG | MET | 1 | 31.136 | 34.198 | 28.685 | 1.00 | 74.36 | A |
| ATOM | 3 | SD | MET | 1 | 32.101 | 32.841 | 29.285 | 1.00 | 88.97 | A |
| ATOM | 4 | CE | MET | 1 | 33.613 | 33.734 | 29.803 | 1.00 | 89.11 | A |
| ATOM | 5 | C | MET | 1 | 27.684 | 34.972 | 28.857 | 1.00 | 57.18 | A |
| ATOM | 6 | O | MET | 1 | 26.930 | 34.692 | 29.780 | 1.00 | 58.31 | A |
| ATOM | 7 | HT1 | MET | 1 | 28.597 | 36.131 | 30.990 | 0.00 | 0.00 | A |
| ATOM | 8 | HT2 | MET | 1 | 28.453 | 37.366 | 29.854 | 0.00 | 0.00 | A |
| ATOM | 9 | N | MET | 1 | 29.061 | 36.593 | 30.179 | 1.00 | 61.29 | A |
| ATOM | 10 | HT3 | MET | 1 | 30.019 | 36.903 | 30.418 | 0.00 | 0.00 | A |
| ATOM | 11 | CA | MET | 1 | 29.073 | 35.515 | 29.140 | 1.00 | 60.77 | A |
| ATOM | 12 | N | ARG | 2 | 27.347 | 34.803 | 27.588 | 1.00 | 53.30 | A |
| ATOM | 13 | H | ARG | 2 | 27.973 | 34.938 | 26.848 | 0.00 | 0.00 | A |
| ATOM | 14 | CA | ARG | 2 | 26.029 | 34.309 | 27.242 | 1.00 | 50.95 | A |
| ATOM | 15 | CB | ARG | 2 | 25.183 | 35.452 | 26.700 | 1.00 | 49.61 | A |
| ATOM | 16 | CG | ARG | 2 | 24.881 | 36.448 | 27.799 | 1.00 | 51.88 | A |
| ATOM | 17 | CD | ARG | 2 | 24.315 | 37.733 | 27.283 | 1.00 | 52.99 | A |
| ATOM | 18 | NE | ARG | 2 | 23.042 | 37.514 | 26.630 | 1.00 | 56.08 | A |
| ATOM | 19 | HE | ARG | 2 | 23.081 | 37.048 | 25.780 | 0.00 | 0.00 | A |
| ATOM | 20 | CZ | ARG | 2 | 21.859 | 37.849 | 27.138 | 1.00 | 58.76 | A |
| ATOM | 21 | NH1 | ARG | 2 | 20.766 | 37.595 | 26.433 | 1.00 | 61.54 | A |
| ATOM | 22 | HH11 | ARG | 2 | 20.824 | 37.136 | 25.545 | 0.00 | 0.00 | A |
| ATOM | 23 | HH12 | ARG | 2 | 19.859 | 37.847 | 26.768 | 0.00 | 0.00 | A |
| ATOM | 24 | NH2 | ARG | 2 | 21.761 | 38.387 | 28.354 | 1.00 | 58.40 | A |
| ATOM | 25 | HH21 | ARG | 2 | 22.536 | 38.550 | 28.960 | 0.00 | 0.00 | A |
| ATOM | 26 | HH22 | ARG | 2 | 20.854 | 38.651 | 28.733 | 0.00 | 0.00 | A |
| ATOM | 27 | C | ARG | 2 | 26.075 | 33.129 | 26.296 | 1.00 | 49.62 | A |
| ATOM | 28 | O | ARG | 2 | 27.010 | 32.993 | 25.513 | 1.00 | 50.93 | A |
| ATOM | 29 | N | ILE | 3 | 25.069 | 32.268 | 26.383 | 1.00 | 47.94 | A |
| ATOM | 30 | H | ILE | 3 | 24.290 | 32.466 | 26.945 | 0.00 | 0.00 | A |
| ATOM | 31 | CA | ILE | 3 | 25.010 | 31.072 | 25.558 | 1.00 | 47.03 | A |
| ATOM | 32 | CB | ILE | 3 | 24.781 | 29.844 | 26.443 | 1.00 | 47.80 | A |
| ATOM | 33 | CG2 | ILE | 3 | 23.443 | 29.944 | 27.139 | 1.00 | 46.70 | A |
| ATOM | 34 | CG1 | ILE | 3 | 24.830 | 28.568 | 25.617 | 1.00 | 48.83 | A |
| ATOM | 35 | CD1 | ILE | 3 | 24.545 | 27.340 | 26.444 | 1.00 | 50.51 | A |
| ATOM | 36 | C | ILE | 3 | 23.885 | 31.163 | 24.549 | 1.00 | 45.56 | A |
| ATOM | 37 | O | ILE | 3 | 22.860 | 31.759 | 24.824 | 1.00 | 45.92 | A |
| ATOM | 38 | N | GLY | 4 | 24.062 | 30.565 | 23.385 | 1.00 | 44.38 | A |
| ATOM | 39 | H | GLY | 4 | 24.882 | 30.070 | 23.188 | 0.00 | 0.00 | A |
| ATOM | 40 | CA | GLY | 4 | 23.007 | 30.618 | 22.395 | 1.00 | 43.98 | A |
| ATOM | 41 | C | GLY | 4 | 22.856 | 29.286 | 21.702 | 1.00 | 42.90 | A |
| ATOM | 42 | O | GLY | 4 | 23.818 | 28.519 | 21.624 | 1.00 | 45.40 | A |
| ATOM | 43 | N | HIS | 5 | 21.656 | 28.989 | 21.219 | 1.00 | 40.24 | A |
| ATOM | 44 | H | HIS | 5 | 20.959 | 29.642 | 21.312 | 0.00 | 0.00 | A |
| ATOM | 45 | CA | HIS | 5 | 21.406 | 27.740 | 20.518 | 1.00 | 39.60 | A |
| ATOM | 46 | CB | HIS | 5 | 20.586 | 26.772 | 21.354 | 1.00 | 38.24 | A |
| ATOM | 47 | CG | HIS | 5 | 20.199 | 25.530 | 20.615 | 1.00 | 38.16 | A |
| ATOM | 48 | CD2 | HIS | 5 | 20.874 | 24.374 | 20.392 | 1.00 | 37.49 | A |
| ATOM | 49 | ND1 | HIS | 5 | 18.986 | 25.395 | 19.975 | 1.00 | 37.88 | A |
| ATOM | 50 | HD1 | HIS | 5 | 18.239 | 26.037 | 19.949 | 0.00 | 0.00 | A |
| ATOM | 51 | CE1 | HIS | 5 | 18.928 | 24.209 | 19.391 | 1.00 | 39.53 | A |
| ATOM | 52 | NE2 | HIS | 5 | 20.059 | 23.570 | 19.631 | 1.00 | 37.92 | A |
| ATOM | 53 | HE2 | HIS | 5 | 20.166 | 22.615 | 19.382 | 0.00 | 0.00 | A |
| ATOM | 54 | C | HIS | 5 | 20.652 | 27.972 | 19.239 | 1.00 | 40.41 | A |
| ATOM | 55 | O | HIS | 5 | 19.642 | 28.680 | 19.231 | 1.00 | 41.83 | A |
| ATOM | 56 | N | GLY | 6 | 21.088 | 27.293 | 18.165 | 1.00 | 39.46 | A |
| ATOM | 57 | H | GLY | 6 | 21.862 | 26.695 | 18.251 | 0.00 | 0.00 | A |
| ATOM | 58 | CA | GLY | 6 | 20.434 | 27.413 | 16.899 | 1.00 | 40.41 | A |
| ATOM | 59 | C | GLY | 6 | 20.152 | 26.043 | 16.314 | 1.00 | 40.56 | A |
| ATOM | 60 | O | GLY | 6 | 20.753 | 25.046 | 16.745 | 1.00 | 41.32 | A |
| ATOM | 61 | N | PHE | 7 | 19.234 | 25.991 | 15.352 | 1.00 | 38.82 | A |
| ATOM | 62 | H | PHE | 7 | 18.775 | 26.805 | 15.036 | 0.00 | 0.00 | A |
| ATOM | 63 | CA | PHE | 7 | 18.873 | 24.745 | 14.694 | 1.00 | 38.23 | A |
| ATOM | 64 | CB | PHE | 7 | 17.943 | 23.944 | 15.580 | 1.00 | 37.28 | A |
| ATOM | 65 | CG | PHE | 7 | 17.391 | 22.732 | 14.922 | 1.00 | 35.86 | A |
| ATOM | 66 | CD1 | PHE | 7 | 17.992 | 21.508 | 15.093 | 1.00 | 35.35 | A |
| ATOM | 67 | CD2 | PHE | 7 | 16.275 | 22.815 | 14.115 | 1.00 | 39.42 | A |
| ATOM | 68 | CE1 | PHE | 7 | 17.495 | 20.377 | 14.468 | 1.00 | 35.48 | A |
| ATOM | 69 | CE2 | PHE | 7 | 15.773 | 21.685 | 13.483 | 1.00 | 40.67 | A |
| ATOM | 70 | CZ | PHE | 7 | 16.389 | 20.463 | 13.662 | 1.00 | 35.86 | A |
| ATOM | 71 | C | PHE | 7 | 18.159 | 25.058 | 13.400 | 1.00 | 39.38 | A |
| ATOM | 72 | O | PHE | 7 | 17.287 | 25.924 | 13.391 | 1.00 | 41.84 | A |
| ATOM | 73 | N | ASP | 8 | 18.476 | 24.319 | 12.338 | 1.00 | 38.56 | A |
| ATOM | 74 | H | ASP | 8 | 19.154 | 23.613 | 12.408 | 0.00 | 0.00 | A |
| ATOM | 75 | CA | ASP | 8 | 17.849 | 24.542 | 11.042 | 1.00 | 39.61 | A |
| ATOM | 76 | CB | ASP | 8 | 18.566 | 25.681 | 10.325 | 1.00 | 41.99 | A |
| ATOM | 77 | CG | ASP | 8 | 17.855 | 26.120 | 9.060 | 1.00 | 45.27 | A |
| ATOM | 78 | OD1 | ASP | 8 | 18.545 | 26.556 | 8.114 | 1.00 | 49.59 | A |
| ATOM | 79 | OD2 | ASP | 8 | 16.612 | 26.035 | 8.999 | 1.00 | 48.12 | A |
| ATOM | 80 | C | ASP | 8 | 17.806 | 23.284 | 10.155 | 1.00 | 40.21 | A |
| ATOM | 81 | O | ASP | 8 | 18.629 | 22.379 | 10.306 | 1.00 | 42.80 | A |
| ATOM | 82 | N | VAL | 9 | 16.844 | 23.231 | 9.235 | 1.00 | 38.60 | A |
| ATOM | 83 | H | VAL | 9 | 16.234 | 24.001 | 9.146 | 0.00 | 0.00 | A |
| ATOM | 84 | CA | VAL | 9 | 16.663 | 22.099 | 8.328 | 1.00 | 35.92 | A |
| ATOM | 85 | CB | VAL | 9 | 15.511 | 21.215 | 8.823 | 1.00 | 34.35 | A |
| ATOM | 86 | CG1 | VAL | 9 | 15.135 | 20.174 | 7.801 | 1.00 | 32.85 | A |
| ATOM | 87 | CG2 | VAL | 9 | 15.893 | 20.557 | 10.102 | 1.00 | 35.09 | A |
| ATOM | 88 | C | VAL | 9 | 16.283 | 22.619 | 6.946 | 1.00 | 37.41 | A |
| ATOM | 89 | O | VAL | 9 | 15.680 | 23.680 | 6.829 | 1.00 | 40.43 | A |
| ATOM | 90 | N | HIS | 10 | 16.690 | 21.920 | 5.895 | 1.00 | 38.39 | A |
| ATOM | 91 | H | HIS | 10 | 17.238 | 21.115 | 6.045 | 0.00 | 0.00 | A |
| ATOM | 92 | CA | HIS | 10 | 16.340 | 22.302 | 4.522 | 1.00 | 39.79 | A |
| ATOM | 93 | CB | HIS | 10 | 17.366 | 23.252 | 3.903 | 1.00 | 41.27 | A |
| ATOM | 94 | CG | HIS | 10 | 17.242 | 24.662 | 4.387 | 1.00 | 44.65 | A |
| ATOM | 95 | CD2 | HIS | 10 | 17.930 | 25.350 | 5.331 | 1.00 | 47.80 | A |
| ATOM | 96 | ND1 | HIS | 10 | 16.263 | 25.514 | 3.934 | 1.00 | 45.71 | A |
| ATOM | 97 | HD1 | HIS | 10 | 15.546 | 25.296 | 3.283 | 0.00 | 0.00 | A |
| ATOM | 98 | CE1 | HIS | 10 | 16.348 | 26.665 | 4.583 | 1.00 | 50.22 | A |
| ATOM | 99 | NE2 | HIS | 10 | 17.352 | 26.594 | 5.439 | 1.00 | 50.26 | A |
| ATOM | 100 | C | HIS | 10 | 16.191 | 21.029 | 3.699 | 1.00 | 39.71 | A |
| ATOM | 101 | O | HIS | 10 | 16.893 | 20.045 | 3.926 | 1.00 | 40.23 | A |
| ATOM | 102 | N | ALA | 11 | 15.212 | 21.017 | 2.808 | 1.00 | 39.52 | A |
| ATOM | 103 | H | ALA | 11 | 14.643 | 21.803 | 2.692 | 0.00 | 0.00 | A |
| ATOM | 104 | CA | ALA | 11 | 14.957 | 19.842 | 1.996 | 1.00 | 38.91 | A |
| ATOM | 105 | CB | ALA | 11 | 13.493 | 19.792 | 1.634 | 1.00 | 42.30 | A |
| ATOM | 106 | C | ALA | 11 | 15.806 | 19.823 | 0.738 | 1.00 | 39.34 | A |
| ATOM | 107 | O | ALA | 11 | 16.217 | 20.869 | 0.246 | 1.00 | 40.69 | A |
| ATOM | 108 | N | PHE | 12 | 16.103 | 18.634 | 0.237 | 1.00 | 39.12 | A |
| ATOM | 109 | H | PHE | 12 | 15.759 | 17.820 | 0.667 | 0.00 | 0.00 | A |
| ATOM | 110 | CA | PHE | 12 | 16.887 | 18.521 | −0.980 | 1.00 | 38.55 | A |
| ATOM | 111 | CB | PHE | 12 | 17.466 | 17.118 | −1.120 | 1.00 | 36.90 | A |
| ATOM | 112 | CG | PHE | 12 | 18.730 | 16.898 | −0.346 | 1.00 | 35.38 | A |
| ATOM | 113 | CD1 | PHE | 12 | 19.828 | 17.725 | −0.533 | 1.00 | 35.26 | A |
| ATOM | 114 | CD2 | PHE | 12 | 18.834 | 15.847 | 0.547 | 1.00 | 33.72 | A |
| ATOM | 115 | CE1 | PHE | 12 | 21.011 | 17.505 | 0.157 | 1.00 | 33.59 | A |
| ATOM | 116 | CE2 | PHE | 12 | 20.017 | 15.622 | 1.239 | 1.00 | 34.13 | A |
| ATOM | 117 | CZ | PHE | 12 | 21.106 | 16.455 | 1.040 | 1.00 | 32.93 | A |
| ATOM | 118 | C | PHE | 12 | 15.960 | 18.810 | −2.153 | 1.00 | 41.15 | A |
| ATOM | 119 | O | PHE | 12 | 14.762 | 18.528 | −2.095 | 1.00 | 40.65 | A |
| ATOM | 120 | N | GLY | 13 | 16.507 | 19.391 | −3.209 | 1.00 | 44.54 | A |
| ATOM | 121 | H | GLY | 13 | 17.447 | 19.633 | −3.235 | 0.00 | 0.00 | A |
| ATOM | 122 | CA | GLY | 13 | 15.703 | 19.700 | −4.373 | 1.00 | 49.82 | A |
| ATOM | 123 | C | GLY | 13 | 16.545 | 20.250 | −5.504 | 1.00 | 54.70 | A |
| ATOM | 124 | O | GLY | 13 | 17.481 | 21.031 | −5.288 | 1.00 | 56.79 | A |
| ATOM | 125 | N | GLY | 14 | 16.224 | 19.827 | −6.719 | 1.00 | 57.42 | A |
| ATOM | 126 | H | GLY | 14 | 15.516 | 19.166 | −6.832 | 0.00 | 0.00 | A |
| ATOM | 127 | CA | GLY | 14 | 16.960 | 20.299 | −7.875 | 1.00 | 62.89 | A |
| ATOM | 128 | C | GLY | 14 | 18.310 | 19.636 | −7.970 | 1.00 | 65.94 | A |
| ATOM | 129 | O | GLY | 14 | 18.569 | 18.639 | −7.287 | 1.00 | 66.52 | A |
| ATOM | 130 | N | GLU | 15 | 19.152 | 20.157 | −8.851 | 1.00 | 68.38 | A |
| ATOM | 131 | H | GLU | 15 | 18.900 | 20.920 | −9.398 | 0.00 | 0.00 | A |
| ATOM | 132 | CA | GLU | 15 | 20.489 | 19.611 | −9.016 | 1.00 | 70.78 | A |
| ATOM | 133 | CB | GLU | 15 | 21.019 | 19.896 | −10.432 | 1.00 | 77.17 | A |
| ATOM | 134 | CG | GLU | 15 | 20.228 | 19.239 | −11.555 | 1.00 | 85.74 | A |
| ATOM | 135 | CD | GLU | 15 | 20.150 | 17.724 | −11.400 | 1.00 | 92.79 | A |
| ATOM | 136 | OE1 | GLU | 15 | 19.073 | 17.220 | −10.992 | 1.00 | 95.97 | A |
| ATOM | 137 | OE2 | GLU | 15 | 21.167 | 17.042 | −11.679 | 1.00 | 96.24 | A |
| ATOM | 138 | C | GLU | 15 | 21.376 | 20.292 | −7.982 | 1.00 | 68.23 | A |
| ATOM | 139 | O | GLU | 15 | 21.019 | 21.364 | −7.470 | 1.00 | 68.59 | A |
| ATOM | 140 | N | GLY | 16 | 22.492 | 19.649 | −7.642 | 1.00 | 64.65 | A |
| ATOM | 141 | H | GLY | 16 | 22.664 | 18.770 | −8.049 | 0.00 | 0.00 | A |
| ATOM | 142 | CA | GLY | 16 | 23.426 | 20.229 | −6.690 | 1.00 | 59.66 | A |
| ATOM | 143 | C | GLY | 16 | 24.219 | 21.346 | −7.350 | 1.00 | 55.53 | A |
| ATOM | 144 | O | GLY | 16 | 23.856 | 21.785 | −8.439 | 1.00 | 56.39 | A |
| ATOM | 145 | N | CPR | 17 | 25.310 | 21.825 | −6.741 | 1.00 | 50.93 | A |
| ATOM | 146 | CD | CPR | 17 | 25.977 | 22.957 | −7.401 | 1.00 | 48.91 | A |
| ATOM | 147 | CA | CPR | 17 | 25.979 | 21.507 | −5.487 | 1.00 | 48.65 | A |
| ATOM | 148 | CB | CPR | 17 | 27.343 | 22.123 | −5.701 | 1.00 | 49.62 | A |
| ATOM | 149 | CG | CPR | 17 | 26.978 | 23.400 | −6.368 | 1.00 | 48.24 | A |
| ATOM | 150 | C | CPR | 17 | 25.259 | 22.227 | −4.364 | 1.00 | 47.36 | A |
| ATOM | 151 | O | CPR | 17 | 24.449 | 23.121 | −4.606 | 1.00 | 52.02 | A |
| ATOM | 152 | N | ILE | 18 | 25.551 | 21.845 | −3.135 | 1.00 | 42.30 | A |
| ATOM | 153 | H | ILE | 18 | 26.232 | 21.163 | −2.972 | 0.00 | 0.00 | A |
| ATOM | 154 | CA | ILE | 18 | 24.912 | 22.478 | −2.017 | 1.00 | 37.54 | A |
| ATOM | 155 | CB | ILE | 18 | 24.435 | 21.444 | −0.964 | 1.00 | 37.61 | A |
| ATOM | 156 | CG2 | ILE | 18 | 23.499 | 20.441 | −1.600 | 1.00 | 39.88 | A |
| ATOM | 157 | CG1 | ILE | 18 | 25.597 | 20.671 | −0.356 | 1.00 | 37.39 | A |
| ATOM | 158 | CD1 | ILE | 18 | 25.131 | 19.646 | 0.680 | 1.00 | 36.52 | A |
| ATOM | 159 | C | ILE | 18 | 25.929 | 23.412 | −1.425 | 1.00 | 36.81 | A |
| ATOM | 160 | O | ILE | 18 | 27.103 | 23.352 | −1.778 | 1.00 | 37.64 | A |
| ATOM | 161 | N | ILE | 19 | 25.471 | 24.310 | −0.566 | 1.00 | 35.94 | A |
| ATOM | 162 | H | ILE | 19 | 24.519 | 24.361 | −0.340 | 0.00 | 0.00 | A |
| ATOM | 163 | CA | ILE | 19 | 26.357 | 25.243 | 0.089 | 1.00 | 33.87 | A |
| ATOM | 164 | CB | ILE | 19 | 25.968 | 26.649 | −0.216 | 1.00 | 31.80 | A |
| ATOM | 165 | CG2 | ILE | 19 | 27.044 | 27.563 | 0.242 | 1.00 | 32.88 | A |
| ATOM | 166 | CG1 | ILE | 19 | 25.762 | 26.824 | −1.706 | 1.00 | 34.76 | A |
| ATOM | 167 | CD1 | ILE | 19 | 26.990 | 26.618 | −2.503 | 1.00 | 39.21 | A |
| ATOM | 168 | C | ILE | 19 | 26.159 | 25.047 | 1.577 | 1.00 | 36.22 | A |
| ATOM | 169 | O | ILE | 19 | 25.058 | 25.267 | 2.078 | 1.00 | 39.60 | A |
| ATOM | 170 | N | ILE | 20 | 27.207 | 24.611 | 2.271 | 1.00 | 35.58 | A |
| ATOM | 171 | H | ILE | 20 | 28.062 | 24.475 | 1.807 | 0.00 | 0.00 | A |
| ATOM | 172 | CA | ILE | 20 | 27.158 | 24.372 | 3.707 | 1.00 | 33.46 | A |
| ATOM | 173 | CB | ILE | 20 | 27.210 | 22.868 | 4.018 | 1.00 | 32.42 | A |
| ATOM | 174 | CG2 | ILE | 20 | 27.117 | 22.649 | 5.501 | 1.00 | 32.88 | A |
| ATOM | 175 | CG1 | ILE | 20 | 26.061 | 22.124 | 3.335 | 1.00 | 33.43 | A |
| ATOM | 176 | CD1 | ILE | 20 | 24.680 | 22.434 | 3.895 | 1.00 | 32.66 | A |
| ATOM | 177 | C | ILE | 20 | 28.376 | 25.011 | 4.362 | 1.00 | 35.25 | A |
| ATOM | 178 | O | ILE | 20 | 29.511 | 24.734 | 3.977 | 1.00 | 36.55 | A |
| ATOM | 179 | N | GLY | 21 | 28.150 | 25.848 | 5.366 | 1.00 | 35.43 | A |
| ATOM | 180 | H | GLY | 21 | 27.232 | 26.066 | 5.608 | 0.00 | 0.00 | A |
| ATOM | 181 | CA | GLY | 21 | 29.257 | 26.489 | 6.046 | 1.00 | 34.06 | A |
| ATOM | 182 | C | GLY | 21 | 30.033 | 27.334 | 5.069 | 1.00 | 34.09 | A |
| ATOM | 183 | O | GLY | 21 | 31.242 | 27.472 | 5.173 | 1.00 | 36.46 | A |
| ATOM | 184 | N | GLY | 22 | 29.342 | 27.848 | 4.071 | 1.00 | 34.29 | A |
| ATOM | 185 | H | GLY | 22 | 28.395 | 27.654 | 3.993 | 0.00 | 0.00 | A |
| ATOM | 186 | CA | GLY | 22 | 29.991 | 28.674 | 3.076 | 1.00 | 36.51 | A |
| ATOM | 187 | C | GLY | 22 | 30.633 | 27.912 | 1.930 | 1.00 | 37.87 | A |
| ATOM | 188 | O | GLY | 22 | 30.842 | 28.481 | 0.853 | 1.00 | 39.41 | A |
| ATOM | 189 | N | VAL | 23 | 30.922 | 26.628 | 2.128 | 1.00 | 36.95 | A |
| ATOM | 190 | H | VAL | 23 | 30.691 | 26.199 | 2.978 | 0.00 | 0.00 | A |
| ATOM | 191 | CA | VAL | 23 | 31.564 | 25.835 | 1.086 | 1.00 | 36.33 | A |
| ATOM | 192 | CB | VAL | 23 | 32.372 | 24.697 | 1.684 | 1.00 | 32.44 | A |
| ATOM | 193 | CG1 | VAL | 23 | 33.159 | 23.995 | 0.612 | 1.00 | 34.46 | A |
| ATOM | 194 | CG2 | VAL | 23 | 33.297 | 25.224 | 2.729 | 1.00 | 33.35 | A |
| ATOM | 195 | C | VAL | 23 | 30.594 | 25.247 | 0.076 | 1.00 | 38.63 | A |
| ATOM | 196 | O | VAL | 23 | 29.489 | 24.836 | 0.425 | 1.00 | 41.44 | A |
| ATOM | 197 | N | ARG | 24 | 31.012 | 25.220 | −1.184 | 1.00 | 39.19 | A |
| ATOM | 198 | H | ARG | 24 | 31.882 | 25.577 | −1.374 | 0.00 | 0.00 | A |
| ATOM | 199 | CA | ARG | 24 | 30.196 | 24.669 | −2.252 | 1.00 | 38.82 | A |
| ATOM | 200 | CB | ARG | 24 | 30.529 | 25.351 | −3.570 | 1.00 | 42.10 | A |
| ATOM | 201 | CG | ARG | 24 | 29.719 | 24.837 | −4.741 | 1.00 | 52.55 | A |
| ATOM | 202 | CD | ARG | 24 | 30.257 | 25.344 | −6.088 | 1.00 | 62.02 | A |
| ATOM | 203 | NE | ARG | 24 | 29.237 | 26.014 | −6.902 | 1.00 | 68.86 | A |
| ATOM | 204 | HE | ARG | 24 | 28.880 | 26.835 | −6.489 | 0.00 | 0.00 | A |
| ATOM | 205 | CZ | ARG | 24 | 28.812 | 25.588 | −8.093. | 1.00 | 73.18 | A |
| ATOM | 206 | NH1 | ARG | 24 | 27.885 | 26.291 | −8.738 | 1.00 | 74.51 | A |
| ATOM | 207 | HH11 | ARG | 24 | 27.519 | 27.133 | −8.327 | 0.00 | 0.00 | A |
| ATOM | 208 | HH12 | ARG | 24 | 27.516 | 26.040 | −9.635 | 0.00 | 0.00 | A |
| ATOM | 209 | NH2 | ARG | 24 | 29.292 | 24.457 | −8.632 | 1.00 | 74.42 | A |
| ATOM | 210 | HH21 | ARG | 24 | 29.979 | 23.922 | −8.133 | 0.00 | 0.00 | A |
| ATOM | 211 | HH22 | ARG | 24 | 28.976 | 24.113 | −9.517 | 0.00 | 0.00 | A |
| ATOM | 212 | C | ARG | 24 | 30.546 | 23.207 | −2.336 | 1.00 | 36.82 | A |
| ATOM | 213 | O | ARG | 24 | 31.575 | 22.850 | −2.897 | 1.00 | 40.97 | A |
| ATOM | 214 | N | ILE | 25 | 29.749 | 22.368 | −1.703 | 1.00 | 34.88 | A |
| ATOM | 215 | H | ILE | 25 | 28.946 | 22.718 | −1.258 | 0.00 | 0.00 | A |
| ATOM | 216 | CA | ILE | 25 | 30.006 | 20.939 | −1.714 | 1.00 | 33.15 | A |
| ATOM | 217 | CB | ILE | 25 | 29.556 | 20.287 | −0.422 | 1.00 | 30.96 | A |
| ATOM | 218 | CG2 | ILE | 25 | 29.756 | 18.814 | −0.507 | 1.00 | 29.02 | A |
| ATOM | 219 | CG1 | ILE | 25 | 30.344 | 20.858 | 0.750 | 1.00 | 28.00 | A |
| ATOM | 220 | CD1 | ILE | 25 | 29.696 | 20.586 | 2.069 | 1.00 | 27.44 | A |
| ATOM | 221 | C | ILE | 25 | 29.210 | 20.340 | −2.836 | 1.00 | 33.91 | A |
| ATOM | 222 | O | ILE | 25 | 28.053 | 20.680 | −3.023 | 1.00 | 37.29 | A |
| ATOM | 223 | N | PRO | 26 | 29.823 | 19.465 | −3.626 | 1.00 | 34.94 | A |
| ATOM | 224 | CD | PRO | 26 | 31.264 | 19.182 | −3.716 | 1.00 | 36.65 | A |
| ATOM | 225 | CA | PRO | 26 | 29.111 | 18.844 | −4.739 | 1.00 | 36.25 | A |
| ATOM | 226 | CB | PRO | 26 | 30.250 | 18.337 | −5.613 | 1.00 | 33.58 | A |
| ATOM | 227 | CG | PRO | 26 | 31.301 | 18.007 | −4.652 | 1.00 | 31.45 | A |
| ATOM | 228 | C | PRO | 26 | 28.212 | 17.719 | −4.290 | 1.00 | 37.95 | A |
| ATOM | 229 | O | PRO | 26 | 28.618 | 16.889 | −3.480 | 1.00 | 40.88 | A |
| ATOM | 230 | N | TYR | 27 | 27.001 | 17.679 | −4.833 | 1.00 | 39.83 | A |
| ATOM | 231 | H | TYR | 27 | 26.717 | 18.343 | −5.496 | 0.00 | 0.00 | A |
| ATOM | 232 | CA | TYR | 27 | 26.035 | 16.641 | −4.493 | 1.00 | 42.26 | A |
| ATOM | 233 | CB | TYR | 27 | 25.263 | 17.039 | −3.248 | 1.00 | 41.75 | A |
| ATOM | 234 | CG | TYR | 27 | 24.462 | 15.927 | −2.645 | 1.00 | 39.96 | A |
| ATOM | 235 | CD1 | TYR | 27 | 25.051 | 14.714 | −2.344 | 1.00 | 37.64 | A |
| ATOM | 236 | CE1 | TYR | 27 | 24.322 | 13.691 | −1.785 | 1.00 | 39.67 | A |
| ATOM | 237 | CD2 | TYR | 27 | 23.115 | 16.095 | −2.370 | 1.00 | 40.37 | A |
| ATOM | 238 | CE2 | TYR | 27 | 22.378 | 15.083 | −1.812 | 1.00 | 42.16 | A |
| ATOM | 239 | CZ | TYR | 27 | 22.988 | 13.879 | −1.524 | 1.00 | 41.60 | A |
| ATOM | 240 | OH | TYR | 27 | 22.244 | 12.857 | −0.991 | 1.00 | 45.39 | A |
| ATOM | 241 | HH | TYR | 27 | 22.808 | 12.066 | −1.009 | 0.00 | 0.00 | A |
| ATOM | 242 | C | TYR | 27 | 25.067 | 16.486 | −5.651 | 1.00 | 45.94 | A |
| ATOM | 243 | O | TYR | 27 | 24.864 | 17.429 | −6.424 | 1.00 | 46.76 | A |
| ATOM | 244 | N | GLU | 28 | 24.465 | 15.306 | −5.770 | 1.00 | 50.51 | A |
| ATOM | 245 | H | GLU | 28 | 24.665 | 14.612 | −5.113 | 0.00 | 0.00 | A |
| ATOM | 246 | CA | GLU | 28 | 23.522 | 15.047 | −6.866 | 1.00 | 53.21 | A |
| ATOM | 247 | CB | GLU | 28 | 22.887 | 13.656 | −6.758 | 1.00 | 57.75 | A |
| ATOM | 248 | CG | GLU | 28 | 23.583 | 12.663 | −5.835 | 1.00 | 66.55 | A |
| ATOM | 249 | CD | GLU | 28 | 22.585 | 11.706 | −5.178 | 1.00 | 72.26 | A |
| ATOM | 250 | OE1 | GLU | 28 | 23.008 | 10.640 | −4.666 | 1.00 | 75.44 | A |
| ATOM | 251 | OE2 | GLU | 28 | 21.373 | 12.038 | −5.148 | 1.00 | 75.71 | A |
| ATOM | 252 | C | GLU | 28 | 22.407 | 16.073 | −6.825 | 1.00 | 50.46 | A |
| ATOM | 253 | O | GLU | 28 | 22.126 | 16.747 | −7.809 | 1.00 | 51.63 | A |
| ATOM | 254 | N | LYS | 29 | 21.801 | 16.197 | −5.655 | 1.00 | 47.76 | A |
| ATOM | 255 | H | LYS | 29 | 22.144 | 15.674 | −4.909 | 0.00 | 0.00 | A |
| ATOM | 256 | CA | LYS | 29 | 20.703 | 17.116 | −5.462 | 1.00 | 46.31 | A |
| ATOM | 257 | CB | LYS | 29 | 19.536 | 16.410 | −4.747 | 1.00 | 47.77 | A |
| ATOM | 258 | CG | LYS | 29 | 19.864 | 15.039 | −4.109 | 1.00 | 48.88 | A |
| ATOM | 259 | CD | LYS | 29 | 18.579 | 14.337 | −3.620 | 1.00 | 52.52 | A |
| ATOM | 260 | CE | LYS | 29 | 18.839 | 13.011 | −2.878 | 1.00 | 53.39 | A |
| ATOM | 261 | NZ | LYS | 29 | 19.415 | 13.147 | −1.505 | 1.00 | 50.81 | A |
| ATOM | 262 | HZ1 | LYS | 29 | 18.772 | 13.645 | −0.851 | 0.00 | 0.00 | A |
| ATOM | 263 | HZ2 | LYS | 29 | 20.366 | 13.578 | −1.528 | 0.00 | 0.00 | A |
| ATOM | 264 | HZ3 | LYS | 29 | 19.562 | 12.185 | −1.140 | 0.00 | 0.00 | A |
| ATOM | 265 | C | LYS | 29 | 21.143 | 18.349 | −4.699 | 1.00 | 43.93 | A |
| ATOM | 266 | O | LYS | 29 | 22.210 | 18.359 | −4.098 | 1.00 | 42.33 | A |
| ATOM | 267 | N | GLY | 30 | 20.327 | 19.393 | −4.759 | 1.00 | 42.98 | A |
| ATOM | 268 | H | GLY | 30 | 19.509 | 19.334 | −5.296 | 0.00 | 0.00 | A |
| ATOM | 269 | CA | GLY | 30 | 20.630 | 20.628 | −4.062 | 1.00 | 43.79 | A |
| ATOM | 270 | C | GLY | 30 | 19.702 | 20.789 | −2.881 | 1.00 | 44.51 | A |
| ATOM | 271 | O | GLY | 30 | 19.073 | 19.810 | −2.474 | 1.00 | 46.21 | A |
| ATOM | 272 | N | LEU | 31 | 19.605 | 22.002 | −2.333 | 1.00 | 44.38 | A |
| ATOM | 273 | H | LEU | 31 | 20.092 | 22.753 | −2.732 | 0.00 | 0.00 | A |
| ATOM | 274 | CA | LEU | 31 | 18.743 | 22.282 | −1.176 | 1.00 | 43.59 | A |
| ATOM | 275 | CB | LEU | 31 | 19.566 | 22.711 | 0.036 | 1.00 | 38.26 | A |
| ATOM | 276 | CG | LEU | 31 | 20.341 | 21.585 | 0.698 | 1.00 | 35.90 | A |
| ATOM | 277 | CD1 | LEU | 31 | 21.235 | 22.100 | 1.789 | 1.00 | 34.43 | A |
| ATOM | 278 | CD2 | LEU | 31 | 19.349 | 20.612 | 1.253− | 1.00 | 37.81 | A |
| ATOM | 279 | C | LEU | 31 | 17.743 | 23.365 | −1.482 | 1.00 | 45.25 | A |
| ATOM | 280 | O | LEU | 31 | 18.082 | 24.392 | −2.052 | 1.00 | 48.42 | A |
| ATOM | 281 | N | LEU | 32 | 16.510 | 23.153 | −1.068 | 1.00 | 47.61 | A |
| ATOM | 282 | H | LEU | 32 | 16.293 | 22.359 | −0.592 | 0.00 | 0.00 | A |
| ATOM | 283 | CA | LEU | 32 | 15.456 | 24.117 | −1.304 | 1.00 | 50.84 | A |
| ATOM | 284 | CB | LEU | 32 | 14.128 | 23.386 | −1.328 | 1.00 | 49.60 | A |
| ATOM | 285 | CG | LEU | 32 | 14.136 | 22.294 | −2.388 | 1.00 | 50.43 | A |
| ATOM | 286 | CD1 | LEU | 32 | 12.837 | 21.512 | −2.361 | 1.00 | 52.26 | A |
| ATOM | 287 | CD2 | LEU | 32 | 14.359 | 22.931 | −3.739 | 1.00 | 51.10 | A |
| ATOM | 288 | C | LEU | 32 | 15.428 | 25.216 | −0.250 | 1.00 | 54.08 | A |
| ATOM | 289 | O | LEU | 32 | 15.375 | 24.928 | 0.951 | 1.00 | 55.60 | A |
| ATOM | 290 | N | ALA | 33 | 15.471 | 26.470 | −0.694 | 1.00 | 57.54 | A |
| ATOM | 291 | H | ALA | 33 | 15.561 | 26.670 | −1.653 | 0.00 | 0.00 | A |
| ATOM | 292 | CA | ALA | 33 | 15.432 | 27.606 | 0.222 | 1.00 | 62.26 | A |
| ATOM | 293 | CB | ALA | 33 | 16.668 | 27.599 | 1.108 | 1.00 | 62.60 | A |
| ATOM | 294 | C | ALA | 33 | 15.300 | 28.961 | −0.487 | 1.00 | 65.52 | A |
| ATOM | 295 | O | ALA | 33 | 15.602 | 29.076 | −1.682 | 1.00 | 68.20 | A |
| ATOM | 296 | N | HIS | 34 | 14.814 | 29.965 | 0.257 | 1.00 | 66.95 | A |
| ATOM | 297 | H | HIS | 34 | 14.563 | 29.753 | 1.177 | 0.00 | 0.00 | A |
| ATOM | 298 | CA | HIS | 34 | 14.645 | 31.342 | −0.244 | 1.00 | 65.92 | A |
| ATOM | 299 | CB | HIS | 34 | 13.856 | 32.188 | 0.795 | 1.00 | 70.44 | A |
| ATOM | 300 | CG | HIS | 34 | 13.669 | 33.650 | 0.451 | 1.00 | 72.87 | A |
| ATOM | 301 | CD2 | HIS | 34 | 14.024 | 34.772 | 1.132 | 1.00 | 72.23 | A |
| ATOM | 302 | ND1 | HIS | 34 | 12.941 | 34.087 | −0.639 | 1.00 | 73.72 | A |
| ATOM | 303 | HD1 | HIS | 34 | 12.511 | 33.531 | −1.321 | 0.00 | 0.00 | A |
| ATOM | 304 | CE1 | HIS | 34 | 12.853 | 35.407 | −0.611 | 1.00 | 72.77 | A |
| ATOM | 305 | NE2 | HIS | 34 | 13.500 | 35.846 | 0.454 | 1.00 | 71.90 | A |
| ATOM | 306 | HE2 | HIS | 34 | 13.491 | 36.783 | 0.774 | 0.00 | 0.00 | A |
| ATOM | 307 | C | HIS | 34 | 16.062 | 31.873 | −0.467 | 1.00 | 63.52 | A |
| ATOM | 308 | O | HIS | 34 | 16.338 | 32.440 | −1.511 | 1.00 | 62.92 | A |
| ATOM | 309 | N | SER | 35 | 16.955 | 31.638 | 0.498 | 1.00 | 60.67 | A |
| ATOM | 310 | H | SER | 35 | 16.713 | 31.125 | 1.287 | 0.00 | 0.00 | A |
| ATOM | 311 | CA | SER | 35 | 18.352 | 32.072 | 0.406 | 1.00 | 56.53 | A |
| ATOM | 312 | CB | SER | 35 | 18.935 | 32.282 | 1.804 | 1.00 | 56.46 | A |
| ATOM | 313 | OG | SER | 35 | 19.088 | 31.045 | 2.493 | 1.00 | 57.59 | A |
| ATOM | 314 | HG | SER | 35 | 19.923 | 31.267 | 2.930 | 0.00 | 0.00 | A |
| ATOM | 315 | C | SER | 35 | 19.120 | 30.956 | −0.279 | 1.00 | 54.14 | A |
| ATOM | 316 | O | SER | 35 | 18.544 | 30.188 | −1.041 | 1.00 | 55.99 | A |
| ATOM | 317 | N | ASP | 36 | 20.406 | 30.845 | 0.029 | 1.00 | 51.05 | A |
| ATOM | 318 | H | ASP | 36 | 20.864 | 31.484 | 0.618 | 0.00 | 0.00 | A |
| ATOM | 319 | CA | ASP | 36 | 21.263 | 29.804 | −0.530 | 1.00 | 48.52 | A |
| ATOM | 320 | CB | ASP | 36 | 22.713 | 30.228 | −0.402 | 1.00 | 46.63 | A |
| ATOM | 321 | CG | ASP | 36 | 23.091 | 30.492 | 1.019 | 1.00 | 50.20 | A |
| ATOM | 322 | OD1 | ASP | 36 | 24.275 | 30.785 | 1.269 | 1.00 | 53.80 | A |
| ATOM | 323 | OD2 | ASP | 36 | 22.197 | 30.414 | 1.902 | 1.00 | 51.88 | A |
| ATOM | 324 | C | ASP | 36 | 21.050 | 28.494 | 0.240 | 1.00 | 47.60 | A |
| ATOM | 325 | O | ASP | 36 | 21.738 | 27.489 | 0.002 | 1.00 | 49.62 | A |
| ATOM | 326 | N | GLY | 37 | 20.175 | 28.547 | 1.239 | 1.00 | 44.42 | A |
| ATOM | 327 | H | GLY | 37 | 19.791 | 29.416 | 1.448 | 0.00 | 0.00 | A |
| ATOM | 328 | CA | GLY | 37 | 19.866 | 27.360 | 2.011 | 1.00 | 41.48 | A |
| ATOM | 329 | C | GLY | 37 | 21.004 | 26.747 | 2.794 | 1.00 | 39.86 | A |
| ATOM | 330 | O | GLY | 37 | 20.941 | 25.570 | 3.142 | 1.00 | 40.20 | A |
| ATOM | 331 | N | ASP | 38 | 22.011 | 27.547 | 3.124 | 1.00 | 37.93 | A |
| ATOM | 332 | h | ASP | 38 | 22.051 | 28.468 | 2.782 | 0.00 | 0.00 | A |
| ATOM | 333 | CA | ASP | 38 | 23.153 | 27.068 | 3.895 | 1.00 | 35.95 | A |
| ATOM | 334 | CB | ASP | 38 | 24.241 | 28.137 | 3.886 | 1.00 | 36.07 | A |
| ATOM | 335 | CG | ASP | 38 | 25.540 | 27.660 | 4.480 | 1.00 | 38.27 | A |
| ATOM | 336 | OD1 | ASP | 38 | 25.525 | 26.898 | 5.471 | 1.00 | 41.36 | A |
| ATOM | 337 | OD2 | ASP | 38 | 26.596 | 28.072 | 3.971 | 1.00 | 41.36 | A |
| ATOM | 338 | C | ASP | 38 | 22.707 | 26.783 | 5.331 | 1.00 | 36.10 | A |
| ATOM | 339 | O | ASP | 38 | 22.663 | 27.683 | 6.172 | 1.00 | 39.94 | A |
| ATOM | 340 | N | VAL | 39 | 22.362 | 25.537 | 5.618 | 1.00 | 34.11 | A |
| ATOM | 341 | H | VAL | 39 | 22.447 | 24.907 | 4.872 | 0.00 | 0.00 | A |
| ATOM | 342 | CA | VAL | 39 | 21.901 | 25.168 | 6.949 | 1.00 | 31.93 | A |
| ATOM | 343 | CB | VAL | 39 | 21.584 | 23.699 | 7.038 | 1.00 | 32.45 | A |
| ATOM | 344 | CG1 | VAL | 39 | 20.625 | 23.465 | 8.155 | 1.00 | 36.75 | A |
| ATOM | 345 | CG2 | VAL | 39 | 20.996 | 23.221 | 5.760 | 1.00 | 34.88 | A |
| ATOM | 346 | C | VAL | 39 | 22.897 | 25.470 | 8.054 | 1.00 | 32.27 | A |
| ATOM | 347 | O | VAL | 39 | 22.545 | 26.093 | 9.046 | 1.00 | 33.95 | A |
| ATOM | 348 | N | ALA | 40 | 24.134 | 25.022 | 7.896 | 1.00 | 32.01 | A |
| ATOM | 349 | H | ALA | 40 | 24.366 | 24.573 | 7.060 | 0.00 | 0.00 | A |
| ATOM | 350 | CA | ALA | 40 | 25.160 | 25.249 | 8.911 | 1.00 | 32.22 | A |
| ATOM | 351 | CB | ALA | 40 | 26.516 | 24.828 | 8.396 | 1.00 | 30.22 | A |
| ATOM | 352 | C | ALA | 40 | 25.206 | 26.706 | 9.341 | 1.00 | 33.45 | A |
| ATOM | 353 | O | ALA | 40 | 25.242 | 27.013 | 10.528 | 1.00 | 35.09 | A |
| ATOM | 354 | N | LEU | 41 | 25.178 | 27.618 | 8.385 | 1.00 | 32.90 | A |
| ATOM | 355 | H | LEU | 41 | 25.103 | 27.365 | 7.436 | 0.00 | 0.00 | A |
| ATOM | 356 | CA | LEU | 41 | 25.241 | 29.011 | 8.759 | 1.00 | 32.68 | A |
| ATOM | 357 | CB | LEU | 41 | 25.742 | 29.865 | 7.607 | 1.00 | 29.34 | A |
| ATOM | 358 | CG | LEU | 41 | 27.150 | 29.462 | 7.176 | 1.00 | 26.35 | A |
| ATOM | 359 | CD1 | LEU | 41 | 27.621 | 30.358 | 6.071 | 1.00 | 27.54 | A |
| ATOM | 360 | CD2 | LEU | 41 | 28.099 | 29.532 | 8.342 | 1.00 | 24.79 | A |
| ATOM | 361 | C | LEU | 41 | 23.950 | 29.554 | 9.373 | 1.00 | 35.94 | A |
| ATOM | 362 | O | LEU | 41 | 24.012 | 30.302 | 10.357 | 1.00 | 39.40 | A |
| ATOM | 363 | N | HIS | 42 | 22.782 | 29.174 | 8.857 | 1.00 | 34.81 | A |
| ATOM | 364 | H | HIS | 42 | 22.799 | 28.554 | 8.096 | 0.00 | 0.00 | A |
| ATOM | 365 | CA | HIS | 42 | 21.550 | 29.671 | 9.480 | 1.00 | 33.31 | A |
| ATOM | 366 | CB | HIS | 42 | 20.284 | 29.129 | 8.831 | 1.00 | 35.61 | A |
| ATOM | 367 | CG | HIS | 42 | 20.132 | 29.506 | 7.396 | 1.00 | 38.04 | A |
| ATOM | 368 | CD2 | HIS | 42 | 20.861 | 30.336 | 6.615 | 1.00 | 38.58 | A |
| ATOM | 369 | ND1 | HIS | 42 | 19.158 | 28.956 | 6.585 | 1.00 | 44.82 | A |
| ATOM | 370 | CE1 | HIS | 42 | 19.305 | 29.435 | 5.359 | 1.00 | 43.57 | A |
| ATOM | 371 | NE2 | HIS | 42 | 20.331 | 30.272 | 5.353 | 1.00 | 40.29 | A |
| ATOM | 372 | HE2 | HIS | 42 | 20.730 | 30.766 | 4.594 | 0.00 | 0.00 | A |
| ATOM | 373 | C | HIS | 42 | 21.555 | 29.236 | 10.933 | 1.00 | 31.52 | A |
| ATOM | 374 | O | HIS | 42 | 21.335 | 30.053 | 11.810 | 1.00 | 35.27 | A |
| ATOM | 375 | N | ALA | 43 | 21.883 | 27.980 | 11.204 | 1.00 | 28.00 | A |
| ATOM | 376 | H | ALA | 43 | 22.132 | 27.353 | 10.491 | 0.00 | 0.00 | A |
| ATOM | 377 | CA | ALA | 43 | 21.891 | 27.544 | 12.583 | 1.00 | 27.47 | A |
| ATOM | 378 | CB | ALA | 43 | 22.201 | 26.091 | 12.686 | 1.00 | 28.00 | A |
| ATOM | 379 | C | ALA | 43 | 22.882 | 28.371 | 13.379 | 1.00 | 28.72 | A |
| ATOM | 380 | O | ALA | 43 | 22.516 | 28.960 | 14.393 | 1.00 | 31.49 | A |
| ATOM | 381 | N | LEU | 44 | 24.109 | 28.496 | 12.888 | 1.00 | 28.85 | A |
| ATOM | 382 | H | LEU | 44 | 24.343 | 28.054 | 12.043 | 0.00 | 0.00 | A |
| ATOM | 383 | CA | LEU | 44 | 25.119 | 29.284 | 13.598 | 1.00 | 29.22 | A |
| ATOM | 384 | CB | LEU | 44 | 26.417 | 29.348 | 12.792 | 1.00 | 24.66 | A |
| ATOM | 385 | CG | LEU | 44 | 27.524 | 30.291 | 13.256 | 1.00 | 24.31 | A |
| ATOM | 386 | CD1 | LEU | 44 | 27.847 | 30.080 | 14.722 | 1.00 | 20.82 | A |
| ATOM | 387 | CD2 | LEU | 44 | 28.763 | 30.048 | 12.401 | 1.00 | 22.43 | A |
| ATOM | 388 | C | LEU | 44 | 24.582 | 30.690 | 13.892 | 1.00 | 32.07 | A |
| ATOM | 389 | O | LEU | 44 | 24.646 | 31.159 | 15.028 | 1.00 | 33.57 | A |
| ATOM | 390 | N | THR | 45 | 23.963 | 31.313 | 12.894 | 1.00 | 33.90 | A |
| ATOM | 391 | H | THR | 45 | 23.848 | 30.870 | 12.040 | 0.00 | 0.00 | A |
| ATOM | 392 | CA | THR | 45 | 23.398 | 32.651 | 13.043 | 1.00 | 35.81 | A |
| ATOM | 393 | CB | THR | 45 | 22.654 | 33.064 | 11.777 | 1.00 | 36.87 | A |
| ATOM | 394 | OG1 | THR | 45 | 23.570 | 33.094 | 10.674 | 1.00 | 40.16 | A |
| ATOM | 395 | HG1 | THR | 45 | 24.287 | 33.702 | 10.866 | 0.00 | 0.00 | A |
| ATOM | 396 | CG2 | THR | 45 | 21.994 | 34.425 | 11.963 | 1.00 | 35.68 | A |
| ATOM | 397 | C | THR | 45 | 22.415 | 32.740 | 14.207 | 1.00 | 36.37 | A |
| ATOM | 398 | O | THR | 45 | 22.526 | 33.617 | 15.063 | 1.00 | 36.91 | A |
| ATOM | 399 | N | ASP | 46 | 21.436 | 31.848 | 14.222 | 1.00 | 36.02 | A |
| ATOM | 400 | H | ASP | 46 | 21.343 | 31.180 | 13.507 | 0.00 | 0.00 | A |
| ATOM | 401 | CA | ASP | 46 | 20.455 | 31.849 | 15.281 | 1.00 | 36.79 | A |
| ATOM | 402 | CB | ASP | 46 | 19.453 | 30.728 | 15.089 | 1.00 | 40.98 | A |
| ATOM | 403 | CG | ASP | 46 | 18.343 | 31.104 | 14.166 | 1.00 | 43.33 | A |
| ATOM | 404 | OD1 | ASP | 46 | 17.470 | 30.250 | 13.884 | 1.00 | 46.09 | A |
| ATOM | 405 | OD2 | ASP | 46 | 18.344 | 32.264 | 13.728 | 1.00 | 45.96 | A |
| ATOM | 406 | C | ASP | 46 | 21.110 | 31.664 | 16.617 | 1.00 | 37.01 | A |
| ATOM | 407 | O | ASP | 46 | 20.691 | 32.264 | 17.595 | 1.00 | 37.77 | A |
| ATOM | 408 | N | ALA | 47 | 22.125 | 30.816 | 16.679 | 1.00 | 34.89 | A |
| ATOM | 409 | H | ALA | 47 | 22.423 | 30.361 | 15.861 | 0.00 | 0.00 | A |
| ATOM | 410 | CA | ALA | 47 | 22.770 | 30.591 | 17.952 | 1.00 | 35.88 | A |
| ATOM | 411 | CB | ALA | 47 | 23.770 | 29.496 | 17.848 | 1.00 | 36.66 | A |
| ATOM | 412 | C | ALA | 47 | 23.422 | 31.874 | 18.438 | 1.00 | 37.80 | A |
| ATOM | 413 | O | ALA | 47 | 23.351 | 32.196 | 19.629 | 1.00 | 39.23 | A |
| ATOM | 414 | N | LEU | 48 | 24.030 | 32.617 | 17.516 | 1.00 | 37.62 | A |
| ATOM | 415 | H | LEU | 48 | 24.041 | 32.300 | 16.587 | 0.00 | 0.00 | A |
| ATOM | 416 | CA | LEU | 48 | 24.685 | 33.877 | 17.860 | 1.00 | 36.25 | A |
| ATOM | 417 | CB | LEU | 48 | 25.539 | 34.392 | 16.697 | 1.00 | 34.41 | A |
| ATOM | 418 | CG | LEU | 48 | 26.829 | 33.621 | 16.410 | 1.00 | 34.31 | A |
| ATOM | 419 | CD1 | LEU | 48 | 27.320 | 33.977 | 15.041 | 1.00 | 33.65 | A |
| ATOM | 420 | CD2 | LEU | 48 | 27.895 | 33.918 | 17.461 | 1.00 | 32.82 | A |
| ATOM | 421 | C | LEU | 48 | 23.628 | 34.904 | 18.243 | 1.00 | 36.61 | A |
| ATOM | 422 | O | LEU | 48 | 23.716 | 35.517 | 19.306 | 1.00 | 38.96 | A |
| ATOM | 423 | N | LEU | 49 | 22.604 | 35.064 | 17.410 | 1.00 | 36.00 | A |
| ATOM | 424 | H | LEU | 49 | 22.554 | 34.537 | 16.600 | 0.00 | 0.00 | A |
| ATOM | 425 | CA | LEU | 49 | 21.541 | 36.015 | 17.715 | 1.00 | 36.10 | A |
| ATOM | 426 | CB | LEU | 49 | 20.482 | 36.033 | 16.612 | 1.00 | 34.42 | A |
| ATOM | 427 | CG | LEU | 49 | 20.910 | 36.652 | 15.278 | 1.00 | 34.04 | A |
| ATOM | 428 | CD1 | LEU | 49 | 19.756 | 36.622 | 14.294 | 1.00 | 30.54 | A |
| ATOM | 429 | CD2 | LEU | 49 | 21.376 | 38.085 | 15.507 | 1.00 | 33.20 | A |
| ATOM | 430 | C | LEU | 49 | 20.907 | 35.627 | 19.046 | 1.00 | 36.97 | A |
| ATOM | 431 | O | LEU | 49 | 20.638 | 36.483 | 19.884 | 1.00 | 38.41 | A |
| ATOM | 432 | N | GLY | 50 | 20.765 | 34.322 | 19.262 | 1.00 | 38.44 | A |
| ATOM | 433 | H | GLY | 50 | 21.084 | 33.718 | 18.574 | 0.00 | 0.00 | A |
| ATOM | 434 | CA | GLY | 50 | 20.178 | 33.801 | 20.485 | 1.00 | 39.96 | A |
| ATOM | 435 | C | GLY | 50 | 20.901 | 34.293 | 21.723 | 1.00 | 41.71 | A |
| ATOM | 436 | O | GLY | 50 | 20.285 | 34.866 | 22.620 | 1.00 | 44.55 | A |
| ATOM | 437 | N | ALA | 51 | 22.212 | 34.108 | 21.771 | 1.00 | 40.30 | A |
| ATOM | 438 | H | ALA | 51 | 22.665 | 33.642 | 21.034 | 0.00 | 0.00 | A |
| ATOM | 439 | CA | ALA | 51 | 22.968 | 34.564 | 22.917 | 1.00 | 38.58 | A |
| ATOM | 440 | CB | ALA | 51 | 24.378 | 34.087 | 22.820 | 1.00 | 38.99 | A |
| ATOM | 441 | C | ALA | 51 | 22.915 | 36.092 | 23.004 | 1.00 | 39.29 | A |
| ATOM | 442 | O | ALA | 51 | 22.931 | 36.663 | 24.086 | 1.00 | 41.21 | A |
| ATOM | 443 | N | ALA | 52 | 22.812 | 36.764 | 21.872 | 1.00 | 37.97 | A |
| ATOM | 444 | H | ALA | 52 | 22.797 | 36.280 | 21.017 | 0.00 | 0.00 | A |
| ATOM | 445 | CA | ALA | 52 | 22.748 | 38.216 | 21.893 | 1.00 | 37.95 | A |
| ATOM | 446 | CB | ALA | 52 | 23.104 | 38.768 | 20.528 | 1.00 | 37.36 | A |
| ATOM | 447 | C | ALA | 52 | 21.362 | 38.699 | 22.298 | 1.00 | 38.39 | A |
| ATOM | 448 | O | ALA | 52 | 21.134 | 39.894 | 22.454 | 1.00 | 41.07 | A |
| ATOM | 449 | N | ALA | 53 | 20.437 | 37.766 | 22.466 | 1.00 | 39.12 | A |
| ATOM | 450 | H | ALA | 53 | 20.663 | 36.825 | 22.318 | 0.00 | 0.00 | A |
| ATOM | 451 | CA | ALA | 53 | 19.050 | 38.086 | 22.819 | 1.00 | 38.48 | A |
| ATOM | 452 | CB | ALA | 53 | 18.978 | 38.793 | 24.160 | 1.00 | 36.77 | A |
| ATOM | 453 | C | ALA | 53 | 18.436 | 38.951 | 21.730 | 1.00 | 37.70 | A |
| ATOM | 454 | O | ALA | 53 | 17.695 | 39.880 | 22.010 | 1.00 | 38.63 | A |
| ATOM | 455 | N | LEU | 54 | 18.779 | 38.665 | 20.483 | 1.00 | 37.76 | A |
| ATOM | 456 | H | LEU | 54 | 19.400 | 37.926 | 20.313 | 0.00 | 0.00 | A |
| ATOM | 457 | CA | LEU | 54 | 18.248 | 39.427 | 19.368 | 1.00 | 37.75 | A |
| ATOM | 458 | CB | LEU | 54 | 19.379 | 39.883 | 18.457 | 1.00 | 37.17 | A |
| ATOM | 459 | CG | LEU | 54 | 20.489 | 40.711 | 19.107 | 1.00 | 35.30 | A |
| ATOM | 460 | CD1 | LEU | 54 | 21.572 | 41.027 | 18.082 | 1.00 | 34.79 | A |
| ATOM | 461 | CD2 | LEU | 54 | 19.911 | 41.977 | 19.657 | 1.00 | 34.70 | A |
| ATOM | 462 | C | LEU | 54 | 17.190 | 38.670 | 18.568 | 1.00 | 39.86 | A |
| ATOM | 463 | O | LEU | 54 | 16.767 | 39.116 | 17.501 | 1.00 | 40.36 | A |
| ATOM | 464 | N | GLY | 55 | 16.740 | 37.535 | 19.085 | 1.00 | 43.40 | A |
| ATOM | 465 | H | GLY | 55 | 17.081 | 37.184 | 19.935 | 0.00 | 0.00 | A |
| ATOM | 466 | CA | GLY | 55 | 15.709 | 36.779 | 18.393 | 1.00 | 44.90 | A |
| ATOM | 467 | C | GLY | 55 | 16.230 | 35.678 | 17.507 | 1.00 | 45.70 | A |
| ATOM | 468 | O | GLY | 55 | 16.906 | 34.765 | 17.990 | 1.00 | 44.56 | A |
| ATOM | 469 | N | ASP | 56 | 15.878 | 35.742 | 16.226 | 1.00 | 47.03 | A |
| ATOM | 470 | H | ASP | 56 | 15.300 | 36.446 | 15.877 | 0.00 | 0.00 | A |
| ATOM | 471 | CA | ASP | 56 | 16.322 | 34.748 | 15.266 | 1.00 | 48.13 | A |
| ATOM | 472 | CB | ASP | 56 | 15.365 | 33.552 | 15.210 | 1.00 | 49.26 | A |
| ATOM | 473 | CG | ASP | 56 | 13.986 | 33.910 | 14.686 | 1.00 | 50.20 | A |
| ATOM | 474 | OD1 | ASP | 56 | 13.913 | 34.557 | 13.630 | 1.00 | 51.48 | A |
| ATOM | 475 | OD2 | ASP | 56 | 12.970 | 33.521 | 15.309 | 1.00 | 49.92 | A |
| ATOM | 476 | C | ASP | 56 | 16.516 | 35.375 | 13.895 | 1.00 | 49.86 | A |
| ATOM | 477 | O | ASP | 56 | 16.100 | 36.512 | 13.658 | 1.00 | 51.59 | A |
| ATOM | 478 | N | ILE | 57 | 17.114 | 34.607 | 12.991 | 1.00 | 50.78 | A |
| ATOM | 479 | H | ILE | 57 | 17.281 | 33.690 | 13.269 | 0.00 | 0.00 | A |
| ATOM | 480 | CA | ILE | 57 | 17.441 | 35.034 | 11.631 | 1.00 | 49.19 | A |
| ATOM | 481 | CB | ILE | 57 | 18.201 | 33.894 | 10.873 | 1.00 | 46.25 | A |
| ATOM | 482 | CG2 | ILE | 57 | 17.251 | 32.823 | 10.378 | 1.00 | 45.61 | A |
| ATOM | 483 | CG1 | ILE | 57 | 18.964 | 34.438 | 9.682 | 1.00 | 44.58 | A |
| ATOM | 484 | CD1 | ILE | 57 | 19.576 | 33.336 | 8.843 | 1.00 | 44.73 | A |
| ATOM | 485 | C | ILE | 57 | 16.208 | 35.482 | 10.861 | 1.00 | 50.71 | A |
| ATOM | 486 | O | ILE | 57 | 16.239 | 36.503 | 10.185 | 1.00 | 50.25 | A |
| ATOM | 487 | N | GLY | 58 | 15.109 | 34.760 | 11.035 | 1.00 | 53.97 | A |
| ATOM | 488 | H | GLY | 58 | 15.100 | 34.032 | 11.700 | 0.00 | 0.00 | A |
| ATOM | 489 | CA | GLY | 58 | 13.870 | 35.083 | 10.347 | 1.00 | 60.15 | A |
| ATOM | 490 | C | GLY | 58 | 13.299 | 36.421 | 10.773 | 1.00 | 64.20 | A |
| ATOM | 491 | O | GLY | 58 | 12.554 | 37.055 | 10.030 | 1.00 | 66.06 | A |
| ATOM | 492 | N | LYS | 59 | 13.625 | 36.840 | 11.987 | 1.00 | 68.59 | A |
| ATOM | 493 | H | LYS | 59 | 14.152 | 36.256 | 12.576 | 0.00 | 0.00 | A |
| ATOM | 494 | CA | LYS | 59 | 13.161 | 38.121 | 12.494 | 1.00 | 71.48 | A |
| ATOM | 495 | CB | LYS | 59 | 13.405 | 38.231 | 14.003 | 1.00 | 75.71 | A |
| ATOM | 496 | CG | LYS | 59 | 13.169 | 39.619 | 14.583 | 1.00 | 78.84 | A |
| ATOM | 497 | CD | LYS | 59 | 13.789 | 39.731 | 15.960 | 1.00 | 82.01 | A |
| ATOM | 498 | CE | LYS | 59 | 14.163 | 41.172 | 16.284 | 1.00 | 86.19 | A |
| ATOM | 499 | NZ | LYS | 59 | 14.989 | 41.252 | 17.527 | 1.00 | 88.87 | A |
| ATOM | 500 | HZ1 | LYS | 59 | 15.259 | 42.227 | 17.752 | 0.00 | 0.00 | A |
| ATOM | 501 | HZ2 | LYS | 59 | 15.841 | 40.658 | 17.388 | 0.00 | 0.00 | A |
| ATOM | 502 | HZ3 | LYS | 59 | 14.444 | 40.853 | 18.315 | 0.00 | 0.00 | A |
| ATOM | 503 | C | LYS | 59 | 13.937 | 39.207 | 11.783 | 1.00 | 71.18 | A |
| ATOM | 504 | O | LYS | 59 | 13.392 | 40.248 | 11.485 | 1.00 | 75.30 | A |
| ATOM | 505 | N | LEU | 60 | 15.211 | 38.968 | 11.508 | 1.00 | 70.11 | A |
| ATOM | 506 | H | LEU | 60 | 15.592 | 38.097 | 11.747 | 0.00 | 0.00 | A |
| ATOM | 507 | CA | LEU | 60 | 16.025 | 39.969 | 10.838 | 1.00 | 69.29 | A |
| ATOM | 508 | CB | LEU | 60 | 17.474 | 39.868 | 11.285 | 1.00 | 69.13 | A |
| ATOM | 509 | CG | LEU | 60 | 17.812 | 40.443 | 12.651 | 1.00 | 70.27 | A |
| ATOM | 510 | CD1 | LEU | 60 | 16.971 | 39.785 | 13.740 | 1.00 | 68.89 | A |
| ATOM | 511 | CD2 | LEU | 60 | 19.305 | 40.236 | 12.887 | 1.00 | 70.90 | A |
| ATOM | 512 | C | LEU | 60 | 15.994 | 39.940 | 9.321 | 1.00 | 68.94 | A |
| ATOM | 513 | O | LEU | 60 | 16.222 | 40.968 | 8.684 | 1.00 | 70.10 | A |
| ATOM | 514 | N | PHE | 61 | 15.763 | 38.773 | 8.734 | 1.00 | 67.68 | A |
| ATOM | 515 | H | PHE | 61 | 15.579 | 37.977 | 9.266 | 0.00 | 0.00 | A |
| ATOM | 516 | CA | PHE | 61 | 15.760 | 38.673 | 7.283 | 1.00 | 67.82 | A |
| ATOM | 517 | CB | PHE | 61 | 17.123 | 38.179 | 6.781 | 1.00 | 64.15 | A |
| ATOM | 518 | CG | PHE | 61 | 18.294 | 38.658 | 7.594 | 1.00 | 60.91 | A |
| ATOM | 519 | CD1 | PHE | 61 | 18.717 | 39.971 | 7.528 | 1.00 | 61.00 | A |
| ATOM | 520 | CD2 | PHE | 61 | 18.981 | 37.784 | 8.423 | 1.00 | 61.72 | A |
| ATOM | 521 | CE1 | PHE | 61 | 19.807 | 40.405 | 8.277 | 1.00 | 61.81 | A |
| ATOM | 522 | CE2 | PHE | 61 | 20.072 | 38.209 | 9.174 | 1.00 | 61.27 | A |
| ATOM | 523 | CZ | PHE | 61 | 20.485 | 39.520 | 9.101 | 1.00 | 60.89 | A |
| ATOM | 524 | C | PHE | 61 | 14.652 | 37.740 | 6.788 | 1.00 | 70.59 | A |
| ATOM | 525 | O | PHE | 61 | 14.893 | 36.563 | 6.508 | 1.00 | 72.17 | A |
| ATOM | 526 | N | PRO | 62 | 13.427 | 38.269 | 6.652 | 1.00 | 72.75 | A |
| ATOM | 527 | CD | PRO | 62 | 13.143 | 39.626 | 7.145 | 1.00 | 72.15 | A |
| ATOM | 528 | CA | PRO | 62 | 12.184 | 37.622 | 6.204 | 1.00 | 76.18 | A |
| ATOM | 529 | CB | PRO | 62 | 11.177 | 38.759 | 6.299 | 1.00 | 74.11 | A |
| ATOM | 530 | CG | PRO | 62 | 11.685 | 39.546 | 7.453 | 1.00 | 72.81 | A |
| ATOM | 531 | C | PRO | 62 | 12.142 | 36.978 | 4.805 | 1.00 | 81.02 | A |
| ATOM | 532 | O | PRO | 62 | 12.579 | 37.584 | 3.817 | 1.00 | 81.21 | A |
| ATOM | 533 | N | ASP | 63 | 11.538 | 35.783 | 4.725 | 1.00 | 85.91 | A |
| ATOM | 534 | H | ASP | 63 | 11.187 | 35.387 | 5.554 | 0.00 | 0.00 | A |
| ATOM | 535 | CA | ASP | 63 | 11.393 | 35.037 | 3.462 | 1.00 | 90.15 | A |
| ATOM | 536 | CB | ASP | 63 | 10.525 | 33.772 | 3.601 | 1.00 | 93.14 | A |
| ATOM | 537 | CG | ASP | 63 | 10.414 | 33.261 | 5.023 | 1.00 | 97.50 | A |
| ATOM | 538 | OD1 | ASP | 63 | 9.815 | 33.964 | 5.878 | 1.00 | 99.52 | A |
| ATOM | 539 | OD2 | ASP | 63 | 10.886 | 32.127 | 5.269 | 1.00 | 98.81 | A |
| ATOM | 540 | C | ASP | 63 | 10.632 | 35.941 | 2.526 | 1.00 | 92.29 | A |
| ATOM | 541 | O | ASP | 63 | 10.873 | 35.963 | 1.316 | 1.00 | 93.16 | A |
| ATOM | 542 | N | THR | 64 | 9.646 | 36.613 | 3.112 | 1.00 | 94.07 | A |
| ATOM | 543 | H | THR | 64 | 9.515 | 36.436 | 4.065 | 0.00 | 0.00 | A |
| ATOM | 544 | CA | THR | 64 | 8.773 | 37.548 | 2.421 | 1.00 | 96.04 | A |
| ATOM | 545 | CB | THR | 64 | 7.878 | 38.322 | 3.438 | 1.00 | 98.56 | A |
| ATOM | 546 | OG1 | THR | 64 | 8.673 | 39.249 | 4.199 | 1.00 | 99.26 | A |
| ATOM | 547 | HG1 | THR | 64 | 8.946 | 39.998 | 3.650 | 0.00 | 0.00 | A |
| ATOM | 548 | CG2 | THR | 64 | 7.203 | 37.345 | 4.407 | 1.00 | 99.55 | A |
| ATOM | 549 | C | THR | 64 | 9.584 | 38.548 | 1.598 | 1.00 | 95.08 | A |
| ATOM | 550 | O | THR | 64 | 9.379 | 38.677 | 0.388 | 1.00 | 95.88 | A |
| ATOM | 551 | N | ASP | 65 | 10.511 | 39.235 | 2.262 | 1.00 | 93.42 | A |
| ATOM | 552 | H | ASP | 65 | 10.686 | 39.039 | 3.204 | 0.00 | 0.00 | A |
| ATOM | 553 | CA | ASP | 65 | 11.348 | 40.219 | 1.601 | 1.00 | 91.63 | A |
| ATOM | 554 | CB | ASP | 65 | 12.285 | 40.885 | 2.600 | 1.00 | 90.76 | A |
| ATOM | 555 | CG | ASP | 65 | 12.952 | 42.125 | 2.037 | 1.00 | 91.21 | A |
| ATOM | 556 | OD1 | ASP | 65 | 13.374 | 42.113 | 0.855 | 1.00 | 89.99 | A |
| ATOM | 557 | OD2 | ASP | 65 | 13.056 | 43.119 | 2.787 | 1.00 | 92.29 | A |
| ATOM | 558 | C | ASP | 65 | 12.134 | 39.490 | 0.523 | 1.00 | 91.85 | A |
| ATOM | 559 | O | ASP | 65 | 12.987 | 38.635 | 0.818 | 1.00 | 90.55 | A |
| ATOM | 560 | N | PRO | 66 | 11.829 | 39.802 | −0.751 | 1.00 | 93.13 | A |
| ATOM | 561 | CD | PRO | 66 | 10.880 | 40.866 | −1.130 | 1.00 | 93.67 | A |
| ATOM | 562 | CA | PRO | 66 | 12.449 | 39.224 | −1.947 | 1.00 | 93.36 | A |
| ATOM | 563 | CB | PRO | 66 | 11.662 | 39.877 | −3.083 | 1.00 | 92.95 | A |
| ATOM | 564 | CG | PRO | 66 | 11.328 | 41.219 | −2.525 | 1.00 | 93.21 | A |
| ATOM | 565 | C | PRO | 66 | 13.954 | 39.468 | −2.070 | 1.00 | 93.29 | A |
| ATOM | 566 | O | PRO | 66 | 14.652 | 38.697 | −2.739 | 1.00 | 94.08 | A |
| ATOM | 567 | N | ALA | 67 | 14.456 | 40.509 | −1.407 | 1.00 | 91.76 | A |
| ATOM | 568 | H | ALA | 67 | 13.871 | 41.083 | −0.855 | 0.00 | 0.00 | A |
| ATOM | 569 | CA | ALA | 67 | 15.884 | 40.829 | −1.445 | 1.00 | 90.66 | A |
| ATOM | 570 | CB | ALA | 67 | 16.146 | 42.115 | −0.658 | 1.00 | 91.65 | A |
| ATOM | 571 | C | ALA | 67 | 16.731 | 39.670 | −0.881 | 1.00 | 89.23 | A |
| ATOM | 572 | O | ALA | 67 | 17.850 | 39.383 | −1.344 | 1.00 | 88.91 | A |
| ATOM | 573 | N | PHE | 68 | 16.171 | 38.992 | 0.113 | 1.00 | 85.59 | A |
| ATOM | 574 | H | PHE | 68 | 15.284 | 39.270 | 0.435 | 0.00 | 0.00 | A |
| ATOM | 575 | CA | PHE | 68 | 16.851 | 37.885 | 0.741 | 1.00 | 81.39 | A |
| ATOM | 576 | CB | PHE | 68 | 16.227 | 37.626 | 2.096 | 1.00 | 80.08 | A |
| ATOM | 577 | CG | PHE | 68 | 16.188 | 38.841 | 2.959 | 1.00 | 78.93 | A |
| ATOM | 578 | CD1 | PHE | 68 | 15.023 | 39.211 | 3.615 | 1.00 | 79.33 | A |
| ATOM | 579 | CD2 | PHE | 68 | 17.322 | 39.630 | 3.108 | 1.00 | 77.40 | A |
| ATOM | 580 | CE1 | PHE | 68 | 14.989 | 40.354 | 4.412 | 1.00 | 79.33 | A |
| ATOM | 581 | CE2 | PHE | 68 | 17.299 | 40.774 | 3.902 | 1.00 | 77.47 | A |
| ATOM | 582 | CZ | PHE | 68 | 16.131 | 41.137 | 4.556 | 1.00 | 78.26 | A |
| ATOM | 583 | C | PHE | 68 | 16.814 | 36.650 | −0.127 | 1.00 | 80.29 | A |
| ATOM | 584 | O | PHE | 68 | 17.455 | 35.652 | 0.190 | 1.00 | 80.77 | A |
| ATOM | 585 | N | LYS | 69 | 16.053 | 36.695 | −1.213 | 1.00 | 78.54 | A |
| ATOM | 586 | H | LYS | 69 | 15.604 | 37.518 | −1.484 | 0.00 | 0.00 | A |
| ATOM | 587 | CA | LYS | 69 | 16.003 | 35.546 | −2.087 | 1.00 | 79.25 | A |
| ATOM | 588 | CB | LYS | 69 | 14.949 | 35.697 | −3.169 | 1.00 | 82.82 | A |
| ATOM | 589 | CG | LYS | 69 | 14.763 | 34.402 | −3.935 | 1.00 | 89.78 | A |
| ATOM | 590 | CD | LYS | 69 | 13.970 | 34.587 | −5.212 | 1.00 | 96.12 | A |
| ATOM | 591 | CE | LYS | 69 | 14.090 | 33.343 | −6.101 | 1.00 | 99.59 | A |
| ATOM | 592 | NZ | LYS | 69 | 13.520 | 33.538 | −7.477 | 1.00 | 100.00 | A |
| ATOM | 593 | HZ1 | LYS | 69 | 13.642 | 32.664 | −8.026 | 0.00 | 0.00 | A |
| ATOM | 594 | HZ2 | LYS | 69 | 14.013 | 34.319 | −7.956 | 0.00 | 0.00 | A |
| ATOM | 595 | HZ3 | LYS | 69 | 12.506 | 33.761 | −7.407 | 0.00 | 0.00 | A |
| ATOM | 596 | C | LYS | 69 | 17.374 | 35.390 | −2.726 | 1.00 | 78.25 | A |
| ATOM | 597 | O | LYS | 69 | 17.965 | 36.365 | −3.190 | 1.00 | 79.05 | A |
| ATOM | 598 | N | GLY | 70 | 17.875 | 34.157 | −2.714 | 1.00 | 76.13 | A |
| ATOM | 599 | H | GLY | 70 | 17.390 | 33.416 | −2.388 | 0.00 | 0.00 | A |
| ATOM | 600 | CA | GLY | 70 | 19.178 | 33.838 | −3.258 | 1.00 | 71.88 | A |
| ATOM | 601 | C | GLY | 70 | 20.307 | 34.323 | −2.366 | 1.00 | 69.60 | A |
| ATOM | 602 | O | GLY | 70 | 21.464 | 33.940 | −2.582 | 1.00 | 69.81 | A |
| ATOM | 603 | N | ALA | 71 | 19.966 | 35.099 | −1.330 | 1.00 | 66.81 | A |
| ATOM | 604 | H | ALA | 71 | 19.027 | 35.282 | −1.145 | 0.00 | 0.00 | A |
| ATOM | 605 | CA | ALA | 71 | 20.955 | 35.690 | −0.417 | 1.00 | 64.11 | A |
| ATOM | 606 | CB | ALA | 71 | 20.269 | 36.395 | 0.765 | 1.00 | 63.37 | A |
| ATOM | 607 | C | ALA | 71 | 22.055 | 34.764 | 0.085 | 1.00 | 60.31 | A |
| ATOM | 608 | O | ALA | 71 | 21.811 | 33.613 | 0.463 | 1.00 | 62.09 | A |
| ATOM | 609 | N | ASP | 72 | 23.273 | 35.282 | 0.050 | 1.00 | 53.98 | A |
| ATOM | 610 | H | ASP | 72 | 23.420 | 36.200 | −0.263 | 0.00 | 0.00 | A |
| ATOM | 611 | CA | ASP | 72 | 24.441 | 34.568 | 0.500 | 1.00 | 46.87 | A |
| ATOM | 612 | CB | ASP | 72 | 25.655 | 35.345 | 0.011 | 1.00 | 47.22 | A |
| ATOM | 613 | CG | ASP | 72 | 26.950 | 34.891 | 0.630 | 1.00 | 52.59 | A |
| ATOM | 614 | OD1 | ASP | 72 | 27.010 | 34.702 | 1.860 | 1.00 | 58.27 | A |
| ATOM | 615 | OD2 | ASP | 72 | 27.956 | 34.789 | −0.103 | 1.00 | 55.56 | A |
| ATOM | 616 | C | ASP | 72 | 24.333 | 34.533 | 2.030 | 1.00 | 44.94 | A |
| ATOM | 617 | O | ASP | 72 | 24.392 | 35.570 | 2.695 | 1.00 | 45.20 | A |
| ATOM | 618 | N | SER | 73 | 24.146 | 33.350 | 2.598 | 1.00 | 40.66 | A |
| ATOM | 619 | H | SER | 73 | 24.087 | 32.553 | 2.031 | 0.00 | 0.00 | A |
| ATOM | 620 | CA | SER | 73 | 24.023 | 33.242 | 4.036 | 1.00 | 39.16 | A |
| ATOM | 621 | CB | SER | 73 | 23.785 | 31.806 | 4.453 | 1.00 | 39.97 | A |
| ATOM | 622 | OG | SER | 73 | 22.456 | 31.405 | 4.172 | 1.00 | 41.15 | A |
| ATOM | 623 | HG | SER | 73 | 22.755 | 30.659 | 3.623 | 0.00 | 0.00 | A |
| ATOM | 624 | C | SER | 73 | 25.185 | 33.825 | 4.827 | 1.00 | 39.91 | A |
| ATOM | 625 | O | SER | 73 | 24.993 | 34.247 | 5.973 | 1.00 | 40.52 | A |
| ATOM | 626 | N | ARG | 74 | 26.385 | 33.829 | 4.249 | 1.00 | 39.07 | A |
| ATOM | 627 | H | ARG | 74 | 26.485 | 33.477 | 3.336 | 0.00 | 0.00 | A |
| ATOM | 628 | CA | ARG | 74 | 27.538 | 34.390 | 4.942 | 1.00 | 40.25 | A |
| ATOM | 629 | CB | ARG | 74 | 28.832 | 34.223 | 4.174 | 1.00 | 38.40 | A |
| ATOM | 630 | CG | ARG | 74 | 29.386 | 32.837 | 4.197 | 1.00 | 40.45 | A |
| ATOM | 631 | CD | ARG | 74 | 30.674 | 32.802 | 3.409 | 1.00 | 44.70 | A |
| ATOM | 632 | NE | ARG | 74 | 31.732 | 33.525 | 4.102 | 1.00 | 46.61 | A |
| ATOM | 633 | HE | ARG | 74 | 31.510 | 33.881 | 4.991 | 0.00 | 0.00 | A |
| ATOM | 634 | CZ | ARG | 74 | 32.953 | 33.719 | 3.624 | 1.00 | 45.83 | A |
| ATOM | 635 | NH1 | ARG | 74 | 33.642 | 34.376 | 4.350 | 1.00 | 51.29 | A |
| ATOM | 636 | HH11 | ARG | 74 | 33.565 | 34.713 | 5.267 | 0.00 | 0.00 | A |
| ATOM | 637 | HH12 | ARG | 74 | 34.810 | 34.583 | 4.118 | 0.00 | 0.00 | A |
| ATOM | 638 | NH2 | ARG | 74 | 33.280 | 33.277 | 2.423 | 1.00 | 43.28 | A |
| ATOM | 639 | HH21 | ARG | 74 | 32.610 | 32.784 | 1.858 | 0.00 | 0.00 | A |
| ATOM | 640 | HH22 | ARG | 74 | 34.210 | 33.404 | 2.067 | 0.00 | 0.00 | A |
| ATOM | 641 | C | ARG | 74 | 27.273 | 35.849 | 5.094 | 1.00 | 42.41 | A |
| ATOM | 642 | O | ARG | 74 | 27.694 | 36.452 | 6.074 | 1.00 | 44.60 | A |
| ATOM | 643 | N | GLU | 75 | 26.608 | 36.435 | 4.109 | 1.00 | 44.27 | A |
| ATOM | 644 | H | GLU | 75 | 26.337 | 35.928 | 3.306 | 0.00 | 0.00 | A |
| ATOM | 645 | CA | GLU | 75 | 26.273 | 37.840 | 4.206 | 1.00 | 49.91 | A |
| ATOM | 646 | CB | GLU | 75 | 25.497 | 38.307 | 2.989 | 1.00 | 56.82 | A |
| ATOM | 647 | CG | GLU | 75 | 26.328 | 38.760 | 1.813 | 1.00 | 69.50 | A |
| ATOM | 648 | CD | GLU | 75 | 25.471 | 39.510 | 0.798 | 1.00 | 77.99 | A |
| ATOM | 649 | OE1 | GLU | 75 | 25.126 | 40.680 | 1.088 | 1.00 | 82.95 | A |
| ATOM | 650 | OE2 | GLU | 75 | 25.114 | 38.928 | −0.260 | 1.00 | 82.16 | A |
| ATOM | 651 | C | GLU | 75 | 25.394 | 37.997 | 5.443 | 1.00 | 48.94 | A |
| ATOM | 652 | O | GLU | 75 | 25.730 | 38.744 | 6.365 | 1.00 | 51.40 | A |
| ATOM | 653 | N | LEU | 76 | 24.299 | 37.249 | 5.489 | 1.00 | 44.75 | A |
| ATOM | 654 | H | LEU | 76 | 24.127 | 36.648 | 4.731 | 0.00 | 0.00 | A |
| ATOM | 655 | CA | LEU | 76 | 23.399 | 37.318 | 6.625 | 1.00 | 41.03 | A |
| ATOM | 656 | CB | LEU | 76 | 22.285 | 36.297 | 6.472 | 1.00 | 43.69 | A |
| ATOM | 657 | CG | LEU | 76 | 21.533 | 36.579 | 5.175 | 1.00 | 46.14 | A |
| ATOM | 658 | CD1 | LEU | 76 | 20.772 | 35.387 | 4.717 | 1.00 | 49.05 | A |
| ATOM | 659 | CD2 | LEU | 76 | 20.606 | 37.739 | 5.376 | 1.00 | 50.35 | A |
| ATOM | 660 | C | LEU | 76 | 24.163 | 37.082 | 7.909 | 1.00 | 39.22 | A |
| ATOM | 661 | O | LEU | 76 | 23.965 | 37.793 | 8.885 | 1.00 | 40.49 | A |
| ATOM | 662 | N | LEU | 77 | 25.086 | 36.131 | 7.899 | 1.00 | 36.28 | A |
| ATOM | 663 | H | LEU | 77 | 25.271 | 35.640 | 7.083 | 0.00 | 0.00 | A |
| ATOM | 664 | CA | LEU | 77 | 25.853 | 35.854 | 9.099 | 1.00 | 35.31 | A |
| ATOM | 665 | CB | LEU | 77 | 26.873 | 34.751 | 8.851 | 1.00 | 33.92 | A |
| ATOM | 666 | CG | LEU | 77 | 27.923 | 34.616 | 9.953 | 1.00 | 31.12 | A |
| ATOM | 667 | CD1 | LEU | 77 | 27.228 | 34.447 | 11.270 | 1.00 | 29.53 | A |
| ATOM | 668 | CD2 | LEU | 77 | 28.869 | 33.456 | 9.673 | 1.00 | 27.00 | A |
| ATOM | 669 | C | LEU | 77 | 26.571 | 37.099 | 9.584 | 1.00 | 35.33 | A |
| ATOM | 670 | O | LEU | 77 | 26.409 | 37.504 | 10.728 | 1.00 | 35.14 | A |
| ATOM | 671 | N | ARG | 78 | 27.331 | 37.721 | 8.697 | 1.00 | 37.12 | A |
| ATOM | 672 | H | ARG | 78 | 27.384 | 37.360 | 7.787 | 0.00 | 0.00 | A |
| ATOM | 673 | CA | ARG | 78 | 28.086 | 38.911 | 9.048 | 1.00 | 40.53 | A |
| ATOM | 674 | CB | ARG | 78 | 28.919 | 39.385 | 7.864 | 1.00 | 41.86 | A |
| ATOM | 675 | CG | ARG | 78 | 29.833 | 38.321 | 7.288 | 1.00 | 47.67 | A |
| ATOM | 676 | CD | ARG | 78 | 30.708 | 38.887 | 6.182 | 1.00 | 52.26 | A |
| ATOM | 677 | NE | ARG | 78 | 30.862 | 37.963 | 5.060 | 1.00 | 58.41 | A |
| ATOM | 678 | HE | ARG | 78 | 31.473 | 37.207 | 5.270 | 0.00 | 0.00 | A |
| ATOM | 679 | CZ | ARG | 78 | 30.204 | 38.078 | 3.906 | 1.00 | 60.91 | A |
| ATOM | 680 | NH1 | ARG | 78 | 30.403 | 37.188 | 2.931 | 1.00 | 63.31 | A |
| ATOM | 681 | HH11 | ARG | 78 | 31.020 | 36.417 | 3.091 | 0.00 | 0.00 | A |
| ATOM | 682 | HH12 | ARG | 78 | 29.897 | 37.200 | 2.057 | 0.00 | 0.00 | A |
| ATOM | 683 | NH2 | ARG | 78 | 29.343 | 39.082 | 3.727 | 1.00 | 61.35 | A |
| ATOM | 684 | HH21 | ARG | 78 | 29.182 | 39.741 | 4.466 | 0.00 | 0.00 | A |
| ATOM | 685 | HH22 | ARG | 78 | 28.790 | 39.193 | 2.888 | 0.00 | 0.00 | A |
| ATOM | 686 | C | ARG | 78 | 27.232 | 40.053 | 9.583 | 1.00 | 41.80 | A |
| ATOM | 687 | O | ARG | 78 | 27.656 | 40.750 | 10.497 | 1.00 | 43.93 | A |
| ATOM | 688 | N | GLU | 79 | 26.038 | 40.248 | 9.027 | 1.00 | 42.51 | A |
| ATOM | 689 | H | GLU | 79 | 25.751 | 39.663 | 8.293 | 0.00 | 0.00 | A |
| ATOM | 690 | CA | GLU | 79 | 25.149 | 41.317 | 9.489 | 1.00 | 43.72 | A |
| ATOM | 691 | CB | GLU | 79 | 23.944 | 41.475 | 8.564 | 1.00 | 46.44 | A |
| ATOM | 692 | CG | GLU | 79 | 22.919 | 42.512 | 9.026 | 1.00 | 51.28 | A |
| ATOM | 693 | CD | GLU | 79 | 23.459 | 43.947 | 9.085 | 1.00 | 56.78 | A |
| ATOM | 694 | OE1 | GLU | 79 | 24.634 | 44.207 | 8.721 | 1.00 | 59.39 | A |
| ATOM | 695 | OE2 | GLU | 79 | 22.688 | 44.834 | 9.509 | 1.00 | 57.97 | A |
| ATOM | 696 | C | GLU | 79 | 24.655 | 41.024 | 10.894 | 1.00 | 43.92 | A |
| ATOM | 697 | O | GLU | 79 | 24.802 | 41.845 | 11.802 | 1.00 | 46.22 | A |
| ATOM | 698 | N | ALA | 80 | 24.053 | 39.855 | 11.070 | 1.00 | 42.17 | A |
| ATOM | 699 | H | ALA | 80 | 23.945 | 39.254 | 10.301 | 0.00 | 0.00 | A |
| ATOM | 700 | CA | ALA | 80 | 23.570 | 39.465 | 12.370 | 1.00 | 39.72 | A |
| ATOM | 701 | CB | ALA | 80 | 23.103 | 38.056 | 12.338 | 1.00 | 40.66 | A |
| ATOM | 702 | C | ALA | 80 | 24.742 | 39.624 | 13.325 | 1.00 | 39.96 | A |
| ATOM | 703 | O | ALA | 80 | 24.557 | 40.033 | 14.464 | 1.00 | 40.78 | A |
| ATOM | 704 | N | TRP | 81 | 25.958 | 39.386 | 12.840 | 1.00 | 39.30 | A |
| ATOM | 705 | H | TRP | 81 | 26.066 | 39.083 | 11.914 | 0.00 | 0.00 | A |
| ATOM | 706 | CA | TRP | 81 | 27.136 | 39.543 | 13.689 | 1.00 | 42.05 | A |
| ATOM | 707 | CB | TRP | 81 | 28.375 | 38.926 | 13.050 | 1.00 | 38.33 | A |
| ATOM | 708 | CG | TRP | 81 | 29.620 | 38.975 | 13.907 | 1.00 | 37.75 | A |
| ATOM | 709 | CD2 | TRP | 81 | 29.748 | 38.617 | 15.300 | 1.00 | 38.66 | A |
| ATOM | 710 | CE2 | TRP | 81 | 31.102 | 38.807 | 15.659 | 1.00 | 37.15 | A |
| ATOM | 711 | CE3 | TRP | 81 | 28.854 | 38.158 | 16.275 | 1.00 | 38.12 | A |
| ATOM | 712 | CD1 | TRP | 81 | 30.862 | 39.346 | 13.502 | 1.00 | 39.82 | A |
| ATOM | 713 | NE1 | TRP | 81 | 31.759 | 39.246 | 14.543 | 1.00 | 40.19 | A |
| ATOM | 714 | HE1 | TRP | 81 | 32.732 | 39.410 | 14.494 | 0.00 | 0.00 | A |
| ATOM | 715 | CZ2 | TRP | 81 | 31.581 | 38.558 | 16.943 | 1.00 | 34.97 | A |
| ATOM | 716 | CZ3 | TRP | 81 | 29.336 | 37.907 | 17.555 | 1.00 | 36.98 | A |
| ATOM | 717 | CH2 | TRP | 81 | 30.686 | 38.111 | 17.874 | 1.00 | 35.39 | A |
| ATOM | 718 | C | TRP | 81 | 27.395 | 41.014 | 13.972 | 1.00 | 46.61 | A |
| ATOM | 719 | O | TRP | 81 | 27.639 | 41.395 | 15.116 | 1.00 | 48.53 | A |
| ATOM | 720 | N | ARG | 82 | 27.326 | 41.846 | 12.938 | 1.00 | 50.32 | A |
| ATOM | 721 | H | ARG | 82 | 27.076 | 41.499 | 12.063 | 0.00 | 0.00 | A |
| ATOM | 722 | CA | ARG | 82 | 27.560 | 43.272 | 13.100 | 1.00 | 52.07 | A |
| ATOM | 723 | CB | ARG | 82 | 27.252 | 44.030 | 11.812 | 1.00 | 55.97 | A |
| ATOM | 724 | CG | ARG | 82 | 27.495 | 45.543 | 11.910 | 1.00 | 64.10 | A |
| ATOM | 725 | CD | ARG | 82 | 26.946 | 46.311 | 10.690 | 1.00 | 68.44 | A |
| ATOM | 726 | NE | ARG | 82 | 25.484 | 46.268 | 10.607 | 1.00 | 70.46 | A |
| ATOM | 727 | HE | ARG | 82 | 25.121 | 45.686 | 9.886 | 0.00 | 0.00 | A |
| ATOM | 728 | CZ | ARG | 82 | 24.665 | 46.928 | 11.423 | 1.00 | 71.72 | A |
| ATOM | 729 | NH1 | ARG | 82 | 23.351 | 46.821 | 11.269 | 1.00 | 72.58 | A |
| ATOM | 730 | HH11 | ARG | 82 | 23.043 | 46.234 | 10.504 | 0.00 | 0.00 | A |
| ATOM | 731 | HH12 | ARG | 82 | 22.657 | 47.276 | 11.819 | 0.00 | 0.00 | A |
| ATOM | 732 | NH2 | ARC | 82 | 25.160 | 47.705 | 12.385 | 1.00 | 72.76 | A |
| ATOM | 733 | HH21 | ARG | 82 | 26.153 | 47.790 | 12.487 | 0.00 | 0.00 | A |
| ATOM | 734 | HH22 | ARG | 82 | 24.580 | 48.221 | 13.018 | 0.00 | 0.00 | A |
| ATOM | 735 | C | ARG | 82 | 26.639 | 43.759 | 14.193 | 1.00 | 52.64 | A |
| ATOM | 736 | O | ARG | 82 | 27.088 | 44.305 | 15.202 | 1.00 | 53.08 | A |
| ATOM | 737 | N | ARG | 83 | 25.353 | 43.491 | 14.016 | 1.00 | 52.67 | A |
| ATOM | 738 | H | ARG | 83 | 25.085 | 42.990 | 13.222 | 0.00 | 0.00 | A |
| ATOM | 739 | CA | ARG | 83 | 24.363 | 43.900 | 14.984 | 1.00 | 54.47 | A |
| ATOM | 740 | CB | ARG | 83 | 22.976 | 43.469 | 14.540 | 1.00 | 56.44 | A |
| ATOM | 741 | CG | ARG | 83 | 22.640 | 43.960 | 13.169 | 1.00 | 62.89 | A |
| ATOM | 742 | CD | ARG | 83 | 21.158 | 43.897 | 12.898 | 1.00 | 70.83 | A |
| ATOM | 743 | NE | ARG | 83 | 20.920 | 44.170 | 11.485 | 1.00 | 78.75 | A |
| ATOM | 744 | HE | ARG | 83 | 21.737 | 44.321 | 10.981 | 0.00 | 0.00 | A |
| ATOM | 745 | CZ | ARG | 83 | 19.733 | 44.144 | 10.880 | 1.00 | 82.99 | A |
| ATOM | 746 | NH1 | ARG | 83 | 19.660 | 44.407 | 9.575 | 1.00 | 86.53 | A |
| ATOM | 747 | HH11 | ARG | 83 | 20.535 | 44.590 | 9.092 | 0.00 | 0.00 | A |
| ATOM | 748 | HH12 | ARG | 83 | 18.821 | 44.398 | 9.028 | 0.00 | 0.00 | A |
| ATOM | 749 | NH2 | ARG | 83 | 18.629 | 43.849 | 11.565 | 1.00 | 85.70 | A |
| ATOM | 750 | HH21 | ARG | 83 | 18.687 | 43.634 | 12.543 | 0.00 | 0.00 | A |
| ATOM | 751 | HH22 | ARG | 83 | 17.721 | 43.804 | 11.138 | 0.00 | 0.00 | A |
| ATOM | 752 | C | ARG | 83 | 24.684 | 43.331 | 16.355 | 1.00 | 55.06 | A |
| ATOM | 753 | O | ARG | 83 | 24.586 | 44.034 | 17.359 | 1.00 | 58.66 | A |
| ATOM | 754 | N | ILE | 84 | 25.115 | 42.081 | 16.411 | 1.00 | 53.17 | A |
| ATOM | 755 | H | ILE | 84 | 25.216 | 41.550 | 15.595 | 0.00 | 0.00 | A |
| ATOM | 756 | CA | ILE | 84 | 25.428 | 41.500 | 17.701 | 1.00 | 52.18 | A |
| ATOM | 757 | CB | ILE | 84 | 25.805 | 40.011 | 17.568 | 1.00 | 51.79 | A |
| ATOM | 758 | CG2 | ILE | 84 | 26.376 | 39.472 | 18.887 | 1.00 | 48.98 | A |
| ATOM | 759 | CG1 | ILE | 84 | 24.567 | 39.214 | 17.152 | 1.00 | 51.44 | A |
| ATOM | 760 | CD1 | ILE | 84 | 24.863 | 37.808 | 16.731 | 1.00 | 51.44 | A |
| ATOM | 761 | C | ILE | 84 | 26.539 | 42.283 | 18.388 | 1.00 | 52.41 | A |
| ATOM | 762 | O | ILE | 84 | 26.417 | 42.659 | 19.555 | 1.00 | 52.74 | A |
| ATOM | 763 | N | GLN | 85 | 27.590 | 42.592 | 17.644 | 1.00 | 52.68 | A |
| ATOM | 764 | H | GLN | 85 | 27.593 | 42.351 | 16.699 | 0.00 | 0.00 | A |
| ATOM | 765 | CA | GLN | 85 | 28.715 | 43.310 | 18.214 | 1.00 | 54.90 | A |
| ATOM | 766 | CB | GLN | 85 | 29.845 | 43.437 | 17.202 | 1.00 | 56.98 | A |
| ATOM | 767 | CG | GLN | 85 | 30.449 | 42.119 | 16.774 | 1.00 | 61.89 | A |
| ATOM | 768 | CD | GLN | 85 | 31.701 | 42.300 | 15.935 | 1.00 | 65.11 | A |
| ATOM | 769 | OE1 | GLN | 85 | 32.820 | 42.177 | 16.437 | 1.00 | 68.32 | A |
| ATOM | 770 | NE2 | GLN | 85 | 31.521 | 42.592 | 14.649 | 1.00 | 67.22 | A |
| ATOM | 771 | HE21 | GLN | 85 | 30.611 | 42.667 | 14.301 | 0.00 | 0.00 | A |
| ATOM | 772 | HE22 | GLN | 85 | 32.335 | 42.706 | 14.123 | 0.00 | 0.00 | A |
| ATOM | 773 | C | GLN | 85 | 28.306 | 44.686 | 18.682 | 1.00 | 55.53 | A |
| ATOM | 774 | O | GLN | 85 | 28.765 | 45.161 | 19.721 | 1.00 | 56.98 | A |
| ATOM | 775 | N | ALA | 86 | 27.426 | 45.314 | 17.916 | 1.00 | 55.14 | A |
| ATOM | 776 | H | ALA | 86 | 27.087 | 44.860 | 17.116 | 0.00 | 0.00 | A |
| ATOM | 777 | CA | ALA | 86 | 26.949 | 46.648 | 18.232 | 1.00 | 54.85 | A |
| ATOM | 778 | CB | ALA | 86 | 26.059 | 47.159 | 17.138 | 1.00 | 55.46 | A |
| ATOM | 779 | C | ALA | 86 | 26.205 | 46.663 | 19.542 | 1.00 | 55.92 | A |
| ATOM | 780 | O | ALA | 86 | 26.148 | 47.692 | 20.203 | 1.00 | 58.87 | A |
| ATOM | 781 | N | LYS | 87 | 25.599 | 45.534 | 19.899 | 1.00 | 57.19 | A |
| ATOM | 782 | H | LYS | 87 | 25.627 | 44.753 | 19.303 | 0.00 | 0.00 | A |
| ATOM | 783 | CA | LYS | 87 | 24.871 | 45.433 | 21.159 | 1.00 | 57.01 | A |
| ATOM | 784 | CB | LYS | 87 | 23.890 | 44.252 | 21.123 | 1.00 | 58.40 | A |
| ATOM | 785 | CG | LYS | 87 | 22.771 | 44.333 | 22.172 | 1.00 | 62.46 | A |
| ATOM | 786 | CD | LYS | 87 | 22.008 | 43.008 | 22.359 | 1.00 | 62.00 | A |
| ATOM | 787 | CE | LYS | 87 | 21.018 | 43.083 | 23.530 | 1.00 | 61.79 | A |
| ATOM | 788 | NZ | LYS | 87 | 20.803 | 41.767 | 24.198 | 1.00 | 59.11 | A |
| ATOM | 789 | HZ1 | LYS | 87 | 20.121 | 41.870 | 24.993 | 0.00 | 0.00 | A |
| ATOM | 790 | HZ2 | LYS | 87 | 21.681 | 41.431 | 24.616 | 0.00 | 0.00 | A |
| ATOM | 791 | HZ3 | LYS | 87 | 20.450 | 41.049 | 23.540 | 0.00 | 0.00 | A |
| ATOM | 792 | C | LYS | 87 | 25.913 | 45.267 | 22.280 | 1.00 | 56.72 | A |
| ATOM | 793 | O | LYS | 87 | 25.573 | 45.129 | 23.454 | 1.00 | 55.76 | A |
| ATOM | 794 | N | GLY | 88 | 27.184 | 45.240 | 21.889 | 1.00 | 56.94 | A |
| ATOM | 795 | H | GLY | 88 | 27.408 | 45.278 | 20.950 | 0.00 | 0.00 | A |
| ATOM | 796 | CA | GLY | 88 | 28.269 | 45.130 | 22.840 | 1.00 | 58.00 | A |
| ATOM | 797 | C | GLY | 88 | 28.911 | 43.775 | 23.069 | 1.00 | 60.12 | A |
| ATOM | 798 | O | GLY | 88 | 29.880 | 43.684 | 23.827 | 1.00 | 63.62 | A |
| ATOM | 799 | N | TYR | 89 | 28.428 | 42.722 | 22.420 | 1.00 | 58.51 | A |
| ATOM | 800 | H | TYR | 89 | 27.711 | 42.835 | 21.766 | 0.00 | 0.00 | A |
| ATOM | 801 | CA | TYR | 89 | 29.016 | 41.407 | 22.654 | 1.00 | 54.55 | A |
| ATOM | 802 | CB | TYR | 89 | 27.976 | 40.310 | 22.421 | 1.00 | 54.07 | A |
| ATOM | 803 | CG | TYR | 89 | 26.698 | 40.482 | 23.208 | 1.00 | 51.97 | A |
| ATOM | 804 | CD1 | TYR | 89 | 25.592 | 41.096 | 22.634 | 1.00 | 53.11 | A |
| ATOM | 805 | CE1 | TYR | 89 | 24.390 | 41.210 | 23.324 | 1.00 | 52.90 | A |
| ATOM | 806 | CD2 | TYR | 89 | 26.576 | 39.990 | 24.505 | 1.00 | 49.82 | A |
| ATOM | 807 | CE2 | TYR | 89 | 25.374 | 40.104 | 25.210 | 1.00 | 50.76 | A |
| ATOM | 808 | CZ | TYR | 89 | 24.281 | 40.713 | 24.607 | 1.00 | 53.59 | A |
| ATOM | 809 | OH | TYR | 89 | 23.066 | 40.821 | 25.257 | 1.00 | 56.60 | A |
| ATOM | 810 | HH | TYR | 89 | 23.163 | 40.512 | 26.168 | 0.00 | 0.00 | A |
| ATOM | 811 | C | TYR | 89 | 30.244 | 41.134 | 21.797 | 1.00 | 52.34 | A |
| ATOM | 812 | O | TYR | 89 | 30.473 | 41.808 | 20.799 | 1.00 | 50.71 | A |
| ATOM | 813 | N | THR | 90 | 31.053 | 40.175 | 22.233 | 1.00 | 51.85 | A |
| ATOM | 814 | H | THE | 90 | 30.841 | 39.730 | 23.081 | 0.00 | 0.00 | A |
| ATOM | 815 | CA | THR | 90 | 32.245 | 39.743 | 21.505 | 1.00 | 53.32 | A |
| ATOM | 816 | CB | THR | 90 | 33.568 | 40.187 | 22.180 | 1.00 | 54.28 | A |
| ATOM | 817 | OG1 | THR | 90 | 33.661 | 39.640 | 23.503 | 1.00 | 58.40 | A |
| ATOM | 818 | HG1 | THR | 90 | 32.959 | 40.048 | 24.021 | 0.00 | 0.00. | A |
| ATOM | 819 | CG2 | THR | 90 | 33.632 | 41.679 | 22.267 | 1.00 | 56.17 | A |
| ATOM | 820 | C | THR | 90 | 32.182 | 38.216 | 21.480 | 1.00 | 51.90 | A |
| ATOM | 821 | O | THR | 90 | 31.660 | 37.591 | 22.416 | 1.00 | 51.56 | A |
| ATOM | 822 | N | LEU | 91 | 32.723 | 37.611 | 20.430 | 1.00 | 49.36 | A |
| ATOM | 823 | H | LEU | 91 | 33.184 | 38.137 | 19.745 | 0.00 | 0.00 | A |
| ATOM | 824 | CA | LEU | 91 | 32.664 | 36.161 | 20.299 | 1.00 | 46.19 | A |
| ATOM | 825 | CB | LEU | 91 | 33.088 | 35.730 | 18.902 | 1.00 | 39.87 | A |
| ATOM | 826 | CG | LEU | 91 | 32.847 | 34.262 | 18.584 | 1.00 | 34.13 | A |
| ATOM | 827 | CD1 | LEU | 91 | 31.435 | 34.137 | 18.052 | 1.00 | 36.72 | A |
| ATOM | 828 | CD2 | LEU | 91 | 33.846 | 33.783 | 17.546 | 1.00 | 32.22 | A |
| ATOM | 829 | C | LEU | 91 | 33.465 | 35.369 | 21.315 | 1.00 | 46.20 | A |
| ATOM | 830 | O | LEU | 91 | 34.645 | 35.623 | 21.525 | 1.00 | 47.57 | A |
| ATOM | 831 | N | GLY | 92 | 32.805 | 34.414 | 21.953 | 1.00 | 46.14 | A |
| ATOM | 832 | H | GLY | 92 | 31.850 | 34.287 | 21.791 | 0.00 | 0.00 | A |
| ATOM | 833 | CA | GLY | 92 | 33.490 | 33.561 | 22.901 | 1.00 | 45.45 | A |
| ATOM | 834 | C | GLY | 92 | 33.992 | 32.430 | 22.041 | 1.00 | 45.08 | A |
| ATOM | 835 | O | GLY | 92 | 35.190 | 32.249 | 21.888 | 1.00 | 49.03 | A |
| ATOM | 836 | N | ASN | 93 | 33.054 | 31.711 | 21.432 | 1.00 | 43.48 | A |
| ATOM | 837 | H | ASN | 93 | 32.110 | 31.939 | 21.577 | 0.00 | 0.00 | A |
| ATOM | 838 | CA | ASN | 93 | 33.352 | 30.593 | 20.538 | 1.00 | 39.47 | A |
| ATOM | 839 | CB | ASN | 93 | 34.161 | 29.526 | 21.235 | 1.00 | 39.34 | A |
| ATOM | 840 | CG | ASN | 93 | 33.363 | 28.795 | 22.268 | 1.00 | 39.86 | A |
| ATOM | 841 | CD1 | ASN | 93 | 33.191 | 27.582 | 22.192 | 1.00 | 35.91 | A |
| ATOM | 842 | ND2 | ASN | 93 | 32.868 | 29.532 | 23.257 | 1.00 | 44.26 | A |
| ATOM | 843 | HD21 | ASN | 93 | 33.070 | 30.485 | 23.268 | 0.00 | 0.00 | A |
| ATOM | 844 | HD22 | ASN | 93 | 32.318 | 29.088 | 23.930 | 0.00 | 0.00 | A |
| ATOM | 845 | C | ASN | 93 | 32.048 | 29.965 | 20.091 | 1.00 | 38.43 | A |
| ATOM | 846 | O | ASN | 93 | 31.007 | 30.146 | 20.735 | 1.00 | 38.86 | A |
| ATOM | 847 | N | VAL | 94 | 32.112 | 29.216 | 18.999 | 1.00 | 36.27 | A |
| ATOM | 848 | H | VAL | 94 | 32.976 | 29.064 | 18.555 | 0.00 | 0.00 | A |
| ATOM | 849 | CA | VAL | 94 | 30.942 | 28.557 | 18.449 | 1.00 | 34.16 | A |
| ATOM | 850 | CB | VAL | 94 | 30.435 | 29.287 | 17.197 | 1.00 | 32.82 | A |
| ATOM | 851 | CG1 | VAL | 94 | 30.098 | 30.727 | 17.525 | 1.00 | 30.33 | A |
| ATOM | 852 | CG2 | VAL | 94 | 31.476 | 29.219 | 16.104 | 1.00 | 33.81 | A |
| ATOM | 853 | C | VAL | 94 | 31.267 | 27.112 | 18.075 | 1.00 | 34.08 | A |
| ATOM | 854 | O | VAL | 94 | 32.432 | 26.765 | 17.810 | 1.00 | 35.73 | A |
| ATOM | 855 | N | ASP | 95 | 30.235 | 26.275 | 18.092 | 1.00 | 32.46 | A |
| ATOM | 856 | H | ASP | 95 | 29.347 | 26.589 | 18.354 | 0.00 | 0.00 | A |
| ATOM | 857 | CA | ASP | 95 | 30.355 | 24.873 | 17.741 | 1.00 | 29.24 | A |
| ATOM | 858 | CB | ASP | 95 | 30.353 | 24.002 | 18.980 | 1.00 | 30.14 | A |
| ATOM | 859 | CG | ASP | 95 | 30.835 | 22.610 | 18.694 | 1.00 | 32.11 | A |
| ATOM | 860 | OD1 | ASP | 95 | 30.711 | 21.721 | 19.552 | 1.00 | 32.23 | A |
| ATOM | 861 | OD2 | ASP | 95 | 31.351 | 22.375 | 17.591 | 1.00 | 35.88 | A |
| ATOM | 862 | C | ASP | 95 | 29.142 | 24.544 | 16.906 | 1.00 | 29.48 | A |
| ATOM | 863 | O | ASP | 95 | 28.007 | 24.881 | 17.286 | 1.00 | 30.34 | A |
| ATOM | 864 | N | VAL | 96 | 29.380 | 23.939 | 15.749 | 1.00 | 27.22 | A |
| ATOM | 865 | H | VAL | 96 | 30.314 | 23.728 | 15.534 | 0.00 | 0.00 | A |
| ATOM | 866 | CA | VAL | 96 | 28.310 | 23.572 | 14.830 | 1.00 | 26.10 | A |
| ATOM | 867 | CB | VAL | 96 | 28.543 | 24.253 | 13.463 | 1.00 | 25.27 | A |
| ATOM | 868 | CG1 | VAL | 96 | 27.416 | 23.937 | 12.483 | 1.00 | 24.61 | A |
| ATOM | 869 | CG2 | VAL | 96 | 28.644 | 25.736 | 13.648 | 1.00 | 23.46 | A |
| ATOM | 870 | C | VAL | 96 | 28.257 | 22.048 | 14.647 | 1.00 | 26.90 | A |
| ATOM | 871 | O | VAL | 96 | 29.275 | 21.361 | 14.730 | 1.00 | 29.30 | A |
| ATOM | 872 | N | THR | 97 | 27.077 | 21.493 | 14.438 | 1.00 | 26.67 | A |
| ATOM | 873 | H | THR | 97 | 26.269 | 22.034 | 14.375 | 0.00 | 0.00 | A |
| ATOM | 874 | CA | THR | 97 | 26.986 | 20.062 | 14.224 | 1.00 | 28.11 | A |
| ATOM | 875 | CB | THR | 97 | 26.318 | 19.355 | 15.371 | 1.00 | 25.26 | A |
| ATOM | 876 | OG1 | THR | 97 | 27.055 | 19.587 | 16.570 | 1.00 | 30.62 | A |
| ATOM | 877 | HG1 | THR | 97 | 27.916 | 19.228 | 16.333 | 0.00 | 0.00 | A |
| ATOM | 878 | CG2 | THR | 97 | 26.295 | 17.895 | 15.105 | 1.00 | 22.05 | A |
| ATOM | 879 | C | THR | 97 | 26.114 | 19.855 | 13.019 | 1.00 | 31.81 | A |
| ATOM | 880 | O | THR | 97 | 24.920 | 20.126 | 13.083 | 1.00 | 38.03 | A |
| ATOM | 881 | N | ILE | 98 | 26.711 | 19.452 | 11.905 | 1.00 | 32.00 | A |
| ATOM | 882 | H | ILE | 98 | 27.674 | 19.297 | 11.903 | 0.00 | 0.00 | A |
| ATOM | 883 | CA | ILE | 98 | 25.962 | 19.204 | 10.683 | 1.00 | 32.35 | A |
| ATOM | 884 | CB | ILE | 98 | 26.866 | 19.327 | 9.464 | 1.00 | 31.39 | A |
| ATOM | 885 | CG2 | ILE | 98 | 26.093 | 19.015 | 8.198 | 1.00 | 29.13 | A |
| ATOM | 886 | CG1 | ILE | 98 | 27.454 | 20.729 | 9.413 | 1.00 | 29.61 | A |
| ATOM | 887 | CD1 | ILE | 98 | 28.565 | 20.850 | 8.425 | 1.00 | 33.37 | A |
| ATOM | 888 | C | ILE | 98 | 25.442 | 17.774 | 10.781 | 1.00 | 34.71 | A |
| ATOM | 889 | O | ILE | 98 | 26.210 | 16.838 | 11.029 | 1.00 | 39.37 | A |
| ATOM | 890 | N | ILE | 99 | 24.137 | 17.606 | 10.651 | 1.00 | 33.08 | A |
| ATOM | 891 | H | ILE | 99 | 23.549 | 18.366 | 10.454 | 0.00 | 0.00 | A |
| ATOM | 892 | CA | ILE | 99 | 23.542 | 16.288 | 10.739 | 1.00 | 30.93 | A |
| ATOM | 893 | CB | ILE | 99 | 22.358 | 16.300 | 11.711 | 1.00 | 26.85 | A |
| ATOM | 894 | CG2 | ILE | 99 | 21.784 | 14.937 | 11.849 | 1.00 | 22.64 | A |
| ATOM | 895 | CG1 | ILE | 99 | 22.836 | 16.773 | 13.074 | 1.00 | 25.93 | A |
| ATOM | 896 | CD1 | ILE | 99 | 21.754 | 16.917 | 14.079 | 1.00 | 25.84 | A |
| ATOM | 897 | C | ILE | 99 | 23.085 | 15.962 | 9.330 | 1.00 | 32.99 | A |
| ATOM | 898 | O | ILE | 99 | 22.112 | 16.532 | 8.845 | 1.00 | 35.97 | A |
| ATOM | 899 | N | ALA | 100 | 23.831 | 15.102 | 8.648 | 1.00 | 33.05 | A |
| ATOM | 900 | H | ALA | 100 | 24.637 | 14.720 | 9.049 | 0.00 | 0.00 | A |
| ATOM | 901 | CA | ALA | 100 | 23.503 | 14.716 | 7.291 | 1.00 | 32.96 | A |
| ATOM | 902 | CB | ALA | 100 | 24.043 | 15.728 | 6.341 | 1.00 | 34.32 | A |
| ATOM | 903 | C | ALA | 100 | 24.063 | 13.342 | 6.970 | 1.00 | 35.90 | A |
| ATOM | 904 | O | ALA | 100 | 25.150 | 12.989 | 7.413 | 1.00 | 36.85 | A |
| ATOM | 905 | N | GLN | 101 | 23.293 | 12.554 | 6.227 | 1.00 | 38.33 | A |
| ATOM | 906 | H | GLN | 101 | 22.428 | 12.908 | 5.926 | 0.00 | 0.00 | A |
| ATOM | 907 | CA | GLN | 101 | 23.698 | 11.203 | 5.835 | 1.00 | 39.38 | A |
| ATOM | 908 | CB | GLN | 101 | 22.491 | 10.455 | 5.265 | 1.00 | 42.32 | A |
| ATOM | 909 | CG | GLN | 101 | 22.674 | 8.960 | 5.077 | 1.00 | 42.69 | A |
| ATOM | 910 | CD | GLN | 101 | 22.830 | 8.238 | 6.387 | 1.00 | 45.23 | A |
| ATOM | 911 | OE1 | GLN | 101 | 23.519 | 7.223 | 6.469 | 1.00 | 51.65 | A |
| ATOM | 912 | NE2 | GLN | 101 | 22.185 | 8.751 | 7.431 | 1.00 | 46.60 | A |
| ATOM | 913 | HE21 | GLN | 101 | 21.593 | 9.521 | 7.308 | 0.00 | 0.00 | A |
| ATOM | 914 | HE22 | GLN | 101 | 22.365 | 8.326 | 8.291 | 0.00 | 0.00 | A |
| ATOM | 915 | C | GLN | 101 | 24.764 | 11.318 | 4.759 | 1.00 | 38.81 | A |
| ATOM | 916 | O | GLN | 101 | 25.644 | 10.473 | 4.625 | 1.00 | 39.22 | A |
| ATOM | 917 | N | ALA | 102 | 24.639 | 12.366 | 3.966 | 1.00 | 38.46 | A |
| ATOM | 918 | H | ALA | 102 | 23.903 | 13.003 | 4.082 | 0.00 | 0.00 | A |
| ATOM | 919 | CA | ALA | 102 | 25.563 | 12.638 | 2.889 | 1.00 | 38.28 | A |
| ATOM | 920 | CB | ALA | 102 | 25.407 | 11.613 | 1.834 | 1.00 | 36.84 | A |
| ATOM | 921 | C | ALA | 102 | 25.124 | 13.988 | 2.372 | 1.00 | 39.02 | A |
| ATOM | 922 | O | ALA | 102 | 23.975 | 14.369 | 2.583 | 1.00 | 40.61 | A |
| ATOM | 923 | N | PRO | 103 | 25.982 | 14.695 | 1.615 | 1.00 | 39.15 | A |
| ATOM | 924 | CD | PRO | 103 | 25.577 | 16.001 | 1.058 | 1.00 | 37.61 | A |
| ATOM | 925 | CA | PRO | 103 | 27.339 | 14.345 | 1.188 | 1.00 | 39.10 | A |
| ATOM | 926 | CB | PRO | 103 | 27.659 | 15.457 | 0.190 | 1.00 | 37.26 | A |
| ATOM | 927 | CG | PRO | 103 | 26.875 | 16.616 | 0.698 | 1.00 | 34.70 | A |
| ATOM | 928 | C | PRO | 103 | 28.352 | 14.264 | 2.334 | 1.00 | 42.77 | A |
| ATOM | 929 | O | PRO | 103 | 27.992 | 14.481 | 3.489 | 1.00 | 45.37 | A |
| ATOM | 930 | N | LYS | 104 | 29.601 | 13.895 | 2.035 | 1.00 | 45.27 | A |
| ATOM | 931 | H | LYS | 104 | 29.846 | 13.710 | 1.107 | 0.00 | 0.00 | A |
| ATOM | 932 | CA | LYS | 104 | 30.627 | 13.805 | 3.081 | 1.00 | 44.20 | A |
| ATOM | 933 | CB | LYS | 104 | 31.797 | 12.920 | 2.648 | 1.00 | 50.54 | A |
| ATOM | 934 | CG | LYS | 104 | 32.513 | 12.256 | 3.827 | 1.00 | 62.62 | A |
| ATOM | 935 | CD | LYS | 104 | 31.514 | 11.371 | 4.589 | 1.00 | 76.42 | A |
| ATOM | 936 | CE | LYS | 104 | 32.070 | 10.739 | 5.881 | 1.00 | 83.18 | A |
| ATOM | 937 | NZ | LYS | 104 | 30.982 | 9.986 | 6.640 | 1.00 | 88.44 | A |
| ATOM | 938 | HZ1 | LYS | 104 | 30.601 | 9.227 | 6.038 | 0.00 | 0.00 | A |
| ATOM | 939 | HZ2 | LYS | 104 | 30.206 | 10.636 | 6.886 | 0.00 | 0.00 | A |
| ATOM | 940 | HZ3 | LYS | 104 | 31.386 | 9.565 | 7.507 | 0.00 | 0.00 | A |
| ATOM | 941 | C | LYS | 104 | 31.127 | 15.201 | 3.418 | 1.00 | 41.08 | A |
| ATOM | 942 | O | LYS | 104 | 31.794 | 15.846 | 2.614 | 1.00 | 43.19 | A |
| ATOM | 943 | N | MET | 105 | 30.751 | 15.678 | 4.589 | 1.00 | 36.31 | A |
| ATOM | 944 | H | MET | 105 | 30.151 | 15.134 | 5.131 | 0.00 | 0.00 | A |
| ATOM | 945 | CA | MET | 105 | 31.124 | 16.992 | 5.037 | 1.00 | 31.86 | A |
| ATOM | 946 | CB | MET | 105 | 30.331 | 17.333 | 6.278 | 1.00 | 32.58 | A |
| ATOM | 947 | CG | MET | 105 | 28.854 | 17.311 | 6.053 | 1.00 | 35.13 | A |
| ATOM | 948 | SD | MET | 105 | 28.493 | 18.486 | 4.777 | 1.00 | 40.47 | A |
| ATOM | 949 | CE | MET | 105 | 26.752 | 18.172 | 4.474 | 1.00 | 36.63 | A |
| ATOM | 950 | C | MET | 105 | 32.577 | 17.078 | 5.373 | 1.00 | 30.67 | A |
| ATOM | 951 | O | MET | 105 | 33.275 | 17.981 | 4.949 | 1.00 | 32.68 | A |
| ATOM | 952 | N | LEU | 106 | 33.040 | 16.116 | 6.131 | 1.00 | 31.08 | A |
| ATOM | 953 | H | LEU | 106 | 32.426 | 15.440 | 6.402 | 0.00 | 0.00 | A |
| ATOM | 954 | CA | LEU | 106 | 34.411 | 16.107 | 6.596 | 1.00 | 36.94 | A |
| ATOM | 955 | CB | LEU | 106 | 34.909 | 14.685 | 6.808 | 1.00 | 40.28 | A |
| ATOM | 956 | CG | LEU | 106 | 36.223 | 14.708 | 7.584 | 1.00 | 42.16 | A |
| ATOM | 957 | CD1 | LEU | 106 | 35.947 | 15.095 | 9.034 | 1.00 | 41.26 | A |
| ATOM | 958 | CD2 | LEU | 106 | 36.905 | 13.363 | 7.489 | 1.00 | 43.74 | A |
| ATOM | 959 | C | LEU | 106 | 35.470 | 16.913 | 5.850 | 1.00 | 37.57 | A |
| ATOM | 960 | O | LEU | 106 | 35.883 | 17.963 | 6.304 | 1.00 | 40.43 | A |
| ATOM | 961 | N | PRO | 107 | 35.862 | 16.480 | 4.663 | 1.00 | 38.57 | A |
| ATOM | 962 | CD | PRO | 107 | 35.190 | 15.508 | 3.795 | 1.00 | 39.15 | A |
| ATOM | 963 | CA | PRO | 107 | 36.887 | 17.211 | 3.912 | 1.00 | 40.04 | A |
| ATOM | 964 | CB | PRO | 107 | 36.865 | 16.513 | 2.559 | 1.00 | 41.84 | A |
| ATOM | 965 | CG | PRO | 107 | 35.451 | 16.092 | 2.435 | 1.00 | 40.97 | A |
| ATOM | 966 | C | PRO | 107 | 36.711 | 18.715 | 3.734 | 1.00 | 40.20 | A |
| ATOM | 957 | O | PRO | 107 | 37.686 | 19.426 | 3.499 | 1.00 | 40.90 | A |
| ATOM | 968 | N | HIS | 108 | 35.476 | 19.198 | 3.809 | 1.00 | 39.98 | A |
| ATOM | 969 | H | HIS | 108 | 34.753 | 18.589 | 4.047 | 0.00 | 0.00 | A |
| ATOM | 970 | CA | HIS | 108 | 35.207 | 20.619 | 3.616 | 1.00 | 39.72 | A |
| ATOM | 971 | CB | HIS | 108 | 33.835 | 20.787 | 2.987 | 1.00 | 38.24 | A |
| ATOM | 972 | CG | HIS | 108 | 33.593 | 19.881 | 1.827 | 1.00 | 35.08 | A |
| ATOM | 973 | CD2 | HIS | 108 | 32.880 | 18.736 | 1.725 | 1.00 | 36.07 | A |
| ATOM | 974 | ND1 | HIS | 108 | 34.112 | 20.122 | 0.577 | 1.00 | 33.69 | A |
| ATOM | 975 | HD1 | HIS | 108 | 34.621 | 20.916 | 0.315 | 0.00 | 0.00 | A |
| ATOM | 976 | CE1 | HIS | 108 | 33.728 | 19.163 | 0.247 | 1.00 | 34.76 | A |
| ATOM | 977 | NE2 | HIS | 108 | 32.979 | 18.309 | 0.426 | 1.00 | 35.43 | A |
| ATOM | 978 | HE2 | HIS | 108 | 32.554 | 17.493 | 0.073 | 0.00 | 0.00 | A |
| ATOM | 979 | C | HIS | 108 | 35.269 | 21.464 | 4.887 | 1.00 | 39.86 | A |
| ATOM | 980 | O | HIS | 108 | 35.406 | 22.688 | 4.834 | 1.00 | 41.64 | A |
| ATOM | 981 | N | ILE | 109 | 35.186 | 20.816 | 6.034 | 1.00 | 38.13 | A |
| ATOM | 982 | H | ILE | 109 | 35.134 | 19.834 | 6.034 | 0.00 | 0.00 | A |
| ATOM | 983 | CA | ILE | 109 | 35.207 | 21.531 | 7.295 | 1.00 | 34.51 | A |
| ATOM | 984 | CB | ILE | 109 | 35.070 | 20.572 | 8.455 | 1.00 | 31.18 | A |
| ATOM | 985 | CG2 | ILE | 109 | 35.118 | 21.312 | 9.760 | 1.00 | 27.62 | A |
| ATOM | 986 | CG1 | ILE | 109 | 33.730 | 19.849 | 8.294 | 1.00 | 30.64 | A |
| ATOM | 987 | CD1 | ILE | 109 | 33.410 | 18.864 | 9.351 | 1.00 | 33.03 | A |
| ATOM | 988 | C | ILE | 109 | 36.313 | 22.542 | 7.526 | 1.00 | 35.78 | A |
| ATOM | 989 | O | ILE | 109 | 36.045 | 23.611 | 8.054 | 1.00 | 39.62 | A |
| ATOM | 990 | N | PRO | 110 | 37.555 | 22.265 | 7.096 | 1.00 | 36.50 | A |
| ATOM | 991 | CD | PRO | 110 | 38.104 | 21.085 | 6.413 | 1.00 | 38.00 | A |
| ATOM | 992 | CA | PRO | 110 | 38.605 | 23.267 | 7.332 | 1.00 | 35.91 | A |
| ATOM | 993 | CB | PRO | 110 | 39.824 | 22.639 | 6.690 | 1.00 | 35.83 | A |
| ATOM | 994 | CG | PRO | 110 | 39.547 | 21.166 | 6.784 | 1.00 | 36.56 | A |
| ATOM | 995 | C | PRO | 110 | 38.251 | 24.568 | 6.631 | 1.00 | 36.73 | A |
| ATOM | 996 | O | PRO | 110 | 38.296 | 25.650 | 7.226 | 1.00 | 35.84 | A |
| ATOM | 997 | N | GLN | 111 | 37.859 | 24.447 | 5.367 | 1.00 | 38.47 | A |
| ATOM | 998 | H | GLN | 111 | 37.821 | 23.558 | 4.957 | 0.00 | 0.00 | A |
| ATOM | 999 | CA | GLN | 111 | 37.467 | 25.607 | 4.579 | 1.00 | 38.09 | A |
| ATOM | 1000 | CB | GLN | 111 | 37.132 | 25.183 | 3.156 | 1.00 | 35.39 | A |
| ATOM | 1001 | CG | GLN | 111 | 36.838 | 26.330 | 2.230 | 1.00 | 33.23 | A |
| ATOM | 1002 | CD | GLN | 111 | 37.935 | 27.359 | 2.236 | 1.00 | 33.42 | A |
| ATOM | 1003 | OE1 | GLN | 111 | 37.681 | 28.530 | 2.456 | 1.00 | 37.52 | A |
| ATOM | 1004 | NE2 | GLN | 111 | 39.169 | 26.926 | 2.020 | 1.00 | 32.86 | A |
| ATOM | 1005 | HE21 | GLN | 111 | 39.253 | 25.966 | 1.908 | 0.00 | 0.00 | A |
| ATOM | 1006 | HE22 | GLN | 111 | 39.878 | 27.605 | 1.988 | 0.00 | 0.00 | A |
| ATOM | 1007 | C | GLN | 111 | 36.266 | 26.303 | 5.223 | 1.00 | 40.04 | A |
| ATOM | 1008 | O | GLN | 111 | 36.176 | 27.531 | 5.206 | 1.00 | 44.61 | A |
| ATOM | 1009 | N | MET | 112 | 35.345 | 25.521 | 5.787 | 1.00 | 39.36 | A |
| ATOM | 1010 | H | MET | 112 | 35.448 | 24.550 | 5.737 | 0.00 | 0.00 | A |
| ATOM | 1011 | CA | MET | 112 | 34.169 | 26.075 | 6.452 | 1.00 | 37.11 | A |
| ATOM | 1012 | CB | MET | 112 | 33.292 | 24.963 | 7.003 | 1.00 | 36.47 | A |
| ATOM | 1013 | CG | MET | 112 | 32.320 | 24.373 | 6.033 | 1.00 | 37.30 | A |
| ATOM | 1014 | SD | MET | 112 | 31.389 | 23.105 | 6.868 | 1.00 | 37.52 | A |
| ATOM | 1015 | CE | MET | 112 | 30.550 | 22.435 | 5.557 | 1.00 | 38.44 | A |
| ATOM | 1016 | C | MET | 112 | 34.609 | 26.936 | 7.621 | 1.00 | 38.47 | A |
| ATOM | 1017 | O | MET | 112 | 34.092 | 28.036 | 7.826 | 1.00 | 39.53 | A |
| ATOM | 1018 | N | ARC | 113 | 35.573 | 26.433 | 8.390 | 1.00 | 38.62 | A |
| ATOM | 1019 | H | ARG | 113 | 35.951 | 25.560 | 8.158 | 0.00 | 0.00 | A |
| ATOM | 1020 | CA | ARG | 113 | 36.068 | 27.153 | 9.556 | 1.00 | 37.95 | A |
| ATOM | 1021 | CB | ARG | 113 | 36.978 | 26.280 | 10.403 | 1.00 | 34.65 | A |
| ATOM | 1022 | CG | ARG | 113 | 36.305 | 25.062 | 10.933 | 1.00 | 32.12 | A |
| ATOM | 1023 | CD | ARG | 113 | 37.287 | 24.194 | 11.655 | 1.00 | 32.67 | A |
| ATOM | 1024 | NE | ARG | 113 | 37.809 | 24.867 | 12.829 | 1.00 | 31.79 | A |
| ATOM | 1025 | HE | ARG | 113 | 37.195 | 25.500 | 13.255 | 0.00 | 0.00 | A |
| ATOM | 1026 | CZ | ARG | 113 | 39.032 | 24.679 | 13.300 | 1.00 | 34.41 | A |
| ATOM | 1027 | NH1 | ARG | 113 | 39.434 | 25.336 | 14.381 | 1.00 | 34.94 | A |
| ATOM | 1028 | HH11 | ARG | 113 | 38.781 | 25.982 | 14.818 | 0.00 | 0.00 | A |
| ATOM | 1029 | HH12 | ARG | 113 | 40.325 | 25.239 | 14.824 | 0.00 | 0.00 | A |
| ATOM | 1030 | NH2 | ARG | 113 | 39.862 | 23.853 | 12.670 | 1.00 | 35.69 | A |
| ATOM | 1031 | HH21 | ARG | 113 | 39.537 | 23.367 | 11.860 | 0.00 | 0.00 | A |
| ATOM | 1032 | HH22 | ARG | 113 | 40.780 | 23.669 | 13.020 | 0.00 | 0.00 | A |
| ATOM | 1033 | C | ARG | 113 | 36.803 | 28.399 | 9.150 | 1.00 | 39.28 | A |
| ATOM | 1034 | O | ARG | 113 | 36.853 | 29.355 | 9.902 | 1.00 | 43.62 | A |
| ATOM | 1035 | N | VAL | 114 | 37.396 | 28.390 | 7.970 | 1.00 | 38.97 | A |
| ATOM | 1036 | H | VAL | 114 | 37.368 | 27.579 | 7.420 | 0.00 | 0.00 | A |
| ATOM | 1037 | CA | VAL | 114 | 38.103 | 29.564 | 7.496 | 1.00 | 38.00 | A |
| ATOM | 1038 | CB | VAL | 114 | 38.898 | 29.238 | 6.259 | 1.00 | 36.79 | A |
| ATOM | 1039 | CG1 | VAL | 114 | 39.492 | 30.487 | 5.704 | 1.00 | 37.14 | A |
| ATOM | 1040 | CG2 | VAL | 114 | 39.974 | 28.209 | 6.598 | 1.00 | 34.77 | A |
| ATOM | 1041 | C | VAL | 114 | 37.097 | 30.667 | 7.189 | 1.00 | 38.83 | A |
| ATOM | 1042 | O | VAL | 114 | 37.265 | 31.807 | 7.613 | 1.00 | 41.57 | A |
| ATOM | 1043 | N | PHE | 115 | 36.031 | 30.310 | 6.484 | 1.00 | 37.62 | A |
| ATOM | 1044 | H | PHE | 115 | 35.956 | 29.380 | 6.170 | 0.00 | 0.00 | A |
| ATOM | 1045 | CA | PHE | 115 | 34.982 | 31.254 | 6.140 | 1.00 | 35.29 | A |
| ATOM | 1046 | CB | PHE | 115 | 33.931 | 30.562 | 5.303 | 1.00 | 32.15 | A |
| ATOM | 1047 | CG | PHE | 115 | 34.353 | 30.302 | 3.908 | 1.00 | 31.90 | A |
| ATOM | 1048 | CD1 | PHE | 115 | 33.609 | 29.465 | 3.097 | 1.00 | 33.74 | A |
| ATOM | 1049 | CD2 | PHE | 115 | 35.427 | 30.970 | 3.362 | 1.00 | 31.32 | A |
| ATOM | 1050 | CE1 | PHE | 115 | 33.929 | 29.315 | 1.754 | 1.00 | 33.71 | A |
| ATOM | 1051 | CE2 | PHE | 115 | 35.750 | 30.823 | 2.024 | 1.00 | 31.16 | A |
| ATOM | 1052 | CZ | PHE | 115 | 35.000 | 29.998 | 1.219 | 1.00 | 29.52 | A |
| ATOM | 1053 | C | PHE | 115 | 34.305 | 31.807 | 7.374 | 1.00 | 37.06 | A |
| ATOM | 1054 | O | PHE | 115 | 34.187 | 33.014 | 7.524 | 1.00 | 39.20 | A |
| ATOM | 1055 | N | ILE | 116 | 33.847 | 30.916 | 8.250 | 1.00 | 38.57 | A |
| ATOM | 1056 | H | ILE | 116 | 33.962 | 29.961 | 8.060 | 0.00 | 0.00 | A |
| ATOM | 1057 | CA | ILE | 116 | 33.153 | 31.321 | 9.473 | 1.00 | 38.49 | A |
| ATOM | 1058 | CB | ILE | 116 | 32.666 | 30.110 | 10.306 | 1.00 | 35.50 | A |
| ATOM | 1059 | CG2 | ILE | 116 | 32.089 | 30.589 | 11.629 | 1.00 | 31.55 | A |
| ATOM | 1060 | CG1 | ILE | 116 | 31.623 | 29.310 | 9.514 | 1.00 | 34.98 | A |
| ATOM | 1061 | CD1 | ILE | 116 | 31.161 | 28.036 | 10.178 | 1.00 | 30.64 | A |
| ATOM | 1062 | C | ILE | 1T6 | 34.006 | 32.198 | 10.367 | 1.00 | 40.38 | A |
| ATOM | 1063 | O | ILE | 116 | 33.508 | 33.152 | 10.943 | 1.00 | 43.64 | A |
| ATOM | 1064 | N | ALA | 117 | 35.282 | 31.863 | 10.506 | 1.00 | 41.81 | A |
| ATOM | 1065 | H | ALA | 117 | 35.651 | 31.082 | 10.043 | 0.00 | 0.00 | A |
| ATOM | 1066 | CA | ALA | 117 | 36.175 | 32.643 | 11.356 | 1.00 | 43.48 | A |
| ATOM | 1067 | CB | ALA | 117 | 37.468 | 31.914 | 11.585 | 1.00 | 43.17 | A |
| ATOM | 1068 | C | ALA | 117 | 36.434 | 33.991 | 10.715 | 1.00 | 45.76 | A |
| ATOM | 1069 | O | ALA | 117 | 36.689 | 34.975 | 11.403 | 1.00 | 46.25 | A |
| ATOM | 1070 | N | GLU | 118 | 36.399 | 34.028 | 9.389 | 1.00 | 49.13 | A |
| ATOM | 1071 | H | GLU | 118 | 36.278 | 33.212 | 8.862 | 0.00 | 0.00 | A |
| ATOM | 1072 | CA | GLU | 118 | 36.591 | 35.281 | 8.677 | 1.00 | 51.41 | A |
| ATOM | 1073 | CB | GLU | 118 | 36.634 | 35.054 | 7.165 | 1.00 | 56.89 | A |
| ATOM | 1074 | CG | GLU | 118 | 38.027 | 34.971 | 6.554 | 1.00 | 66.15 | A |
| ATOM | 1075 | CD | GLU | 118 | 37.998 | 34.956 | 5.021 | 1.00 | 72.90 | A |
| ATOM | 1076 | OE1 | GLU | 118 | 38.978 | 34.443 | 4.430 | 1.00 | 76.68 | A |
| ATOM | 1077 | OE2 | GLU | 118 | 37.007 | 35.447 | 4.405 | 1.00 | 72.92 | A |
| ATOM | 1078 | C | GLU | 118 | 35.382 | 36.128 | 9.016 | 1.00 | 49.35 | A |
| ATOM | 1079 | O | GLU | 118 | 35.499 | 37.163 | 9.656 | 1.00 | 50.17 | A |
| ATOM | 1080 | N | ASP | 119 | 34.215− | 35.619 | 8.647 | 1.00 | 47.09 | A |
| ATOM | 1081 | H | ASP | 119 | 34.186 | 34.769 | 8.170 | 0.00 | 0.00 | A |
| ATOM | 1082 | CA | ASP | 119 | 32.953 | 36.287 | 8.877 | 1.00 | 44.60 | A |
| ATOM | 1083 | CB | ASP | 119 | 31.816 | 35.338 | 8.529 | 1.00 | 43.17 | A |
| ATOM | 1084 | CG | ASP | 119 | 31.703 | 35.086 | 7.051 | 1.00 | 44.21 | A |
| ATOM | 1085 | OD1 | ASP | 119 | 30.845 | 34.275 | 6.671 | 1.00 | 45.78 | A |
| ATOM | 1086 | OD2 | ASP | 119 | 32.448 | 35.703 | 6.255 | 1.00 | 42.15 | A |
| ATOM | 1087 | C | ASP | 119 | 32.768 | 36.813 | 10.295 | 1.00 | 44.78 | A |
| ATOM | 1088 | O | ASP | 119 | 32.182 | 37.875 | 10.489 | 1.00 | 47.15 | A |
| ATOM | 1089 | N | LEU | 120 | 33.270 | 36.078 | 11.282 | 1.00 | 42.90 | A |
| ATOM | 1090 | H | LEU | 120 | 33.716 | 35.239 | 11.049 | 0.00 | 0.00 | A |
| ATOM | 1091 | CA | LEU | 120 | 33.125 | 36.476 | 12.673 | 1.00 | 42.63 | A |
| ATOM | 1092 | CB | LEU | 120 | 32.917 | 35.243 | 13.556 | 1.00 | 40.97 | A |
| ATOM | 1093 | CG | LEU | 120 | 31.708 | 34.341 | 13.305 | 1.00 | 38.07 | A |
| ATOM | 1094 | CD1 | LEU | 120 | 31.685 | 33.256 | 14.351 | 1.00 | 37.85 | A |
| ATOM | 1095 | CD2 | LEU | 120 | 30.431 | 35.137 | 13.370 | 1.00 | 38.16 | A |
| ATOM | 1096 | C | LEU | 120 | 34.317 | 37.276 | 13.181 | 1.00 | 44.65 | A |
| ATOM | 1097 | O | LEU | 120 | 34.271 | 37.873 | 14.262 | 1.00 | 48.38 | A |
| ATOM | 1098 | N | GLY | 121 | 35.398 | 37.261 | 12.418 | 1.00 | 44.89 | A |
| ATOM | 1099 | H | GLY | 121 | 35.414 | 36.757 | 11.579 | 0.00 | 0.00 | A |
| ATOM | 1100 | CA | GLY | 121 | 36.586 | 37.990 | 12.813 | 1.00 | 45.01 | A |
| ATOM | 1101 | C | GLY | 121 | 37.268 | 37.423 | 14.035 | 1.00 | 45.73 | A |
| ATOM | 1102 | O | GLY | 121 | 37.662 | 38.180 | 14.914 | 1.00 | 50.15 | A |
| ATOM | 1103 | N | CYS | 122 | 37.431 | 36.106 | 14.089 | 1.00 | 46.13 | A |
| ATOM | 1104 | H | CYS | 122 | 37.159 | 35.549 | 13.327 | 0.00 | 0.00 | A |
| ATOM | 1105 | CA | CYS | 122 | 38.079 | 35.454 | 15.228 | 1.00 | 47.73 | A |
| ATOM | 1106 | CB | CYS | 122 | 37.056 | 34.667 | 16.035 | 1.00 | 47.20 | A |
| ATOM | 1107 | SG | CYS | 122 | 36.281 | 33.344 | 15.099 | 1.00 | 42.47 | A |
| ATOM | 1108 | C | CYS | 122 | 39.116 | 34.489 | 14.700 | 1.00 | 48.85 | A |
| ATOM | 1109 | O | CYS | 122 | 39.299 | 34.389 | 13.494 | 1.00 | 48.78 | A |
| ATOM | 1110 | N | HIS | 123 | 39.817 | 33.793 | 15.586 | 1.00 | 51.62 | A |
| ATOM | 1111 | H | HIS | 123 | 39.585 | 33.859 | 16.541 | 0.00 | 0.00 | A |
| ATOM | 1112 | CA | HIS | 123 | 40.802 | 32.830 | 15.111 | 1.00 | 57.48 | A |
| ATOM | 1113 | CB | HIS | 123 | 41.856 | 32.474 | 16.171 | 1.00 | 71.19 | A |
| ATOM | 1114 | CG | HIS | 123 | 42.363 | 33.647 | 16.956 | 1.00 | 88.42 | A |
| ATOM | 1115 | CD2 | HIS | 123 | 42.128 | 34.031 | 18.236 | 1.00 | 94.22 | A |
| ATOM | 1116 | ND1 | HIS | 123 | 43.220 | 34.593 | 16.425 | 1.00 | 96.08 | A |
| ATOM | 1117 | HD1 | HIS | 123 | 43.613 | 34.596 | 15.522 | 0.00 | 0.00 | A |
| ATOM | 1118 | CE1 | HIS | 123 | 43.487 | 35.510 | 17.341 | 1.00 | 98.81 | A |
| ATOM | 1119 | NE2 | HIS | 123 | 42.837 | 35.191 | 18.449 | 1.00 | 99.59 | A |
| ATOM | 1120 | HE2 | HIS | 123 | 42.821 | 35.708 | 19.285 | 0.00 | 0.00 | A |
| ATOM | 1121 | C | HIS | 123 | 39.982 | 31.597 | 14.843 | 1.00 | 53.91 | A |
| ATOM | 1122 | O | HIS | 123 | 38.929 | 31.404 | 15.444 | 1.00 | 52.66 | A |
| ATOM | 1123 | N | MET | 124 | 40.477 | 30.739 | 13.968 | 1.00 | 51.05 | A |
| ATOM | 1124 | H | MET | 124 | 41.298 | 30.940 | 13.477 | 0.00 | 0.00 | A |
| ATOM | 1125 | CA | MET | 124 | 39.769 | 29.517 | 13.671 | 1.00 | 49.06 | A |
| ATOM | 1126 | CB | MET | 124 | 40.554 | 28.651 | 12.705 | 1.00 | 48.86 | A |
| ATOM | 1127 | CG | MET | 124 | 40.264 | 28.879 | 11.262 | 1.00 | 50.38 | A |
| ATOM | 1128 | SD | MET | 124 | 41.338 | 21.111 | 10.370 | 1.00 | 54.27 | A |
| ATOM | 1129 | CE | MET | 124 | 40.245 | 26.437 | 10.055 | 1.00 | 55.82 | A |
| ATOM | 1130 | C | MET | 124 | 39.567 | 28.719 | 14.935 | 1.00 | 48.93 | A |
| ATOM | 1131 | O | MET | 124 | 38.659 | 27.902 | 14.999 | 1.00 | 50.52 | A |
| ATOM | 1132 | N | ASP | 125 | 40.420 | 28.920 | 15.935 | 1.00 | 49.22 | A |
| ATOM | 1133 | H | ASP | 125 | 41.142 | 29.568 | 15.880 | 0.00 | 0.00 | A |
| ATOM | 1134 | CA | ASP | 125 | 40.280 | 28.145 | 17.158 | 1.00 | 50.57 | A |
| ATOM | 1135 | CB | ASP | 125 | 41.502 | 28.268 | 18.066 | 1.00 | 59.71 | A |
| ATOM | 1136 | CG | ASP | 125 | 41.590 | 27.121 | 19.086 | 1.00 | 69.02 | A |
| ATOM | 1137 | OD1 | ASP | 125 | 42.457 | 26.231 | 18.904 | 1.00 | 76.01 | A |
| ATOM | 1138 | OD2 | ASP | 125 | 40.794 | 27.081 | 20.064 | 1.00 | 71.67 | A |
| ATOM | 1139 | C | ASP | 125 | 39.008 | 28.480 | 17.915 | 1.00 | 47.32 | A |
| ATOM | 1140 | O | ASP | 125 | 38.587 | 27.737 | 18.792 | 1.00 | 45.87 | A |
| ATOM | 1141 | N | ASP | 126 | 38.375 | 29.587 | 17.578 | 1.00 | 44.13 | A |
| ATOM | 1142 | H | ASP | 126 | 38.713 | 30.216 | 16.920 | 0.00 | 0.00 | A |
| ATOM | 1143 | CA | ASP | 126 | 37.142 | 29.899 | 18.254 | 1.00 | 42.60 | A |
| ATOM | 1144 | CB | ASP | 126 | 36.992 | 31.401 | 18.419 | 1.00 | 45.25 | A |
| ATOM | 1145 | CG | ASP | 126 | 38.107 | 32.001 | 19.246 | 1.00 | 48.57 | A |
| ATOM | 1146 | OD1 | ASP | 126 | 38.513 | 33.142 | 18.934 | 1.00 | 54.04 | A |
| ATOM | 1147 | OD2 | ASP | 126 | 38.606 | 31.325 | 20.180 | 1.00 | 48.91 | A |
| ATOM | 1148 | C | ASP | 126 | 35.989 | 29.316 | 17.462 | 1.00 | 41.55 | A |
| ATOM | 1149 | O | ASP | 126 | 34.837 | 29.454 | 17.851 | 1.00 | 44.74 | A |
| ATOM | 1150 | N | VAL | 127 | 36.299 | 28.613 | 16.377 | 1.00 | 39.15 | A |
| ATOM | 1151 | H | VAL | 127 | 37.230 | 28.483 | 16.132 | 0.00 | 0.00 | A |
| ATOM | 1152 | CA | VAL | 127 | 35.274 | 28.021 | 15.530 | 1.00 | 37.59 | A |
| ATOM | 1153 | CB | VAL | 127 | 35.236 | 28.698 | 14.163 | 1.00 | 37.64 | A |
| ATOM | 1154 | CG1 | VAL | 127 | 34.189 | 28.055 | 13.304 | 1.00 | 40.53 | A |
| ATOM | 1155 | CG2 | VAL | 127 | 34.934 | 30.164 | 14.315 | 1.00 | 40.48 | A |
| ATOM | 1156 | C | VAL | 127 | 35.475 | 26.535 | 15.292 | 1.00 | 37.16 | A |
| ATOM | 1157 | O | VAL | 127 | 36.521 | 26.104 | 14.805 | 1.00 | 34.79 | A |
| ATOM | 1159 | H | ASN | 128 | 33.618 | 26.136 | 15.969 | 0.00 | 0.00 | A |
| ATOM | 1160 | CA | ASN | 128 | 34.487 | 24.317 | 15.391 | 1.00 | 39.61 | A |
| ATOM | 1161 | CB | ASN | 128 | 34.546 | 23.609 | 16.736 | 1.00 | 43.62 | A |
| ATOM | 1162 | CG | ASN | 128 | 34.847 | 22.134 | 16.597 | 1.00 | 47.36 | A |
| ATOM | 1163 | OD1 | ASN | 128 | 35.815 | 21.754 | 15.942 | 1.00 | 49.87 | A |
| ATOM | 1164 | ND2 | ASK | 128 | 34.022 | 21.293 | 17.213 | 1.00 | 49.51 | A |
| ATOM | 1165 | HD21 | ASN | 128 | 33.277 | 21.700 | 17.717 | 0.00 | 0.00 | A |
| ATOM | 1166 | HD22 | ASN | 128 | 34.186 | 20.329 | 17.138 | 0.00 | 0.00 | A |
| ATOM | 1167 | C | ASN | 128 | 33.258 | 23.850 | 14.608 | 1.00 | 38.87 | A |
| ATOM | 1168 | O | ASN | 128 | 32.156 | 24.389 | 14.783 | 1.00 | 41.23 | A |
| ATOM | 1169 | N | VAL | 129 | 33.447 | 22.871 | 13.726 | 1.00 | 34.70 | A |
| ATOM | 1170 | H | VAL | 129 | 34.326 | 22.448 | 13.622 | 0.00 | 0.00 | A |
| ATOM | 1171 | CA | VAL | 129 | 32.358 | 22.333 | 12.915 | 1.00 | 29.76 | A |
| ATOM | 1172 | CB | VAL | 129 | 32.398 | 22.904 | 11.497 | 1.00 | 26.47 | A |
| ATOM | 1173 | CG1 | VAL | 129 | 31.369 | 22.227 | 10.607 | 1.00 | 25.24 | A |
| ATOM | 1174 | CG2 | VAL | 129 | 32.148 | 24.371 | 11.540 | 1.00 | 23.29 | A |
| ATOM | 1175 | C | VAL | 129 | 32.579 | 20.836 | 12.855 | 1.00 | 31.02 | A |
| ATOM | 1176 | O | VAL | 129 | 33.707 | 20.385 | 12.693 | 1.00 | 33.10 | A |
| ATOM | 1177 | N | LYS | 130 | 31.524 | 20.058 | 13.035 | 1.00 | 31.47 | A |
| ATOM | 1178 | H | LYS | 130 | 30.636 | 20.451 | 13.167 | 0.00 | 0.00 | A |
| ATOM | 1179 | CA | LYS | 130 | 31.648 | 18.603 | 12.990 | 1.00 | 34.37 | A |
| ATOM | 1180 | CB | LYS | 130 | 31.651 | 18.021 | 14.401 | 1.00 | 36.93 | A |
| ATOM | 1181 | CG | LYS | 130 | 30.347 | 18.230 | 15.167 | 1.00 | 39.60 | A |
| ATOM | 1182 | CD | LYS | 130 | 30.451 | 17.711 | 16.593 | 1.00 | 39.50 | A |
| ATOM | 1183 | CE | LYS | 130 | 31.108 | 18.727 | 17.468 | 1.00 | 38.44 | A |
| ATOM | 1184 | NZ | LYS | 130 | 30.228 | 19.910 | 17.624 | 1.00 | 34.84 | A |
| ATOM | 1185 | HZ1 | LYS | 130 | 30.776 | 20.562 | 18.223 | 0.00 | 0.00 | A |
| ATOM | 1186 | HZ2 | LYS | 130 | 29.369 | 19.708 | 18.157 | 0.00 | 0.00 | A |
| ATOM | 1187 | HZ3 | LYS | 130 | 30.067 | 20.458 | 16.757 | 0.00 | 0.00 | A |
| ATOM | 1188 | C | LYS | 130 | 30.439 | 18.097 | 12.241 | 1.00 | 35.86 | A |
| ATOM | 1189 | O | LYS | 130 | 29.493 | 18.864 | 12.028 | 1.00 | 39.30 | A |
| ATOM | 1190 | N | ALA | 131 | 30.435 | 16.826 | 11.858 | 1.00 | 33.92 | A |
| ATOM | 1191 | H | ALA | 131 | 31.181 | 16.219 | 12.097 | 0.00 | 0.00 | A |
| ATOM | 1192 | CA | ALA | 131 | 29.295 | 16.296 | 11.133 | 1.00 | 32.77 | A |
| ATOM | 1193 | CB | ALA | 131 | 29.614 | 16.179 | 9.680 | 1.00 | 30.18 | A |
| ATOM | 1194 | C | ALA | 131 | 28.891 | 14.957 | 11.674 | 1.00 | 34.79 | A |
| ATOM | 1195 | O | ALA | 131 | 29.674 | 14.297 | 12.349 | 1.00 | 37.48 | A |
| ATOM | 1196 | N | THE | 132 | 27.660 | 14.561 | 11.385 | 1.00 | 36.62 | A |
| ATOM | 1197 | H | THR | 132 | 27.051 | 15.132 | 10.873 | 0.00 | 0.00 | A |
| ATOM | 1198 | CA | THR | 132 | 27.156 | 13.275 | 11.820 | 1.00 | 39.88 | A |
| ATOM | 1199 | CB | THR | 132 | 26.659 | 13.322 | 13.262 | 1.00 | 41.64 | A |
| ATOM | 1200 | OG1 | THR | 132 | 26.281 | 11.999 | 13.662 | 1.00 | 47.04 | A |
| ATOM | 1201 | HG1 | THR | 132 | 25.380 | 11.738 | 13.434 | 0.00 | 0.00 | A |
| ATOM | 1202 | CG2 | THR | 132 | 25.437 | 14.232 | 13.384 | 1.00 | 42.12 | A |
| ATOM | 1203 | C | THR | 132 | 25.982 | 12.828 | 10.966 | 1.00 | 41.21 | A |
| ATOM | 1204 | O | THR | 132 | 25.261 | 13.659 | 10.418 | 1.00 | 41.28 | A |
| ATOM | 1205 | N | THR | 133 | 25.781 | 11.516 | 10.874 | 1.00 | 42.73 | A |
| ATOM | 1206 | H | THR | 133 | 26.368 | 10.909 | 11.368 | 0.00 | 0.00 | A |
| ATOM | 1207 | CA | THR | 133 | 24.652 | 10.973 | 10.123 | 1.00 | 44.20 | A |
| ATOM | 1208 | CB | THR | 133 | 25.037 | 9.740 | 9.294 | 1.00 | 45.94 | A |
| ATOM | 1209 | OG1 | THR | 133 | 25.124 | 8.601 | 10.152 | 1.00 | 47.84 | A |
| ATOM | 1210 | HG1 | THR | 133 | 25.859 | 8.546 | 10.784 | 0.00 | 0.00 | A |
| ATOM | 1211 | CG2 | THR | 133 | 26.368 | 9.930 | 8.614 | 1.00 | 48.01 | A |
| ATOM | 1212 | C | THR | 133 | 23.680 | 10.480 | 11.179 | 1.00 | 42.86 | A |
| ATOM | 1213 | O | THR | 133 | 24.024 | 10.412 | 12.357 | 1.00 | 46.33 | A |
| ATOM | 1214 | N | THR | 134 | 22.481 | 10.112 | 10.774 | 1.00 | 40.04 | A |
| ATOM | 1215 | H | THR | 134 | 22.171 | 10.213 | 9.855 | 0.00 | 0.00 | A |
| ATOM | 1216 | CA | THR | 134 | 21.539 | 9.589 | 11.738 | 1.00 | 39.32 | A |
| ATOM | 1217 | CB | THR | 134 | 20.263 | 10.349 | 11.671 | 1.00 | 36.35 | A |
| ATOM | 1218 | OG1 | THR | 134 | 19.917 | 10.569 | 10.297 | 1.00 | 34.92 | A |
| ATOM | 1219 | HG1 | THR | 134 | 18.946 | 10.524 | 10.242 | 0.00 | 0.00 | A |
| ATOM | 1220 | CG2 | THR | 134 | 20.462 | 11.663 | 12.350 | 1.00 | 34.64 | A |
| ATOM | 1221 | C | THR | 134 | 21.328 | 8.110 | 11.437 | 1.00 | 43.18 | A |
| ATOM | 1222 | O | THR | 134 | 20.249 | 7.551 | 11.661 | 1.00 | 44.18 | A |
| ATOM | 1223 | N | GLU | 135 | 22.395 | 7.494 | 10.925 | 1.00 | 43.98 | A |
| ATOM | 1224 | H | GLU | 135 | 23.248 | 7.967 | 10.836 | 0.00 | 0.00 | A |
| ATOM | 1225 | CA | GLU | 135 | 22.444 | 6.084 | 10.557 | 1.00 | 43.99 | A |
| ATOM | 1226 | CB | GLU | 135 | 22.623 | 5.206 | 11.795 | 1.00 | 47.33 | A |
| ATOM | 1227 | CG | GLU | 135 | 23.763 | 5.627 | 12.726 | 1.00 | 57.69 | A |
| ATOM | 1228 | CD | GLU | 135 | 25.166 | 5.301 | 12.214 | 1.00 | 63.44 | A |
| ATOM | 1229 | OE1 | GLU | 135 | 26.092 | 5.235 | 13.053 | 1.00 | 67.71 | A |
| ATOM | 1230 | OE2 | GLU | 135 | 25.360 | 5.121 | 10.988 | 1.00 | 69.59 | A |
| ATOM | 1231 | C | GLU | 135 | 21.226 | 5.655 | 9.767 | 1.00 | 42.57 | A |
| ATOM | 1232 | O | GLU | 135 | 20.410 | 4.860 | 10.219 | 1.00 | 44.24 | A |
| ATOM | 1233 | N | LYS | 136 | 21.066 | 6.239 | 8.597 | 1.00 | 41.04 | A |
| ATOM | 1234 | H | LYS | 136 | 21.742 | 6.854 | 8.272 | 0.00 | 0.00 | A |
| ATOM | 1235 | CA | LYS | 136 | 19.943 | 5.898 | 7.756 | 1.00 | 41.08 | A |
| ATOM | 1236 | CB | LYS | 136 | 20.085 | 4.458 | 7.300 | 1.00 | 44.47 | A |
| ATOM | 1237 | CG | LYS | 136 | 21.165 | 4.259 | 6.250 | 1.00 | 49.59 | A |
| ATOM | 1238 | CD | LYS | 136 | 20.704 | 4.877 | 4.955 | 1.00 | 57.33 | A |
| ATOM | 1239 | CE | LYS | 136 | 21.477 | 4.350 | 3.764 | 1.00 | 65.59 | A |
| ATOM | 1240 | NZ | LYS | 136 | 20.880 | 4.888 | 2.498 | 1.00 | 70.82 | A |
| ATOM | 1241 | HZ1 | LYS | 136 | 21.428 | 4.553 | 1.684 | 0.00 | 0.00 | A |
| ATOM | 1242 | HZ2 | LYS | 136 | 20.920 | 5.928 | 2.547 | 0.00 | 0.00 | A |
| ATOM | 1243 | HZ3 | LYS | 136 | 19.886 | 4.593 | 2.422 | 0.00 | 0.00 | A |
| ATOM | 1244 | C | LYS | 136 | 18.553 | 6.145 | 8.345 | 1.00 | 39.36 | A |
| ATOM | 1245 | O | LYS | 136 | 17.567 | 6.033 | 7.632 | 1.00 | 41.15 | A |
| ATOM | 1246 | N | LEU | 137 | 18.469 | 6.502 | 9.622 | 1.00 | 37.10 | A |
| ATOM | 1247 | H | LEU | 137 | 19.246 | 6.594 | 10.203 | 0.00 | 0.00 | A |
| ATOM | 1248 | CA | LEU | 137 | 17.182 | 6.788 | 10.248 | 1.00 | 35.46 | A |
| ATOM | 1249 | CB | LEU | 137 | 17.265 | 6.588 | 11.760 | 1.00 | 33.24 | A |
| ATOM | 1250 | CG | LEU | 137 | 17.709 | 5.239 | 12.257 | 1.00 | 30.79 | A |
| ATOM | 1251 | CD1 | LEU | 137 | 17.842 | 5.261 | 13.739 | 1.00 | 33.51 | A |
| ATOM | 1252 | CD2 | LEU | 137 | 16.684 | 4.266 | 11.864 | 1.00 | 32.33 | A |
| ATOM | 1253 | C | LEU | 137 | 16.764 | 8.245 | 10.015 | 1.00 | 35.18 | A |
| ATOM | 1254 | O | LEU | 137 | 17.612 | 9.146 | 9.911 | 1.00 | 33.95 | A |
| ATOM | 1255 | N | GLY | 138 | 15.455 | 8.473 | 9.986 | 1.00 | 32.70 | A |
| ATOM | 1256 | H | GLY | 138 | 14.876 | 7.692 | 10.062 | 0.00 | 0.00 | A |
| ATOM | 1257 | CA | GLY | 138 | 14.933 | 9.821 | 9.836 | 1.00 | 34.20 | A |
| ATOM | 1258 | C | GLY | 138 | 14.977 | 10.466 | 8.472 | 1.00 | 34.94 | A |
| ATOM | 1259 | O | GLY | 138 | 15.567 | 9.911 | 7.554 | 1.00 | 37.46 | A |
| ATOM | 1260 | N | PHE | 139 | 14.382 | 11.654 | 8.344 | 1.00 | 32.96 | A |
| ATOM | 1261 | H | PHE | 139 | 13.997 | 12.097 | 9.125 | 0.00 | 0.00 | A |
| ATOM | 1262 | CA | PHE | 139 | 14.353 | 12.334 | 7.058 | 1.00 | 31.79 | A |
| ATOM | 1263 | CB | PHE | 139 | 13.550 | 13.633 | 7.100 | 1.00 | 33.06 | A |
| ATOM | 1264 | CG | PHE | 139 | 14.207 | 14.760 | 7.860 | 1.00 | 34.50 | A |
| ATOM | 1265 | CD1 | PHE | 139 | 15.048 | 15.652 | 7.218 | 1.00 | 34.41 | A |
| ATOM | 1266 | CD2 | PHE | 139 | 13.915 | 14.983 | 9.196 | 1.00 | 32.34 | A |
| ATOM | 1267 | CE1 | PHE | 139 | 15.575 | 16.747 | 7.897 | 1.00 | 34.13 | A |
| ATOM | 1268 | CE2 | PHE | 139 | 14.447 | 16.085 | 9.877 | 1.00 | 30.58 | A |
| ATOM | 1269 | CZ | PHE | 139 | 15.271 | 16.962 | 9.227 | 1.00 | 29.75 | A |
| ATOM | 1270 | C | PHE | 139 | 15.760 | 12.592 | 6.636 | 1.00 | 32.63 | A |
| ATOM | 1271 | O | PHE | 139 | 16.067 | 12.581 | 5.453 | 1.00 | 31.67 | A |
| ATOM | 1272 | N | THR | 140 | 16.618 | 12.817 | 7.619 | 1.00 | 33.73 | A |
| ATOM | 1273 | H | THR | 140 | 16.352 | 12.832 | 8.557 | 0.00 | 0.00 | A |
| ATOM | 1274 | CA | THR | 140 | 18.013 | 13.045 | 7.331 | 1.00 | 37.52 | A |
| ATOM | 1275 | CB | THR | 140 | 18.785 | 13.458 | 8.571 | 1.00 | 35.72 | A |
| ATOM | 1276 | OG1 | THR | 140 | 18.451 | 12.564 | 9.643 | 1.00 | 39.50 | A |
| ATOM | 1277 | HG1 | THR | 140 | 19.095 | 12.696 | 10.349 | 0.00 | 0.00 | A |
| ATOM | 1278 | CG2 | THR | 140 | 18.460 | 14.899 | 8.939 | 1.00 | 32.48 | A |
| ATOM | 1279 | C | THR | 140 | 18.562 | 11.718 | 6.849 | 1.00 | 39.69 | A |
| ATOM | 1280 | O | THR | 140 | 19.229 | 11.661 | 5.812 | 1.00 | 42.90 | A |
| ATOM | 1281 | N | GLY | 141 | 18.252 | 10.653 | 7.585 | 1.00 | 38.94 | A |
| ATOM | 1262 | H | GLY | 141 | 17.718 | 10.748 | 8.398 | 0.00 | 0.00 | A |
| ATOM | 1283 | CA | GLY | 141 | 18.731 | 9.328 | 7.222 | 1.00 | 37.80 | A |
| ATOM | 1284 | C | GLY | 141 | 18.233 | 8.844 | 5.877 | 1.00 | 38.02 | A |
| ATOM | 1285 | O | GLY | 141 | 18.907 | 8.090 | 5.182 | 1.00 | 40.16 | A |
| ATOM | 1286 | N | ARG | 142 | 17.065 | 9.316 | 5.478 | 1.00 | 37.88 | A |
| ATOM | 1287 | H | ARG | 142 | 16.597 | 9.962 | 6.031 | 0.00 | 0.00 | A |
| ATOM | 1288 | CA | ARG | 142 | 16.497 | 8.912 | 4.216 | 1.00 | 35.78 | A |
| ATOM | 1289 | CB | ARG | 142 | 14.994 | 8.950 | 4.298 | 1.00 | 33.88 | A |
| ATOM | 1290 | CG | ARG | 142 | 14.504 | 7.962 | 5.292 | 1.00 | 39.95 | A |
| ATOM | 1291 | CD | ARG | 142 | 13.044 | 7.686 | 5.094 | 1.00 | 45.40 | A |
| ATOM | 1292 | NE | ARG | 142 | 12.294 | 8.906 | 5.283 | 1.00 | 45.64 | A |
| ATOM | 1293 | HE | ARG | 142 | 12.083 | 9.382 | 4.454 | 0.00 | 0.00 | A |
| ATOM | 1294 | CZ | ARG | 142 | 11.920 | 9.355 | 6.467 | 1.00 | 47.74 | A |
| ATOM | 1295 | NH1 | ARG | 142 | 11.256 | 10.493 | 6.549 | 1.00 | 53.62 | A |
| ATOM | 1296 | HH11 | ARG | 142 | 11.134 | 10.992 | 5.657 | 0.00 | 0.00 | A |
| ATOM | 1297 | HH12 | ARG | 142 | 10.944 | 10.950 | 7.362 | 0.00 | 0.00 | A |
| ATOM | 1298 | NH2 | ARG | 142 | 12.212 | 8.662 | 7.560 | 1.00 | 48.74 | A |
| ATOM | 1299 | HH21 | ARG | 142 | 12.725 | 7.804 | 7.452 | 0.00 | 0.00 | A |
| ATOM | 1300 | HH22 | ARG | 142 | 11.954 | 8.957 | 8.471 | 0.00 | 0.00 | A |
| ATOM | 1301 | C | ARG | 142 | 16.974 | 9.780 | 3.089 | 1.00 | 36.10 | A |
| ATOM | 1302 | O | ARG | 142 | 16.589 | 9.594 | 1.951 | 1.00 | 39.86 | A |
| ATOM | 1303 | N | GLY | 143 | 17.824 | 10.736 | 3.397 | 1.00 | 36.39 | A |
| ATOM | 1304 | H | GLY | 143 | 18.123 | 10.866 | 4.320 | 0.00 | 0.00 | A |
| ATOM | 1305 | CA | GLY | 143 | 18.321 | 11.603 | 2.351 | 1.00 | 37.56 | A |
| ATOM | 1306 | C | GLY | 143 | 17.290 | 12.616 | 1.912 | 1.00 | 36.28 | A |
| ATOM | 1307 | O | GLY | 143 | 17.405 | 13.182 | 0.824 | 1.00 | 40.14 | A |
| ATOM | 1308 | N | GLY | 144 | 16.313 | 12.876 | 2.770 | 1.00 | 35.27 | A |
| ATOM | 1309 | H | GLU | 144 | 16.275 | 12.401 | 3.620 | 0.00 | 0.00 | A |
| ATOM | 1310 | CA | GLU | 144 | 15.272 | 13.824 | 2.464 | 1.00 | 34.37 | A |
| ATOM | 1311 | CB | GLU | 144 | 14.033 | 13.520 | 3.280 | 1.00 | 34.26 | A |
| ATOM | 1312 | CG | GLU | 144 | 13.478 | 12.145 | 2.962 | 1.00 | 38.03 | A |
| ATOM | 1313 | CD | GLU | 144 | 12.238 | 11.787 | 3.754 | 1.00 | 42.96 | A |
| ATOM | 1314 | OE1 | GLU | 144 | 11.577 | 10.780 | 3.393 | 1.00 | 41.79 | A |
| ATOM | 1315 | OE2 | GLU | 144 | 11.924 | 12.492 | 4.750 | 1.00 | 46.37 | A |
| ATOM | 1316 | C | GLU | 144 | 15.707 | 15.257 | 2.651 | 1.00 | 35.77 | A |
| ATOM | 1317 | O | GLU | 144 | 15.247 | 16.128 | 1.921 | 1.00 | 39.52 | A |
| ATOM | 1318 | N | GLY | 145 | 16.625 | 15.507 | 3.580 | 1.00 | 35.09 | A |
| ATOM | 1319 | H | GLY | 145 | 17.009 | 14.780 | 4.115 | 0.00 | 0.00 | A |
| ATOM | 1320 | CA | GLY | 145 | 17.090 | 16.869 | 3.822 | 1.00 | 34.50 | A |
| ATOM | 1321 | C | GLY | 145 | 18.285 | 16.887 | 4.753 | 1.00 | 34.83 | A |
| ATOM | 1322 | O | GLY | 145 | 18.782 | 15.821 | 5.102 | 1.00 | 39.97 | A |
| ATOM | 1323 | N | ILE | 146 | 18.791 | 18.060 | 5.117 | 1.00 | 33.76 | A |
| ATOM | 1324 | H | ILE | 146 | 18.371 | 18.889 | 4.799 | 0.00 | 0.00 | A |
| ATOM | 1325 | CA | ILE | 146 | 19.939 | 18.145 | 6.024 | 1.00 | 34.74 | A |
| ATOM | 1326 | CB | ILE | 146 | 21.161 | 18.867 | 5.407 | 1.00 | 34.28 | A |
| ATOM | 1327 | CG2 | ILE | 146 | 22.243 | 19.020 | 6.431 | 1.00 | 36.35 | A |
| ATOM | 1328 | CG1 | ILE | 146 | 21.791 | 18.064 | 4.289 | 1.00 | 34.71 | A |
| ATOM | 1329 | CD1 | ILE | 146 | 23.060 | 18.701 | 3.783 | 1.00 | 33.05 | A |
| ATOM | 1330 | C | ILE | 146 | 19.484 | 19.013 | 7.169 | 1.00 | 36.16 | A |
| ATOM | 1331 | O | ILE | 146 | 18.691 | 19.935 | 6.964 | 1.00 | 41.73 | A |
| ATOM | 1332 | N | ALA | 147 | 19.967 | 18.730 | 8.371 | 1.00 | 33.96 | A |
| ATOM | 1333 | H | ALA | 147 | 20.619 | 18.001 | 8.484 | 0.00 | 0.00 | A |
| ATOM | 1334 | CA | ALA | 147 | 19.610 | 19.521 | 9.538 | 1.00 | 31.32 | A |
| ATOM | 1335 | CB | ALA | 147 | 18.856 | 18.678 | 10.532 | 1.00 | 30.85 | A |
| ATOM | 1336 | C | ALA | 147 | 20.934 | 19.942 | 10.116 | 1.00 | 30.81 | A |
| ATOM | 1337 | O | ALA | 147 | 21.961 | 19.398 | 9.738 | 1.00 | 33.32 | A |
| ATOM | 1338 | N | CYS | 148 | 20.936 | 20.892 | 11.034 | 1.00 | 30.12 | A |
| ATOM | 1339 | H | CYS | 148 | 20.103 | 21.335 | 11.304 | 0.00 | 0.00 | A |
| ATOM | 1340 | CA | CYS | 148 | 22.189 | 21.323 | 11.623 | 1.00 | 30.27 | A |
| ATOM | 1341 | CB | CYS | 148 | 22.932 | 22.211 | 10.645 | 1.00 | 31.14 | A |
| ATOM | 1342 | SG | CYS | 148 | 24.419 | 22.923 | 11.321 | 1.00 | 43.66 | A |
| ATOM | 1343 | C | CYS | 148 | 21.935 | 22.072 | 12.905 | 1.00 | 29.41 | A |
| ATOM | 1344 | O | CYS | 148 | 21.019 | 22.886 | 12.967 | 1.00 | 31.66 | A |
| ATOM | 1345 | N | GLU | 149 | 22.694 | 21.755 | 13.947 | 1.00 | 29.29 | A |
| ATOM | 1346 | H | GLU | 149 | 23.399 | 21.085 | 13.851 | 0.00 | 0.00 | A |
| ATOM | 1347 | CA | GLU | 149 | 22.537 | 22.427 | 15.234 | 1.00 | 31.44 | A |
| ATOM | 1348 | CB | GLU | 149 | 22.436 | 21.437 | 16.371 | 1.00 | 29.41 | A |
| ATOM | 1349 | CG | GLU | 149 | 21.199 | 20.642 | 16.368 | 1.00 | 35.53 | A |
| ATOM | 1350 | CD | GLU | 149 | 20.853 | 20.201 | 17.748 | 1.00 | 39.71 | A |
| ATOM | 1351 | OE1 | GLU | 149 | 20.825 | 21.085 | 18.628 | 1.00 | 41.10 | A |
| ATOM | 1352 | OE2 | GLU | 149 | 20.667 | 18.984 | 17.956 | 1.00 | 42.98 | A |
| ATOM | 1353 | C | GLU | 149 | 23.767 | 23.243 | 15.478 | 1.00 | 32.40 | A |
| ATOM | 1354 | O | GLU | 149 | 24.812 | 22.979 | 14.875 | 1.00 | 35.98 | A |
| ATOM | 1355 | N | ALA | 150 | 23.676 | 24.183 | 16.410 | 1.00 | 30.12 | A |
| ATOM | 1356 | H | ALA | 150 | 22.828 | 24.328 | 16.884 | 0.00 | 0.00 | A |
| ATOM | 1357 | CA | ALA | 150 | 24.824 | 25.010 | 16.722 | 1.00 | 29.19 | A |
| ATOM | 1358 | CB | ALA | 150 | 24.989 | 26.078 | 15.666 | 1.00 | 28.98 | A |
| ATOM | 1359 | C | ALA | 150 | 24.675 | 25.648 | 18.085 | 1.00 | 29.18 | A |
| ATOM | 1360 | O | ALA | 150 | 23.562 | 25.922 | 18.539 | 1.00 | 30.94 | A |
| ATOM | 1361 | N | VAL | 151 | 25.784 | 25.805 | 18.780 | 1.00 | 28.02 | A |
| ATOM | 1362 | H | VAL | 151 | 26.652 | 25.526 | 18.422 | 0.00 | 0.00 | A |
| ATOM | 1363 | CA | VAL | 151 | 25.740 | 26.455 | 20.064 | 1.00 | 30.70 | A |
| ATOM | 1364 | CB | VAL | 151 | 26.035 | 25.517 | 21.211 | 1.00 | 30.22 | A |
| ATOM | 1365 | CG1 | VAL | 151 | 24.902 | 24.533 | 21.378 | 1.00 | 29.56 | A |
| ATOM | 1366 | CG2 | VAL | 151 | 27.351 | 24.826 | 20.980 | 1.00 | 29.53 | A |
| ATOM | 1367 | C | VAL | 151 | 26.831 | 27.478 | 19.973 | 1.00 | 33.91 | A |
| ATOM | 1368 | O | VAL | 151 | 27.801 | 27.282 | 19.241 | 1.00 | 34.96 | A |
| ATOM | 1369 | N | ALA | 152 | 26.659 | 28.575 | 20.698 | 1.00 | 37.05 | A |
| ATOM | 1370 | H | ALA | 152 | 25.865 | 28.651 | 21.273 | 0.00 | 0.00 | A |
| ATOM | 1371 | CA | ALA | 152 | 27.617 | 29.672 | 20.703 | 1.00 | 37.81 | A |
| ATOM | 1372 | CB | ALA | 152 | 27.176 | 30.734 | 19.730 | 1.00 | 37.51 | A |
| ATOM | 1373 | C | ALA | 152 | 27.705 | 30.264 | 22.099 | 1.00 | 38.53 | A |
| ATOM | 1374 | O | ALA | 152 | 26.764 | 30.148 | 22.899 | 1.00 | 40.62 | A |
| ATOM | 1375 | N | LEU | 153 | 28.832 | 30.901 | 22.383 | 1.00 | 37.52 | A |
| ATOM | 1376 | H | LEU | 153 | 29.534 | 30.961 | 21.703 | 0.00 | 0.00 | A |
| ATOM | 1377 | CA | LEU | 153 | 29.063 | 31.528 | 23.671 | 1.00 | 35.79 | A |
| ATOM | 1378 | CB | LEU | 153 | 30.047 | 30.695 | 24.458 | 1.00 | 37.41 | A |
| ATOM | 1379 | CG | LEU | 153 | 30.367 | 31.053 | 25.902 | 1.00 | 42.45 | A |
| ATOM | 1380 | CD1 | LEU | 153 | 30.932 | 29.827 | 26.608 | 1.00 | 43.24 | A |
| ATOM | 1381 | CD2 | LEU | 153 | 31.377 | 32.187 | 25.939 | 1.00 | 47.27 | A |
| ATOM | 1382 | C | LEU | 153 | 29.636 | 32.895 | 23.361 | 1.00 | 36.48 | A |
| ATOM | 1383 | O | LEU | 153 | 30.630 | 33.001 | 22.643 | 1.00 | 37.54 | A |
| ATOM | 1384 | N | LEU | 154 | 28.931 | 33.937 | 23.788 | 1.00 | 36.82 | A |
| ATOM | 1385 | H | LEU | 154 | 28.113 | 33.771 | 24.286 | 0.00 | 0.00 | A |
| ATOM | 1386 | CA | LEU | 154 | 29.348 | 35.315 | 23.566 | 1.00 | 36.27 | A |
| ATOM | 1387 | CB | LEU | 154 | 28.182 | 36.173 | 23.098 | 1.00 | 31.06 | A |
| ATOM | 1388 | CG | LEU | 154 | 27.513 | 35.822 | 21.780 | 1.00 | 27.71 | A |
| ATOM | 1389 | CD1 | LEU | 154 | 26.347 | 36.761 | 21.550 | 1.00 | 23.79 | A |
| ATOM | 1390 | CD2 | LEU | 154 | 28.517 | 35.901 | 20.658 | 1.00 | 27.16 | A |
| ATOM | 1391 | C | LEU | 154 | 29.863 | 35.870 | 24.880 | 1.00 | 39.40 | A |
| ATOM | 1392 | O | LEU | 154 | 29.534 | 35.363 | 25.956 | 1.00 | 38.64 | A |
| ATOM | 1393 | N | ILE | 155 | 30.590 | 36.975 | 24.791 | 1.00 | 43.20 | A |
| ATOM | 1394 | H | ILE | 155 | 30.700 | 37.408 | 23.928 | 0.00 | 0.00 | A |
| ATOM | 1395 | CA | ILE | 155 | 31.188 | 37.603 | 25.955 | 1.00 | 45.95 | A |
| ATOM | 1396 | CB | ILE | 155 | 32.692 | 37.389 | 25.902 | 1.00 | 46.34 | A |
| ATOM | 1397 | CG2 | ILE | 155 | 33.393 | 38.287 | 26.857 | 1.00 | 48.78 | A |
| ATOM | 1398 | CG1 | ILE | 155 | 33.001 | 35.933 | 26.216 | 1.00 | 48.32 | A |
| ATOM | 1399 | CD1 | ILE | 155 | 34.445 | 35.599 | 26.051 | 1.00 | 53.04 | A |
| ATOM | 1400 | C | ILE | 155 | 30.870 | 39.091 | 26.032 | 1.00 | 48.60 | A |
| ATOM | 1401 | O | ILE | 155 | 30.396 | 39.682 | 25.054 | 1.00 | 53.70 | A |
| ATOM | 1402 | ZN | ZN | 156 | 17.609 | 27.810 | 6.962 | 1.00 | 57.72 | A |
| ATOM | 1403 | OZN | OZN | 157 | 16.132 | 28.999 | 7.358 | 1.00 | 47.02 | A |
| ATOM | 1404 | N1 | CYT | 669 | 8.409 | 30.546 | 12.853 | 1.00 | 37.71 | A |
| ATOM | 1405 | C2 | CYT | 669 | 7.205 | 30.577 | 13.498 | 1.00 | 38.02 | A |
| ATOM | 1406 | N3 | CYT | 669 | 6.468 | 29.456 | 13.776 | 1.00 | 36.07 | A |
| ATOM | 1407 | C4 | CYT | 669 | 6.942 | 28.257 | 13.398 | 1.00 | 34.04 | A |
| ATOM | 1408 | C5 | CYT | 669 | 8.162 | 28.171 | 12.744 | 1.00 | 34.45 | A |
| ATOM | 1409 | C6 | CYT | 669 | 8.846 | 29.348 | 12.499 | 1.00 | 35.16 | A |
| ATOM | 1410 | O2 | CYT | 669 | 6.727 | 31.652 | 13.861 | 1.00 | 42.67 | A |
| ATOM | 1411 | N4 | CYT | 669 | 6.223 | 27.165 | 13.661 | 1.00 | 32.17 | A |
| ATOM | 1412 | C1* | CYT | 669 | 9.156 | 31.793 | 12.571 | 1.00 | 42.42 | A |
| ATOM | 1413 | C2* | CYT | 669 | 10.523 | 31.798 | 13.173 | 1.00 | 46.88 | A |
| ATOM | 1414 | O2* | CYT | 669 | 10.470 | 32.376 | 14.449 | 1.00 | 49.90 | A |
| ATOM | 1415 | C3* | CYT | 669 | 11.380 | 32.535 | 12.198 | 1.00 | 48.07 | A |
| ATOM | 1416 | C4* | CYT | 669 | 10.571 | 32.575 | 10.924 | 1.00 | 49.22 | A |
| ATOM | 1417 | O4* | CYT | 669 | 9.343 | 31.958 | 11.197 | 1.00 | 44.89 | A |
| ATOM | 1418 | O3* | CYT | 669 | 11.568 | 33.892 | 12.527 | 1.00 | 48.56 | A |
| ATOM | 1419 | C5* | CYT | 669 | 11.457 | 31.844 | 10.071 | 1.00 | 55.25 | A |
| ATOM | 1420 | O5* | CYT | 669 | 11.423 | 30.476 | 10.252 | 1.00 | 59.02 | A |
| END | | | | | | | | | | |

ANNEX 2
Coordinates of structure mgcdp2

| | | | | | | | | | | |
|---|---|---|---|---|---|---|---|---|---|---|
| ATOM | 1 | CB | MET | 1 | 29.813 | 33.877 | 29.728 | 1.00 | 45.57 | A |
| ATOM | 2 | CG | MET | 1 | 31.325 | 33.953 | 29.920 | 1.00 | 54.42 | A |
| ATOM | 3 | SD | MET | 1 | 32.281 | 33.696 | 28.405 | 1.00 | 65.45 | A |
| ATOM | 4 | CE | MET | 1 | 34.005 | 33.566 | 29.075 | 1.00 | 65.04 | A |
| ATOM | 5 | C | MET | 1 | 27.701 | 34.792 | 28.813 | 1.00 | 37.02 | A |
| ATOM | 6 | O | MET | 1 | 26.910 | 34.731 | 29.750 | 1.00 | 37.06 | A |
| ATOM | 7 | HT1 | MET | 1 | 28.715 | 36.015 | 30.806 | 0.00 | 0.00 | A |
| ATOM | 8 | HT2 | MET | 1 | 28.784 | 37.085 | 29.510 | 0.00 | 0.00 | A |
| ATOM | 9 | N | MET | 1 | 29.272 | 36.294 | 29.969 | 1.00 | 38.60 | A |
| ATOM | 10 | HT3 | MET | 1 | 30.254 | 36.509 | 30.210 | 0.00 | 0.00 | A |
| ATOM | 11 | CA | MET | 1 | 29.168 | 35.100 | 29.075 | 1.00 | 39.50 | A |
| ATOM | 12 | N | ARG | 2 | 27.337 | 34.630 | 27.544 | 1.00 | 33.80 | A |
| ATOM | 13 | H | ARG | 2 | 27.977 | 34.640 | 26.808 | 0.00 | 0.00 | A |
| ATOM | 14 | CA | ARG | 2 | 25.966 | 34.314 | 27.162 | 1.00 | 31.46 | A |
| ATOM | 15 | CB | ARG | 2 | 25.254 | 35.548 | 26.589 | 1.00 | 30.37 | A |
| ATOM | 16 | CG | ARG | 2 | 24.801 | 36.496 | 27.688 | 1.00 | 30.99 | A |
| ATOM | 17 | CD | ARG | 2 | 24.011 | 37.675 | 27.172 | 1.00 | 37.34 | A |
| ATOM | 18 | NE | ARG | 2 | 22.720 | 37.297 | 26.602 | 1.00 | 41.01 | A |
| ATOM | 19 | HE | ARG | 2 | 22.757 | 36.738 | 25.798 | 0.00 | 0.00 | A |
| ATOM | 20 | CZ | ARG | 2 | 21.531 | 37.625 | 27.110 | 1.00 | 42.32 | A |
| ATOM | 21 | NH1 | ARG | 2 | 20.424 | 37.213 | 26.492 | 1.00 | 38.62 | A |
| ATOM | 22 | HH11 | ARG | 2 | 20.475 | 36.646 | 25.667 | 0.00 | 0.00 | A |
| ATOM | 23 | HH12 | ARG | 2 | 19.519 | 37.447 | 26.837 | 0.00 | 0.00 | A |
| ATOM | 24 | NH2 | ARG | 2 | 21.449 | 38.304 | 28.261 | 1.00 | 42.19 | A |
| ATOM | 25 | HH21 | ARG | 2 | 22.237 | 38.585 | 28.802 | 0.00 | 0.00 | A |
| ATOM | 26 | HH22 | ARG | 2 | 20.557 | 38.586 | 28.658 | 0.00 | 0.00 | A |
| ATOM | 27 | C | ARG | 2 | 25.964 | 33.136 | 26.193 | 1.00 | 29.80 | A |
| ATOM | 28 | O | ARG | 2 | 26.828 | 33.041 | 25.330 | 1.00 | 29.69 | A |
| ATOM | 29 | N | ILE | 3 | 24.990 | 32.244 | 26.354 | 1.00 | 29.64 | A |
| ATOM | 30 | H | ILE | 3 | 24.250 | 32.455 | 26.949 | 0.00 | 0.00 | A |
| ATOM | 31 | CA | ILE | 3 | 24.860 | 31.022 | 25.560 | 1.00 | 27.25 | A |
| ATOM | 32 | CB | ILE | 3 | 24.577 | 29.828 | 26.515 | 1.00 | 29.21 | A |
| ATOM | 33 | CG2 | ILE | 3 | 23.172 | 29.914 | 27.085 | 1.00 | 28.35 | A |
| ATOM | 34 | CG1 | ILE | 3 | 24.672 | 28.500 | 25.788 | 1.00 | 32.48 | A |
| ATOM | 35 | CD1 | ILE | 3 | 24.341 | 27.340 | 26.697 | 1.00 | 37.82 | A |
| ATOM | 36 | C | ILE | 3 | 23.725 | 31.112 | 24.541 | 1.00 | 25.55 | A |
| ATOM | 37 | O | ILE | 3 | 22.694 | 31.712 | 24.818 | 1.00 | 26.38 | A |
| ATOM | 38 | N | GLY | 4 | 23.898 | 30.475 | 23.390 | 1.00 | 23.53 | A |
| ATOM | 39 | H | GLY | 4 | 24.728 | 29.981 | 23.217 | 0.00 | 0.00 | A |
| ATOM | 40 | CA | GLY | 4 | 22.866 | 30.481 | 22.363 | 1.00 | 21.33 | A |
| ATOM | 41 | C | GLY | 4 | 22.752 | 29.133 | 21.674 | 1.00 | 21.00 | A |
| ATOM | 42 | O | GLY | 4 | 23.684 | 28.331 | 21.706 | 1.00 | 21.02 | A |
| ATOM | 43 | N | HIS | 5 | 21.612 | 28.868 | 21.050 | 1.00 | 20.99 | A |
| ATOM | 44 | H | HIS | 5 | 20.959 | 29.569 | 20.997 | 0.00 | 0.00 | A |
| ATOM | 45 | CA | HIS | 5 | 21.381 | 27.604 | 20.352 | 1.00 | 20.38 | A |
| ATOM | 46 | CB | HIS | 5 | 20.649 | 26.599 | 21.251 | 1.00 | 20.12 | A |
| ATOM | 47 | CG | HIS | 5 | 20.263 | 25.332 | 20.549 | 1.00 | 22.13 | A |
| ATOM | 48 | CD2 | HIS | 5 | 20.963 | 24.195 | 20.307 | 1.00 | 19.36 | A |
| ATOM | 49 | ND1 | HIS | 5 | 19.035 | 25.162 | 19.941 | 1.00 | 23.51 | A |
| ATOM | 50 | HD1 | HIS | 5 | 18.268 | 25.781 | 19.942 | 0.00 | 0.00 | A |
| ATOM | 51 | CE1 | HIS | 5 | 19.000 | 23.981 | 19.345 | 1.00 | 23.02 | A |
| ATOM | 52 | NE2 | HIS | 5 | 20.156 | 23.376 | 19.554 | 1.00 | 21.92 | A |
| ATOM | 53 | HE2 | HIS | 5 | 20.287 | 22.438 | 19.285 | 0.00 | 0.00 | A |
| ATOM | 54 | C | HIS | 5 | 20.565 | 27.825 | 19.079 | 1.00 | 22.17 | A |
| ATOM | 55 | O | HIS | 5 | 19.569 | 28.570 | 19.081 | 1.00 | 22.67 | A |
| ATOM | 56 | N | GLY | 6 | 20.983 | 27.172 | 18.000 | 1.00 | 20.95 | A |
| ATOM | 57 | H | GLY | 6 | 21.791 | 26.612 | 18.027 | 0.00 | 0.00 | A |
| ATOM | 58 | CA | GLY | 6 | 20.270 | 27.280 | 16.743 | 1.00 | 21.94 | A |
| ATOM | 59 | C | GLY | 6 | 20.047 | 25.914 | 16.112 | 1.00 | 22.93 | A |
| ATOM | 60 | O | GLY | 6 | 20.794 | 24.971 | 16.371 | 1.00 | 24.45 | A |
| ATOM | 61 | N | PHE | 7 | 18.994 | 25.787 | 15.318 | 1.00 | 22.51 | A |
| ATOM | 62 | H | PHE | 7 | 18.406 | 26.550 | 15.106 | 0.00 | 0.00 | A |
| ATOM | 63 | CA | PHE | 7 | 18.705 | 24.526 | 14.655 | 1.00 | 22.04 | A |
| ATOM | 64 | CB | PHE | 7 | 17.805 | 23.663 | 15.525 | 1.00 | 19.14 | A |
| ATOM | 65 | CG | PHE | 7 | 17.297 | 22.451 | 14.830 | 1.00 | 19.29 | A |
| ATOM | 66 | CD1 | PHE | 7 | 18.060 | 21.306 | 14.769 | 1.00 | 20.19 | A |
| ATOM | 67 | CD2 | PHE | 7 | 16.066 | 22.462 | 14.203 | 1.00 | 20.81 | A |
| ATOM | 68 | CE1 | PHE | 7 | 17.603 | 20.184 | 14.086 | 1.00 | 18.50 | A |
| ATOM | 69 | CE2 | PHE | 7 | 15.604 | 21.346 | 13.520 | 1.00 | 20.63 | A |
| ATOM | 70 | CZ | PHE | 7 | 16.372 | 20.208 | 13.461 | 1.00 | 18.39 | A |
| ATOM | 71 | C | PHE | 7 | 18.029 | 24.829 | 13.329 | 1.00 | 23.15 | A |
| ATOM | 72 | O | PHE | 7 | 17.201 | 25.723 | 13.270 | 1.00 | 27.13 | A |
| ATOM | 73 | N | ASP | 8 | 18.415 | 24.129 | 12.266 | 1.00 | 23.83 | A |
| ATOM | 74 | H | ASP | 8 | 19.109 | 23.441 | 12.347 | 0.00 | 0.00 | A |
| ATOM | 75 | CA | ASP | 8 | 17.809 | 24.350 | 10.955 | 1.00 | 23.43 | A |
| ATOM | 76 | CB | ASP | 8 | 18.536 | 25.467 | 10.211 | 1.00 | 25.38 | A |
| ATOM | 77 | CG | ASP | 8 | 17.756 | 25.996 | 9.002 | 1.00 | 27.54 | A |
| ATOM | 78 | OD1 | ASP | 8 | 18.432 | 26.452 | 8.064 | 1.00 | 29.53 | A |
| ATOM | 79 | OD2 | ASP | 8 | 16.494 | 25.995 | 8.970 | 1.00 | 28.60 | A |
| ATOM | 80 | C | ASP | 8 | 17.754 | 23.078 | 10.103 | 1.00 | 23.85 | A |
| ATOM | 81 | O | ASP | 8 | 18.473 | 22.102 | 10.351 | 1.00 | 22.67 | A |
| ATOM | 82 | N | VAL | 9 | 16.857 | 23.089 | 9.122 | 1.00 | 22.84 | A |
| ATOM | 83 | H | VAL | 9 | 16.298 | 23.887 | 9.002 | 0.00 | 0.00 | A |
| ATOM | 84 | CA | VAL | 9 | 16.648 | 21.971 | 8.224 | 1.00 | 21.50 | A |
| ATOM | 85 | CB | VAL | 9 | 15.465 | 21.088 | 8.699 | 1.00 | 20.53 | A |
| ATOM | 86 | CG1 | VAL | 9 | 15.109 | 20.034 | 7.650 | 1.00 | 18.50 | A |
| ATOM | 87 | CG2 | VAL | 9 | 15.794 | 20.431 | 10.014 | 1.00 | 19.25 | A |
| ATOM | 88 | C | VAL | 9 | 16.277 | 22.520 | 6.863 | 1.00 | 23.27 | A |
| ATOM | 89 | O | VAL | 9 | 15.648 | 23.580 | 6.763 | 1.00 | 25.63 | A |
| ATOM | 90 | N | HIS | 10 | 16.756 | 21.847 | 5.819 | 1.00 | 25.28 | A |
| ATOM | 91 | H | HIS | 10 | 17.345 | 21.075 | 5.997 | 0.00 | 0.00 | A |
| ATOM | 92 | CA | HIS | 10 | 16.435 | 22.177 | 4.423 | 1.00 | 24.90 | A |
| ATOM | 93 | CB | HIS | 10 | 17.402 | 23.179 | 3.780 | 1.00 | 24.17 | A |
| ATOM | 94 | CG | HIS | 10 | 17.162 | 24.590 | 4.223 | 1.00 | 27.36 | A |
| ATOM | 95 | CD2 | HIS | 10 | 17.793 | 25.355 | 5.147 | 1.00 | 28.24 | A |
| ATOM | 96 | ND1 | HIS | 10 | 16.084 | 25.329 | 3.789 | 1.00 | 26.78 | A |
| ATOM | 97 | HD1 | HIS | 10 | 15.474 | 25.012 | 3.070 | 0.00 | 0.00 | A |
| ATOM | 98 | CE1 | HIS | 10 | 16.055 | 26.483 | 4.433 | 1.00 | 29.23 | A |
| ATOM | 99 | NE2 | HIS | 10 | 17.081 | 26.527 | 5.267 | 1.00 | 31.54 | A |
| ATOM | 100 | C | HIS | 10 | 16.328 | 20.879 | 3.643 | 1.00 | 24.81 | A |
| ATOM | 101 | O | HIS | 10 | 17.037 | 19.900 | 3.919 | 1.00 | 24.91 | A |
| ATOM | 102 | N | ALA | 11 | 15.324 | 20.835 | 2.780 | 1.00 | 24.08 | A |
| ATOM | 103 | H | ALA | 11 | 14.735 | 21.608 | 2.675 | 0.00 | 0.00 | A |
| ATOM | 104 | CA | ALA | 11 | 15.054 | 19.666 | 1.976 | 1.00 | 23.13 | A |
| ATOM | 105 | CB | ALA | 11 | 13.569 | 19.596 | 1.674 | 1.00 | 22.04 | A |
| ATOM | 106 | C | ALA | 11 | 15.848 | 19.623 | 0.687 | 1.00 | 23.70 | A |
| ATOM | 107 | O | ALA | 11 | 16.144 | 20.652 | 0.087 | 1.00 | 24.62 | A |
| ATOM | 108 | N | PHE | 12 | 16.199 | 18.418 | 0.269 | 1.00 | 25.49 | A |
| ATOM | 109 | H | PHE | 12 | 15.926 | 17.631 | 0.789 | 0.00 | 0.00 | A |
| ATOM | 110 | CA | PHE | 12 | 16.913 | 18.235 | −0.975 | 1.00 | 26.38 | A |
| ATOM | 111 | CB | PHE | 12 | 17.452 | 16.812 | −1.087 | 1.00 | 23.20 | A |
| ATOM | 112 | CG | PHE | 12 | 18.734 | 16.608 | −0.363 | 1.00 | 20.10 | A |
| ATOM | 113 | CD1 | PHE | 12 | 19.812 | 17.449 | −0.597 | 1.00 | 19.79 | A |
| ATOM | 114 | CD2 | PHE | 12 | 18.858 | 15.614 | 0.577 | 1.00 | 17.04 | A |
| ATOM | 115 | CE1 | PHE | 12 | 20.994 | 17.303 | 0.102 | 1.00 | 19.68 | A |
| ATOM | 116 | CE2 | PHE | 12 | 20.037 | 15.462 | 1.283 | 1.00 | 18.75 | A |
| ATOM | 117 | CZ | PHE | 12 | 21.107 | 16.311 | 1.044 | 1.00 | 19.49 | A |
| ATOM | 118 | C | PHE | 12 | 15.925 | 18.502 | −2.088 | 1.00 | 29.81 | A |
| ATOM | 119 | O | PHE | 12 | 14.723 | 18.259 | −1.941 | 1.00 | 31.17 | A |
| ATOM | 120 | N | GLY | 13 | 16.429 | 19.027 | −3.193 | 1.00 | 34.56 | A |
| ATOM | 121 | H | GLY | 13 | 17.376 | 19.242 | −3.267 | 0.00 | 0.00 | A |
| ATOM | 122 | CA | GLY | 13 | 15.583 | 19.324 | −4.327 | 1.00 | 36.61 | A |
| ATOM | 123 | C | GLY | 13 | 16.433 | 19.902 | −5.426 | 1.00 | 39.05 | A |
| ATOM | 124 | O | GLY | 13 | 17.307 | 20.735 | −5.167 | 1.00 | 41.03 | A |
| ATOM | 125 | N | GLY | 14 | 16.211 | 19.426 | −6.646 | 1.00 | 40.90 | A |
| ATOM | 126 | H | GLY | 14 | 15.553 | 18.717 | −6.775 | 0.00 | 0.00 | A |
| ATOM | 127 | CA | GLY | 14 | 16.970 | 19.915 | −7.782 | 1.00 | 42.80 | A |
| ATOM | 128 | C | GLY | 14 | 18.319 | 19.251 | −7.962 | 1.00 | 43.75 | A |
| ATOM | 129 | O | GLY | 14 | 18.552 | 18.144 | −7.472 | 1.00 | 42.97 | A |
| ATOM | 130 | N | GLU | 15 | 19.206 | 19.954 | −8.655 | 1.00 | 46.32 | A |
| ATOM | 131 | H | GLU | 15 | 18.977 | 20.840 | −8.990 | 0.00 | 0.00 | A |
| ATOM | 132 | CA | GLU | 15 | 20.551 | 19.474 | −8.940 | 1.00 | 49.76 | A |
| ATOM | 133 | CB | GLU | 15 | 20.952 | 19.898 | −10.359 | 1.00 | 57.48 | A |
| ATOM | 134 | CG | GLU | 15 | 20.143 | 19.244 | −11.477 | 1.00 | 67.67 | A |
| ATOM | 135 | CD | GLU | 15 | 20.382 | 17.740 | −11.569 | 1.00 | 74.77 | A |
| ATOM | 136 | OE1 | GLU | 15 | 19.392 | 16.969 | −11.487 | 1.00 | 78.99 | A |
| ATOM | 137 | OE2 | GLU | 15 | 21.561 | 17.332 | −11.724 | 1.00 | 78.94 | A |
| ATOM | 138 | C | GLU | 15 | 21.573 | 20.023 | −7.945 | 1.00 | 47.00 | A |
| ATOM | 139 | O | GLU | 15 | 21.358 | 21.083 | −7.348 | 1.00 | 47.60 | A |
| ATOM | 140 | N | GLY | 16 | 22.681 | 19.305 | −7.774 | 1.00 | 43.47 | A |
| ATOM | 141 | H | GLY | 16 | 22.785 | 18.476 | −8.289 | 0.00 | 0.00 | A |
| ATOM | 142 | CA | GLY | 16 | 23.718 | 19.756 | −6.867 | 1.00 | 38.10 | A |
| ATOM | 143 | C | GLY | 16 | 24.393 | 20.977 | −7.453 | 1.00 | 36.67 | A |
| ATOM | 144 | O | GLY | 16 | 24.060 | 21.389 | −8.566 | 1.00 | 37.70 | A |
| ATOM | 145 | N | CPR | 17 | 25.376 | 21.564 | −6.760 | 1.00 | 33.07 | A |
| ATOM | 146 | CD | CPR | 17 | 26.058 | 22.731 | −7.341 | 1.00 | 28.03 | A |
| ATOM | 147 | CA | CPR | 17 | 25.957 | 21.228 | −5.463 | 1.00 | 31.17 | A |
| ATOM | 148 | CB | CPR | 17 | 27.313 | 21.901 | −5.548 | 1.00 | 30.73 | A |
| ATOM | 149 | CG | CPR | 17 | 26.963 | 23.180 | −6.217 | 1.00 | 28.65 | A |
| ATOM | 150 | C | CPR | 17 | 25.137 | 21.854 | −4.342 | 1.00 | 30.88 | A |
| ATOM | 151 | O | CPR | 17 | 24.112 | 22.503 | −4.585 | 1.00 | 34.56 | A |
| ATOM | 152 | N | ILE | 18 | 25.598 | 21.673 | −3.116 | 1.00 | 27.52 | A |
| ATOM | 153 | H | ILE | 18 | 26.428 | 21.172 | −2.963 | 0.00 | 0.00 | A |
| ATOM | 154 | CA | ILE | 18 | 24.926 | 22.240 | −1.972 | 1.00 | 22.91 | A |
| ATOM | 155 | CB | ILE | 18 | 24.549 | 21.152 | −0.938 | 1.00 | 21.47 | A |
| ATOM | 156 | CG2 | ILE | 18 | 23.545 | 20.206 | −1.524 | 1.00 | 20.06 | A |
| ATOM | 157 | CG1 | ILE | 18 | 25.773 | 20.361 | −0.485 | 1.00 | 19.34 | A |
| ATOM | 158 | CD1 | ILE | 18 | 25.435 | 19.282 | 0.516 | 1.00 | 14.57 | A |
| ATOM | 159 | C | ILE | 18 | 25.921 | 23.190 | −1.368 | 1.00 | 22.37 | A |
| ATOM | 160 | O | ILE | 18 | 27.106 | 23.065 | −1.629 | 1.00 | 25.80 | A |
| ATOM | 161 | N | ILE | 19 | 25.454 | 24.186 | −0.630 | 1.00 | 22.84 | A |
| ATOM | 162 | H | ILE | 19 | 24.495 | 24.313 | −0.477 | 0.00 | 0.00 | A |
| ATOM | 163 | CA | ILE | 19 | 26.371 | 25.109 | 0.025 | 1.00 | 19.61 | A |
| ATOM | 164 | CB | ILE | 19 | 26.032 | 26.556 | −0.288 | 1.00 | 19.09 | A |
| ATOM | 165 | CG2 | ILE | 19 | 27.120 | 27.451 | 0.202 | 1.00 | 15.64 | A |
| ATOM | 166 | CG1 | ILE | 19 | 25.878 | 26.752 | −1.797 | 1.00 | 19.94 | A |
| ATOM | 167 | CD1 | ILE | 19 | 27.121 | 26.566 | −2.579 | 1.00 | 23.12 | A |
| ATOM | 168 | C | ILE | 19 | 26.173 | 24.868 | 1.511 | 1.00 | 20.51 | A |
| ATOM | 169 | O | ILE | 19 | 25.039 | 24.911 | 1.986 | 1.00 | 20.44 | A |
| ATOM | 170 | N | ILE | 20 | 27.248 | 24.496 | 2.209 | 1.00 | 19.87 | A |
| ATOM | 171 | H | ILE | 20 | 28.107 | 24.400 | 1.745 | 0.00 | 0.00 | A |
| ATOM | 172 | CA | ILE | 20 | 27.205 | 24.234 | 3.647 | 1.00 | 19.21 | A |
| ATOM | 173 | CB | ILE | 20 | 27.323 | 22.731 | 3.973 | 1.00 | 20.17 | A |
| ATOM | 174 | CG2 | ILE | 20 | 27.141 | 22.514 | 5.480 | 1.00 | 16.96 | A |
| ATOM | 175 | CG1 | ILE | 20 | 26.261 | 21.913 | 3.233 | 1.00 | 21.44 | A |
| ATOM | 176 | CD1 | ILE | 20 | 24.845 | 22.059 | 3.806 | 1.00 | 19.65 | A |
| ATOM | 177 | C | ILE | 20 | 28.408 | 24.894 | 4.293 | 1.00 | 20.78 | A |
| ATOM | 178 | O | ILE | 20 | 29.540 | 24.605 | 3.923 | 1.00 | 24.00 | A |
| ATOM | 179 | N | GLY | 21 | 28.176 | 25.756 | 5.276 | 1.00 | 20.89 | A |
| ATOM | 180 | H | GLY | 21 | 27.252 | 25.979 | 5.506 | 0.00 | 0.00 | A |
| ATOM | 181 | CA | GLY | 21 | 29.281 | 26.427 | 5.943 | 1.00 | 18.56 | A |
| ATOM | 182 | C | GLY | 21 | 29.993 | 27.325 | 4.961 | 1.00 | 19.68 | A |
| ATOM | 183 | O | GLY | 21 | 31.145 | 27.685 | 5.146 | 1.00 | 21.98 | A |
| ATOM | 184 | N | GLY | 22 | 29.287 | 27.706 | 3.908 | 1.00 | 21.47 | A |
| ATOM | 185 | H | GLY | 22 | 28.349 | 27.438 | 3.820 | 0.00 | 0.00 | A |
| ATOM | 186 | CA | GLY | 22 | 29.868 | 28.560 | 2.894 | 1.00 | 22.19 | A |
| ATOM | 187 | C | GLY | 22 | 30.574 | 27.782 | 1.797 | 1.00 | 24.59 | A |
| ATOM | 188 | O | GLY | 22 | 30.942 | 28.368 | 0.786 | 1.00 | 27.44 | A |
| ATOM | 189 | N | VAL | 23 | 30.717 | 26.465 | 1.961 | 1.00 | 23.88 | A |
| ATOM | 190 | H | VAL | 23 | 30.346 | 26.036 | 2.760 | 0.00 | 0.00 | A |
| ATOM | 191 | CA | VAL | 23 | 31.409 | 25.619 | 0.991 | 1.00 | 19.56 | A |
| ATOM | 192 | CB | VAL | 23 | 32.246 | 24.548 | 1.722 | 1.00 | 15.76 | A |
| ATOM | 193 | CG1 | VAL | 23 | 33.016 | 23.716 | 0.748 | 1.00 | 17.49 | A |
| ATOM | 194 | CG2 | VAL | 23 | 33.223 | 25.210 | 2.644 | 1.00 | 14.82 | A |
| ATOM | 195 | C | VAL | 23 | 30.500 | 24.958 | −0.043 | 1.00 | 22.85 | A |
| ATOM | 196 | O | VAL | 23 | 29.450 | 24.398 | 0.287 | 1.00 | 27.11 | A |
| ATOM | 197 | N | ARG | 24 | 30.871 | 25.080 | −1.310 | 1.00 | 23.92 | A |
| ATOM | 198 | H | ARG | 24 | 31.661 | 25.598 | −1.506 | 0.00 | 0.00 | A |
| ATOM | 199 | CA | ARG | 24 | 30.106 | 24.484 | −2.391 | 1.00 | 25.47 | A |
| ATOM | 200 | CB | ARG | 24 | 30.402 | 25.196 | −3.700 | 1.00 | 28.09 | A |
| ATOM | 201 | CG | ARG | 24 | 29.782 | 24.511 | −4.888 | 1.00 | 38.07 | A |
| ATOM | 202 | CD | ARG | 24 | 30.126 | 25.209 | −6.195 | 1.00 | 44.99 | A |
| ATOM | 203 | NE | ARG | 24 | 28.998 | 25.997 | −6.679 | 1.00 | 53.12 | A |
| ATOM | 204 | HE | ARG | 24 | 28.726 | 26.726 | −6.075 | 0.00 | 0.00 | A |
| ATOM | 205 | CZ | ARG | 24 | 28.378 | 25.786 | −7.836 | 1.00 | 56.13 | A |
| ATOM | 206 | NH1 | ARG | 24 | 27.351 | 26.558 | −8.179 | 1.00 | 57.79 | A |
| ATOM | 207 | HH11 | ARG | 24 | 27.042 | 27.300 | −7.576 | 0.00 | 0.00 | A |
| ATOM | 208 | HH12 | ARG | 24 | 26.848 | 26.443 | −9.039 | 0.00 | 0.00 | A |
| ATOM | 209 | NH2 | ARG | 24 | 28.796 | 24.816 | −8.655 | 1.00 | 60.85 | A |
| ATOM | 210 | HH21 | ARG | 24 | 29.582 | 24.252 | −8.388 | 0.00 | 0.00 | A |
| ATOM | 211 | HH22 | ARG | 24 | 28.358 | 24.615 | −9.533 | 0.00 | 0.00 | A |
| ATOM | 212 | C | ARG | 24 | 30.546 | 23.037 | −2.443 | 1.00 | 26.16 | A |
| ATOM | 213 | O | ARG | 24 | 31.670 | 22.733 | −2.839 | 1.00 | 31.30 | A |
| ATOM | 214 | N | ILE | 25 | 29.691 | 22.157 | −1.949 | 1.00 | 25.63 | A |
| ATOM | 215 | H | ILE | 25 | 28.835 | 22.476 | −1.606 | 0.00 | 0.00 | A |
| ATOM | 216 | CA | ILE | 25 | 29.983 | 20.734 | −1.871 | 1.00 | 21.72 | A |
| ATOM | 217 | CB | ILE | 25 | 29.537 | 20.176 | −0.505 | 1.00 | 19.56 | A |
| ATOM | 218 | CG2 | ILE | 25 | 29.806 | 18.703 | −0.436 | 1.00 | 19.72 | A |
| ATOM | 219 | CG1 | ILE | 25 | 30.247 | 20.919 | 0.633 | 1.00 | 16.60 | A |
| ATOM | 220 | CD1 | ILE | 25 | 29.763 | 20.551 | 2.017 | 1.00 | 12.26 | A |
| ATOM | 221 | C | ILE | 25 | 29.244 | 19.982 | −2.948 | 1.00 | 23.33 | A |
| ATOM | 222 | O | ILE | 25 | 28.020 | 20.032 | −3.021 | 1.00 | 27.56 | A |
| ATOM | 223 | N | PRO | 26 | 29.973 | 19.294 | −3.824 | 1.00 | 22.69 | A |
| ATOM | 224 | CD | PRO | 26 | 31.436 | 19.182 | −3.894 | 1.00 | 21.57 | A |
| ATOM | 225 | CA | PRO | 26 | 29.341 | 18.532 | −4.899 | 1.00 | 21.47 | A |
| ATOM | 226 | CB | PRO | 26 | 30.537 | 17.947 | −5.634 | 1.00 | 19.51 | A |
| ATOM | 227 | CG | PRO | 26 | 31.597 | 17.884 | −4.585 | 1.00 | 19.72 | A |
| ATOM | 228 | C | PRO | 26 | 28.419 | 17.436 | −4.371 | 1.00 | 22.68 | A |
| ATOM | 229 | O | PRO | 26 | 28.799 | 16.654 | −3.493 | 1.00 | 23.18 | A |
| ATOM | 230 | N | TYR | 27 | 27.212 | 17.380 | −4.918 | 1.00 | 23.70 | A |
| ATOM | 231 | H | TYR | 27 | 26.942 | 18.006 | −5.622 | 0.00 | 0.00 | A |
| ATOM | 232 | CA | TYR | 27 | 26.234 | 16.389 | −4.511 | 1.00 | 28.60 | A |
| ATOM | 233 | CB | TYR | 27 | 25.498 | 16.838 | −3.248 | 1.00 | 28.88 | A |
| ATOM | 234 | CG | TYR | 27 | 24.661 | 15.752 | −2.612 | 1.00 | 27.13 | A |
| ATOM | 235 | CD1 | TYR | 27 | 25.198 | 14.498 | −2.355 | 1.00 | 26.71 | A |
| ATOM | 236 | CE1 | TYR | 27 | 24.435 | 13.499 | −1.763 | 1.00 | 27.66 | A |
| ATOM | 237 | CD2 | TYR | 27 | 23.335 | 15.984 | −2.261 | 1.00 | 27.81 | A |
| ATOM | 238 | CE2 | TYR | 27 | 22.572 | 15.001 | −1.675 | 1.00 | 26.98 | A |
| ATOM | 239 | CZ | TYR | 27 | 23.126 | 13.762 | −1.431 | 1.00 | 26.38 | A |
| ATOM | 240 | OH | TYR | 27 | 22.359 | 12.778 | −0.870 | 1.00 | 29.97 | A |
| ATOM | 241 | HH | TYR | 27 | 22.924 | 11.986 | −0.837 | 0.00 | 0.00 | A |
| ATOM | 242 | C | TYR | 27 | 25.230 | 16.193 | −5.633 | 1.00 | 32.25 | A |
| ATOM | 243 | O | TYR | 27 | 24.991 | 17.111 | −6.419 | 1.00 | 34.35 | A |
| ATOM | 244 | N | GLU | 28 | 24.655 | 14.991 | −5.699 | 1.00 | 36.20 | A |
| ATOM | 245 | H | GLU | 28 | 24.909 | 14.307 | −5.048 | 0.00 | 0.00 | A |
| ATOM | 246 | CA | GLU | 28 | 23.665 | 14.635 | −6.720 | 1.00 | 39.28 | A |
| ATOM | 247 | CB | GLU | 28 | 23.253 | 13.167 | −6.577 | 1.00 | 43.37 | A |
| ATOM | 248 | CG | GLU | 28 | 22.943 | 12.777 | −5.148 | 1.00 | 52.35 | A |
| ATOM | 249 | CD | GLU | 28 | 22.423 | 11.366 | −5.012 | 1.00 | 56.49 | A |
| ATOM | 250 | OE1 | GLU | 28 | 23.233 | 10.455 | −4.723 | 1.00 | 59.10 | A |
| ATOM | 251 | OE2 | GLU | 28 | 21.195 | 11.182 | −5.162 | 1.00 | 60.26 | A |
| ATOM | 252 | C | GLU | 28 | 22.428 | 15.520 | −6.699 | 1.00 | 37.05 | A |
| ATOM | 253 | O | GLU | 28 | 21.847 | 15.794 | −7.739 | 1.00 | 38.91 | A |
| ATOM | 254 | N | LYS | 29 | 22.012 | 15.940 | −5.512 | 1.00 | 35.07 | A |
| ATOM | 255 | H | LYS | 29 | 22.514 | 15.706 | −4.712 | 0.00 | 0.00 | A |
| ATOM | 256 | CA | LYS | 29 | 20.850 | 16.798 | −5.390 | 1.00 | 33.57 | A |
| ATOM | 257 | CB | LYS | 29 | 19.709 | 16.109 | −4.628 | 1.00 | 32.34 | A |
| ATOM | 258 | CG | LYS | 29 | 20.034 | 14.750 | −4.034 | 1.00 | 33.71 | A |
| ATOM | 259 | CD | LYS | 29 | 18.798 | 14.142 | −3.401 | 1.00 | 35.14 | A |
| ATOM | 260 | CE | LYS | 29 | 19.076 | 12.794 | −2.721 | 1.00 | 37.21 | A |
| ATOM | 261 | NZ | LYS | 29 | 19.803 | 12.853 | −1.405 | 1.00 | 35.28 | A |
| ATOM | 262 | HZ1 | LYS | 29 | 19.243 | 13.360 | −0.686 | 0.00 | 0.00 | A |
| ATOM | 263 | HZ2 | LYS | 29 | 20.756 | 13.263 | −1.495 | 0.00 | 0.00 | A |
| ATOM | 264 | HZ3 | LYS | 29 | 19.950 | 11.880 | −1.083 | 0.00 | 0.00 | A |
| ATOM | 265 | C | LYS | 29 | 21.279 | 18.051 | −4.669 | 1.00 | 32.71 | A |
| ATOM | 266 | O | LYS | 29 | 22.337 | 18.075 | −4.046 | 1.00 | 34.22 | A |
| ATOM | 267 | N | GLY | 30 | 20.498 | 19.109 | −4.831 | 1.00 | 31.32 | A |
| ATOM | 268 | H | GLY | 30 | 19.709 | 19.045 | −5.406 | 0.00 | 0.00 | A |
| ATOM | 269 | CA | GLY | 30 | 20.783 | 20.363 | −4.161 | 1.00 | 31.08 | A |
| ATOM | 270 | C | GLY | 30 | 19.795 | 20.554 | −3.022 | 1.00 | 31.36 | A |
| ATOM | 271 | O | GLY | 30 | 19.040 | 19.634 | −2.686 | 1.00 | 29.34 | A |
| ATOM | 272 | N | LEU | 31 | 19.796 | 21.738 | −2.417 | 1.00 | 31.88 | A |
| ATOM | 273 | H | LEU | 31 | 20.374 | 22.455 | −2.748 | 0.00 | 0.00 | A |
| ATOM | 274 | CA | LEU | 31 | 18.887 | 22.024 | −1.309 | 1.00 | 31.84 | A |
| ATOM | 275 | CB | LEU | 31 | 19.654 | 22.473 | −0.058 | 1.00 | 28.52 | A |
| ATOM | 276 | CG | LEU | 31 | 20.382 | 21.387 | 0.733 | 1.00 | 26.61 | A |
| ATOM | 277 | CD1 | LEU | 31 | 21.211 | 22.013 | 1.825 | 1.00 | 27.45 | A |
| ATOM | 278 | CD2 | LEU | 31 | 19.386 | 20.411 | 1.316 | 1.00 | 25.77 | A |
| ATOM | 279 | C | LEU | 31 | 17.895 | 23.092 | −1.696 | 1.00 | 32.32 | A |
| ATOM | 280 | O | LEU | 31 | 18.260 | 24.069 | −2.325 | 1.00 | 32.63 | A |
| ATOM | 281 | N | LEU | 32 | 16.637 | 22.878 | −1.336 | 1.00 | 34.40 | A |
| ATOM | 282 | H | LEU | 32 | 16.420 | 22.059 | −0.890 | 0.00 | 0.00 | A |
| ATOM | 283 | CA | LEU | 32 | 15.570 | 23.825 | −1.607 | 1.00 | 38.00 | A |
| ATOM | 284 | CB | LEU | 32 | 14.248 | 23.087 | −1.589 | 1.00 | 34.88 | A |
| ATOM | 285 | CG | LEU | 32 | 14.111 | 22.037 | −2.671 | 1.00 | 36.70 | A |
| ATOM | 286 | CD1 | LEU | 32 | 12.834 | 21.261 | −2.447 | 1.00 | 35.96 | A |
| ATOM | 287 | CD2 | LEU | 32 | 14.101 | 22.716 | −4.028 | 1.00 | 35.85 | A |
| ATOM | 288 | C | LEU | 32 | 15.524 | 24.953 | −0.563 | 1.00 | 41.28 | A |
| ATOM | 289 | O | LEU | 32 | 15.417 | 24.680 | 0.644 | 1.00 | 44.82 | A |
| ATOM | 290 | N | ALA | 33 | 15.570 | 26.206 | −1.021 | 1.00 | 44.52 | A |
| ATOM | 291 | H | ALA | 33 | 15.670 | 26.387 | −1.982 | 0.00 | 0.00 | A |
| ATOM | 292 | CA | ALA | 33 | 15.514 | 27.368 | −0.126 | 1.00 | 49.53 | A |
| ATOM | 293 | CB | ALA | 33 | 16.752 | 27.385 | 0.780 | 1.00 | 48.41 | A |
| ATOM | 294 | C | ALA | 33 | 15.334 | 28.749 | −0.819 | 1.00 | 53.33 | A |
| ATOM | 295 | O | ALA | 33 | 15.605 | 28.890 | −2.016 | 1.00 | 54.77 | A |
| ATOM | 296 | N | HIS | 34 | 14.844 | 29.740 | −0.051 | 1.00 | 57.06 | A |
| ATOM | 297 | H | HIS | 34 | 14.637 | 29.510 | 0.867 | 0.00 | 0.00 | A |
| ATOM | 298 | CA | HIS | 34 | 14.634 | 31.138 | −0.500 | 1.00 | 57.83 | A |
| ATOM | 299 | CB | HIS | 34 | 13.932 | 31.943 | 0.637 | 1.00 | 64.24 | A |
| ATOM | 300 | CG | HIS | 34 | 13.749 | 33.430 | 0.392 | 1.00 | 69.95 | A |
| ATOM | 301 | CD2 | HIS | 34 | 14.101 | 34.501 | 1.154 | 1.00 | 69.48 | A |
| ATOM | 302 | ND1 | HIS | 34 | 12.993 | 33.945 | −0.646 | 1.00 | 71.87 | A |
| ATOM | 303 | HD1 | HIS | 34 | 12.569 | 33.439 | −1.370 | 0.00 | 0.00 | A |
| ATOM | 304 | CE1 | HIS | 34 | 12.882 | 35.258 | −0.506 | 1.00 | 69.84 | A |
| ATOM | 305 | NE2 | HIS | 34 | 13.545 | 35.619 | 0.577 | 1.00 | 67.82 | A |
| ATOM | 306 | HE2 | HIS | 34 | 13.534 | 36.537 | 0.950 | 0.00 | 0.00 | A |
| ATOM | 307 | C | HIS | 34 | 16.040 | 31.678 | −0.791 | 1.00 | 56.42 | A |
| ATOM | 308 | O | HIS | 34 | 16.268 | 32.262 | −1.847 | 1.00 | 55.74 | A |
| ATOM | 309 | N | SER | 35 | 16.970 | 31.418 | 0.136 | 1.00 | 54.55 | A |
| ATOM | 310 | H | SER | 35 | 16.736 | 30.904 | 0.927 | 0.00 | 0.00 | A |
| ATOM | 311 | CA | SER | 35 | 18.375 | 31.829 | 0.043 | 1.00 | 51.78 | A |
| ATOM | 312 | CB | SER | 35 | 18.933 | 32.091 | 1.456 | 1.00 | 52.98 | A |
| ATOM | 313 | OG | SER | 35 | 19.009 | 30.889 | 2.226 | 1.00 | 55.70 | A |
| ATOM | 314 | HG | SER | 35 | 19.977 | 30.741 | 2.190 | 0.00 | 0.00 | A |
| ATOM | 315 | C | SER | 35 | 19.155 | 30.686 | −0.608 | 1.00 | 49.09 | A |
| ATOM | 316 | O | SER | 35 | 18.644 | 30.005 | −1.494 | 1.00 | 49.69 | A |
| ATOM | 317 | N | ASP | 36 | 20.390 | 30.481 | −0.160 | 1.00 | 46.76 | A |
| ATOM | 318 | H | ASP | 36 | 20.844 | 31.094 | 0.457 | 0.00 | 0.00 | A |
| ATOM | 319 | CA | ASP | 36 | 21.235 | 29.397 | −0.663 | 1.00 | 44.27 | A |
| ATOM | 320 | CB | ASP | 36 | 22.708 | 29.820 | −0.642 | 1.00 | 42.39 | A |
| ATOM | 321 | CG | ASP | 36 | 23.152 | 30.316 | 0.708 | 1.00 | 42.09 | A |
| ATOM | 322 | OD1 | ASP | 36 | 24.296 | 30.809 | 0.794 | 1.00 | 39.99 | A |
| ATOM | 323 | OD2 | ASP | 36 | 22.358 | 30.220 | 1.681 | 1.00 | 43.02 | A |
| ATOM | 324 | C | ASP | 36 | 21.022 | 28.095 | 0.144 | 1.00 | 43.33 | A |
| ATOM | 325 | O | ASP | 36 | 21.672 | 27.064 | −0.115 | 1.00 | 42.20 | A |
| ATOM | 326 | N | GLY | 37 | 20.130 | 28.170 | 1.140 | 1.00 | 39.97 | A |
| ATOM | 327 | H | GLY | 37 | 19.725 | 29.042 | 1.292 | 0.00 | 0.00 | A |
| ATOM | 328 | CA | GLY | 37 | 19.795 | 27.016 | 1.951 | 1.00 | 33.43 | A |
| ATOM | 329 | C | GLY | 37 | 20.918 | 26.467 | 2.785 | 1.00 | 30.89 | A |
| ATOM | 330 | O | GLY | 37 | 20.880 | 25.310 | 3.183 | 1.00 | 31.66 | A |
| ATOM | 331 | N | ASP | 38 | 21.898 | 27.304 | 3.089 | 1.00 | 28.48 | A |
| ATOM | 332 | H | ASP | 38 | 21.940 | 28.206 | 2.701 | 0.00 | 0.00 | A |
| ATOM | 333 | CA | ASP | 38 | 23.017 | 26.880 | 3.908 | 1.00 | 26.77 | A |
| ATOM | 334 | CB | ASP | 38 | 24.080 | 27.972 | 3.914 | 1.00 | 23.84 | A |
| ATOM | 335 | CG | ASP | 38 | 25.417 | 27.482 | 4.399 | 1.00 | 25.34 | A |
| ATOM | 336 | OD1 | ASP | 38 | 25.461 | 26.730 | 5.386 | 1.00 | 29.26 | A |
| ATOM | 337 | OD2 | ASP | 38 | 26.447 | 27.860 | 3.813 | 1.00 | 27.31 | A |
| ATOM | 338 | C | ASP | 38 | 22.525 | 26.581 | 5.340 | 1.00 | 28.01 | A |
| ATOM | 339 | O | ASP | 38 | 22.431 | 27.480 | 6.190 | 1.00 | 31.86 | A |
| ATOM | 340 | N | VAL | 39 | 22.167 | 25.326 | 5.590 | 1.00 | 25.58 | A |
| ATOM | 341 | H | VAL | 39 | 22.258 | 24.728 | 4.817 | 0.00 | 0.00 | A |
| ATOM | 342 | CA | VAL | 39 | 21.677 | 24.900 | 6.896 | 1.00 | 24.79 | A |
| ATOM | 343 | CB | VAL | 39 | 21.448 | 23.370 | 6.978 | 1.00 | 25.32 | A |
| ATOM | 344 | CG1 | VAL | 39 | 20.265 | 23.079 | 7.845 | 1.00 | 27.38 | A |
| ATOM | 345 | CG2 | VAL | 39 | 21.255 | 22.765 | 5.632 | 1.00 | 28.13 | A |
| ATOM | 346 | C | VAL | 39 | 22.661 | 25.213 | 8.007 | 1.00 | 25.71 | A |
| ATOM | 347 | O | VAL | 39 | 22.255 | 25.600 | 9.096 | 1.00 | 27.96 | A |
| ATOM | 348 | N | ALA | 40 | 23.950 | 25.016 | 7.742 | 1.00 | 24.49 | A |
| ATOM | 349 | H | ALA | 40 | 24.210 | 24.769 | 6.830 | 0.00 | 0.00 | A |
| ATOM | 350 | CA | ALA | 40 | 24.980 | 25.234 | 8.746 | 1.00 | 22.18 | A |
| ATOM | 351 | CB | ALA | 40 | 26.321 | 24.731 | 8.257 | 1.00 | 21.72 | A |
| ATOM | 352 | C | ALA | 40 | 25.095 | 26.672 | 9.190 | 1.00 | 23.76 | A |
| ATOM | 353 | O | ALA | 40 | 25.297 | 26.946 | 10.374 | 1.00 | 27.45 | A |
| ATOM | 354 | N | LEU | 41 | 24.989 | 27.606 | 8.255 | 1.00 | 24.01 | A |
| ATOM | 355 | H | LEU | 41 | 24.854 | 27.360 | 7.308 | 0.00 | 0.00 | A |
| ATOM | 356 | CA | LEU | 41 | 25.099 | 29.002 | 8.631 | 1.00 | 20.69 | A |
| ATOM | 357 | CB | LEU | 41 | 25.640 | 29.851 | 7.503 | 1.00 | 19.56 | A |
| ATOM | 358 | CG | LEU | 41 | 27.034 | 29.382 | 7.078 | 1.00 | 18.44 | A |
| ATOM | 359 | CD1 | LEU | 41 | 27.557 | 30.312 | 6.001 | 1.00 | 20.10 | A |
| ATOM | 360 | CD2 | LEU | 41 | 27.992 | 29.331 | 8.249 | 1.00 | 15.65 | A |
| ATOM | 361 | C | LEU | 41 | 23.819 | 29.560 | 9.202 | 1.00 | 22.47 | A |
| ATOM | 362 | O | LEU | 41 | 23.873 | 30.490 | 9.998 | 1.00 | 26.20 | A |
| ATOM | 363 | N | HIS | 42 | 22.668 | 28.991 | 8.852 | 1.00 | 21.14 | A |
| ATOM | 364 | H | HIS | 42 | 22.693 | 28.255 | 8.204 | 0.00 | 0.00 | A |
| ATOM | 365 | CA | HIS | 42 | 21.429 | 29.478 | 9.451 | 1.00 | 20.57 | A |
| ATOM | 366 | CB | HIS | 42 | 20.193 | 28.913 | 8.784 | 1.00 | 21.77 | A |
| ATOM | 367 | CG | HIS | 42 | 20.006 | 29.373 | 7.375 | 1.00 | 22.31 | A |
| ATOM | 368 | CD2 | HIS | 42 | 20.731 | 30.237 | 6.625 | 1.00 | 21.65 | A |
| ATOM | 369 | ND1 | HIS | 42 | 18.987 | 28.907 | 6.563 | 1.00 | 26.77 | A |
| ATOM | 370 | CE1 | HIS | 42 | 19.107 | 29.471 | 5.370 | 1.00 | 26.31 | A |
| ATOM | 371 | NE2 | HIS | 42 | 20.154 | 30.278 | 5.384 | 1.00 | 22.99 | A |
| ATOM | 372 | HE2 | HIS | 42 | 20.529 | 30.829 | 4.642 | 0.00 | 0.00 | A |
| ATOM | 373 | C | HIS | 42 | 21.436 | 29.052 | 10.899 | 1.00 | 22.19 | A |
| ATOM | 374 | O | HIS | 42 | 21.239 | 29.873 | 11.788 | 1.00 | 28.19 | A |
| ATOM | 375 | N | ALA | 43 | 21.711 | 27.782 | 11.153 | 1.00 | 20.32 | A |
| ATOM | 376 | H | ALA | 43 | 21.896 | 27.142 | 10.431 | 0.00 | 0.00 | A |
| ATOM | 377 | CA | ALA | 43 | 21.742 | 27.314 | 12.526 | 1.00 | 18.61 | A |
| ATOM | 378 | CB | ALA | 43 | 22.053 | 25.868 | 12.577 | 1.00 | 16.89 | A |
| ATOM | 379 | C | ALA | 43 | 22.750 | 28.114 | 13.326 | 1.00 | 20.49 | A |
| ATOM | 380 | O | ALA | 43 | 22.470 | 28.493 | 14.456 | 1.00 | 23.34 | A |
| ATOM | 381 | N | LEU | 44 | 23.901 | 28.430 | 12.737 | 1.00 | 21.44 | A |
| ATOM | 382 | H | LEU | 44 | 24.096 | 28.116 | 11.829 | 0.00 | 0.00 | A |
| ATOM | 383 | CA | LEU | 44 | 24.900 | 29.217 | 13.466 | 1.00 | 21.39 | A |
| ATOM | 384 | CB | LEU | 44 | 26.236 | 29.266 | 12.714 | 1.00 | 16.46 | A |
| ATOM | 385 | CG | LEU | 44 | 27.344 | 30.116 | 13.356 | 1.00 | 15.17 | A |
| ATOM | 386 | CD1 | LEU | 44 | 27.687 | 29.617 | 14.746 | 1.00 | 13.86 | A |
| ATOM | 387 | CD2 | LEU | 44 | 28.586 | 30.102 | 12.487 | 1.00 | 13.77 | A |
| ATOM | 388 | C | LEU | 44 | 24.392 | 30.635 | 13.769 | 1.00 | 22.26 | A |
| ATOM | 389 | O | LEU | 44 | 24.501 | 31.109 | 14.900 | 1.00 | 25.46 | A |
| ATOM | 390 | N | THR | 45 | 23.816 | 31.290 | 12.766 | 1.00 | 22.17 | A |
| ATOM | 391 | H | THR | 45 | 23.740 | 30.874 | 11.883 | 0.00 | 0.00 | A |
| ATOM | 392 | CA | THR | 45 | 23.274 | 32.642 | 12.894 | 1.00 | 20.03 | A |
| ATOM | 393 | CB | THR | 45 | 22.585 | 33.043 | 11.588 | 1.00 | 19.37 | A |
| ATOM | 394 | OG1 | THR | 45 | 23.523 | 32.913 | 10.513 | 1.00 | 17.42 | A |
| ATOM | 395 | HG1 | THR | 45 | 24.283 | 33.476 | 10.667 | 0.00 | 0.00 | A |
| ATOM | 396 | CG2 | THR | 45 | 22.073 | 34.474 | 11.644 | 1.00 | 19.20 | A |
| ATOM | 397 | C | THR | 45 | 22.279 | 32.729 | 14.047 | 1.00 | 21.34 | A |
| ATOM | 398 | O | THR | 45 | 22.336 | 33.644 | 14.874 | 1.00 | 24.76 | A |
| ATOM | 399 | N | ASP | 46 | 21.375 | 31.765 | 14.106 | 1.00 | 21.29 | A |
| ATOM | 400 | H | ASP | 46 | 21.340 | 31.077 | 13.405 | 0.00 | 0.00 | A |
| ATOM | 401 | CA | ASP | 46 | 20.377 | 31.693 | 15.155 | 1.00 | 18.92 | A |
| ATOM | 402 | CB | ASP | 46 | 19.464 | 30.522 | 14.884 | 1.00 | 22.50 | A |
| ATOM | 403 | CG | ASP | 46 | 18.232 | 30.904 | 14.098 | 1.00 | 26.66 | A |
| ATOM | 404 | OD1 | ASP | 46 | 17.385 | 30.008 | 13.891 | 1.00 | 33.07 | A |
| ATOM | 405 | OD2 | ASP | 46 | 18.090 | 32.079 | 13.706 | 1.00 | 24.13 | A |
| ATOM | 406 | C | ASP | 46 | 20.995 | 31.490 | 16.522 | 1.00 | 20.20 | A |
| ATOM | 407 | O | ASP | 46 | 20.480 | 31.969 | 17.523 | 1.00 | 23.20 | A |
| ATOM | 408 | N | ALA | 47 | 22.051 | 30.696 | 16.581 | 1.00 | 20.43 | A |
| ATOM | 409 | H | ALA | 47 | 22.363 | 30.272 | 15.752 | 0.00 | 0.00 | A |
| ATOM | 410 | CA | ALA | 47 | 22.716 | 30.438 | 17.838 | 1.00 | 20.61 | A |
| ATOM | 411 | CB | ALA | 47 | 23.804 | 29.418 | 17.653 | 1.00 | 19.05 | A |
| ATOM | 412 | C | ALA | 47 | 23.292 | 31.735 | 18.364 | 1.00 | 22.32 | A |
| ATOM | 413 | O | ALA | 47 | 23.140 | 32.056 | 19.542 | 1.00 | 24.28 | A |
| ATOM | 414 | N | LEU | 48 | 23.931 | 32.493 | 17.477 | 1.00 | 23.95 | A |
| ATOM | 415 | H | LEU | 48 | 23.999 | 32.168 | 16.552 | 0.00 | 0.00 | A |
| ATOM | 416 | CA | LEU | 48 | 24.543 | 33.779 | 17.832 | 1.00 | 22.88 | A |
| ATOM | 417 | CB | LEU | 48 | 25.428 | 34.274 | 16.695 | 1.00 | 20.45 | A |
| ATOM | 418 | CG | LEU | 48 | 26.730 | 33.520 | 16.431 | 1.00 | 18.88 | A |
| ATOM | 419 | CD1 | LEU | 48 | 27.177 | 33.781 | 15.009 | 1.00 | 17.97 | A |
| ATOM | 420 | CD2 | LEU | 48 | 27.802 | 33.937 | 17.430 | 1.00 | 17.44 | A |
| ATOM | 421 | C | LEU | 48 | 23.488 | 34.832 | 18.180 | 1.00 | 23.71 | A |
| ATOM | 422 | O | LEU | 48 | 23.648 | 35.572 | 19.145 | 1.00 | 26.73 | A |
| ATOM | 423 | N | LEU | 49 | 22.417 | 34.913 | 17.396 | 1.00 | 23.40 | A |
| ATOM | 424 | H | LEU | 49 | 22.342 | 34.328 | 16.619 | 0.00 | 0.00 | A |
| ATOM | 425 | CA | LEU | 49 | 21.348 | 35.867 | 17.688 | 1.00 | 23.03 | A |
| ATOM | 426 | CB | LEU | 49 | 20.299 | 35.894 | 16.572 | 1.00 | 21.42 | A |
| ATOM | 427 | CG | LEU | 49 | 20.700 | 36.524 | 15.236 | 1.00 | 20.49 | A |
| ATOM | 428 | CD1 | LEU | 49 | 19.612 | 36.323 | 14.193 | 1.00 | 17.56 | A |
| ATOM | 429 | CD2 | LEU | 49 | 21.002 | 37.989 | 15.452 | 1.00 | 18.19 | A |
| ATOM | 430 | C | LEU | 49 | 20.687 | 35.451 | 18.998 | 1.00 | 23.97 | A |
| ATOM | 431 | O | LEU | 49 | 20.289 | 36.297 | 19.781 | 1.00 | 26.87 | A |
| ATOM | 432 | N | GLY | 50 | 20.567 | 34.146 | 19.224 | 1.00 | 23.94 | A |
| ATOM | 433 | H | GLY | 50 | 20.863 | 33.510 | 18.546 | 0.00 | 0.00 | A |
| ATOM | 434 | CA | GLY | 50 | 19.983 | 33.642 | 20.451 | 1.00 | 23.85 | A |
| ATOM | 435 | C | GLY | 50 | 20.790 | 34.054 | 21.675 | 1.00 | 25.64 | A |
| ATOM | 436 | O | GLY | 50 | 20.238 | 34.558 | 22.644 | 1.00 | 27.76 | A |
| ATOM | 437 | N | ALA | 51 | 22.104 | 33.872 | 21.631 | 1.00 | 25.76 | A |
| ATOM | 438 | H | ALA | 51 | 22.501 | 33.442 | 20.844 | 0.00 | 0.00 | A |
| ATOM | 439 | CA | ALA | 51 | 22.947 | 34.252 | 22.744 | 1.00 | 23.85 | A |
| ATOM | 440 | CB | ALA | 51 | 24.353 | 33.840 | 22.482 | 1.00 | 22.01 | A |
| ATOM | 441 | C | ALA | 51 | 22.879 | 35.752 | 22.997 | 1.00 | 25.21 | A |
| ATOM | 442 | O | ALA | 51 | 23.068 | 36.200 | 24.121 | 1.00 | 27.10 | A |
| ATOM | 443 | N | ALA | 52 | 22.601 | 36.526 | 21.954 | 1.00 | 25.94 | A |
| ATOM | 444 | H | ALA | 52 | 22.485 | 36.107 | 21.075 | 0.00 | 0.00 | A |
| ATOM | 445 | CA | ALA | 52 | 22.504 | 37.983 | 22.062 | 1.00 | 24.97 | A |
| ATOM | 446 | CB | ALA | 52 | 22.943 | 38.620 | 20.756 | 1.00 | 24.28 | A |
| ATOM | 447 | C | ALA | 52 | 21.107 | 38.473 | 22.411 | 1.00 | 25.16 | A |
| ATOM | 448 | O | ALA | 52 | 20.900 | 39.654 | 22.653 | 1.00 | 28.72 | A |
| ATOM | 449 | N | ALA | 53 | 20.144 | 37.569 | 22.431 | 1.00 | 25.64 | A |
| ATOM | 450 | H | ALA | 53 | 20.360 | 36.630 | 22.240 | 0.00 | 0.00 | A |
| ATOM | 451 | CA | ALA | 53 | 18.748 | 37.911 | 22.703 | 1.00 | 24.66 | A |
| ATOM | 452 | CB | ALA | 53 | 18.594 | 38.562 | 24.058 | 1.00 | 23.36 | A |
| ATOM | 453 | C | ALA | 53 | 18.223 | 38.821 | 21.600 | 1.00 | 25.17 | A |
| ATOM | 454 | O | ALA | 53 | 17.555 | 39.811 | 21.863 | 1.00 | 27.13 | A |
| ATOM | 455 | N | LEU | 54 | 18.554 | 38.484 | 20.358 | 1.00 | 24.41 | A |
| ATOM | 456 | H | LEU | 54 | 19.108 | 37.691 | 20.225 | 0.00 | 0.00 | A |
| ATOM | 457 | CA | LEU | 54 | 18.112 | 39.246 | 19.207 | 1.00 | 22.45 | A |
| ATOM | 458 | CB | LEU | 54 | 19.295 | 39.670 | 18.337 | 1.00 | 22.92 | A |
| ATOM | 459 | CG | LEU | 54 | 20.242 | 40.686 | 18.987 | 1.00 | 22.92 | A |
| ATOM | 460 | CD1 | LEU | 54 | 21.369 | 41.074 | 18.050 | 1.00 | 21.18 | A |
| ATOM | 461 | CD2 | LEU | 54 | 19.454 | 41.903 | 19.361 | 1.00 | 21.98 | A |
| ATOM | 462 | C | LEU | 54 | 17.079 | 38.467 | 18.407 | 1.00 | 22.88 | A |
| ATOM | 463 | O | LEU | 54 | 16.621 | 38.908 | 17.360 | 1.00 | 25.22 | A |
| ATOM | 464 | N | GLY | 55 | 16.694 | 37.311 | 18.913 | 1.00 | 23.76 | A |
| ATOM | 465 | H | GLY | 55 | 17.073 | 36.956 | 19.748 | 0.00 | 0.00 | A |
| ATOM | 466 | CA | GLY | 55 | 15.671 | 36.543 | 18.250 | 1.00 | 24.33 | A |
| ATOM | 467 | C | GLY | 55 | 16.143 | 35.443 | 17.356 | 1.00 | 25.99 | A |
| ATOM | 468 | O | GLY | 55 | 16.688 | 34.442 | 17.817 | 1.00 | 25.55 | A |
| ATOM | 469 | N | ASP | 56 | 15.838 | 35.597 | 16.078 | 1.00 | 28.38 | A |
| ATOM | 470 | H | ASP | 56 | 15.333 | 36.363 | 15.748 | 0.00 | 0.00 | A |
| ATOM | 471 | CA | ASP | 56 | 16.220 | 34.613 | 15.102 | 1.00 | 30.81 | A |
| ATOM | 472 | CB | ASP | 56 | 15.292 | 33.385 | 15.148 | 1.00 | 31.74 | A |
| ATOM | 473 | CG | ASP | 56 | 13.875 | 33.667 | 14.670 | 1.00 | 31.78 | A |
| ATOM | 474 | OD1 | ASP | 56 | 13.713 | 34.197 | 13.557 | 1.00 | 34.32 | A |
| ATOM | 475 | OD2 | ASP | 56 | 12.911 | 33.296 | 15.380 | 1.00 | 32.34 | A |
| ATOM | 476 | C | ASP | 56 | 16.335 | 35.199 | 13.710 | 1.00 | 31.76 | A |
| ATOM | 477 | O | ASP | 56 | 15.874 | 36.303 | 13.430 | 1.00 | 31.09 | A |
| ATOM | 478 | N | ILE | 57 | 16.965 | 34.430 | 12.843 | 1.00 | 34.20 | A |
| ATOM | 479 | H | ILE | 57 | 17.187 | 33.546 | 13.158 | 0.00 | 0.00 | A |
| ATOM | 480 | CA | ILE | 57 | 17.233 | 34.803 | 11.476 | 1.00 | 35.42 | A |
| ATOM | 481 | CB | ILE | 57 | 17.963 | 33.622 | 10.755 | 1.00 | 35.12 | A |
| ATOM | 482 | CG2 | ILE | 57 | 16.986 | 32.640 | 10.105 | 1.00 | 37.00 | A |
| ATOM | 483 | CG1 | ILE | 57 | 18.942 | 34.147 | 9.727 | 1.00 | 37.20 | A |
| ATOM | 484 | CD1 | ILE | 57 | 19.606 | 33.031 | 8.952 | 1.00 | 40.93 | A |
| ATOM | 485 | C | ILE | 57 | 15.982 | 35.298 | 10.750 | 1.00 | 36.47 | A |
| ATOM | 486 | O | ILE | 57 | 16.006 | 36.358 | 10.135 | 1.00 | 36.23 | A |
| ATOM | 487 | N | GLY | 58 | 14.864 | 34.605 | 10.926 | 1.00 | 38.21 | A |
| ATOM | 488 | H | GLY | 58 | 14.836 | 33.854 | 11.564 | 0.00 | 0.00 | A |
| ATOM | 489 | CA | GLY | 58 | 13.635 | 35.003 | 10.261 | 1.00 | 42.21 | A |
| ATOM | 490 | C | GLY | 58 | 13.031 | 36.290 | 10.788 | 1.00 | 45.59 | A |
| ATOM | 491 | O | GLY | 58 | 12.176 | 36.890 | 10.151 | 1.00 | 47.75 | A |
| ATOM | 492 | N | LYS | 59 | 13.423 | 36.689 | 11.986 | 1.00 | 49.06 | A |
| ATOM | 493 | H | LYS | 59 | 14.018 | 36.109 | 12.514 | 0.00 | 0.00 | A |
| ATOM | 494 | CA | LYS | 59 | 12.918 | 37.925 | 12.566 | 1.00 | 51.57 | A |
| ATOM | 495 | CB | LYS | 59 | 13.152 | 37.948 | 14.088 | 1.00 | 53.55 | A |
| ATOM | 496 | CG | LYS | 59 | 12.690 | 39.211 | 14.796 | 1.00 | 53.06 | A |
| ATOM | 497 | CD | LYS | 59 | 13.472 | 39.407 | 16.077 | 1.00 | 56.45 | A |
| ATOM | 498 | CE | LYS | 59 | 13.760 | 40.894 | 16.336 | 1.00 | 60.73 | A |
| ATOM | 499 | NZ | LYS | 59 | 14.826 | 41.136 | 17.375 | 1.00 | 62.05 | A |
| ATOM | 500 | HZ1 | LYS | 59 | 15.040 | 42.145 | 17.475 | 0.00 | 0.00 | A |
| ATOM | 501 | HZ2 | LYS | 59 | 15.684 | 40.607 | 17.081 | 0.00 | 0.00 | A |
| ATOM | 502 | HZ3 | LYS | 59 | 14.520 | 40.746 | 18.286 | 0.00 | 0.00 | A |
| ATOM | 503 | C | LYS | 59 | 13.674 | 39.067 | 11.910 | 1.00 | 52.54 | A |
| ATOM | 504 | O | LYS | 59 | 13.096 | 40.107 | 11.615 | 1.00 | 54.27 | A |
| ATOM | 505 | N | LEU | 60 | 14.967 | 38.865 | 11.684 | 1.00 | 52.98 | A |
| ATOM | 506 | H | LEU | 60 | 15.353 | 37.998 | 11.933 | 0.00 | 0.00 | A |
| ATOM | 507 | CA | LEU | 60 | 15.806 | 39.884 | 11.066 | 1.00 | 54.86 | A |
| ATOM | 508 | CB | LEU | 60 | 17.257 | 39.726 | 11.520 | 1.00 | 53.32 | A |
| ATOM | 509 | CG | LEU | 60 | 17.731 | 40.224 | 12.883 | 1.00 | 51.24 | A |
| ATOM | 510 | CD1 | LEU | 60 | 17.046 | 39.493 | 14.019 | 1.00 | 50.08 | A |
| ATOM | 511 | CD2 | LEU | 60 | 19.236 | 40.025 | 12.938 | 1.00 | 50.89 | A |
| ATOM | 512 | C | LEU | 60 | 15.768 | 39.917 | 9.528 | 1.00 | 57.16 | A |
| ATOM | 513 | O | LEU | 60 | 15.846 | 40.993 | 8.928 | 1.00 | 58.73 | A |
| ATOM | 514 | N | PHE | 61 | 15.679 | 38.750 | 8.895 | 1.00 | 58.80 | A |
| ATOM | 515 | H | PHE | 61 | 15.584 | 37.937 | 9.412 | 0.00 | 0.00 | A |
| ATOM | 516 | CA | PHE | 61 | 15.668 | 38.666 | 7.438 | 1.00 | 60.35 | A |
| ATOM | 517 | CB | PHE | 61 | 17.030 | 38.151 | 6.924 | 1.00 | 58.13 | A |
| ATOM | 518 | CG | PHE | 61 | 18.221 | 38.605 | 7.749 | 1.00 | 57.06 | A |
| ATOM | 519 | CD1 | PHE | 61 | 18.679 | 39.912 | 7.685 | 1.00 | 55.58 | A |
| ATOM | 520 | CD2 | PHE | 61 | 18.862 | 37.720 | 8.618 | 1.00 | 58.01 | A |
| ATOM | 521 | CE1 | PHE | 61 | 19.750 | 40.334 | 8.475 | 1.00 | 55.66 | A |
| ATOM | 522 | CE2 | PHE | 61 | 19.937 | 38.135 | 9.413 | 1.00 | 57.33 | A |
| ATOM | 523 | CZ | PHE | 61 | 20.378 | 39.444 | 9.341 | 1.00 | 56.88 | A |
| ATOM | 524 | C | PHE | 61 | 14.530 | 37.742 | 6.959 | 1.00 | 64.27 | A |
| ATOM | 525 | O | PHE | 61 | 14.750 | 36.557 | 6.687 | 1.00 | 65.95 | A |
| ATOM | 526 | N | PRO | 62 | 13.305 | 38.288 | 6.829 | 1.00 | 67.25 | A |
| ATOM | 527 | CD | PRO | 62 | 13.009 | 39.673 | 7.237 | 1.00 | 67.03 | A |
| ATOM | 528 | CA | PRO | 62 | 12.068 | 37.620 | 6.397 | 1.00 | 71.85 | A |
| ATOM | 529 | CB | PRO | 62 | 11.071 | 38.772 | 6.361 | 1.00 | 68.59 | A |
| ATOM | 530 | CG | PRO | 62 | 11.526 | 39.627 | 7.474 | 1.00 | 66.39 | A |
| ATOM | 531 | C | PRO | 62 | 12.044 | 36.839 | 5.068 | 1.00 | 78.05 | A |
| ATOM | 532 | O | PRO | 62 | 12.469 | 37.347 | 4.020 | 1.00 | 78.31 | A |
| ATOM | 533 | N | ASP | 63 | 11.462 | 35.633 | 5.122 | 1.00 | 84.71 | A |
| ATOM | 534 | H | ASP | 63 | 11.182 | 35.267 | 5.987 | 0.00 | 0.00 | A |
| ATOM | 535 | CA | ASP | 63 | 11.301 | 34.738 | 3.957 | 1.00 | 89.77 | A |
| ATOM | 536 | CB | ASP | 63 | 10.471 | 33.473 | 4.326 | 1.00 | 92.49 | A |
| ATOM | 537 | CG | ASP | 63 | 11.285 | 32.395 | 5.081 | 1.00 | 95.12 | A |
| ATOM | 538 | OD1 | ASP | 63 | 11.934 | 32.738 | 6.099 | 1.00 | 97.45 | A |
| ATOM | 539 | OD2 | ASP | 63 | 11.246 | 31.190 | 4.680 | 1.00 | 94.38 | A |
| ATOM | 540 | C | ASP | 63 | 10.539 | 35.500 | 2.875 | 1.00 | 91.43 | A |
| ATOM | 541 | O | ASP | 63 | 10.725 | 35.276 | 1.671 | 1.00 | 91.10 | A |
| ATOM | 542 | N | THR | 64 | 9.673 | 36.395 | 3.341 | 1.00 | 94.04 | A |
| ATOM | 543 | H | THR | 64 | 9.593 | 36.503 | 4.307 | 0.00 | 0.00 | A |
| ATOM | 544 | CA | THR | 64 | 8.826 | 37.226 | 2.494 | 1.00 | 97.27 | A |
| ATOM | 545 | CB | THR | 64 | 7.710 | 37.903 | 3.335 | 1.00 | 98.91 | A |
| ATOM | 546 | OG1 | THR | 64 | 8.299 | 38.787 | 4.305 | 1.00 | 100.00 | A |
| ATOM | 547 | HG1 | THR | 64 | 8.633 | 39.577 | 3.860 | 0.00 | 0.00 | A |
| ATOM | 548 | CG2 | THR | 64 | 6.867 | 36.843 | 4.061 | 1.00 | 99.40 | A |
| ATOM | 549 | C | THR | 64 | 9.577 | 38.307 | 1.707 | 1.00 | 97.49 | A |
| ATOM | 550 | O | THR | 64 | 9.227 | 38.592 | 0.555 | 1.00 | 98.15 | A |
| ATOM | 551 | N | ASP | 65 | 10.578 | 38.931 | 2.332 | 1.00 | 97.20 | A |
| ATOM | 552 | H | ASP | 65 | 10.860 | 38.658 | 3.226 | 0.00 | 0.00 | A |
| ATOM | 553 | CA | ASP | 65 | 11.341 | 39.976 | 1.659 | 1.00 | 96.71 | A |
| ATOM | 554 | CB | ASP | 65 | 12.296 | 40.670 | 2.633 | 1.00 | 95.97 | A |
| ATOM | 555 | CG | ASP | 65 | 12.826 | 42.003 | 2.103 | 1.00 | 95.73 | A |
| ATOM | 556 | OD1 | ASP | 65 | 13.415 | 42.028 | 0.995 | 1.00 | 96.11 | A |
| ATOM | 557 | OD2 | ASP | 65 | 12.666 | 43.028 | 2.805 | 1.00 | 93.74 | A |
| ATOM | 558 | C | ASP | 65 | 12.092 | 39.336 | 0.490 | 1.00 | 97.06 | A |
| ATOM | 559 | O | ASP | 65 | 12.887 | 38.396 | 0.673 | 1.00 | 95.96 | A |
| ATOM | 560 | N | PRO | 66 | 11.799 | 39.806 | −0.740 | 1.00 | 98.07 | A |
| ATOM | 561 | CD | PRO | 66 | 10.875 | 40.938 | −0.956 | 1.00 | 98.21 | A |
| ATOM | 562 | CA | PRO | 66 | 12.368 | 39.360 | −2.019 | 1.00 | 98.46 | A |
| ATOM | 563 | CB | PRO | 66 | 11.636 | 40.237 | −3.043 | 1.00 | 98.33 | A |
| ATOM | 564 | CG | PRO | 66 | 11.351 | 41.494 | −2.273 | 1.00 | 98.69 | A |
| ATOM | 565 | C | PRO | 66 | 13.893 | 39.452 | −2.164 | 1.00 | 98.62 | A |
| ATOM | 566 | O | PRO | 66 | 14.498 | 38.630 | −2.864 | 1.00 | 99.36 | A |
| ATOM | 567 | N | ALA | 67 | 14.514 | 40.426 | −1.499 | 1.00 | 97.55 | A |
| ATOM | 568 | H | ALA | 67 | 13.999 | 41.045 | −0.923 | 0.00 | 0.00 | A |
| ATOM | 569 | CA | ALA | 67 | 15.970 | 40.597 | −1.565 | 1.00 | 96.25 | A |
| ATOM | 570 | CB | ALA | 67 | 16.379 | 41.833 | −0.770 | 1.00 | 97.33 | A |
| ATOM | 571 | C | ALA | 67 | 16.707 | 39.354 | −1.032 | 1.00 | 94.65 | A |
| ATOM | 572 | O | ALA | 67 | 17.761 | 38.947 | −1.548 | 1.00 | 94.11 | A |
| ATOM | 573 | N | PHE | 68 | 16.111 | 38.740 | −0.016 | 1.00 | 91.87 | A |
| ATOM | 574 | H | PHE | 68 | 15.268 | 39.115 | 0.326 | 0.00 | 0.00 | A |
| ATOM | 575 | CA | PHE | 68 | 16.668 | 37.558 | 0.617 | 1.00 | 88.29 | A |
| ATOM | 576 | CB | PHE | 68 | 15.984 | 37.329 | 1.966 | 1.00 | 87.89 | A |
| ATOM | 577 | CG | PHE | 68 | 15.927 | 38.560 | 2.818 | 1.00 | 86.68 | A |
| ATOM | 578 | CD1 | PHE | 68 | 14.826 | 38.816 | 3.619 | 1.00 | 85.84 | A |
| ATOM | 579 | CD2 | PHE | 68 | 16.971 | 39.487 | 2.795 | 1.00 | 85.68 | A |
| ATOM | 580 | CE1 | PHE | 68 | 14.759 | 39.982 | 4.389 | 1.00 | 85.57 | A |
| ATOM | 581 | CE2 | PHE | 68 | 16.913 | 40.652 | 3.558 | 1.00 | 85.54 | A |
| ATOM | 582 | CZ | PHE | 68 | 15.802 | 40.901 | 4.358 | 1.00 | 85.10 | A |
| ATOM | 583 | C | PHE | 68 | 16.537 | 36.331 | −0.266 | 1.00 | 86.14 | A |
| ATOM | 584 | O | PHE | 68 | 16.925 | 35.235 | 0.131 | 1.00 | 86.02 | A |
| ATOM | 585 | N | LYS | 69 | 15.967 | 36.498 | −1.450 | 1.00 | 84.09 | A |
| ATOM | 586 | H | LYS | 69 | 15.702 | 37.375 | −1.796 | 0.00 | 0.00 | A |
| ATOM | 587 | CA | LYS | 69 | 15.827 | 35.371 | −2.346 | 1.00 | 83.53 | A |
| ATOM | 588 | CB | LYS | 69 | 14.643 | 35.559 | −3.291 | 1.00 | 87.26 | A |
| ATOM | 589 | CG | LYS | 69 | 14.321 | 34.311 | −4.109 | 1.00 | 92.41 | A |
| ATOM | 590 | CD | LYS | 69 | 14.616 | 34.539 | −5.590 | 1.00 | 96.71 | A |
| ATOM | 591 | CE | LYS | 69 | 14.581 | 33.245 | −6.399 | 1.00 | 98.06 | A |
| ATOM | 592 | NZ | LYS | 69 | 14.634 | 33.543 | −7.865 | 1.00 | 99.07 | A |
| ATOM | 593 | HZ1 | LYS | 69 | 14.677 | 32.663 | −8.416 | 0.00 | 0.00 | A |
| ATOM | 594 | HZ2 | LYS | 69 | 15.447 | 34.151 | −8.089 | 0.00 | 0.00 | A |
| ATOM | 595 | HZ3 | LYS | 69 | 13.758 | 34.050 | −8.116 | 0.00 | 0.00 | A |
| ATOM | 596 | C | LYS | 69 | 17.125 | 35.194 | −3.121 | 1.00 | 80.98 | A |
| ATOM | 597 | O | LYS | 69 | 17.567 | 36.099 | −3.836 | 1.00 | 80.62 | A |
| ATOM | 598 | N | GLY | 70 | 17.744 | 34.032 | −2.919 | 1.00 | 77.88 | A |
| ATOM | 599 | H | GLY | 70 | 17.436 | 33.429 | −2.251 | 0.00 | 0.00 | A |
| ATOM | 600 | CA | GLY | 70 | 18.996 | 33.679 | −3.560 | 1.00 | 72.80 | A |
| ATOM | 601 | C | GLY | 70 | 20.137 | 34.143 | −2.677 | 1.00 | 69.22 | A |
| ATOM | 602 | O | GLY | 70 | 21.296 | 33.790 | −2.914 | 1.00 | 69.66 | A |
| ATOM | 603 | N | ALA | 71 | 19.784 | 34.878 | −1.620 | 1.00 | 65.24 | A |
| ATOM | 604 | H | ALA | 71 | 18.838 | 35.043 | −1.452 | 0.00 | 0.00 | A |
| ATOM | 605 | CA | ALA | 71 | 20.739 | 35.454 | −0.673 | 1.00 | 60.96 | A |
| ATOM | 606 | CB | ALA | 71 | 20.009 | 36.114 | 0.516 | 1.00 | 59.52 | A |
| ATOM | 607 | C | ALA | 71 | 21.841 | 34.530 | −0.167 | 1.00 | 57.14 | A |
| ATOM | 608 | O | ALA | 71 | 21.619 | 33.340 | 0.115 | 1.00 | 57.38 | A |
| ATOM | 609 | N | ASP | 72 | 23.023 | 35.122 | −0.051 | 1.00 | 50.55 | A |
| ATOM | 610 | H | ASP | 72 | 23.135 | 36.078 | −0.262 | 0.00 | 0.00 | A |
| ATOM | 611 | CA | ASP | 72 | 24.221 | 34.464 | 0.419 | 1.00 | 43.22 | A |
| ATOM | 612 | CB | ASP | 72 | 25.404 | 35.272 | −0.112 | 1.00 | 41.03 | A |
| ATOM | 613 | CG | ASP | 72 | 26.706 | 34.903 | 0.508 | 1.00 | 41.59 | A |
| ATOM | 614 | OD1 | ASP | 72 | 26.821 | 34.989 | 1.735 | 1.00 | 49.23 | A |
| ATOM | 615 | OD2 | ASP | 72 | 27.665 | 34.612 | −0.227 | 1.00 | 40.90 | A |
| ATOM | 616 | C | ASP | 72 | 24.114 | 34.451 | 1.954 | 1.00 | 40.72 | A |
| ATOM | 617 | O | ASP | 72 | 24.020 | 35.504 | 2.598 | 1.00 | 41.10 | A |
| ATOM | 618 | N | SER | 73 | 24.044 | 33.252 | 2.530 | 1.00 | 35.47 | A |
| ATOM | 619 | H | SER | 73 | 24.070 | 32.455 | 1.949 | 0.00 | 0.00 | A |
| ATOM | 620 | CA | SER | 73 | 23.925 | 33.093 | 3.971 | 1.00 | 30.80 | A |
| ATOM | 621 | CB | SER | 73 | 23.717 | 31.621 | 4.343 | 1.00 | 30.50 | A |
| ATOM | 622 | OG | SER | 73 | 22.423 | 31.152 | 3.985 | 1.00 | 28.11 | A |
| ATOM | 623 | HG | SER | 73 | 22.736 | 30.385 | 3.477 | 0.00 | 0.00 | A |
| ATOM | 624 | C | SER | 73 | 25.073 | 33.694 | 4.786 | 1.00 | 29.61 | A |
| ATOM | 625 | O | SER | 73 | 24.922 | 33.926 | 5.996 | 1.00 | 31.63 | A |
| ATOM | 626 | N | ARG | 74 | 26.222 | 33.918 | 4.153 | 1.00 | 27.17 | A |
| ATOM | 627 | H | ARG | 74 | 26.306 | 33.699 | 3.196 | 0.00 | 0.00 | A |
| ATOM | 628 | CA | ARG | 74 | 27.359 | 34.522 | 4.841 | 1.00 | 26.85 | A |
| ATOM | 629 | CB | ARG | 74 | 28.659 | 34.311 | 4.081 | 1.00 | 24.22 | A |
| ATOM | 630 | CG | ARG | 74 | 29.158 | 32.881 | 4.132 | 1.00 | 24.79 | A |
| ATOM | 631 | CD | ARG | 74 | 30.501 | 32.732 | 3.436 | 1.00 | 24.19 | A |
| ATOM | 632 | NE | ARG | 74 | 31.567 | 33.450 | 4.128 | 1.00 | 29.00 | A |
| ATOM | 633 | HE | ARG | 74 | 31.382 | 33.722 | 5.052 | 0.00 | 0.00 | A |
| ATOM | 634 | CZ | ARG | 74 | 32.763 | 33.737 | 3.609 | 1.00 | 28.34 | A |
| ATOM | 635 | NH1 | ARG | 74 | 33.664 | 34.392 | 4.337 | 1.00 | 28.98 | A |
| ATOM | 636 | HH11 | ARG | 74 | 33.415 | 34.664 | 5.283 | 0.00 | 0.00 | A |
| ATOM | 637 | HH12 | ARG | 74 | 34.616 | 34.645 | 4.071 | 0.00 | 0.00 | A |
| ATOM | 638 | NH2 | ARG | 74 | 33.058 | 33.384 | 2.366 | 1.00 | 24.91 | A |
| ATOM | 639 | HH21 | ARG | 74 | 32.393 | 32.892 | 1.797 | 0.00 | 0.00 | A |
| ATOM | 640 | HH22 | ARG | 74 | 33.967 | 33.587 | 1.988 | 0.00 | 0.00 | A |
| ATOM | 641 | C | ARG | 74 | 27.083 | 35.998 | 5.008 | 1.00 | 27.70 | A |
| ATOM | 642 | O | ARG | 74 | 27.556 | 36.615 | 5.953 | 1.00 | 29.27 | A |
| ATOM | 643 | N | GLU | 75 | 26.305 | 36.569 | 4.099 | 1.00 | 29.93 | A |
| ATOM | 644 | H | GLU | 75 | 25.984 | 36.056 | 3.315 | 0.00 | 0.00 | A |
| ATOM | 645 | CA | GLU | 75 | 25.943 | 37.974 | 4.206 | 1.00 | 34.71 | A |
| ATOM | 646 | CB | GLU | 75 | 25.139 | 38.436 | 3.004 | 1.00 | 40.39 | A |
| ATOM | 647 | CG | GLU | 75 | 25.920 | 38.582 | 1.725 | 1.00 | 51.93 | A |
| ATOM | 648 | CD | GLU | 75 | 25.062 | 39.173 | 0.612 | 1.00 | 59.24 | A |
| ATOM | 649 | OE1 | GLU | 75 | 25.127 | 40.411 | 0.418 | 1.00 | 63.80 | A |
| ATOM | 650 | OE2 | GLU | 75 | 24.305 | 38.411 | −0.048 | 1.00 | 61.97 | A |
| ATOM | 651 | C | GLU | 75 | 25.080 | 38.123 | 5.447 | 1.00 | 33.71 | A |
| ATOM | 652 | O | GLU | 75 | 25.310 | 39.001 | 6.272 | 1.00 | 34.50 | A |
| ATOM | 653 | N | LEU | 76 | 24.076 | 37.263 | 5.566 | 1.00 | 32.65 | A |
| ATOM | 654 | H | LEU | 76 | 23.946 | 36.620 | 4.835 | 0.00 | 0.00 | A |
| ATOM | 655 | CA | LEU | 76 | 23.184 | 37.275 | 6.718 | 1.00 | 30.01 | A |
| ATOM | 656 | CB | LEU | 76 | 22.111 | 36.214 | 6.558 | 1.00 | 31.68 | A |
| ATOM | 657 | CG | LEU | 76 | 21.278 | 36.476 | 5.306 | 1.00 | 34.28 | A |
| ATOM | 658 | CD1 | LEU | 76 | 20.375 | 35.301 | 5.034 | 1.00 | 36.19 | A |
| ATOM | 659 | CD2 | LEU | 76 | 20.473 | 37.761 | 5.480 | 1.00 | 33.07 | A |
| ATOM | 660 | C | LEU | 76 | 23.980 | 37.005 | 7.972 | 1.00 | 29.19 | A |
| ATOM | 661 | O | LEU | 76 | 23.727 | 37.613 | 9.005 | 1.00 | 30.32 | A |
| ATOM | 662 | N | LEU | 77 | 24.942 | 36.094 | 7.884 | 1.00 | 26.48 | A |
| ATOM | 663 | H | LEU | 77 | 25.088 | 35.603 | 7.050 | 0.00 | 0.00 | A |
| ATOM | 664 | CA | LEU | 77 | 25.768 | 35.786 | 9.033 | 1.00 | 26.35 | A |
| ATOM | 665 | CB | LEU | 77 | 26.741 | 34.655 | 8.719 | 1.00 | 24.86 | A |
| ATOM | 666 | CG | LEU | 77 | 27.776 | 34.373 | 9.809 | 1.00 | 24.21 | A |
| ATOM | 667 | CD1 | LEU | 77 | 27.080 | 34.006 | 11.100 | 1.00 | 22.81 | A |
| ATOM | 668 | CD2 | LEU | 77 | 28.699 | 33.257 | 9.358 | 1.00 | 22.96 | A |
| ATOM | 669 | C | LEU | 77 | 26.530 | 37.022 | 9.491 | 1.00 | 28.22 | A |
| ATOM | 670 | O | LEU | 77 | 26.507 | 37.371 | 10.674 | 1.00 | 30.70 | A |
| ATOM | 671 | N | ARG | 78 | 27.180 | 37.704 | 8.556 | 1.00 | 29.03 | A |
| ATOM | 672 | H | ARG | 78 | 27.157 | 37.389 | 7.632 | 0.00 | 0.00 | A |
| ATOM | 673 | CA | ARG | 78 | 27.952 | 38.899 | 8.889 | 1.00 | 30.08 | A |
| ATOM | 674 | CB | ARG | 78 | 28.786 | 39.341 | 7.694 | 1.00 | 28.69 | A |
| ATOM | 675 | CG | ARG | 78 | 29.811 | 38.342 | 7.266 | 1.00 | 29.53 | A |
| ATOM | 676 | CD | ARG | 78 | 30.625 | 38.883 | 6.107 | 1.00 | 32.27 | A |
| ATOM | 677 | NE | ARG | 78 | 30.673 | 37.930 | 5.002 | 1.00 | 37.71 | A |
| ATOM | 678 | HE | ARG | 78 | 31.177 | 37.102 | 5.227 | 0.00 | 0.00 | A |
| ATOM | 679 | CZ | ARG | 78 | 30.057 | 38.116 | 3.843 | 1.00 | 36.77 | A |
| ATOM | 680 | NH1 | ARG | 78 | 30.135 | 37.196 | 2.879 | 1.00 | 40.40 | A |
| ATOM | 681 | HH11 | ARG | 78 | 30.628 | 36.343 | 3.056 | 0.00 | 0.00 | A |
| ATOM | 682 | HH12 | ARG | 78 | 29.646 | 37.265 | 1.998 | 0.00 | 0.00 | A |
| ATOM | 683 | NH2 | ARG | 78 | 29.368 | 39.236 | 3.654 | 1.00 | 39.81 | A |
| ATOM | 684 | HH21 | ARG | 78 | 29.313 | 39.916 | 4.388 | 0.00 | 0.00 | A |
| ATOM | 685 | HH22 | ARG | 78 | 28.853 | 39.425 | 2.810 | 0.00 | 0.00 | A |
| ATOM | 686 | C | ARG | 78 | 27.124 | 40.078 | 9.422 | 1.00 | 30.55 | A |
| ATOM | 687 | O | ARG | 78 | 27.597 | 40.828 | 10.279 | 1.00 | 32.08 | A |
| ATOM | 688 | N | GLU | 79 | 25.915 | 40.251 | 8.892 | 1.00 | 30.50 | A |
| ATOM | 689 | H | GLU | 79 | 25.625 | 39.654 | 8.170 | 0.00 | 0.00 | A |
| ATOM | 690 | CA | GLU | 79 | 24.997 | 41.308 | 9.314 | 1.00 | 31.51 | A |
| ATOM | 691 | CB | GLU | 79 | 23.809 | 41.371 | 8.357 | 1.00 | 31.48 | A |
| ATOM | 692 | CG | GLU | 79 | 22.676 | 42.293 | 8.790 | 1.00 | 38.50 | A |
| ATOM | 693 | CD | GLU | 79 | 23.081 | 43.758 | 8.952 | 1.00 | 41.47 | A |
| ATOM | 694 | OE1 | GLU | 79 | 24.278 | 44.120 | 8.855 | 1.00 | 42.30 | A |
| ATOM | 695 | OE2 | GLU | 79 | 22.170 | 44.570 | 9.195 | 1.00 | 44.86 | A |
| ATOM | 696 | C | GLU | 79 | 24.511 | 41.055 | 10.744 | 1.00 | 32.98 | A |
| ATOM | 697 | O | GLU | 79 | 24.546 | 41.945 | 11.606 | 1.00 | 35.69 | A |
| ATOM | 698 | N | ALA | 80 | 24.045 | 39.835 | 10.987 | 1.00 | 32.61 | A |
| ATOM | 699 | H | ALA | 80 | 23.999 | 39.195 | 10.245 | 0.00 | 0.00 | A |
| ATOM | 700 | CA | ALA | 80 | 23.593 | 39.436 | 12.302 | 1.00 | 29.35 | A |
| ATOM | 701 | CB | ALA | 80 | 23.200 | 37.992 | 12.282 | 1.00 | 29.90 | A |
| ATOM | 702 | C | ALA | 80 | 24.759 | 39.645 | 13.251 | 1.00 | 28.52 | A |
| ATOM | 703 | O | ALA | 80 | 24.584 | 40.122 | 14.364 | 1.00 | 30.69 | A |
| ATOM | 704 | N | TRP | 81 | 25.964 | 39.339 | 12.791 | 1.00 | 27.54 | A |
| ATOM | 705 | H | TRP | 81 | 26.062 | 38.968 | 11.889 | 0.00 | 0.00 | A |
| ATOM | 706 | CA | TRP | 81 | 27.145 | 39.509 | 13.628 | 1.00 | 27.55 | A |
| ATOM | 707 | CB | TRP | 81 | 28.354 | 38.824 | 12.992 | 1.00 | 23.66 | A |
| ATOM | 708 | CG | TRP | 81 | 29.589 | 38.895 | 13.817 | 1.00 | 21.43 | A |
| ATOM | 709 | CD2 | TRP | 81 | 29.732 | 38.529 | 15.201 | 1.00 | 21.82 | A |
| ATOM | 710 | CE2 | TRP | 81 | 31.057 | 38.827 | 15.577 | 1.00 | 19.80 | A |
| ATOM | 711 | CE3 | TRP | 81 | 28.864 | 37.987 | 16.162 | 1.00 | 23.43 | A |
| ATOM | 712 | CD1 | TRP | 81 | 30.793 | 39.369 | 13.424 | 1.00 | 19.21 | A |
| ATOM | 713 | NE1 | TRP | 81 | 31.686 | 39.337 | 14.473 | 1.00 | 20.15 | A |
| ATOM | 714 | HE1 | TRP | 81 | 32.634 | 39.598 | 14.442 | 0.00 | 0.00 | A |
| ATOM | 715 | CZ2 | TRP | 81 | 31.538 | 38.607 | 16.867 | 1.00 | 19.88 | A |
| ATOM | 716 | CZ3 | TRP | 81 | 29.341 | 37.767 | 17.442 | 1.00 | 21.26 | A |
| ATOM | 717 | CH2 | TRP | 81 | 30.667 | 38.079 | 17.783 | 1.00 | 22.83 | A |
| ATOM | 718 | C | TRP | 81 | 27.424 | 40.992 | 13.871 | 1.00 | 30.66 | A |
| ATOM | 719 | O | TRP | 81 | 27.822 | 41.392 | 14.964 | 1.00 | 32.92 | A |
| ATOM | 720 | N | ARG | 82 | 27.196 | 41.815 | 12.860 | 1.00 | 33.90 | A |
| ATOM | 721 | H | ARG | 82 | 26.883 | 41.461 | 12.001 | 0.00 | 0.00 | A |
| ATOM | 722 | CA | ARG | 82 | 27.419 | 43.240 | 13.006 | 1.00 | 36.25 | A |
| ATOM | 723 | CB | ARG | 82 | 27.073 | 43.982 | 11.724 | 1.00 | 38.07 | A |
| ATOM | 724 | CG | ARG | 82 | 27.250 | 45.488 | 11.849 | 1.00 | 46.41 | A |
| ATOM | 725 | CD | ARG | 82 | 26.746 | 46.253 | 10.610 | 1.00 | 51.17 | A |
| ATOM | 726 | NE | ARG | 82 | 25.299 | 46.145 | 10.417 | 1.00 | 52.84 | A |
| ATOM | 727 | HE | ARG | 82 | 25.026 | 45.622 | 9.630 | 0.00 | 0.00 | A |
| ATOM | 728 | CZ | ARG | 82 | 24.391 | 46.704 | 11.209 | 1.00 | 51.83 | A |
| ATOM | 729 | NH1 | ARG | 82 | 23.103 | 46.537 | 10.948 | 1.00 | 53.02 | A |
| ATOM | 730 | HH11 | ARG | 82 | 22.876 | 45.966 | 10.134 | 0.00 | 0.00 | A |
| ATOM | 731 | HH12 | ARG | 82 | 22.347 | 46.916 | 11.473 | 0.00 | 0.00 | A |
| ATOM | 732 | NH2 | ARG | 82 | 24.775 | 47.430 | 12.256 | 1.00 | 51.39 | A |
| ATOM | 733 | HH21 | ARG | 82 | 25.754 | 47.546 | 12.440 | 0.00 | 0.00 | A |
| ATOM | 734 | HH22 | ARG | 82 | 24.130 | 47.871 | 12.881 | 0.00 | 0.00 | A |
| ATOM | 735 | C | ARG | 82 | 26.524 | 43.744 | 14.116 | 1.00 | 37.68 | A |
| ATOM | 736 | O | ARG | 82 | 26.991 | 44.380 | 15.062 | 1.00 | 38.74 | A |
| ATOM | 737 | N | ARG | 83 | 25.237 | 43.438 | 13.996 | 1.00 | 38.30 | A |
| ATOM | 738 | H | ARG | 83 | 24.967 | 42.895 | 13.224 | 0.00 | 0.00 | A |
| ATOM | 739 | CA | ARG | 83 | 24.240 | 43.855 | 14.974 | 1.00 | 39.69 | A |
| ATOM | 740 | CB | ARG | 83 | 22.855 | 43.416 | 14.524 | 1.00 | 39.56 | A |
| ATOM | 741 | CG | ARG | 83 | 22.560 | 43.792 | 13.112 | 1.00 | 42.74 | A |
| ATOM | 742 | CD | ARG | 83 | 21.087 | 43.856 | 12.886 | 1.00 | 48.69 | A |
| ATOM | 743 | NE | ARG | 83 | 20.815 | 43.962 | 11.463 | 1.00 | 55.50 | A |
| ATOM | 744 | HE | ARG | 83 | 21.615 | 44.053 | 10.904 | 0.00 | 0.00 | A |
| ATOM | 745 | CZ | ARG | 83 | 19.608 | 43.863 | 10.910 | 1.00 | 59.49 | A |
| ATOM | 746 | NH1 | ARG | 83 | 19.477 | 43.965 | 9.587 | 1.00 | 62.56 | A |
| ATOM | 747 | HH11 | ARG | 83 | 20.332 | 44.106 | 9.051 | 0.00 | 0.00 | A |
| ATOM | 748 | HH12 | ARG | 83 | 18.621 | 43.893 | 9.074 | 0.00 | 0.00 | A |
| ATOM | 749 | NH2 | ARG | 83 | 18.536 | 43.663 | 11.674 | 1.00 | 61.55 | A |
| ATOM | 750 | HH21 | ARG | 83 | 18.637 | 43.583 | 12.667 | 0.00 | 0.00 | A |
| ATOM | 751 | HH22 | ARG | 83 | 17.612 | 43.574 | 11.291 | 0.00 | 0.00 | A |
| ATOM | 752 | C | ARG | 83 | 24.514 | 43.329 | 16.381 | 1.00 | 40.72 | A |
| ATOM | 753 | O | ARG | 83 | 24.254 | 44.023 | 17.374 | 1.00 | 43.07 | A |
| ATOM | 754 | N | ILE | 84 | 25.028 | 42.103 | 16.463 | 1.00 | 39.42 | A |
| ATOM | 755 | H | ILE | 84 | 25.181 | 41.597 | 15.638 | 0.00 | 0.00 | A |
| ATOM | 756 | CA | ILE | 84 | 25.340 | 41.482 | 17.745 | 1.00 | 36.11 | A |
| ATOM | 757 | CB | ILE | 84 | 25.723 | 39.984 | 17.560 | 1.00 | 35.31 | A |
| ATOM | 758 | CG2 | ILE | 84 | 26.336 | 39.421 | 18.829 | 1.00 | 31.56 | A |
| ATOM | 759 | CG1 | ILE | 84 | 24.486 | 39.174 | 17.148 | 1.00 | 33.07 | A |
| ATOM | 760 | CD1 | ILE | 84 | 24.805 | 37.806 | 16.667 | 1.00 | 29.11 | A |
| ATOM | 761 | C | ILE | 84 | 26.468 | 42.244 | 18.416 | 1.00 | 34.96 | A |
| ATOM | 762 | O | ILE | 84 | 26.383 | 42.588 | 19.587 | 1.00 | 35.82 | A |
| ATOM | 763 | N | GLN | 85 | 27.512 | 42.530 | 17.658 | 1.00 | 34.93 | A |
| ATOM | 764 | H | GLN | 85 | 27.516 | 42.242 | 16.721 | 0.00 | 0.00 | A |
| ATOM | 765 | CA | GLN | 85 | 28.649 | 43.259 | 18.183 | 1.00 | 37.08 | A |
| ATOM | 766 | CB | GLN | 85 | 29.717 | 43.377 | 17.122 | 1.00 | 37.99 | A |
| ATOM | 767 | CG | GLN | 85 | 30.289 | 42.067 | 16.714 | 1.00 | 44.09 | A |
| ATOM | 768 | CD | GLN | 85 | 31.515 | 42.230 | 15.847 | 1.00 | 48.13 | A |
| ATOM | 769 | OE1 | GLN | 85 | 32.650 | 42.199 | 16.337 | 1.00 | 50.17 | A |
| ATOM | 770 | NE2 | GLN | 85 | 31.299 | 42.406 | 14.544 | 1.00 | 52.16 | A |
| ATOM | 771 | HE21 | GLN | 85 | 30.374 | 42.411 | 14.226 | 0.00 | 0.00 | A |
| ATOM | 772 | HE22 | GLN | 85 | 32.088 | 42.512 | 13.980 | 0.00 | 0.00 | A |
| ATOM | 773 | C | GLN | 85 | 28.267 | 44.652 | 18.642 | 1.00 | 37.32 | A |
| ATOM | 774 | O | GLN | 85 | 28.811 | 45.159 | 19.623 | 1.00 | 38.04 | A |
| ATOM | 775 | N | ALA | 86 | 27.354 | 45.276 | 17.906 | 1.00 | 37.76 | A |
| ATOM | 776 | H | ALA | 86 | 26.998 | 44.819 | 17.114 | 0.00 | 0.00 | A |
| ATOM | 777 | CA | ALA | 86 | 26.883 | 46.622 | 18.226 | 1.00 | 38.61 | A |
| ATOM | 778 | CB | ALA | 86 | 25.998 | 47.157 | 17.130 | 1.00 | 36.51 | A |
| ATOM | 779 | C | ALA | 86 | 26.131 | 46.633 | 19.535 | 1.00 | 40.74 | A |
| ATOM | 780 | O | ALA | 86 | 26.097 | 47.654 | 20.215 | 1.00 | 45.10 | A |
| ATOM | 781 | N | LYS | 87 | 25.502 | 45.509 | 19.869 | 1.00 | 41.30 | A |
| ATOM | 782 | H | LYS | 87 | 25.518 | 44.747 | 19.251 | 0.00 | 0.00 | A |
| ATOM | 783 | CA | LYS | 87 | 24.763 | 45.368 | 21.118 | 1.00 | 39.49 | A |
| ATOM | 784 | CB | LYS | 87 | 23.803 | 44.175 | 21.016 | 1.00 | 41.52 | A |
| ATOM | 785 | CG | LYS | 87 | 22.808 | 44.041 | 22.158 | 1.00 | 46.73 | A |
| ATOM | 786 | CD | LYS | 87 | 21.831 | 42.883 | 21.920 | 1.00 | 50.18 | A |
| ATOM | 787 | CE | LYS | 87 | 20.751 | 42.793 | 23.017 | 1.00 | 52.39 | A |
| ATOM | 788 | NZ | LYS | 87 | 21.055 | 41.845 | 24.144 | 1.00 | 53.96 | A |
| ATOM | 789 | HZ1 | LYS | 87 | 20.286 | 41.893 | 24.863 | 0.00 | 0.00 | A |
| ATOM | 790 | HZ2 | LYS | 87 | 21.948 | 41.993 | 24.647 | 0.00 | 0.00 | A |
| ATOM | 791 | HZ3 | LYS | 87 | 21.058 | 40.873 | 23.796 | 0.00 | 0.00 | A |
| ATOM | 792 | C | LYS | 87 | 25.783 | 45.175 | 22.256 | 1.00 | 38.16 | A |
| ATOM | 793 | O | LYS | 87 | 25.417 | 44.955 | 23.409 | 1.00 | 39.13 | A |
| ATOM | 794 | N | GLY | 88 | 27.067 | 45.229 | 21.915 | 1.00 | 36.46 | A |
| ATOM | 795 | H | GLY | 88 | 27.358 | 45.346 | 20.994 | 0.00 | 0.00 | A |
| ATOM | 796 | CA | GLY | 88 | 28.115 | 45.090 | 22.905 | 1.00 | 35.83 | A |
| ATOM | 797 | C | GLY | 88 | 28.756 | 43.724 | 23.067 | 1.00 | 37.88 | A |
| ATOM | 798 | O | GLY | 88 | 29.625 | 43.563 | 23.925 | 1.00 | 41.41 | A |
| ATOM | 799 | N | TYR | 89 | 28.414 | 42.755 | 22.225 | 1.00 | 36.71 | A |
| ATOM | 800 | H | TYR | 89 | 27.803 | 42.938 | 21.483 | 0.00 | 0.00 | A |
| ATOM | 801 | CA | TYR | 89 | 28.987 | 41.424 | 22.384 | 1.00 | 33.86 | A |
| ATOM | 802 | CB | TYR | 89 | 27.947 | 40.345 | 22.080 | 1.00 | 32.76 | A |
| ATOM | 803 | CG | TYR | 89 | 26.680 | 40.445 | 22.900 | 1.00 | 30.78 | A |
| ATOM | 804 | CD1 | TYR | 89 | 25.590 | 41.178 | 22.437 | 1.00 | 31.22 | A |
| ATOM | 805 | CE1 | TYR | 89 | 24.412 | 41.259 | 23.170 | 1.00 | 32.54 | A |
| ATOM | 806 | CD2 | TYR | 89 | 26.562 | 39.795 | 24.122 | 1.00 | 28.22 | A |
| ATOM | 807 | CE2 | TYR | 89 | 25.385 | 39.868 | 24.865 | 1.00 | 29.98 | A |
| ATOM | 808 | CZ | TYR | 89 | 24.314 | 40.602 | 24.381 | 1.00 | 32.24 | A |
| ATOM | 809 | OH | TYR | 89 | 23.133 | 40.690 | 25.093 | 1.00 | 35.47 | A |
| ATOM | 810 | HH | TYR | 89 | 23.233 | 40.234 | 25.939 | 0.00 | 0.00 | A |
| ATOM | 811 | C | TYR | 89 | 30.236 | 41.141 | 21.577 | 1.00 | 34.63 | A |
| ATOM | 812 | O | TYR | 89 | 30.504 | 41.781 | 20.559 | 1.00 | 34.31 | A |
| ATOM | 813 | N | THR | 90 | 30.992 | 40.162 | 22.066 | 1.00 | 35.65 | A |
| ATOM | 814 | H | THR | 90 | 30.725 | 39.726 | 22.905 | 0.00 | 0.00 | A |
| ATOM | 815 | CA | THR | 90 | 32.215 | 39.678 | 21.440 | 1.00 | 36.21 | A |
| ATOM | 816 | CB | THR | 90 | 33.474 | 40.104 | 22.215 | 1.00 | 38.32 | A |
| ATOM | 817 | OG1 | THR | 90 | 33.256 | 39.956 | 23.623 | 1.00 | 43.37 | A |
| ATOM | 818 | HG1 | THR | 90 | 32.557 | 40.563 | 23.898 | 0.00 | 0.00 | A |
| ATOM | 819 | CG2 | THR | 90 | 33.822 | 41.538 | 21.913 | 1.00 | 40.08 | A |
| ATOM | 820 | C | THR | 90 | 32.117 | 38.151 | 21.437 | 1.00 | 35.13 | A |
| ATOM | 821 | O | THR | 90 | 31.490 | 37.560 | 22.321 | 1.00 | 35.43 | A |
| ATOM | 822 | N | LEU | 91 | 32.732 | 37.516 | 20.449 | 1.00 | 32.16 | A |
| ATOM | 823 | H | LEU | 91 | 33.251 | 38.023 | 19.793 | 0.00 | 0.00 | A |
| ATOM | 824 | CA | LEU | 91 | 32.671 | 36.071 | 20.336 | 1.00 | 29.30 | A |
| ATOM | 825 | CB | LEU | 91 | 33.137 | 35.627 | 18.950 | 1.00 | 24.67 | A |
| ATOM | 826 | CG | LEU | 91 | 32.912 | 34.167 | 18.587 | 1.00 | 19.85 | A |
| ATOM | 827 | CD1 | LEU | 91 | 31.430 | 33.932 | 18.372 | 1.00 | 20.06 | A |
| ATOM | 828 | CD2 | LEU | 91 | 33.670 | 33.834 | 17.337 | 1.00 | 19.42 | A |
| ATOM | 829 | C | LEU | 91 | 33.464 | 35.320 | 21.392 | 1.00 | 31.02 | A |
| ATOM | 830 | O | LEU | 91 | 34.570 | 35.713 | 21.751 | 1.00 | 34.13 | A |
| ATOM | 831 | N | GLY | 92 | 32.852 | 34.266 | 21.922 | 1.00 | 32.12 | A |
| ATOM | 832 | H | GLY | 92 | 31.929 | 34.073 | 21.663 | 0.00 | 0.00 | A |
| ATOM | 833 | CA | GLY | 92 | 33.503 | 33.399 | 22.886 | 1.00 | 29.30 | A |
| ATOM | 834 | C | GLY | 92 | 33.963 | 32.257 | 21.998 | 1.00 | 29.48 | A |
| ATOM | 835 | O | GLY | 92 | 35.149 | 32.107 | 21.750 | 1.00 | 31.23 | A |
| ATOM | 836 | N | ASN | 93 | 33.005 | 31.498 | 21.467 | 1.00 | 26.68 | A |
| ATOM | 837 | H | ASN | 93 | 32.067 | 31.695 | 21.680 | 0.00 | 0.00 | A |
| ATOM | 838 | CA | ASN | 93 | 33.275 | 30.395 | 20.554 | 1.00 | 22.70 | A |
| ATOM | 839 | CB | ASN | 93 | 34.159 | 29.321 | 21.190 | 1.00 | 23.08 | A |
| ATOM | 840 | CG | ASN | 93 | 33.398 | 28.376 | 22.091 | 1.00 | 23.73 | A |
| ATOM | 841 | OD1 | ASN | 93 | 33.334 | 27.172 | 21.841 | 1.00 | 20.09 | A |
| ATOM | 842 | ND2 | ASN | 93 | 32.871 | 28.903 | 23.178 | 1.00 | 27.74 | A |
| ATOM | 843 | HD21 | ASN | 93 | 33.045 | 29.852 | 23.344 | 0.00 | 0.00 | A |
| ATOM | 844 | HD22 | ASN | 93 | 32.318 | 28.349 | 23.752 | 0.00 | 0.00 | A |
| ATOM | 845 | C | ASN | 93 | 31.968 | 29.797 | 20.075 | 1.00 | 22.39 | A |
| ATOM | 846 | O | ASN | 93 | 30.923 | 30.005 | 20.688 | 1.00 | 22.79 | A |
| ATOM | 847 | N | VAL | 94 | 32.019 | 29.136 | 18.923 | 1.00 | 22.36 | A |
| ATOM | 848 | H | VAL | 94 | 32.876 | 29.047 | 18.449 | 0.00 | 0.00 | A |
| ATOM | 849 | CA | VAL | 94 | 30.852 | 28.481 | 18.335 | 1.00 | 20.54 | A |
| ATOM | 850 | CB | VAL | 94 | 30.360 | 29.221 | 17.058 | 1.00 | 21.42 | A |
| ATOM | 851 | CG1 | VAL | 94 | 30.250 | 30.708 | 17.327 | 1.00 | 19.83 | A |
| ATOM | 852 | CG2 | VAL | 94 | 31.276 | 28.946 | 15.874 | 1.00 | 19.15 | A |
| ATOM | 853 | C | VAL | 94 | 31.209 | 27.027 | 17.976 | 1.00 | 19.33 | A |
| ATOM | 854 | O | VAL | 94 | 32.380 | 26.718 | 17.714 | 1.00 | 17.95 | A |
| ATOM | 855 | N | ASP | 95 | 30.213 | 26.139 | 18.048 | 1.00 | 19.88 | A |
| ATOM | 856 | H | ASP | 95 | 29.324 | 26.428 | 18.340 | 0.00 | 0.00 | A |
| ATOM | 857 | CA | ASP | 95 | 30.364 | 24.719 | 17.710 | 1.00 | 17.64 | A |
| ATOM | 858 | CB | ASP | 95 | 30.434 | 23.852 | 18.971 | 1.00 | 18.08 | A |
| ATOM | 859 | CG | ASP | 95 | 30.775 | 22.391 | 18.667 | 1.00 | 21.66 | A |
| ATOM | 860 | OD1 | ASP | 95 | 30.501 | 21.505 | 19.503 | 1.00 | 20.28 | A |
| ATOM | 861 | OD2 | ASP | 95 | 31.316 | 22.095 | 17.583 | 1.00 | 23.59 | A |
| ATOM | 862 | C | ASP | 95 | 29.137 | 24.346 | 16.872 | 1.00 | 18.51 | A |
| ATOM | 863 | O | ASP | 95 | 27.989 | 24.653 | 17.253 | 1.00 | 19.45 | A |
| ATOM | 864 | N | VAL | 96 | 29.390 | 23.751 | 15.706 | 1.00 | 16.90 | A |
| ATOM | 865 | H | VAL | 96 | 30.329 | 23.565 | 15.491 | 0.00 | 0.00 | A |
| ATOM | 866 | CA | VAL | 96 | 28.340 | 23.352 | 14.764 | 1.00 | 15.26 | A |
| ATOM | 867 | CB | VAL | 96 | 28.555 | 24.077 | 13.397 | 1.00 | 15.51 | A |
| ATOM | 868 | CG1 | VAL | 96 | 27.454 | 23.755 | 12.414 | 1.00 | 14.44 | A |
| ATOM | 869 | CG2 | VAL | 96 | 28.640 | 25.577 | 13.608 | 1.00 | 13.94 | A |
| ATOM | 870 | C | VAL | 96 | 28.327 | 21.828 | 14.558 | 1.00 | 15.23 | A |
| ATOM | 871 | O | VAL | 96 | 29.381 | 21.188 | 14.573 | 1.00 | 17.35 | A |
| ATOM | 872 | N | THR | 97 | 27.139 | 21.238 | 14.442 | 1.00 | 13.28 | A |
| ATOM | 873 | H | THR | 97 | 26.327 | 21.780 | 14.481 | 0.00 | 0.00 | A |
| ATOM | 874 | CA | THR | 97 | 26.999 | 19.804 | 14.214 | 1.00 | 14.82 | A |
| ATOM | 875 | CB | THR | 97 | 26.368 | 19.108 | 15.407 | 1.00 | 15.83 | A |
| ATOM | 876 | OG1 | THR | 97 | 27.037 | 19.524 | 16.606 | 1.00 | 19.29 | A |
| ATOM | 877 | HG1 | THR | 97 | 27.951 | 19.340 | 16.386 | 0.00 | 0.00 | A |
| ATOM | 878 | CG2 | THR | 97 | 26.473 | 17.596 | 15.252 | 1.00 | 10.00 | A |
| ATOM | 879 | C | THR | 97 | 26.064 | 19.611 | 13.025 | 1.00 | 18.72 | A |
| ATOM | 880 | O | THR | 97 | 24.876 | 19.923 | 13.122 | 1.00 | 21.12 | A |
| ATOM | 881 | N | ILE | 98 | 26.610 | 19.183 | 11.887 | 1.00 | 19.48 | A |
| ATOM | 882 | H | ILE | 98 | 27.567 | 19.001 | 11.854 | 0.00 | 0.00 | A |
| ATOM | 883 | CA | ILE | 98 | 25.826 | 18.947 | 10.671 | 1.00 | 19.61 | A |
| ATOM | 884 | CB | ILE | 98 | 26.697 | 19.095 | 9.393 | 1.00 | 21.12 | A |
| ATOM | 885 | CG2 | ILE | 98 | 25.866 | 18.850 | 8.132 | 1.00 | 17.76 | A |
| ATOM | 886 | CG1 | ILE | 98 | 27.334 | 20.481 | 9.347 | 1.00 | 20.52 | A |
| ATOM | 887 | CD1 | ILE | 98 | 28.494 | 20.560 | 8.415 | 1.00 | 21.17 | A |
| ATOM | 888 | C | ILE | 98 | 25.304 | 17.518 | 10.728 | 1.00 | 21.13 | A |
| ATOM | 889 | O | ILE | 98 | 26.075 | 16.569 | 10.918 | 1.00 | 25.78 | A |
| ATOM | 890 | N | ILE | 99 | 23.998 | 17.357 | 10.605 | 1.00 | 20.00 | A |
| ATOM | 891 | H | ILE | 99 | 23.415 | 18.126 | 10.433 | 0.00 | 0.00 | A |
| ATOM | 892 | CA | ILE | 99 | 23.407 | 16.030 | 10.656 | 1.00 | 18.35 | A |
| ATOM | 893 | CB | ILE | 99 | 22.187 | 16.010 | 11.601 | 1.00 | 15.90 | A |
| ATOM | 894 | CG2 | ILE | 99 | 21.607 | 14.630 | 11.685 | 1.00 | 12.68 | A |
| ATOM | 895 | CG1 | ILE | 99 | 22.608 | 16.466 | 13.001 | 1.00 | 11.79 | A |
| ATOM | 896 | CD1 | ILE | 99 | 21.565 | 17.244 | 13.702 | 1.00 | 8.20 | A |
| ATOM | 897 | C | ILE | 99 | 23.004 | 15.713 | 9.232 | 1.00 | 19.98 | A |
| ATOM | 898 | O | ILE | 99 | 22.048 | 16.277 | 8.717 | 1.00 | 22.37 | A |
| ATOM | 899 | N | ALA | 100 | 23.796 | 14.880 | 8.570 | 1.00 | 21.78 | A |
| ATOM | 900 | H | ALA | 100 | 24.586 | 14.505 | 9.020 | 0.00 | 0.00 | A |
| ATOM | 901 | CA | ALA | 100 | 23.537 | 14.491 | 7.196 | 1.00 | 21.76 | A |
| ATOM | 902 | CB | ALA | 100 | 24.141 | 15.497 | 6.259 | 1.00 | 21.29 | A |
| ATOM | 903 | C | ALA | 100 | 24.118 | 13.111 | 6.920 | 1.00 | 24.41 | A |
| ATOM | 904 | O | ALA | 100 | 25.221 | 12.778 | 7.368 | 1.00 | 25.86 | A |
| ATOM | 905 | N | GLN | 101 | 23.338 | 12.297 | 6.219 | 1.00 | 23.45 | A |
| ATOM | 906 | H | GLN | 101 | 22.466 | 12.642 | 5.933 | 0.00 | 0.00 | A |
| ATOM | 907 | CA | GLN | 101 | 23.730 | 10.944 | 5.839 | 1.00 | 22.22 | A |
| ATOM | 908 | CB | GLN | 101 | 22.506 | 10.214 | 5.269 | 1.00 | 22.24 | A |
| ATOM | 909 | CG | GLN | 101 | 22.652 | 8.718 | 5.115 | 1.00 | 22.85 | A |
| ATOM | 910 | CD | GLN | 101 | 22.866 | 8.015 | 6.441 | 1.00 | 23.88 | A |
| ATOM | 911 | OE1 | GLN | 101 | 23.586 | 7.024 | 6.514 | 1.00 | 27.80 | A |
| ATOM | 912 | NE2 | GLN | 101 | 22.229 | 8.514 | 7.493 | 1.00 | 24.00 | A |
| ATOM | 913 | HE21 | GLN | 101 | 21.610 | 9.265 | 7.372 | 0.00 | 0.00 | A |
| ATOM | 914 | HE22 | GLN | 101 | 22.455 | 6.092 | 8.342 | 0.00 | 0.00 | A |
| ATOM | 915 | C | GLN | 101 | 24.793 | 11.065 | 4.754 | 1.00 | 21.36 | A |
| ATOM | 916 | O | GLN | 101 | 25.688 | 10.237 | 4.620 | 1.00 | 22.39 | A |
| ATOM | 917 | N | ALA | 102 | 24.648 | 12.098 | 3.946 | 1.00 | 21.14 | A |
| ATOM | 918 | H | ALA | 102 | 23.904 | 12.728 | 4.054 | 0.00 | 0.00 | A |
| ATOM | 919 | CA | ALA | 102 | 25.563 | 12.372 | 2.855 | 1.00 | 21.10 | A |
| ATOM | 920 | CB | ALA | 102 | 25.403 | 11.326 | 1.769 | 1.00 | 16.60 | A |
| ATOM | 921 | C | ALA | 102 | 25.150 | 13.742 | 2.345 | 1.00 | 21.35 | A |
| ATOM | 922 | O | ALA | 102 | 23.990 | 14.125 | 2.485 | 1.00 | 23.11 | A |
| ATOM | 923 | N | PRO | 103 | 26.062 | 14.461 | 1.676 | 1.00 | 23.02 | A |
| ATOM | 924 | CD | PRO | 103 | 25.800 | 15.739 | 0.981 | 1.00 | 20.44 | A |
| ATOM | 925 | CA | PRO | 103 | 27.423 | 13.978 | 1.417 | 1.00 | 23.61 | A |
| ATOM | 926 | CB | PRO | 103 | 27.881 | 14.878 | 0.269 | 1.00 | 19.36 | A |
| ATOM | 927 | CG | PRO | 103 | 27.177 | 16.164 | 0.547 | 1.00 | 20.06 | A |
| ATOM | 928 | C | PRO | 103 | 28.356 | 14.027 | 2.638 | 1.00 | 27.06 | A |
| ATOM | 929 | O | PRO | 103 | 27.948 | 14.432 | 3.737 | 1.00 | 30.75 | A |
| ATOM | 930 | N | LYS | 104 | 29.584 | 13.538 | 2.455 | 1.00 | 28.26 | A |
| ATOM | 931 | H | LYS | 104 | 29.823 | 13.198 | 1.572 | 0.00 | 0.00 | A |
| ATOM | 932 | CA | LYS | 104 | 30.609 | 13.521 | 3.505 | 1.00 | 25.95 | A |
| ATOM | 933 | CB | LYS | 104 | 31.795 | 12.683 | 3.023 | 1.00 | 26.26 | A |
| ATOM | 934 | CG | LYS | 104 | 32.788 | 12.300 | 4.091 | 1.00 | 32.64 | A |
| ATOM | 935 | CD | LYS | 104 | 32.253 | 11.191 | 4.977 | 1.00 | 37.05 | A |
| ATOM | 936 | CE | LYS | 104 | 33.248 | 10.857 | 6.082 | 1.00 | 39.91 | A |
| ATOM | 937 | NZ | LYS | 104 | 32.850 | 9.618 | 6.824 | 1.00 | 45.96 | A |
| ATOM | 938 | HZ1 | LYS | 104 | 32.816 | 8.814 | 6.166 | 0.00 | 0.00 | A |
| ATOM | 939 | HZ2 | LYS | 104 | 31.916 | 9.742 | 7.265 | 0.00 | 0.00 | A |
| ATOM | 940 | HZ3 | LYS | 104 | 33.548 | 9.423 | 7.572 | 0.00 | 0.00 | A |
| ATOM | 941 | C | LYS | 104 | 31.049 | 14.973 | 3.720 | 1.00 | 25.70 | A |
| ATOM | 942 | O | LYS | 104 | 31.528 | 15.626 | 2.793 | 1.00 | 28.73 | A |
| ATOM | 943 | N | MET | 105 | 30.892 | 15.482 | 4.930 | 1.00 | 23.00 | A |
| ATOM | 944 | H | MET | 105 | 30.471 | 14.944 | 5.619 | 0.00 | 0.00 | A |
| ATOM | 945 | CA | MET | 105 | 31.251 | 16.857 | 5.200 | 1.00 | 20.31 | A |
| ATOM | 946 | CB | MET | 105 | 30.392 | 17.404 | 6.338 | 1.00 | 20.07 | A |
| ATOM | 947 | CG | MET | 105 | 28.901 | 17.293 | 6.118 | 1.00 | 19.73 | A |
| ATOM | 948 | SD | MET | 105 | 28.468 | 18.310 | 4.747 | 1.00 | 23.41 | A |
| ATOM | 949 | CE | MET | 105 | 26.816 | 17.876 | 4.464 | 1.00 | 18.54 | A |
| ATOM | 950 | C | MET | 105 | 32.690 | 16.975 | 5.599 | 1.00 | 20.48 | A |
| ATOM | 951 | O | MET | 105 | 33.318 | 18.008 | 5.402 | 1.00 | 22.73 | A |
| ATOM | 952 | N | LEU | 106 | 33.228 | 15.891 | 6.119 | 1.00 | 21.27 | A |
| ATOM | 953 | H | LEU | 106 | 32.699 | 15.082 | 6.123 | 0.00 | 0.00 | A |
| ATOM | 954 | CA | LEU | 106 | 34.582 | 15.886 | 6.638 | 1.00 | 23.19 | A |
| ATOM | 955 | CB | LEU | 106 | 35.038 | 14.456 | 6.933 | 1.00 | 26.27 | A |
| ATOM | 956 | CG | LEU | 106 | 36.304 | 14.396 | 7.799 | 1.00 | 28.31 | A |
| ATOM | 957 | CD1 | LEU | 106 | 36.083 | 15.126 | 9.117 | 1.00 | 25.60 | A |
| ATOM | 958 | CD2 | LEU | 106 | 36.687 | 12.969 | 8.055 | 1.00 | 30.24 | A |
| ATOM | 959 | C | LEU | 106 | 35.670 | 16.641 | 5.881 | 1.00 | 23.93 | A |
| ATOM | 960 | O | LEU | 106 | 36.389 | 17.445 | 6.464 | 1.00 | 24.02 | A |
| ATOM | 961 | N | PRO | 107 | 35.812 | 16.395 | 4.580 | 1.00 | 24.64 | A |
| ATOM | 962 | CD | PRO | 107 | 35.266 | 15.296 | 3.763 | 1.00 | 24.66 | A |
| ATOM | 963 | CA | PRO | 107 | 36.866 | 17.113 | 3.856 | 1.00 | 24.64 | A |
| ATOM | 964 | CB | PRO | 107 | 36.927 | 16.369 | 2.517 | 1.00 | 24.42 | A |
| ATOM | 965 | CG | PRO | 107 | 35.577 | 15.750 | 2.377 | 1.00 | 22.59 | A |
| ATOM | 966 | C | PRO | 107 | 36.684 | 18.601 | 3.649 | 1.00 | 24.83 | A |
| ATOM | 967 | O | PRO | 107 | 37.639 | 19.313 | 3.329 | 1.00 | 26.50 | A |
| ATOM | 968 | N | HIS | 108 | 35.458 | 19.073 | 3.820 | 1.00 | 26.40 | A |
| ATOM | 969 | H | HIS | 108 | 34.760 | 18.472 | 4.160 | 0.00 | 0.00 | A |
| ATOM | 970 | CA | HIS | 108 | 35.135 | 20.483 | 3.596 | 1.00 | 24.44 | A |
| ATOM | 971 | CB | HIS | 108 | 33.769 | 20.576 | 2.924 | 1.00 | 21.94 | A |
| ATOM | 972 | CG | HIS | 108 | 33.598 | 19.633 | 1.776 | 1.00 | 21.26 | A |
| ATOM | 973 | CD2 | HIS | 108 | 32.965 | 18.441 | 1.691 | 1.00 | 22.57 | A |
| ATOM | 974 | ND1 | HIS | 108 | 34.107 | 19.885 | 0.521 | 1.00 | 21.69 | A |
| ATOM | 975 | HD1 | HIS | 108 | 34.557 | 20.709 | 0.240 | 0.00 | 0.00 | A |
| ATOM | 976 | CE1 | HIS | 108 | 33.796 | 18.889 | −0.291 | 1.00 | 21.16 | A |
| ATOM | 977 | NE2 | HIS | 108 | 33.102 | 17.999 | 0.396 | 1.00 | 26.38 | A |
| ATOM | 978 | HE2 | HIS | 108 | 32.723 | 17.157 | 0.052 | 0.00 | 0.00 | A |
| ATOM | 979 | C | HIS | 108 | 35.126 | 21.330 | 4.859 | 1.00 | 24.57 | A |
| ATOM | 980 | O | HIS | 108 | 35.004 | 22.554 | 4.808 | 1.00 | 24.66 | A |
| ATOM | 981 | N | ILE | 109 | 35.267 | 20.685 | 6.001 | 1.00 | 24.16 | A |
| ATOM | 982 | H | ILE | 109 | 35.402 | 19.713 | 6.018 | 0.00 | 0.00 | A |
| ATOM | 983 | CA | ILE | 109 | 35.230 | 21.411 | 7.245 | 1.00 | 22.94 | A |
| ATOM | 984 | CB | ILE | 109 | 35.076 | 20.438 | 8.414 | 1.00 | 21.11 | A |
| ATOM | 985 | CG2 | ILE | 109 | 35.460 | 21.099 | 9.728 | 1.00 | 18.07 | A |
| ATOM | 986 | CG1 | ILE | 109 | 33.630 | 19.929 | 8.395 | 1.00 | 21.03 | A |
| ATOM | 987 | CD1 | ILE | 109 | 33.342 | 18.794 | 9.307 | 1.00 | 19.99 | A |
| ATOM | 988 | C | ILE | 109 | 36.321 | 22.457 | 7.438 | 1.00 | 23.74 | A |
| ATOM | 989 | O | ILE | 109 | 36.040 | 23.552 | 7.941 | 1.00 | 28.27 | A |
| ATOM | 990 | N | PRO | 110 | 37.568 | 22.164 | 7.032 | 1.00 | 21.42 | A |
| ATOM | 991 | CD | PRO | 110 | 38.113 | 20.876 | 6.569 | 1.00 | 20.03 | A |
| ATOM | 992 | CA | PRO | 110 | 38.640 | 23.157 | 7.197 | 1.00 | 20.88 | A |
| ATOM | 993 | CB | PRO | 110 | 39.821 | 22.477 | 6.525 | 1.00 | 19.93 | A |
| ATOM | 994 | CG | PRO | 110 | 39.580 | 21.018 | 6.859 | 1.00 | 18.67 | A |
| ATOM | 995 | C | PRO | 110 | 38.279 | 24.469 | 6.499 | 1.00 | 22.22 | A |
| ATOM | 996 | O | PRO | 110 | 38.400 | 25.556 | 7.083 | 1.00 | 22.23 | A |
| ATOM | 997 | N | GLN | 111 | 37.800 | 24.350 | 5.259 | 1.00 | 24.84 | A |
| ATOM | 998 | H | GLN | 111 | 37.725 | 23.457 | 4.866 | 0.00 | 0.00 | A |
| ATOM | 999 | CA | GLN | 111 | 37.388 | 25.511 | 4.465 | 1.00 | 25.00 | A |
| ATOM | 1000 | CB | GLN | 111 | 37.049 | 25.092 | 3.037 | 1.00 | 22.50 | A |
| ATOM | 1001 | CG | GLN | 111 | 36.842 | 26.256 | 2.085 | 1.00 | 21.51 | A |
| ATOM | 1002 | CD | GLN | 111 | 37.951 | 27.278 | 2.176 | 1.00 | 21.23 | A |
| ATOM | 1003 | OE1 | GLN | 111 | 37.703 | 28.457 | 2.379 | 1.00 | 26.01 | A |
| ATOM | 1004 | NE2 | GLN | 111 | 39.179 | 26.827 | 2.055 | 1.00 | 19.65 | A |
| ATOM | 1005 | HE21 | GLN | 111 | 39.280 | 25.867 | 1.940 | 0.00 | 0.00 | A |
| ATOM | 1006 | HE22 | GLN | 111 | 39.886 | 27.509 | 2.085 | 0.00 | 0.00 | A |
| ATOM | 1007 | C | GLN | 111 | 36.198 | 26.208 | 5.125 | 1.00 | 26.58 | A |
| ATOM | 1008 | O | GLN | 111 | 36.117 | 27.432 | 5.123 | 1.00 | 30.59 | A |
| ATOM | 1009 | N | MET | 112 | 35.288 | 25.424 | 5.701 | 1.00 | 28.16 | A |
| ATOM | 1010 | H | MET | 112 | 35.383 | 24.453 | 5.638 | 0.00 | 0.00 | A |
| ATOM | 1011 | CA | MET | 112 | 34.122 | 25.962 | 6.407 | 1.00 | 25.55 | A |
| ATOM | 1012 | CB | MET | 112 | 33.257 | 24.835 | 6.970 | 1.00 | 21.85 | A |
| ATOM | 1013 | CG | MET | 112 | 32.331 | 24.192 | 5.983 | 1.00 | 18.40 | A |
| ATOM | 1014 | SD | MET | 112 | 31.293 | 22.998 | 6.794 | 1.00 | 20.99 | A |
| ATOM | 1015 | CE | MET | 112 | 31.111 | 21.836 | 5.536 | 1.00 | 18.79 | A |
| ATOM | 1016 | C | MET | 112 | 34.605 | 26.827 | 7.565 | 1.00 | 26.22 | A |
| ATOM | 1017 | O | MET | 112 | 34.179 | 27.977 | 7.704 | 1.00 | 29.08 | A |
| ATOM | 1018 | N | ARG | 113 | 35.533 | 26.298 | 8.366 | 1.00 | 25.36 | A |
| ATOM | 1019 | H | ARG | 113 | 35.866 | 25.402 | 8.168 | 0.00 | 0.00 | A |
| ATOM | 1020 | CA | ARG | 113 | 36.062 | 27.042 | 9.515 | 1.00 | 22.96 | A |
| ATOM | 1021 | CB | ARG | 113 | 37.027 | 26.193 | 10.322 | 1.00 | 21.15 | A |
| ATOM | 1022 | CG | ARG | 113 | 36.394 | 24.972 | 10.917 | 1.00 | 19.88 | A |
| ATOM | 1023 | CD | ARG | 113 | 37.427 | 24.162 | 11.611 | 1.00 | 19.44 | A |
| ATOM | 1024 | NE | ARG | 113 | 37.873 | 24.832 | 12.815 | 1.00 | 23.83 | A |
| ATOM | 1025 | HE | ARG | 113 | 37.251 | 25.484 | 13.217 | 0.00 | 0.00 | A |
| ATOM | 1026 | CZ | ARG | 113 | 39.046 | 24.612 | 13.400 | 1.00 | 24.74 | A |
| ATOM | 1027 | NH1 | ARG | 113 | 39.364 | 25.259 | 14.511 | 1.00 | 23.20 | A |
| ATOM | 1028 | HH11 | ARG | 113 | 38.688 | 25.915 | 14.888 | 0.00 | 0.00 | A |
| ATOM | 1029 | HH12 | ARG | 113 | 40.204 | 25.130 | 15.040 | 0.00 | 0.00 | A |
| ATOM | 1030 | NH2 | ARG | 113 | 39.920 | 23.782 | 12.850 | 1.00 | 27.49 | A |
| ATOM | 1031 | HH21 | ARG | 113 | 39.682 | 23.313 | 11.999 | 0.00 | 0.00 | A |
| ATOM | 1032 | HH22 | ARG | 113 | 40.800 | 23.586 | 13.283 | 0.00 | 0.00 | A |
| ATOM | 1033 | C | ARG | 113 | 36.753 | 28.324 | 9.104 | 1.00 | 23.87 | A |
| ATOM | 1034 | O | ARG | 113 | 36.800 | 29.264 | 9.870 | 1.00 | 26.90 | A |
| ATOM | 1035 | N | VAL | 114 | 37.316 | 28.346 | 7.904 | 1.00 | 23.95 | A |
| ATOM | 1036 | H | VAL | 114 | 37.290 | 27.535 | 7.354 | 0.00 | 0.00 | A |
| ATOM | 1037 | CA | VAL | 114 | 37.993 | 29.519 | 7.385 | 1.00 | 20.83 | A |
| ATOM | 1038 | CB | VAL | 114 | 38.800 | 29.143 | 6.143 | 1.00 | 22.99 | A |
| ATOM | 1039 | CG1 | VAL | 114 | 39.242 | 30.386 | 5.378 | 1.00 | 17.27 | A |
| ATOM | 1040 | CG2 | VAL | 114 | 39.992 | 28.280 | 6.557 | 1.00 | 18.58 | A |
| ATOM | 1041 | C | VAL | 114 | 36.968 | 30.586 | 7.040 | 1.00 | 23.41 | A |
| ATOM | 1042 | O | VAL | 114 | 37.145 | 31.765 | 7.359 | 1.00 | 25.36 | A |
| ATOM | 1043 | N | PHE | 115 | 35.892 | 30.172 | 6.389 | 1.00 | 21.86 | A |
| ATOM | 1044 | H | PHE | 115 | 35.815 | 29.227 | 6.126 | 0.00 | 0.00 | A |
| ATOM | 1045 | CA | PHE | 115 | 34.837 | 31.091 | 6.035 | 1.00 | 20.46 | A |
| ATOM | 1046 | CB | PHE | 115 | 33.830 | 30.386 | 5.169 | 1.00 | 19.94 | A |
| ATOM | 1047 | CG | PHE | 115 | 34.286 | 30.200 | 3.772 | 1.00 | 19.38 | A |
| ATOM | 1048 | CD1 | PHE | 115 | 33.664 | 29.286 | 2.943 | 1.00 | 19.34 | A |
| ATOM | 1049 | CD2 | PHE | 115 | 35.270 | 31.010 | 3.245 | 1.00 | 19.40 | A |
| ATOM | 1050 | CE1 | PHE | 115 | 34.006 | 29.195 | 1.608 | 1.00 | 17.70 | A |
| ATOM | 1051 | CE2 | PHE | 115 | 35.612 | 30.921 | 1.906 | 1.00 | 20.55 | A |
| ATOM | 1052 | CZ | PHE | 115 | 34.974 | 30.013 | 1.089 | 1.00 | 16.90 | A |
| ATOM | 1053 | C | PHE | 115 | 34.141 | 31.645 | 7.258 | 1.00 | 22.63 | A |
| ATOM | 1054 | O | PHE | 115 | 33.991 | 32.854 | 7.388 | 1.00 | 25.45 | A |
| ATOM | 1055 | N | ILE | 116 | 33.727 | 30.768 | 8.166 | 1.00 | 23.42 | A |
| ATOM | 1056 | H | ILE | 116 | 33.878 | 29.815 | 8.000 | 0.00 | 0.00 | A |
| ATOM | 1057 | CA | ILE | 116 | 33.035 | 31.195 | 9.385 | 1.00 | 22.27 | A |
| ATOM | 1058 | CB | ILE | 116 | 32.540 | 29.981 | 10.214 | 1.00 | 20.68 | A |
| ATOM | 1059 | CG2 | ILE | 116 | 31.854 | 30.447 | 11.502 | 1.00 | 22.54 | A |
| ATOM | 1060 | CG1 | ILE | 116 | 31.540 | 29.166 | 9.389 | 1.00 | 19.53 | A |
| ATOM | 1061 | CD1 | ILE | 116 | 31.156 | 27.833 | 9.999 | 1.00 | 15.30 | A |
| ATOM | 1062 | C | ILE | 116 | 33.877 | 32.125 | 10.256 | 1.00 | 23.20 | A |
| ATOM | 1063 | O | ILE | 116 | 33.387 | 33.146 | 10.724 | 1.00 | 27.15 | A |
| ATOM | 1064 | N | ALA | 117 | 35.149 | 31.797 | 10.451 | 1.00 | 23.66 | A |
| ATOM | 1065 | H | ALA | 117 | 35.516 | 30.983 | 10.044 | 0.00 | 0.00 | A |
| ATOM | 1066 | CA | ALA | 117 | 36.043 | 32.614 | 11.275 | 1.00 | 23.66 | A |
| ATOM | 1067 | CB | ALA | 117 | 37.372 | 31.910 | 11.463 | 1.00 | 24.22 | A |
| ATOM | 1068 | C | ALA | 117 | 36.263 | 33.966 | 10.631 | 1.00 | 25.94 | A |
| ATOM | 1069 | O | ALA | 117 | 36.461 | 34.970 | 11.302 | 1.00 | 27.54 | A |
| ATOM | 1070 | N | GLU | 118 | 36.263 | 33.969 | 9.311 | 1.00 | 29.34 | A |
| ATOM | 1071 | H | GLU | 118 | 36.179 | 33.129 | 8.812 | 0.00 | 0.00 | A |
| ATOM | 1072 | CA | GLU | 118 | 36.431 | 35.181 | 8.535 | 1.00 | 30.36 | A |
| ATOM | 1073 | CB | GLU | 118 | 36.429 | 34.815 | 7.059 | 1.00 | 36.53 | A |
| ATOM | 1074 | CG | GLU | 118 | 37.286 | 35.681 | 6.168 | 1.00 | 46.08 | A |
| ATOM | 1075 | CD | GLU | 118 | 37.542 | 35.017 | 4.826 | 1.00 | 51.97 | A |
| ATOM | 1076 | OE1 | GLU | 118 | 38.630 | 34.400 | 4.685 | 1.00 | 54.29 | A |
| ATOM | 1077 | OE2 | GLU | 118 | 36.647 | 35.091 | 3.933 | 1.00 | 53.35 | A |
| ATOM | 1078 | C | GLU | 118 | 35.229 | 36.049 | 8.844 | 1.00 | 28.73 | A |
| ATOM | 1079 | O | GLU | 118 | 35.370 | 37.152 | 9.344 | 1.00 | 28.53 | A |
| ATOM | 1080 | N | ASP | 119 | 34.046 | 35.490 | 8.607 | 1.00 | 27.95 | A |
| ATOM | 1081 | H | ASP | 119 | 34.011 | 34.588 | 8.230 | 0.00 | 0.00 | A |
| ATOM | 1082 | CA | ASP | 119 | 32.777 | 36.160 | 8.834 | 1.00 | 26.70 | A |
| ATOM | 1083 | CB | ASP | 119 | 31.622 | 35.217 | 8.486 | 1.00 | 26.99 | A |
| ATOM | 1084 | CG | ASP | 119 | 31.447 | 35.016 | 6.994 | 1.00 | 28.65 | A |
| ATOM | 1085 | OD1 | ASP | 119 | 30.536 | 34.254 | 6.608 | 1.00 | 29.00 | A |
| ATOM | 1086 | OD2 | ASP | 119 | 32.195 | 35.620 | 6.194 | 1.00 | 30.02 | A |
| ATOM | 1087 | C | ASP | 119 | 32.582 | 36.682 | 10.257 | 1.00 | 27.75 | A |
| ATOM | 1088 | O | ASP | 119 | 31.934 | 37.717 | 10.467 | 1.00 | 27.35 | A |
| ATOM | 1089 | N | LEU | 120 | 33.109 | 35.951 | 11.235 | 1.00 | 27.46 | A |
| ATOM | 1090 | H | LEU | 120 | 33.575 | 35.123 | 10.997 | 0.00 | 0.00 | A |
| ATOM | 1091 | CA | LEU | 120 | 32.960 | 36.342 | 12.629 | 1.00 | 26.98 | A |
| ATOM | 1092 | CB | LEU | 120 | 32.718 | 35.108 | 13.511 | 1.00 | 23.01 | A |
| ATOM | 1093 | CG | LEU | 120 | 31.465 | 34.283 | 13.201 | 1.00 | 21.83 | A |
| ATOM | 1094 | CD1 | LEU | 120 | 31.400 | 33.099 | 14.130 | 1.00 | 17.51 | A |
| ATOM | 1095 | CD2 | LEU | 120 | 30.206 | 35.136 | 13.321 | 1.00 | 19.28 | A |
| ATOM | 1096 | C | LEU | 120 | 34.163 | 37.132 | 13.123 | 1.00 | 29.70 | A |
| ATOM | 1097 | O | LEU | 120 | 34.225 | 37.541 | 14.290 | 1.00 | 31.59 | A |
| ATOM | 1098 | N | GLY | 121 | 35.131 | 37.325 | 12.235 | 1.00 | 31.47 | A |
| ATOM | 1099 | H | GLY | 121 | 35.062 | 36.962 | 11.329 | 0.00 | 0.00 | A |
| ATOM | 1100 | CA | GLY | 121 | 36.325 | 38.072 | 12.585 | 1.00 | 30.53 | A |
| ATOM | 1101 | C | GLY | 121 | 37.097 | 37.482 | 13.738 | 1.00 | 30.81 | A |
| ATOM | 1102 | O | GLY | 121 | 37.754 | 38.208 | 14.484 | 1.00 | 33.57 | A |
| ATOM | 1103 | N | CYS | 122 | 37.047 | 36.163 | 13.875 | 1.00 | 31.22 | A |
| ATOM | 1104 | H | CYS | 122 | 36.589 | 35.623 | 13.200 | 0.00 | 0.00 | A |
| ATOM | 1105 | CA | CYS | 122 | 37.749 | 35.488 | 14.960 | 1.00 | 30.91 | A |
| ATOM | 1106 | CB | CYS | 122 | 36.782 | 34.668 | 15.820 | 1.00 | 28.33 | A |
| ATOM | 1107 | SG | CYS | 122 | 36.050 | 33.263 | 14.987 | 1.00 | 26.15 | A |
| ATOM | 1108 | C | CYS | 122 | 38.796 | 34.567 | 14.392 | 1.00 | 32.46 | A |
| ATOM | 1109 | O | CYS | 122 | 39.034 | 34.527 | 13.184 | 1.00 | 34.41 | A |
| ATOM | 1110 | N | HIS | 123 | 39.419 | 33.818 | 15.281 | 1.00 | 34.90 | A |
| ATOM | 1111 | H | HIS | 123 | 39.163 | 33.864 | 16.231 | 0.00 | 0.00 | A |
| ATOM | 1112 | CA | HIS | 123 | 40.431 | 32.879 | 14.889 | 1.00 | 35.93 | A |
| ATOM | 1113 | CB | HIS | 123 | 41.478 | 32.770 | 15.993 | 1.00 | 44.57 | A |
| ATOM | 1114 | CG | HIS | 123 | 42.631 | 31.890 | 15.637 | 1.00 | 52.97 | A |
| ATOM | 1115 | CD2 | HIS | 123 | 43.564 | 32.001 | 14.662 | 1.00 | 55.11 | A |
| ATOM | 1116 | ND1 | HIS | 123 | 42.906 | 30.711 | 16.299 | 1.00 | 56.93 | A |
| ATOM | 1117 | HD1 | HIS | 123 | 42.435 | 30.342 | 17.089 | 0.00 | 0.00 | A |
| ATOM | 1118 | CE1 | HIS | 123 | 43.957 | 30.134 | 15.748 | 1.00 | 57.57 | A |
| ATOM | 1119 | NE2 | HIS | 123 | 44.375 | 30.897 | 14.753 | 1.00 | 57.48 | A |
| ATOM | 1120 | HE2 | HIS | 123 | 45.174 | 30.750 | 14.190 | 0.00 | 0.00 | A |
| ATOM | 1121 | C | HIS | 123 | 39.731 | 31.550 | 14.684 | 1.00 | 34.48 | A |
| ATOM | 1122 | O | HIS | 123 | 38.705 | 31.279 | 15.295 | 1.00 | 32.89 | A |
| ATOM | 1123 | N | MET | 124 | 40.272 | 30.732 | 13.796 | 1.00 | 34.44 | A |
| ATOM | 1124 | H | MET | 124 | 41.022 | 31.027 | 13.244 | 0.00 | 0.00 | A |
| ATOM | 1125 | CA | MET | 124 | 39.698 | 29.429 | 13.529 | 1.00 | 34.15 | A |
| ATOM | 1126 | CB | MET | 124 | 40.590 | 28.633 | 12.596 | 1.00 | 34.48 | A |
| ATOM | 1127 | CG | MET | 124 | 40.245 | 28.733 | 11.152 | 1.00 | 37.53 | A |
| ATOM | 1128 | SD | MET | 124 | 41.421 | 27.704 | 10.294 | 1.00 | 42.26 | A |
| ATOM | 1129 | CE | MET | 124 | 40.524 | 26.210 | 10.128 | 1.00 | 41.79 | A |
| ATOM | 1130 | C | MET | 124 | 39.514 | 28.610 | 14.789 | 1.00 | 34.63 | A |
| ATOM | 1131 | O | MET | 124 | 38.601 | 27.797 | 14.850 | 1.00 | 37.33 | A |
| ATOM | 1132 | N | ASP | 125 | 40.386 | 28.791 | 15.781 | 1.00 | 32.80 | A |
| ATOM | 1133 | H | ASP | 125 | 41.076 | 29.460 | 15.691 | 0.00 | 0.00 | A |
| ATOM | 1134 | CA | ASP | 125 | 40.284 | 28.003 | 17.005 | 1.00 | 32.71 | A |
| ATOM | 1135 | CB | ASP | 125 | 41.516 | 28.154 | 17.906 | 1.00 | 43.03 | A |
| ATOM | 1136 | CG | ASP | 125 | 41.520 | 27.129 | 19.068 | 1.00 | 53.79 | A |
| ATOM | 1137 | OD1 | ASP | 125 | 42.087 | 26.026 | 18.892 | 1.00 | 59.91 | A |
| ATOM | 1138 | OD2 | ASP | 125 | 40.937 | 27.395 | 20.153 | 1.00 | 59.02 | A |
| ATOM | 1139 | C | ASP | 125 | 39.026 | 28.268 | 17.797 | 1.00 | 29.12 | A |
| ATOM | 1140 | O | ASP | 125 | 38.654 | 27.475 | 18.647 | 1.00 | 30.19 | A |
| ATOM | 1141 | N | ASP | 126 | 38.339 | 29.357 | 17.495 | 1.00 | 25.24 | A |
| ATOM | 1142 | H | ASP | 126 | 38.626 | 30.000 | 16.820 | 0.00 | 0.00 | A |
| ATOM | 1143 | CA | ASP | 126 | 37.111 | 29.669 | 18.194 | 1.00 | 22.66 | A |
| ATOM | 1144 | CB | ASP | 126 | 36.948 | 31.168 | 18.344 | 1.00 | 24.15 | A |
| ATOM | 1145 | CG | ASP | 126 | 38.041 | 31.780 | 19.164 | 1.00 | 27.12 | A |
| ATOM | 1146 | OD1 | ASP | 126 | 38.304 | 32.984 | 18.986 | 1.00 | 33.75 | A |
| ATOM | 1147 | OD2 | ASP | 126 | 38.658 | 31.056 | 19.976 | 1.00 | 31.37 | A |
| ATOM | 1148 | C | ASP | 126 | 35.945 | 29.132 | 17.429 | 1.00 | 21.17 | A |
| ATOM | 1149 | O | ASP | 126 | 34.803 | 29.385 | 17.789 | 1.00 | 22.12 | A |
| ATOM | 1150 | N | VAL | 127 | 36.234 | 28.374 | 16.380 | 1.00 | 19.01 | A |
| ATOM | 1151 | H | VAL | 127 | 37.161 | 28.182 | 16.152 | 0.00 | 0.00 | A |
| ATOM | 1152 | CA | VAL | 127 | 35.212 | 27.809 | 15.522 | 1.00 | 18.45 | A |
| ATOM | 1153 | CB | VAL | 127 | 35.249 | 28.481 | 14.131 | 1.00 | 20.02 | A |
| ATOM | 1154 | CG1 | VAL | 127 | 34.168 | 27.913 | 13.241 | 1.00 | 20.57 | A |
| ATOM | 1155 | CG2 | VAL | 127 | 35.097 | 29.992 | 14.263 | 1.00 | 19.44 | A |
| ATOM | 1156 | C | VAL | 127 | 35.413 | 26.314 | 15.319 | 1.00 | 18.95 | A |
| ATOM | 1157 | O | VAL | 127 | 36.487 | 25.874 | 14.926 | 1.00 | 19.18 | A |
| ATOM | 1158 | N | ASN | 128 | 34.374 | 25.531 | 15.563 | 1.00 | 19.15 | A |
| ATOM | 1159 | H | ASN | 128 | 33.529 | 25.905 | 15.905 | 0.00 | 0.00 | A |
| ATOM | 1160 | CA | ASN | 128 | 34.454 | 24.091 | 15.361 | 1.00 | 20.66 | A |
| ATOM | 1161 | CB | ASN | 128 | 34.524 | 23.350 | 16.704 | 1.00 | 21.54 | A |
| ATOM | 1162 | CG | ASN | 128 | 34.868 | 21.879 | 16.543 | 1.00 | 22.62 | A |
| ATOM | 1163 | OD1 | ASN | 128 | 36.024 | 21.525 | 16.322 | 1.00 | 22.44 | A |
| ATOM | 1164 | ND2 | ASN | 128 | 33.869 | 21.017 | 16.655 | 1.00 | 21.64 | A |
| ATOM | 1165 | HD21 | ASN | 128 | 32.989 | 21.399 | 16.859 | 0.00 | 0.00 | A |
| ATOM | 1166 | HD22 | ASN | 128 | 34.046 | 20.058 | 16.538 | 0.00 | 0.00 | A |
| ATOM | 1167 | C | ASN | 128 | 33.224 | 23.631 | 14.576 | 1.00 | 20.89 | A |
| ATOM | 1168 | O | ASN | 128 | 32.132 | 24.176 | 14.749 | 1.00 | 21.59 | A |
| ATOM | 1169 | N | VAL | 129 | 33.422 | 22.705 | 13.642 | 1.00 | 18.73 | A |
| ATOM | 1170 | H | VAL | 129 | 34.311 | 22.325 | 13.476 | 0.00 | 0.00 | A |
| ATOM | 1171 | CA | VAL | 129 | 32.315 | 22.163 | 12.873 | 1.00 | 17.22 | A |
| ATOM | 1172 | CB | VAL | 129 | 32.296 | 22.670 | 11.442 | 1.00 | 16.58 | A |
| ATOM | 1173 | CG1 | VAL | 129 | 31.120 | 22.070 | 10.719 | 1.00 | 12.70 | A |
| ATOM | 1174 | CG2 | VAL | 129 | 32.214 | 24.182 | 11.418 | 1.00 | 14.63 | A |
| ATOM | 1175 | C | VAL | 129 | 32.490 | 20.656 | 12.859 | 1.00 | 17.83 | A |
| ATOM | 1176 | O | VAL | 129 | 33.612 | 20.170 | 12.830 | 1.00 | 18.94 | A |
| ATOM | 1177 | N | LYS | 130 | 31.399 | 19.907 | 12.941 | 1.00 | 17.82 | A |
| ATOM | 1178 | H | LYS | 130 | 30.510 | 20.318 | 12.987 | 0.00 | 0.00 | A |
| ATOM | 1179 | CA | LYS | 130 | 31.496 | 18.458 | 12.921 | 1.00 | 15.78 | A |
| ATOM | 1180 | CB | LYS | 130 | 31.546 | 17.905 | 14.341 | 1.00 | 19.59 | A |
| ATOM | 1181 | CG | LYS | 130 | 30.232 | 17.866 | 15.067 | 1.00 | 21.72 | A |
| ATOM | 1182 | CD | LYS | 130 | 30.437 | 17.434 | 16.505 | 1.00 | 19.99 | A |
| ATOM | 1183 | CE | LYS | 130 | 31.060 | 18.531 | 17.330 | 1.00 | 21.11 | A |
| ATOM | 1184 | NZ | LYS | 130 | 30.098 | 19.648 | 17.542 | 1.00 | 18.84 | A |
| ATOM | 1185 | HZ1 | LYS | 130 | 30.611 | 20.325 | 18.153 | 0.00 | 0.00 | A |
| ATOM | 1186 | HZ2 | LYS | 130 | 29.281 | 19.363 | 18.097 | 0.00 | 0.00 | A |
| ATOM | 1187 | HZ3 | LYS | 130 | 29.875 | 20.206 | 16.700 | 0.00 | 0.00 | A |
| ATOM | 1188 | C | LYS | 130 | 30.300 | 17.916 | 12.188 | 1.00 | 16.35 | A |
| ATOM | 1189 | O | LYS | 130 | 29.410 | 18.677 | 11.831 | 1.00 | 15.71 | A |
| ATOM | 1190 | N | ALA | 131 | 30.268 | 16.609 | 11.955 | 1.00 | 18.04 | A |
| ATOM | 1191 | H | ALA | 131 | 31.000 | 16.018 | 12.272 | 0.00 | 0.00 | A |
| ATOM | 1192 | CA | ALA | 131 | 29.145 | 16.026 | 11.255 | 1.00 | 16.54 | A |
| ATOM | 1193 | CB | ALA | 131 | 29.449 | 15.925 | 9.782 | 1.00 | 17.34 | A |
| ATOM | 1194 | C | ALA | 131 | 28.778 | 14.671 | 11.821 | 1.00 | 18.05 | A |
| ATOM | 1195 | O | ALA | 131 | 29.543 | 14.081 | 12.581 | 1.00 | 18.75 | A |
| ATOM | 1196 | N | THR | 132 | 27.563 | 14.224 | 11.512 | 1.00 | 19.98 | A |
| ATOM | 1197 | H | THR | 132 | 26.951 | 14.784 | 10.984 | 0.00 | 0.00 | A |
| ATOM | 1198 | CA | THR | 132 | 27.074 | 12.922 | 11.938 | 1.00 | 20.72 | A |
| ATOM | 1199 | CB | THR | 132 | 26.589 | 12.927 | 13.405 | 1.00 | 23.76 | A |
| ATOM | 1200 | OG1 | THR | 132 | 26.273 | 11.587 | 13.804 | 1.00 | 28.13 | A |
| ATOM | 1201 | HG1 | THR | 132 | 25.350 | 11.330 | 13.700 | 0.00 | 0.00 | A |
| ATOM | 1202 | CG2 | THR | 132 | 25.335 | 13.789 | 13.572 | 1.00 | 24.65 | A |
| ATOM | 1203 | C | THR | 132 | 25.909 | 12.526 | 11.052 | 1.00 | 22.87 | A |
| ATOM | 1204 | O | THR | 132 | 25.214 | 13.386 | 10.511 | 1.00 | 24.45 | A |
| ATOM | 1205 | N | THR | 133 | 25.731 | 11.221 | 10.867 | 1.00 | 24.71 | A |
| ATOM | 1206 | H | THR | 133 | 26.334 | 10.634 | 11.344 | 0.00 | 0.00 | A |
| ATOM | 1207 | CA | THR | 133 | 24.622 | 10.677 | 10.078 | 1.00 | 23.94 | A |
| ATOM | 1208 | CB | THR | 133 | 25.008 | 9.404 | 9.249 | 1.00 | 22.97 | A |
| ATOM | 1209 | OG1 | THR | 133 | 25.300 | 8.325 | 10.134 | 1.00 | 24.28 | A |
| ATOM | 1210 | HG1 | THR | 133 | 25.658 | 8.667 | 10.960 | 0.00 | 0.00 | A |
| ATOM | 1211 | CG2 | THR | 133 | 26.206 | 9.631 | 8.378 | 1.00 | 20.89 | A |
| ATOM | 1212 | C | THR | 133 | 23.676 | 10.183 | 11.151 | 1.00 | 25.52 | A |
| ATOM | 1213 | O | THR | 133 | 24.083 | 10.010 | 12.313 | 1.00 | 25.29 | A |
| ATOM | 1214 | N | THR | 134 | 22.426 | 9.955 | 10.787 | 1.00 | 26.77 | A |
| ATOM | 1215 | H | THR | 134 | 22.077 | 10.165 | 9.900 | 0.00 | 0.00 | A |
| ATOM | 1216 | CA | THR | 134 | 21.480 | 9.423 | 11.756 | 1.00 | 28.61 | A |
| ATOM | 1217 | CB | THR | 134 | 20.163 | 10.169 | 11.693 | 1.00 | 26.32 | A |
| ATOM | 1218 | OG1 | THR | 134 | 19.766 | 10.316 | 10.326 | 1.00 | 29.09 | A |
| ATOM | 1219 | HG1 | THR | 134 | 18.805 | 10.462 | 10.313 | 0.00 | 0.00 | A |
| ATOM | 1220 | CG2 | THR | 134 | 20.349 | 11.536 | 12.288 | 1.00 | 24.43 | A |
| ATOM | 1221 | C | THR | 134 | 21.328 | 7.920 | 11.474 | 1.00 | 30.19 | A |
| ATOM | 1222 | O | THR | 134 | 20.285 | 7.312 | 11.734 | 1.00 | 31.26 | A |
| ATOM | 1223 | N | GLU | 135 | 22.426 | 7.347 | 10.973 | 1.00 | 29.66 | A |
| ATOM | 1224 | H | GLU | 135 | 23.246 | 7.862 | 10.872 | 0.00 | 0.00 | A |
| ATOM | 1225 | CA | GLU | 135 | 22.550 | 5.938 | 10.617 | 1.00 | 30.60 | A |
| ATOM | 1226 | CB | GLU | 135 | 22.962 | 5.082 | 11.859 | 1.00 | 30.82 | A |
| ATOM | 1227 | CG | GLU | 135 | 24.325 | 5.473 | 12.617 | 1.00 | 37.55 | A |
| ATOM | 1228 | CD | GLU | 135 | 25.634 | 4.957 | 11.954 | 1.00 | 46.16 | A |
| ATOM | 1229 | OE1 | GLU | 135 | 26.731 | 4.797 | 12.609 | 1.00 | 52.93 | A |
| ATOM | 1230 | OE2 | GLU | 135 | 25.636 | 4.724 | 10.734 | 1.00 | 53.64 | A |
| ATOM | 1231 | C | GLU | 135 | 21.295 | 5.415 | 9.862 | 1.00 | 29.46 | A |
| ATOM | 1232 | O | GLU | 135 | 20.665 | 4.434 | 10.246 | 1.00 | 31.45 | A |
| ATOM | 1233 | N | LYS | 136 | 20.948 | 6.090 | 8.769 | 1.00 | 26.96 | A |
| ATOM | 1234 | H | LYS | 136 | 21.499 | 6.838 | 8.497 | 0.00 | 0.00 | A |
| ATOM | 1235 | CA | LYS | 136 | 19.801 | 5.721 | 7.930 | 1.00 | 26.37 | A |
| ATOM | 1236 | CB | LYS | 136 | 19.922 | 4.281 | 7.451 | 1.00 | 27.24 | A |
| ATOM | 1237 | CG | LYS | 136 | 20.994 | 4.063 | 6.423 | 1.00 | 30.47 | A |
| ATOM | 1238 | CD | LYS | 136 | 20.567 | 4.610 | 5.097 | 1.00 | 37.61 | A |
| ATOM | 1239 | CE | LYS | 136 | 21.541 | 4.199 | 3.995 | 1.00 | 47.03 | A |
| ATOM | 1240 | NZ | LYS | 136 | 21.098 | 4.676 | 2.636 | 1.00 | 52.17 | A |
| ATOM | 1241 | HZ1 | LYS | 136 | 21.791 | 4.399 | 1.915 | 0.00 | 0.00 | A |
| ATOM | 1242 | HZ2 | LYS | 136 | 21.020 | 5.714 | 2.676 | 0.00 | 0.00 | A |
| ATOM | 1243 | HZ3 | LYS | 136 | 20.163 | 4.276 | 2.421 | 0.00 | 0.00 | A |
| ATOM | 1244 | C | LYS | 136 | 18.403 | 5.960 | 8.492 | 1.00 | 25.21 | A |
| ATOM | 1245 | O | LYS | 136 | 17.400 | 5.705 | 7.822 | 1.00 | 25.62 | A |
| ATOM | 1246 | N | LEU | 137 | 18.327 | 6.469 | 9.707 | 1.00 | 24.24 | A |
| ATOM | 1247 | H | LEU | 137 | 19.133 | 6.654 | 10.230 | 0.00 | 0.00 | A |
| ATOM | 1248 | CA | LEU | 137 | 17.044 | 6.752 | 10.314 | 1.00 | 22.17 | A |
| ATOM | 1249 | CB | LEU | 137 | 17.129 | 6.521 | 11.830 | 1.00 | 20.95 | A |
| ATOM | 1250 | CG | LEU | 137 | 17.479 | 5.125 | 12.345 | 1.00 | 17.57 | A |
| ATOM | 1251 | CD1 | LEU | 137 | 17.385 | 5.071 | 13.847 | 1.00 | 16.93 | A |
| ATOM | 1252 | CD2 | LEU | 137 | 16.511 | 4.161 | 11.772 | 1.00 | 16.03 | A |
| ATOM | 1253 | C | LEU | 137 | 16.572 | 8.193 | 10.032 | 1.00 | 23.25 | A |
| ATOM | 1254 | O | LEU | 137 | 17.384 | 9.120 | 9.882 | 1.00 | 24.33 | A |
| ATOM | 1255 | N | GLY | 138 | 15.255 | 8.364 | 9.927 | 1.00 | 21.73 | A |
| ATOM | 1256 | H | GLY | 138 | 14.706 | 7.558 | 9.986 | 0.00 | 0.00 | A |
| ATOM | 1257 | CA | GLY | 138 | 14.668 | 9.679 | 9.721 | 1.00 | 19.28 | A |
| ATOM | 1258 | C | GLY | 138 | 14.738 | 10.320 | 8.354 | 1.00 | 20.83 | A |
| ATOM | 1259 | O | GLY | 138 | 15.229 | 9.730 | 7.396 | 1.00 | 22.89 | A |
| ATOM | 1260 | N | PHE | 139 | 14.247 | 11.550 | 8.262 | 1.00 | 19.55 | A |
| ATOM | 1261 | H | PHE | 139 | 13.915 | 12.010 | 9.058 | 0.00 | 0.00 | A |
| ATOM | 1262 | CA | PHE | 139 | 14.252 | 12.249 | 6.997 | 1.00 | 20.09 | A |
| ATOM | 1263 | CB | PHE | 139 | 13.469 | 13.556 | 7.082 | 1.00 | 18.62 | A |
| ATOM | 1264 | CG | PHE | 139 | 14.120 | 14.631 | 7.916 | 1.00 | 20.58 | A |
| ATOM | 1265 | CD1 | PHE | 139 | 15.103 | 15.454 | 7.380 | 1.00 | 22.70 | A |
| ATOM | 1266 | CD2 | PHE | 139 | 13.696 | 14.879 | 9.207 | 1.00 | 18.27 | A |
| ATOM | 1267 | CE1 | PHE | 139 | 15.644 | 16.503 | 8.115 | 1.00 | 20.94 | A |
| ATOM | 1268 | CE2 | PHE | 139 | 14.240 | 15.936 | 9.947 | 1.00 | 17.15 | A |
| ATOM | 1269 | CZ | PHE | 139 | 15.208 | 16.741 | 9.399 | 1.00 | 18.14 | A |
| ATOM | 1270 | C | PHE | 139 | 15.673 | 12.472 | 6.540 | 1.00 | 20.80 | A |
| ATOM | 1271 | O | PHE | 139 | 15.939 | 12.562 | 5.353 | 1.00 | 24.89 | A |
| ATOM | 1272 | N | THR | 140 | 16.582 | 12.561 | 7.496 | 1.00 | 21.00 | A |
| ATOM | 1273 | H | THR | 140 | 16.342 | 12.508 | 8.440 | 0.00 | 0.00 | A |
| ATOM | 1274 | CA | THR | 140 | 17.998 | 12.747 | 7.205 | 1.00 | 23.14 | A |
| ATOM | 1275 | CB | THR | 140 | 18.786 | 13.201 | 8.461 | 1.00 | 21.69 | A |
| ATOM | 1276 | OG1 | THR | 140 | 18.245 | 12.535 | 9.616 | 1.00 | 27.74 | A |
| ATOM | 1277 | HG1 | THR | 140 | 18.746 | 12.853 | 10.376 | 0.00 | 0.00 | A |
| ATOM | 1278 | CG2 | THR | 140 | 18.705 | 14.714 | 8.643 | 1.00 | 18.25 | A |
| ATOM | 1279 | C | THR | 140 | 18.555 | 11.402 | 6.747 | 1.00 | 23.93 | A |
| ATOM | 1280 | O | THR | 140 | 19.242 | 11.334 | 5.734 | 1.00 | 26.53 | A |
| ATOM | 1281 | N | GLY | 141 | 18.266 | 10.342 | 7.506 | 1.00 | 24.35 | A |
| ATOM | 1282 | H | GLY | 141 | 17.742 | 10.450 | 8.327 | 0.00 | 0.00 | A |
| ATOM | 1283 | CA | GLY | 141 | 18.733 | 9.010 | 7.165 | 1.00 | 21.24 | A |
| ATOM | 1284 | C | GLY | 141 | 18.204 | 8.567 | 5.817 | 1.00 | 23.06 | A |
| ATOM | 1285 | O | GLY | 141 | 18.859 | 7.800 | 5.107 | 1.00 | 25.29 | A |
| ATOM | 1286 | N | ARG | 142 | 17.031 | 9.069 | 5.441 | 1.00 | 22.67 | A |
| ATOM | 1287 | H | ARG | 142 | 16.557 | 9.671 | 6.042 | 0.00 | 0.00 | A |
| ATOM | 1288 | CA | ARG | 142 | 16.439 | 8.725 | 4.160 | 1.00 | 20.74 | A |
| ATOM | 1289 | CB | ARG | 142 | 14.939 | 8.750 | 4.250 | 1.00 | 18.36 | A |
| ATOM | 1290 | CG | ARG | 142 | 14.452 | 7.652 | 5.128 | 1.00 | 20.99 | A |
| ATOM | 1291 | CD | ARG | 142 | 12.991 | 7.496 | 4.956 | 1.00 | 22.98 | A |
| ATOM | 1292 | NE | ARG | 142 | 12.365 | 8.773 | 5.208 | 1.00 | 23.08 | A |
| ATOM | 1293 | HE | ARG | 142 | 12.352 | 9.334 | 4.423 | 0.00 | 0.00 | A |
| ATOM | 1294 | CZ | ARG | 142 | 11.907 | 9.137 | 6.393 | 1.00 | 23.81 | A |
| ATOM | 1295 | NH1 | ARG | 142 | 11.359 | 10.328 | 6.556 | 1.00 | 25.63 | A |
| ATOM | 1296 | HH11 | ARG | 142 | 11.363 | 10.919 | 5.712 | 0.00 | 0.00 | A |
| ATOM | 1297 | HH12 | ARG | 142 | 11.000 | 10.724 | 7.382 | 0.00 | 0.00 | A |
| ATOM | 1298 | NH2 | ARG | 142 | 11.998 | 8.295 | 7.408 | 1.00 | 22.83 | A |
| ATOM | 1299 | HH21 | ARG | 142 | 12.420 | 7.396 | 7.243 | 0.00 | 0.00 | A |
| ATOM | 1300 | HH22 | ARG | 142 | 11.667 | 8.501 | 8.320 | 0.00 | 0.00 | A |
| ATOM | 1301 | C | ARG | 142 | 16.904 | 9.588 | 3.008 | 1.00 | 21.27 | A |
| ATOM | 1302 | O | ARG | 142 | 16.494 | 9.381 | 1.870 | 1.00 | 24.37 | A |
| ATOM | 1303 | N | GLY | 143 | 17.750 | 10.562 | 3.305 | 1.00 | 19.79 | A |
| ATOM | 1304 | H | GLY | 143 | 18.031 | 10.703 | 4.232 | 0.00 | 0.00 | A |
| ATOM | 1305 | CA | GLY | 143 | 18.276 | 11.418 | 2.267 | 1.00 | 18.02 | A |
| ATOM | 1306 | C | GLY | 143 | 17.314 | 12.473 | 1.801 | 1.00 | 20.26 | A |
| ATOM | 1307 | O | GLY | 143 | 17.525 | 13.067 | 0.737 | 1.00 | 22.68 | A |
| ATOM | 1308 | N | GLU | 144 | 16.290 | 12.735 | 2.607 | 1.00 | 20.76 | A |
| ATOM | 1309 | H | GLU | 144 | 16.184 | 12.241 | 3.445 | 0.00 | 0.00 | A |
| ATOM | 1310 | CA | GLU | 144 | 15.280 | 13.730 | 2.294 | 1.00 | 18.45 | A |
| ATOM | 1311 | CB | GLU | 144 | 14.026 | 13.441 | 3.091 | 1.00 | 18.11 | A |
| ATOM | 1312 | CG | GLU | 144 | 13.481 | 12.073 | 2.832 | 1.00 | 19.13 | A |
| ATOM | 1313 | CD | GLU | 144 | 12.336 | 11.712 | 3.738 | 1.00 | 23.33 | A |
| ATOM | 1314 | OE1 | GLU | 144 | 11.694 | 10.678 | 3.472 | 1.00 | 25.00 | A |
| ATOM | 1315 | OE2 | GLU | 144 | 12.060 | 12.443 | 4.722 | 1.00 | 25.62 | A |
| ATOM | 1316 | C | GLU | 144 | 15.743 | 15.156 | 2.556 | 1.00 | 19.58 | A |
| ATOM | 1317 | O | GLU | 144 | 15.238 | 16.092 | 1.946 | 1.00 | 21.53 | A |
| ATOM | 1318 | N | GLY | 145 | 16.712 | 15.327 | 3.445 | 1.00 | 19.19 | A |
| ATOM | 1319 | H | GLY | 145 | 17.111 | 14.566 | 3.918 | 0.00 | 0.00 | A |
| ATOM | 1320 | CA | GLY | 145 | 17.194 | 16.660 | 3.748 | 1.00 | 19.31 | A |
| ATOM | 1321 | C | GLY | 145 | 18.387 | 16.643 | 4.677 | 1.00 | 21.36 | A |
| ATOM | 1322 | O | GLY | 145 | 18.888 | 15.571 | 5.027 | 1.00 | 23.35 | A |
| ATOM | 1323 | N | ILE | 146 | 18.865 | 17.829 | 5.051 | 1.00 | 21.21 | A |
| ATOM | 1324 | H | ILE | 146 | 18.418 | 18.646 | 4.741 | 0.00 | 0.00 | A |
| ATOM | 1325 | CA | ILE | 146 | 20.009 | 17.966 | 5.949 | 1.00 | 18.25 | A |
| ATOM | 1326 | CB | ILE | 146 | 21.233 | 18.645 | 5.265 | 1.00 | 18.20 | A |
| ATOM | 1327 | CG2 | ILE | 146 | 22.364 | 18.842 | 6.251 | 1.00 | 20.78 | A |
| ATOM | 1328 | CG1 | ILE | 146 | 21.812 | 17.749 | 4.193 | 1.00 | 19.26 | A |
| ATOM | 1329 | CD1 | ILE | 146 | 23.073 | 18.320 | 3.607 | 1.00 | 24.47 | A |
| ATOM | 1330 | C | ILE | 146 | 19.537 | 18.843 | 7.091 | 1.00 | 17.65 | A |
| ATOM | 1331 | O | ILE | 146 | 18.684 | 19.708 | 6.901 | 1.00 | 20.43 | A |
| ATOM | 1332 | N | ALA | 147 | 20.054 | 18.584 | 8.282 | 1.00 | 15.65 | A |
| ATOM | 1333 | H | ALA | 147 | 20.729 | 17.876 | 8.374 | 0.00 | 0.00 | A |
| ATOM | 1334 | CA | ALA | 147 | 19.703 | 19.345 | 9.461 | 1.00 | 12.77 | A |
| ATOM | 1335 | CB | ALA | 147 | 19.024 | 18.456 | 10.455 | 1.00 | 12.16 | A |
| ATOM | 1336 | C | ALA | 147 | 21.021 | 19.807 | 10.013 | 1.00 | 13.55 | A |
| ATOM | 1337 | O | ALA | 147 | 22.072 | 19.343 | 9.580 | 1.00 | 14.38 | A |
| ATOM | 1338 | N | CYS | 148 | 20.974 | 20.722 | 10.964 | 1.00 | 13.87 | A |
| ATOM | 1339 | H | CYS | 148 | 20.113 | 21.097 | 11.251 | 0.00 | 0.00 | A |
| ATOM | 1340 | CA | CYS | 148 | 22.186 | 21.217 | 11.589 | 1.00 | 15.60 | A |
| ATOM | 1341 | CB | CYS | 148 | 22.900 | 22.200 | 10.671 | 1.00 | 15.05 | A |
| ATOM | 1342 | SG | CYS | 148 | 24.511 | 22.723 | 11.286 | 1.00 | 25.21 | A |
| ATOM | 1343 | C | CYS | 148 | 21.850 | 21.891 | 12.910 | 1.00 | 16.64 | A |
| ATOM | 1344 | O | CYS | 148 | 20.796 | 22.517 | 13.062 | 1.00 | 17.23 | A |
| ATOM | 1345 | N | GLU | 149 | 22.724 | 21.709 | 13.884 | 1.00 | 17.44 | A |
| ATOM | 1346 | H | GLU | 149 | 23.523 | 21.164 | 13.736 | 0.00 | 0.00 | A |
| ATOM | 1347 | CA | GLU | 149 | 22.557 | 22.324 | 15.187 | 1.00 | 17.94 | A |
| ATOM | 1348 | CB | GLU | 149 | 22.441 | 21.278 | 16.259 | 1.00 | 17.70 | A |
| ATOM | 1349 | CG | GLU | 149 | 21.199 | 20.519 | 16.168 | 1.00 | 24.98 | A |
| ATOM | 1350 | CD | GLU | 149 | 20.778 | 20.057 | 17.503 | 1.00 | 26.55 | A |
| ATOM | 1351 | OE1 | GLU | 149 | 20.475 | 20.920 | 18.341 | 1.00 | 26.17 | A |
| ATOM | 1352 | OE2 | GLU | 149 | 20.821 | 18.842 | 17.725 | 1.00 | 34.31 | A |
| ATOM | 1353 | C | GLU | 149 | 23.796 | 23.111 | 15.470 | 1.00 | 17.70 | A |
| ATOM | 1354 | O | GLU | 149 | 24.859 | 22.794 | 14.943 | 1.00 | 17.36 | A |
| ATOM | 1355 | N | ALA | 150 | 23.685 | 24.099 | 16.344 | 1.00 | 17.69 | A |
| ATOM | 1356 | H | ALA | 150 | 22.814 | 24.307 | 16.747 | 0.00 | 0.00 | A |
| ATOM | 1357 | CA | ALA | 150 | 24.846 | 24.894 | 16.690 | 1.00 | 18.25 | A |
| ATOM | 1358 | CB | ALA | 150 | 25.084 | 25.953 | 15.636 | 1.00 | 17.97 | A |
| ATOM | 1359 | C | ALA | 150 | 24.669 | 25.556 | 18.023 | 1.00 | 17.97 | A |
| ATOM | 1360 | O | ALA | 150 | 23.548 | 25.830 | 18.433 | 1.00 | 16.74 | A |
| ATOM | 1361 | N | VAL | 151 | 25.774 | 25.741 | 18.728 | 1.00 | 17.92 | A |
| ATOM | 1362 | H | VAL | 151 | 26.641 | 25.431 | 18.386 | 0.00 | 0.00 | A |
| ATOM | 1363 | CA | VAL | 151 | 25.739 | 26.456 | 19.985 | 1.00 | 18.61 | A |
| ATOM | 1364 | CB | VAL | 151 | 26.019 | 25.593 | 21.217 | 1.00 | 17.01 | A |
| ATOM | 1365 | CG1 | VAL | 151 | 24.862 | 24.622 | 21.452 | 1.00 | 15.64 | A |
| ATOM | 1366 | CG2 | VAL | 151 | 27.365 | 24.919 | 21.108 | 1.00 | 11.72 | A |
| ATOM | 1367 | C | VAL | 151 | 26.818 | 27.505 | 19.849 | 1.00 | 21.12 | A |
| ATOM | 1368 | O | VAL | 151 | 27.759 | 27.329 | 19.066 | 1.00 | 23.68 | A |
| ATOM | 1369 | N | ALA | 152 | 26.635 | 28.611 | 20.566 | 1.00 | 22.06 | A |
| ATOM | 1370 | H | ALA | 152 | 25.845 | 28.666 | 21.148 | 0.00 | 0.00 | A |
| ATOM | 1371 | CA | ALA | 152 | 27.557 | 29.743 | 20.574 | 1.00 | 23.43 | A |
| ATOM | 1372 | CB | ALA | 152 | 27.054 | 30.837 | 19.647 | 1.00 | 21.26 | A |
| ATOM | 1373 | C | ALA | 152 | 27.674 | 30.296 | 21.990 | 1.00 | 24.19 | A |
| ATOM | 1374 | O | ALA | 152 | 26.752 | 30.167 | 22.799 | 1.00 | 25.64 | A |
| ATOM | 1375 | N | LEU | 153 | 28.822 | 30.884 | 22.292 | 1.00 | 24.75 | A |
| ATOM | 1376 | H | LEU | 153 | 29.528 | 30.933 | 21.618 | 0.00 | 0.00 | A |
| ATOM | 1377 | CA | LEU | 153 | 29.051 | 31.482 | 23.590 | 1.00 | 24.84 | A |
| ATOM | 1378 | CB | LEU | 153 | 30.117 | 30.699 | 24.331 | 1.00 | 23.99 | A |
| ATOM | 1379 | CG | LEU | 153 | 30.070 | 30.808 | 25.847 | 1.00 | 27.53 | A |
| ATOM | 1380 | CD1 | LEU | 153 | 30.862 | 29.682 | 26.466 | 1.00 | 28.78 | A |
| ATOM | 1381 | CD2 | LEU | 153 | 30.635 | 32.138 | 26.278 | 1.00 | 31.63 | A |
| ATOM | 1382 | C | LEU | 153 | 29.540 | 32.896 | 23.299 | 1.00 | 27.24 | A |
| ATOM | 1383 | O | LEU | 153 | 30.502 | 33.061 | 22.555 | 1.00 | 29.53 | A |
| ATOM | 1384 | N | LEU | 154 | 28.822 | 33.907 | 23.781 | 1.00 | 25.19 | A |
| ATOM | 1385 | H | LEU | 154 | 28.015 | 33.736 | 24.267 | 0.00 | 0.00 | A |
| ATOM | 1386 | CA | LEU | 154 | 29.223 | 35.288 | 23.583 | 1.00 | 23.68 | A |
| ATOM | 1387 | CB | LEU | 154 | 28.062 | 36.137 | 23.121 | 1.00 | 20.76 | A |
| ATOM | 1388 | CG | LEU | 154 | 27.413 | 35.758 | 21.806 | 1.00 | 19.25 | A |
| ATOM | 1389 | CD1 | LEU | 154 | 26.218 | 36.653 | 21.599 | 1.00 | 17.69 | A |
| ATOM | 1390 | CD2 | LEU | 154 | 28.399 | 35.882 | 20.674 | 1.00 | 19.58 | A |
| ATOM | 1391 | C | LEU | 154 | 29.742 | 35.834 | 24.899 | 1.00 | 24.69 | A |
| ATOM | 1392 | O | LEU | 154 | 29.406 | 35.346 | 25.969 | 1.00 | 22.83 | A |
| ATOM | 1393 | N | ILE | 155 | 30.541 | 36.880 | 24.810 | 1.00 | 27.74 | A |
| ATOM | 1394 | H | ILE | 155 | 30.723 | 37.273 | 23.939 | 0.00 | 0.00 | A |
| ATOM | 1395 | CA | ILE | 155 | 31.142 | 37.490 | 25.976 | 1.00 | 31.15 | A |
| ATOM | 1396 | CB | ILE | 155 | 32.642 | 37.532 | 25.806 | 1.00 | 32.47 | A |
| ATOM | 1397 | CG2 | ILE | 155 | 33.282 | 38.182 | 26.991 | 1.00 | 34.48 | A |
| ATOM | 1398 | CG1 | ILE | 155 | 33.180 | 36.123 | 25.662 | 1.00 | 32.67 | A |
| ATOM | 1399 | CD1 | ILE | 155 | 34.623 | 36.121 | 25.301 | 1.00 | 37.00 | A |
| ATOM | 1400 | C | ILE | 155 | 30.646 | 38.910 | 26.176 | 1.00 | 32.68 | A |
| ATOM | 1401 | O | ILE | 155 | 30.360 | 39.610 | 25.207 | 1.00 | 37.28 | A |
| ATOM | 1402 | N1 | CDP | 669 | 8.765 | 30.671 | 12.490 | 1.00 | 27.96 | A |
| ATOM | 1403 | C2 | CDP | 669 | 7.666 | 30.747 | 13.343 | 1.00 | 27.87 | A |
| ATOM | 1404 | N3 | CDP | 669 | 6.934 | 29.670 | 13.731 | 1.00 | 26.00 | A |
| ATOM | 1405 | C4 | CDP | 669 | 7.264 | 28.449 | 13.288 | 1.00 | 22.26 | A |
| ATOM | 1406 | C5 | CDP | 669 | 8.355 | 28.298 | 12.437 | 1.00 | 22.12 | A |
| ATOM | 1407 | C6 | CDP | 669 | 9.063 | 29.436 | 12.072 | 1.00 | 25.79 | A |
| ATOM | 1408 | O2 | CDP | 669 | 7.283 | 31.831 | 13.803 | 1.00 | 32.85 | A |
| ATOM | 1409 | N4 | CDP | 669 | 6.526 | 27.405 | 13.686 | 1.00 | 20.28 | A |
| ATOM | 1410 | C1* | CDP | 669 | 9.535 | 31.902 | 12.073 | 1.00 | 28.43 | A |
| ATOM | 1411 | C2* | CDP | 669 | 10.949 | 32.015 | 12.552 | 1.00 | 31.97 | A |
| ATOM | 1412 | O2* | CDP | 669 | 11.191 | 33.371 | 12.818 | 1.00 | 32.98 | A |
| ATOM | 1413 | C3* | CDP | 669 | 11.782 | 31.485 | 11.430 | 1.00 | 33.34 | A |
| ATOM | 1414 | C4* | CDP | 669 | 10.884 | 31.537 | 10.220 | 1.00 | 31.39 | A |
| ATOM | 1415 | O4* | CDP | 669 | 9.635 | 32.019 | 10.681 | 1.00 | 30.34 | A |
| ATOM | 1416 | O3* | CDP | 669 | 12.903 | 32.274 | 11.102 | 1.00 | 36.84 | A |
| ATOM | 1417 | C5* | CDP | 669 | 10.952 | 30.150 | 9.873 | 1.00 | 34.19 | A |
| ATOM | 1418 | O5* | CDP | 669 | 11.300 | 29.973 | 8.578 | 1.00 | 34.24 | A |
| ATOM | 1419 | PA | CDP | 669 | 11.976 | 28.573 | 8.200 | 1.00 | 32.45 | A |
| ATOM | 1420 | O1A | CDP | 669 | 11.485 | 27.486 | 9.152 | 1.00 | 34.55 | A |
| ATOM | 1421 | O2A | CDP | 669 | 11.518 | 28.353 | 6.719 | 1.00 | 42.80 | A |
| ATOM | 1422 | O3A | CDP | 669 | 13.607 | 28.683 | 8.308 | 1.00 | 37.96 | A |
| ATOM | 1423 | PB | CDP | 669 | 14.479 | 29.278 | 7.006 | 1.00 | 34.00 | A |
| ATOM | 1424 | O1B | CDP | 669 | 13.762 | 28.981 | 5.588 | 1.00 | 43.45 | A |
| ATOM | 1425 | O2B | CDP | 669 | 15.860 | 28.582 | 7.073 | 1.00 | 34.07 | A |
| ATOM | 1426 | O3B | CDP | 669 | 14.649 | 30.931 | 7.180 | 1.00 | 42.04 | A |
| ATOM | 1427 | MG | MG | 700 | 12.163 | 27.874 | 4.768 | 1.00 | 50.22 | A |
| ATOM | 1428 | ZN | ZN | 156 | 17.511 | 27.631 | 6.826 | 1.00 | 36.94 | A |
| END | | | | | | | | | | |

ANNEX 3
Coordinates of structure nat2

| | | | | | | | | | | |
|---|---|---|---|---|---|---|---|---|---|---|
| ATOM | 1 | CB | MET | 1 | 30.140 | 34.301 | 29.540 | 1.00 | 62.77 | A |
| ATOM | 2 | CG | MET | 1 | 31.544 | 34.436 | 29.021 | 1.00 | 71.56 | A |
| ATOM | 3 | SD | MET | 1 | 32.531 | 33.052 | 29.566 | 1.00 | 86.03 | A |
| ATOM | 4 | CE | MET | 1 | 33.774 | 33.930 | 30.653 | 1.00 | 85.87 | A |
| ATOM | 5 | C | MET | 1 | 27.846 | 35.000 | 28.932 | 1.00 | 52.35 | A |
| ATOM | 6 | O | MET | 1 | 27.090 | 34.746 | 29.866 | 1.00 | 52.83 | A |
| ATOM | 7 | HT1 | MET | 1 | 28.854 | 36.060 | 31.062 | 0.00 | 0.00 | A |
| ATOM | 8 | HT2 | MET | 1 | 28.712 | 37.322 | 29.960 | 0.00 | 0.00 | A |
| ATOM | 9 | N | MET | 1 | 29.312 | 36.528 | 30.249 | 1.00 | 56.90 | A |
| ATOM | 10 | HT3 | MET | 1 | 30.281 | 36.812 | 30.470 | 0.00 | 0.00 | A |
| ATOM | 11 | CA | MET | 1 | 29.258 | 35.482 | 29.182 | 1.00 | 56.44 | A |
| ATOM | 12 | N | ARG | 2 | 27.486 | 34.878 | 27.667 | 1.00 | 48.20 | A |
| ATOM | 13 | H | ARG | 2 | 28.098 | 35.002 | 26.920 | 0.00 | 0.00 | A |
| ATOM | 14 | CA | ARG | 2 | 26.154 | 34.446 | 27.331 | 1.00 | 45.75 | A |
| ATOM | 15 | CB | ARG | 2 | 25.363 | 35.615 | 26.753 | 1.00 | 44.19 | A |
| ATOM | 16 | CG | ARG | 2 | 25.059 | 36.641 | 27.829 | 1.00 | 44.31 | A |
| ATOM | 17 | CD | ARG | 2 | 24.190 | 37.785 | 27.364 | 1.00 | 47.19 | A |
| ATOM | 18 | NE | ARG | 2 | 22.872 | 37.366 | 26.895 | 1.00 | 50.07 | A |
| ATOM | 19 | HE | ARG | 2 | 22.866 | 36.750 | 26.130 | 0.00 | 0.00 | A |
| ATOM | 20 | CZ | ARG | 2 | 21.712 | 37.732 | 27.440 | 1.00 | 50.67 | A |
| ATOM | 21 | NH1 | ARG | 2 | 20.581 | 37.297 | 26.902 | 1.00 | 51.57 | A |
| ATOM | 22 | HH11 | ARG | 2 | 20.582 | 36.689 | 26.102 | 0.00 | 0.00 | A |
| ATOM | 23 | HH12 | ARG | 2 | 19.697 | 37.588 | 27.282 | 0.00 | 0.00 | A |
| ATOM | 24 | NH2 | ARG | 2 | 21.678 | 38.455 | 28.557 | 1.00 | 50.01 | A |
| ATOM | 25 | HH21 | ARG | 2 | 22.492 | 38.731 | 29.063 | 0.00 | 0.00 | A |
| ATOM | 26 | HH22 | ARG | 2 | 20.808 | 38.737 | 29.004 | 0.00 | 0.00 | A |
| ATOM | 27 | C | ARG | 2 | 26.196 | 33.246 | 26.415 | 1.00 | 44.37 | A |
| ATOM | 28 | O | ARG | 2 | 27.136 | 33.085 | 25.647 | 1.00 | 45.40 | A |
| ATOM | 29 | N | ILE | 3 | 25.203 | 32.375 | 26.554 | 1.00 | 43.25 | A |
| ATOM | 30 | H | ILE | 3 | 24.447 | 32.593 | 27.131 | 0.00 | 0.00 | A |
| ATOM | 31 | CA | ILE | 3 | 25.112 | 31.151 | 25.772 | 1.00 | 42.27 | A |
| ATOM | 32 | CB | ILE | 3 | 24.856 | 29.959 | 26.706 | 1.00 | 43.01 | A |
| ATOM | 33 | CG2 | ILE | 3 | 23.496 | 30.094 | 27.361 | 1.00 | 43.45 | A |
| ATOM | 34 | CG1 | ILE | 3 | 24.923 | 28.644 | 25.939 | 1.00 | 44.97 | A |
| ATOM | 35 | CD1 | ILE | 3 | 24.653 | 27.445 | 26.812 | 1.00 | 45.63 | A |
| ATOM | 36 | C | ILE | 3 | 23.975 | 31.246 | 24.756 | 1.00 | 40.63 | A |
| ATOM | 37 | O | ILE | 3 | 22.954 | 31.858 | 25.031 | 1.00 | 41.01 | A |
| ATOM | 38 | N | GLY | 4 | 24.151 | 30.643 | 23.589 | 1.00 | 38.67 | A |
| ATOM | 39 | H | GLY | 4 | 24.977 | 30.149 | 23.400 | 0.00 | 0.00 | A |
| ATOM | 40 | CA | GLY | 4 | 23.113 | 30.687 | 22.579 | 1.00 | 35.77 | A |
| ATOM | 41 | C | GLY | 4 | 22.999 | 29.343 | 21.905 | 1.00 | 35.14 | A |
| ATOM | 42 | O | GLY | 4 | 23.943 | 28.554 | 21.935 | 1.00 | 37.50 | A |
| ATOM | 43 | N | HIS | 5 | 21.847 | 29.064 | 21.315 | 1.00 | 32.87 | A |
| ATOM | 44 | H | HIS | 5 | 21.146 | 29.739 | 21.334 | 0.00 | 0.00 | A |
| ATOM | 45 | CA | HIS | 5 | 21.627 | 27.805 | 20.628 | 1.00 | 30.15 | A |
| ATOM | 46 | CB | HIS | 5 | 20.881 | 26.823 | 21.513 | 1.00 | 26.75 | A |
| ATOM | 47 | CG | HIS | 5 | 20.425 | 25.594 | 20.790 | 1.00 | 25.34 | A |
| ATOM | 48 | CD2 | HIS | 5 | 21.045 | 24.413 | 20.556 | 1.00 | 23.75 | A |
| ATOM | 49 | ND1 | HIS | 5 | 19.185 | 25.501 | 20.195 | 1.00 | 25.21 | A |
| ATOM | 50 | HD1 | HIS | 5 | 18.459 | 26.167 | 20.191 | 0.00 | 0.00 | A |
| ATOM | 51 | CE1 | HIS | 5 | 19.061 | 24.314 | 19.625 | 1.00 | 28.23 | A |
| ATOM | 52 | NE2 | HIS | 5 | 20.175 | 23.635 | 19.831 | 1.00 | 26.45 | A |
| ATOM | 53 | HE2 | HIS | 5 | 20.239 | 22.678 | 19.581 | 0.00 | 0.00 | A |
| ATOM | 54 | C | HIS | 5 | 20.802 | 28.026 | 19.392 | 1.00 | 31.54 | A |
| ATOM | 55 | O | HIS | 5 | 19.802 | 28.752 | 19.433 | 1.00 | 33.18 | A |
| ATOM | 56 | N | GLY | 6 | 21.161 | 27.320 | 18.325 | 1.00 | 30.21 | A |
| ATOM | 57 | H | GLY | 6 | 21.926 | 26.703 | 18.359 | 0.00 | 0.00 | A |
| ATOM | 58 | CA | GLY | 6 | 20.438 | 27.443 | 17.077 | 1.00 | 28.34 | A |
| ATOM | 59 | C | GLY | 6 | 20.159 | 26.086 | 16.478 | 1.00 | 29.12 | A |
| ATOM | 60 | O | GLY | 6 | 20.744 | 25.092 | 16.903 | 1.00 | 31.64 | A |
| ATOM | 61 | N | PHE | 7 | 19.251 | 26.038 | 15.512 | 1.00 | 29.14 | A |
| ATOM | 62 | H | PHE | 7 | 18.792 | 26.850 | 15.189 | 0.00 | 0.00 | A |
| ATOM | 63 | CA | PHE | 7 | 18.904 | 24.793 | 14.854 | 1.00 | 29.11 | A |
| ATOM | 64 | CB | PHE | 7 | 17.959 | 23.999 | 15.738 | 1.00 | 27.39 | A |
| ATOM | 65 | CG | PHE | 7 | 17.413 | 22.780 | 15.085 | 1.00 | 26.39 | A |
| ATOM | 66 | CD1 | PHE | 7 | 18.120 | 21.595 | 15.114 | 1.00 | 25.61 | A |
| ATOM | 67 | CD2 | PHE | 7 | 16.205 | 22.828 | 14.403 | 1.00 | 29.51 | A |
| ATOM | 68 | CE1 | PHE | 7 | 17.640 | 20.468 | 14.468 | 1.00 | 27.83 | A |
| ATOM | 69 | CE2 | PHE | 7 | 15.712 | 21.706 | 13.751 | 1.00 | 30.69 | A |
| ATOM | 70 | CZ | PHE | 7 | 16.435 | 20.519 | 13.782 | 1.00 | 28.48 | A |
| ATOM | 71 | C | PHE | 7 | 18.223 | 25.114 | 13.532 | 1.00 | 32.26 | A |
| ATOM | 72 | O | PHE | 7 | 17.411 | 26.037 | 13.474 | 1.00 | 35.80 | A |
| ATOM | 73 | N | ASP | 8 | 18.525 | 24.339 | 12.490 | 1.00 | 32.86 | A |
| ATOM | 74 | H | ASP | 8 | 19.160 | 23.597 | 12.592 | 0.00 | 0.00 | A |
| ATOM | 75 | CA | ASP | 8 | 17.936 | 24.568 | 11.179 | 1.00 | 32.25 | A |
| ATOM | 76 | CB | ASP | 8 | 18.681 | 25.694 | 10.482 | 1.00 | 33.50 | A |
| ATOM | 77 | CG | ASP | 8 | 17.944 | 26.222 | 9.275 | 1.00 | 36.43 | A |
| ATOM | 78 | OD1 | ASP | 8 | 18.617 | 26.760 | 8.371 | 1.00 | 41.07 | A |
| ATOM | 79 | OD2 | ASP | 8 | 16.699 | 26.111 | 9.217 | 1.00 | 37.63 | A |
| ATOM | 80 | C | ASP | 8 | 17.917 | 23.319 | 10.299 | 1.00 | 32.59 | A |
| ATOM | 81 | O | ASP | 8 | 18.771 | 22.444 | 10.431 | 1.00 | 33.62 | A |
| ATOM | 82 | N | VAL | 9 | 16.944 | 23.256 | 9.394 | 1.00 | 33.03 | A |
| ATOM | 83 | H | VAL | 9 | 16.332 | 24.028 | 9.326 | 0.00 | 0.00 | A |
| ATOM | 84 | CA | VAL | 9 | 16.747 | 22.135 | 8.477 | 1.00 | 31.99 | A |
| ATOM | 85 | CB | VAL | 9 | 15.612 | 21.226 | 8.990 | 1.00 | 31.14 | A |
| ATOM | 86 | CG1 | VAL | 9 | 15.233 | 20.185 | 7.971 | 1.00 | 32.63 | A |
| ATOM | 87 | CG2 | VAL | 9 | 16.035 | 20.549 | 10.247 | 1.00 | 34.83 | A |
| ATOM | 88 | C | VAL | 9 | 16.324 | 22.662 | 7.104 | 1.00 | 34.09 | A |
| ATOM | 89 | O | VAL | 9 | 15.688 | 23.706 | 7.008 | 1.00 | 35.20 | A |
| ATOM | 90 | N | HIS | 10 | 16.743 | 21.987 | 6.039 | 1.00 | 36.07 | A |
| ATOM | 91 | H | HIS | 10 | 17.326 | 21.204 | 6.174 | 0.00 | 0.00 | A |
| ATOM | 92 | CA | HIS | 10 | 16.360 | 22.355 | 4.672 | 1.00 | 35.99 | A |
| ATOM | 93 | CB | HIS | 10 | 17.366 | 23.290 | 4.008 | 1.00 | 34.78 | A |
| ATOM | 94 | CG | HIS | 10 | 17.268 | 24.704 | 4.481 | 1.00 | 36.65 | A |
| ATOM | 95 | CD2 | HIS | 10 | 18.036 | 25.414 | 5.343 | 1.00 | 37.64 | A |
| ATOM | 96 | ND1 | HIS | 10 | 16.249 | 25.544 | 4.096 | 1.00 | 36.14 | A |
| ATOM | 97 | HD1 | HIS | 10 | 15.476 | 25.321 | 3.512 | 0.00 | 0.00 | A |
| ATOM | 98 | CE1 | HIS | 10 | 16.389 | 26.710 | 4.704 | 1.00 | 39.69 | A |
| ATOM | 99 | NE2 | HIS | 10 | 17.467 | 26.658 | 5.468 | 1.00 | 42.02 | A |
| ATOM | 100 | C | HIS | 10 | 16.207 | 21.081 | 3.865 | 1.00 | 37.13 | A |
| ATOM | 101 | O | HIS | 10 | 16.949 | 20.115 | 4.055 | 1.00 | 38.06 | A |
| ATOM | 102 | N | ALA | 11 | 15.191 | 21.060 | 3.018 | 1.00 | 37.06 | A |
| ATOM | 103 | H | ALA | 11 | 14.606 | 21.839 | 2.926 | 0.00 | 0.00 | A |
| ATOM | 104 | CA | ALA | 11 | 14.912 | 19.900 | 2.206 | 1.00 | 36.98 | A |
| ATOM | 105 | CB | ALA | 11 | 13.455 | 19.878 | 1.866 | 1.00 | 39.16 | A |
| ATOM | 106 | C | ALA | 11 | 15.740 | 19.888 | 0.937 | 1.00 | 38.77 | A |
| ATOM | 107 | O | ALA | 11 | 16.118 | 20.942 | 0.419 | 1.00 | 40.53 | A |
| ATOM | 108 | N | PHE | 12 | 16.034 | 18.697 | 0.434 | 1.00 | 38.72 | A |
| ATOM | 109 | H | PHE | 12 | 15.701 | 17.886 | 0.875 | 0.00 | 0.00 | A |
| ATOM | 110 | CA | PHE | 12 | 16.801 | 18.591 | −0.795 | 1.00 | 38.34 | A |
| ATOM | 111 | CB | PHE | 12 | 17.366 | 17.176 | −0.975 | 1.00 | 35.93 | A |
| ATOM | 112 | CG | PHE | 12 | 18.642 | 16.917 | −0.220 | 1.00 | 31.92 | A |
| ATOM | 113 | CD1 | PHE | 12 | 19.728 | 17.771 | −0.341 | 1.00 | 30.66 | A |
| ATOM | 114 | CD2 | PHE | 12 | 18.757 | 15.814 | 0.608 | 1.00 | 29.77 | A |
| ATOM | 115 | CE1 | PHE | 12 | 20.905 | 17.531 | 0.354 | 1.00 | 27.66 | A |
| ATOM | 116 | CE2 | PHE | 12 | 19.932 | 15.570 | 1.301 | 1.00 | 29.10 | A |
| ATOM | 117 | CZ | PHE | 12 | 21.006 | 16.436 | 1.170 | 1.00 | 27.45 | A |
| ATOM | 118 | C | PHE | 12 | 15.857 | 18.913 | −1.942 | 1.00 | 40.43 | A |
| ATOM | 119 | O | PHE | 12 | 14.657 | 18.655 | −1.871 | 1.00 | 39.30 | A |
| ATOM | 120 | N | GLY | 13 | 16.406 | 19.481 | −3.000 | 1.00 | 44.48 | A |
| ATOM | 121 | H | GLY | 13 | 17.356 | 19.697 | −3.025 | 0.00 | 0.00 | A |
| ATOM | 122 | CA | GLY | 13 | 15.600 | 19.814 | −4.154 | 1.00 | 50.14 | A |
| ATOM | 123 | C | GLY | 13 | 16.437 | 20.444 | −5.247 | 1.00 | 54.20 | A |
| ATOM | 124 | O | GLY | 13 | 17.390 | 21.187 | −4.978 | 1.00 | 55.14 | A |
| ATOM | 125 | N | GLY | 14 | 16.094 | 20.133 | −6.489 | 1.00 | 57.43 | A |
| ATOM | 126 | H | GLY | 14 | 15.372 | 19.497 | −6.653 | 0.00 | 0.00 | A |
| ATOM | 127 | CA | GLY | 14 | 16.829 | 20.689 | −7.606 | 1.00 | 63.17 | A |
| ATOM | 128 | C | GLY | 14 | 18.170 | 20.016 | −7.777 | 1.00 | 66.47 | A |
| ATOM | 129 | O | GLY | 14 | 18.414 | 18.934 | −7.232 | 1.00 | 66.67 | A |
| ATOM | 130 | N | GLU | 15 | 19.038 | 20.655 | −8.544 | 1.00 | 69.62 | A |
| ATOM | 131 | H | GLU | 15 | 18.822 | 21.511 | −8.952 | 0.00 | 0.00 | A |
| ATOM | 132 | CA | GLU | 15 | 20.356 | 20.101 | −8.788 | 1.00 | 72.31 | A |
| ATOM | 133 | CB | GLU | 15 | 20.812 | 20.411 | −10.220 | 1.00 | 80.07 | A |
| ATOM | 134 | CG | GLU | 15 | 20.034 | 19.669 | −11.300 | 1.00 | 89.59 | A |
| ATOM | 135 | CD | GLU | 15 | 20.091 | 18.154 | −11.118 | 1.00 | 96.50 | A |
| ATOM | 136 | OE1 | GLU | 15 | 19.094 | 17.581 | −10.607 | 1.00 | 99.80 | A |
| ATOM | 137 | OE2 | GLU | 15 | 21.132 | 17.545 | −11.478 | 1.00 | 99.27 | A |
| ATOM | 138 | C | GLU | 15 | 21.331 | 20.686 | −7.791 | 1.00 | 68.91 | A |
| ATOM | 139 | O | GLU | 15 | 21.087 | 21.768 | −7.246 | 1.00 | 69.73 | A |
| ATOM | 140 | N | GLY | 16 | 22.407 | 19.949 | −7.531 | 1.00 | 64.49 | A |
| ATOM | 141 | H | GLY | 16 | 22.496 | 19.075 | −7.979 | 0.00 | 0.00 | A |
| ATOM | 142 | CA | GLY | 16 | 23.428 | 20.411 | −6.609 | 1.00 | 58.55 | A |
| ATOM | 143 | C | GLY | 16 | 24.292 | 21.484 | −7.249 | 1.00 | 53.32 | A |
| ATOM | 144 | O | GLY | 16 | 23.993 | 21.932 | −8.357 | 1.00 | 53.53 | A |
| ATOM | 145 | N | CPR | 17 | 25.374 | 21.918 | −6.591 | 1.00 | 46.80 | A |
| ATOM | 146 | CD | CPR | 17 | 26.035 | 23.151 | −7.053 | 1.00 | 42.93 | A |
| ATOM | 147 | CA | CPR | 17 | 25.901 | 21.523 | −5.293 | 1.00 | 44.04 | A |
| ATOM | 148 | CB | CPR | 17 | 27.294 | 22.114 | −5.341 | 1.00 | 44.54 | A |
| ATOM | 149 | CG | CPR | 17 | 27.013 | 23.457 | −5.940 | 1.00 | 41.76 | A |
| ATOM | 150 | C | CPR | 17 | 25.094 | 22.201 | −4.187 | 1.00 | 43.03 | A |
| ATOM | 151 | O | CPR | 17 | 24.143 | 22.950 | −4.445 | 1.00 | 46.68 | A |
| ATOM | 152 | N | ILE | 18 | 25.479 | 21.948 | −2.951 | 1.00 | 37.16 | A |
| ATOM | 153 | H | ILE | 18 | 26.241 | 21.369 | −2.774 | 0.00 | 0.00 | A |
| ATOM | 154 | CA | ILE | 18 | 24.808 | 22.563 | −1.845 | 1.00 | 31.91 | A |
| ATOM | 155 | CB | ILE | 18 | 24.440 | 21.529 | −0.760 | 1.00 | 30.83 | A |
| ATOM | 156 | CG2 | ILE | 18 | 23.536 | 20.468 | −1.317 | 1.00 | 31.47 | A |
| ATOM | 157 | CG1 | ILE | 18 | 25.673 | 20.837 | −0.210 | 1.00 | 29.48 | A |
| ATOM | 158 | CD1 | ILE | 18 | 25.302 | 19.795 | 0.814 | 1.00 | 32.94 | A |
| ATOM | 159 | C | ILE | 18 | 25.816 | 23.554 | −1.304 | 1.00 | 33.54 | A |
| ATOM | 160 | O | ILE | 18 | 26.980 | 23.556 | −1.725 | 1.00 | 34.41 | A |
| ATOM | 161 | N | ILE | 19 | 25.371 | 24.427 | −0.409 | 1.00 | 32.41 | A |
| ATOM | 162 | H | ILE | 19 | 24.434 | 24.441 | −0.124 | 0.00 | 0.00 | A |
| ATOM | 163 | CA | ILE | 19 | 26.265 | 25.388 | 0.195 | 1.00 | 29.98 | A |
| ATOM | 164 | CB | ILE | 19 | 25.855 | 26.791 | −0.139 | 1.00 | 30.00 | A |
| ATOM | 165 | CG2 | ILE | 19 | 26.918 | 27.740 | 0.300 | 1.00 | 30.41 | A |
| ATOM | 166 | CG1 | ILE | 19 | 25.656 | 26.941 | −1.643 | 1.00 | 32.92 | A |
| ATOM | 167 | CD1 | ILE | 19 | 26.917 | 27.008 | −2.436 | 1.00 | 37.49 | A |
| ATOM | 168 | C | ILE | 19 | 26.103 | 25.193 | 1.681 | 1.00 | 30.86 | A |
| ATOM | 169 | O | ILE | 19 | 25.041 | 25.460 | 2.218 | 1.00 | 34.44 | A |
| ATOM | 170 | N | ILE | 20 | 27.134 | 24.676 | 2.335 | 1.00 | 30.07 | A |
| ATOM | 171 | H | ILE | 20 | 27.967 | 24.485 | 1.850 | 0.00 | 0.00 | A |
| ATOM | 172 | CA | ILE | 20 | 27.090 | 24.424 | 3.763 | 1.00 | 28.44 | A |
| ATOM | 173 | CB | ILE | 20 | 27.140 | 22.908 | 4.042 | 1.00 | 28.91 | A |
| ATOM | 174 | CG2 | ILE | 20 | 27.087 | 22.636 | 5.527 | 1.00 | 28.51 | A |
| ATOM | 175 | CG1 | ILE | 20 | 25.985 | 22.183 | 3.334 | 1.00 | 29.77 | A |
| ATOM | 176 | CD1 | ILE | 20 | 24.615 | 22.466 | 3.883 | 1.00 | 24.66 | A |
| ATOM | 177 | C | ILE | 20 | 28.307 | 25.062 | 4.410 | 1.00 | 29.67 | A |
| ATOM | 178 | O | ILE | 20 | 29.427 | 24.704 | 4.076 | 1.00 | 30.62 | A |
| ATOM | 179 | N | GLY | 21 | 28.092 | 26.000 | 5.329 | 1.00 | 29.96 | A |
| ATOM | 180 | H | GLY | 21 | 27.184 | 26.281 | 5.520 | 0.00 | 0.00 | A |
| ATOM | 181 | CA | GLY | 21 | 29.200 | 26.651 | 6.009 | 1.00 | 29.89 | A |
| ATOM | 182 | C | GLY | 21 | 29.956 | 27.552 | 5.062 | 1.00 | 30.91 | A |
| ATOM | 183 | O | GLY | 21 | 31.137 | 27.838 | 5.242 | 1.00 | 30.52 | A |
| ATOM | 184 | N | GLY | 22 | 29.258 | 27.992 | 4.029 | 1.00 | 31.91 | A |
| ATOM | 185 | H | GLY | 22 | 28.308 | 27.755 | 3.938 | 0.00 | 0.00 | A |
| ATOM | 186 | CA | GLY | 22 | 29.864 | 28.855 | 3.044 | 1.00 | 32.74 | A |
| ATOM | 187 | C | GLY | 22 | 30.523 | 28.096 | 1.911 | 1.00 | 34.29 | A |
| ATOM | 188 | O | GLY | 22 | 30.752 | 28.669 | 0.843 | 1.00 | 38.86 | A |
| ATOM | 189 | N | VAL | 23 | 30.793 | 26.809 | 2.111 | 1.00 | 33.50 | A |
| ATOM | 190 | H | VAL | 23 | 30.534 | 26.379 | 2.953 | 0.00 | 0.00 | A |
| ATOM | 191 | CA | VAL | 23 | 31.451 | 26.001 | 1.089 | 1.00 | 31.63 | A |
| ATOM | 192 | CB | VAL | 23 | 32.303 | 24.884 | 1.715 | 1.00 | 29.95 | A |
| ATOM | 193 | CG1 | VAL | 23 | 33.116 | 24.205 | 0.656 | 1.00 | 32.97 | A |
| ATOM | 194 | CG2 | VAL | 23 | 33.219 | 25.435 | 2.786 | 1.00 | 29.27 | A |
| ATOM | 195 | C | VAL | 23 | 30.478 | 25.374 | 0.105 | 1.00 | 33.45 | A |
| ATOM | 196 | O | VAL | 23 | 29.415 | 24.877 | 0.484 | 1.00 | 35.64 | A |
| ATOM | 197 | N | ARG | 24 | 30.843 | 25.417 | −1.170 | 1.00 | 35.41 | A |
| ATOM | 198 | H | ARG | 24 | 31.677 | 25.851 | −1.374 | 0.00 | 0.00 | A |
| ATOM | 199 | CA | ARG | 24 | 30.025 | 24.852 | −2.235 | 1.00 | 35.87 | A |
| ATOM | 200 | CB | ARG | 24 | 30.369 | 25.536 | −3.551 | 1.00 | 37.53 | A |
| ATOM | 201 | CG | ARG | 24 | 29.267 | 25.507 | −4.570 | 1.00 | 49.38 | A |
| ATOM | 202 | CD | ARG | 24 | 29.738 | 26.035 | −5.930 | 1.00 | 59.51 | A |
| ATOM | 203 | NE | ARG | 24 | 28.660 | 26.620 | −6.738 | 1.00 | 65.55 | A |
| ATOM | 204 | HE | ARG | 24 | 28.229 | 27.405 | −6.329 | 0.00 | 0.00 | A |
| ATOM | 205 | CZ | ARG | 24 | 28.270 | 26.162 | −7.927 | 1.00 | 68.74 | A |
| ATOM | 206 | NH1 | ARG | 24 | 27.287 | 26.781 | −8.576 | 1.00 | 70.59 | A |
| ATOM | 207 | HH11 | ARG | 24 | 26.840 | 27.589 | −8.180 | 0.00 | 0.00 | A |
| ATOM | 208 | HH12 | ARG | 24 | 26.948 | 26.479 | −9.470 | 0.00 | 0.00 | A |
| ATOM | 209 | NH2 | ARG | 24 | 28.840 | 25.074 | −8.458 | 1.00 | 72.50 | A |
| ATOM | 210 | HH21 | ARG | 24 | 29.573 | 24.605 | −7.958 | 0.00 | 0.00 | A |
| ATOM | 211 | HH22 | ARG | 24 | 28.564 | 24.697 | −9.343 | 0.00 | 0.00 | A |
| ATOM | 212 | C | ARG | 24 | 30.406 | 23.388 | −2.291 | 1.00 | 34.25 | A |
| ATOM | 213 | O | ARG | 24 | 31.500 | 23.053 | −2.739 | 1.00 | 37.81 | A |
| ATOM | 214 | N | ILE | 25 | 29.556 | 22.528 | −1.749 | 1.00 | 32.42 | A |
| ATOM | 215 | H | ILE | 25 | 28.718 | 22.866 | −1.372 | 0.00 | 0.00 | A |
| ATOM | 216 | CA | ILE | 25 | 29.836 | 21.096 | −1.724 | 1.00 | 30.16 | A |
| ATOM | 217 | CB | ILE | 25 | 29.411 | 20.470 | −0.396 | 1.00 | 28.34 | A |
| ATOM | 218 | CG2 | ILE | 25 | 29.719 | 19.016 | −0.413 | 1.00 | 27.27 | A |
| ATOM | 219 | CG1 | ILE | 25 | 30.144 | 21.126 | 0.770 | 1.00 | 25.31 | A |
| ATOM | 220 | CD1 | ILE | 25 | 29.649 | 20.681 | 2.099 | 1.00 | 21.21 | A |
| ATOM | 221 | C | ILE | 25 | 29.069 | 20.404 | −2.828 | 1.00 | 31.39 | A |
| ATOM | 222 | O | ILE | 25 | 27.858 | 20.531 | −2.921 | 1.00 | 34.30 | A |
| ATOM | 223 | N | PRO | 26 | 29.760 | 19.650 | −3.679 | 1.00 | 31.82 | A |
| ATOM | 224 | CD | PRO | 26 | 31.209 | 19.404 | −3.718 | 1.00 | 33.84 | A |
| ATOM | 225 | CA | PRO | 26 | 29.100 | 18.950 | −4.776 | 1.00 | 31.70 | A |
| ATOM | 226 | CB | PRO | 26 | 30.280 | 18.406 | −5.569 | 1.00 | 28.55 | A |
| ATOM | 227 | CG | PRO | 26 | 31.289 | 18.146 | −4.538 | 1.00 | 29.11 | A |
| ATOM | 228 | C | PRO | 26 | 28.197 | 17.832 | −4.294 | 1.00 | 33.75 | A |
| ATOM | 229 | O | PRO | 26 | 28.628 | 16.990 | −3.500 | 1.00 | 35.64 | A |
| ATOM | 230 | N | TYR | 27 | 26.960 | 17.817 | −4.794 | 1.00 | 35.20 | A |
| ATOM | 231 | H | TYR | 27 | 26.664 | 18.492 | −5.439 | 0.00 | 0.00 | A |
| ATOM | 232 | CA | TYR | 27 | 25.976 | 16.796 | −4.433 | 1.00 | 37.32 | A |
| ATOM | 233 | CB | TYR | 27 | 25.233 | 17.192 | −3.159 | 1.00 | 36.46 | A |
| ATOM | 234 | CG | TYR | 27 | 24.426 | 16.076 | −2.558 | 1.00 | 34.15 | A |
| ATOM | 235 | CD1 | TYR | 27 | 24.982 | 14.818 | −2.392 | 1.00 | 33.22 | A |
| ATOM | 236 | CE1 | TYR | 27 | 24.246 | 13.773 | −1.876 | 1.00 | 34.86 | A |
| ATOM | 237 | CD2 | TYR | 27 | 23.100 | 16.270 | −2.181 | 1.00 | 33.09 | A |
| ATOM | 238 | CE2 | TYR | 27 | 22.352 | 15.233 | −1.663 | 1.00 | 34.75 | A |
| ATOM | 239 | CZ | TYR | 27 | 22.934 | 13.982 | −1.516 | 1.00 | 36.17 | A |
| ATOM | 240 | OH | TYR | 27 | 22.200 | 12.921 | −1.041 | 1.00 | 39.92 | A |
| ATOM | 241 | HH | TYR | 27 | 22.752 | 12.129 | −1.179 | 0.00 | 0.00 | A |
| ATOM | 242 | C | TYR | 27 | 24.980 | 16.664 | −5.572 | 1.00 | 40.73 | A |
| ATOM | 243 | O | TYR | 27 | 24.791 | 17.612 | −6.344 | 1.00 | 41.01 | A |
| ATOM | 244 | N | GLU | 28 | 24.344 | 15.498 | −5.673 | 1.00 | 44.17 | A |
| ATOM | 245 | H | GLU | 28 | 24.544 | 14.807 | −5.014 | 0.00 | 0.00 | A |
| ATOM | 246 | CA | GLU | 28 | 23.369 | 15.244 | −6.741 | 1.00 | 47.93 | A |
| ATOM | 247 | CB | GLU | 28 | 22.718 | 13.871 | −6.603 | 1.00 | 50.79 | A |
| ATOM | 248 | CG | GLU | 28 | 23.423 | 12.875 | −5.701 | 1.00 | 59.51 | A |
| ATOM | 249 | CD | GLU | 28 | 22.436 | 11.873 | −5.091 | 1.00 | 65.33 | A |
| ATOM | 250 | OE1 | GLU | 28 | 22.879 | 10.915 | −4.413 | 1.00 | 67.99 | A |
| ATOM | 251 | OE2 | GLU | 28 | 21.205 | 12.064 | −5.262 | 1.00 | 69.07 | A |
| ATOM | 252 | C | GLU | 28 | 22.263 | 16.280 | −6.719 | 1.00 | 46.72 | A |
| ATOM | 253 | O | GLU | 28 | 22.055 | 17.013 | −7.682 | 1.00 | 49.91 | A |
| ATOM | 254 | N | LYS | 29 | 21.545 | 16.309 | −5.608 | 1.00 | 45.13 | A |
| ATOM | 255 | H | LYS | 29 | 21.818 | 15.700 | −4.902 | 0.00 | 0.00 | A |
| ATOM | 256 | CA | LYS | 29 | 20.452 | 17.243 | −5.413 | 1.00 | 42.09 | A |
| ATOM | 257 | CB | LYS | 29 | 19.300 | 16.547 | −4.665 | 1.00 | 41.72 | A |
| ATOM | 258 | CG | LYS | 29 | 19.712 | 15.304 | −3.854 | 1.00 | 43.47 | A |
| ATOM | 259 | CD | LYS | 29 | 18.495 | 14.489 | −3.390 | 1.00 | 46.08 | A |
| ATOM | 260 | CE | LYS | 29 | 18.853 | 13.086 | −2.815 | 1.00 | 46.96 | A |
| ATOM | 261 | NZ | LYS | 29 | 19.465 | 13.026 | −1.442 | 1.00 | 42.08 | A |
| ATOM | 262 | HZ1 | LYS | 29 | 18.830 | 13.418 | −0.711 | 0.00 | 0.00 | A |
| ATOM | 263 | HZ2 | LYS | 29 | 20.411 | 13.471 | −1.418 | 0.00 | 0.00 | A |
| ATOM | 264 | HZ3 | LYS | 29 | 19.628 | 12.025 | −1.231 | 0.00 | 0.00 | A |
| ATOM | 265 | C | LYS | 29 | 20.975 | 18.458 | −4.648 | 1.00 | 40.27 | A |
| ATOM | 266 | O | LYS | 29 | 22.098 | 18.443 | −4.146 | 1.00 | 39.24 | A |
| ATOM | 267 | N | GLY | 30 | 20.198 | 19.532 | −4.640 | 1.00 | 39.41 | A |
| ATOM | 268 | H | GLY | 30 | 19.353 | 19.520 | −5.136 | 0.00 | 0.00 | A |
| ATOM | 269 | CA | GLY | 30 | 20.583 | 20.734 | −3.927 | 1.00 | 38.30 | A |
| ATOM | 270 | C | GLY | 30 | 19.669 | 20.920 | −2.732 | 1.00 | 39.51 | A |
| ATOM | 271 | O | GLY | 30 | 19.017 | 19.962 | −2.296 | 1.00 | 39.66 | A |
| ATOM | 272 | N | LEU | 31 | 19.601 | 22.136 | −2.195 | 1.00 | 38.98 | A |
| ATOM | 273 | H | LEU | 31 | 20.093 | 22.883 | −2.596 | 0.00 | 0.00 | A |
| ATOM | 274 | CA | LEU | 31 | 18.745 | 22.401 | −1.036 | 1.00 | 38.14 | A |
| ATOM | 275 | CB | LEU | 31 | 19.572 | 22.773 | 0.192 | 1.00 | 32.38 | A |
| ATOM | 276 | CG | LEU | 31 | 20.242 | 21.583 | 0.858 | 1.00 | 30.44 | A |
| ATOM | 277 | CD1 | LEU | 31 | 20.983 | 22.007 | 2.087 | 1.00 | 29.64 | A |
| ATOM | 278 | CD2 | LEU | 31 | 19.183 | 20.603 | 1.229 | 1.00 | 31.90 | A |
| ATOM | 279 | C | LEU | 31 | 17.731 | 23.485 | −1.305 | 1.00 | 39.50 | A |
| ATOM | 280 | O | LEU | 31 | 18.066 | 24.547 | −1.811 | 1.00 | 42.83 | A |
| ATOM | 281 | N | LEU | 32 | 16.482 | 23.205 | −0.981 | 1.00 | 40.50 | A |
| ATOM | 282 | H | LEU | 32 | 16.278 | 22.334 | −0.627 | 0.00 | 0.00 | A |
| ATOM | 283 | CA | LEU | 32 | 15.411 | 24.163 | −1.172 | 1.00 | 41.87 | A |
| ATOM | 284 | CB | LEU | 32 | 14.092 | 23.426 | −1.176 | 1.00 | 40.48 | A |
| ATOM | 285 | CG | LEU | 32 | 14.085 | 22.333 | −2.224 | 1.00 | 40.86 | A |
| ATOM | 286 | CD1 | LEU | 32 | 12.752 | 21.651 | −2.203 | 1.00 | 43.18 | A |
| ATOM | 287 | CD2 | LEU | 32 | 14.349 | 22.941 | −3.578 | 1.00 | 39.76 | A |
| ATOM | 288 | C | LEU | 32 | 15.379 | 25.240 | −0.094 | 1.00 | 43.44 | A |
| ATOM | 289 | O | LEU | 32 | 15.364 | 24.930 | 1.104 | 1.00 | 44.03 | A |
| ATOM | 290 | N | ALA | 33 | 15.348 | 26.501 | −0.518 | 1.00 | 45.84 | A |
| ATOM | 291 | H | ALA | 33 | 15.397 | 26.718 | −1.475 | 0.00 | 0.00 | A |
| ATOM | 292 | CA | ALA | 33 | 15.287 | 27.618 | 0.417 | 1.00 | 49.65 | A |
| ATOM | 293 | CB | ALA | 33 | 16.519 | 27.624 | 1.292 | 1.00 | 49.82 | A |
| ATOM | 294 | C | ALA | 33 | 15.106 | 28.985 | −0.262 | 1.00 | 52.83 | A |
| ATOM | 295 | O | ALA | 33 | 15.309 | 29.114 | −1.478 | 1.00 | 55.37 | A |
| ATOM | 296 | N | HIS | 34 | 14.683 | 29.981 | 0.530 | 1.00 | 53.59 | A |
| ATOM | 297 | H | HIS | 34 | 14.500 | 29.756 | 1.467 | 0.00 | 0.00 | A |
| ATOM | 298 | CA | HIS | 34 | 14.476 | 31.366 | 0.064 | 1.00 | 53.41 | A |
| ATOM | 299 | CB | HIS | 34 | 13.614 | 32.149 | 1.091 | 1.00 | 56.17 | A |
| ATOM | 300 | CG | HIS | 34 | 13.390 | 33.612 | 0.781 | 1.00 | 57.42 | A |
| ATOM | 301 | CD2 | HIS | 34 | 13.729 | 34.728 | 1.478 | 1.00 | 57.47 | A |
| ATOM | 302 | ND1 | HIS | 34 | 12.634 | 34.052 | −0.287 | 1.00 | 56.97 | A |
| ATOM | 303 | HD1 | HIS | 34 | 12.212 | 33.491 | −0.972 | 0.00 | 0.00 | A |
| ATOM | 304 | CE1 | HIS | 34 | 12.513 | 35.369 | −0.230 | 1.00 | 56.53 | A |
| ATOM | 305 | NE2 | HIS | 34 | 13.168 | 35.803 | 0.831 | 1.00 | 55.86 | A |
| ATOM | 306 | HE2 | HIS | 34 | 13.161 | 36.726 | 1.177 | 0.00 | 0.00 | A |
| ATOM | 307 | C | HIS | 34 | 15.855 | 32.014 | −0.139 | 1.00 | 52.27 | A |
| ATOM | 308 | O | HIS | 34 | 16.032 | 32.778 | −1.077 | 1.00 | 52.50 | A |
| ATOM | 309 | N | SER | 35 | 16.802 | 31.728 | 0.759 | 1.00 | 50.62 | A |
| ATOM | 310 | H | SER | 35 | 16.613 | 31.127 | 1.503 | 0.00 | 0.00 | A |
| ATOM | 311 | CA | SER | 35 | 18.172 | 32.243 | 0.670 | 1.00 | 46.85 | A |
| ATOM | 312 | CB | SER | 35 | 18.750 | 32.417 | 2.070 | 1.00 | 46.29 | A |
| ATOM | 313 | OG | SER | 35 | 19.004 | 31.146 | 2.658 | 1.00 | 49.31 | A |
| ATOM | 314 | HG | SER | 35 | 19.952 | 31.005 | 2.449 | 0.00 | 0.00 | A |
| ATOM | 315 | C | SER | 35 | 18.939 | 31.133 | −0.043 | 1.00 | 44.18 | A |
| ATOM | 316 | O | SER | 35 | 18.353 | 30.374 | −0.805 | 1.00 | 46.39 | A |
| ATOM | 317 | N | ASP | 36 | 20.226 | 30.995 | 0.239 | 1.00 | 40.32 | A |
| ATOM | 318 | H | ASP | 36 | 20.729 | 31.624 | 0.802 | 0.00 | 0.00 | A |
| ATOM | 319 | CA | ASP | 36 | 21.012 | 29.937 | −0.382 | 1.00 | 39.23 | A |
| ATOM | 320 | CB | ASP | 36 | 22.485 | 30.320 | −0.390 | 1.00 | 36.86 | A |
| ATOM | 321 | CG | ASP | 36 | 22.994 | 30.620 | 0.977 | 1.00 | 38.88 | A |
| ATOM | 322 | OD1 | ASP | 36 | 24.143 | 31.075 | 1.101 | 1.00 | 42.63 | A |
| ATOM | 323 | OD2 | ASP | 36 | 22.230 | 30.418 | 1.945 | 1.00 | 42.58 | A |
| ATOM | 324 | C | ASP | 36 | 20.805 | 28.619 | 0.379 | 1.00 | 38.60 | A |
| ATOM | 325 | O | ASP | 36 | 21.441 | 27.600 | 0.086 | 1.00 | 42.48 | A |
| ATOM | 326 | N | GLY | 37 | 19.971 | 28.667 | 1.409 | 1.00 | 35.01 | A |
| ATOM | 327 | H | GLY | 37 | 19.569 | 29.519 | 1.627 | 0.00 | 0.00 | A |
| ATOM | 328 | CA | GLY | 37 | 19.684 | 27.473 | 2.172 | 1.00 | 31.19 | A |
| ATOM | 329 | C | GLY | 37 | 20.830 | 26.842 | 2.918 | 1.00 | 29.85 | A |
| ATOM | 330 | O | GLY | 37 | 20.766 | 25.659 | 3.236 | 1.00 | 29.67 | A |
| ATOM | 331 | N | ASP | 38 | 21.839 | 27.636 | 3.252 | 1.00 | 28.70 | A |
| ATOM | 332 | H | ASP | 38 | 21.889 | 28.565 | 2.931 | 0.00 | 0.00 | A |
| ATOM | 333 | CA | ASP | 38 | 22.999 | 27.155 | 4.002 | 1.00 | 28.19 | A |
| ATOM | 334 | CB | ASP | 38 | 24.071 | 28.244 | 4.004 | 1.00 | 27.80 | A |
| ATOM | 335 | CG | ASP | 38 | 25.395 | 27.775 | 4.550 | 1.00 | 29.98 | A |
| ATOM | 336 | OD1 | ASP | 38 | 25.436 | 26.918 | 5.456 | 1.00 | 31.73 | A |
| ATOM | 337 | OD2 | ASP | 38 | 26.424 | 28.299 | 4.091 | 1.00 | 34.12 | A |
| ATOM | 338 | C | ASP | 38 | 22.595 | 26.821 | 5.446 | 1.00 | 30.24 | A |
| ATOM | 339 | O | ASP | 38 | 22.688 | 27.668 | 6.339 | 1.00 | 33.72 | A |
| ATOM | 340 | N | VAL | 39 | 22.132 | 25.594 | 5.679 | 1.00 | 29.74 | A |
| ATOM | 341 | H | VAL | 39 | 22.108 | 25.005 | 4.893 | 0.00 | 0.00 | A |
| ATOM | 342 | CA | VAL | 39 | 21.710 | 25.159 | 7.012 | 1.00 | 26.14 | A |
| ATOM | 343 | CB | VAL | 39 | 21.446 | 23.659 | 7.067 | 1.00 | 24.10 | A |
| ATOM | 344 | CG1 | VAL | 39 | 20.656 | 23.328 | 8.279 | 1.00 | 28.91 | A |
| ATOM | 345 | CG2 | VAL | 39 | 20.678 | 23.226 | 5.890 | 1.00 | 26.10 | A |
| ATOM | 346 | C | VAL | 39 | 22.731 | 25.458 | 8.092 | 1.00 | 26.31 | A |
| ATOM | 347 | O | VAL | 39 | 22.379 | 25.982 | 9.134 | 1.00 | 30.63 | A |
| ATOM | 348 | N | ALA | 40 | 23.999 | 25.176 | 7.830 | 1.00 | 25.68 | A |
| ATOM | 349 | H | ALA | 40 | 24.233 | 24.873 | 6.929 | 0.00 | 0.00 | A |
| ATOM | 350 | CA | ALA | 40 | 25.054 | 25.395 | 8.820 | 1.00 | 25.20 | A |
| ATOM | 351 | CB | ALA | 40 | 26.416 | 25.035 | 8.245 | 1.00 | 23.66 | A |
| ATOM | 352 | C | ALA | 40 | 25.100 | 26.810 | 9.336 | 1.00 | 24.88 | A |
| ATOM | 353 | O | ALA | 40 | 25.121 | 27.044 | 10.535 | 1.00 | 25.00 | A |
| ATOM | 354 | N | LEU | 41 | 25.115 | 27.768 | 8.431 | 1.00 | 26.04 | A |
| ATOM | 355 | H | LEU | 41 | 25.048 | 27.557 | 7.467 | 0.00 | 0.00 | A |
| ATOM | 356 | CA | LEU | 41 | 25.207 | 29.141 | 8.868 | 1.00 | 27.53 | A |
| ATOM | 357 | CB | LEU | 41 | 25.740 | 30.025 | 7.753 | 1.00 | 27.17 | A |
| ATOM | 358 | CG | LEU | 41 | 27.108 | 29.607 | 7.223 | 1.00 | 27.91 | A |
| ATOM | 359 | CD1 | LEU | 41 | 27.569 | 30.617 | 6.201 | 1.00 | 31.11 | A |
| ATOM | 360 | CD2 | LEU | 41 | 28.107 | 29.523 | 8.350 | 1.00 | 29.30 | A |
| ATOM | 361 | C | LEU | 41 | 23.931 | 29.701 | 9.478 | 1.00 | 30.47 | A |
| ATOM | 362 | O | LEU | 41 | 23.998 | 30.575 | 10.343 | 1.00 | 32.41 | A |
| ATOM | 363 | N | HIS | 42 | 22.767 | 29.199 | 9.075 | 1.00 | 30.55 | A |
| ATOM | 364 | H | HIS | 42 | 22.784 | 28.494 | 8.391 | 0.00 | 0.00 | A |
| ATOM | 365 | CA | HIS | 42 | 21.541 | 29.703 | 9.687 | 1.00 | 29.53 | A |
| ATOM | 366 | CB | HIS | 42 | 20.300 | 29.144 | 9.035 | 1.00 | 30.33 | A |
| ATOM | 367 | CG | HIS | 42 | 20.127 | 29.581 | 7.626 | 1.00 | 32.60 | A |
| ATOM | 368 | CD2 | HIS | 42 | 20.790 | 30.513 | 6.905 | 1.00 | 33.16 | A |
| ATOM | 369 | ND1 | HIS | 42 | 19.199 | 29.015 | 6.779 | 1.00 | 40.31 | A |
| ATOM | 370 | CE1 | HIS | 42 | 19.305 | 29.584 | 5.589 | 1.00 | 38.43 | A |
| ATOM | 371 | NE2 | HIS | 42 | 20.262 | 30.493 | 5.640 | 1.00 | 34.59 | A |
| ATOM | 372 | HE2 | HIS | 42 | 20.618 | 31.054 | 4.902 | 0.00 | 0.00 | A |
| ATOM | 373 | C | HIS | 42 | 21.560 | 29.300 | 11.136 | 1.00 | 28.70 | A |
| ATOM | 374 | O | HIS | 42 | 21.321 | 30.125 | 11.998 | 1.00 | 30.99 | A |
| ATOM | 375 | N | ALA | 43 | 21.910 | 28.051 | 11.411 | 1.00 | 26.33 | A |
| ATOM | 376 | H | ALA | 43 | 22.140 | 27.422 | 10.690 | 0.00 | 0.00 | A |
| ATOM | 377 | CA | ALA | 43 | 21.958 | 27.604 | 12.785 | 1.00 | 27.10 | A |
| ATOM | 378 | CB | ALA | 43 | 22.269 | 26.148 | 12.849 | 1.00 | 29.62 | A |
| ATOM | 379 | C | ALA | 43 | 22.985 | 28.419 | 13.573 | 1.00 | 29.27 | A |
| ATOM | 380 | O | ALA | 43 | 22.696 | 28.891 | 14.672 | 1.00 | 31.69 | A |
| ATOM | 381 | N | LEU | 44 | 24.172 | 28.620 | 13.011 | 1.00 | 29.91 | A |
| ATOM | 382 | H | LEU | 44 | 24.370 | 28.225 | 12.135 | 0.00 | 0.00 | A |
| ATOM | 383 | CA | LEU | 44 | 25.190 | 29.406 | 13.705 | 1.00 | 29.86 | A |
| ATOM | 384 | CB | LEU | 44 | 26.479 | 29.484 | 12.881 | 1.00 | 26.00 | A |
| ATOM | 385 | CG | LEU | 44 | 27.587 | 30.381 | 13.437 | 1.00 | 23.44 | A |
| ATOM | 386 | CD1 | LEU | 44 | 27.957 | 29.926 | 14.834 | 1.00 | 21.62 | A |
| ATOM | 387 | CD2 | LEU | 44 | 28.802 | 30.343 | 12.522 | 1.00 | 19.96 | A |
| ATOM | 388 | C | LEU | 44 | 24.636 | 30.808 | 13.969 | 1.00 | 31.04 | A |
| ATOM | 389 | O | LEU | 44 | 24.715 | 31.315 | 15.082 | 1.00 | 34.25 | A |
| ATOM | 390 | N | THR | 45 | 24.023 | 31.406 | 12.957 | 1.00 | 30.25 | A |
| ATOM | 391 | H | THR | 45 | 23.932 | 30.955 | 12.103 | 0.00 | 0.00 | A |
| ATOM | 392 | CA | THR | 45 | 23.454 | 32.730 | 13.092 | 1.00 | 30.88 | A |
| ATOM | 393 | CB | THR | 45 | 22.706 | 33.124 | 11.816 | 1.00 | 32.62 | A |
| ATOM | 394 | OG1 | THR | 45 | 23.614 | 33.118 | 10.705 | 1.00 | 35.22 | A |
| ATOM | 395 | HG1 | THR | 45 | 24.335 | 33.729 | 10.867 | 0.00 | 0.00 | A |
| ATOM | 396 | CG2 | THR | 45 | 22.065 | 34.502 | 11.966 | 1.00 | 32.65 | A |
| ATOM | 397 | C | THR | 45 | 22.494 | 32.799 | 14.286 | 1.00 | 32.31 | A |
| ATOM | 398 | O | THR | 45 | 22.683 | 33.610 | 15.182 | 1.00 | 35.22 | A |
| ATOM | 399 | N | ASP | 46 | 21.488 | 31.937 | 14.322 | 1.00 | 31.17 | A |
| ATOM | 400 | H | ASP | 46 | 21.344 | 31.291 | 13.598 | 0.00 | 0.00 | A |
| ATOM | 401 | CA | ASP | 46 | 20.542 | 31.949 | 15.423 | 1.00 | 30.62 | A |
| ATOM | 402 | CB | ASP | 46 | 19.520 | 30.853 | 15.265 | 1.00 | 32.40 | A |
| ATOM | 403 | CG | ASP | 46 | 18.434 | 31.218 | 14.333 | 1.00 | 34.20 | A |
| ATOM | 404 | OD1 | ASP | 46 | 17.575 | 30.353 | 14.049 | 1.00 | 38.98 | A |
| ATOM | 405 | OD2 | ASP | 46 | 18.441 | 32.372 | 13.884 | 1.00 | 36.02 | A |
| ATOM | 406 | C | ASP | 46 | 21.186 | 31.759 | 16.768 | 1.00 | 32.47 | A |
| ATOM | 407 | O | ASP | 46 | 20.675 | 32.255 | 17.773 | 1.00 | 33.35 | A |
| ATOM | 408 | N | ALA | 47 | 22.261 | 30.978 | 16.805 | 1.00 | 30.81 | A |
| ATOM | 409 | H | ALA | 47 | 22.579 | 30.573 | 15.968 | 0.00 | 0.00 | A |
| ATOM | 410 | CA | ALA | 47 | 22.943 | 30.723 | 18.060 | 1.00 | 32.11 | A |
| ATOM | 411 | CB | ALA | 47 | 23.993 | 29.682 | 17.879 | 1.00 | 35.31 | A |
| ATOM | 412 | C | ALA | 47 | 23.556 | 32.008 | 18.588 | 1.00 | 32.83 | A |
| ATOM | 413 | O | ALA | 47 | 23.509 | 32.274 | 19.791 | 1.00 | 34.02 | A |
| ATOM | 414 | N | LEU | 48 | 24.128 | 32.795 | 17.681 | 1.00 | 30.84 | A |
| ATOM | 415 | H | LEU | 48 | 24.134 | 32.492 | 16.745 | 0.00 | 0.00 | A |
| ATOM | 416 | CA | LEU | 48 | 24.739 | 34.071 | 18.025 | 1.00 | 30.17 | A |
| ATOM | 417 | CB | LEU | 48 | 25.553 | 34.592 | 16.844 | 1.00 | 28.10 | A |
| ATOM | 418 | CG | LEU | 48 | 26.809 | 33.774 | 16.530 | 1.00 | 30.19 | A |
| ATOM | 419 | CD1 | LEU | 48 | 27.344 | 34.148 | 15.158 | 1.00 | 27.92 | A |
| ATOM | 420 | CD2 | LEU | 48 | 27.875 | 33.981 | 17.630 | 1.00 | 26.45 | A |
| ATOM | 421 | C | LEU | 48 | 23.647 | 35.070 | 18.404 | 1.00 | 31.67 | A |
| ATOM | 422 | O | LEU | 48 | 23.694 | 35.665 | 19.476 | 1.00 | 34.50 | A |
| ATOM | 423 | N | LEU | 49 | 22.649 | 35.239 | 17.541 | 1.00 | 32.36 | A |
| ATOM | 424 | H | LEU | 49 | 22.656 | 34.735 | 16.704 | 0.00 | 0.00 | A |
| ATOM | 425 | CA | LEU | 49 | 21.544 | 36.147 | 17.824 | 1.00 | 31.40 | A |
| ATOM | 426 | CB | LEU | 49 | 20.468 | 36.059 | 16.749 | 1.00 | 31.09 | A |
| ATOM | 427 | CG | LEU | 49 | 20.777 | 36.715 | 15.410 | 1.00 | 32.22 | A |
| ATOM | 428 | CD1 | LEU | 49 | 19.570 | 36.601 | 14.491 | 1.00 | 33.49 | A |
| ATOM | 429 | CD2 | LEU | 49 | 21.125 | 38.172 | 15.637 | 1.00 | 31.20 | A |
| ATOM | 430 | C | LEU | 49 | 20.938 | 35.728 | 19.144 | 1.00 | 32.06 | A |
| ATOM | 431 | O | LEU | 49 | 20.652 | 36.561 | 19.985 | 1.00 | 32.69 | A |
| ATOM | 432 | N | GLY | 50 | 20.781 | 34.423 | 19.328 | 1.00 | 32.56 | A |
| ATOM | 433 | H | GLY | 50 | 21.056 | 33.819 | 18.619 | 0.00 | 0.00 | A |
| ATOM | 434 | CA | GLY | 50 | 20.219 | 33.899 | 20.561 | 1.00 | 35.79 | A |
| ATOM | 435 | C | GLY | 50 | 20.976 | 34.321 | 21.814 | 1.00 | 36.88 | A |
| ATOM | 436 | O | GLY | 50 | 20.386 | 34.829 | 22.766 | 1.00 | 40.51 | A |
| ATOM | 437 | N | ALA | 51 | 22.287 | 34.130 | 21.819 | 1.00 | 35.88 | A |
| ATOM | 438 | H | ALA | 51 | 22.714 | 33.708 | 21.043 | 0.00 | 0.00 | A |
| ATOM | 439 | CA | ALA | 51 | 23.085 | 34.507 | 22.965 | 1.00 | 33.52 | A |
| ATOM | 440 | CB | ALA | 51 | 24.498 | 34.074 | 22.761 | 1.00 | 33.00 | A |
| ATOM | 441 | C | ALA | 51 | 23.012 | 36.017 | 23.200 | 1.00 | 34.92 | A |
| ATOM | 442 | O | ALA | 51 | 22.999 | 36.478 | 24.339 | 1.00 | 36.43 | A |
| ATOM | 443 | N | ALA | 52 | 22.931 | 36.791 | 22.130 | 1.00 | 34.18 | A |
| ATOM | 444 | H | ALA | 52 | 22.938 | 36.379 | 21.237 | 0.00 | 0.00 | A |
| ATOM | 445 | CA | ALA | 52 | 22.850 | 38.240 | 22.262 | 1.00 | 35.75 | A |
| ATOM | 446 | CB | ALA | 52 | 23.336 | 38.898 | 20.985 | 1.00 | 36.63 | A |
| ATOM | 447 | C | ALA | 52 | 21.432 | 38.719 | 22.576 | 1.00 | 35.92 | A |
| ATOM | 448 | O | ALA | 52 | 21.192 | 39.915 | 22.712 | 1.00 | 38.03 | A |
| ATOM | 449 | N | ALA | 53 | 20.498 | 37.784 | 22.686 | 1.00 | 36.22 | A |
| ATOM | 450 | H | ALA | 53 | 20.743 | 36.842 | 22.572 | 0.00 | 0.00 | A |
| ATOM | 451 | CA | ALA | 53 | 19.087 | 38.089 | 22.940 | 1.00 | 36.19 | A |
| ATOM | 452 | CB | ALA | 53 | 18.901 | 38.734 | 24.293 | 1.00 | 37.51 | A |
| ATOM | 453 | C | ALA | 53 | 18.509 | 38.971 | 21.845 | 1.00 | 36.35 | A |
| ATOM | 454 | O | ALA | 53 | 17.726 | 39.870 | 22.106 | 1.00 | 39.81 | A |
| ATOM | 455 | N | LEU | 54 | 18.911 | 38.717 | 20.609 | 1.00 | 36.46 | A |
| ATOM | 456 | H | LEU | 54 | 19.550 | 37.995 | 20.460 | 0.00 | 0.00 | A |
| ATOM | 457 | CA | LEU | 54 | 18.416 | 39.485 | 19.487 | 1.00 | 34.04 | A |
| ATOM | 458 | CB | LEU | 54 | 19.562 | 39.971 | 18.616 | 1.00 | 33.54 | A |
| ATOM | 459 | CG | LEU | 54 | 20.483 | 40.981 | 19.291 | 1.00 | 31.52 | A |
| ATOM | 460 | CD1 | LEU | 54 | 21.641 | 41.288 | 18.387 | 1.00 | 32.68 | A |
| ATOM | 461 | CD2 | LEU | 54 | 19.720 | 42.233 | 19.583 | 1.00 | 29.52 | A |
| ATOM | 462 | C | LEU | 54 | 17.401 | 38.709 | 18.664 | 1.00 | 35.10 | A |
| ATOM | 463 | O | LEU | 54 | 17.046 | 39.115 | 17.556 | 1.00 | 37.92 | A |
| ATOM | 464 | N | GLY | 55 | 16.918 | 37.600 | 19.206 | 1.00 | 35.75 | A |
| ATOM | 465 | H | GLY | 55 | 17.225 | 37.273 | 20.080 | 0.00 | 0.00 | A |
| ATOM | 466 | CA | GLY | 55 | 15.902 | 36.832 | 18.512 | 1.00 | 36.80 | A |
| ATOM | 467 | C | GLY | 55 | 16.385 | 35.718 | 17.633 | 1.00 | 38.78 | A |
| ATOM | 468 | O | GLY | 55 | 17.022 | 34.772 | 18.093 | 1.00 | 39.32 | A |
| ATOM | 469 | N | ASP | 56 | 16.011 | 35.795 | 16.372 | 1.00 | 42.32 | A |
| ATOM | 470 | H | ASP | 56 | 15.447 | 36.514 | 16.028 | 0.00 | 0.00 | A |
| ATOM | 471 | CA | ASP | 56 | 16.417 | 34.794 | 15.420 | 1.00 | 46.79 | A |
| ATOM | 472 | CB | ASP | 56 | 15.500 | 33.551 | 15.466 | 1.00 | 48.59 | A |
| ATOM | 473 | CG | ASP | 56 | 14.098 | 33.795 | 14.916 | 1.00 | 50.08 | A |
| ATOM | 474 | OD1 | ASP | 56 | 13.929 | 34.568 | 13.956 | 1.00 | 50.66 | A |
| ATOM | 475 | OD2 | ASP | 56 | 13.149 | 33.160 | 15.421 | 1.00 | 52.31 | A |
| ATOM | 476 | C | ASP | 56 | 16.519 | 35.395 | 14.030 | 1.00 | 48.81 | A |
| ATOM | 477 | O | ASP | 56 | 16.076 | 36.525 | 13.786 | 1.00 | 50.01 | A |
| ATOM | 478 | N | ILE | 57 | 17.085 | 34.616 | 13.118 | 1.00 | 50.51 | A |
| ATOM | 479 | H | ILE | 57 | 17.289 | 33.709 | 13.397 | 0.00 | 0.00 | A |
| ATOM | 480 | CA | ILE | 57 | 17.302 | 35.028 | 11.747 | 1.00 | 49.88 | A |
| ATOM | 481 | CB | ILE | 57 | 18.265 | 34.030 | 11.029 | 1.00 | 46.50 | A |
| ATOM | 482 | CG2 | ILE | 57 | 17.525 | 32.860 | 10.403 | 1.00 | 40.87 | A |
| ATOM | 483 | CG1 | ILE | 57 | 19.064 | 34.756 | 9.969 | 1.00 | 48.12 | A |
| ATOM | 484 | CD1 | ILE | 57 | 19.983 | 33.839 | 9.191 | 1.00 | 53.89 | A |
| ATOM | 485 | C | ILE | 57 | 15.980 | 35.241 | 11.003 | 1.00 | 51.86 | A |
| ATOM | 486 | O | ILE | 57 | 15.888 | 36.138 | 10.174 | 1.00 | 52.56 | A |
| ATOM | 487 | N | GLY | 58 | 14.938 | 34.505 | 11.390 | 1.00 | 54.04 | A |
| ATOM | 488 | H | GLY | 58 | 15.018 | 33.895 | 12.161 | 0.00 | 0.00 | A |
| ATOM | 489 | CA | GLY | 58 | 13.631 | 34.623 | 10.749 | 1.00 | 58.57 | A |
| ATOM | 490 | C | GLY | 58 | 12.850 | 35.867 | 11.146 | 1.00 | 61.78 | A |
| ATOM | 491 | O | GLY | 58 | 11.771 | 36.154 | 10.619 | 1.00 | 62.41 | A |
| ATOM | 492 | N | LYS | 59 | 13.370 | 36.564 | 12.145 | 1.00 | 65.48 | A |
| ATOM | 493 | H | LYS | 59 | 14.139 | 36.186 | 12.624 | 0.00 | 0.00 | A |
| ATOM | 494 | CA | LYS | 59 | 12.778 | 37.798 | 12.626 | 1.00 | 67.57 | A |
| ATOM | 495 | CB | LYS | 59 | 12.871 | 37.871 | 14.158 | 1.00 | 69.95 | A |
| ATOM | 496 | CG | LYS | 59 | 12.595 | 39.248 | 14.751 | 1.00 | 73.60 | A |
| ATOM | 497 | CD | LYS | 59 | 13.439 | 39.491 | 15.994 | 1.00 | 78.34 | A |
| ATOM | 498 | CE | LYS | 59 | 13.886 | 40.964 | 16.113 | 1.00 | 83.80 | A |
| ATOM | 499 | NZ | LYS | 59 | 14.883 | 41.230 | 17.225 | 1.00 | 85.43 | A |
| ATOM | 500 | HZ1 | LYS | 59 | 15.146 | 42.231 | 17.277 | 0.00 | 0.00 | A |
| ATOM | 501 | HZ2 | LYS | 59 | 15.737 | 40.635 | 17.087 | 0.00 | 0.00 | A |
| ATOM | 502 | HZ3 | LYS | 59 | 14.447 | 40.950 | 18.126 | 0.00 | 0.00 | A |
| ATOM | 503 | C | LYS | 59 | 13.606 | 38.912 | 11.999 | 1.00 | 67.49 | A |
| ATOM | 504 | O | LYS | 59 | 13.087 | 39.977 | 11.687 | 1.00 | 70.83 | A |
| ATOM | 505 | N | LEU | 60 | 14.895 | 38.661 | 11.818 | 1.00 | 65.48 | A |
| ATOM | 506 | H | LEU | 60 | 15.256 | 37.794 | 12.098 | 0.00 | 0.00 | A |
| ATOM | 507 | CA | LEU | 60 | 15.784 | 39.650 | 11.236 | 1.00 | 66.29 | A |
| ATOM | 508 | CB | LEU | 60 | 17.209 | 39.400 | 11.688 | 1.00 | 66.92 | A |
| ATOM | 509 | CG | LEU | 60 | 17.791 | 40.434 | 12.633 | 1.00 | 67.54 | A |
| ATOM | 510 | CD1 | LEU | 60 | 17.408 | 40.090 | 14.079 | 1.00 | 66.42 | A |
| ATOM | 511 | CD2 | LEU | 60 | 19.303 | 40.448 | 12.437 | 1.00 | 67.11 | A |
| ATOM | 512 | C | LEU | 60 | 15.779 | 39.718 | 9.712 | 1.00 | 67.19 | A |
| ATOM | 513 | O | LEU | 60 | 15.999 | 40.790 | 9.139 | 1.00 | 67.82 | A |
| ATOM | 514 | N | PHE | 61 | 15.625 | 38.565 | 9.064 | 1.00 | 67.12 | A |
| ATOM | 515 | H | PHE | 61 | 15.472 | 37.762 | 9.582 | 0.00 | 0.00 | A |
| ATOM | 516 | CA | PHE | 61 | 15.620 | 38.466 | 7.601 | 1.00 | 66.38 | A |
| ATOM | 517 | CB | PHE | 61 | 16.989 | 37.953 | 7.076 | 1.00 | 64.98 | A |
| ATOM | 518 | CG | PHE | 61 | 18.203 | 38.485 | 7.829 | 1.00 | 63.28 | A |
| ATOM | 519 | CD1 | PHE | 61 | 18.516 | 39.840 | 7.835 | 1.00 | 62.57 | A |
| ATOM | 520 | CD2 | PHE | 61 | 19.023 | 37.618 | 8.545 | 1.00 | 62.14 | A |
| ATOM | 521 | CE1 | PHE | 61 | 19.624 | 40.315 | 8.549 | 1.00 | 61.04 | A |
| ATOM | 522 | CE2 | PHE | 61 | 20.131 | 38.087 | 9.257 | 1.00 | 60.19 | A |
| ATOM | 523 | CZ | PHE | 61 | 20.429 | 39.433 | 9.260 | 1.00 | 58.98 | A |
| ATOM | 524 | C | PHE | 61 | 14.486 | 37.494 | 7.189 | 1.00 | 66.51 | A |
| ATOM | 525 | O | PHE | 61 | 14.719 | 36.317 | 6.915 | 1.00 | 67.05 | A |
| ATOM | 526 | N | PRO | 62 | 13.243 | 37.992 | 7.128 | 1.00 | 66.73 | A |
| ATOM | 527 | CD | PRO | 62 | 12.902 | 39.379 | 7.480 | 1.00 | 65.79 | A |
| ATOM | 528 | CA | PRO | 62 | 12.029 | 37.248 | 6.773 | 1.00 | 68.15 | A |
| ATOM | 529 | CB | PRO | 62 | 10.941 | 38.304 | 6.933 | 1.00 | 67.13 | A |
| ATOM | 530 | CG | PRO | 62 | 11.501 | 39.232 | 7.952 | 1.00 | 65.97 | A |
| ATOM | 531 | C | PRO | 62 | 11.940 | 36.609 | 5.386 | 1.00 | 71.55 | A |
| ATOM | 532 | O | PRO | 62 | 12.412 | 37.177 | 4.400 | 1.00 | 72.34 | A |
| ATOM | 533 | N | ASP | 63 | 11.267 | 35.456 | 5.318 | 1.00 | 75.18 | A |
| ATOM | 534 | H | ASP | 63 | 10.965 | 35.007 | 6.139 | 0.00 | 0.00 | A |
| ATOM | 535 | CA | ASP | 63 | 11.042 | 34.727 | 4.064 | 1.00 | 78.62 | A |
| ATOM | 536 | CB | ASP | 63 | 10.181 | 33.491 | 4.293 | 1.00 | 79.66 | A |
| ATOM | 537 | CG | ASP | 63 | 10.859 | 32.464 | 5.138 | 1.00 | 83.31 | A |
| ATOM | 538 | OD1 | ASP | 63 | 11.369 | 32.844 | 6.213 | 1.00 | 88.01 | A |
| ATOM | 539 | OD2 | ASP | 63 | 10.879 | 31.279 | 4.737 | 1.00 | 84.56 | A |
| ATOM | 540 | C | ASP | 63 | 10.227 | 35.632 | 3.192 | 1.00 | 81.76 | A |
| ATOM | 541 | O | ASP | 63 | 10.337 | 35.611 | 1.964 | 1.00 | 83.71 | A |
| ATOM | 542 | N | THR | 64 | 9.337 | 36.355 | 3.864 | 1.00 | 84.86 | A |
| ATOM | 543 | H | THR | 64 | 9.314 | 36.225 | 4.830 | 0.00 | 0.00 | A |
| ATOM | 544 | CA | THR | 64 | 8.425 | 37.308 | 3.248 | 1.00 | 87.36 | A |
| ATOM | 545 | CB | THR | 64 | 7.524 | 37.998 | 4.337 | 1.00 | 88.93 | A |
| ATOM | 546 | OG1 | THR | 64 | 8.274 | 38.994 | 5.059 | 1.00 | 90.59 | A |
| ATOM | 547 | HG1 | THR | 64 | 8.477 | 39.758 | 4.500 | 0.00 | 0.00 | A |
| ATOM | 548 | CG2 | THR | 64 | 6.998 | 36.953 | 5.336 | 1.00 | 88.86 | A |
| ATOM | 549 | C | THR | 64 | 9.183 | 38.370 | 2.434 | 1.00 | 87.15 | A |
| ATOM | 550 | O | THR | 64 | 8.837 | 38.650 | 1.283 | 1.00 | 88.81 | A |
| ATOM | 551 | N | ASP | 65 | 10.230 | 38.938 | 3.023 | 1.00 | 85.20 | A |
| ATOM | 552 | H | ASP | 65 | 10.527 | 38.653 | 3.909 | 0.00 | 0.00 | A |
| ATOM | 553 | CA | ASP | 65 | 11.003 | 39.954 | 2.343 | 1.00 | 83.08 | A |
| ATOM | 554 | CB | ASP | 65 | 11.933 | 40.647 | 3.321 | 1.00 | 83.06 | A |
| ATOM | 555 | CG | ASP | 65 | 12.343 | 42.009 | 2.849 | 1.00 | 83.76 | A |
| ATOM | 556 | OD1 | ASP | 65 | 12.572 | 42.171 | 1.629 | 1.00 | 83.60 | A |
| ATOM | 557 | OD2 | ASP | 65 | 12.422 | 42.920 | 3.698 | 1.00 | 85.48 | A |
| ATOM | 558 | C | ASP | 65 | 11.782 | 39.335 | 1.189 | 1.00 | 82.81 | A |
| ATOM | 559 | O | ASP | 65 | 12.714 | 38.543 | 1.387 | 1.00 | 82.23 | A |
| ATOM | 560 | N | PRO | 66 | 11.404 | 39.694 | −0.046 | 1.00 | 83.01 | A |
| ATOM | 561 | CD | PRO | 66 | 10.385 | 40.721 | −0.329 | 1.00 | 84.12 | A |
| ATOM | 562 | CA | PRO | 66 | 12.008 | 39.218 | −1.292 | 1.00 | 82.43 | A |
| ATOM | 563 | CB | PRO | 66 | 11.046 | 39.747 | −2.350 | 1.00 | 83.11 | A |
| ATOM | 564 | CG | PRO | 66 | 10.655 | 41.065 | −1.781 | 1.00 | 83.63 | A |
| ATOM | 565 | C | PRO | 66 | 13.423 | 39.740 | −1.509 | 1.00 | 80.78 | A |
| ATOM | 566 | O | PRO | 66 | 14.080 | 39.382 | −2.488 | 1.00 | 80.72 | A |
| ATOM | 567 | N | ALA | 67 | 13.876 | 40.611 | −0.616 | 1.00 | 78.31 | A |
| ATOM | 568 | H | ALA | 67 | 13.309 | 40.951 | 0.117 | 0.00 | 0.00 | A |
| ATOM | 569 | CA | ALA | 67 | 15.225 | 41.142 | −0.710 | 1.00 | 77.87 | A |
| ATOM | 570 | CB | ALA | 67 | 15.373 | 42.341 | 0.212 | 1.00 | 78.30 | A |
| ATOM | 571 | C | ALA | 67 | 16.188 | 40.027 | −0.288 | 1.00 | 77.86 | A |
| ATOM | 572 | O | ALA | 67 | 17.355 | 39.969 | −0.706 | 1.00 | 79.36 | A |
| ATOM | 573 | N | PHE | 68 | 15.667 | 39.111 | 0.517 | 1.00 | 75.08 | A |
| ATOM | 574 | H | PHE | 68 | 14.735 | 39.205 | 0.811 | 0.00 | 0.00 | A |
| ATOM | 575 | CA | PHE | 68 | 16.461 | 38.011 | 1.016 | 1.00 | 71.36 | A |
| ATOM | 576 | CB | PHE | 68 | 15.986 | 37.672 | 2.423 | 1.00 | 68.67 | A |
| ATOM | 577 | CG | PHE | 68 | 15.950 | 38.863 | 3.342 | 1.00 | 64.36 | A |
| ATOM | 578 | CD1 | PHE | 68 | 14.802 | 39.172 | 4.062 | 1.00 | 61.72 | A |
| ATOM | 579 | CD2 | PHE | 68 | 17.071 | 39.674 | 3.490 | 1.00 | 61.25 | A |
| ATOM | 580 | CE1 | PHE | 68 | 14.773 | 40.266 | 4.915 | 1.00 | 59.55 | A |
| ATOM | 581 | CE2 | PHE | 68 | 17.050 | 40.769 | 4.341 | 1.00 | 59.58 | A |
| ATOM | 582 | CZ | PHE | 68 | 15.898 | 41.065 | 5.056 | 1.00 | 59.60 | A |
| ATOM | 583 | C | PHE | 68 | 16.452 | 36.782 | 0.115 | 1.00 | 70.65 | A |
| ATOM | 584 | O | PHE | 68 | 17.121 | 35.791 | 0.406 | 1.00 | 71.05 | A |
| ATOM | 585 | N | LYS | 69 | 15.701 | 36.831 | −0.978 | 1.00 | 69.82 | A |
| ATOM | 586 | H | LYS | 69 | 15.259 | 37.664 | −1.238 | 0.00 | 0.00 | A |
| ATOM | 587 | CA | LYS | 69 | 15.658 | 35.691 | −1.877 | 1.00 | 71.04 | A |
| ATOM | 588 | CB | LYS | 69 | 14.625 | 35.895 | −2.972 | 1.00 | 74.41 | A |
| ATOM | 589 | CG | LYS | 69 | 14.518 | 34.708 | −3.898 | 1.00 | 80.75 | A |
| ATOM | 590 | CD | LYS | 69 | 13.979 | 35.148 | −5.236 | 1.00 | 88.48 | A |
| ATOM | 591 | CE | LYS | 69 | 14.316 | 34.142 | −6.331 | 1.00 | 93.94 | A |
| ATOM | 592 | NZ | LYS | 69 | 14.057 | 34.704 | −7.700 | 1.00 | 97.54 | A |
| ATOM | 593 | HZ1 | LYS | 69 | 14.309 | 33.986 | −8.410 | 0.00 | 0.00 | A |
| ATOM | 594 | HZ2 | LYS | 69 | 14.646 | 35.549 | −7.842 | 0.00 | 0.00 | A |
| ATOM | 595 | HZ3 | LYS | 69 | 13.052 | 34.951 | −7.798 | 0.00 | 0.00 | A |
| ATOM | 596 | C | LYS | 69 | 17.041 | 35.497 | −2.496 | 1.00 | 70.29 | A |
| ATOM | 597 | O | LYS | 69 | 17.621 | 36.440 | −3.040 | 1.00 | 71.48 | A |
| ATOM | 598 | N | GLY | 70 | 17.538 | 34.261 | −2.438 | 1.00 | 67.56 | A |
| ATOM | 599 | H | GLY | 70 | 17.039 | 33.499 | −2.195 | 0.00 | 0.00 | A |
| ATOM | 600 | CA | GLY | 70 | 18.854 | 33.922 | −2.947 | 1.00 | 61.75 | A |
| ATOM | 601 | C | GLY | 70 | 19.984 | 34.434 | −2.070 | 1.00 | 58.57 | A |
| ATOM | 602 | O | GLY | 70 | 21.147 | 34.195 | −2.389 | 1.00 | 59.45 | A |
| ATOM | 603 | N | ALA | 71 | 19.655 | 35.060 | −0.937 | 1.00 | 54.87 | A |
| ATOM | 604 | H | ALA | 71 | 18.711 | 35.134 | −0.691 | 0.00 | 0.00 | A |
| ATOM | 605 | CA | ALA | 71 | 20.660 | 35.644 | −0.045 | 1.00 | 51.47 | A |
| ATOM | 606 | CB | ALA | 71 | 20.009 | 36.234 | 1.192 | 1.00 | 50.56 | A |
| ATOM | 607 | C | ALA | 71 | 21.808 | 34.734 | 0.356 | 1.00 | 49.57 | A |
| ATOM | 608 | O | ALA | 71 | 21.616 | 33.567 | 0.701 | 1.00 | 52.68 | A |
| ATOM | 609 | N | ASP | 72 | 23.009 | 35.284 | 0.290 | 1.00 | 44.98 | A |
| ATOM | 610 | H | ASP | 72 | 23.118 | 36.214 | 0.003 | 0.00 | 0.00 | A |
| ATOM | 611 | CA | ASP | 72 | 24.209 | 34.569 | 0.658 | 1.00 | 39.97 | A |
| ATOM | 612 | CB | ASP | 72 | 25.399 | 35.353 | 0.124 | 1.00 | 39.91 | A |
| ATOM | 613 | CG | ASP | 72 | 26.725 | 34.897 | 0.681 | 1.00 | 44.97 | A |
| ATOM | 614 | OD1 | ASP | 72 | 26.781 | 34.214 | 1.722 | 1.00 | 50.04 | A |
| ATOM | 615 | OD2 | ASP | 72 | 27.758 | 35.270 | 0.088 | 1.00 | 49.57 | A |
| ATOM | 616 | C | ASP | 72 | 24.164 | 34.584 | 2.177 | 1.00 | 39.39 | A |
| ATOM | 617 | O | ASP | 72 | 24.232 | 35.643 | 2.795 | 1.00 | 40.77 | A |
| ATOM | 618 | N | SER | 73 | 24.056 | 33.415 | 2.792 | 1.00 | 36.91 | A |
| ATOM | 619 | H | SER | 73 | 24.059 | 32.605 | 2.242 | 0.00 | 0.00 | A |
| ATOM | 620 | CA | SER | 73 | 23.985 | 33.345 | 4.243 | 1.00 | 34.67 | A |
| ATOM | 621 | CB | SER | 73 | 23.720 | 31.925 | 4.690 | 1.00 | 34.49 | A |
| ATOM | 622 | OG | SER | 73 | 22.424 | 31.527 | 4.285 | 1.00 | 34.67 | A |
| ATOM | 623 | HG | SER | 73 | 22.614 | 31.527 | 3.337 | 0.00 | 0.00 | A |
| ATOM | 624 | C | SER | 73 | 25.145 | 33.936 | 5.029 | 1.00 | 35.77 | A |
| ATOM | 625 | O | SER | 73 | 24.980 | 34.254 | 6.207 | 1.00 | 37.56 | A |
| ATOM | 626 | N | ARG | 74 | 26.313 | 34.065 | 4.403 | 1.00 | 36.11 | A |
| ATOM | 627 | H | ARG | 74 | 26.383 | 33.728 | 3.488 | 0.00 | 0.00 | A |
| ATOM | 628 | CA | ARG | 74 | 27.473 | 34.642 | 5.066 | 1.00 | 35.20 | A |
| ATOM | 629 | CB | ARG | 74 | 28.731 | 34.490 | 4.252 | 1.00 | 31.95 | A |
| ATOM | 630 | CG | ARG | 74 | 29.288 | 33.104 | 4.285 | 1.00 | 33.83 | A |
| ATOM | 631 | CD | ARG | 74 | 30.599 | 33.062 | 3.543 | 1.00 | 37.00 | A |
| ATOM | 632 | NE | ARG | 74 | 31.631 | 33.803 | 4.258 | 1.00 | 38.05 | A |
| ATOM | 633 | HE | ARG | 74 | 31.381 | 34.195 | 5.104 | 0.00 | 0.00 | A |
| ATOM | 634 | CZ | ARG | 74 | 32.859 | 34.003 | 3.807 | 1.00 | 37.27 | A |
| ATOM | 635 | NH1 | ARG | 74 | 33.734 | 34.677 | 4.544 | 1.00 | 41.80 | A |
| ATOM | 636 | HH11 | ARG | 74 | 33.445 | 35.003 | 5.458 | 0.00 | 0.00 | A |
| ATOM | 637 | HH12 | ARG | 74 | 34.704 | 34.865 | 4.324 | 0.00 | 0.00 | A |
| ATOM | 638 | NH2 | ARG | 74 | 33.195 | 33.559 | 2.606 | 1.00 | 35.06 | A |
| ATOM | 639 | HH21 | ARG | 74 | 32.527 | 33.068 | 2.040 | 0.00 | 0.00 | A |
| ATOM | 640 | HH22 | ARG | 74 | 34.127 | 33.680 | 2.253 | 0.00 | 0.00 | A |
| ATOM | 641 | C | ARG | 74 | 27.197 | 36.085 | 5.194 | 1.00 | 36.89 | A |
| ATOM | 642 | O | ARG | 74 | 27.658 | 36.728 | 6.126 | 1.00 | 39.99 | A |
| ATOM | 643 | N | GLU | 75 | 26.469 | 36.611 | 4.225 | 1.00 | 39.34 | A |
| ATOM | 644 | H | GLU | 75 | 26.172 | 36.063 | 3.459 | 0.00 | 0.00 | A |
| ATOM | 645 | CA | GLU | 75 | 26.107 | 38.016 | 4.251 | 1.00 | 43.69 | A |
| ATOM | 646 | CB | GLU | 75 | 25.405 | 38.397 | 2.965 | 1.00 | 49.06 | A |
| ATOM | 647 | CG | GLU | 75 | 25.732 | 39.764 | 2.441 | 1.00 | 58.61 | A |
| ATOM | 648 | CD | GLU | 75 | 25.521 | 39.823 | 0.937 | 1.00 | 65.82 | A |
| ATOM | 649 | OE1 | GLU | 75 | 24.347 | 39.852 | 0.497 | 1.00 | 67.54 | A |
| ATOM | 650 | OE2 | GLU | 75 | 26.534 | 39.797 | 0.196 | 1.00 | 71.24 | A |
| ATOM | 651 | C | GLU | 75 | 25.181 | 38.219 | 5.443 | 1.00 | 41.79 | A |
| ATOM | 652 | O | GLU | 75 | 25.344 | 39.183 | 6.189 | 1.00 | 42.71 | A |
| ATOM | 653 | N | LEU | 76 | 24.244 | 37.291 | 5.645 | 1.00 | 38.47 | A |
| ATOM | 654 | H | LEU | 76 | 24.174 | 36.559 | 4.997 | 0.00 | 0.00 | A |
| ATOM | 655 | CA | LEU | 76 | 23.324 | 37.373 | 6.777 | 1.00 | 35.34 | A |
| ATOM | 656 | CB | LEU | 76 | 22.195 | 36.353 | 6.659 | 1.00 | 36.17 | A |
| ATOM | 657 | CG | LEU | 76 | 21.340 | 36.406 | 5.387 | 1.00 | 37.48 | A |
| ATOM | 658 | CD1 | LEU | 76 | 20.128 | 35.507 | 5.531 | 1.00 | 39.41 | A |
| ATOM | 659 | CD2 | LEU | 76 | 20.872 | 37.807 | 5.143 | 1.00 | 41.52 | A |
| ATOM | 660 | C | LEU | 76 | 24.084 | 37.151 | 8.078 | 1.00 | 34.45 | A |
| ATOM | 661 | O | LEU | 76 | 23.808 | 37.811 | 9.076 | 1.00 | 36.98 | A |
| ATOM | 662 | N | LEU | 77 | 25.050 | 36.238 | 8.071 | 1.00 | 32.22 | A |
| ATOM | 663 | H | LEU | 77 | 25.239 | 35.738 | 7.259 | 0.00 | 0.00 | A |
| ATOM | 664 | CA | LEU | 77 | 25.838 | 35.977 | 9.268 | 1.00 | 30.77 | A |
| ATOM | 665 | CB | LEU | 77 | 26.859 | 34.873 | 9.023 | 1.00 | 29.28 | A |
| ATOM | 666 | CG | LEU | 77 | 27.944 | 34.708 | 10.097 | 1.00 | 26.98 | A |
| ATOM | 667 | CD1 | LEU | 77 | 27.307 | 34.498 | 11.453 | 1.00 | 26.01 | A |
| ATOM | 668 | CD2 | LEU | 77 | 28.860 | 33.551 | 9.746 | 1.00 | 21.32 | A |
| ATOM | 669 | C | LEU | 77 | 26.571 | 37.232 | 9.711 | 1.00 | 32.43 | A |
| ATOM | 670 | O | LEU | 77 | 26.551 | 37.583 | 10.885 | 1.00 | 35.39 | A |
| ATOM | 671 | N | ARG | 78 | 27.208 | 37.917 | 8.772 | 1.00 | 34.22 | A |
| ATOM | 672 | H | ARG | 78 | 27.201 | 37.585 | 7.849 | 0.00 | 0.00 | A |
| ATOM | 673 | CA | ARG | 78 | 27.948 | 39.126 | 9.095 | 1.00 | 34.89 | A |
| ATOM | 674 | CB | ARG | 78 | 28.732 | 39.602 | 7.886 | 1.00 | 34.05 | A |
| ATOM | 675 | CG | ARG | 78 | 29.753 | 38.607 | 7.419 | 1.00 | 39.13 | A |
| ATOM | 676 | CD | ARG | 78 | 30.669 | 39.198 | 6.372 | 1.00 | 43.99 | A |
| ATOM | 677 | NE | ARG | 78 | 30.781 | 38.313 | 5.221 | 1.00 | 51.06 | A |
| ATOM | 678 | HE | ARG | 78 | 31.382 | 37.541 | 5.397 | 0.00 | 0.00 | A |
| ATOM | 679 | CZ | ARG | 78 | 30.101 | 38.477 | 4.089 | 1.00 | 53.91 | A |
| ATOM | 680 | NH1 | ARG | 78 | 30.253 | 37.611 | 3.087 | 1.00 | 57.23 | A |
| ATOM | 681 | HH11 | ARG | 78 | 30.857 | 36.822 | 3.206 | 0.00 | 0.00 | A |
| ATOM | 682 | HH12 | ARG | 78 | 29.740 | 37.667 | 2.218 | 0.00 | 0.00 | A |
| ATOM | 683 | NH2 | ARG | 78 | 29.277 | 39.518 | 3.955 | 1.00 | 57.96 | A |
| ATOM | 684 | HH21 | ARG | 78 | 29.158 | 40.170 | 4.708 | 0.00 | 0.00 | A |
| ATOM | 685 | HH22 | ARG | 78 | 28.722 | 39.671 | 3.124 | 0.00 | 0.00 | A |
| ATOM | 686 | C | ARG | 78 | 27.089 | 40.256 | 9.653 | 1.00 | 35.89 | A |
| ATOM | 687 | O | ARG | 78 | 27.516 | 40.953 | 10.566 | 1.00 | 39.01 | A |
| ATOM | 688 | N | GLU | 79 | 25.881 | 40.429 | 9.125 | 1.00 | 35.00 | A |
| ATOM | 689 | H | GLU | 79 | 25.583 | 39.856 | 8.387 | 0.00 | 0.00 | A |
| ATOM | 690 | CA | GLU | 79 | 24.989 | 41.478 | 9.600 | 1.00 | 35.61 | A |
| ATOM | 691 | CB | GLU | 79 | 23.752 | 41.574 | 8.723 | 1.00 | 38.12 | A |
| ATOM | 692 | CG | GLU | 79 | 22.735 | 42.605 | 9.205 | 1.00 | 44.19 | A |
| ATOM | 693 | CD | GLU | 79 | 23.275 | 44.037 | 9.258 | 1.00 | 48.14 | A |
| ATOM | 694 | OE1 | GLU | 79 | 24.453 | 44.285 | 8.902 | 1.00 | 52.30 | A |
| ATOM | 695 | OE2 | GLU | 79 | 22.501 | 44.930 | 9.658 | 1.00 | 47.94 | A |
| ATOM | 696 | C | GLU | 79 | 24.551 | 41.218 | 11.022 | 1.00 | 36.88 | A |
| ATOM | 697 | O | GLU | 79 | 24.613 | 42.102 | 11.875 | 1.00 | 38.40 | A |
| ATOM | 698 | N | ALA | 80 | 24.034 | 40.021 | 11.256 | 1.00 | 36.17 | A |
| ATOM | 699 | H | ALA | 80 | 23.938 | 39.393 | 10.506 | 0.00 | 0.00 | A |
| ATOM | 700 | CA | ALA | 80 | 23.611 | 39.644 | 12.581 | 1.00 | 35.43 | A |
| ATOM | 701 | CB | ALA | 80 | 23.231 | 38.201 | 12.603 | 1.00 | 36.92 | A |
| ATOM | 702 | C | ALA | 80 | 24.800 | 39.883 | 13.491 | 1.00 | 36.03 | A |
| ATOM | 703 | O | ALA | 80 | 24.663 | 40.481 | 14.550 | 1.00 | 37.36 | A |
| ATOM | 704 | N | TRP | 81 | 25.985 | 39.482 | 13.051 | 1.00 | 34.52 | A |
| ATOM | 705 | H | TRP | 81 | 26.070 | 39.036 | 12.182 | 0.00 | 0.00 | A |
| ATOM | 706 | CA | TRP | 81 | 27.163 | 39.688 | 13.872 | 1.00 | 36.48 | A |
| ATOM | 707 | CB | TRP | 81 | 28.388 | 39.029 | 13.258 | 1.00 | 34.24 | A |
| ATOM | 708 | CG | TRP | 81 | 29.612 | 39.109 | 14.125 | 1.00 | 35.45 | A |
| ATOM | 709 | CD2 | TRP | 81 | 29.739 | 38.665 | 15.483 | 1.00 | 36.70 | A |
| ATOM | 710 | CE2 | TRP | 81 | 31.077 | 38.903 | 15.878 | 1.00 | 35.64 | A |
| ATOM | 711 | CE3 | TRP | 81 | 28.859 | 38.080 | 16.403 | 1.00 | 36.81 | A |
| ATOM | 712 | CD1 | TRP | 81 | 30.837 | 39.586 | 13.766 | 1.00 | 37.71 | A |
| ATOM | 713 | NE1 | TRP | 81 | 31.724 | 39.463 | 14.812 | 1.00 | 37.51 | A |
| ATOM | 714 | HE1 | TRP | 81 | 32.683 | 39.695 | 14.795 | 0.00 | 0.00 | A |
| ATOM | 715 | CZ2 | TRP | 81 | 31.551 | 38.581 | 17.141 | 1.00 | 35.63 | A |
| ATOM | 716 | CZ3 | TRP | 81 | 29.332 | 37.757 | 17.662 | 1.00 | 36.48 | A |
| ATOM | 717 | CH2 | TRP | 81 | 30.667 | 38.009 | 18.019 | 1.00 | 37.36 | A |
| ATOM | 718 | C | TRP | 81 | 27.428 | 41.172 | 14.068 | 1.00 | 39.20 | A |
| ATOM | 719 | O | TRP | 81 | 27.865 | 41.597 | 15.137 | 1.00 | 40.70 | A |
| ATOM | 720 | N | ARG | 82 | 27.163 | 41.964 | 13.039 | 1.00 | 41.20 | A |
| ATOM | 721 | H | ARG | 82 | 26.808 | 41.584 | 12.212 | 0.00 | 0.00 | A |
| ATOM | 722 | CA | ARG | 82 | 27.385 | 43.395 | 13.125 | 1.00 | 43.01 | A |
| ATOM | 723 | CB | ARG | 82 | 26.984 | 44.083 | 11.824 | 1.00 | 45.94 | A |
| ATOM | 724 | CG | ARG | 82 | 27.350 | 45.561 | 11.768 | 1.00 | 51.33 | A |
| ATOM | 725 | CD | ARG | 82 | 26.745 | 46.269 | 10.545 | 1.00 | 55.76 | A |
| ATOM | 726 | NE | ARG | 82 | 25.280 | 46.291 | 10.560 | 1.00 | 58.28 | A |
| ATOM | 727 | HE | ARG | 82 | 24.844 | 45.831 | 9.811 | 0.00 | 0.00 | A |
| ATOM | 728 | CZ | ARG | 82 | 24.536 | 46.903 | 11.479 | 1.00 | 59.82 | A |
| ATOM | 729 | NH1 | ARG | 82 | 23.214 | 46.852 | 11.398 | 1.00 | 60.94 | A |
| ATOM | 730 | HH11 | ARG | 82 | 22.843 | 46.338 | 10.611 | 0.00 | 0.00 | A |
| ATOM | 731 | HH12 | ARG | 82 | 22.566 | 47.270 | 12.026 | 0.00 | 0.00 | A |
| ATOM | 732 | NH2 | ARG | 82 | 25.110 | 47.586 | 12.465 | 1.00 | 61.01 | A |
| ATOM | 733 | HH21 | ARG | 82 | 26.109 | 47.637 | 12.514 | 0.00 | 0.00 | A |
| ATOM | 734 | HH22 | ARG | 82 | 24.582 | 48.056 | 13.173 | 0.00 | 0.00 | A |
| ATOM | 735 | C | ARG | 82 | 26.520 | 43.907 | 14.253 | 1.00 | 44.80 | A |
| ATOM | 736 | O | ARG | 82 | 27.013 | 44.500 | 15.213 | 1.00 | 46.01 | A |
| ATOM | 737 | N | ARG | 83 | 25.232 | 43.605 | 14.163 | 1.00 | 46.09 | A |
| ATOM | 738 | H | ARG | 83 | 24.935 | 43.057 | 13.412 | 0.00 | 0.00 | A |
| ATOM | 739 | CA | ARG | 83 | 24.272 | 44.031 | 15.162 | 1.00 | 47.04 | A |
| ATOM | 740 | CB | ARG | 83 | 22.868 | 43.607 | 14.753 | 1.00 | 48.41 | A |
| ATOM | 741 | CG | ARG | 83 | 22.515 | 44.010 | 13.345 | 1.00 | 54.45 | A |
| ATOM | 742 | CD | ARG | 83 | 21.028 | 43.865 | 13.065 | 1.00 | 60.36 | A |
| ATOM | 743 | NE | ARG | 83 | 20.769 | 44.120 | 11.649 | 1.00 | 67.66 | A |
| ATOM | 744 | HE | ARG | 83 | 21.579 | 44.220 | 11.109 | 0.00 | 0.00 | A |
| ATOM | 745 | CZ | ARG | 83 | 19.567 | 44.138 | 11.074 | 1.00 | 71.21 | A |
| ATOM | 746 | NH1 | ARG | 83 | 19.464 | 44.382 | 9.764 | 1.00 | 73.92 | A |
| ATOM | 747 | HH11 | ARG | 83 | 20.326 | 44.527 | 9.248 | 0.00 | 0.00 | A |
| ATOM | 748 | HH12 | ARG | 83 | 18.604 | 44.401 | 9.251 | 0.00 | 0.00 | A |
| ATOM | 749 | NH2 | ARG | 83 | 18.477 | 43.905 | 11.800 | 1.00 | 73.75 | A |
| ATOM | 750 | HH21 | ARG | 83 | 18.571 | 43.717 | 12.780 | 0.00 | 0.00 | A |
| ATOM | 751 | HH22 | ARG | 83 | 17.549 | 43.896 | 11.415 | 0.00 | 0.00 | A |
| ATOM | 752 | C | ARG | 83 | 24.603 | 43.474 | 16.538 | 1.00 | 47.66 | A |
| ATOM | 753 | O | ARG | 83 | 24.438 | 44.164 | 17.543 | 1.00 | 51.10 | A |
| ATOM | 754 | N | ILE | 84 | 25.107 | 42.247 | 16.586 | 1.00 | 45.77 | A |
| ATOM | 755 | H | ILE | 84 | 25.265 | 41.764 | 15.755 | 0.00 | 0.00 | A |
| ATOM | 756 | CA | ILE | 84 | 25.433 | 41.628 | 17.860 | 1.00 | 44.71 | A |
| ATOM | 757 | CB | ILE | 84 | 25.816 | 40.142 | 17.677 | 1.00 | 43.63 | A |
| ATOM | 758 | CG2 | ILE | 84 | 26.330 | 39.548 | 18.998 | 1.00 | 39.67 | A |
| ATOM | 759 | CG1 | ILE | 84 | 24.606 | 39.360 | 17.164 | 1.00 | 41.19 | A |
| ATOM | 760 | CD1 | ILE | 84 | 24.919 | 37.949 | 16.774 | 1.00 | 40.05 | A |
| ATOM | 761 | C | ILE | 84 | 26.550 | 42.377 | 18.567 | 1.00 | 45.94 | A |
| ATOM | 762 | O | ILE | 84 | 26.493 | 42.609 | 19.778 | 1.00 | 46.71 | A |
| ATOM | 763 | N | GLN | 85 | 27.557 | 42.772 | 17.803 | 1.00 | 46.56 | A |
| ATOM | 764 | H | GLN | 85 | 27.535 | 42.576 | 16.843 | 0.00 | 0.00 | A |
| ATOM | 765 | CA | GLN | 85 | 28.691 | 43.486 | 18.365 | 1.00 | 48.49 | A |
| ATOM | 766 | CB | GLN | 85 | 29.799 | 43.611 | 17.332 | 1.00 | 49.27 | A |
| ATOM | 767 | CG | GLN | 85 | 30.390 | 42.297 | 16.886 | 1.00 | 51.51 | A |
| ATOM | 768 | CD | GLN | 85 | 31.595 | 42.494 | 16.002 | 1.00 | 52.54 | A |
| ATOM | 769 | OE1 | GLN | 85 | 32.734 | 42.396 | 16.458 | 1.00 | 53.13 | A |
| ATOM | 770 | NE2 | GLN | 85 | 31.354 | 42.799 | 14.728 | 1.00 | 53.73 | A |
| ATOM | 771 | HE21 | GLN | 85 | 30.422 | 42.871 | 14.438 | 0.00 | 0.00 | A |
| ATOM | 772 | HE22 | GLN | 85 | 32.132 | 42.925 | 14.152 | 0.00 | 0.00 | A |
| ATOM | 773 | C | GLN | 85 | 28.266 | 44.868 | 18.817 | 1.00 | 49.21 | A |
| ATOM | 774 | O | GLN | 85 | 28.763 | 45.387 | 19.818 | 1.00 | 50.82 | A |
| ATOM | 775 | N | ALA | 86 | 27.356 | 45.465 | 18.057 | 1.00 | 48.82 | A |
| ATOM | 776 | H | ALA | 86 | 27.034 | 44.996 | 17.256 | 0.00 | 0.00 | A |
| ATOM | 777 | CA | ALA | 86 | 26.833 | 46.787 | 18.362 | 1.00 | 47.23 | A |
| ATOM | 778 | CB | ALA | 86 | 25.828 | 47.205 | 17.313 | 1.00 | 46.13 | A |
| ATOM | 779 | C | ALA | 86 | 26.182 | 46.778 | 19.734 | 1.00 | 47.81 | A |
| ATOM | 780 | O | ALA | 86 | 26.259 | 47.764 | 20.451 | 1.00 | 49.75 | A |
| ATOM | 781 | N | LYS | 87 | 25.540 | 45.664 | 20.091 | 1.00 | 48.61 | A |
| ATOM | 782 | H | LYS | 87 | 25.487 | 44.920 | 19.453 | 0.00 | 0.00 | A |
| ATOM | 783 | CA | LYS | 87 | 24.890 | 45.521 | 21.393 | 1.00 | 48.26 | A |
| ATOM | 784 | CB | LYS | 87 | 23.935 | 44.320 | 21.369 | 1.00 | 50.54 | A |
| ATOM | 785 | CG | LYS | 87 | 22.937 | 44.230 | 22.543 | 1.00 | 57.30 | A |
| ATOM | 786 | CD | LYS | 87 | 21.932 | 43.043 | 22.381 | 1.00 | 59.87 | A |
| ATOM | 787 | CE | LYS | 87 | 20.886 | 42.927 | 23.524 | 1.00 | 59.12 | A |
| ATOM | 788 | NZ | LYS | 87 | 21.151 | 41.849 | 24.546 | 1.00 | 56.97 | A |
| ATOM | 789 | HZ1 | LYS | 87 | 20.398 | 41.886 | 25.291 | 0.00 | 0.00 | A |
| ATOM | 790 | HZ2 | LYS | 87 | 22.062 | 41.928 | 25.034 | 0.00 | 0.00 | A |
| ATOM | 791 | HZ3 | LYS | 87 | 21.095 | 40.925 | 24.087 | 0.00 | 0.00 | A |
| ATOM | 792 | C | LYS | 87 | 25.978 | 45.365 | 22.475 | 1.00 | 47.28 | A |
| ATOM | 793 | O | LYS | 87 | 25.694 | 45.262 | 23.664 | 1.00 | 47.47 | A |
| ATOM | 794 | N | GLY | 88 | 27.231 | 45.348 | 22.042 | 1.00 | 46.52 | A |
| ATOM | 795 | H | GLY | 88 | 27.432 | 45.402 | 21.099 | 0.00 | 0.00 | A |
| ATOM | 796 | CA | GLY | 88 | 28.337 | 45.242 | 22.964 | 1.00 | 48.00 | A |
| ATOM | 797 | C | GLY | 88 | 28.948 | 43.871 | 23.164 | 1.00 | 50.62 | A |
| ATOM | 798 | O | GLY | 88 | 29.821 | 43.711 | 24.016 | 1.00 | 54.79 | A |
| ATOM | 799 | N | TYR | 89 | 28.572 | 42.883 | 22.365 | 1.00 | 48.91 | A |
| ATOM | 800 | H | TYR | 89 | 27.965 | 43.045 | 21.615 | 0.00 | 0.00 | A |
| ATOM | 801 | CA | TYR | 89 | 29.129 | 41.562 | 22.586 | 1.00 | 44.46 | A |
| ATOM | 802 | CB | TYR | 89 | 28.056 | 40.501 | 22.332 | 1.00 | 44.47 | A |
| ATOM | 803 | CG | TYR | 89 | 26.831 | 40.622 | 23.211 | 1.00 | 40.84 | A |
| ATOM | 804 | CD1 | TYR | 89 | 25.707 | 41.310 | 22.771 | 1.00 | 42.82 | A |
| ATOM | 805 | CE1 | TYR | 89 | 24.556 | 41.397 | 23.559 | 1.00 | 43.87 | A |
| ATOM | 806 | CD2 | TYR | 89 | 26.785 | 40.025 | 24.469 | 1.00 | 39.22 | A |
| ATOM | 807 | CE2 | TYR | 89 | 25.644 | 40.110 | 25.275 | 1.00 | 39.80 | A |
| ATOM | 808 | CZ | TYR | 89 | 24.526 | 40.797 | 24.811 | 1.00 | 44.51 | A |
| ATOM | 809 | OH | TYR | 89 | 23.367 | 40.883 | 25.574 | 1.00 | 46.03 | A |
| ATOM | 810 | HH | TYR | 89 | 23.534 | 40.479 | 26.435 | 0.00 | 0.00 | A |
| ATOM | 811 | C | TYR | 89 | 30.365 | 41.281 | 21.747 | 1.00 | 43.62 | A |
| ATOM | 812 | O | TYR | 89 | 30.599 | 41.959 | 20.747 | 1.00 | 42.23 | A |
| ATOM | 813 | N | THR | 90 | 31.172 | 40.320 | 22.211 | 1.00 | 43.30 | A |
| ATOM | 814 | H | THR | 90 | 30.941 | 39.890 | 23.063 | 0.00 | 0.00 | A |
| ATOM | 815 | CA | THR | 90 | 32.386 | 39.844 | 21.529 | 1.00 | 45.09 | A |
| ATOM | 816 | CB | THR | 90 | 33.695 | 40.250 | 22.235 | 1.00 | 44.73 | A |
| ATOM | 817 | OG1 | THR | 90 | 33.687 | 39.790 | 23.590 | 1.00 | 49.84 | A |
| ATOM | 818 | HG1 | THR | 90 | 32.998 | 40.286 | 24.051 | 0.00 | 0.00 | A |
| ATOM | 819 | CG2 | THR | 90 | 33.848 | 41.723 | 22.228 | 1.00 | 48.37 | A |
| ATOM | 820 | C | THR | 90 | 32.315 | 38.314 | 21.511 | 1.00 | 44.94 | A |
| ATOM | 821 | O | THR | 90 | 31.675 | 37.706 | 22.379 | 1.00 | 45.20 | A |
| ATOM | 822 | N | LEU | 91 | 33.013 | 37.687 | 20.570 | 1.00 | 43.42 | A |
| ATOM | 823 | H | LEU | 91 | 33.593 | 38.190 | 19.966 | 0.00 | 0.00 | A |
| ATOM | 824 | CA | LEU | 91 | 32.938 | 36.238 | 20.452 | 1.00 | 40.51 | A |
| ATOM | 825 | CB | LEU | 91 | 33.372 | 35.771 | 19.061 | 1.00 | 37.34 | A |
| ATOM | 826 | CG | LEU | 91 | 32.977 | 34.345 | 18.671 | 1.00 | 33.14 | A |
| ATOM | 827 | CD1 | LEU | 91 | 31.490 | 34.314 | 18.419 | 1.00 | 33.98 | A |
| ATOM | 828 | CD2 | LEU | 91 | 33.710 | 33.906 | 17.418 | 1.00 | 33.13 | A |
| ATOM | 829 | C | LEU | 91 | 33.698 | 35.463 | 21.496 | 1.00 | 40.16 | A |
| ATOM | 830 | O | LEU | 91 | 34.842 | 35.771 | 21.801 | 1.00 | 40.92 | A |
| ATOM | 831 | N | GLY | 92 | 33.020 | 34.473 | 22.062 | 1.00 | 41.01 | A |
| ATOM | 832 | H | GLY | 92 | 32.082 | 34.333 | 21.826 | 0.00 | 0.00 | A |
| ATOM | 833 | CA | GLY | 92 | 33.630 | 33.597 | 23.042 | 1.00 | 39.62 | A |
| ATOM | 834 | C | GLY | 92 | 34.162 | 32.457 | 22.207 | 1.00 | 38.21 | A |
| ATOM | 835 | O | GLY | 92 | 35.370 | 32.253 | 22.129 | 1.00 | 42.68 | A |
| ATOM | 836 | N | ASN | 93 | 33.250 | 31.738 | 21.558 | 1.00 | 33.40 | A |
| ATOM | 837 | H | ASN | 93 | 32.298 | 31.956 | 21.666 | 0.00 | 0.00 | A |
| ATOM | 838 | CA | ASN | 93 | 33.596 | 30.639 | 20.669 | 1.00 | 29.36 | A |
| ATOM | 839 | CB | ASN | 93 | 34.382 | 29.571 | 21.383 | 1.00 | 30.39 | A |
| ATOM | 840 | CG | ASN | 93 | 33.518 | 28.720 | 22.250 | 1.00 | 31.62 | A |
| ATOM | 841 | OD1 | ASN | 93 | 33.335 | 27.543 | 21.983 | 1.00 | 32.44 | A |
| ATOM | 842 | ND2 | ASN | 93 | 32.980 | 29.308 | 23.305 | 1.00 | 34.70 | A |
| ATOM | 843 | HD21 | ASN | 93 | 33.212 | 30.247 | 23.462 | 0.00 | 0.00 | A |
| ATOM | 844 | HD22 | ASN | 93 | 32.371 | 28.797 | 23.867 | 0.00 | 0.00 | A |
| ATOM | 845 | C | ASN | 93 | 32.306 | 30.038 | 20.201 | 1.00 | 28.88 | A |
| ATOM | 846 | O | ASN | 93 | 31.257 | 30.294 | 20.791 | 1.00 | 29.50 | A |
| ATOM | 847 | N | VAL | 94 | 32.376 | 29.257 | 19.133 | 1.00 | 27.85 | A |
| ATOM | 848 | H | VAL | 94 | 33.239 | 29.076 | 18.700 | 0.00 | 0.00 | A |
| ATOM | 849 | CA | VAL | 94 | 31.195 | 28.609 | 18.584 | 1.00 | 28.06 | A |
| ATOM | 850 | CB | VAL | 94 | 30.647 | 29.357 | 17.356 | 1.00 | 26.42 | A |
| ATOM | 851 | CG1 | VAL | 94 | 30.447 | 30.822 | 17.686 | 1.00 | 25.10 | A |
| ATOM | 852 | CG2 | VAL | 94 | 31.572 | 29.180 | 16.169 | 1.00 | 25.22 | A |
| ATOM | 853 | C | VAL | 94 | 31.480 | 27.156 | 18.199 | 1.00 | 30.43 | A |
| ATOM | 854 | O | VAL | 94 | 32.641 | 26.762 | 17.942 | 1.00 | 33.46 | A |
| ATOM | 855 | N | ASP | 95 | 30.416 | 26.358 | 18.202 | 1.00 | 29.67 | A |
| ATOM | 856 | H | ASP | 95 | 29.535 | 26.710 | 18.447 | 0.00 | 0.00 | A |
| ATOM | 857 | CA | ASP | 95 | 30.495 | 24.953 | 17.856 | 1.00 | 26.42 | A |
| ATOM | 858 | CB | ASP | 95 | 30.448 | 24.087 | 19.102 | 1.00 | 27.34 | A |
| ATOM | 859 | CG | ASP | 95 | 30.895 | 22.681 | 18.827 | 1.00 | 29.37 | A |
| ATOM | 860 | OD1 | ASP | 95 | 30.892 | 21.844 | 19.745 | 1.00 | 29.22 | A |
| ATOM | 861 | OD2 | ASP | 95 | 31.250 | 22.388 | 17.672 | 1.00 | 32.12 | A |
| ATOM | 862 | C | ASP | 95 | 29.289 | 24.660 | 17.013 | 1.00 | 25.22 | A |
| ATOM | 863 | O | ASP | 95 | 28.175 | 25.056 | 17.371 | 1.00 | 26.83 | A |
| ATOM | 864 | N | VAL | 96 | 29.516 | 23.976 | 15.899 | 1.00 | 22.97 | A |
| ATOM | 865 | H | VAL | 96 | 30.440 | 23.692 | 15.730 | 0.00 | 0.00 | A |
| ATOM | 866 | CA | VAL | 96 | 28.467 | 23.625 | 14.956 | 1.00 | 23.98 | A |
| ATOM | 867 | CB | VAL | 96 | 28.722 | 24.335 | 13.628 | 1.00 | 22.85 | A |
| ATOM | 868 | CG1 | VAL | 96 | 27.647 | 23.987 | 12.623 | 1.00 | 21.58 | A |
| ATOM | 869 | CG2 | VAL | 96 | 28.768 | 25.823 | 13.847 | 1.00 | 22.98 | A |
| ATOM | 870 | C | VAL | 96 | 28.426 | 22.114 | 14.695 | 1.00 | 27.17 | A |
| ATOM | 871 | O | VAL | 96 | 29.475 | 21.472 | 14.575 | 1.00 | 31.62 | A |
| ATOM | 872 | N | THR | 97 | 27.229 | 21.540 | 14.592 | 1.00 | 27.95 | A |
| ATOM | 873 | H | THR | 97 | 26.426 | 22.080 | 14.660 | 0.00 | 0.00 | A |
| ATOM | 874 | CA | THR | 97 | 27.089 | 20.109 | 14.320 | 1.00 | 27.90 | A |
| ATOM | 875 | CB | THR | 97 | 26.443 | 19.369 | 15.482 | 1.00 | 26.54 | A |
| ATOM | 876 | OG1 | THR | 97 | 27.139 | 19.680 | 16.694 | 1.00 | 31.74 | A |
| ATOM | 877 | HG1 | THR | 97 | 28.024 | 19.376 | 16.473 | 0.00 | 0.00 | A |
| ATOM | 878 | CG2 | THR | 97 | 26.504 | 17.878 | 15.243 | 1.00 | 24.13 | A |
| ATOM | 879 | C | THR | 97 | 26.174 | 19.911 | 13.132 | 1.00 | 29.49 | A |
| ATOM | 880 | O | THR | 97 | 24.982 | 20.183 | 13.233 | 1.00 | 33.63 | A |
| ATOM | 881 | N | ILE | 98 | 26.731 | 19.494 | 12.001 | 1.00 | 28.27 | A |
| ATOM | 882 | H | ILE | 98 | 27.695 | 19.334 | 11.966 | 0.00 | 0.00 | A |
| ATOM | 883 | CA | ILE | 98 | 25.942 | 19.241 | 10.798 | 1.00 | 28.60 | A |
| ATOM | 884 | CB | ILE | 98 | 26.806 | 19.330 | 9.540 | 1.00 | 28.09 | A |
| ATOM | 885 | CG2 | ILE | 98 | 25.957 | 19.060 | 8.309 | 1.00 | 25.26 | A |
| ATOM | 886 | CG1 | ILE | 98 | 27.473 | 20.701 | 9.467 | 1.00 | 27.97 | A |
| ATOM | 887 | CD1 | ILE | 98 | 28.574 | 20.782 | 8.446 | 1.00 | 29.00 | A |
| ATOM | 888 | C | ILE | 98 | 25.443 | 17.806 | 10.920 | 1.00 | 30.10 | A |
| ATOM | 889 | O | ILE | 98 | 26.200 | 16.918 | 11.318 | 1.00 | 33.90 | A |
| ATOM | 890 | N | ILE | 99 | 24.183 | 17.568 | 10.593 | 1.00 | 28.23 | A |
| ATOM | 891 | H | ILE | 99 | 23.605 | 18.283 | 10.253 | 0.00 | 0.00 | A |
| ATOM | 892 | CA | ILE | 99 | 23.625 | 16.229 | 10.695 | 1.00 | 26.18 | A |
| ATOM | 893 | CB | ILE | 99 | 22.456 | 16.203 | 11.695 | 1.00 | 24.53 | A |
| ATOM | 894 | CG2 | ILE | 99 | 21.883 | 14.822 | 11.816 | 1.00 | 21.72 | A |
| ATOM | 895 | CG1 | ILE | 99 | 22.951 | 16.657 | 13.063 | 1.00 | 24.46 | A |
| ATOM | 896 | CD1 | ILE | 99 | 21.869 | 17.102 | 13.983 | 1.00 | 23.99 | A |
| ATOM | 897 | C | ILE | 99 | 23.153 | 15.910 | 9.299 | 1.00 | 27.13 | A |
| ATOM | 898 | O | ILE | 99 | 22.194 | 16.494 | 8.813 | 1.00 | 28.31 | A |
| ATOM | 899 | N | ALA | 100 | 23.889 | 15.046 | 8.620 | 1.00 | 28.13 | A |
| ATOM | 900 | H | ALA | 100 | 24.678 | 14.632 | 9.039 | 0.00 | 0.00 | A |
| ATOM | 901 | CA | ALA | 100 | 23.551 | 14.676 | 7.263 | 1.00 | 29.51 | A |
| ATOM | 902 | CB | ALA | 100 | 24.098 | 15.704 | 6.321 | 1.00 | 27.33 | A |
| ATOM | 903 | C | ALA | 100 | 24.120 | 13.302 | 6.936 | 1.00 | 33.76 | A |
| ATOM | 904 | O | ALA | 100 | 25.183 | 12.931 | 7.434 | 1.00 | 37.48 | A |
| ATOM | 905 | N | GLN | 101 | 23.381 | 12.537 | 6.132 | 1.00 | 35.65 | A |
| ATOM | 906 | H | GLN | 101 | 22.530 | 12.905 | 5.815 | 0.00 | 0.00 | A |
| ATOM | 907 | CA | GLN | 101 | 23.785 | 11.193 | 5.702 | 1.00 | 35.60 | A |
| ATOM | 908 | CB | GLN | 101 | 22.569 | 10.450 | 5.167 | 1.00 | 36.96 | A |
| ATOM | 909 | CG | GLN | 101 | 22.736 | 8.963 | 5.096 | 1.00 | 40.26 | A |
| ATOM | 910 | CD | GLN | 101 | 22.835 | 8.342 | 6.463 | 1.00 | 42.36 | A |
| ATOM | 911 | OE1 | GLN | 101 | 23.612 | 7.408 | 6.675 | 1.00 | 46.71 | A |
| ATOM | 912 | NE2 | GLN | 101 | 22.047 | 8.858 | 7.413 | 1.00 | 42.34 | A |
| ATOM | 913 | HE21 | GLN | 101 | 21.426 | 9.574 | 7.154 | 0.00 | 0.00 | A |
| ATOM | 914 | HE22 | GLN | 101 | 22.123 | 8.513 | 8.317 | 0.00 | 0.00 | A |
| ATOM | 915 | C | GLN | 101 | 24.808 | 11.325 | 4.577 | 1.00 | 34.80 | A |
| ATOM | 916 | O | GLN | 101 | 25.684 | 10.483 | 4.387 | 1.00 | 35.38 | A |
| ATOM | 917 | N | ALA | 102 | 24.648 | 12.391 | 3.811 | 1.00 | 36.36 | A |
| ATOM | 918 | H | ALA | 102 | 23.912 | 13.022 | 3.964 | 0.00 | 0.00 | A |
| ATOM | 919 | CA | ALA | 102 | 25.524 | 12.713 | 2.704 | 1.00 | 35.91 | A |
| ATOM | 920 | CB | ALA | 102 | 25.300 | 11.746 | 1.590 | 1.00 | 36.12 | A |
| ATOM | 921 | C | ALA | 102 | 25.157 | 14.133 | 2.274 | 1.00 | 36.73 | A |
| ATOM | 922 | O | ALA | 102 | 24.037 | 14.592 | 2.524 | 1.00 | 36.49 | A |
| ATOM | 923 | N | CPR | 103 | 26.071 | 14.837 | 1.589 | 1.00 | 36.82 | A |
| ATOM | 924 | CD | CPR | 103 | 25.708 | 16.160 | 1.046 | 1.00 | 35.33 | A |
| ATOM | 925 | CA | CPR | 103 | 27.418 | 14.443 | 1.170 | 1.00 | 37.46 | A |
| ATOM | 926 | CB | CPR | 103 | 27.769 | 15.527 | 0.157 | 1.00 | 35.36 | A |
| ATOM | 927 | CG | CPR | 103 | 27.029 | 16.725 | 0.673 | 1.00 | 32.55 | A |
| ATOM | 928 | C | CPR | 103 | 28.383 | 14.413 | 2.354 | 1.00 | 41.85 | A |
| ATOM | 929 | O | CPR | 103 | 27.967 | 14.664 | 3.486 | 1.00 | 45.89 | A |
| ATOM | 930 | N | LYS | 104 | 29.646 | 14.047 | 2.112 | 1.00 | 43.89 | A |
| ATOM | 931 | H | LYS | 104 | 29.912 | 13.830 | 1.197 | 0.00 | 0.00 | A |
| ATOM | 932 | CA | LYS | 104 | 30.656 | 14.002 | 3.178 | 1.00 | 43.00 | A |
| ATOM | 933 | CB | LYS | 104 | 31.888 | 13.222 | 2.737 | 1.00 | 49.77 | A |
| ATOM | 934 | CG | LYS | 104 | 31.744 | 11.725 | 2.577 | 1.00 | 60.37 | A |
| ATOM | 935 | CD | LYS | 104 | 33.109 | 11.184 | 2.133 | 1.00 | 72.57 | A |
| ATOM | 936 | CE | LYS | 104 | 33.225 | 9.659 | 2.174 | 1.00 | 80.21 | A |
| ATOM | 937 | NZ | LYS | 104 | 34.671 | 9.252 | 2.030 | 1.00 | 85.47 | A |
| ATOM | 938 | HZ1 | LYS | 104 | 35.223 | 9.777 | 2.743 | 0.00 | 0.00 | A |
| ATOM | 939 | HZ2 | LYS | 104 | 34.981 | 9.517 | 1.084 | 0.00 | 0.00 | A |
| ATOM | 940 | HZ3 | LYS | 104 | 34.778 | 8.232 | 2.206 | 0.00 | 0.00 | A |
| ATOM | 941 | C | LYS | 104 | 31.087 | 15.431 | 3.499 | 1.00 | 40.41 | A |
| ATOM | 942 | O | LYS | 104 | 31.673 | 16.114 | 2.652 | 1.00 | 41.38 | A |
| ATOM | 943 | N | MET | 105 | 30.832 | 15.869 | 4.723 | 1.00 | 35.02 | A |
| ATOM | 944 | H | MET | 105 | 30.364 | 15.273 | 5.343 | 0.00 | 0.00 | A |
| ATOM | 945 | CA | MET | 105 | 31.171 | 17.217 | 5.113 | 1.00 | 31.17 | A |
| ATOM | 946 | CB | MET | 105 | 30.338 | 17.636 | 6.307 | 1.00 | 30.26 | A |
| ATOM | 947 | CG | MET | 105 | 28.861 | 17.566 | 6.071 | 1.00 | 32.39 | A |
| ATOM | 948 | SD | MET | 105 | 28.383 | 18.600 | 4.705 | 1.00 | 35.48 | A |
| ATOM | 949 | CE | MET | 105 | 26.728 | 18.017 | 4.441 | 1.00 | 31.76 | A |
| ATOM | 950 | C | MET | 105 | 32.604 | 17.314 | 5.504 | 1.00 | 30.28 | A |
| ATOM | 951 | O | MET | 105 | 33.277 | 18.284 | 5.212 | 1.00 | 31.68 | A |
| ATOM | 952 | N | LEU | 106 | 33.081 | 16.271 | 6.140 | 1.00 | 31.11 | A |
| ATOM | 953 | H | LEU | 106 | 32.508 | 15.492 | 6.265 | 0.00 | 0.00 | A |
| ATOM | 954 | CA | LEU | 106 | 34.432 | 16.251 | 6.661 | 1.00 | 34.46 | A |
| ATOM | 955 | CB | LEU | 106 | 34.845 | 14.819 | 6.973 | 1.00 | 42.07 | A |
| ATOM | 956 | CG | LEU | 106 | 36.011 | 14.739 | 7.956 | 1.00 | 47.55 | A |
| ATOM | 957 | CD1 | LEU | 106 | 35.590 | 15.344 | 9.301 | 1.00 | 48.30 | A |
| ATOM | 958 | CD2 | LEU | 106 | 36.462 | 13.285 | 8.114 | 1.00 | 52.58 | A |
| ATOM | 959 | C | LEU | 106 | 35.547 | 16.968 | 5.910 | 1.00 | 33.93 | A |
| ATOM | 960 | O | LEU | 106 | 36.249 | 17.796 | 6.474 | 1.00 | 34.78 | A |
| ATOM | 961 | N | PRO | 107 | 35.735 | 16.656 | 4.632 | 1.00 | 34.19 | A |
| ATOM | 962 | CD | PRO | 107 | 35.029 | 15.703 | 3.763 | 1.00 | 32.58 | A |
| ATOM | 963 | CA | PRO | 107 | 36.810 | 17.333 | 3.906 | 1.00 | 34.58 | A |
| ATOM | 964 | CB | PRO | 107 | 36.767 | 16.654 | 2.544 | 1.00 | 35.18 | A |
| ATOM | 965 | CG | PRO | 107 | 35.333 | 16.251 | 2.410 | 1.00 | 33.44 | A |
| ATOM | 966 | C | PRO | 107 | 36.622 | 18.827 | 3.765 | 1.00 | 35.69 | A |
| ATOM | 967 | O | PRO | 107 | 37.580 | 19.562 | 3.542 | 1.00 | 38.33 | A |
| ATOM | 968 | N | HIS | 108 | 35.382 | 19.274 | 3.874 | 1.00 | 34.83 | A |
| ATOM | 969 | H | HIS | 108 | 34.678 | 18.640 | 4.093 | 0.00 | 0.00 | A |
| ATOM | 970 | CA | HIS | 108 | 35.078 | 20.683 | 3.717 | 1.00 | 35.74 | A |
| ATOM | 971 | CB | HIS | 108 | 33.703 | 20.840 | 3.078 | 1.00 | 35.84 | A |
| ATOM | 972 | CG | HIS | 108 | 33.495 | 19.972 | 1.879 | 1.00 | 34.67 | A |
| ATOM | 973 | CD2 | HIS | 108 | 32.820 | 18.808 | 1.730 | 1.00 | 36.37 | A |
| ATOM | 974 | ND1 | HIS | 108 | 34.031 | 20.263 | 0.645 | 1.00 | 34.89 | A |
| ATOM | 975 | HD1 | HIS | 108 | 34.509 | 21.086 | 0.416 | 0.00 | 0.00 | A |
| ATOM | 976 | CE1 | HIS | 108 | 33.698 | 19.313 | −0.212 | 1.00 | 35.92 | A |
| ATOM | 977 | NE2 | HIS | 108 | 32.963 | 18.418 | 0.422 | 1.00 | 35.47 | A |
| ATOM | 978 | HE2 | HIS | 108 | 32.565 | 17.603 | 0.038 | 0.00 | 0.00 | A |
| ATOM | 979 | C | HIS | 108 | 35.129 | 21.514 | 4.994 | 1.00 | 37.27 | A |
| ATOM | 980 | O | HIS | 108 | 35.184 | 22.746 | 4.924 | 1.00 | 39.42 | A |
| ATOM | 981 | N | ILE | 109 | 35.131 | 20.868 | 6.157 | 1.00 | 35.87 | A |
| ATOM | 982 | H | ILE | 109 | 35.139 | 19.887 | 6.182 | 0.00 | 0.00 | A |
| ATOM | 983 | CA | ILE | 109 | 35.141 | 21.624 | 7.403 | 1.00 | 33.92 | A |
| ATOM | 984 | CB | ILE | 109 | 35.130 | 20.721 | 8.668 | 1.00 | 33.08 | A |
| ATOM | 985 | CG2 | ILE | 109 | 35.661 | 21.476 | 9.857 | 1.00 | 33.55 | A |
| ATOM | 986 | CG1 | ILE | 109 | 33.702 | 20.309 | 9.036 | 1.00 | 31.13 | A |
| ATOM | 987 | CD1 | ILE | 109 | 33.261 | 19.050 | 8.416 | 1.00 | 29.72 | A |
| ATOM | 988 | C | ILE | 109 | 36.208 | 22.707 | 7.538 | 1.00 | 35.33 | A |
| ATOM | 989 | O | ILE | 109 | 35.889 | 23.818 | 7.961 | 1.00 | 39.72 | A |
| ATOM | 990 | N | PRO | 110 | 37.469 | 22.437 | 7.144 | 1.00 | 35.30 | A |
| ATOM | 991 | CD | PRO | 110 | 38.047 | 21.217 | 6.556 | 1.00 | 36.37 | A |
| ATOM | 992 | CA | PRO | 110 | 38.501 | 23.480 | 7.281 | 1.00 | 34.53 | A |
| ATOM | 993 | CB | PRO | 110 | 39.725 | 22.836 | 6.648 | 1.00 | 34.70 | A |
| ATOM | 994 | CG | PRO | 110 | 39.508 | 21.374 | 6.883 | 1.00 | 34.53 | A |
| ATOM | 995 | C | PRO | 110 | 38.141 | 24.785 | 6.579 | 1.00 | 34.91 | A |
| ATOM | 996 | O | PRO | 110 | 38.218 | 25.870 | 7.172 | 1.00 | 35.36 | A |
| ATOM | 997 | N | GLN | 111 | 37.728 | 24.671 | 5.322 | 1.00 | 35.00 | A |
| ATOM | 998 | H | GLN | 111 | 37.671 | 23.781 | 4.914 | 0.00 | 0.00 | A |
| ATOM | 999 | CA | GLN | 111 | 37.342 | 25.838 | 4.543 | 1.00 | 33.40 | A |
| ATOM | 1000 | CB | GLN | 111 | 36.985 | 25.419 | 3.122 | 1.00 | 30.60 | A |
| ATOM | 1001 | CG | GLN | 111 | 36.719 | 26.574 | 2.209 | 1.00 | 27.01 | A |
| ATOM | 1002 | CD | GLN | 111 | 37.838 | 27.565 | 2.221 | 1.00 | 24.51 | A |
| ATOM | 1003 | OE1 | GLN | 111 | 37.620 | 28.750 | 2.380 | 1.00 | 30.89 | A |
| ATOM | 1004 | NE2 | GLN | 111 | 39.051 | 27.085 | 2.088 | 1.00 | 25.10 | A |
| ATOM | 1005 | HE21 | GLN | 111 | 39.139 | 26.119 | 2.020 | 0.00 | 0.00 | A |
| ATOM | 1006 | HE22 | GLN | 111 | 39.770 | 27.754 | 2.068 | 0.00 | 0.00 | A |
| ATOM | 1007 | C | GLN | 111 | 36.156 | 26.532 | 5.218 | 1.00 | 35.25 | A |
| ATOM | 1008 | O | GLN | 111 | 36.077 | 27.761 | 5.230 | 1.00 | 38.78 | A |
| ATOM | 1009 | N | MET | 112 | 35.237 | 25.743 | 5.776 | 1.00 | 33.55 | A |
| ATOM | 1010 | H | MET | 112 | 35.323 | 24.770 | 5.705 | 0.00 | 0.00 | A |
| ATOM | 1011 | CA | MET | 112 | 34.090 | 26.297 | 6.475 | 1.00 | 30.11 | A |
| ATOM | 1012 | CB | MET | 112 | 33.205 | 25.195 | 7.024 | 1.00 | 29.21 | A |
| ATOM | 1013 | CG | MET | 112 | 32.389 | 24.461 | 6.012 | 1.00 | 31.09 | A |
| ATOM | 1014 | SD | MET | 112 | 31.371 | 23.267 | 6.864 | 1.00 | 32.08 | A |
| ATOM | 1015 | CE | MET | 112 | 30.700 | 22.432 | 5.550 | 1.00 | 34.82 | A |
| ATOM | 1016 | C | MET | 112 | 34.612 | 27.105 | 7.647 | 1.00 | 31.63 | A |
| ATOM | 1017 | O | MET | 112 | 34.166 | 28.230 | 7.872 | 1.00 | 34.86 | A |
| ATOM | 1018 | N | ARG | 113 | 35.570 | 26.545 | 8.387 | 1.00 | 28.98 | A |
| ATOM | 1019 | H | ARG | 113 | 35.907 | 25.667 | 8.135 | 0.00 | 0.00 | A |
| ATOM | 1020 | CA | ARG | 113 | 36.125 | 27.241 | 9.539 | 1.00 | 29.61 | A |
| ATOM | 1021 | CB | ARG | 113 | 37.091 | 26.362 | 10.293 | 1.00 | 24.87 | A |
| ATOM | 1022 | CG | ARG | 113 | 36.433 | 25.157 | 10.821 | 1.00 | 26.17 | A |
| ATOM | 1023 | CD | ARG | 113 | 37.400 | 24.320 | 11.569 | 1.00 | 25.46 | A |
| ATOM | 1024 | NE | ARG | 113 | 37.801 | 24.989 | 12.781 | 1.00 | 25.23 | A |
| ATOM | 1025 | HE | ARG | 113 | 37.143 | 25.600 | 13.186 | 0.00 | 0.00 | A |
| ATOM | 1026 | CZ | ARG | 113 | 38.984 | 24.819 | 13.348 | 1.00 | 29.97 | A |
| ATOM | 1027 | NH1 | ARG | 113 | 39.287 | 25.469 | 14.467 | 1.00 | 29.51 | A |
| ATOM | 1028 | HH11 | ARG | 113 | 38.598 | 26.100 | 14.864 | 0.00 | 0.00 | A |
| ATOM | 1029 | HH12 | ARG | 113 | 40.146 | 25.380 | 14.976 | 0.00 | 0.00 | A |
| ATOM | 1030 | NH2 | ARG | 113 | 39.874 | 24.018 | 12.769 | 1.00 | 30.83 | A |
| ATOM | 1031 | HH21 | ARG | 113 | 39.638 | 23.537 | 11.925 | 0.00 | 0.00 | A |
| ATOM | 1032 | HH22 | ARG | 113 | 40.765 | 23.851 | 13.191 | 0.00 | 0.00 | A |
| ATOM | 1033 | C | ARG | 113 | 36.823 | 28.512 | 9.128 | 1.00 | 33.63 | A |
| ATOM | 1034 | O | ARG | 113 | 36.880 | 29.468 | 9.894 | 1.00 | 37.76 | A |
| ATOM | 1035 | N | VAL | 114 | 37.378 | 28.517 | 7.925 | 1.00 | 34.51 | A |
| ATOM | 1036 | H | VAL | 114 | 37.337 | 27.705 | 7.380 | 0.00 | 0.00 | A |
| ATOM | 1037 | CA | VAL | 114 | 38.058 | 29.691 | 7.407 | 1.00 | 33.83 | A |
| ATOM | 1038 | CB | VAL | 114 | 38.790 | 29.326 | 6.136 | 1.00 | 31.94 | A |
| ATOM | 1039 | CG1 | VAL | 114 | 39.296 | 30.540 | 5.471 | 1.00 | 32.81 | A |
| ATOM | 1040 | CG2 | VAL | 114 | 39.910 | 28.381 | 6.455 | 1.00 | 29.61 | A |
| ATOM | 1041 | C | VAL | 114 | 37.029 | 30.808 | 7.135 | 1.00 | 35.86 | A |
| ATOM | 1042 | O | VAL | 114 | 37.181 | 31.934 | 7.611 | 1.00 | 38.69 | A |
| ATOM | 1043 | N | PHE | 115 | 35.960 | 30.475 | 6.415 | 1.00 | 33.76 | A |
| ATOM | 1044 | H | PHE | 115 | 35.893 | 29.556 | 6.074 | 0.00 | 0.00 | A |
| ATOM | 1045 | CA | PHE | 115 | 34.898 | 31.422 | 6.104 | 1.00 | 29.82 | A |
| ATOM | 1046 | CB | PHE | 115 | 33.833 | 30.727 | 5.289 | 1.00 | 25.92 | A |
| ATOM | 1047 | CG | PHE | 115 | 34.242 | 30.443 | 3.889 | 1.00 | 27.52 | A |
| ATOM | 1048 | CD1 | PHE | 115 | 33.669 | 29.399 | 3.186 | 1.00 | 30.53 | A |
| ATOM | 1049 | CD2 | PHE | 115 | 35.122 | 31.273 | 3.231 | 1.00 | 28.89 | A |
| ATOM | 1050 | CE1 | PHE | 115 | 33.961 | 29.201 | 1.847 | 1.00 | 29.36 | A |
| ATOM | 1051 | CE2 | PHE | 115 | 35.419 | 31.077 | 1.886 | 1.00 | 30.52 | A |
| ATOM | 1052 | CZ | PHE | 115 | 34.835 | 30.043 | 1.196 | 1.00 | 29.00 | A |
| ATOM | 1053 | C | PHE | 115 | 34.245 | 31.998 | 7.348 | 1.00 | 30.97 | A |
| ATOM | 1054 | O | PHE | 115 | 34.099 | 33.206 | 7.468 | 1.00 | 33.01 | A |
| ATOM | 1055 | N | ILE | 116 | 33.827 | 31.127 | 8.261 | 1.00 | 30.32 | A |
| ATOM | 1056 | H | ILE | 116 | 33.949 | 30.168 | 8.086 | 0.00 | 0.00 | A |
| ATOM | 1057 | CA | ILE | 116 | 33.177 | 31.551 | 9.497 | 1.00 | 29.71 | A |
| ATOM | 1058 | CB | ILE | 116 | 32.698 | 30.342 | 10.340 | 1.00 | 27.98 | A |
| ATOM | 1059 | CG2 | ILE | 116 | 32.160 | 30.820 | 11.686 | 1.00 | 25.27 | A |
| ATOM | 1060 | CG1 | ILE | 116 | 31.636 | 29.549 | 9.569 | 1.00 | 28.72 | A |
| ATOM | 1061 | CD1 | ILE | 116 | 31.217 | 28.223 | 10.202 | 1.00 | 25.58 | A |
| ATOM | 1062 | C | ILE | 116 | 34.083 | 32.415 | 10.363 | 1.00 | 31.66 | A |
| ATOM | 1063 | O | ILE | 116 | 33.651 | 33.435 | 10.885 | 1.00 | 33.57 | A |
| ATOM | 1064 | N | ALA | 117 | 35.332 | 31.998 | 10.542 | 1.00 | 33.58 | A |
| ATOM | 1065 | H | ALA | 117 | 35.646 | 31.169 | 10.121 | 0.00 | 0.00 | A |
| ATOM | 1066 | CA | ALA | 117 | 36.274 | 32.752 | 11.367 | 1.00 | 33.56 | A |
| ATOM | 1067 | CB | ALA | 117 | 37.591 | 32.036 | 11.445 | 1.00 | 33.16 | A |
| ATOM | 1068 | C | ALA | 117 | 36.459 | 34.131 | 10.768 | 1.00 | 34.96 | A |
| ATOM | 1069 | O | ALA | 117 | 36.542 | 35.114 | 11.485 | 1.00 | 34.09 | A |
| ATOM | 1070 | N | GLU | 118 | 36.521 | 34.200 | 9.445 | 1.00 | 38.60 | A |
| ATOM | 1071 | H | GLU | 118 | 36.502 | 33.388 | 8.895 | 0.00 | 0.00 | A |
| ATOM | 1072 | CA | GLU | 118 | 36.663 | 35.482 | 8.776 | 1.00 | 41.62 | A |
| ATOM | 1073 | CB | GLU | 118 | 36.803 | 35.319 | 7.256 | 1.00 | 47.56 | A |
| ATOM | 1074 | CG | GLU | 118 | 38.174 | 34.811 | 6.773 | 1.00 | 56.80 | A |
| ATOM | 1075 | CD | GLU | 118 | 38.308 | 34.765 | 5.241 | 1.00 | 61.74 | A |
| ATOM | 1076 | OE1 | GLU | 118 | 39.392 | 34.331 | 4.767 | 1.00 | 61.62 | A |
| ATOM | 1077 | OE2 | GLU | 118 | 37.341 | 35.158 | 4.521 | 1.00 | 63.72 | A |
| ATOM | 1078 | C | GLU | 118 | 35.419 | 36.294 | 9.084 | 1.00 | 41.15 | A |
| ATOM | 1079 | O | GLU | 118 | 35.513 | 37.359 | 9.670 | 1.00 | 43.82 | A |
| ATOM | 1080 | N | ASP | 119 | 34.255 | 35.755 | 8.740 | 1.00 | 39.27 | A |
| ATOM | 1081 | H | ASP | 119 | 34.234 | 34.883 | 8.303 | 0.00 | 0.00 | A |
| ATOM | 1082 | CA | ASP | 119 | 32.984 | 36.425 | 8.967 | 1.00 | 36.68 | A |
| ATOM | 1083 | CB | ASP | 119 | 31.843 | 35.489 | 8.623 | 1.00 | 35.65 | A |
| ATOM | 1084 | CG | ASP | 119 | 31.684 | 35.289 | 7.160 | 1.00 | 35.37 | A |
| ATOM | 1085 | OD1 | ASP | 119 | 30.883 | 34.412 | 6.802 | 1.00 | 35.02 | A |
| ATOM | 1086 | OD2 | ASP | 119 | 32.330 | 36.007 | 6.363 | 1.00 | 34.03 | A |
| ATOM | 1087 | C | ASP | 119 | 32.765 | 36.953 | 10.379 | 1.00 | 37.89 | A |
| ATOM | 1088 | O | ASP | 119 | 32.116 | 37.977 | 10.562 | 1.00 | 39.62 | A |
| ATOM | 1089 | N | LEU | 120 | 33.256 | 36.233 | 11.382 | 1.00 | 39.17 | A |
| ATOM | 1090 | H | LEU | 120 | 33.716 | 35.396 | 11.169 | 0.00 | 0.00 | A |
| ATOM | 1091 | CA | LEU | 120 | 33.086 | 36.660 | 12.770 | 1.00 | 40.30 | A |
| ATOM | 1092 | CB | LEU | 120 | 32.832 | 35.452 | 13.680 | 1.00 | 38.20 | A |
| ATOM | 1093 | CG | LEU | 120 | 31.609 | 34.574 | 13.405 | 1.00 | 36.15 | A |
| ATOM | 1094 | CD1 | LEU | 120 | 31.608 | 33.441 | 14.402 | 1.00 | 35.67 | A |
| ATOM | 1095 | CD2 | LEU | 120 | 30.327 | 35.372 | 13.500 | 1.00 | 32.68 | A |
| ATOM | 1096 | C | LEU | 120 | 34.302 | 37.441 | 13.263 | 1.00 | 41.35 | A |
| ATOM | 1097 | O | LEU | 120 | 34.300 | 37.982 | 14.380 | 1.00 | 44.52 | A |
| ATOM | 1098 | N | GLY | 121 | 35.339 | 37.477 | 12.428 | 1.00 | 41.49 | A |
| ATOM | 1099 | H | GLY | 121 | 35.288 | 37.011 | 11.571 | 0.00 | 0.00 | A |
| ATOM | 1100 | CA | GLY | 121 | 36.570 | 38.177 | 12.751 | 1.00 | 40.36 | A |
| ATOM | 1101 | C | GLY | 121 | 37.202 | 37.615 | 13.998 | 1.00 | 40.60 | A |
| ATOM | 1102 | O | GLY | 121 | 37.603 | 38.359 | 14.884 | 1.00 | 45.36 | A |
| ATOM | 1103 | N | CYS | 122 | 37.276 | 36.296 | 14.078 | 1.00 | 40.11 | A |
| ATOM | 1104 | H | CYS | 122 | 36.996 | 35.742 | 13.318 | 0.00 | 0.00 | A |
| ATOM | 1105 | CA | CYS | 122 | 37.843 | 35.638 | 15.239 | 1.00 | 40.44 | A |
| ATOM | 1106 | CB | CYS | 122 | 36.773 | 34.834 | 15.969 | 1.00 | 38.95 | A |
| ATOM | 1107 | SG | CYS | 122 | 36.224 | 33.385 | 15.070 | 1.00 | 38.21 | A |
| ATOM | 1108 | C | CYS | 122 | 38.899 | 34.693 | 14.753 | 1.00 | 41.47 | A |
| ATOM | 1109 | O | CYS | 122 | 39.078 | 34.509 | 13.556 | 1.00 | 43.15 | A |
| ATOM | 1110 | N | HIS | 123 | 39.619 | 34.084 | 15.670 | 1.00 | 43.34 | A |
| ATOM | 1111 | H | HIS | 123 | 39.435 | 34.204 | 16.629 | 0.00 | 0.00 | A |
| ATOM | 1112 | CA | HIS | 123 | 40.615 | 33.168 | 15.216 | 1.00 | 46.15 | A |
| ATOM | 1113 | CB | HIS | 123 | 41.707 | 32.984 | 16.258 | 1.00 | 55.20 | A |
| ATOM | 1114 | CG | HIS | 123 | 42.845 | 32.151 | 15.766 | 1.00 | 65.25 | A |
| ATOM | 1115 | CD2 | HIS | 123 | 43.505 | 32.165 | 14.581 | 1.00 | 68.81 | A |
| ATOM | 1116 | ND1 | HIS | 123 | 43.385 | 31.111 | 16.495 | 1.00 | 69.72 | A |
| ATOM | 1117 | HD1 | HIS | 123 | 43.151 | 30.843 | 17.421 | 0.00 | 0.00 | A |
| ATOM | 1118 | CE1 | HIS | 123 | 44.325 | 30.518 | 15.780 | 1.00 | 73.65 | A |
| ATOM | 1119 | NE2 | HIS | 123 | 44.418 | 31.138 | 14.615 | 1.00 | 74.10 | A |
| ATOM | 1120 | HE2 | HIS | 123 | 45.059 | 30.922 | 13.895 | 0.00 | 0.00 | A |
| ATOM | 1121 | C | HIS | 123 | 39.905 | 31.859 | 14.946 | 1.00 | 45.53 | A |
| ATOM | 1122 | O | HIS | 123 | 38.883 | 31.559 | 15.554 | 1.00 | 45.19 | A |
| ATOM | 1123 | N | MET | 124 | 40.433 | 31.087 | 14.011 | 1.00 | 44.71 | A |
| ATOM | 1124 | H | MET | 124 | 41.168 | 31.408 | 13.457 | 0.00 | 0.00 | A |
| ATOM | 1125 | CA | MET | 124 | 39.842 | 29.803 | 13.699 | 1.00 | 43.94 | A |
| ATOM | 1126 | CB | MET | 124 | 40.689 | 29.043 | 12.691 | 1.00 | 44.83 | A |
| ATOM | 1127 | CG | MET | 124 | 40.226 | 29.177 | 11.272 | 1.00 | 48.83 | A |
| ATOM | 1128 | SD | MET | 124 | 41.194 | 28.108 | 10.232 | 1.00 | 55.06 | A |
| ATOM | 1129 | CE | MET | 124 | 40.418 | 26.538 | 10.543 | 1.00 | 54.48 | A |
| ATOM | 1130 | C | MET | 124 | 39.701 | 28.952 | 14.941 | 1.00 | 43.43 | A |
| ATOM | 1131 | O | MET | 124 | 38.770 | 28.163 | 15.039 | 1.00 | 43.92 | A |
| ATOM | 1132 | N | ASP | 125 | 40.617 | 29.104 | 15.893 | 1.00 | 42.07 | A |
| ATOM | 1133 | H | ASP | 125 | 41.327 | 29.752 | 15.802 | 0.00 | 0.00 | A |
| ATOM | 1134 | CA | ASP | 125 | 40.540 | 28.296 | 17.092 | 1.00 | 42.75 | A |
| ATOM | 1135 | CB | ASP | 125 | 41.783 | 28.445 | 17.966 | 1.00 | 51.71 | A |
| ATOM | 1136 | CG | ASP | 125 | 41.918 | 27.290 | 18.965 | 1.00 | 63.91 | A |
| ATOM | 1137 | OD1 | ASP | 125 | 42.404 | 26.211 | 18.550 | 1.00 | 72.36 | A |
| ATOM | 1138 | OD2 | ASP | 125 | 41.492 | 27.413 | 20.146 | 1.00 | 68.02 | A |
| ATOM | 1139 | C | ASP | 125 | 39.275 | 28.566 | 17.898 | 1.00 | 40.22 | A |
| ATOM | 1140 | O | ASP | 125 | 38.916 | 27.808 | 18.800 | 1.00 | 39.87 | A |
| ATOM | 1141 | N | ASP | 126 | 38.570 | 29.630 | 17.566 | 1.00 | 36.36 | A |
| ATOM | 1142 | H | ASP | 126 | 38.835 | 30.255 | 16.875 | 0.00 | 0.00 | A |
| ATOM | 1143 | CA | ASP | 126 | 37.357 | 29.913 | 18.290 | 1.00 | 34.77 | A |
| ATOM | 1144 | CB | ASP | 126 | 37.197 | 31.407 | 18.514 | 1.00 | 39.84 | A |
| ATOM | 1145 | CG | ASP | 126 | 38.231 | 31.961 | 19.454 | 1.00 | 41.87 | A |
| ATOM | 1146 | OD1 | ASP | 126 | 38.670 | 33.108 | 19.218 | 1.00 | 46.83 | A |
| ATOM | 1147 | OD2 | ASP | 126 | 38.624 | 31.242 | 20.406 | 1.00 | 45.78 | A |
| ATOM | 1148 | C | ASP | 126 | 36.173 | 29.383 | 17.535 | 1.00 | 32.72 | A |
| ATOM | 1149 | O | ASP | 126 | 35.037 | 29.567 | 17.962 | 1.00 | 33.59 | A |
| ATOM | 1150 | N | VAL | 127 | 36.437 | 28.719 | 16.415 | 1.00 | 30.83 | A |
| ATOM | 1151 | H | VAL | 127 | 37.358 | 28.608 | 16.139 | 0.00 | 0.00 | A |
| ATOM | 1152 | CA | VAL | 127 | 35.382 | 28.155 | 15.583 | 1.00 | 29.48 | A |
| ATOM | 1153 | CB | VAL | 127 | 35.352 | 28.826 | 14.220 | 1.00 | 27.48 | A |
| ATOM | 1154 | CG1 | VAL | 127 | 34.149 | 28.372 | 13.452 | 1.00 | 29.76 | A |
| ATOM | 1155 | CG2 | VAL | 127 | 35.310 | 30.319 | 14.385 | 1.00 | 32.92 | A |
| ATOM | 1156 | C | VAL | 127 | 35.547 | 26.654 | 15.360 | 1.00 | 30.10 | A |
| ATOM | 1157 | O | VAL | 127 | 36.587 | 26.198 | 14.882 | 1.00 | 30.13 | A |
| ATOM | 1158 | N | ASN | 128 | 34.524 | 25.885 | 15.713 | 1.00 | 30.26 | A |
| ATOM | 1159 | H | ASN | 128 | 33.722 | 26.267 | 16.136 | 0.00 | 0.00 | A |
| ATOM | 1160 | CA | ASN | 128 | 34.566 | 24.444 | 15.511 | 1.00 | 30.42 | A |
| ATOM | 1161 | CB | ASN | 128 | 34.684 | 23.721 | 16.846 | 1.00 | 34.46 | A |
| ATOM | 1162 | CG | ASN | 128 | 34.899 | 22.228 | 16.681 | 1.00 | 36.26 | A |
| ATOM | 1163 | OD1 | ASN | 128 | 35.990 | 21.773 | 16.332 | 1.00 | 37.23 | A |
| ATOM | 1164 | ND2 | ASN | 128 | 33.864 | 21.457 | 16.951 | 1.00 | 40.11 | A |
| ATOM | 1165 | HD21 | ASN | 128 | 33.050 | 21.909 | 17.254 | 0.00 | 0.00 | A |
| ATOM | 1166 | HD22 | ASN | 128 | 33.967 | 20.488 | 16.845 | 0.00 | 0.00 | A |
| ATOM | 1167 | C | ASN | 128 | 33.314 | 23.986 | 14.758 | 1.00 | 29.41 | A |
| ATOM | 1168 | O | ASN | 128 | 32.218 | 24.491 | 14.994 | 1.00 | 33.57 | A |
| ATOM | 1169 | N | VAL | 129 | 33.490 | 23.081 | 13.806 | 1.00 | 25.98 | A |
| ATOM | 1170 | H | VAL | 129 | 34.374 | 22.691 | 13.636 | 0.00 | 0.00 | A |
| ATOM | 1171 | CA | VAL | 129 | 32.384 | 22.562 | 13.014 | 1.00 | 22.72 | A |
| ATOM | 1172 | CB | VAL | 129 | 32.470 | 23.039 | 11.574 | 1.00 | 18.54 | A |
| ATOM | 1173 | CG1 | VAL | 129 | 31.390 | 22.408 | 10.758 | 1.00 | 16.76 | A |
| ATOM | 1174 | CG2 | VAL | 129 | 32.375 | 24.526 | 11.513 | 1.00 | 18.49 | A |
| ATOM | 1175 | C | VAL | 129 | 32.589 | 21.063 | 12.990 | 1.00 | 25.37 | A |
| ATOM | 1176 | O | VAL | 129 | 33.728 | 20.601 | 12.883 | 1.00 | 28.16 | A |
| ATOM | 1177 | N | LYS | 130 | 31.526 | 20.294 | 13.153 | 1.00 | 24.23 | A |
| ATOM | 1178 | H | LYS | 130 | 30.631 | 20.675 | 13.253 | 0.00 | 0.00 | A |
| ATOM | 1179 | CA | LYS | 130 | 31.685 | 18.854 | 13.105 | 1.00 | 27.49 | A |
| ATOM | 1180 | CB | LYS | 130 | 31.827 | 18.244 | 14.493 | 1.00 | 30.39 | A |
| ATOM | 1181 | CG | LYS | 130 | 30.645 | 18.386 | 15.400 | 1.00 | 34.45 | A |
| ATOM | 1182 | CD | LYS | 130 | 30.994 | 17.827 | 16.767 | 1.00 | 34.01 | A |
| ATOM | 1183 | CE | LYS | 130 | 31.450 | 18.918 | 17.693 | 1.00 | 34.22 | A |
| ATOM | 1184 | NZ | LYS | 130 | 30.340 | 19.883 | 17.905 | 1.00 | 30.81 | A |
| ATOM | 1185 | HZ1 | LYS | 130 | 30.709 | 20.550 | 18.610 | 0.00 | 0.00 | A |
| ATOM | 1186 | HZ2 | LYS | 130 | 29.512 | 19.440 | 18.320 | 0.00 | 0.00 | A |
| ATOM | 1187 | HZ3 | LYS | 130 | 30.149 | 20.490 | 17.088 | 0.00 | 0.00 | A |
| ATOM | 1188 | C | LYS | 130 | 30.514 | 18.290 | 12.364 | 1.00 | 28.74 | A |
| ATOM | 1189 | O | LYS | 130 | 29.607 | 19.049 | 11.997 | 1.00 | 31.31 | A |
| ATOM | 1190 | N | ALA | 131 | 30.537 | 16.987 | 12.097 | 1.00 | 27.87 | A |
| ATOM | 1191 | H | ALA | 131 | 31.279 | 16.408 | 12.419 | 0.00 | 0.00 | A |
| ATOM | 1192 | CA | ALA | 131 | 29.451 | 16.368 | 11.350 | 1.00 | 29.02 | A |
| ATOM | 1193 | CB | ALA | 131 | 29.796 | 16.298 | 9.890 | 1.00 | 24.98 | A |
| ATOM | 1194 | C | ALA | 131 | 29.084 | 14.999 | 11.864 | 1.00 | 31.32 | A |
| ATOM | 1195 | O | ALA | 131 | 29.923 | 14.290 | 12.435 | 1.00 | 34.62 | A |
| ATOM | 1196 | N | THR | 132 | 27.823 | 14.634 | 11.644 | 1.00 | 33.28 | A |
| ATOM | 1197 | H | THR | 132 | 27.206 | 15.237 | 11.177 | 0.00 | 0.00 | A |
| ATOM | 1198 | CA | THR | 132 | 27.293 | 13.354 | 12.074 | 1.00 | 36.07 | A |
| ATOM | 1199 | CB | THR | 132 | 26.783 | 13.438 | 13.521 | 1.00 | 37.37 | A |
| ATOM | 1200 | OG1 | THR | 132 | 26.402 | 12.131 | 13.961 | 1.00 | 42.55 | A |
| ATOM | 1201 | HG1 | THR | 132 | 25.519 | 11.835 | 13.717 | 0.00 | 0.00 | A |
| ATOM | 1202 | CG2 | THR | 132 | 25.573 | 14.370 | 13.626 | 1.00 | 37.24 | A |
| ATOM | 1203 | C | THR | 132 | 26.154 | 12.862 | 11.182 | 1.00 | 39.30 | A |
| ATOM | 1204 | O | THR | 132 | 25.457 | 13.654 | 10.540 | 1.00 | 40.63 | A |
| ATOM | 1205 | N | THR | 133 | 25.931 | 11.550 | 11.216 | 1.00 | 43.16 | A |
| ATOM | 1206 | H | THR | 133 | 26.487 | 10.995 | 11.807 | 0.00 | 0.00 | A |
| ATOM | 1207 | CA | THR | 133 | 24.884 | 10.866 | 10.448 | 1.00 | 44.61 | A |
| ATOM | 1208 | CB | THR | 133 | 25.461 | 9.607 | 9.806 | 1.00 | 45.68 | A |
| ATOM | 1209 | OG1 | THR | 133 | 26.458 | 9.968 | 8.856 | 1.00 | 54.55 | A |
| ATOM | 1210 | HG1 | THR | 133 | 26.114 | 10.493 | 8.124 | 0.00 | 0.00 | A |
| ATOM | 1211 | CG2 | THR | 133 | 24.420 | 8.831 | 9.119 | 1.00 | 49.24 | A |
| ATOM | 1212 | C | THR | 133 | 23.817 | 10.368 | 11.408 | 1.00 | 44.26 | A |
| ATOM | 1213 | O | THR | 133 | 24.092 | 10.174 | 12.591 | 1.00 | 46.81 | A |
| ATOM | 1214 | N | THR | 134 | 22.603 | 10.167 | 10.919 | 1.00 | 42.50 | A |
| ATOM | 1215 | H | THR | 134 | 22.346 | 10.415 | 10.010 | 0.00 | 0.00 | A |
| ATOM | 1216 | CA | THR | 134 | 21.563 | 9.619 | 11.774 | 1.00 | 42.96 | A |
| ATOM | 1217 | CB | THR | 134 | 20.257 | 10.360 | 11.568 | 1.00 | 41.63 | A |
| ATOM | 1218 | OG1 | THR | 134 | 20.101 | 10.678 | 10.178 | 1.00 | 42.80 | A |
| ATOM | 1219 | HG1 | THR | 134 | 19.147 | 10.832 | 10.070 | 0.00 | 0.00 | A |
| ATOM | 1220 | CG2 | THR | 134 | 20.282 | 11.623 | 12.357 | 1.00 | 40.56 | A |
| ATOM | 1221 | C | THR | 134 | 21.416 | 8.113 | 11.467 | 1.00 | 44.93 | A |
| ATOM | 1222 | O | THR | 134 | 20.389 | 7.492 | 11.758 | 1.00 | 46.76 | A |
| ATOM | 1223 | N | GLU | 135 | 22.494 | 7.535 | 10.934 | 1.00 | 44.61 | A |
| ATOM | 1224 | H | GLU | 135 | 23.331 | 8.015 | 10.930 | 0.00 | 0.00 | A |
| ATOM | 1225 | CA | GLU | 135 | 22.596 | 6.128 | 10.542 | 1.00 | 45.80 | A |
| ATOM | 1226 | CB | GLU | 135 | 22.879 | 5.238 | 11.757 | 1.00 | 48.20 | A |
| ATOM | 1227 | CG | GLU | 135 | 24.045 | 5.682 | 12.655 | 1.00 | 55.67 | A |
| ATOM | 1228 | CD | GLU | 135 | 25.427 | 5.492 | 12.043 | 1.00 | 60.08 | A |
| ATOM | 1229 | OE1 | GLU | 135 | 25.708 | 6.096 | 10.982 | 1.00 | 67.29 | A |
| ATOM | 1230 | OE2 | GLU | 135 | 26.245 | 4.756 | 12.639 | 1.00 | 63.15 | A |
| ATOM | 1231 | C | GLU | 135 | 21.384 | 5.621 | 9.760 | 1.00 | 46.06 | A |
| ATOM | 1232 | O | GLU | 135 | 20.798 | 4.586 | 10.088 | 1.00 | 47.45 | A |
| ATOM | 1233 | N | LYS | 136 | 21.046 | 6.339 | 8.693 | 1.00 | 44.79 | A |
| ATOM | 1234 | H | LYS | 136 | 21.610 | 7.085 | 8.444 | 0.00 | 0.00 | A |
| ATOM | 1235 | CA | LYS | 136 | 19.907 | 6.009 | 7.843 | 1.00 | 44.04 | A |
| ATOM | 1236 | CB | LYS | 136 | 19.966 | 4.561 | 7.374 | 1.00 | 47.65 | A |
| ATOM | 1237 | CG | LYS | 136 | 21.094 | 4.237 | 6.396 | 1.00 | 53.89 | A |
| ATOM | 1238 | CD | LYS | 136 | 20.770 | 4.670 | 4.977 | 1.00 | 59.40 | A |
| ATOM | 1239 | CE | LYS | 136 | 21.820 | 4.126 | 3.999 | 1.00 | 67.26 | A |
| ATOM | 1240 | NZ | LYS | 136 | 21.523 | 4.435 | 2.551 | 1.00 | 70.49 | A |
| ATOM | 1241 | HZ1 | LYS | 136 | 22.266 | 4.037 | 1.943 | 0.00 | 0.00 | A |
| ATOM | 1242 | HZ2 | LYS | 136 | 21.500 | 5.471 | 2.451 | 0.00 | 0.00 | A |
| ATOM | 1243 | HZ3 | LYS | 136 | 20.593 | 4.048 | 2.297 | 0.00 | 0.00 | A |
| ATOM | 1244 | C | LYS | 136 | 18.555 | 6.299 | 8.493 | 1.00 | 43.12 | A |
| ATOM | 1245 | O | LYS | 136 | 17.538 | 6.317 | 7.808 | 1.00 | 45.73 | A |
| ATOM | 1246 | N | LEU | 137 | 18.538 | 6.545 | 9.799 | 1.00 | 39.95 | A |
| ATOM | 1247 | H | LEU | 137 | 19.346 | 6.519 | 10.343 | 0.00 | 0.00 | A |
| ATOM | 1248 | CA | LEU | 137 | 17.294 | 6.870 | 10.488 | 1.00 | 36.53 | A |
| ATOM | 1249 | CB | LEU | 137 | 17.444 | 6.691 | 12.004 | 1.00 | 34.12 | A |
| ATOM | 1250 | CG | LEU | 137 | 17.855 | 5.322 | 12.499 | 1.00 | 30.87 | A |
| ATOM | 1251 | CD1 | LEU | 137 | 17.749 | 5.271 | 13.979 | 1.00 | 31.56 | A |
| ATOM | 1252 | CD2 | LEU | 137 | 16.937 | 4.318 | 11.915 | 1.00 | 31.30 | A |
| ATOM | 1253 | C | LEU | 137 | 16.873 | 8.317 | 10.222 | 1.00 | 34.78 | A |
| ATOM | 1254 | O | LEU | 137 | 17.716 | 9.229 | 10.144 | 1.00 | 33.11 | A |
| ATOM | 1255 | N | GLY | 138 | 15.568 | 8.517 | 10.074 | 1.00 | 31.84 | A |
| ATOM | 1256 | H | GLY | 138 | 14.999 | 7.723 | 10.080 | 0.00 | 0.00 | A |
| ATOM | 1257 | CA | GLY | 138 | 15.037 | 9.858 | 9.884 | 1.00 | 31.47 | A |
| ATOM | 1258 | C | GLY | 138 | 15.017 | 10.507 | 8.518 | 1.00 | 31.07 | A |
| ATOM | 1259 | O | GLY | 138 | 15.489 | 9.938 | 7.546 | 1.00 | 34.43 | A |
| ATOM | 1260 | N | PHE | 139 | 14.463 | 11.712 | 8.441 | 1.00 | 29.27 | A |
| ATOM | 1261 | H | PHE | 139 | 14.141 | 12.161 | 9.248 | 0.00 | 0.00 | A |
| ATOM | 1262 | CA | PHE | 139 | 14.391 | 12.394 | 7.174 | 1.00 | 29.25 | A |
| ATOM | 1263 | CB | PHE | 139 | 13.594 | 13.690 | 7.255 | 1.00 | 32.54 | A |
| ATOM | 1264 | CG | PHE | 139 | 14.283 | 14.815 | 7.980 | 1.00 | 35.05 | A |
| ATOM | 1265 | CD1 | PHE | 139 | 15.221 | 15.607 | 7.332 | 1.00 | 34.64 | A |
| ATOM | 1266 | CD2 | PHE | 139 | 13.900 | 15.160 | 9.278 | 1.00 | 34.02 | A |
| ATOM | 1267 | CE1 | PHE | 139 | 15.759 | 16.730 | 7.958 | 1.00 | 36.71 | A |
| ATOM | 1268 | CE2 | PHE | 139 | 14.435 | 16.284 | 9.919 | 1.00 | 34.42 | A |
| ATOM | 1269 | CZ | PHE | 139 | 15.363 | 17.073 | 9.257 | 1.00 | 36.02 | A |
| ATOM | 1270 | C | PHE | 139 | 15.782 | 12.638 | 6.703 | 1.00 | 30.10 | A |
| ATOM | 1271 | O | PHE | 139 | 16.039 | 12.644 | 5.517 | 1.00 | 32.97 | A |
| ATOM | 1272 | N | THR | 140 | 16.690 | 12.842 | 7.640 | 1.00 | 30.55 | A |
| ATOM | 1273 | H | THR | 140 | 16.473 | 12.864 | 8.590 | 0.00 | 0.00 | A |
| ATOM | 1274 | CA | THR | 140 | 18.076 | 13.050 | 7.272 | 1.00 | 33.04 | A |
| ATOM | 1275 | CB | THR | 140 | 18.933 | 13.553 | 8.445 | 1.00 | 29.98 | A |
| ATOM | 1276 | OG1 | THR | 140 | 18.696 | 12.727 | 9.594 | 1.00 | 34.35 | A |
| ATOM | 1277 | HG1 | THR | 140 | 19.306 | 13.027 | 10.280 | 0.00 | 0.00 | A |
| ATOM | 1278 | CG2 | THR | 140 | 18.629 | 14.995 | 8.753 | 1.00 | 22.60 | A |
| ATOM | 1279 | C | THR | 140 | 18.599 | 11.686 | 6.856 | 1.00 | 34.77 | A |
| ATOM | 1280 | O | THR | 140 | 19.274 | 11.569 | 5.832 | 1.00 | 39.03 | A |
| ATOM | 1281 | N | GLY | 141 | 18.283 | 10.663 | 7.649 | 1.00 | 33.47 | A |
| ATOM | 1282 | H | GLY | 141 | 17.761 | 10.805 | 8.462 | 0.00 | 0.00 | A |
| ATOM | 1283 | CA | GLY | 141 | 18.735 | 9.319 | 7.345 | 1.00 | 32.17 | A |
| ATOM | 1284 | C | GLY | 141 | 18.267 | 8.866 | 5.983 | 1.00 | 33.73 | A |
| ATOM | 1285 | O | GLY | 141 | 18.980 | 8.183 | 5.254 | 1.00 | 36.15 | A |
| ATOM | 1286 | N | ARG | 142 | 17.082 | 9.311 | 5.604 | 1.00 | 34.72 | A |
| ATOM | 1287 | H | ARG | 142 | 16.606 | 9.934 | 6.163 | 0.00 | 0.00 | A |
| ATOM | 1288 | CA | ARG | 142 | 16.522 | 8.948 | 4.324 | 1.00 | 35.05 | A |
| ATOM | 1289 | CB | ARG | 142 | 15.016 | 8.995 | 4.390 | 1.00 | 33.09 | A |
| ATOM | 1290 | CG | ARG | 142 | 14.440 | 7.902 | 5.210 | 1.00 | 37.43 | A |
| ATOM | 1291 | CD | ARG | 142 | 12.948 | 7.895 | 5.008 | 1.00 | 42.67 | A |
| ATOM | 1292 | NE | ARG | 142 | 12.404 | 9.168 | 5.433 | 1.00 | 43.43 | A |
| ATOM | 1293 | HE | ARG | 142 | 12.291 | 9.825 | 4.718 | 0.00 | 0.00 | A |
| ATOM | 1294 | CZ | ARG | 142 | 12.091 | 9.439 | 6.687 | 1.00 | 44.72 | A |
| ATOM | 1295 | NH1 | ARG | 142 | 11.626 | 10.639 | 7.006 | 1.00 | 45.73 | A |
| ATOM | 1296 | HH11 | ARG | 142 | 11.578 | 11.299 | 6.217 | 0.00 | 0.00 | A |
| ATOM | 1297 | HH12 | ARG | 142 | 11.382 | 10.960 | 7.905 | 0.00 | 0.00 | A |
| ATOM | 1298 | NH2 | ARG | 142 | 12.224 | 8.492 | 7.609 | 1.00 | 45.65 | A |
| ATOM | 1299 | HH21 | ARG | 142 | 12.565 | 7.593 | 7.312 | 0.00 | 0.00 | A |
| ATOM | 1300 | HH22 | ARG | 142 | 12.006 | 8.608 | 8.569 | 0.00 | 0.00 | A |
| ATOM | 1301 | C | ARG | 142 | 16.995 | 9.884 | 3.235 | 1.00 | 36.23 | A |
| ATOM | 1302 | O | ARG | 142 | 16.518 | 9.826 | 2.109 | 1.00 | 40.53 | A |
| ATOM | 1303 | N | GLY | 143 | 17.909 | 10.774 | 3.571 | 1.00 | 34.81 | A |
| ATOM | 1304 | H | GLY | 143 | 18.252 | 10.797 | 4.479 | 0.00 | 0.00 | A |
| ATOM | 1305 | CA | GLY | 143 | 18.408 | 11.699 | 2.581 | 1.00 | 35.64 | A |
| ATOM | 1306 | C | GLY | 143 | 17.370 | 12.681 | 2.074 | 1.00 | 36.73 | A |
| ATOM | 1307 | O | GLY | 143 | 17.464 | 13.134 | 0.925 | 1.00 | 40.69 | A |
| ATOM | 1308 | N | GLU | 144 | 16.398 | 13.025 | 2.914 | 1.00 | 35.49 | A |
| ATOM | 1309 | H | GLU | 144 | 16.358 | 12.581 | 3.771 | 0.00 | 0.00 | A |
| ATOM | 1310 | CA | GLU | 144 | 15.362 | 13.975 | 2.542 | 1.00 | 33.73 | A |
| ATOM | 1311 | CB | GLU | 144 | 14.083 | 13.671 | 3.289 | 1.00 | 31.22 | A |
| ATOM | 1312 | CG | GLU | 144 | 13.645 | 12.261 | 3.107 | 1.00 | 35.07 | A |
| ATOM | 1313 | CD | GLU | 144 | 12.391 | 11.933 | 3.864 | 1.00 | 39.55 | A |
| ATOM | 1314 | OE1 | GLU | 144 | 11.683 | 10.998 | 3.433 | 1.00 | 41.84 | A |
| ATOM | 1315 | OE2 | GLU | 144 | 12.110 | 12.577 | 4.904 | 1.00 | 42.38 | A |
| ATOM | 1316 | C | GLU | 144 | 15.773 | 15.417 | 2.803 | 1.00 | 34.19 | A |
| ATOM | 1317 | O | GLU | 144 | 15.193 | 16.333 | 2.235 | 1.00 | 38.36 | A |
| ATOM | 1318 | N | GLY | 145 | 16.779 | 15.627 | 3.641 | 1.00 | 32.32 | A |
| ATOM | 1319 | H | GLY | 145 | 17.248 | 14.881 | 4.071 | 0.00 | 0.00 | A |
| ATOM | 1320 | CA | GLY | 145 | 17.206 | 16.980 | 3.945 | 1.00 | 30.14 | A |
| ATOM | 1321 | C | GLY | 145 | 18.418 | 16.972 | 4.847 | 1.00 | 31.35 | A |
| ATOM | 1322 | O | GLY | 145 | 18.949 | 15.899 | 5.159 | 1.00 | 33.79 | A |
| ATOM | 1323 | N | ILE | 146 | 18.874 | 18.156 | 5.242 | 1.00 | 30.57 | A |
| ATOM | 1324 | H | ILE | 146 | 18.407 | 18.973 | 4.959 | 0.00 | 0.00 | A |
| ATOM | 1325 | CA | ILE | 146 | 20.041 | 18.284 | 6.110 | 1.00 | 31.73 | A |
| ATOM | 1326 | CB | ILE | 146 | 21.255 | 18.934 | 5.379 | 1.00 | 33.69 | A |
| ATOM | 1327 | CG2 | ILE | 146 | 22.311 | 19.384 | 6.377 | 1.00 | 34.94 | A |
| ATOM | 1328 | CG1 | ILE | 146 | 21.912 | 17.941 | 4.423 | 1.00 | 34.49 | A |
| ATOM | 1329 | CD1 | ILE | 146 | 23.121 | 18.503 | 3.704 | 1.00 | 34.89 | A |
| ATOM | 1330 | C | ILE | 146 | 19.656 | 19.180 | 7.258 | 1.00 | 31.78 | A |
| ATOM | 1331 | O | ILE | 146 | 19.002 | 20.205 | 7.056 | 1.00 | 36.22 | A |
| ATOM | 1332 | N | ALA | 147 | 20.057 | 18.803 | 8.463 | 1.00 | 29.08 | A |
| ATOM | 1333 | H | ALA | 147 | 20.614 | 18.001 | 8.569 | 0.00 | 0.00 | A |
| ATOM | 1334 | CA | ALA | 147 | 19.753 | 19.601 | 9.637 | 1.00 | 27.19 | A |
| ATOM | 1335 | CB | ALA | 147 | 18.973 | 18.782 | 10.624 | 1.00 | 25.22 | A |
| ATOM | 1336 | C | ALA | 147 | 21.080 | 20.017 | 10.233 | 1.00 | 27.00 | A |
| ATOM | 1337 | O | ALA | 147 | 22.115 | 19.458 | 9.875 | 1.00 | 29.62 | A |
| ATOM | 1338 | N | CYS | 148 | 21.069 | 20.997 | 11.126 | 1.00 | 27.21 | A |
| ATOM | 1339 | H | CYS | 148 | 20.230 | 21.447 | 11.363 | 0.00 | 0.00 | A |
| ATOM | 1340 | CA | CYS | 148 | 22.299 | 21.442 | 11.765 | 1.00 | 28.02 | A |
| ATOM | 1341 | CB | CYS | 148 | 23.018 | 22.446 | 10.877 | 1.00 | 30.78 | A |
| ATOM | 1342 | SG | CYS | 148 | 24.648 | 22.936 | 11.456 | 1.00 | 40.03 | A |
| ATOM | 1343 | C | CYS | 148 | 21.992 | 22.076 | 13.111 | 1.00 | 28.21 | A |
| ATOM | 1344 | O | CYS | 148 | 20.912 | 22.630 | 13.307 | 1.00 | 30.03 | A |
| ATOM | 1345 | N | GLU | 149 | 22.920 | 21.958 | 14.052 | 1.00 | 27.43 | A |
| ATOM | 1346 | H | GLU | 149 | 23.755 | 21.489 | 13.862 | 0.00 | 0.00 | A |
| ATOM | 1347 | CA | GLU | 149 | 22.749 | 22.546 | 15.378 | 1.00 | 27.03 | A |
| ATOM | 1348 | CB | GLU | 149 | 22.647 | 21.471 | 16.439 | 1.00 | 25.66 | A |
| ATOM | 1349 | CG | GLU | 149 | 21.384 | 20.714 | 16.386 | 1.00 | 31.88 | A |
| ATOM | 1350 | CD | GLU | 149 | 20.895 | 20.385 | 17.755 | 1.00 | 34.90 | A |
| ATOM | 1351 | OE1 | GLU | 149 | 20.892 | 21.295 | 18.603 | 1.00 | 38.22 | A |
| ATOM | 1352 | OE2 | GLU | 149 | 20.551 | 19.219 | 17.988 | 1.00 | 38.19 | A |
| ATOM | 1353 | C | GLU | 149 | 23.971 | 23.381 | 15.673 | 1.00 | 26.40 | A |
| ATOM | 1354 | O | GLU | 149 | 25.038 | 23.122 | 15.119 | 1.00 | 29.71 | A |
| ATOM | 1355 | N | ALA | 150 | 23.848 | 24.336 | 16.581 | 1.00 | 22.85 | A |
| ATOM | 1356 | H | ALA | 150 | 22.988 | 24.481 | 17.031 | 0.00 | 0.00 | A |
| ATOM | 1357 | CA | ALA | 150 | 24.983 | 25.171 | 16.911 | 1.00 | 23.70 | A |
| ATOM | 1358 | CB | ALA | 150 | 25.135 | 26.271 | 15.879 | 1.00 | 23.80 | A |
| ATOM | 1359 | C | ALA | 150 | 24.848 | 25.785 | 18.280 | 1.00 | 26.05 | A |
| ATOM | 1360 | O | ALA | 150 | 23.732 | 25.989 | 18.778 | 1.00 | 27.61 | A |
| ATOM | 1361 | N | VAL | 151 | 25.986 | 26.016 | 18.922 | 1.00 | 26.79 | A |
| ATOM | 1362 | H | VAL | 151 | 26.850 | 25.784 | 18.520 | 0.00 | 0.00 | A |
| ATOM | 1363 | CA | VAL | 151 | 25.985 | 26.675 | 20.215 | 1.00 | 28.64 | A |
| ATOM | 1364 | CB | VAL | 151 | 26.298 | 25.747 | 21.376 | 1.00 | 26.52 | A |
| ATOM | 1365 | CG1 | VAL | 151 | 25.164 | 24.778 | 21.556 | 1.00 | 25.94 | A |
| ATOM | 1366 | CG2 | VAL | 151 | 27.620 | 25.058 | 21.168 | 1.00 | 25.61 | A |
| ATOM | 1367 | C | VAL | 151 | 27.047 | 27.733 | 20.113 | 1.00 | 30.50 | A |
| ATOM | 1368 | O | VAL | 151 | 27.991 | 27.577 | 19.338 | 1.00 | 33.35 | A |
| ATOM | 1369 | N | ALA | 152 | 26.852 | 28.832 | 20.836 | 1.00 | 30.80 | A |
| ATOM | 1370 | H | ALA | 152 | 26.061 | 28.889 | 21.417 | 0.00 | 0.00 | A |
| ATOM | 1371 | CA | ALA | 152 | 27.786 | 29.950 | 20.839 | 1.00 | 30.69 | A |
| ATOM | 1372 | CB | ALA | 152 | 27.315 | 31.025 | 19.915 | 1.00 | 29.59 | A |
| ATOM | 1373 | C | ALA | 152 | 27.868 | 30.509 | 22.231 | 1.00 | 31.01 | A |
| ATOM | 1374 | O | ALA | 152 | 26.945 | 30.357 | 23.022 | 1.00 | 34.37 | A |
| ATOM | 1375 | N | LEU | 153 | 28.986 | 31.141 | 22.533 | 1.00 | 30.94 | A |
| ATOM | 1376 | H | LEU | 153 | 29.701 | 31.205 | 21.866 | 0.00 | 0.00 | A |
| ATOM | 1377 | CA | LEU | 153 | 29.179 | 31.749 | 23.823 | 1.00 | 30.88 | A |
| ATOM | 1378 | CB | LEU | 153 | 30.164 | 30.933 | 24.625 | 1.00 | 34.85 | A |
| ATOM | 1379 | CG | LEU | 153 | 30.532 | 31.379 | 26.034 | 1.00 | 40.14 | A |
| ATOM | 1380 | CD1 | LEU | 153 | 31.159 | 30.203 | 26.756 | 1.00 | 42.45 | A |
| ATOM | 1381 | CD2 | LEU | 153 | 31.507 | 32.545 | 25.998 | 1.00 | 42.83 | A |
| ATOM | 1382 | C | LEU | 153 | 29.737 | 33.111 | 23.499 | 1.00 | 31.79 | A |
| ATOM | 1383 | O | LEU | 153 | 30.719 | 33.215 | 22.766 | 1.00 | 33.28 | A |
| ATOM | 1384 | N | LEU | 154 | 29.022 | 34.150 | 23.917 | 1.00 | 31.67 | A |
| ATOM | 1385 | H | LEU | 154 | 28.207 | 33.982 | 24.422 | 0.00 | 0.00 | A |
| ATOM | 1386 | CA | LEU | 154 | 29.436 | 35.523 | 23.683 | 1.00 | 29.03 | A |
| ATOM | 1387 | CB | LEU | 154 | 28.265 | 36.382 | 23.229 | 1.00 | 23.35 | A |
| ATOM | 1388 | CG | LEU | 154 | 27.591 | 36.013 | 21.914 | 1.00 | 21.34 | A |
| ATOM | 1389 | CD1 | LEU | 154 | 26.422 | 36.940 | 21.678 | 1.00 | 22.18 | A |
| ATOM | 1390 | CD2 | LEU | 154 | 28.561 | 36.091 | 20.777 | 1.00 | 20.06 | A |
| ATOM | 1391 | C | LEU | 154 | 29.961 | 36.036 | 25.005 | 1.00 | 30.48 | A |
| ATOM | 1392 | O | LEU | 154 | 29.595 | 35.533 | 26.068 | 1.00 | 28.15 | A |
| ATOM | 1393 | N | ILE | 155 | 30.814 | 37.045 | 24.930 | 1.00 | 34.27 | A |
| ATOM | 1394 | H | ILE | 155 | 31.029 | 37.431 | 24.063 | 0.00 | 0.00 | A |
| ATOM | 1395 | CA | ILE | 155 | 31.431 | 37.629 | 26.103 | 1.00 | 38.12 | A |
| ATOM | 1396 | CB | ILE | 155 | 32.919 | 37.389 | 26.054 | 1.00 | 39.05 | A |
| ATOM | 1397 | CG2 | ILE | 155 | 33.605 | 38.171 | 27.118 | 1.00 | 40.00 | A |
| ATOM | 1398 | CG1 | ILE | 155 | 33.178 | 35.905 | 26.263 | 1.00 | 44.51 | A |
| ATOM | 1399 | CD1 | ILE | 155 | 34.620 | 35.510 | 26.130 | 1.00 | 53.49 | A |
| ATOM | 1400 | C | ILE | 155 | 31.158 | 39.116 | 26.193 | 1.00 | 40.33 | A |
| ATOM | 1401 | O | ILE | 155 | 30.730 | 39.719 | 25.212 | 1.00 | 46.67 | A |
| ATOM | 1402 | ZN | ZN | 156 | 17.669 | 27.814 | 7.041 | 1.00 | 51.26 | A |
| ATOM | 1403 | OZN | OZN | 157 | 16.081 | 28.929 | 7.090 | 1.00 | 41.54 | A |
| END | | | | | | | | | | |

ANNEX 4
Coordinates of structure sub2

| | | | | | | | | | | |
|---|---|---|---|---|---|---|---|---|---|---|
| ATOM | 1 | CB | MET | 1 | 29.901 | 34.119 | 29.417 | 1.00 | 51.95 | A |
| ATOM | 2 | CG | MET | 1 | 31.314 | 34.275 | 28.920 | 1.00 | 61.31 | A |
| ATOM | 3 | SD | MET | 1 | 32.349 | 32.940 | 29.486 | 1.00 | 73.99 | A |
| ATOM | 4 | CE | MET | 1 | 33.323 | 33.812 | 30.799 | 1.00 | 72.56 | A |
| ATOM | 5 | C | MET | 1 | 27.601 | 34.854 | 28.814 | 1.00 | 44.54 | A |
| ATOM | 6 | O | MET | 1 | 26.836 | 34.633 | 29.749 | 1.00 | 45.32 | A |
| ATOM | 7 | HT1 | MET | 1 | 28.755 | 35.983 | 30.994 | 0.00 | 0.00 | A |
| ATOM | 8 | HT2 | MET | 1 | 28.575 | 37.193 | 29.843 | 0.00 | 0.00 | A |
| ATOM | 9 | N | MET | 1 | 29.162 | 36.383 | 30.112 | 1.00 | 46.93 | A |
| ATOM | 10 | HT3 | MET | 1 | 30.142 | 36.655 | 30.281 | 0.00 | 0.00 | A |
| ATOM | 11 | CA | MET | 1 | 29.030 | 35.314 | 29.069 | 1.00 | 47.91 | A |
| ATOM | 12 | N | ARG | 2 | 27.244 | 34.723 | 27.541 | 1.00 | 41.96 | A |
| ATOM | 13 | H | ARG | 2 | 27.883 | 34.853 | 26.810 | 0.00 | 0.00 | A |
| ATOM | 14 | CA | ARG | 2 | 25.902 | 34.305 | 27.153 | 1.00 | 38.93 | A |
| ATOM | 15 | CB | ARG | 2 | 25.140 | 35.473 | 26.525 | 1.00 | 38.22 | A |
| ATOM | 16 | CG | ARG | 2 | 24.814 | 36.535 | 27.557 | 1.00 | 39.75 | A |
| ATOM | 17 | CD | ARG | 2 | 24.023 | 37.671 | 26.992 | 1.00 | 44.11 | A |
| ATOM | 18 | NE | ARG | 2 | 22.700 | 37.251 | 26.554 | 1.00 | 47.84 | A |
| ATOM | 19 | HE | ARG | 2 | 22.635 | 36.711 | 25.750 | 0.00 | 0.00 | A |
| ATOM | 20 | CZ | ARG | 2 | 21.574 | 37.498 | 27.212 | 1.00 | 49.14 | A |
| ATOM | 21 | NH1 | ARG | 2 | 20.418 | 37.068 | 26.707 | 1.00 | 47.55 | A |
| ATOM | 22 | HH11 | ARG | 2 | 20.344 | 36.512 | 25.869 | 0.00 | 0.00 | A |
| ATOM | 23 | HH12 | ARG | 2 | 19.552 | 37.270 | 27.172 | 0.00 | 0.00 | A |
| ATOM | 24 | NH2 | ARG | 2 | 21.618 | 38.100 | 28.404 | 1.00 | 48.99 | A |
| ATOM | 25 | HH21 | ARG | 2 | 22.469 | 38.362 | 28.849 | 0.00 | 0.00 | A |
| ATOM | 26 | HH22 | ARG | 2 | 20.783 | 38.311 | 28.949 | 0.00 | 0.00 | A |
| ATOM | 27 | C | ARG | 2 | 25.946 | 33.106 | 26.229 | 1.00 | 36.54 | A |
| ATOM | 28 | O | ARG | 2 | 26.844 | 32.987 | 25.403 | 1.00 | 37.10 | A |
| ATOM | 29 | N | ILE | 3 | 24.965 | 32.227 | 26.374 | 1.00 | 34.62 | A |
| ATOM | 30 | H | ILE | 3 | 24.201 | 32.464 | 26.919 | 0.00 | 0.00 | A |
| ATOM | 31 | CA | ILE | 3 | 24.885 | 30.999 | 25.596 | 1.00 | 32.46 | A |
| ATOM | 32 | CB | ILE | 3 | 24.642 | 29.791 | 26.548 | 1.00 | 34.66 | A |
| ATOM | 33 | CG2 | ILE | 3 | 23.241 | 29.835 | 27.154 | 1.00 | 34.08 | A |
| ATOM | 34 | CG1 | ILE | 3 | 24.792 | 28.475 | 25.804 | 1.00 | 38.26 | A |
| ATOM | 35 | CD1 | ILE | 3 | 24.435 | 27.286 | 26.668 | 1.00 | 41.98 | A |
| ATOM | 36 | C | ILE | 3 | 23.768 | 31.080 | 24.560 | 1.00 | 30.29 | A |
| ATOM | 37 | O | ILE | 3 | 22.735 | 31.702 | 24.795 | 1.00 | 29.29 | A |
| ATOM | 38 | N | GLY | 4 | 23.978 | 30.451 | 23.414 | 1.00 | 29.36 | A |
| ATOM | 39 | H | GLY | 4 | 24.816 | 29.967 | 23.256 | 0.00 | 0.00 | A |
| ATOM | 40 | CA | GLY | 4 | 22.964 | 30.457 | 22.376 | 1.00 | 28.58 | A |
| ATOM | 41 | C | GLY | 4 | 22.876 | 29.106 | 21.698 | 1.00 | 27.65 | A |
| ATOM | 42 | O | GLY | 4 | 23.847 | 28.345 | 21.702 | 1.00 | 26.35 | A |
| ATOM | 43 | N | HIS | 5 | 21.715 | 28.807 | 21.122 | 1.00 | 27.16 | A |
| ATOM | 44 | H | HIS | 5 | 21.017 | 29.479 | 21.153 | 0.00 | 0.00 | A |
| ATOM | 45 | CA | HIS | 5 | 21.473 | 27.549 | 20.415 | 1.00 | 26.76 | A |
| ATOM | 46 | CB | HIS | 5 | 20.753 | 26.546 | 21.317 | 1.00 | 26.36 | A |
| ATOM | 47 | CG | HIS | 5 | 20.244 | 25.344 | 20.584 | 1.00 | 28.76 | A |
| ATOM | 48 | CD2 | HIS | 5 | 20.835 | 24.158 | 20.293 | 1.00 | 27.44 | A |
| ATOM | 49 | ND1 | HIS | 5 | 18.998 | 25.307 | 19.994 | 1.00 | 28.95 | A |
| ATOM | 50 | HD1 | HIS | 5 | 18.293 | 25.998 | 20.023 | 0.00 | 0.00 | A |
| ATOM | 51 | CE1 | HIS | 5 | 18.845 | 24.153 | 19.366 | 1.00 | 29.15 | A |
| ATOM | 52 | NE2 | HIS | 5 | 19.942 | 23.438 | 19.534 | 1.00 | 27.91 | A |
| ATOM | 53 | HE2 | HIS | 5 | 19.995 | 22.491 | 19.233 | 0.00 | 0.00 | A |
| ATOM | 54 | C | HIS | 5 | 20.627 | 27.761 | 19.159 | 1.00 | 28.31 | A |
| ATOM | 55 | O | HIS | 5 | 19.624 | 28.492 | 19.190 | 1.00 | 29.43 | A |
| ATOM | 56 | N | GLY | 6 | 20.993 | 27.075 | 18.076 | 1.00 | 27.58 | A |
| ATOM | 57 | H | GLY | 6 | 21.772 | 26.484 | 18.084 | 0.00 | 0.00 | A |
| ATOM | 58 | CA | GLY | 6 | 20.246 | 27.174 | 16.834 | 1.00 | 25.72 | A |
| ATOM | 59 | C | GLY | 6 | 20.031 | 25.805 | 16.211 | 1.00 | 26.82 | A |
| ATOM | 60 | O | GLY | 6 | 20.782 | 24.860 | 16.478 | 1.00 | 26.71 | A |
| ATOM | 61 | N | PHE | 7 | 18.977 | 25.681 | 15.414 | 1.00 | 26.44 | A |
| ATOM | 62 | H | PHE | 7 | 18.404 | 26.455 | 15.239 | 0.00 | 0.00 | A |
| ATOM | 63 | CA | PHE | 7 | 18.655 | 24.437 | 14.727 | 1.00 | 26.21 | A |
| ATOM | 64 | CB | PHE | 7 | 17.696 | 23.578 | 15.564 | 1.00 | 25.04 | A |
| ATOM | 65 | CG | PHE | 7 | 17.211 | 22.335 | 14.849 | 1.00 | 26.03 | A |
| ATOM | 66 | CD1 | PHE | 7 | 18.014 | 21.210 | 14.756 | 1.00 | 26.42 | A |
| ATOM | 67 | CD2 | PHE | 7 | 15.964 | 22.309 | 14.230 | 1.00 | 27.92 | A |
| ATOM | 68 | CE1 | PHE | 7 | 17.585 | 20.080 | 14.053 | 1.00 | 25.69 | A |
| ATOM | 69 | CE2 | PHE | 7 | 15.528 | 21.184 | 13.525 | 1.00 | 26.33 | A |
| ATOM | 70 | CZ | PHE | 7 | 16.339 | 20.073 | 13.436 | 1.00 | 25.32 | A |
| ATOM | 71 | C | PHE | 7 | 17.994 | 24.814 | 13.409 | 1.00 | 27.17 | A |
| ATOM | 72 | O | PHE | 7 | 17.152 | 25.715 | 13.383 | 1.00 | 29.65 | A |
| ATOM | 73 | N | ASP | 8 | 18.385 | 24.154 | 12.321 | 1.00 | 27.46 | A |
| ATOM | 74 | H | ASP | 8 | 19.081 | 23.466 | 12.377 | 0.00 | 0.00 | A |
| ATOM | 75 | CA | ASP | 8 | 17.794 | 24.429 | 11.013 | 1.00 | 26.30 | A |
| ATOM | 76 | CB | ASP | 8 | 18.580 | 25.521 | 10.289 | 1.00 | 26.02 | A |
| ATOM | 77 | CG | ASP | 8 | 17.821 | 26.107 | 9.106 | 1.00 | 29.20 | A |
| ATOM | 78 | OD1 | ASP | 8 | 18.477 | 26.665 | 8.210 | 1.00 | 30.79 | A |
| ATOM | 79 | OD2 | ASP | 8 | 16.573 | 26.016 | 9.053 | 1.00 | 28.76 | A |
| ATOM | 80 | C | ASP | 8 | 17.727 | 23.160 | 10.153 | 1.00 | 28.12 | A |
| ATOM | 81 | O | ASP | 8 | 18.476 | 22.193 | 10.383 | 1.00 | 28.21 | A |
| ATOM | 82 | N | VAL | 9 | 16.803 | 23.157 | 9.190 | 1.00 | 27.98 | A |
| ATOM | 83 | H | VAL | 9 | 16.246 | 23.963 | 9.099 | 0.00 | 0.00 | A |
| ATOM | 84 | CA | VAL | 9 | 16.589 | 22.035 | 8.272 | 1.00 | 26.18 | A |
| ATOM | 85 | CB | VAL | 9 | 15.421 | 21.108 | 8.750 | 1.00 | 23.97 | A |
| ATOM | 86 | CG1 | VAL | 9 | 15.052 | 20.107 | 7.679 | 1.00 | 21.03 | A |
| ATOM | 87 | CG2 | VAL | 9 | 15.802 | 20.365 | 10.001 | 1.00 | 23.62 | A |
| ATOM | 88 | C | VAL | 9 | 16.210 | 22.579 | 6.892 | 1.00 | 28.29 | A |
| ATOM | 89 | O | VAL | 9 | 15.542 | 23.617 | 6.787 | 1.00 | 29.03 | A |
| ATOM | 90 | N | HIS | 10 | 16.718 | 21.931 | 5.843 | 1.00 | 29.48 | A |
| ATOM | 91 | H | HIS | 10 | 17.323 | 21.170 | 6.005 | 0.00 | 0.00 | A |
| ATOM | 92 | CA | HIS | 10 | 16.397 | 22.277 | 4.451 | 1.00 | 29.70 | A |
| ATOM | 93 | CB | HIS | 10 | 17.402 | 23.251 | 3.829 | 1.00 | 28.20 | A |
| ATOM | 94 | CG | HIS | 10 | 17.204 | 24.661 | 4.289 | 1.00 | 28.51 | A |
| ATOM | 95 | CD2 | HIS | 10 | 17.950 | 25.450 | 5.099 | 1.00 | 28.35 | A |
| ATOM | 96 | ND1 | HIS | 10 | 16.053 | 25.367 | 4.022 | 1.00 | 26.73 | A |
| ATOM | 97 | HD1 | HIS | 10 | 15.275 | 25.035 | 3.499 | 0.00 | 0.00 | A |
| ATOM | 98 | CE1 | HIS | 10 | 16.095 | 26.528 | 4.654 | 1.00 | 28.80 | A |
| ATOM | 99 | NE2 | HIS | 10 | 17.236 | 26.605 | 5.317 | 1.00 | 29.81 | A |
| ATOM | 100 | C | HIS | 10 | 16.266 | 20.991 | 3.657 | 1.00 | 29.38 | A |
| ATOM | 101 | O | HIS | 10 | 16.982 | 20.025 | 3.903 | 1.00 | 31.41 | A |
| ATOM | 102 | N | ALA | 11 | 15.269 | 20.942 | 2.793 | 1.00 | 28.56 | A |
| ATOM | 103 | H | ALA | 11 | 14.682 | 21.714 | 2.678 | 0.00 | 0.00 | A |
| ATOM | 104 | CA | ALA | 11 | 15.010 | 19.763 | 2.005 | 1.00 | 28.78 | A |
| ATOM | 105 | CB | ALA | 11 | 13.534 | 19.680 | 1.712 | 1.00 | 28.47 | A |
| ATOM | 106 | C | ALA | 11 | 15.793 | 19.772 | 0.710 | 1.00 | 30.66 | A |
| ATOM | 107 | O | ALA | 11 | 16.061 | 20.835 | 0.157 | 1.00 | 32.69 | A |
| ATOM | 108 | N | PHE | 12 | 16.176 | 18.587 | 0.236 | 1.00 | 31.94 | A |
| ATOM | 109 | H | PHE | 12 | 15.945 | 17.777 | 0.736 | 0.00 | 0.00 | A |
| ATOM | 110 | CA | PHE | 12 | 16.895 | 18.467 | −1.027 | 1.00 | 30.85 | A |
| ATOM | 111 | CB | PHE | 12 | 17.467 | 17.064 | −1.218 | 1.00 | 28.19 | A |
| ATOM | 112 | CG | PHE | 12 | 18.711 | 16.791 | −0.423 | 1.00 | 26.27 | A |
| ATOM | 113 | CD1 | PHE | 12 | 19.845 | 17.568 | −0.590 | 1.00 | 26.30 | A |
| ATOM | 114 | CD2 | PHE | 12 | 18.747 | 15.751 | 0.492 | 1.00 | 24.96 | A |
| ATOM | 115 | CE1 | PHE | 12 | 20.994 | 17.314 | 0.147 | 1.00 | 26.02 | A |
| ATOM | 116 | CE2 | PHE | 12 | 19.888 | 15.489 | 1.232 | 1.00 | 24.00 | A |
| ATOM | 117 | CZ | PHE | 12 | 21.014 | 16.272 | 1.061 | 1.00 | 25.64 | A |
| ATOM | 118 | C | PHE | 12 | 15.905 | 18.748 | −2.146 | 1.00 | 34.42 | A |
| ATOM | 119 | O | PHE | 12 | 14.701 | 18.473 | −2.027 | 1.00 | 33.62 | A |
| ATOM | 120 | N | GLY | 13 | 16.417 | 19.301 | −3.233 | 1.00 | 38.09 | A |
| ATOM | 121 | H | GLY | 13 | 17.362 | 19.521 | −3.309 | 0.00 | 0.00 | A |
| ATOM | 122 | CA | GLY | 13 | 15.586 | 19.619 | −4.369 | 1.00 | 41.96 | A |
| ATOM | 123 | C | GLY | 13 | 16.460 | 20.198 | −5.457 | 1.00 | 47.40 | A |
| ATOM | 124 | O | GLY | 13 | 17.369 | 20.998 | −5.188 | 1.00 | 48.26 | A |
| ATOM | 125 | N | GLY | 14 | 16.219 | 19.754 | −6.685 | 1.00 | 51.00 | A |
| ATOM | 126 | H | GLY | 14 | 15.534 | 19.072 | −6.822 | 0.00 | 0.00 | A |
| ATOM | 127 | CA | GLY | 14 | 16.981 | 20.244 | −7.819 | 1.00 | 54.43 | A |
| ATOM | 128 | C | GLY | 14 | 18.339 | 19.598 | −7.971 | 1.00 | 55.17 | A |
| ATOM | 129 | O | GLY | 14 | 18.607 | 18.543 | −7.390 | 1.00 | 55.12 | A |
| ATOM | 130 | N | GLU | 15 | 19.189 | 20.240 | −8.762 | 1.00 | 56.65 | A |
| ATOM | 131 | H | GLU | 15 | 18.933 | 21.076 | −9.191 | 0.00 | 0.00 | A |
| ATOM | 132 | CA | GLU | 15 | 20.529 | 19.739 | −9.012 | 1.00 | 59.30 | A |
| ATOM | 133 | CB | GLU | 15 | 20.998 | 20.119 | −10.429 | 1.00 | 66.59 | A |
| ATOM | 134 | CG | GLU | 15 | 20.049 | 19.727 | −11.572 | 1.00 | 75.54 | A |
| ATOM | 135 | CD | GLU | 15 | 19.773 | 18.227 | −11.635 | 1.00 | 82.06 | A |
| ATOM | 136 | OE1 | GLU | 15 | 18.577 | 17.839 | −11.666 | 1.00 | 85.07 | A |
| ATOM | 137 | OE2 | GLU | 15 | 20.750 | 17.441 | −11.655 | 1.00 | 85.89 | A |
| ATOM | 138 | C | GLU | 15 | 21.462 | 20.361 | −7.992 | 1.00 | 56.38 | A |
| ATOM | 139 | O | GLU | 15 | 21.152 | 21.410 | −7.417 | 1.00 | 55.64 | A |
| ATOM | 140 | N | GLY | 16 | 22.595 | 19.703 | −7.764 | 1.00 | 53.51 | A |
| ATOM | 141 | H | GLY | 16 | 22.742 | 18.859 | −8.243 | 0.00 | 0.00 | A |
| ATOM | 142 | CA | GLY | 16 | 23.576 | 20.213 | −6.826 | 1.00 | 48.86 | A |
| ATOM | 143 | C | GLY | 16 | 24.335 | 21.384 | −7.419 | 1.00 | 46.05 | A |
| ATOM | 144 | O | GLY | 16 | 23.995 | 21.854 | −8.505 | 1.00 | 46.93 | A |
| ATOM | 145 | N | CPR | 17 | 25.381 | 21.875 | −6.745 | 1.00 | 41.98 | A |
| ATOM | 146 | CD | CPR | 17 | 26.230 | 22.931 | −7.320 | 1.00 | 38.18 | A |
| ATOM | 147 | CA | CPR | 17 | 25.921 | 21.427 | −5.464 | 1.00 | 40.25 | A |
| ATOM | 148 | CB | CPR | 17 | 27.331 | 22.001 | −5.500 | 1.00 | 39.59 | A |
| ATOM | 149 | CG | CPR | 17 | 27.106 | 23.313 | −6.159 | 1.00 | 37.38 | A |
| ATOM | 150 | C | CPR | 17 | 25.124 | 22.048 | −4.322 | 1.00 | 39.21 | A |
| ATOM | 151 | O | CPR | 17 | 24.114 | 22.727 | −4.549 | 1.00 | 42.64 | A |
| ATOM | 152 | N | ILE | 18 | 25.558 | 21.796 | −3.096 | 1.00 | 35.06 | A |
| ATOM | 153 | H | ILE | 18 | 26.352 | 21.237 | −2.955 | 0.00 | 0.00 | A |
| ATOM | 154 | CA | ILE | 18 | 24.903 | 22.375 | −1.943 | 1.00 | 31.00 | A |
| ATOM | 155 | CB | ILE | 18 | 24.475 | 21.307 | −0.920 | 1.00 | 29.20 | A |
| ATOM | 156 | CG2 | ILE | 18 | 23.503 | 20.336 | −1.544 | 1.00 | 24.80 | A |
| ATOM | 157 | CG1 | ILE | 18 | 25.688 | 20.556 | −0.394 | 1.00 | 27.99 | A |
| ATOM | 158 | CD1 | ILE | 18 | 25.327 | 19.431 | 0.531 | 1.00 | 30.35 | A |
| ATOM | 159 | C | ILE | 18 | 25.952 | 23.282 | −1.334 | 1.00 | 31.49 | A |
| ATOM | 160 | O | ILE | 18 | 27.141 | 23.120 | −1.607 | 1.00 | 31.50 | A |
| ATOM | 161 | N | ILE | 19 | 25.510 | 24.297 | −0.601 | 1.00 | 31.64 | A |
| ATOM | 162 | H | ILE | 19 | 24.551 | 24.419 | −0.477 | 0.00 | 0.00 | A |
| ATOM | 163 | CA | ILE | 19 | 26.423 | 25.221 | 0.062 | 1.00 | 30.03 | A |
| ATOM | 164 | CB | ILE | 19 | 26.064 | 26.692 | −0.211 | 1.00 | 28.04 | A |
| ATOM | 165 | CG2 | ILE | 19 | 27.195 | 27.586 | 0.233 | 1.00 | 25.62 | A |
| ATOM | 166 | CG1 | ILE | 19 | 25.771 | 26.916 | −1.693 | 1.00 | 27.90 | A |
| ATOM | 167 | CD1 | ILE | 19 | 26.928 | 26.664 | −2.606 | 1.00 | 32.79 | A |
| ATOM | 168 | C | ILE | 19 | 26.236 | 24.965 | 1.554 | 1.00 | 30.99 | A |
| ATOM | 169 | O | ILE | 19 | 25.130 | 25.135 | 2.071 | 1.00 | 31.55 | A |
| ATOM | 170 | N | ILE | 20 | 27.284 | 24.485 | 2.224 | 1.00 | 29.49 | A |
| ATOM | 171 | H | ILE | 20 | 28.125 | 24.325 | 1.745 | 0.00 | 0.00 | A |
| ATOM | 172 | CA | ILE | 20 | 27.226 | 24.210 | 3.657 | 1.00 | 27.71 | A |
| ATOM | 173 | CB | ILE | 20 | 27.295 | 22.696 | 3.946 | 1.00 | 28.08 | A |
| ATOM | 174 | CG2 | ILE | 20 | 27.168 | 22.445 | 5.441 | 1.00 | 27.99 | A |
| ATOM | 175 | CG1 | ILE | 20 | 26.155 | 21.954 | 3.241 | 1.00 | 28.59 | A |
| ATOM | 176 | CD1 | ILE | 20 | 24.767 | 22.281 | 3.779 | 1.00 | 27.82 | A |
| ATOM | 177 | C | ILE | 20 | 28.406 | 24.896 | 4.342 | 1.00 | 28.33 | A |
| ATOM | 178 | O | ILE | 20 | 29.559 | 24.647 | 3.996 | 1.00 | 30.80 | A |
| ATOM | 179 | N | GLY | 21 | 28.126 | 25.781 | 5.293 | 1.00 | 27.29 | A |
| ATOM | 180 | H | GLY | 21 | 27.196 | 25.996 | 5.487 | 0.00 | 0.00 | A |
| ATOM | 181 | CA | GLY | 21 | 29.200 | 26.468 | 5.982 | 1.00 | 24.90 | A |
| ATOM | 182 | C | GLY | 21 | 29.965 | 27.309 | 4.991 | 1.00 | 26.52 | A |
| ATOM | 183 | O | GLY | 21 | 31.171 | 27.497 | 5.119 | 1.00 | 27.51 | A |
| ATOM | 184 | N | GLY | 22 | 29.260 | 27.766 | 3.961 | 1.00 | 28.13 | A |
| ATOM | 185 | H | GLY | 22 | 28.316 | 27.533 | 3.902 | 0.00 | 0.00 | A |
| ATOM | 186 | CA | GLY | 22 | 29.860 | 28.600 | 2.933 | 1.00 | 28.76 | A |
| ATOM | 187 | C | GLY | 22 | 30.574 | 27.862 | 1.818 | 1.00 | 30.76 | A |
| ATOM | 188 | O | GLY | 22 | 30.915 | 28.475 | 0.803 | 1.00 | 31.99 | A |
| ATOM | 189 | N | VAL | 23 | 30.783 | 26.556 | 1.981 | 1.00 | 30.76 | A |
| ATOM | 190 | H | VAL | 23 | 30.458 | 26.110 | 2.794 | 0.00 | 0.00 | A |
| ATOM | 191 | CA | VAL | 23 | 31.482 | 25.745 | 0.982 | 1.00 | 30.13 | A |
| ATOM | 192 | CB | VAL | 23 | 32.328 | 24.633 | 1.665 | 1.00 | 28.58 | A |
| ATOM | 193 | CG1 | VAL | 23 | 33.072 | 23.791 | 0.636 | 1.00 | 26.24 | A |
| ATOM | 194 | CG2 | VAL | 23 | 33.307 | 25.249 | 2.628 | 1.00 | 28.33 | A |
| ATOM | 195 | C | VAL | 23 | 30.542 | 25.099 | −0.037 | 1.00 | 32.52 | A |
| ATOM | 196 | O | VAL | 23 | 29.489 | 24.559 | 0.324 | 1.00 | 35.28 | A |
| ATOM | 197 | N | ARG | 24 | 30.905 | 25.204 | −1.312 | 1.00 | 32.27 | A |
| ATOM | 198 | H | ARG | 24 | 31.697 | 25.706 | −1.525 | 0.00 | 0.00 | A |
| ATOM | 199 | CA | ARG | 24 | 30.133 | 24.611 | −2.394 | 1.00 | 32.99 | A |
| ATOM | 200 | CB | ARG | 24 | 30.454 | 25.320 | −3.716 | 1.00 | 34.44 | A |
| ATOM | 201 | CG | ARG | 24 | 29.969 | 24.576 | −4.950 | 1.00 | 43.97 | A |
| ATOM | 202 | CD | ARG | 24 | 30.272 | 25.306 | −6.266 | 1.00 | 49.15 | A |
| ATOM | 203 | NE | ARG | 24 | 29.186 | 26.213 | −6.620 | 1.00 | 56.66 | A |
| ATOM | 204 | HE | ARG | 24 | 29.027 | 26.942 | −5.965 | 0.00 | 0.00 | A |
| ATOM | 205 | CZ | ARG | 24 | 28.450 | 26.118 | −7.725 | 1.00 | 59.52 | A |
| ATOM | 206 | NH1 | ARG | 24 | 27.473 | 26.989 | −7.944 | 1.00 | 62.24 | A |
| ATOM | 207 | HH11 | ARG | 24 | 27.301 | 27.710 | −7.262 | 0.00 | 0.00 | A |
| ATOM | 208 | HH12 | ARG | 24 | 26.880 | 26.965 | −8.749 | 0.00 | 0.00 | A |
| ATOM | 209 | NH2 | ARG | 24 | 28.703 | 25.175 | −8.625 | 1.00 | 62.44 | A |
| ATOM | 210 | HH21 | ARG | 24 | 29.465 | 24.536 | −8.477 | 0.00 | 0.00 | A |
| ATOM | 211 | HH22 | ARG | 24 | 28.196 | 25.039 | −9.475 | 0.00 | 0.00 | A |
| ATOM | 212 | C | ARG | 24 | 30.543 | 23.138 | −2.420 | 1.00 | 31.90 | A |
| ATOM | 213 | O | ARG | 24 | 31.680 | 22.808 | −2.735 | 1.00 | 35.52 | A |
| ATOM | 214 | N | ILE | 25 | 29.646 | 22.265 | −2.001 | 1.00 | 30.22 | A |
| ATOM | 215 | H | ILE | 25 | 28.794 | 22.583 | −1.686 | 0.00 | 0.00 | A |
| ATOM | 216 | CA | ILE | 25 | 29.928 | 20.842 | −1.940 | 1.00 | 27.76 | A |
| ATOM | 217 | CB | ILE | 25 | 29.494 | 20.290 | −0.580 | 1.00 | 25.24 | A |
| ATOM | 218 | CG2 | ILE | 25 | 29.629 | 18.791 | −0.553 | 1.00 | 24.77 | A |
| ATOM | 219 | CG1 | ILE | 25 | 30.311 | 20.949 | 0.529 | 1.00 | 23.49 | A |
| ATOM | 220 | CD1 | ILE | 25 | 29.856 | 20.596 | 1.911 | 1.00 | 20.35 | A |
| ATOM | 221 | C | ILE | 25 | 29.209 | 20.079 | −3.042 | 1.00 | 29.39 | A |
| ATOM | 222 | O | ILE | 25 | 27.995 | 20.165 | −3.172 | 1.00 | 31.21 | A |
| ATOM | 223 | N | PRO | 26 | 29.947 | 19.314 | −3.855 | 1.00 | 29.44 | A |
| ATOM | 224 | CD | PRO | 26 | 31.402 | 19.076 | −3.879 | 1.00 | 29.27 | A |
| ATOM | 225 | CA | PRO | 26 | 29.283 | 18.569 | −4.922 | 1.00 | 28.82 | A |
| ATOM | 226 | CB | PRO | 26 | 30.462 | 17.949 | −5.676 | 1.00 | 27.61 | A |
| ATOM | 227 | CG | PRO | 26 | 31.492 | 17.768 | −4.613 | 1.00 | 26.77 | A |
| ATOM | 228 | C | PRO | 26 | 28.320 | 17.506 | −4.387 | 1.00 | 30.28 | A |
| ATOM | 229 | O | PRO | 26 | 28.654 | 16.764 | −3.452 | 1.00 | 30.06 | A |
| ATOM | 230 | N | TYR | 27 | 27.131 | 17.443 | −4.985 | 1.00 | 31.36 | A |
| ATOM | 231 | H | TYR | 27 | 26.895 | 18.049 | −5.716 | 0.00 | 0.00 | A |
| ATOM | 232 | CA | TYR | 27 | 26.109 | 16.475 | −4.599 | 1.00 | 33.90 | A |
| ATOM | 233 | CB | TYR | 27 | 25.397 | 16.926 | −3.325 | 1.00 | 32.99 | A |
| ATOM | 234 | CG | TYR | 27 | 24.571 | 15.844 | −2.675 | 1.00 | 33.62 | A |
| ATOM | 235 | CD1 | TYR | 27 | 25.134 | 14.609 | −2.362 | 1.00 | 31.53 | A |
| ATOM | 236 | CE1 | TYR | 27 | 24.380 | 13.612 | −1.753 | 1.00 | 33.64 | A |
| ATOM | 237 | CD2 | TYR | 27 | 23.227 | 16.057 | −2.363 | 1.00 | 34.10 | A |
| ATOM | 238 | CE2 | TYR | 27 | 22.466 | 15.066 | −1.756 | 1.00 | 33.94 | A |
| ATOM | 239 | CZ | TYR | 27 | 23.047 | 13.847 | −1.455 | 1.00 | 33.03 | A |
| ATOM | 240 | OH | TYR | 27 | 22.289 | 12.858 | −0.869 | 1.00 | 35.70 | A |
| ATOM | 241 | HH | TYR | 27 | 22.815 | 12.037 | −0.905 | 0.00 | 0.00 | A |
| ATOM | 242 | C | TYR | 27 | 25.080 | 16.300 | −5.715 | 1.00 | 36.08 | A |
| ATOM | 243 | O | TYR | 27 | 24.841 | 17.222 | −6.496 | 1.00 | 35.64 | A |
| ATOM | 244 | N | GLU | 28 | 24.466 | 15.120 | −5.773 | 1.00 | 39.68 | A |
| ATOM | 245 | H | GLU | 28 | 24.709 | 14.446 | −5.110 | 0.00 | 0.00 | A |
| ATOM | 246 | CA | GLU | 28 | 23.457 | 14.817 | −6.792 | 1.00 | 43.54 | A |
| ATOM | 247 | CB | GLU | 28 | 22.796 | 13.466 | −6.530 | 1.00 | 48.67 | A |
| ATOM | 248 | CG | GLU | 28 | 23.613 | 12.452 | −5.734 | 1.00 | 59.51 | A |
| ATOM | 249 | CD | GLU | 28 | 22.725 | 11.415 | −5.030 | 1.00 | 64.56 | A |
| ATOM | 250 | OE1 | GLU | 28 | 23.244 | 10.673 | −4.165 | 1.00 | 68.33 | A |
| ATOM | 251 | OE2 | GLU | 28 | 21.502 | 11.363 | −5.311 | 1.00 | 67.63 | A |
| ATOM | 252 | C | GLU | 28 | 22.355 | 15.864 | −6.764 | 1.00 | 42.81 | A |
| ATOM | 253 | O | GLU | 28 | 22.010 | 16.456 | −7.781 | 1.00 | 44.92 | A |
| ATOM | 254 | N | LYS | 29 | 21.808 | 16.074 | −5.576 | 1.00 | 41.78 | A |
| ATOM | 255 | H | LYS | 29 | 22.182 | 15.602 | −4.812 | 0.00 | 0.00 | A |
| ATOM | 256 | CA | LYS | 29 | 20.728 | 17.019 | −5.380 | 1.00 | 40.44 | A |
| ATOM | 257 | CB | LYS | 29 | 19.562 | 16.344 | −4.623 | 1.00 | 42.02 | A |
| ATOM | 258 | CG | LYS | 29 | 19.918 | 15.045 | −3.848 | 1.00 | 43.63 | A |
| ATOM | 259 | CD | LYS | 29 | 18.654 | 14.302 | −3.366 | 1.00 | 44.92 | A |
| ATOM | 260 | CE | LYS | 29 | 18.937 | 12.905 | −2.776 | 1.00 | 45.07 | A |
| ATOM | 261 | NZ | LYS | 29 | 19.609 | 12.859 | −1.433 | 1.00 | 43.53 | A |
| ATOM | 262 | HZ1 | LYS | 29 | 19.010 | 13.300 | −0.700 | 0.00 | 0.00 | A |
| ATOM | 263 | HZ2 | LYS | 29 | 20.566 | 13.276 | −1.435 | 0.00 | 0.00 | A |
| ATOM | 264 | HZ3 | LYS | 29 | 19.741 | 11.864 | −1.181 | 0.00 | 0.00 | A |
| ATOM | 265 | C | LYS | 29 | 21.195 | 18.278 | −4.662 | 1.00 | 38.70 | A |
| ATOM | 266 | O | LYS | 29 | 22.275 | 18.304 | −4.070 | 1.00 | 38.52 | A |
| ATOM | 267 | N | GLY | 30 | 20.403 | 19.336 | −4.781 | 1.00 | 36.86 | A |
| ATOM | 268 | H | GLY | 30 | 19.591 | 19.275 | −5.325 | 0.00 | 0.00 | A |
| ATOM | 269 | CA | GLY | 30 | 20.715 | 20.587 | −4.121 | 1.00 | 36.05 | A |
| ATOM | 270 | C | GLY | 30 | 19.758 | 20.776 | −2.959 | 1.00 | 36.31 | A |
| ATOM | 271 | O | GLY | 30 | 18.996 | 19.859 | −2.634 | 1.00 | 36.03 | A |
| ATOM | 272 | N | LEU | 31 | 19.798 | 21.945 | −2.323 | 1.00 | 35.97 | A |
| ATOM | 273 | H | LEU | 31 | 20.400 | 22.650 | −2.637 | 0.00 | 0.00 | A |
| ATOM | 274 | CA | LEU | 31 | 18.914 | 22.240 | −1.193 | 1.00 | 34.62 | A |
| ATOM | 275 | CB | LEU | 31 | 19.724 | 22.648 | 0.035 | 1.00 | 29.44 | A |
| ATOM | 276 | CG | LEU | 31 | 20.483 | 21.537 | 0.742 | 1.00 | 26.01 | A |
| ATOM | 277 | CD1 | LEU | 31 | 21.379 | 22.131 | 1.805 | 1.00 | 29.50 | A |
| ATOM | 278 | CD2 | LEU | 31 | 19.509 | 20.576 | 1.356 | 1.00 | 23.88 | A |
| ATOM | 279 | C | LEU | 31 | 17.926 | 23.348 | −1.528 | 1.00 | 35.56 | A |
| ATOM | 280 | O | LEU | 31 | 18.297 | 24.361 | −2.110 | 1.00 | 36.85 | A |
| ATOM | 281 | N | LEU | 32 | 16.669 | 23.148 | −1.159 | 1.00 | 37.12 | A |
| ATOM | 282 | H | LEU | 32 | 16.442 | 22.325 | −0.710 | 0.00 | 0.00 | A |
| ATOM | 283 | CA | LEU | 32 | 15.618 | 24.132 | −1.396 | 1.00 | 39.24 | A |
| ATOM | 284 | CB | LEU | 32 | 14.277 | 23.414 | −1.482 | 1.00 | 37.00 | A |
| ATOM | 285 | CG | LEU | 32 | 14.127 | 22.336 | −2.552 | 1.00 | 38.26 | A |
| ATOM | 286 | CD1 | LEU | 32 | 12.832 | 21.589 | −2.322 | 1.00 | 37.26 | A |
| ATOM | 287 | CD2 | LEU | 32 | 14.148 | 22.958 | −3.944 | 1.00 | 36.58 | A |
| ATOM | 288 | C | LEU | 32 | 15.554 | 25.170 | −0.260 | 1.00 | 42.63 | A |
| ATOM | 289 | O | LEU | 32 | 15.531 | 24.800 | 0.923 | 1.00 | 45.83 | A |
| ATOM | 290 | N | ALA | 33 | 15.521 | 26.458 | −0.602 | 1.00 | 44.75 | A |
| ATOM | 291 | H | ALA | 33 | 15.591 | 26.743 | −1.540 | 0.00 | 0.00 | A |
| ATOM | 292 | CA | ALA | 33 | 15.425 | 27.526 | 0.402 | 1.00 | 47.26 | A |
| ATOM | 293 | CB | ALA | 33 | 16.647 | 27.514 | 1.311 | 1.00 | 45.99 | A |
| ATOM | 294 | C | ALA | 33 | 15.277 | 28.897 | −0.256 | 1.00 | 49.59 | A |
| ATOM | 295 | O | ALA | 33 | 15.514 | 29.031 | −1.460 | 1.00 | 53.59 | A |
| ATOM | 296 | N | HIS | 34 | 14.857 | 29.899 | 0.524 | 1.00 | 50.40 | A |
| ATOM | 297 | H | HIS | 34 | 14.609 | 29.689 | 1.449 | 0.00 | 0.00 | A |
| ATOM | 298 | CA | HIS | 34 | 14.707 | 31.276 | 0.030 | 1.00 | 49.48 | A |
| ATOM | 299 | CB | HIS | 34 | 14.095 | 32.172 | 1.118 | 1.00 | 52.23 | A |
| ATOM | 300 | CG | HIS | 34 | 13.797 | 33.574 | 0.669 | 1.00 | 55.73 | A |
| ATOM | 301 | CD2 | HIS | 34 | 14.028 | 34.768 | 1.269 | 1.00 | 55.33 | A |
| ATOM | 302 | ND1 | HIS | 34 | 13.144 | 33.862 | −0.512 | 1.00 | 56.32 | A |
| ATOM | 303 | HD1 | HIS | 34 | 12.807 | 33.202 | −1.155 | 0.00 | 0.00 | A |
| ATOM | 304 | CE1 | HIS | 34 | 12.983 | 35.170 | −0.617 | 1.00 | 55.92 | A |
| ATOM | 305 | NE2 | HIS | 34 | 13.510 | 35.742 | 0.450 | 1.00 | 55.37 | A |
| ATOM | 306 | HE2 | HIS | 34 | 13.455 | 36.698 | 0.689 | 0.00 | 0.00 | A |
| ATOM | 307 | C | HIS | 34 | 16.084 | 31.825 | −0.375 | 1.00 | 48.04 | A |
| ATOM | 308 | O | HIS | 34 | 16.233 | 32.417 | −1.447 | 1.00 | 47.66 | A |
| ATOM | 309 | N | SER | 35 | 17.064 | 31.655 | 0.513 | 1.00 | 45.72 | A |
| ATOM | 310 | H | SER | 35 | 16.861 | 31.192 | 1.328 | 0.00 | 0.00 | A |
| ATOM | 311 | CA | SER | 35 | 18.443 | 32.088 | 0.302 | 1.00 | 42.28 | A |
| ATOM | 312 | CB | SER | 35 | 19.103 | 32.385 | 1.655 | 1.00 | 41.47 | A |
| ATOM | 313 | OG | SER | 35 | 19.299 | 31.196 | 2.417 | 1.00 | 40.82 | A |
| ATOM | 314 | HG | SER | 35 | 20.253 | 31.032 | 2.279 | 0.00 | 0.00 | A |
| ATOM | 315 | C | SER | 35 | 19.143 | 30.911 | −0.366 | 1.00 | 41.34 | A |
| ATOM | 316 | O | SER | 35 | 18.487 | 30.084 | −0.996 | 1.00 | 41.92 | A |
| ATOM | 317 | N | ASP | 36 | 20.459 | 30.812 | −0.207 | 1.00 | 40.50 | A |
| ATOM | 318 | H | ASP | 36 | 20.985 | 31.498 | 0.266 | 0.00 | 0.00 | A |
| ATOM | 319 | CA | ASP | 36 | 21.219 | 29.698 | −0.777 | 1.00 | 39.44 | A |
| ATOM | 320 | CB | ASP | 36 | 22.716 | 30.014 | −0.792 | 1.00 | 37.49 | A |
| ATOM | 321 | CG | ASP | 36 | 23.253 | 30.347 | 0.576 | 1.00 | 37.91 | A |
| ATOM | 322 | OD1 | ASP | 36 | 24.428 | 30.743 | 0.667 | 1.00 | 37.37 | A |
| ATOM | 323 | OD2 | ASP | 36 | 22.500 | 30.237 | 1.569 | 1.00 | 39.99 | A |
| ATOM | 324 | C | ASP | 36 | 20.963 | 28.393 | −0.004 | 1.00 | 39.66 | A |
| ATOM | 325 | O | ASP | 36 | 21.522 | 27.346 | −0.342 | 1.00 | 40.47 | A |
| ATOM | 326 | N | GLY | 37 | 20.167 | 28.484 | 1.066 | 1.00 | 38.52 | A |
| ATOM | 327 | H | GLY | 37 | 19.842 | 29.366 | 1.310 | 0.00 | 0.00 | A |
| ATOM | 328 | CA | GLY | 37 | 19.814 | 27.318 | 1.858 | 1.00 | 33.83 | A |
| ATOM | 329 | C | GLY | 37 | 20.889 | 26.709 | 2.729 | 1.00 | 32.50 | A |
| ATOM | 330 | O | GLY | 37 | 20.755 | 25.565 | 3.165 | 1.00 | 33.84 | A |
| ATOM | 331 | N | ASP | 38 | 21.924 | 27.476 | 3.039 | 1.00 | 29.56 | A |
| ATOM | 332 | H | ASP | 38 | 22.009 | 28.376 | 2.654 | 0.00 | 0.00 | A |
| ATOM | 333 | CA | ASP | 38 | 23.012 | 26.987 | 3.871 | 1.00 | 28.09 | A |
| ATOM | 334 | CB | ASP | 38 | 24.115 | 28.032 | 3.906 | 1.00 | 25.91 | A |
| ATOM | 335 | CG | ASP | 38 | 25.415 | 27.486 | 4.404 | 1.00 | 27.62 | A |
| ATOM | 336 | OD1 | ASP | 38 | 25.413 | 26.678 | 5.354 | 1.00 | 30.71 | A |
| ATOM | 337 | OD2 | ASP | 38 | 26.459 | 27.889 | 3.860 | 1.00 | 28.67 | A |
| ATOM | 338 | C | ASP | 38 | 22.524 | 26.660 | 5.286 | 1.00 | 29.07 | A |
| ATOM | 339 | O | ASP | 38 | 22.465 | 27.532 | 6.156 | 1.00 | 31.45 | A |
| ATOM | 340 | N | VAL | 39 | 22.178 | 25.399 | 5.517 | 1.00 | 29.41 | A |
| ATOM | 341 | H | VAL | 39 | 22.300 | 24.797 | 4.752 | 0.00 | 0.00 | A |
| ATOM | 342 | CA | VAL | 39 | 21.664 | 24.952 | 6.813 | 1.00 | 28.18 | A |
| ATOM | 343 | CB | VAL | 39 | 21.356 | 23.441 | 6.830 | 1.00 | 28.03 | A |
| ATOM | 344 | CG1 | VAL | 39 | 20.262 | 23.154 | 7.820 | 1.00 | 26.99 | A |
| ATOM | 345 | CG2 | VAL | 39 | 20.972 | 22.955 | 5.476 | 1.00 | 31.58 | A |
| ATOM | 346 | C | VAL | 39 | 22.610 | 25.206 | 7.979 | 1.00 | 28.87 | A |
| ATOM | 347 | O | VAL | 39 | 22.158 | 25.495 | 9.085 | 1.00 | 29.58 | A |
| ATOM | 348 | N | ALA | 40 | 23.913 | 25.069 | 7.743 | 1.00 | 27.43 | A |
| ATOM | 349 | H | ALA | 40 | 24.207 | 24.891 | 6.824 | 0.00 | 0.00 | A |
| ATOM | 350 | CA | ALA | 40 | 24.906 | 25.255 | 8.793 | 1.00 | 26.33 | A |
| ATOM | 351 | CB | ALA | 40 | 26.258 | 24.740 | 8.338 | 1.00 | 27.11 | A |
| ATOM | 352 | C | ALA | 40 | 25.033 | 26.696 | 9.256 | 1.00 | 27.55 | A |
| ATOM | 353 | O | ALA | 40 | 25.112 | 26.964 | 10.452 | 1.00 | 30.12 | A |
| ATOM | 354 | N | LEU | 41 | 25.073 | 27.631 | 8.315 | 1.00 | 28.00 | A |
| ATOM | 355 | H | LEU | 41 | 25.012 | 27.380 | 7.363 | 0.00 | 0.00 | A |
| ATOM | 356 | CA | LEU | 41 | 25.204 | 29.028 | 8.686 | 1.00 | 25.15 | A |
| ATOM | 357 | CB | LEU | 41 | 25.715 | 29.863 | 7.519 | 1.00 | 24.20 | A |
| ATOM | 358 | CG | LEU | 41 | 27.127 | 29.499 | 7.041 | 1.00 | 21.87 | A |
| ATOM | 359 | CD1 | LEU | 41 | 27.556 | 30.512 | 6.014 | 1.00 | 22.20 | A |
| ATOM | 360 | CD2 | LEU | 41 | 28.120 | 29.468 | 8.181 | 1.00 | 18.94 | A |
| ATOM | 361 | C | LEU | 41 | 23.923 | 29.596 | 9.281 | 1.00 | 26.22 | A |
| ATOM | 362 | O | LEU | 41 | 23.986 | 30.470 | 10.148 | 1.00 | 27.34 | A |
| ATOM | 363 | N | HIS | 42 | 22.768 | 29.084 | 8.856 | 1.00 | 25.42 | A |
| ATOM | 364 | H | HIS | 42 | 22.808 | 28.399 | 8.155 | 0.00 | 0.00 | A |
| ATOM | 365 | CA | HIS | 42 | 21.496 | 29.538 | 9.423 | 1.00 | 25.30 | A |
| ATOM | 366 | CB | HIS | 42 | 20.303 | 28.915 | 8.715 | 1.00 | 23.59 | A |
| ATOM | 367 | CG | HIS | 42 | 20.087 | 29.418 | 7.323 | 1.00 | 23.47 | A |
| ATOM | 368 | CD2 | HIS | 42 | 20.777 | 30.321 | 6.586 | 1.00 | 23.78 | A |
| ATOM | 369 | ND1 | HIS | 42 | 19.052 | 28.975 | 6.524 | 1.00 | 25.59 | A |
| ATOM | 370 | CE1 | HIS | 42 | 19.121 | 29.586 | 5.352 | 1.00 | 24.57 | A |
| ATOM | 371 | NE2 | HIS | 42 | 20.156 | 30.407 | 5.365 | 1.00 | 21.77 | A |
| ATOM | 372 | HE2 | HIS | 42 | 20.494 | 31.003 | 4.641 | 0.00 | 0.00 | A |
| ATOM | 373 | C | HIS | 42 | 21.460 | 29.116 | 10.886 | 1.00 | 26.73 | A |
| ATOM | 374 | O | HIS | 42 | 21.210 | 29.929 | 11.767 | 1.00 | 29.62 | A |
| ATOM | 375 | N | ALA | 43 | 21.743 | 27.846 | 11.149 | 1.00 | 26.96 | A |
| ATOM | 376 | H | ALA | 43 | 21.940 | 27.211 | 10.427 | 0.00 | 0.00 | A |
| ATOM | 377 | CA | ALA | 43 | 21.750 | 27.352 | 12.516 | 1.00 | 25.91 | A |
| ATOM | 378 | CB | ALA | 43 | 22.094 | 25.895 | 12.540 | 1.00 | 22.86 | A |
| ATOM | 379 | C | ALA | 43 | 22.755 | 28.159 | 13.336 | 1.00 | 27.38 | A |
| ATOM | 380 | O | ALA | 43 | 22.438 | 28.619 | 14.436 | 1.00 | 29.77 | A |
| ATOM | 381 | N | LEU | 44 | 23.944 | 28.382 | 12.784 | 1.00 | 26.03 | A |
| ATOM | 382 | H | LEU | 44 | 24.154 | 27.999 | 11.906 | 0.00 | 0.00 | A |
| ATOM | 383 | CA | LEU | 44 | 24.959 | 29.159 | 13.486 | 1.00 | 26.04 | A |
| ATOM | 384 | CB | LEU | 44 | 26.246 | 29.229 | 12.665 | 1.00 | 22.73 | A |
| ATOM | 385 | CG | LEU | 44 | 27.363 | 30.088 | 13.268 | 1.00 | 21.49 | A |
| ATOM | 386 | CD1 | LEU | 44 | 27.660 | 29.649 | 14.686 | 1.00 | 20.77 | A |
| ATOM | 387 | CD2 | LEU | 44 | 28.609 | 29.987 | 12.421 | 1.00 | 19.56 | A |
| ATOM | 388 | C | LEU | 44 | 24.456 | 30.571 | 13.794 | 1.00 | 28.03 | A |
| ATOM | 389 | O | LEU | 44 | 24.657 | 31.089 | 14.891 | 1.00 | 29.75 | A |
| ATOM | 390 | N | THR | 45 | 23.795 | 31.189 | 12.825 | 1.00 | 30.23 | A |
| ATOM | 391 | H | THR | 45 | 23.647 | 30.748 | 11.967 | 0.00 | 0.00 | A |
| ATOM | 392 | CA | THR | 45 | 23.258 | 32.533 | 12.993 | 1.00 | 30.10 | A |
| ATOM | 393 | CB | THR | 45 | 22.616 | 33.023 | 11.680 | 1.00 | 30.18 | A |
| ATOM | 394 | OG1 | THR | 45 | 23.557 | 32.858 | 10.610 | 1.00 | 29.12 | A |
| ATOM | 395 | HG1 | THR | 45 | 24.395 | 33.235 | 10.880 | 0.00 | 0.00 | A |
| ATOM | 396 | CG2 | THR | 45 | 22.218 | 34.497 | 11.783 | 1.00 | 29.79 | A |
| ATOM | 397 | C | THR | 45 | 22.241 | 32.596 | 14.140 | 1.00 | 30.61 | A |
| ATOM | 398 | O | THR | 45 | 22.292 | 33.507 | 14.969 | 1.00 | 32.51 | A |
| ATOM | 399 | N | ASP | 46 | 21.332 | 31.631 | 14.202 | 1.00 | 28.53 | A |
| ATOM | 400 | H | ASP | 46 | 21.299 | 30.931 | 13.514 | 0.00 | 0.00 | A |
| ATOM | 401 | CA | ASP | 46 | 20.340 | 31.599 | 15.264 | 1.00 | 27.70 | A |
| ATOM | 402 | CB | ASP | 46 | 19.374 | 30.437 | 15.056 | 1.00 | 31.90 | A |
| ATOM | 403 | CG | ASP | 46 | 18.164 | 30.824 | 14.247 | 1.00 | 33.90 | A |
| ATOM | 404 | OD1 | ASP | 46 | 17.313 | 29.942 | 13.982 | 1.00 | 34.98 | A |
| ATOM | 405 | OD2 | ASP | 46 | 18.050 | 32.010 | 13.888 | 1.00 | 32.31 | A |
| ATOM | 406 | C | ASP | 46 | 20.989 | 31.449 | 16.628 | 1.00 | 27.67 | A |
| ATOM | 407 | O | ASP | 46 | 20.486 | 31.966 | 17.619 | 1.00 | 28.04 | A |
| ATOM | 408 | N | ALA | 47 | 22.076 | 30.690 | 16.686 | 1.00 | 27.06 | A |
| ATOM | 409 | H | ALA | 47 | 22.389 | 30.265 | 15.858 | 0.00 | 0.00 | A |
| ATOM | 410 | CA | ALA | 47 | 22.782 | 30.472 | 17.940 | 1.00 | 27.96 | A |
| ATOM | 411 | CB | ALA | 47 | 23.892 | 29.466 | 17.751 | 1.00 | 28.03 | A |
| ATOM | 412 | C | ALA | 47 | 23.349 | 31.779 | 18.461 | 1.00 | 29.48 | A |
| ATOM | 413 | O | ALA | 47 | 23.220 | 32.092 | 19.648 | 1.00 | 29.95 | A |
| ATOM | 414 | N | LEU | 48 | 23.995 | 32.526 | 17.569 | 1.00 | 29.29 | A |
| ATOM | 415 | H | LEU | 48 | 24.078 | 32.185 | 16.651 | 0.00 | 0.00 | A |
| ATOM | 416 | CA | LEU | 48 | 24.590 | 33.815 | 17.907 | 1.00 | 27.88 | A |
| ATOM | 417 | CB | LEU | 48 | 25.437 | 34.313 | 16.740 | 1.00 | 26.78 | A |
| ATOM | 418 | CG | LEU | 48 | 26.695 | 33.509 | 16.409 | 1.00 | 24.39 | A |
| ATOM | 419 | CD1 | LEU | 48 | 27.110 | 33.769 | 14.975 | 1.00 | 23.93 | A |
| ATOM | 420 | CD2 | LEU | 48 | 27.809 | 33.871 | 17.375 | 1.00 | 23.36 | A |
| ATOM | 421 | C | LEU | 48 | 23.518 | 34.846 | 18.268 | 1.00 | 28.23 | A |
| ATOM | 422 | O | LEU | 48 | 23.640 | 35.541 | 19.272 | 1.00 | 29.88 | A |
| ATOM | 423 | N | LEU | 49 | 22.464 | 34.938 | 17.459 | 1.00 | 28.64 | A |
| ATOM | 424 | H | LEU | 49 | 22.419 | 34.364 | 16.668 | 0.00 | 0.00 | A |
| ATOM | 425 | CA | LEU | 49 | 21.369 | 35.875 | 17.723 | 1.00 | 28.80 | A |
| ATOM | 426 | CB | LEU | 49 | 20.330 | 35.847 | 16.598 | 1.00 | 26.37 | A |
| ATOM | 427 | CG | LEU | 49 | 20.770 | 36.482 | 15.281 | 1.00 | 26.75 | A |
| ATOM | 428 | CD1 | LEU | 49 | 19.720 | 36.320 | 14.187 | 1.00 | 24.67 | A |
| ATOM | 429 | CD2 | LEU | 49 | 21.070 | 37.934 | 15.533 | 1.00 | 25.61 | A |
| ATOM | 430 | C | LEU | 49 | 20.697 | 35.499 | 19.031 | 1.00 | 30.26 | A |
| ATOM | 431 | O | LEU | 49 | 20.340 | 36.361 | 19.822 | 1.00 | 32.05 | A |
| ATOM | 432 | N | GLY | 50 | 20.525 | 34.203 | 19.253 | 1.00 | 31.75 | A |
| ATOM | 433 | H | GLY | 50 | 20.799 | 33.555 | 18.576 | 0.00 | 0.00 | A |
| ATOM | 434 | CA | GLY | 50 | 19.911 | 33.736 | 20.480 | 1.00 | 32.95 | A |
| ATOM | 435 | C | GLY | 50 | 20.707 | 34.137 | 21.711 | 1.00 | 33.57 | A |
| ATOM | 436 | O | GLY | 50 | 20.143 | 34.610 | 22.699 | 1.00 | 35.64 | A |
| ATOM | 437 | N | ALA | 51 | 22.021 | 33.949 | 21.655 | 1.00 | 33.58 | A |
| ATOM | 438 | H | ALA | 51 | 22.408 | 33.529 | 20.857 | 0.00 | 0.00 | A |
| ATOM | 439 | CA | ALA | 51 | 22.894 | 34.303 | 22.761 | 1.00 | 32.57 | A |
| ATOM | 440 | CB | ALA | 51 | 24.306 | 33.862 | 22.472 | 1.00 | 32.82 | A |
| ATOM | 441 | C | ALA | 51 | 22.850 | 35.806 | 23.007 | 1.00 | 32.83 | A |
| ATOM | 442 | O | ALA | 51 | 23.048 | 36.263 | 24.126 | 1.00 | 32.71 | A |
| ATOM | 443 | N | ALA | 52 | 22.591 | 36.572 | 21.955 | 1.00 | 32.22 | A |
| ATOM | 444 | H | ALA | 52 | 22.478 | 36.153 | 21.076 | 0.00 | 0.00 | A |
| ATOM | 445 | CA | ALA | 52 | 22.514 | 38.021 | 22.065 | 1.00 | 32.89 | A |
| ATOM | 446 | CB | ALA | 52 | 22.976 | 38.655 | 20.753 | 1.00 | 29.72 | A |
| ATOM | 447 | C | ALA | 52 | 21.091 | 38.499 | 22.411 | 1.00 | 33.63 | A |
| ATOM | 448 | O | ALA | 52 | 20.858 | 39.688 | 22.637 | 1.00 | 36.57 | A |
| ATOM | 449 | N | ALA | 53 | 20.151 | 37.567 | 22.485 | 1.00 | 33.18 | A |
| ATOM | 450 | H | ALA | 53 | 20.388 | 36.626 | 22.356 | 0.00 | 0.00 | A |
| ATOM | 451 | CA | ALA | 53 | 18.750 | 37.886 | 22.746 | 1.00 | 31.14 | A |
| ATOM | 452 | CB | ALA | 53 | 18.570 | 38.508 | 24.116 | 1.00 | 28.74 | A |
| ATOM | 453 | C | ALA | 53 | 18.243 | 38.820 | 21.647 | 1.00 | 31.82 | A |
| ATOM | 454 | O | ALA | 53 | 17.561 | 39.805 | 21.920 | 1.00 | 33.15 | A |
| ATOM | 455 | N | LEU | 54 | 18.623 | 38.527 | 20.405 | 1.00 | 31.26 | A |
| ATOM | 456 | H | LEU | 54 | 19.204 | 37.758 | 20.269 | 0.00 | 0.00 | A |
| ATOM | 457 | CA | LEU | 54 | 18.189 | 39.314 | 19.256 | 1.00 | 30.81 | A |
| ATOM | 458 | CB | LEU | 54 | 19.371 | 39.732 | 18.382 | 1.00 | 29.95 | A |
| ATOM | 459 | CG | LEU | 54 | 20.328 | 40.757 | 18.999 | 1.00 | 31.24 | A |
| ATOM | 460 | CD1 | LEU | 54 | 21.412 | 41.134 | 18.018 | 1.00 | 29.58 | A |
| ATOM | 461 | CD2 | LEU | 54 | 19.559 | 41.983 | 19.391 | 1.00 | 30.27 | A |
| ATOM | 462 | C | LEU | 54 | 17.133 | 38.584 | 18.424 | 1.00 | 31.59 | A |
| ATOM | 463 | O | LEU | 54 | 16.711 | 39.063 | 17.373 | 1.00 | 34.28 | A |
| ATOM | 464 | N | GLY | 55 | 16.673 | 37.444 | 18.916 | 1.00 | 32.54 | A |
| ATOM | 465 | H | GLY | 55 | 17.009 | 37.075 | 19.762 | 0.00 | 0.00 | A |
| ATOM | 466 | CA | GLY | 55 | 15.644 | 36.708 | 18.215 | 1.00 | 32.79 | A |
| ATOM | 467 | C | GLY | 55 | 16.161 | 35.574 | 17.378 | 1.00 | 35.07 | A |
| ATOM | 468 | O | GLY | 55 | 16.811 | 34.658 | 17.891 | 1.00 | 34.84 | A |
| ATOM | 469 | N | ASP | 56 | 15.832 | 35.617 | 16.093 | 1.00 | 36.63 | A |
| ATOM | 470 | H | ASP | 56 | 15.280 | 36.334 | 15.723 | 0.00 | 0.00 | A |
| ATOM | 471 | CA | ASP | 56 | 16.264 | 34.592 | 15.166 | 1.00 | 37.80 | A |
| ATOM | 472 | CB | ASP | 56 | 15.330 | 33.369 | 15.212 | 1.00 | 37.51 | A |
| ATOM | 473 | CG | ASP | 56 | 13.918 | 33.671 | 14.741 | 1.00 | 36.92 | A |
| ATOM | 474 | OD1 | ASP | 56 | 13.760 | 34.433 | 13.770 | 1.00 | 35.45 | A |
| ATOM | 475 | OD2 | ASP | 56 | 12.956 | 33.122 | 15.328 | 1.00 | 38.80 | A |
| ATOM | 476 | C | ASP | 56 | 16.394 | 35.161 | 13.752 | 1.00 | 38.48 | A |
| ATOM | 477 | O | ASP | 56 | 15.937 | 36.277 | 13.478 | 1.00 | 38.67 | A |
| ATOM | 478 | N | ILE | 57 | 16.968 | 34.354 | 12.862 | 1.00 | 38.06 | A |
| ATOM | 479 | H | ILE | 57 | 17.172 | 33.457 | 13.167 | 0.00 | 0.00 | A |
| ATOM | 480 | CA | ILE | 57 | 17.232 | 34.709 | 11.473 | 1.00 | 36.63 | A |
| ATOM | 481 | CB | ILE | 57 | 17.987 | 33.550 | 10.744 | 1.00 | 33.47 | A |
| ATOM | 482 | CG2 | ILE | 57 | 17.035 | 32.445 | 10.316 | 1.00 | 31.29 | A |
| ATOM | 483 | CG1 | ILE | 57 | 18.709 | 34.068 | 9.516 | 1.00 | 31.65 | A |
| ATOM | 484 | CD1 | ILE | 57 | 19.543 | 33.014 | 8.865 | 1.00 | 32.03 | A |
| ATOM | 485 | C | ILE | 57 | 16.007 | 35.148 | 10.683 | 1.00 | 38.59 | A |
| ATOM | 486 | O | ILE | 57 | 16.077 | 36.115 | 9.933 | 1.00 | 39.40 | A |
| ATOM | 487 | N | GLY | 58 | 14.876 | 34.480 | 10.886 | 1.00 | 40.97 | A |
| ATOM | 488 | H | GLY | 58 | 14.832 | 33.772 | 11.569 | 0.00 | 0.00 | A |
| ATOM | 489 | CA | GLY | 58 | 13.672 | 34.835 | 10.158 | 1.00 | 43.78 | A |
| ATOM | 490 | C | GLY | 58 | 13.143 | 36.205 | 10.533 | 1.00 | 46.85 | A |
| ATOM | 491 | O | GLY | 58 | 12.591 | 36.926 | 9.703 | 1.00 | 48.60 | A |
| ATOM | 492 | N | LYS | 59 | 13.325 | 36.568 | 11.793 | 1.00 | 49.62 | A |
| ATOM | 493 | H | LYS | 59 | 13.760 | 35.937 | 12.412 | 0.00 | 0.00 | A |
| ATOM | 494 | CA | LYS | 59 | 12.870 | 37.850 | 12.309 | 1.00 | 51.87 | A |
| ATOM | 495 | CB | LYS | 59 | 13.018 | 37.852 | 13.826 | 1.00 | 53.55 | A |
| ATOM | 496 | CG | LYS | 59 | 12.534 | 39.086 | 14.516 | 1.00 | 56.93 | A |
| ATOM | 497 | CD | LYS | 59 | 13.206 | 39.156 | 15.859 | 1.00 | 60.39 | A |
| ATOM | 498 | CE | LYS | 59 | 12.776 | 40.366 | 16.653 | 1.00 | 62.70 | A |
| ATOM | 499 | NZ | LYS | 59 | 13.622 | 40.468 | 17.878 | 1.00 | 67.42 | A |
| ATOM | 500 | HZ1 | LYS | 59 | 13.319 | 41.273 | 18.449 | 0.00 | 0.00 | A |
| ATOM | 501 | HZ2 | LYS | 59 | 14.603 | 40.643 | 17.546 | 0.00 | 0.00 | A |
| ATOM | 502 | HZ3 | LYS | 59 | 13.575 | 39.581 | 18.413 | 0.00 | 0.00 | A |
| ATOM | 503 | C | LYS | 59 | 13.660 | 39.007 | 11.690 | 1.00 | 52.21 | A |
| ATOM | 504 | O | LYS | 59 | 13.094 | 40.054 | 11.385 | 1.00 | 53.64 | A |
| ATOM | 505 | N | LEU | 60 | 14.968 | 38.815 | 11.529 | 1.00 | 51.56 | A |
| ATOM | 506 | H | LEU | 60 | 15.343 | 37.957 | 11.824 | 0.00 | 0.00 | A |
| ATOM | 507 | CA | LEU | 60 | 15.852 | 39.823 | 10.938 | 1.00 | 50.00 | A |
| ATOM | 508 | CB | LEU | 60 | 17.286 | 39.640 | 11.437 | 1.00 | 49.26 | A |
| ATOM | 509 | CG | LEU | 60 | 17.734 | 40.269 | 12.752 | 1.00 | 51.25 | A |
| ATOM | 510 | CD1 | LEU | 60 | 16.954 | 39.719 | 13.946 | 1.00 | 51.11 | A |
| ATOM | 511 | CD2 | LEU | 60 | 19.226 | 40.014 | 12.898 | 1.00 | 51.47 | A |
| ATOM | 512 | C | LEU | 60 | 15.882 | 39.821 | 9.403 | 1.00 | 49.29 | A |
| ATOM | 513 | O | LEU | 60 | 16.098 | 40.864 | 8.787 | 1.00 | 49.22 | A |
| ATOM | 514 | N | PHE | 61 | 15.735 | 38.649 | 8.791 | 1.00 | 48.60 | A |
| ATOM | 515 | H | PHE | 61 | 15.590 | 37.835 | 9.314 | 0.00 | 0.00 | A |
| ATOM | 516 | CA | PHE | 61 | 15.771 | 38.537 | 7.338 | 1.00 | 48.74 | A |
| ATOM | 517 | CB | PHE | 61 | 17.114 | 37.934 | 6.882 | 1.00 | 46.51 | A |
| ATOM | 518 | CG | PHE | 61 | 18.314 | 38.447 | 7.650 | 1.00 | 45.75 | A |
| ATOM | 519 | CD1 | PHE | 61 | 18.690 | 39.783 | 7.583 | 1.00 | 43.79 | A |
| ATOM | 520 | CD2 | PHE | 61 | 19.045 | 37.592 | 8.474 | 1.00 | 45.32 | A |
| ATOM | 521 | CE1 | PHE | 61 | 19.772 | 40.261 | 8.330 | 1.00 | 43.44 | A |
| ATOM | 522 | CE2 | PHE | 61 | 20.129 | 38.063 | 9.224 | 1.00 | 44.22 | A |
| ATOM | 523 | CZ | PHE | 61 | 20.490 | 39.400 | 9.152 | 1.00 | 43.06 | A |
| ATOM | 524 | C | PHE | 61 | 14.603 | 37.669 | 6.851 | 1.00 | 50.87 | A |
| ATOM | 525 | O | PHE | 61 | 14.787 | 36.517 | 6.485 | 1.00 | 51.44 | A |
| ATOM | 526 | N | PRO | 62 | 13.390 | 38.241 | 6.797 | 1.00 | 53.60 | A |
| ATOM | 527 | CD | PRO | 62 | 13.137 | 39.641 | 7.179 | 1.00 | 54.38 | A |
| ATOM | 528 | CA | PRO | 62 | 12.139 | 37.600 | 6.372 | 1.00 | 56.25 | A |
| ATOM | 529 | CB | PRO | 62 | 11.167 | 38.775 | 6.334 | 1.00 | 55.31 | A |
| ATOM | 530 | CG | PRO | 62 | 11.656 | 39.641 | 7.434 | 1.00 | 53.95 | A |
| ATOM | 531 | C | PRO | 62 | 12.107 | 36.827 | 5.045 | 1.00 | 59.40 | A |
| ATOM | 532 | O | PRO | 62 | 12.545 | 37.326 | 4.006 | 1.00 | 59.70 | A |
| ATOM | 533 | N | ASP | 63 | 11.501 | 35.639 | 5.095 | 1.00 | 63.52 | A |
| ATOM | 534 | H | ASP | 63 | 11.207 | 35.298 | 5.963 | 0.00 | 0.00 | A |
| ATOM | 535 | CA | ASP | 63 | 11.320 | 34.746 | 3.942 | 1.00 | 67.07 | A |
| ATOM | 536 | CB | ASP | 63 | 10.503 | 33.513 | 4.357 | 1.00 | 70.08 | A |
| ATOM | 537 | CG | ASP | 63 | 11.372 | 32.325 | 4.730 | 1.00 | 75.30 | A |
| ATOM | 538 | OD1 | ASP | 63 | 12.548 | 32.525 | 5.113 | 1.00 | 79.11 | A |
| ATOM | 539 | OD2 | ASP | 63 | 10.879 | 31.178 | 4.632 | 1.00 | 76.30 | A |
| ATOM | 540 | C | ASP | 63 | 10.551 | 35.449 | 2.836 | 1.00 | 68.14 | A |
| ATOM | 541 | O | ASP | 63 | 10.678 | 35.116 | 1.655 | 1.00 | 68.67 | A |
| ATOM | 542 | N | THR | 64 | 9.701 | 36.379 | 3.250 | 1.00 | 69.64 | A |
| ATOM | 543 | H | THR | 64 | 9.617 | 36.563 | 4.205 | 0.00 | 0.00 | A |
| ATOM | 544 | CA | THR | 64 | 8.862 | 37.158 | 2.350 | 1.00 | 71.34 | A |
| ATOM | 545 | CB | THR | 64 | 7.690 | 37.812 | 3.136 | 1.00 | 72.58 | A |
| ATOM | 546 | OG1 | THR | 64 | 8.192 | 38.483 | 4.304 | 1.00 | 73.91 | A |
| ATOM | 547 | HG1 | THR | 64 | 8.469 | 39.388 | 4.075 | 0.00 | 0.00 | A |
| ATOM | 548 | CG2 | THR | 64 | 6.683 | 36.749 | 3.568 | 1.00 | 73.09 | A |
| ATOM | 549 | C | THR | 64 | 9.635 | 38.228 | 1.571 | 1.00 | 70.96 | A |
| ATOM | 550 | O | THR | 64 | 9.427 | 38.404 | 0.366 | 1.00 | 72.17 | A |
| ATOM | 551 | N | ASP | 65 | 10.536 | 38.922 | 2.260 | 1.00 | 69.78 | A |
| ATOM | 552 | H | ASP | 65 | 10.704 | 38.703 | 3.197 | 0.00 | 0.00 | A |
| ATOM | 553 | CA | ASP | 65 | 11.333 | 39.969 | 1.647 | 1.00 | 67.92 | A |
| ATOM | 554 | CB | ASP | 65 | 12.216 | 40.630 | 2.697 | 1.00 | 68.89 | A |
| ATOM | 555 | CG | ASP | 65 | 12.836 | 41.923 | 2.212 | 1.00 | 70.13 | A |
| ATOM | 556 | OD1 | ASP | 65 | 13.069 | 42.064 | 0.994 | 1.00 | 71.39 | A |
| ATOM | 557 | OD2 | ASP | 65 | 13.091 | 42.807 | 3.057 | 1.00 | 71.48 | A |
| ATOM | 558 | C | ASP | 65 | 12.182 | 39.381 | 0.525 | 1.00 | 67.48 | A |
| ATOM | 559 | O | ASP | 65 | 13.103 | 38.591 | 0.766 | 1.00 | 65.87 | A |
| ATOM | 560 | N | PRO | 66 | 11.876 | 39.764 | −0.725 | 1.00 | 68.09 | A |
| ATOM | 561 | CD | PRO | 66 | 10.836 | 40.762 | −1.038 | 1.00 | 69.04 | A |
| ATOM | 562 | CA | PRO | 66 | 12.553 | 39.325 | −1.952 | 1.00 | 68.48 | A |
| ATOM | 563 | CB | PRO | 66 | 11.725 | 39.990 | −3.051 | 1.00 | 68.61 | A |
| ATOM | 564 | CG | PRO | 66 | 11.265 | 41.254 | −2.398 | 1.00 | 69.34 | A |
| ATOM | 565 | C | PRO | 66 | 14.026 | 39.728 | −2.031 | 1.00 | 68.29 | A |
| ATOM | 566 | O | PRO | 66 | 14.769 | 39.246 | −2.894 | 1.00 | 68.55 | A |
| ATOM | 567 | N | ALA | 67 | 14.446 | 40.603 | −1.126 | 1.00 | 67.34 | A |
| ATOM | 568 | H | ALA | 67 | 13.825 | 40.985 | −0.467 | 0.00 | 0.00 | A |
| ATOM | 569 | CA | ALA | 67 | 15.828 | 41.053 | −1.079 | 1.00 | 67.20 | A |
| ATOM | 570 | CB | ALA | 67 | 15.949 | 42.227 | −0.128 | 1.00 | 68.19 | A |
| ATOM | 571 | C | ALA | 67 | 16.744 | 39.912 | −0.623 | 1.00 | 66.93 | A |
| ATOM | 572 | O | ALA | 67 | 17.950 | 39.903 | −0.897 | 1.00 | 67.19 | A |
| ATOM | 573 | N | PHE | 68 | 16.157 | 38.941 | 0.065 | 1.00 | 65.52 | A |
| ATOM | 574 | H | PHE | 68 | 15.198 | 39.014 | 0.267 | 0.00 | 0.00 | A |
| ATOM | 575 | CA | PHE | 68 | 16.916 | 37.814 | 0.572 | 1.00 | 63.77 | A |
| ATOM | 576 | CB | PHE | 68 | 16.458 | 37.504 | 1.995 | 1.00 | 61.81 | A |
| ATOM | 577 | CG | PHE | 68 | 16.310 | 38.725 | 2.851 | 1.00 | 59.89 | A |
| ATOM | 578 | CD1 | PHE | 68 | 15.106 | 39.008 | 3.478 | 1.00 | 59.01 | A |
| ATOM | 579 | CD2 | PHE | 68 | 17.372 | 39.607 | 3.014 | 1.00 | 58.70 | A |
| ATOM | 580 | CE1 | PHE | 68 | 14.962 | 40.153 | 4.257 | 1.00 | 57.86 | A |
| ATOM | 581 | CE2 | PHE | 68 | 17.236 | 40.753 | 3.790 | 1.00 | 57.41 | A |
| ATOM | 582 | CZ | PHE | 68 | 16.029 | 41.026 | 4.413 | 1.00 | 57.49 | A |
| ATOM | 583 | C | PHE | 68 | 16.813 | 36.574 | −0.304 | 1.00 | 63.76 | A |
| ATOM | 584 | O | PHE | 68 | 17.152 | 35.475 | 0.142 | 1.00 | 64.40 | A |
| ATOM | 585 | N | LYS | 69 | 16.329 | 36.725 | −1.534 | 1.00 | 63.50 | A |
| ATOM | 586 | H | LYS | 69 | 16.112 | 37.613 | −1.894 | 0.00 | 0.00 | A |
| ATOM | 587 | CA | LYS | 69 | 16.219 | 35.565 | −2.409 | 1.00 | 65.34 | A |
| ATOM | 588 | CB | LYS | 69 | 15.153 | 35.741 | −3.482 | 1.00 | 67.60 | A |
| ATOM | 589 | CG | LYS | 69 | 14.950 | 34.446 | −4.252 | 1.00 | 72.47 | A |
| ATOM | 590 | CD | LYS | 69 | 14.094 | 34.620 | −5.478 | 1.00 | 78.38 | A |
| ATOM | 591 | CE | LYS | 69 | 14.042 | 33.326 | −6.276 | 1.00 | 81.66 | A |
| ATOM | 592 | NZ | LYS | 69 | 13.217 | 33.460 | −7.511 | 1.00 | 84.90 | A |
| ATOM | 593 | HZ1 | LYS | 69 | 13.217 | 32.558 | −8.028 | 0.00 | 0.00 | A |
| ATOM | 594 | HZ2 | LYS | 69 | 13.606 | 34.210 | −8.116 | 0.00 | 0.00 | A |
| ATOM | 595 | HZ3 | LYS | 69 | 12.241 | 33.701 | −7.245 | 0.00 | 0.00 | A |
| ATOM | 596 | C | LYS | 69 | 17.554 | 35.232 | −3.070 | 1.00 | 64.26 | A |
| ATOM | 597 | O | LYS | 69 | 18.122 | 36.054 | −3.791 | 1.00 | 65.40 | A |
| ATOM | 598 | N | GLY | 70 | 18.018 | 34.003 | −2.855 | 1.00 | 61.40 | A |
| ATOM | 599 | H | GLY | 70 | 17.495 | 33.367 | −2.336 | 0.00 | 0.00 | A |
| ATOM | 600 | CA | GLY | 70 | 19.288 | 33.569 | −3.399 | 1.00 | 57.42 | A |
| ATOM | 601 | C | GLY | 70 | 20.415 | 34.166 | −2.577 | 1.00 | 55.41 | A |
| ATOM | 602 | O | GLY | 70 | 21.587 | 33.983 | −2.903 | 1.00 | 56.80 | A |
| ATOM | 603 | N | ALA | 71 | 20.055 | 34.833 | −1.480 | 1.00 | 52.44 | A |
| ATOM | 604 | H | ALA | 71 | 19.111 | 34.885 | −1.237 | 0.00 | 0.00 | A |
| ATOM | 605 | CA | ALA | 71 | 21.015 | 35.491 | −0.595 | 1.00 | 50.60 | A |
| ATOM | 606 | CB | ALA | 71 | 20.289 | 36.108 | 0.616 | 1.00 | 47.83 | A |
| ATOM | 607 | C | ALA | 71 | 22.159 | 34.587 | −0.125 | 1.00 | 49.05 | A |
| ATOM | 608 | O | ALA | 71 | 21.980 | 33.379 | 0.074 | 1.00 | 50.42 | A |
| ATOM | 609 | N | ASP | 72 | 23.335 | 35.187 | 0.017 | 1.00 | 44.70 | A |
| ATOM | 610 | H | ASP | 72 | 23.427 | 36.145 | −0.178 | 0.00 | 0.00 | A |
| ATOM | 611 | CA | ASP | 72 | 24.524 | 34.497 | 0.475 | 1.00 | 39.54 | A |
| ATOM | 612 | CB | ASP | 72 | 25.748 | 35.337 | 0.096 | 1.00 | 40.15 | A |
| ATOM | 613 | CG | ASP | 72 | 27.068 | 34.711 | 0.510 | 1.00 | 42.70 | A |
| ATOM | 614 | OD1 | ASP | 72 | 27.083 | 33.808 | 1.361 | 1.00 | 47.32 | A |
| ATOM | 615 | OD2 | ASP | 72 | 28.124 | 35.140 | −0.005 | 1.00 | 44.57 | A |
| ATOM | 616 | C | ASP | 72 | 24.363 | 34.434 | 1.990 | 1.00 | 38.34 | A |
| ATOM | 617 | O | ASP | 72 | 24.429 | 35.464 | 2.664 | 1.00 | 39.34 | A |
| ATOM | 618 | N | SER | 73 | 24.143 | 33.242 | 2.537 | 1.00 | 34.94 | A |
| ATOM | 619 | H | SER | 73 | 24.098 | 32.444 | 1.958 | 0.00 | 0.00 | A |
| ATOM | 620 | CA | SER | 73 | 23.981 | 33.111 | 3.978 | 1.00 | 31.43 | A |
| ATOM | 621 | CB | SER | 73 | 23.704 | 31.667 | 4.368 | 1.00 | 30.77 | A |
| ATOM | 622 | OG | SER | 73 | 22.413 | 31.269 | 3.937 | 1.00 | 28.57 | A |
| ATOM | 623 | HG | SER | 73 | 22.695 | 30.522 | 3.393 | 0.00 | 0.00 | A |
| ATOM | 624 | C | SER | 73 | 25.150 | 33.681 | 4.777 | 1.00 | 31.01 | A |
| ATOM | 625 | O | SER | 73 | 25.014 | 33.953 | 5.972 | 1.00 | 31.19 | A |
| ATOM | 626 | N | ARG | 74 | 26.301 | 33.850 | 4.133 | 1.00 | 30.67 | A |
| ATOM | 627 | H | ARG | 74 | 26.387 | 33.552 | 3.201 | 0.00 | 0.00 | A |
| ATOM | 628 | CA | ARG | 74 | 27.457 | 34.440 | 4.801 | 1.00 | 31.01 | A |
| ATOM | 629 | CB | ARG | 74 | 28.745 | 34.226 | 4.013 | 1.00 | 28.78 | A |
| ATOM | 630 | CG | ARG | 74 | 29.279 | 32.814 | 4.094 | 1.00 | 28.19 | A |
| ATOM | 631 | CD | ARG | 74 | 30.570 | 32.667 | 3.319 | 1.00 | 28.25 | A |
| ATOM | 632 | NE | ARG | 74 | 31.666 | 33.385 | 3.960 | 1.00 | 32.00 | A |
| ATOM | 633 | HE | ARG | 74 | 31.494 | 33.724 | 4.859 | 0.00 | 0.00 | A |
| ATOM | 634 | CZ | ARG | 74 | 32.858 | 33.611 | 3.412 | 1.00 | 31.64 | A |
| ATOM | 635 | NH1 | ARG | 74 | 33.781 | 34.272 | 4.099 | 1.00 | 31.03 | A |
| ATOM | 636 | HH11 | ARG | 74 | 33.546 | 34.605 | 5.028 | 0.00 | 0.00 | A |
| ATOM | 637 | HH12 | ARG | 74 | 34.707 | 34.478 | 3.754 | 0.00 | 0.00 | A |
| ATOM | 638 | NH2 | ARG | 74 | 33.127 | 33.185 | 2.183 | 1.00 | 30.03 | A |
| ATOM | 639 | HH21 | ARG | 74 | 32.443 | 32.686 | 1.634 | 0.00 | 0.00 | A |
| ATOM | 640 | HH22 | ARG | 74 | 34.022 | 33.356 | 1.748 | 0.00 | 0.00 | A |
| ATOM | 641 | C | ARG | 74 | 27.188 | 35.924 | 4.954 | 1.00 | 33.03 | A |
| ATOM | 642 | O | ARG | 74 | 27.626 | 36.536 | 5.920 | 1.00 | 34.50 | A |
| ATOM | 643 | N | GLU | 75 | 26.475 | 36.510 | 3.997 | 1.00 | 36.19 | A |
| ATOM | 644 | H | GLU | 75 | 26.190 | 36.001 | 3.207 | 0.00 | 0.00 | A |
| ATOM | 645 | CA | GLU | 75 | 26.136 | 37.925 | 4.089 | 1.00 | 39.72 | A |
| ATOM | 646 | CB | GLU | 75 | 25.424 | 38.416 | 2.835 | 1.00 | 45.78 | A |
| ATOM | 647 | CG | GLU | 75 | 26.328 | 38.899 | 1.718 | 1.00 | 55.78 | A |
| ATOM | 648 | CD | GLU | 75 | 25.530 | 39.541 | 0.587 | 1.00 | 61.93 | A |
| ATOM | 649 | OE1 | GLU | 75 | 25.182 | 40.735 | 0.716 | 1.00 | 66.40 | A |
| ATOM | 650 | OE2 | GLU | 75 | 25.228 | 38.851 | −0.417 | 1.00 | 64.86 | A |
| ATOM | 651 | C | GLU | 75 | 25.211 | 38.110 | 5.281 | 1.00 | 38.61 | A |
| ATOM | 652 | O | GLU | 75 | 25.344 | 39.074 | 6.035 | 1.00 | 39.33 | A |
| ATOM | 653 | N | LEU | 76 | 24.271 | 37.182 | 5.443 | 1.00 | 36.17 | A |
| ATOM | 654 | H | LEU | 76 | 24.208 | 36.470 | 4.771 | 0.00 | 0.00 | A |
| ATOM | 655 | CA | LEU | 76 | 23.330 | 37.230 | 6.555 | 1.00 | 33.67 | A |
| ATOM | 656 | CB | LEU | 76 | 22.231 | 36.181 | 6.384 | 1.00 | 35.59 | A |
| ATOM | 657 | CG | LEU | 76 | 21.335 | 36.255 | 5.142 | 1.00 | 36.44 | A |
| ATOM | 658 | CD1 | LEU | 76 | 20.221 | 35.219 | 5.262 | 1.00 | 35.97 | A |
| ATOM | 659 | CD2 | LEU | 76 | 20.738 | 37.649 | 5.017 | 1.00 | 37.62 | A |
| ATOM | 660 | C | LEU | 76 | 24.054 | 36.997 | 7.875 | 1.00 | 33.45 | A |
| ATOM | 661 | O | LEU | 76 | 23.716 | 37.602 | 8.893 | 1.00 | 34.12 | A |
| ATOM | 662 | N | LEU | 77 | 25.041 | 36.108 | 7.868 | 1.00 | 31.70 | A |
| ATOM | 663 | H | LEU | 77 | 25.255 | 35.627 | 7.043 | 0.00 | 0.00 | A |
| ATOM | 664 | CA | LEU | 77 | 25.794 | 35.831 | 9.077 | 1.00 | 31.76 | A |
| ATOM | 665 | CB | LEU | 77 | 26.770 | 34.677 | 8.850 | 1.00 | 29.77 | A |
| ATOM | 666 | CG | LEU | 77 | 27.678 | 34.328 | 10.033 | 1.00 | 29.16 | A |
| ATOM | 667 | CD1 | LEU | 77 | 26.841 | 33.852 | 11.206 | 1.00 | 27.54 | A |
| ATOM | 668 | CD2 | LEU | 77 | 28.690 | 33.263 | 9.624 | 1.00 | 29.03 | A |
| ATOM | 669 | C | LEU | 77 | 26.545 | 37.083 | 9.535 | 1.00 | 33.17 | A |
| ATOM | 670 | O | LEU | 77 | 26.462 | 37.482 | 10.698 | 1.00 | 34.87 | A |
| ATOM | 671 | N | ARG | 78 | 27.266 | 37.711 | 8.617 | 1.00 | 34.17 | A |
| ATOM | 672 | H | ARG | 78 | 27.313 | 37.346 | 7.707 | 0.00 | 0.00 | A |
| ATOM | 673 | CA | ARG | 78 | 28.022 | 38.910 | 8.940 | 1.00 | 33.92 | A |
| ATOM | 674 | CB | ARG | 78 | 28.817 | 39.366 | 7.732 | 1.00 | 33.13 | A |
| ATOM | 675 | CG | ARG | 78 | 29.974 | 38.451 | 7.422 | 1.00 | 36.28 | A |
| ATOM | 676 | CD | ARG | 78 | 30.828 | 39.004 | 6.299 | 1.00 | 36.20 | A |
| ATOM | 677 | NE | ARG | 78 | 30.890 | 38.074 | 5.181 | 1.00 | 39.52 | A |
| ATOM | 678 | HE | ARG | 78 | 31.458 | 37.281 | 5.351 | 0.00 | 0.00 | A |
| ATOM | 679 | CZ | ARG | 78 | 30.229 | 38.235 | 4.041 | 1.00 | 38.95 | A |
| ATOM | 680 | NH1 | ARG | 78 | 30.340 | 37.319 | 3.083 | 1.00 | 39.89 | A |
| ATOM | 681 | HH11 | ARG | 78 | 30.917 | 36.507 | 3.188 | 0.00 | 0.00 | A |
| ATOM | 682 | HH12 | ARG | 78 | 29.882 | 37.392 | 2.190 | 0.00 | 0.00 | A |
| ATOM | 683 | NH2 | ARG | 78 | 29.483 | 39.323 | 3.850 | 1.00 | 39.37 | A |
| ATOM | 684 | HH21 | ARG | 78 | 29.426 | 40.057 | 4.547 | 0.00 | 0.00 | A |
| ATOM | 685 | HH22 | ARG | 78 | 28.970 | 39.487 | 3.002 | 0.00 | 0.00 | A |
| ATOM | 686 | C | ARG | 78 | 27.157 | 40.045 | 9.470 | 1.00 | 35.08 | A |
| ATOM | 687 | O | ARG | 78 | 27.538 | 40.712 | 10.428 | 1.00 | 36.64 | A |
| ATOM | 688 | N | GLU | 79 | 25.996 | 40.259 | 8.858 | 1.00 | 35.56 | A |
| ATOM | 689 | H | GLU | 79 | 25.751 | 39.717 | 8.076 | 0.00 | 0.00 | A |
| ATOM | 690 | CA | GLU | 79 | 25.073 | 41.306 | 9.291 | 1.00 | 36.83 | A |
| ATOM | 691 | CB | GLU | 79 | 23.904 | 41.429 | 8.313 | 1.00 | 38.38 | A |
| ATOM | 692 | CG | GLU | 79 | 22.793 | 42.385 | 8.747 | 1.00 | 41.21 | A |
| ATOM | 693 | CD | GLU | 79 | 23.254 | 43.819 | 8.959 | 1.00 | 43.20 | A |
| ATOM | 694 | OE1 | GLU | 79 | 24.449 | 44.138 | 8.776 | 1.00 | 44.41 | A |
| ATOM | 695 | OE2 | GLU | 79 | 22.404 | 44.650 | 9.321 | 1.00 | 46.20 | A |
| ATOM | 696 | C | GLU | 79 | 24.545 | 41.033 | 10.695 | 1.00 | 38.65 | A |
| ATOM | 697 | O | GLU | 79 | 24.487 | 41.940 | 11.533 | 1.00 | 41.64 | A |
| ATOM | 698 | N | ALA | 80 | 24.141 | 39.788 | 10.942 | 1.00 | 37.65 | A |
| ATOM | 699 | H | ALA | 80 | 24.151 | 39.128 | 10.215 | 0.00 | 0.00 | A |
| ATOM | 700 | CA | ALA | 80 | 23.653 | 39.388 | 12.250 | 1.00 | 35.38 | A |
| ATOM | 701 | CB | ALA | 80 | 23.224 | 37.937 | 12.225 | 1.00 | 34.83 | A |
| ATOM | 702 | C | ALA | 80 | 24.791 | 39.589 | 13.250 | 1.00 | 35.15 | A |
| ATOM | 703 | O | ALA | 80 | 24.570 | 40.022 | 14.383 | 1.00 | 35.56 | A |
| ATOM | 704 | N | TRP | 81 | 26.017 | 39.312 | 12.817 | 1.00 | 34.64 | A |
| ATOM | 705 | H | TRP | 81 | 26.133 | 38.971 | 11.908 | 0.00 | 0.00 | A |
| ATOM | 706 | CA | TRP | 81 | 27.183 | 39.475 | 13.681 | 1.00 | 34.82 | A |
| ATOM | 707 | CB | TRP | 81 | 28.410 | 38.831 | 13.045 | 1.00 | 30.93 | A |
| ATOM | 708 | CG | TRP | 81 | 29.640 | 38.964 | 13.874 | 1.00 | 28.09 | A |
| ATOM | 709 | CD2 | TRP | 81 | 29.793 | 38.603 | 15.254 | 1.00 | 27.74 | A |
| ATOM | 710 | CE2 | TRP | 81 | 31.122 | 38.908 | 15.620 | 1.00 | 27.70 | A |
| ATOM | 711 | CE3 | TRP | 81 | 28.936 | 38.051 | 16.217 | 1.00 | 28.86 | A |
| ATOM | 712 | CD1 | TRP | 81 | 30.843 | 39.454 | 13.472 | 1.00 | 26.55 | A |
| ATOM | 713 | NE1 | TRP | 81 | 31.741 | 39.426 | 14.513 | 1.00 | 27.17 | A |
| ATOM | 714 | HE1 | TRP | 81 | 32.678 | 39.725 | 14.472 | 0.00 | 0.00 | A |
| ATOM | 715 | CZ2 | TRP | 81 | 31.618 | 38.681 | 16.908 | 1.00 | 27.33 | A |
| ATOM | 716 | CZ3 | TRP | 81 | 29.426 | 37.824 | 17.496 | 1.00 | 28.25 | A |
| ATOM | 717 | CH2 | TRP | 81 | 30.757 | 38.140 | 17.829 | 1.00 | 29.54 | A |
| ATOM | 718 | C | TRP | 81 | 27.449 | 40.955 | 13.956 | 1.00 | 37.02 | A |
| ATOM | 719 | O | TRP | 81 | 27.793 | 41.347 | 15.073 | 1.00 | 37.28 | A |
| ATOM | 720 | N | ARG | 82 | 27.275 | 41.779 | 12.932 | 1.00 | 39.58 | A |
| ATOM | 721 | H | ARG | 82 | 26.983 | 41.412 | 12.076 | 0.00 | 0.00 | A |
| ATOM | 722 | CA | ARG | 82 | 27.477 | 43.210 | 13.066 | 1.00 | 41.07 | A |
| ATOM | 723 | CB | ARG | 82 | 27.180 | 43.909 | 11.746 | 1.00 | 41.46 | A |
| ATOM | 724 | CG | ARG | 82 | 27.506 | 45.376 | 11.773 | 1.00 | 46.01 | A |
| ATOM | 725 | CD | ARG | 82 | 27.003 | 46.091 | 10.533 | 1.00 | 51.38 | A |
| ATOM | 726 | NE | ARG | 82 | 25.544 | 46.071 | 10.404 | 1.00 | 54.82 | A |
| ATOM | 727 | HE | ARG | 82 | 25.199 | 45.599 | 9.617 | 0.00 | 0.00 | A |
| ATOM | 728 | CZ | ARG | 82 | 24.693 | 46.665 | 11.240 | 1.00 | 55.83 | A |
| ATOM | 729 | NH1 | ARG | 82 | 23.385 | 46.579 | 11.019 | 1.00 | 56.12 | A |
| ATOM | 730 | HH11 | ARG | 82 | 23.092 | 46.044 | 10.206 | 0.00 | 0.00 | A |
| ATOM | 731 | HH12 | ARG | 82 | 22.678 | 46.985 | 11.590 | 0.00 | 0.00 | A |
| ATOM | 732 | NH2 | ARG | 82 | 25.145 | 47.347 | 12.290 | 1.00 | 55.77 | A |
| ATOM | 733 | HH21 | ARG | 82 | 26.138 | 47.451 | 12.451 | 0.00 | 0.00 | A |
| ATOM | 734 | HH22 | ARG | 82 | 24.539 | 47.809 | 12.936 | 0.00 | 0.00 | A |
| ATOM | 735 | C | ARG | 82 | 26.526 | 43.725 | 14.140 | 1.00 | 42.07 | A |
| ATOM | 736 | O | ARG | 82 | 26.942 | 44.382 | 15.099 | 1.00 | 42.32 | A |
| ATOM | 737 | N | ARG | 83 | 25.251 | 43.391 | 13.996 | 1.00 | 40.81 | A |
| ATOM | 738 | H | ARG | 83 | 24.982 | 42.830 | 13.235 | 0.00 | 0.00 | A |
| ATOM | 739 | CA | ARG | 83 | 24.257 | 43.822 | 14.959 | 1.00 | 41.25 | A |
| ATOM | 740 | CB | ARG | 83 | 22.875 | 43.366 | 14.524 | 1.00 | 42.00 | A |
| ATOM | 741 | CG | ARG | 83 | 22.560 | 43.787 | 13.122 | 1.00 | 46.32 | A |
| ATOM | 742 | CD | ARG | 83 | 21.083 | 43.791 | 12.861 | 1.00 | 52.65 | A |
| ATOM | 743 | NE | ARG | 83 | 20.831 | 44.013 | 11.443 | 1.00 | 58.69 | A |
| ATOM | 744 | HE | ARG | 83 | 21.636 | 44.171 | 10.921 | 0.00 | 0.00 | A |
| ATOM | 745 | CZ | ARG | 83 | 19.639 | 43.938 | 10.857 | 1.00 | 61.36 | A |
| ATOM | 746 | NH1 | ARG | 83 | 19.538 | 44.154 | 9.549 | 1.00 | 63.52 | A |
| ATOM | 747 | HH11 | ARG | 83 | 20.397 | 44.342 | 9.045 | 0.00 | 0.00 | A |
| ATOM | 748 | HH12 | ARG | 83 | 18.712 | 44.094 | 8.978 | 0.00 | 0.00 | A |
| ATOM | 749 | NH2 | ARG | 83 | 18.554 | 43.656 | 11.574 | 1.00 | 63.61 | A |
| ATOM | 750 | HH21 | ARG | 83 | 18.638 | 43.508 | 12.568 | 0.00 | 0.00 | A |
| ATOM | 751 | HH22 | ARG | 83 | 17.644 | 43.582 | 11.160 | 0.00 | 0.00 | A |
| ATOM | 752 | C | ARG | 83 | 24.564 | 43.309 | 16.356 | 1.00 | 41.94 | A |
| ATOM | 753 | O | ARG | 83 | 24.422 | 44.040 | 17.341 | 1.00 | 43.82 | A |
| ATOM | 754 | N | ILE | 84 | 25.009 | 42.064 | 16.445 | 1.00 | 40.45 | A |
| ATOM | 755 | H | ILE | 84 | 25.112 | 41.518 | 15.637 | 0.00 | 0.00 | A |
| ATOM | 756 | CA | ILE | 84 | 25.318 | 41.481 | 17.737 | 1.00 | 39.83 | A |
| ATOM | 757 | CB | ILE | 84 | 25.708 | 40.000 | 17.589 | 1.00 | 39.57 | A |
| ATOM | 758 | CG2 | ILE | 84 | 26.341 | 39.478 | 18.875 | 1.00 | 37.70 | A |
| ATOM | 759 | CG1 | ILE | 84 | 24.476 | 39.179 | 17.209 | 1.00 | 37.44 | A |
| ATOM | 760 | CD1 | ILE | 84 | 24.808 | 37.801 | 16.731 | 1.00 | 35.82 | A |
| ATOM | 761 | C | ILE | 84 | 26.428 | 42.265 | 18.421 | 1.00 | 39.86 | A |
| ATOM | 762 | O | ILE | 84 | 26.329 | 42.602 | 19.605 | 1.00 | 39.67 | A |
| ATOM | 763 | N | GLN | 85 | 27.474 | 42.569 | 17.665 | 1.00 | 40.65 | A |
| ATOM | 764 | H | GLN | 85 | 27.495 | 42.270 | 16.734 | 0.00 | 0.00 | A |
| ATOM | 765 | CA | GLN | 85 | 28.604 | 43.321 | 18.195 | 1.00 | 41.60 | A |
| ATOM | 766 | CB | GLN | 85 | 29.703 | 43.446 | 17.151 | 1.00 | 41.42 | A |
| ATOM | 767 | CG | GLN | 85 | 30.316 | 42.120 | 16.783 | 1.00 | 44.05 | A |
| ATOM | 768 | CD | GLN | 85 | 31.582 | 42.266 | 15.973 | 1.00 | 45.05 | A |
| ATOM | 769 | OE1 | GLN | 85 | 32.685 | 42.097 | 16.495 | 1.00 | 46.08 | A |
| ATOM | 770 | NE2 | GLN | 85 | 31.435 | 42.568 | 14.684 | 1.00 | 46.62 | A |
| ATOM | 771 | HE21 | GLN | 85 | 30.533 | 42.677 | 14.326 | 0.00 | 0.00 | A |
| ATOM | 772 | HE22 | GLN | 85 | 32.251 | 42.661 | 14.153 | 0.00 | 0.00 | A |
| ATOM | 773 | C | GLN | 85 | 28.166 | 44.699 | 18.648 | 1.00 | 41.58 | A |
| ATOM | 774 | O | GLN | 85 | 28.677 | 45.221 | 19.629 | 1.00 | 42.37 | A |
| ATOM | 775 | N | ALA | 86 | 27.198 | 45.271 | 17.943 | 1.00 | 42.01 | A |
| ATOM | 776 | H | ALA | 86 | 26.836 | 44.801 | 17.165 | 0.00 | 0.00 | A |
| ATOM | 777 | CA | ALA | 86 | 26.680 | 46.585 | 18.290 | 1.00 | 42.70 | A |
| ATOM | 778 | CB | ALA | 86 | 25.736 | 47.095 | 17.212 | 1.00 | 41.09 | A |
| ATOM | 779 | C | ALA | 86 | 25.971 | 46.521 | 19.635 | 1.00 | 44.14 | A |
| ATOM | 780 | O | ALA | 86 | 25.977 | 47.493 | 20.380 | 1.00 | 48.60 | A |
| ATOM | 781 | N | LYS | 87 | 25.348 | 45.387 | 19.947 | 1.00 | 44.39 | A |
| ATOM | 782 | H | LYS | 87 | 25.340 | 44.643 | 19.308 | 0.00 | 0.00 | A |
| ATOM | 783 | CA | LYS | 87 | 24.676 | 45.239 | 21.235 | 1.00 | 43.10 | A |
| ATOM | 784 | CB | LYS | 87 | 23.750 | 44.017 | 21.231 | 1.00 | 44.41 | A |
| ATOM | 785 | CG | LYS | 87 | 22.809 | 43.918 | 22.443 | 1.00 | 48.05 | A |
| ATOM | 786 | CD | LYS | 87 | 21.655 | 42.928 | 22.199 | 1.00 | 50.44 | A |
| ATOM | 787 | CE | LYS | 87 | 20.640 | 42.873 | 23.357 | 1.00 | 51.41 | A |
| ATOM | 788 | NZ | LYS | 87 | 20.871 | 41.761 | 24.340 | 1.00 | 51.41 | A |
| ATOM | 789 | HZ1 | LYS | 87 | 20.144 | 41.811 | 25.101 | 0.00 | 0.00 | A |
| ATOM | 790 | HZ2 | LYS | 87 | 21.801 | 41.751 | 24.801 | 0.00 | 0.00 | A |
| ATOM | 791 | HZ3 | LYS | 87 | 20.727 | 40.855 | 23.864 | 0.00 | 0.00 | A |
| ATOM | 792 | C | LYS | 87 | 25.754 | 45.101 | 22.311 | 1.00 | 42.73 | A |
| ATOM | 793 | O | LYS | 87 | 25.449 | 44.989 | 23.491 | 1.00 | 44.30 | A |
| ATOM | 794 | N | GLY | 88 | 27.015 | 45.063 | 21.885 | 1.00 | 42.41 | A |
| ATOM | 795 | H | GLY | 88 | 27.235 | 45.082 | 20.940 | 0.00 | 0.00 | A |
| ATOM | 796 | CA | GLY | 88 | 28.125 | 44.967 | 22.812 | 1.00 | 42.05 | A |
| ATOM | 797 | C | GLY | 88 | 28.793 | 43.621 | 23.045 | 1.00 | 44.25 | A |
| ATOM | 798 | O | GLY | 88 | 29.630 | 43.509 | 23.944 | 1.00 | 47.95 | A |
| ATOM | 799 | N | TYR | 89 | 28.497 | 42.604 | 22.245 | 1.00 | 43.51 | A |
| ATOM | 800 | H | TYR | 89 | 27.894 | 42.730 | 21.485 | 0.00 | 0.00 | A |
| ATOM | 801 | CA | TYR | 89 | 29.121 | 41.306 | 22.489 | 1.00 | 41.00 | A |
| ATOM | 802 | CB | TYR | 89 | 28.114 | 40.182 | 22.280 | 1.00 | 39.04 | A |
| ATOM | 803 | CG | TYR | 89 | 26.854 | 40.335 | 23.077 | 1.00 | 37.49 | A |
| ATOM | 804 | CD1 | TYR | 89 | 25.771 | 41.029 | 22.556 | 1.00 | 39.33 | A |
| ATOM | 805 | CE1 | TYR | 89 | 24.590 | 41.150 | 23.263 | 1.00 | 40.48 | A |
| ATOM | 806 | CD2 | TYR | 89 | 26.728 | 39.765 | 24.337 | 1.00 | 37.34 | A |
| ATOM | 807 | CE2 | TYR | 89 | 25.544 | 39.878 | 25.059 | 1.00 | 38.70 | A |
| ATOM | 808 | CZ | TYR | 89 | 24.477 | 40.573 | 24.511 | 1.00 | 40.58 | A |
| ATOM | 809 | OH | TYR | 89 | 23.281 | 40.701 | 25.191 | 1.00 | 45.02 | A |
| ATOM | 810 | HH | TYR | 89 | 23.385 | 40.308 | 26.066 | 0.00 | 0.00 | A |
| ATOM | 811 | C | TYR | 89 | 30.340 | 41.023 | 21.637 | 1.00 | 41.02 | A |
| ATOM | 812 | O | TYR | 89 | 30.546 | 41.654 | 20.604 | 1.00 | 42.02 | A |
| ATOM | 813 | N | THR | 90 | 31.169 | 40.098 | 22.113 | 1.00 | 41.35 | A |
| ATOM | 814 | H | THR | 90 | 30.979 | 39.686 | 22.983 | 0.00 | 0.00 | A |
| ATOM | 815 | CA | THR | 90 | 32.354 | 39.641 | 21.389 | 1.00 | 41.59 | A |
| ATOM | 816 | CB | THR | 90 | 33.684 | 40.062 | 22.067 | 1.00 | 43.37 | A |
| ATOM | 817 | OG1 | THR | 90 | 33.650 | 39.764 | 23.468 | 1.00 | 47.12 | A |
| ATOM | 818 | HG1 | THR | 90 | 32.963 | 40.305 | 23.875 | 0.00 | 0.00 | A |
| ATOM | 819 | CG2 | THR | 90 | 33.924 | 41.539 | 21.878 | 1.00 | 44.59 | A |
| ATOM | 820 | C | THR | 90 | 32.229 | 38.116 | 21.348 | 1.00 | 39.90 | A |
| ATOM | 821 | O | THR | 90 | 31.531 | 37.526 | 22.176 | 1.00 | 39.71 | A |
| ATOM | 822 | N | LEU | 91 | 32.869 | 37.476 | 20.380 | 1.00 | 37.78 | A |
| ATOM | 823 | H | LEU | 91 | 33.441 | 37.962 | 19.746 | 0.00 | 0.00 | A |
| ATOM | 824 | CA | LEU | 91 | 32.759 | 36.034 | 20.266 | 1.00 | 35.62 | A |
| ATOM | 825 | CB | LEU | 91 | 33.215 | 35.569 | 18.886 | 1.00 | 32.64 | A |
| ATOM | 826 | CG | LEU | 91 | 32.857 | 34.125 | 18.573 | 1.00 | 28.76 | A |
| ATOM | 827 | CD1 | LEU | 91 | 31.371 | 34.029 | 18.296 | 1.00 | 28.90 | A |
| ATOM | 828 | CD2 | LEU | 91 | 33.630 | 33.668 | 17.375 | 1.00 | 31.91 | A |
| ATOM | 829 | C | LEU | 91 | 33.535 | 35.268 | 21.318 | 1.00 | 36.43 | A |
| ATOM | 830 | O | LEU | 91 | 34.647 | 35.647 | 21.680 | 1.00 | 38.55 | A |
| ATOM | 831 | N | GLY | 92 | 32.914 | 34.212 | 21.834 | 1.00 | 36.81 | A |
| ATOM | 832 | H | GLY | 92 | 31.993 | 34.020 | 21.571 | 0.00 | 0.00 | A |
| ATOM | 833 | CA | GLY | 92 | 33.561 | 33.342 | 22.802 | 1.00 | 34.57 | A |
| ATOM | 834 | C | GLY | 92 | 34.056 | 32.198 | 21.939 | 1.00 | 33.87 | A |
| ATOM | 835 | O | GLY | 92 | 35.239 | 32.071 | 21.683 | 1.00 | 35.45 | A |
| ATOM | 836 | N | ASN | 93 | 33.129 | 31.388 | 21.449 | 1.00 | 32.44 | A |
| ATOM | 837 | H | ASN | 93 | 32.185 | 31.542 | 21.671 | 0.00 | 0.00 | A |
| ATOM | 838 | CA | ASN | 93 | 33.451 | 30.282 | 20.557 | 1.00 | 29.69 | A |
| ATOM | 839 | CB | ASN | 93 | 34.303 | 29.223 | 21.254 | 1.00 | 28.93 | A |
| ATOM | 840 | CG | ASN | 93 | 33.483 | 28.236 | 22.042 | 1.00 | 29.29 | A |
| ATOM | 841 | OD1 | ASN | 93 | 33.413 | 27.058 | 21.696 | 1.00 | 28.88 | A |
| ATOM | 842 | ND2 | ASN | 93 | 32.876 | 28.700 | 23.118 | 1.00 | 28.94 | A |
| ATOM | 843 | HD21 | ASN | 93 | 33.048 | 29.633 | 23.365 | 0.00 | 0.00 | A |
| ATOM | 844 | HD22 | ASN | 93 | 32.257 | 28.128 | 23.594 | 0.00 | 0.00 | A |
| ATOM | 845 | C | ASN | 93 | 32.124 | 29.704 | 20.084 | 1.00 | 29.73 | A |
| ATOM | 846 | O | ASN | 93 | 31.083 | 29.972 | 20.689 | 1.00 | 31.43 | A |
| ATOM | 847 | N | VAL | 94 | 32.142 | 29.012 | 18.953 | 1.00 | 29.13 | A |
| ATOM | 848 | H | VAL | 94 | 32.990 | 28.876 | 18.473 | 0.00 | 0.00 | A |
| ATOM | 849 | CA | VAL | 94 | 30.937 | 28.401 | 18.402 | 1.00 | 27.17 | A |
| ATOM | 850 | CB | VAL | 94 | 30.444 | 29.127 | 17.135 | 1.00 | 28.71 | A |
| ATOM | 851 | CG1 | VAL | 94 | 30.221 | 30.607 | 17.422 | 1.00 | 28.69 | A |
| ATOM | 852 | CG2 | VAL | 94 | 31.424 | 28.918 | 15.983 | 1.00 | 28.08 | A |
| ATOM | 853 | C | VAL | 94 | 31.236 | 26.956 | 18.027 | 1.00 | 26.74 | A |
| ATOM | 854 | O | VAL | 94 | 32.388 | 26.607 | 17.726 | 1.00 | 26.11 | A |
| ATOM | 855 | N | ASP | 95 | 30.202 | 26.124 | 18.046 | 1.00 | 24.82 | A |
| ATOM | 856 | H | ASP | 95 | 29.307 | 26.441 | 18.295 | 0.00 | 0.00 | A |
| ATOM | 857 | CA | ASP | 95 | 30.350 | 24.724 | 17.703 | 1.00 | 23.46 | A |
| ATOM | 858 | CB | ASP | 95 | 30.381 | 23.870 | 18.961 | 1.00 | 24.23 | A |
| ATOM | 859 | CG | ASP | 95 | 30.768 | 22.432 | 18.675 | 1.00 | 27.86 | A |
| ATOM | 860 | OD1 | ASP | 95 | 30.486 | 21.558 | 19.515 | 1.00 | 25.98 | A |
| ATOM | 861 | OD2 | ASP | 95 | 31.341 | 22.148 | 17.601 | 1.00 | 27.12 | A |
| ATOM | 862 | C | ASP | 95 | 29.155 | 24.362 | 16.861 | 1.00 | 24.06 | A |
| ATOM | 863 | O | ASP | 95 | 28.022 | 24.665 | 17.236 | 1.00 | 27.82 | A |
| ATOM | 864 | N | VAL | 96 | 29.406 | 23.733 | 15.718 | 1.00 | 23.79 | A |
| ATOM | 865 | H | VAL | 96 | 30.338 | 23.508 | 15.514 | 0.00 | 0.00 | A |
| ATOM | 866 | CA | VAL | 96 | 28.352 | 23.352 | 14.784 | 1.00 | 22.02 | A |
| ATOM | 867 | CB | VAL | 96 | 28.545 | 24.098 | 13.437 | 1.00 | 23.61 | A |
| ATOM | 868 | CG1 | VAL | 96 | 27.485 | 23.695 | 12.426 | 1.00 | 21.94 | A |
| ATOM | 869 | CG2 | VAL | 96 | 28.503 | 25.603 | 13.665 | 1.00 | 23.55 | A |
| ATOM | 870 | C | VAL | 96 | 28.317 | 21.845 | 14.549 | 1.00 | 21.82 | A |
| ATOM | 871 | O | VAL | 96 | 29.359 | 21.189 | 14.496 | 1.00 | 23.75 | A |
| ATOM | 872 | N | THR | 97 | 27.117 | 21.290 | 14.431 | 1.00 | 21.11 | A |
| ATOM | 873 | H | THR | 97 | 26.321 | 21.849 | 14.463 | 0.00 | 0.00 | A |
| ATOM | 874 | CA | THR | 97 | 26.948 | 19.863 | 14.200 | 1.00 | 22.07 | A |
| ATOM | 875 | CB | THR | 97 | 26.293 | 19.179 | 15.407 | 1.00 | 24.54 | A |
| ATOM | 876 | OG1 | THR | 97 | 27.038 | 19.487 | 16.595 | 1.00 | 29.07 | A |
| ATOM | 877 | HG1 | THR | 97 | 27.764 | 18.857 | 16.515 | 0.00 | 0.00 | A |
| ATOM | 878 | CG2 | THR | 97 | 26.256 | 17.668 | 15.215 | 1.00 | 20.95 | A |
| ATOM | 879 | C | THR | 97 | 26.021 | 19.686 | 13.013 | 1.00 | 24.03 | A |
| ATOM | 880 | O | THR | 97 | 24.836 | 20.013 | 13.111 | 1.00 | 24.95 | A |
| ATOM | 881 | N | ILE | 98 | 26.575 | 19.245 | 11.884 | 1.00 | 24.06 | A |
| ATOM | 882 | H | ILE | 98 | 27.529 | 19.057 | 11.868 | 0.00 | 0.00 | A |
| ATOM | 883 | CA | ILE | 98 | 25.809 | 18.998 | 10.659 | 1.00 | 25.64 | A |
| ATOM | 884 | CB | ILE | 98 | 26.687 | 19.161 | 9.419 | 1.00 | 26.46 | A |
| ATOM | 885 | CG2 | ILE | 98 | 25.886 | 18.879 | 8.155 | 1.00 | 24.22 | A |
| ATOM | 886 | CG1 | ILE | 98 | 27.266 | 20.574 | 9.391 | 1.00 | 27.56 | A |
| ATOM | 887 | CD1 | ILE | 98 | 28.417 | 20.727 | 8.445 | 1.00 | 27.49 | A |
| ATOM | 888 | C | ILE | 98 | 25.280 | 17.566 | 10.710 | 1.00 | 26.81 | A |
| ATOM | 889 | O | ILE | 98 | 26.029 | 16.619 | 10.966 | 1.00 | 30.64 | A |
| ATOM | 890 | N | ILE | 99 | 23.990 | 17.404 | 10.485 | 1.00 | 25.35 | A |
| ATOM | 891 | H | ILE | 99 | 23.429 | 18.168 | 10.235 | 0.00 | 0.00 | A |
| ATOM | 892 | CA | ILE | 99 | 23.381 | 16.090 | 10.556 | 1.00 | 24.37 | A |
| ATOM | 893 | CB | ILE | 99 | 22.165 | 16.123 | 11.510 | 1.00 | 23.31 | A |
| ATOM | 894 | CG2 | ILE | 99 | 21.538 | 14.762 | 11.632 | 1.00 | 23.17 | A |
| ATOM | 895 | CG1 | ILE | 99 | 22.614 | 16.589 | 12.898 | 1.00 | 23.59 | A |
| ATOM | 896 | CD1 | ILE | 99 | 21.512 | 17.147 | 13.748 | 1.00 | 19.94 | A |
| ATOM | 897 | C | ILE | 99 | 22.968 | 15.718 | 9.150 | 1.00 | 25.25 | A |
| ATOM | 898 | O | ILE | 99 | 21.964 | 16.213 | 8.637 | 1.00 | 24.57 | A |
| ATOM | 899 | N | ALA | 100 | 23.773 | 14.875 | 8.515 | 1.00 | 26.25 | A |
| ATOM | 900 | H | ALA | 100 | 24.565 | 14.515 | 8.976 | 0.00 | 0.00 | A |
| ATOM | 901 | CA | ALA | 100 | 23.509 | 14.447 | 7.152 | 1.00 | 26.65 | A |
| ATOM | 902 | CB | ALA | 100 | 24.119 | 15.436 | 6.183 | 1.00 | 25.30 | A |
| ATOM | 903 | C | ALA | 100 | 24.051 | 13.049 | 6.870 | 1.00 | 29.75 | A |
| ATOM | 904 | O | ALA | 100 | 25.130 | 12.674 | 7.339 | 1.00 | 30.24 | A |
| ATOM | 905 | N | GLN | 101 | 23.274 | 12.273 | 6.121 | 1.00 | 30.65 | A |
| ATOM | 906 | H | GLN | 101 | 22.416 | 12.637 | 5.816 | 0.00 | 0.00 | A |
| ATOM | 907 | CA | GLN | 101 | 23.661 | 10.922 | 5.731 | 1.00 | 30.21 | A |
| ATOM | 908 | CB | GLN | 101 | 22.438 | 10.203 | 5.140 | 1.00 | 31.90 | A |
| ATOM | 909 | CG | GLN | 101 | 22.545 | 8.685 | 5.058 | 1.00 | 32.46 | A |
| ATOM | 910 | CD | GLN | 101 | 22.794 | 8.035 | 6.409 | 1.00 | 34.14 | A |
| ATOM | 911 | OE1 | GLN | 101 | 23.588 | 7.104 | 6.518 | 1.00 | 36.30 | A |
| ATOM | 912 | NE2 | GLN | 101 | 22.118 | 8.524 | 7.445 | 1.00 | 34.90 | A |
| ATOM | 913 | HE21 | GLN | 101 | 21.465 | 9.237 | 7.278 | 0.00 | 0.00 | A |
| ATOM | 914 | HE22 | GLN | 101 | 22.328 | 8.161 | 8.325 | 0.00 | 0.00 | A |
| ATOM | 915 | C | GLN | 101 | 24.761 | 11.073 | 4.672 | 1.00 | 30.27 | A |
| ATOM | 916 | O | GLN | 101 | 25.759 | 10.335 | 4.650 | 1.00 | 32.28 | A |
| ATOM | 917 | N | ALA | 102 | 24.564 | 12.059 | 3.805 | 1.00 | 28.45 | A |
| ATOM | 918 | H | ALA | 102 | 23.768 | 12.629 | 3.880 | 0.00 | 0.00 | A |
| ATOM | 919 | CA | ALA | 102 | 25.491 | 12.383 | 2.732 | 1.00 | 27.28 | A |
| ATOM | 920 | CB | ALA | 102 | 25.299 | 11.431 | 1.578 | 1.00 | 24.64 | A |
| ATOM | 921 | C | ALA | 102 | 25.137 | 13.802 | 2.311 | 1.00 | 27.53 | A |
| ATOM | 922 | O | ALA | 102 | 23.997 | 14.233 | 2.488 | 1.00 | 28.45 | A |
| ATOM | 923 | N | PRO | 103 | 26.077 | 14.528 | 1.689 | 1.00 | 28.94 | A |
| ATOM | 924 | CD | PRO | 103 | 25.767 | 15.838 | 1.074 | 1.00 | 27.65 | A |
| ATOM | 925 | CA | PRO | 103 | 27.440 | 14.089 | 1.364 | 1.00 | 27.92 | A |
| ATOM | 926 | CB | PRO | 103 | 27.858 | 15.084 | 0.287 | 1.00 | 27.03 | A |
| ATOM | 927 | CG | PRO | 103 | 27.110 | 16.348 | 0.674 | 1.00 | 26.85 | A |
| ATOM | 928 | C | PRO | 103 | 28.376 | 14.092 | 2.572 | 1.00 | 29.67 | A |
| ATOM | 929 | O | PRO | 103 | 27.957 | 14.400 | 3.686 | 1.00 | 32.19 | A |
| ATOM | 930 | N | LYS | 104 | 29.619 | 13.674 | 2.372 | 1.00 | 30.26 | A |
| ATOM | 931 | H | LYS | 104 | 29.889 | 13.388 | 1.476 | 0.00 | 0.00 | A |
| ATOM | 932 | CA | LYS | 104 | 30.600 | 13.647 | 3.451 | 1.00 | 30.53 | A |
| ATOM | 933 | CB | LYS | 104 | 31.806 | 12.811 | 3.028 | 1.00 | 33.62 | A |
| ATOM | 934 | CG | LYS | 104 | 32.536 | 12.137 | 4.173 | 1.00 | 40.28 | A |
| ATOM | 935 | CD | LYS | 104 | 31.664 | 11.063 | 4.806 | 1.00 | 46.67 | A |
| ATOM | 936 | CE | LYS | 104 | 32.281 | 10.471 | 6.080 | 1.00 | 51.22 | A |
| ATOM | 937 | NZ | LYS | 104 | 31.291 | 9.581 | 6.794 | 1.00 | 54.74 | A |
| ATOM | 938 | HZ1 | LYS | 104 | 31.000 | 8.822 | 6.145 | 0.00 | 0.00 | A |
| ATOM | 939 | HZ2 | LYS | 104 | 30.405 | 10.108 | 6.961 | 0.00 | 0.00 | A |
| ATOM | 940 | HZ3 | LYS | 104 | 31.671 | 9.183 | 7.674 | 0.00 | 0.00 | A |
| ATOM | 941 | C | LYS | 104 | 31.027 | 15.093 | 3.710 | 1.00 | 31.13 | A |
| ATOM | 942 | O | LYS | 104 | 31.450 | 15.796 | 2.795 | 1.00 | 31.65 | A |
| ATOM | 943 | N | MET | 105 | 30.928 | 15.539 | 4.954 | 1.00 | 30.78 | A |
| ATOM | 944 | H | MET | 105 | 30.560 | 14.950 | 5.633 | 0.00 | 0.00 | A |
| ATOM | 945 | CA | MET | 105 | 31.276 | 16.908 | 5.289 | 1.00 | 28.60 | A |
| ATOM | 946 | CB | MET | 105 | 30.381 | 17.417 | 6.414 | 1.00 | 27.58 | A |
| ATOM | 947 | CG | MET | 105 | 28.911 | 17.337 | 6.123 | 1.00 | 27.10 | A |
| ATOM | 948 | SD | MET | 105 | 28.465 | 18.378 | 4.738 | 1.00 | 29.30 | A |
| ATOM | 949 | CE | MET | 105 | 26.749 | 17.915 | 4.476 | 1.00 | 23.71 | A |
| ATOM | 950 | C | MET | 105 | 32.711 | 17.090 | 5.716 | 1.00 | 29.67 | A |
| ATOM | 951 | O | MET | 105 | 33.303 | 18.133 | 5.468 | 1.00 | 31.16 | A |
| ATOM | 952 | N | LEU | 106 | 33.280 | 16.066 | 6.334 | 1.00 | 31.18 | A |
| ATOM | 953 | H | LEU | 106 | 32.773 | 15.245 | 6.422 | 0.00 | 0.00 | A |
| ATOM | 954 | CA | LEU | 106 | 34.642 | 16.139 | 6.866 | 1.00 | 32.29 | A |
| ATOM | 955 | CB | LEU | 106 | 35.122 | 14.751 | 7.321 | 1.00 | 34.54 | A |
| ATOM | 956 | CG | LEU | 106 | 36.423 | 14.705 | 8.141 | 1.00 | 36.02 | A |
| ATOM | 957 | CD1 | LEU | 106 | 36.341 | 15.605 | 9.371 | 1.00 | 36.26 | A |
| ATOM | 958 | CD2 | LEU | 106 | 36.701 | 13.284 | 8.557 | 1.00 | 37.24 | A |
| ATOM | 959 | C | LEU | 106 | 35.725 | 16.840 | 6.041 | 1.00 | 31.14 | A |
| ATOM | 960 | O | LEU | 106 | 36.439 | 17.700 | 6.551 | 1.00 | 32.97 | A |
| ATOM | 961 | N | PRO | 107 | 35.870 | 16.485 | 4.765 | 1.00 | 29.97 | A |
| ATOM | 962 | CD | PRO | 107 | 35.222 | 15.406 | 4.003 | 1.00 | 29.86 | A |
| ATOM | 963 | CA | PRO | 107 | 36.904 | 17.145 | 3.964 | 1.00 | 30.08 | A |
| ATOM | 964 | CB | PRO | 107 | 36.880 | 16.344 | 2.663 | 1.00 | 29.81 | A |
| ATOM | 965 | CG | PRO | 107 | 35.471 | 15.831 | 2.594 | 1.00 | 28.63 | A |
| ATOM | 966 | C | PRO | 107 | 36.672 | 18.630 | 3.711 | 1.00 | 29.61 | A |
| ATOM | 967 | O | PRO | 107 | 37.590 | 19.361 | 3.330 | 1.00 | 31.63 | A |
| ATOM | 968 | N | HIS | 108 | 35.444 | 19.075 | 3.917 | 1.00 | 29.45 | A |
| ATOM | 969 | H | HIS | 108 | 34.766 | 18.465 | 4.273 | 0.00 | 0.00 | A |
| ATOM | 970 | CA | HIS | 108 | 35.085 | 20.468 | 3.685 | 1.00 | 28.69 | A |
| ATOM | 971 | CB | HIS | 108 | 33.712 | 20.512 | 3.039 | 1.00 | 28.22 | A |
| ATOM | 972 | CG | HIS | 108 | 33.606 | 19.661 | 1.820 | 1.00 | 27.30 | A |
| ATOM | 973 | CD2 | HIS | 108 | 33.047 | 18.446 | 1.630 | 1.00 | 26.75 | A |
| ATOM | 974 | ND1 | HIS | 108 | 34.150 | 20.029 | 0.608 | 1.00 | 28.84 | A |
| ATOM | 975 | HD1 | HIS | 108 | 34.564 | 20.895 | 0.404 | 0.00 | 0.00 | A |
| ATOM | 976 | CE1 | HIS | 108 | 33.930 | 19.073 | −0.279 | 1.00 | 27.04 | A |
| ATOM | 977 | NE2 | HIS | 108 | 33.262 | 18.102 | 0.318 | 1.00 | 30.85 | A |
| ATOM | 978 | HE2 | HIS | 108 | 32.935 | 17.272 | −0.106 | 0.00 | 0.00 | A |
| ATOM | 979 | C | HIS | 108 | 35.083 | 21.321 | 4.944 | 1.00 | 29.30 | A |
| ATOM | 980 | O | HIS | 108 | 35.004 | 22.551 | 4.887 | 1.00 | 30.33 | A |
| ATOM | 981 | N | ILE | 109 | 35.195 | 20.674 | 6.089 | 1.00 | 29.22 | A |
| ATOM | 982 | H | ILE | 109 | 35.302 | 19.699 | 6.100 | 0.00 | 0.00 | A |
| ATOM | 983 | CA | ILE | 109 | 35.176 | 21.394 | 7.338 | 1.00 | 28.21 | A |
| ATOM | 984 | CB | ILE | 109 | 35.036 | 20.402 | 8.496 | 1.00 | 26.19 | A |
| ATOM | 985 | CG2 | ILE | 109 | 35.447 | 21.037 | 9.813 | 1.00 | 23.27 | A |
| ATOM | 986 | CG1 | ILE | 109 | 33.582 | 19.893 | 8.481 | 1.00 | 25.41 | A |
| ATOM | 987 | CD1 | ILE | 109 | 33.294 | 18.679 | 9.316 | 1.00 | 22.28 | A |
| ATOM | 988 | C | ILE | 109 | 36.260 | 22.470 | 7.513 | 1.00 | 29.56 | A |
| ATOM | 989 | O | ILE | 109 | 35.956 | 23.576 | 7.959 | 1.00 | 32.98 | A |
| ATOM | 990 | N | PRO | 110 | 37.523 | 22.190 | 7.132 | 1.00 | 29.83 | A |
| ATOM | 991 | CD | PRO | 110 | 38.070 | 20.887 | 6.701 | 1.00 | 30.02 | A |
| ATOM | 992 | CA | PRO | 110 | 38.598 | 23.191 | 7.266 | 1.00 | 28.97 | A |
| ATOM | 993 | CB | PRO | 110 | 39.770 | 22.510 | 6.578 | 1.00 | 28.55 | A |
| ATOM | 994 | CG | PRO | 110 | 39.553 | 21.063 | 6.913 | 1.00 | 28.58 | A |
| ATOM | 995 | C | PRO | 110 | 38.258 | 24.516 | 6.568 | 1.00 | 29.16 | A |
| ATOM | 996 | O | PRO | 110 | 38.448 | 25.600 | 7.131 | 1.00 | 28.85 | A |
| ATOM | 997 | N | GLN | 111 | 37.751 | 24.418 | 5.340 | 1.00 | 29.71 | A |
| ATOM | 998 | H | GLN | 111 | 37.631 | 23.530 | 4.946 | 0.00 | 0.00 | A |
| ATOM | 999 | CA | GLN | 111 | 37.367 | 25.598 | 4.572 | 1.00 | 29.62 | A |
| ATOM | 1000 | CB | GLN | 111 | 37.061 | 25.231 | 3.124 | 1.00 | 27.80 | A |
| ATOM | 1001 | CG | GLN | 111 | 36.829 | 26.425 | 2.215 | 1.00 | 27.44 | A |
| ATOM | 1002 | CD | GLN | 111 | 37.976 | 27.408 | 2.232 | 1.00 | 28.40 | A |
| ATOM | 1003 | OE1 | GLN | 111 | 37.772 | 28.603 | 2.394 | 1.00 | 33.05 | A |
| ATOM | 1004 | NE2 | GLN | 111 | 39.188 | 26.911 | 2.073 | 1.00 | 27.65 | A |
| ATOM | 1005 | HE21 | GLN | 111 | 39.237 | 25.944 | 1.965 | 0.00 | 0.00 | A |
| ATOM | 1006 | HE22 | GLN | 111 | 39.947 | 27.539 | 2.085 | 0.00 | 0.00 | A |
| ATOM | 1007 | C | GLN | 111 | 36.167 | 26.279 | 5.220 | 1.00 | 30.70 | A |
| ATOM | 1008 | O | GLN | 111 | 36.083 | 27.508 | 5.226 | 1.00 | 32.19 | A |
| ATOM | 1009 | N | MET | 112 | 35.235 | 25.488 | 5.753 | 1.00 | 30.56 | A |
| ATOM | 1010 | H | MET | 112 | 35.308 | 24.515 | 5.671 | 0.00 | 0.00 | A |
| ATOM | 1011 | CA | MET | 112 | 34.073 | 26.048 | 6.440 | 1.00 | 28.68 | A |
| ATOM | 1012 | CB | MET | 112 | 33.182 | 24.953 | 7.008 | 1.00 | 25.74 | A |
| ATOM | 1013 | CG | MET | 112 | 32.295 | 24.285 | 6.012 | 1.00 | 24.06 | A |
| ATOM | 1014 | SD | MET | 112 | 31.278 | 23.056 | 6.809 | 1.00 | 25.13 | A |
| ATOM | 1015 | CE | MET | 112 | 31.057 | 21.944 | 5.476 | 1.00 | 22.48 | A |
| ATOM | 1016 | C | MET | 112 | 34.600 | 26.879 | 7.601 | 1.00 | 29.74 | A |
| ATOM | 1017 | O | MET | 112 | 34.211 | 28.036 | 7.774 | 1.00 | 32.59 | A |
| ATOM | 1018 | N | ARG | 113 | 35.533 | 26.313 | 8.362 | 1.00 | 28.20 | A |
| ATOM | 1019 | H | ARG | 113 | 35.841 | 25.417 | 8.136 | 0.00 | 0.00 | A |
| ATOM | 1020 | CA | ARG | 113 | 36.097 | 27.016 | 9.508 | 1.00 | 27.51 | A |
| ATOM | 1021 | CB | ARG | 113 | 37.079 | 26.129 | 10.251 | 1.00 | 25.96 | A |
| ATOM | 1022 | CG | ARG | 113 | 36.420 | 24.948 | 10.908 | 1.00 | 26.78 | A |
| ATOM | 1023 | CD | ARG | 113 | 37.437 | 24.099 | 11.610 | 1.00 | 27.65 | A |
| ATOM | 1024 | NE | ARG | 113 | 37.888 | 24.712 | 12.850 | 1.00 | 29.67 | A |
| ATOM | 1025 | HE | ARG | 113 | 37.257 | 25.329 | 13.295 | 0.00 | 0.00 | A |
| ATOM | 1026 | CZ | ARG | 113 | 39.071 | 24.484 | 13.406 | 1.00 | 29.03 | A |
| ATOM | 1027 | NH1 | ARG | 113 | 39.391 | 25.075 | 14.553 | 1.00 | 29.15 | A |
| ATOM | 1028 | HH11 | ARG | 113 | 38.716 | 25.702 | 14.978 | 0.00 | 0.00 | A |
| ATOM | 1029 | HH12 | ARG | 113 | 40.242 | 24.942 | 15.069 | 0.00 | 0.00 | A |
| ATOM | 1030 | NH2 | ARG | 113 | 39.949 | 23.707 | 12.783 | 1.00 | 30.87 | A |
| ATOM | 1031 | HH21 | ARG | 113 | 39.714 | 23.303 | 11.899 | 0.00 | 0.00 | A |
| ATOM | 1032 | HH22 | ARG | 113 | 40.844 | 23.520 | 13.187 | 0.00 | 0.00 | A |
| ATOM | 1033 | C | ARG | 113 | 36.769 | 28.309 | 9.099 | 1.00 | 28.55 | A |
| ATOM | 1034 | O | ARG | 113 | 36.681 | 29.310 | 9.805 | 1.00 | 30.43 | A |
| ATOM | 1035 | N | VAL | 114 | 37.433 | 28.287 | 7.951 | 1.00 | 27.89 | A |
| ATOM | 1036 | H | VAL | 114 | 37.479 | 27.449 | 7.445 | 0.00 | 0.00 | A |
| ATOM | 1037 | CA | VAL | 114 | 38.107 | 29.463 | 7.438 | 1.00 | 25.46 | A |
| ATOM | 1038 | CB | VAL | 114 | 38.859 | 29.128 | 6.150 | 1.00 | 25.17 | A |
| ATOM | 1039 | CG1 | VAL | 114 | 39.298 | 30.393 | 5.455 | 1.00 | 21.86 | A |
| ATOM | 1040 | CG2 | VAL | 114 | 40.049 | 28.238 | 6.465 | 1.00 | 21.55 | A |
| ATOM | 1041 | C | VAL | 114 | 37.100 | 30.568 | 7.161 | 1.00 | 27.81 | A |
| ATOM | 1042 | O | VAL | 114 | 37.268 | 31.708 | 7.611 | 1.00 | 29.66 | A |
| ATOM | 1043 | N | PHE | 115 | 36.037 | 30.215 | 6.447 | 1.00 | 27.62 | A |
| ATOM | 1044 | H | PHE | 115 | 35.952 | 29.285 | 6.140 | 0.00 | 0.00 | A |
| ATOM | 1045 | CA | PHE | 115 | 34.991 | 31.165 | 6.105 | 1.00 | 27.99 | A |
| ATOM | 1046 | CB | PHE | 115 | 33.941 | 30.490 | 5.233 | 1.00 | 26.10 | A |
| ATOM | 1047 | CG | PHE | 115 | 34.356 | 30.306 | 3.804 | 1.00 | 26.22 | A |
| ATOM | 1048 | CD1 | PHE | 115 | 33.760 | 29.322 | 3.019 | 1.00 | 26.25 | A |
| ATOM | 1049 | CD2 | PHE | 115 | 35.279 | 31.160 | 3.213 | 1.00 | 25.63 | A |
| ATOM | 1050 | CE1 | PHE | 115 | 34.069 | 29.198 | 1.664 | 1.00 | 25.44 | A |
| ATOM | 1051 | CE2 | PHE | 115 | 35.590 | 31.040 | 1.860 | 1.00 | 27.36 | A |
| ATOM | 1052 | CZ | PHE | 115 | 34.980 | 30.056 | 1.086 | 1.00 | 25.73 | A |
| ATOM | 1053 | C | PHE | 115 | 34.322 | 31.752 | 7.341 | 1.00 | 29.79 | A |
| ATOM | 1054 | O | PHE | 115 | 34.224 | 32.969 | 7.477 | 1.00 | 32.99 | A |
| ATOM | 1055 | N | ILE | 116 | 33.877 | 30.883 | 8.245 | 1.00 | 30.43 | A |
| ATOM | 1056 | H | ILE | 116 | 34.001 | 29.927 | 8.068 | 0.00 | 0.00 | A |
| ATOM | 1057 | CA | ILE | 116 | 33.202 | 31.304 | 9.473 | 1.00 | 29.53 | A |
| ATOM | 1058 | CB | ILE | 116 | 32.685 | 30.075 | 10.290 | 1.00 | 29.75 | A |
| ATOM | 1059 | CG2 | ILE | 116 | 32.059 | 30.529 | 11.616 | 1.00 | 29.66 | A |
| ATOM | 1060 | CG1 | ILE | 116 | 31.650 | 29.298 | 9.466 | 1.00 | 28.02 | A |
| ATOM | 1061 | CD1 | ILE | 116 | 31.248 | 27.954 | 10.040 | 1.00 | 25.69 | A |
| ATOM | 1062 | C | ILE | 116 | 34.094 | 32.176 | 10.347 | 1.00 | 29.27 | A |
| ATOM | 1063 | O | ILE | 116 | 33.653 | 33.209 | 10.844 | 1.00 | 30.15 | A |
| ATOM | 1064 | N | ALA | 117 | 35.347 | 31.771 | 10.525 | 1.00 | 29.28 | A |
| ATOM | 1065 | H | ALA | 117 | 35.659 | 30.943 | 10.106 | 0.00 | 0.00 | A |
| ATOM | 1066 | CA | ALA | 117 | 36.288 | 32.535 | 11.341 | 1.00 | 29.60 | A |
| ATOM | 1067 | CB | ALA | 117 | 37.629 | 31.817 | 11.424 | 1.00 | 28.13 | A |
| ATOM | 1068 | C | ALA | 117 | 36.455 | 33.927 | 10.741 | 1.00 | 31.57 | A |
| ATOM | 1069 | O | ALA | 117 | 36.570 | 34.915 | 11.459 | 1.00 | 33.05 | A |
| ATOM | 1070 | N | GLU | 118 | 36.453 | 34.008 | 9.417 | 1.00 | 33.56 | A |
| ATOM | 1071 | H | GLU | 118 | 36.403 | 33.194 | 8.871 | 0.00 | 0.00 | A |
| ATOM | 1072 | CA | GLU | 118 | 36.565 | 35.293 | 8.747 | 1.00 | 34.27 | A |
| ATOM | 1073 | CB | GLU | 118 | 36.718 | 35.116 | 7.253 | 1.00 | 37.70 | A |
| ATOM | 1074 | CG | GLU | 118 | 38.110 | 34.785 | 6.808 | 1.00 | 46.36 | A |
| ATOM | 1075 | CD | GLU | 118 | 38.209 | 34.740 | 5.298 | 1.00 | 53.12 | A |
| ATOM | 1076 | OE1 | GLU | 118 | 39.250 | 34.244 | 4.806 | 1.00 | 55.78 | A |
| ATOM | 1077 | OE2 | GLU | 118 | 37.246 | 35.193 | 4.607 | 1.00 | 53.25 | A |
| ATOM | 1078 | C | GLU | 118 | 35.321 | 36.113 | 8.987 | 1.00 | 33.52 | A |
| ATOM | 1079 | O | GLU | 118 | 35.406 | 37.259 | 9.407 | 1.00 | 33.80 | A |
| ATOM | 1080 | N | ASP | 119 | 34.163 | 35.524 | 8.710 | 1.00 | 33.13 | A |
| ATOM | 1081 | H | ASP | 119 | 34.142 | 34.613 | 8.361 | 0.00 | 0.00 | A |
| ATOM | 1082 | CA | ASP | 119 | 32.896 | 36.215 | 8.890 | 1.00 | 32.45 | A |
| ATOM | 1083 | CB | ASP | 119 | 31.731 | 35.325 | 8.467 | 1.00 | 31.59 | A |
| ATOM | 1084 | CG | ASP | 119 | 31.714 | 35.049 | 6.979 | 1.00 | 33.03 | A |
| ATOM | 1085 | OD1 | ASP | 119 | 30.989 | 34.126 | 6.568 | 1.00 | 34.45 | A |
| ATOM | 1086 | OD2 | ASP | 119 | 32.411 | 35.743 | 6.206 | 1.00 | 33.73 | A |
| ATOM | 1087 | C | ASP | 119 | 32.683 | 36.723 | 10.311 | 1.00 | 32.57 | A |
| ATOM | 1088 | O | ASP | 119 | 32.143 | 37.812 | 10.498 | 1.00 | 34.32 | A |
| ATOM | 1089 | N | LEU | 120 | 33.130 | 35.954 | 11.304 | 1.00 | 31.94 | A |
| ATOM | 1090 | H | LEU | 120 | 33.554 | 35.103 | 11.072 | 0.00 | 0.00 | A |
| ATOM | 1091 | CA | LEU | 120 | 32.969 | 36.330 | 12.710 | 1.00 | 31.05 | A |
| ATOM | 1092 | CB | LEU | 120 | 32.753 | 35.090 | 13.584 | 1.00 | 26.23 | A |
| ATOM | 1093 | CG | LEU | 120 | 31.541 | 34.234 | 13.214 | 1.00 | 24.54 | A |
| ATOM | 1094 | CD1 | LEU | 120 | 31.402 | 33.091 | 14.197 | 1.00 | 22.21 | A |
| ATOM | 1095 | CD2 | LEU | 120 | 30.291 | 35.094 | 13.205 | 1.00 | 19.98 | A |
| ATOM | 1096 | C | LEU | 120 | 34.154 | 37.123 | 13.233 | 1.00 | 32.71 | A |
| ATOM | 1097 | O | LEU | 120 | 34.180 | 37.537 | 14.399 | 1.00 | 34.84 | A |
| ATOM | 1098 | N | GLY | 121 | 35.151 | 37.302 | 12.378 | 1.00 | 33.55 | A |
| ATOM | 1099 | H | GLY | 121 | 35.107 | 36.918 | 11.478 | 0.00 | 0.00 | A |
| ATOM | 1100 | CA | GLY | 121 | 36.336 | 38.048 | 12.754 | 1.00 | 34.58 | A |
| ATOM | 1101 | C | GLY | 121 | 37.126 | 37.430 | 13.886 | 1.00 | 35.65 | A |
| ATOM | 1102 | O | GLY | 121 | 37.713 | 38.153 | 14.692 | 1.00 | 39.09 | A |
| ATOM | 1103 | N | CYS | 122 | 37.199 | 36.104 | 13.925 | 1.00 | 36.09 | A |
| ATOM | 1104 | H | CYS | 122 | 36.809 | 35.560 | 13.215 | 0.00 | 0.00 | A |
| ATOM | 1105 | CA | CYS | 122 | 37.919 | 35.429 | 14.999 | 1.00 | 36.68 | A |
| ATOM | 1106 | CB | CYS | 122 | 36.927 | 34.664 | 15.882 | 1.00 | 34.82 | A |
| ATOM | 1107 | SG | CYS | 122 | 36.048 | 33.314 | 15.043 | 1.00 | 31.16 | A |
| ATOM | 1108 | C | CYS | 122 | 38.999 | 34.472 | 14.512 | 1.00 | 38.35 | A |
| ATOM | 1109 | O | CYS | 122 | 39.282 | 34.377 | 13.316 | 1.00 | 37.98 | A |
| ATOM | 1110 | N | HIS | 123 | 39.631 | 33.799 | 15.466 | 1.00 | 41.36 | A |
| ATOM | 1111 | H | HIS | 123 | 39.352 | 33.910 | 16.402 | 0.00 | 0.00 | A |
| ATOM | 1112 | CA | HIS | 123 | 40.647 | 32.816 | 15.158 | 1.00 | 45.48 | A |
| ATOM | 1113 | CB | HIS | 123 | 41.457 | 32.466 | 16.396 | 1.00 | 54.49 | A |
| ATOM | 1114 | CG | HIS | 123 | 42.176 | 33.622 | 17.000 | 1.00 | 67.14 | A |
| ATOM | 1115 | CD2 | HIS | 123 | 41.838 | 34.452 | 18.017 | 1.00 | 71.87 | A |
| ATOM | 1116 | ND1 | HIS | 123 | 43.424 | 34.027 | 16.572 | 1.00 | 72.28 | A |
| ATOM | 1117 | HD1 | HIS | 123 | 43.941 | 33.587 | 15.858 | 0.00 | 0.00 | A |
| ATOM | 1118 | CE1 | HIS | 123 | 43.823 | 35.057 | 17.299 | 1.00 | 74.82 | A |
| ATOM | 1119 | NE2 | HIS | 123 | 42.879 | 35.333 | 18.182 | 1.00 | 76.41 | A |
| ATOM | 1120 | HE2 | HIS | 123 | 42.909 | 36.046 | 18.858 | 0.00 | 0.00 | A |
| ATOM | 1121 | C | HIS | 123 | 39.887 | 31.567 | 14.772 | 1.00 | 44.42 | A |
| ATOM | 1122 | O | HIS | 123 | 38.792 | 31.315 | 15.270 | 1.00 | 44.12 | A |
| ATOM | 1123 | N | MET | 124 | 40.496 | 30.747 | 13.936 | 1.00 | 43.48 | A |
| ATOM | 1124 | H | MET | 124 | 41.379 | 30.983 | 13.577 | 0.00 | 0.00 | A |
| ATOM | 1125 | CA | MET | 124 | 39.864 | 29.514 | 13.526 | 1.00 | 42.01 | A |
| ATOM | 1126 | CB | MET | 124 | 40.741 | 28.785 | 12.514 | 1.00 | 42.54 | A |
| ATOM | 1127 | CG | MET | 124 | 40.093 | 28.589 | 11.174 | 1.00 | 45.00 | A |
| ATOM | 1128 | SD | MET | 124 | 41.168 | 27.667 | 10.083 | 1.00 | 51.02 | A |
| ATOM | 1129 | CE | MET | 124 | 40.616 | 25.978 | 10.354 | 1.00 | 49.02 | A |
| ATOM | 1130 | C | MET | 124 | 39.655 | 28.628 | 14.746 | 1.00 | 41.21 | A |
| ATOM | 1131 | O | MET | 124 | 38.763 | 27.788 | 14.748 | 1.00 | 42.45 | A |
| ATOM | 1132 | N | ASP | 125 | 40.461 | 28.814 | 15.788 | 1.00 | 39.83 | A |
| ATOM | 1133 | H | ASP | 125 | 41.159 | 29.498 | 15.781 | 0.00 | 0.00 | A |
| ATOM | 1134 | CA | ASP | 125 | 40.326 | 27.980 | 16.977 | 1.00 | 40.59 | A |
| ATOM | 1135 | CB | ASP | 125 | 41.552 | 28.079 | 17.891 | 1.00 | 47.04 | A |
| ATOM | 1136 | CG | ASP | 125 | 41.657 | 26.887 | 18.852 | 1.00 | 53.30 | A |
| ATOM | 1137 | OD1 | ASP | 125 | 41.882 | 25.748 | 18.373 | 1.00 | 58.69 | A |
| ATOM | 1138 | OD2 | ASP | 125 | 41.495 | 27.062 | 20.083 | 1.00 | 55.37 | A |
| ATOM | 1139 | C | ASP | 125 | 39.065 | 28.275 | 17.768 | 1.00 | 37.95 | A |
| ATOM | 1140 | O | ASP | 125 | 38.680 | 27.511 | 18.651 | 1.00 | 36.98 | A |
| ATOM | 1141 | N | ASP | 126 | 38.407 | 29.375 | 17.444 | 1.00 | 35.17 | A |
| ATOM | 1142 | H | ASP | 126 | 38.731 | 29.987 | 16.755 | 0.00 | 0.00 | A |
| ATOM | 1143 | CA | ASP | 126 | 37.188 | 29.724 | 18.139 | 1.00 | 34.06 | A |
| ATOM | 1144 | CB | ASP | 126 | 37.083 | 31.246 | 18.292 | 1.00 | 35.68 | A |
| ATOM | 1145 | CG | ASP | 126 | 38.160 | 31.816 | 19.212 | 1.00 | 40.48 | A |
| ATOM | 1146 | OD1 | ASP | 126 | 38.586 | 32.973 | 19.002 | 1.00 | 47.60 | A |
| ATOM | 1147 | OD2 | ASP | 126 | 38.612 | 31.104 | 20.140 | 1.00 | 44.86 | A |
| ATOM | 1148 | C | ASP | 126 | 35.991 | 29.152 | 17.393 | 1.00 | 32.58 | A |
| ATOM | 1149 | O | ASP | 126 | 34.847 | 29.337 | 17.801 | 1.00 | 34.85 | A |
| ATOM | 1150 | N | VAL | 127 | 36.260 | 28.386 | 16.343 | 1.00 | 28.49 | A |
| ATOM | 1151 | H | VAL | 127 | 37.182 | 28.195 | 16.084 | 0.00 | 0.00 | A |
| ATOM | 1152 | CA | VAL | 127 | 35.205 | 27.803 | 15.536 | 1.00 | 25.44 | A |
| ATOM | 1153 | CB | VAL | 127 | 35.190 | 28.449 | 14.158 | 1.00 | 24.68 | A |
| ATOM | 1154 | CG1 | VAL | 127 | 34.166 | 27.785 | 13.276 | 1.00 | 25.60 | A |
| ATOM | 1155 | CG2 | VAL | 127 | 34.910 | 29.924 | 14.283 | 1.00 | 22.79 | A |
| ATOM | 1156 | C | VAL | 127 | 35.394 | 26.308 | 15.345 | 1.00 | 26.08 | A |
| ATOM | 1157 | O | VAL | 127 | 36.477 | 25.852 | 14.989 | 1.00 | 25.20 | A |
| ATOM | 1158 | N | ASN | 128 | 34.335 | 25.540 | 15.564 | 1.00 | 27.39 | A |
| ATOM | 1159 | H | ASN | 128 | 33.487 | 25.925 | 15.881 | 0.00 | 0.00 | A |
| ATOM | 1160 | CA | ASN | 128 | 34.399 | 24.092 | 15.379 | 1.00 | 27.13 | A |
| ATOM | 1161 | CB | ASN | 128 | 34.446 | 23.357 | 16.727 | 1.00 | 28.57 | A |
| ATOM | 1162 | CG | ASN | 128 | 34.813 | 21.876 | 16.582 | 1.00 | 30.70 | A |
| ATOM | 1163 | OD1 | ASN | 128 | 35.965 | 21.528 | 16.298 | 1.00 | 29.65 | A |
| ATOM | 1164 | ND2 | ASN | 128 | 33.841 | 21.001 | 16.794 | 1.00 | 31.36 | A |
| ATOM | 1165 | HD21 | ASN | 128 | 32.973 | 21.369 | 17.042 | 0.00 | 0.00 | A |
| ATOM | 1166 | HD22 | ASN | 128 | 34.036 | 20.043 | 16.701 | 0.00 | 0.00 | A |
| ATOM | 1167 | C | ASN | 128 | 33.168 | 23.658 | 14.597 | 1.00 | 26.11 | A |
| ATOM | 1168 | O | ASN | 128 | 32.093 | 24.231 | 14.764 | 1.00 | 26.52 | A |
| ATOM | 1169 | N | VAL | 129 | 33.353 | 22.726 | 13.668 | 1.00 | 24.69 | A |
| ATOM | 1170 | H | VAL | 129 | 34.239 | 22.333 | 13.517 | 0.00 | 0.00 | A |
| ATOM | 1171 | CA | VAL | 129 | 32.245 | 22.195 | 12.881 | 1.00 | 23.70 | A |
| ATOM | 1172 | CB | VAL | 129 | 32.248 | 22.696 | 11.412 | 1.00 | 21.95 | A |
| ATOM | 1173 | CG1 | VAL | 129 | 31.081 | 22.096 | 10.674 | 1.00 | 18.56 | A |
| ATOM | 1174 | CG2 | VAL | 129 | 32.177 | 24.213 | 11.343 | 1.00 | 18.78 | A |
| ATOM | 1175 | C | VAL | 129 | 32.425 | 20.677 | 12.876 | 1.00 | 25.23 | A |
| ATOM | 1176 | O | VAL | 129 | 33.558 | 20.180 | 12.829 | 1.00 | 24.42 | A |
| ATOM | 1177 | N | LYS | 130 | 31.332 | 19.935 | 12.980 | 1.00 | 24.56 | A |
| ATOM | 1178 | H | LYS | 130 | 30.443 | 20.346 | 13.039 | 0.00 | 0.00 | A |
| ATOM | 1179 | CA | LYS | 130 | 31.435 | 18.484 | 12.953 | 1.00 | 25.99 | A |
| ATOM | 1180 | CB | LYS | 130 | 31.514 | 17.909 | 14.366 | 1.00 | 28.08 | A |
| ATOM | 1181 | CG | LYS | 130 | 30.219 | 17.922 | 15.142 | 1.00 | 31.65 | A |
| ATOM | 1182 | CD | LYS | 130 | 30.450 | 17.465 | 16.574 | 1.00 | 31.66 | A |
| ATOM | 1183 | CE | LYS | 130 | 31.046 | 18.568 | 17.409 | 1.00 | 29.76 | A |
| ATOM | 1184 | NZ | LYS | 130 | 30.045 | 19.659 | 17.570 | 1.00 | 27.46 | A |
| ATOM | 1185 | HZ1 | LYS | 130 | 30.516 | 20.384 | 18.157 | 0.00 | 0.00 | A |
| ATOM | 1186 | HZ2 | LYS | 130 | 29.234 | 19.351 | 18.126 | 0.00 | 0.00 | A |
| ATOM | 1187 | HZ3 | LYS | 130 | 29.784 | 20.150 | 16.699 | 0.00 | 0.00 | A |
| ATOM | 1188 | C | LYS | 130 | 30.229 | 17.952 | 12.216 | 1.00 | 26.66 | A |
| ATOM | 1189 | O | LYS | 130 | 29.338 | 18.725 | 11.859 | 1.00 | 28.90 | A |
| ATOM | 1190 | N | ALA | 131 | 30.206 | 16.651 | 11.955 | 1.00 | 26.92 | A |
| ATOM | 1191 | H | ALA | 131 | 30.952 | 16.068 | 12.246 | 0.00 | 0.00 | A |
| ATOM | 1192 | CA | ALA | 131 | 29.085 | 16.049 | 11.251 | 1.00 | 23.86 | A |
| ATOM | 1193 | CB | ALA | 131 | 29.385 | 15.967 | 9.765 | 1.00 | 22.73 | A |
| ATOM | 1194 | C | ALA | 131 | 28.783 | 14.670 | 11.807 | 1.00 | 24.68 | A |
| ATOM | 1195 | O | ALA | 131 | 29.600 | 14.085 | 12.519 | 1.00 | 23.54 | A |
| ATOM | 1196 | N | THR | 132 | 27.568 | 14.201 | 11.552 | 1.00 | 25.97 | A |
| ATOM | 1197 | H | THR | 132 | 26.919 | 14.763 | 11.067 | 0.00 | 0.00 | A |
| ATOM | 1198 | CA | THR | 132 | 27.124 | 12.877 | 11.967 | 1.00 | 26.10 | A |
| ATOM | 1199 | CB | THR | 132 | 26.697 | 12.828 | 13.452 | 1.00 | 27.03 | A |
| ATOM | 1200 | OG1 | THR | 132 | 26.503 | 11.461 | 13.837 | 1.00 | 29.47 | A |
| ATOM | 1201 | HG1 | THR | 132 | 25.649 | 11.058 | 13.613 | 0.00 | 0.00 | A |
| ATOM | 1202 | CG2 | THR | 132 | 25.387 | 13.593 | 13.684 | 1.00 | 24.88 | A |
| ATOM | 1203 | C | THR | 132 | 25.933 | 12.512 | 11.094 | 1.00 | 28.23 | A |
| ATOM | 1204 | O | THR | 132 | 25.275 | 13.390 | 10.531 | 1.00 | 30.55 | A |
| ATOM | 1205 | N | THR | 133 | 25.705 | 11.217 | 10.916 | 1.00 | 29.76 | A |
| ATOM | 1206 | H | THR | 133 | 26.260 | 10.579 | 11.401 | 0.00 | 0.00 | A |
| ATOM | 1207 | CA | THR | 133 | 24.570 | 10.739 | 10.135 | 1.00 | 29.38 | A |
| ATOM | 1208 | CB | THR | 133 | 24.924 | 9.517 | 9.240 | 1.00 | 28.88 | A |
| ATOM | 1209 | OG1 | THR | 133 | 25.172 | 8.375 | 10.064 | 1.00 | 29.30 | A |
| ATOM | 1210 | HG1 | THR | 133 | 25.836 | 8.472 | 10.766 | 0.00 | 0.00 | A |
| ATOM | 1211 | CG2 | THR | 133 | 26.143 | 9.772 | 8.381 | 1.00 | 27.35 | A |
| ATOM | 1212 | C | THR | 133 | 23.609 | 10.226 | 11.199 | 1.00 | 31.22 | A |
| ATOM | 1213 | O | THR | 133 | 23.991 | 10.081 | 12.369 | 1.00 | 29.70 | A |
| ATOM | 1214 | N | THR | 134 | 22.364 | 9.982 | 10.813 | 1.00 | 32.68 | A |
| ATOM | 1215 | H | THR | 134 | 22.032 | 10.207 | 9.922 | 0.00 | 0.00 | A |
| ATOM | 1216 | CA | THR | 134 | 21.395 | 9.431 | 11.747 | 1.00 | 32.99 | A |
| ATOM | 1217 | CB | THR | 134 | 20.061 | 10.172 | 11.671 | 1.00 | 31.58 | A |
| ATOM | 1218 | OG1 | THR | 134 | 19.680 | 10.319 | 10.300 | 1.00 | 33.34 | A |
| ATOM | 1219 | HG1 | THR | 134 | 18.723 | 10.489 | 10.297 | 0.00 | 0.00 | A |
| ATOM | 1220 | CG2 | THR | 134 | 20.191 | 11.545 | 12.304 | 1.00 | 30.28 | A |
| ATOM | 1221 | C | THR | 134 | 21.214 | 7.932 | 11.437 | 1.00 | 34.41 | A |
| ATOM | 1222 | O | THR | 134 | 20.147 | 7.360 | 11.675 | 1.00 | 36.43 | A |
| ATOM | 1223 | N | GLU | 135 | 22.267 | 7.317 | 10.887 | 1.00 | 33.19 | A |
| ATOM | 1224 | H | GLU | 135 | 23.108 | 7.802 | 10.763 | 0.00 | 0.00 | A |
| ATOM | 1225 | CA | GLU | 135 | 22.285 | 5.894 | 10.539 | 1.00 | 33.15 | A |
| ATOM | 1226 | CB | GLU | 135 | 22.377 | 5.049 | 11.814 | 1.00 | 34.19 | A |
| ATOM | 1227 | CG | GLU | 135 | 23.484 | 5.467 | 12.785 | 1.00 | 38.74 | A |
| ATOM | 1228 | CD | GLU | 135 | 24.875 | 5.037 | 12.356 | 1.00 | 42.35 | A |
| ATOM | 1229 | OE1 | GLU | 135 | 25.860 | 5.454 | 13.003 | 1.00 | 45.39 | A |
| ATOM | 1230 | OE2 | GLU | 135 | 25.003 | 4.262 | 11.393 | 1.00 | 45.66 | A |
| ATOM | 1231 | C | GLU | 135 | 21.089 | 5.432 | 9.691 | 1.00 | 32.18 | A |
| ATOM | 1232 | O | GLU | 135 | 20.420 | 4.454 | 10.019 | 1.00 | 31.74 | A |
| ATOM | 1233 | N | LYS | 136 | 20.832 | 6.133 | 8.594 | 1.00 | 31.68 | A |
| ATOM | 1234 | H | LYS | 136 | 21.418 | 6.868 | 8.369 | 0.00 | 0.00 | A |
| ATOM | 1235 | CA | LYS | 136 | 19.723 | 5.813 | 7.697 | 1.00 | 31.84 | A |
| ATOM | 1236 | CB | LYS | 136 | 19.848 | 4.390 | 7.166 | 1.00 | 33.28 | A |
| ATOM | 1237 | CG | LYS | 136 | 21.023 | 4.159 | 6.241 | 1.00 | 36.29 | A |
| ATOM | 1238 | CD | LYS | 136 | 20.787 | 4.772 | 4.882 | 1.00 | 41.84 | A |
| ATOM | 1239 | CE | LYS | 136 | 21.892 | 4.351 | 3.914 | 1.00 | 49.17 | A |
| ATOM | 1240 | NZ | LYS | 136 | 21.769 | 4.980 | 2.555 | 1.00 | 52.87 | A |
| ATOM | 1241 | HZ1 | LYS | 136 | 22.554 | 4.666 | 1.952 | 0.00 | 0.00 | A |
| ATOM | 1242 | HZ2 | LYS | 136 | 21.853 | 6.011 | 2.678 | 0.00 | 0.00 | A |
| ATOM | 1243 | HZ3 | LYS | 136 | 20.854 | 4.750 | 2.124 | 0.00 | 0.00 | A |
| ATOM | 1244 | C | LYS | 136 | 18.341 | 6.012 | 8.306 | 1.00 | 31.20 | A |
| ATOM | 1245 | O | LYS | 136 | 17.333 | 5.819 | 7.636 | 1.00 | 32.88 | A |
| ATOM | 1246 | N | LEU | 137 | 18.285 | 6.398 | 9.572 | 1.00 | 30.53 | A |
| ATOM | 1247 | H | LEU | 137 | 19.079 | 6.564 | 10.112 | 0.00 | 0.00 | A |
| ATOM | 1248 | CA | LEU | 137 | 17.009 | 6.629 | 10.228 | 1.00 | 29.13 | A |
| ATOM | 1249 | CB | LEU | 137 | 17.133 | 6.366 | 11.737 | 1.00 | 28.47 | A |
| ATOM | 1250 | CG | LEU | 137 | 17.540 | 4.959 | 12.179 | 1.00 | 25.54 | A |
| ATOM | 1251 | CD1 | LEU | 137 | 17.474 | 4.821 | 13.672 | 1.00 | 24.54 | A |
| ATOM | 1252 | CD2 | LEU | 137 | 16.594 | 3.984 | 11.558 | 1.00 | 27.70 | A |
| ATOM | 1253 | C | LEU | 137 | 16.566 | 8.073 | 9.991 | 1.00 | 29.76 | A |
| ATOM | 1254 | O | LEU | 137 | 17.403 | 8.974 | 9.870 | 1.00 | 32.16 | A |
| ATOM | 1255 | N | GLY | 138 | 15.260 | 8.285 | 9.858 | 1.00 | 28.38 | A |
| ATOM | 1256 | H | GLY | 138 | 14.676 | 7.503 | 9.868 | 0.00 | 0.00 | A |
| ATOM | 1257 | CA | GLY | 138 | 14.732 | 9.630 | 9.680 | 1.00 | 28.53 | A |
| ATOM | 1258 | C | GLY | 138 | 14.825 | 10.309 | 8.324 | 1.00 | 29.85 | A |
| ATOM | 1259 | O | GLY | 138 | 15.353 | 9.735 | 7.368 | 1.00 | 31.86 | A |
| ATOM | 1260 | N | PHE | 139 | 14.310 | 11.542 | 8.244 | 1.00 | 28.29 | A |
| ATOM | 1261 | H | PHE | 139 | 13.940 | 11.963 | 9.044 | 0.00 | 0.00 | A |
| ATOM | 1262 | CA | PHE | 139 | 14.325 | 12.298 | 6.999 | 1.00 | 27.69 | A |
| ATOM | 1263 | CB | PHE | 139 | 13.487 | 13.581 | 7.091 | 1.00 | 25.35 | A |
| ATOM | 1264 | CG | PHE | 139 | 14.103 | 14.690 | 7.911 | 1.00 | 27.13 | A |
| ATOM | 1265 | CD1 | PHE | 139 | 14.999 | 15.588 | 7.338 | 1.00 | 28.41 | A |
| ATOM | 1266 | CD2 | PHE | 139 | 13.722 | 14.896 | 9.234 | 1.00 | 25.58 | A |
| ATOM | 1267 | CE1 | PHE | 139 | 15.501 | 16.671 | 8.068 | 1.00 | 26.59 | A |
| ATOM | 1268 | CE2 | PHE | 139 | 14.220 | 15.984 | 9.972 | 1.00 | 22.77 | A |
| ATOM | 1269 | CZ | PHE | 139 | 15.109 | 16.867 | 9.383 | 1.00 | 24.67 | A |
| ATOM | 1270 | C | PHE | 139 | 15.744 | 12.570 | 6.538 | 1.00 | 27.84 | A |
| ATOM | 1271 | O | PHE | 139 | 15.989 | 12.739 | 5.351 | 1.00 | 30.40 | A |
| ATOM | 1272 | N | THR | 140 | 16.674 | 12.608 | 7.483 | 1.00 | 27.65 | A |
| ATOM | 1273 | H | THR | 140 | 16.457 | 12.516 | 8.431 | 0.00 | 0.00 | A |
| ATOM | 1274 | CA | THR | 140 | 18.087 | 12.811 | 7.171 | 1.00 | 29.27 | A |
| ATOM | 1275 | CB | THR | 140 | 18.879 | 13.272 | 8.423 | 1.00 | 26.16 | A |
| ATOM | 1276 | OG1 | THR | 140 | 18.343 | 12.611 | 9.580 | 1.00 | 32.68 | A |
| ATOM | 1277 | HG1 | THR | 140 | 18.814 | 12.953 | 10.351 | 0.00 | 0.00 | A |
| ATOM | 1278 | CG2 | THR | 140 | 18.772 | 14.777 | 8.613 | 1.00 | 21.89 | A |
| ATOM | 1279 | C | THR | 140 | 18.644 | 11.461 | 6.684 | 1.00 | 30.26 | A |
| ATOM | 1280 | O | THR | 140 | 19.348 | 11.398 | 5.673 | 1.00 | 32.42 | A |
| ATOM | 1281 | N | GLY | 141 | 18.307 | 10.389 | 7.404 | 1.00 | 30.28 | A |
| ATOM | 1282 | H | GLY | 141 | 17.752 | 10.488 | 8.205 | 0.00 | 0.00 | A |
| ATOM | 1283 | CA | GLY | 141 | 18.765 | 9.057 | 7.058 | 1.00 | 27.95 | A |
| ATOM | 1284 | C | GLY | 141 | 18.222 | 8.592 | 5.724 | 1.00 | 29.44 | A |
| ATOM | 1285 | O | GLY | 141 | 18.869 | 7.804 | 5.026 | 1.00 | 29.86 | A |
| ATOM | 1286 | N | ARG | 142 | 17.034 | 9.074 | 5.370 | 1.00 | 28.14 | A |
| ATOM | 1287 | H | ARG | 142 | 16.568 | 9.669 | 5.982 | 0.00 | 0.00 | A |
| ATOM | 1288 | CA | ARG | 142 | 16.418 | 8.720 | 4.103 | 1.00 | 27.36 | A |
| ATOM | 1289 | CB | ARG | 142 | 14.905 | 8.726 | 4.215 | 1.00 | 24.98 | A |
| ATOM | 1290 | CG | ARG | 142 | 14.387 | 7.641 | 5.131 | 1.00 | 27.95 | A |
| ATOM | 1291 | CD | ARG | 142 | 12.895 | 7.476 | 4.969 | 1.00 | 29.21 | A |
| ATOM | 1292 | NE | ARG | 142 | 12.250 | 8.757 | 5.160 | 1.00 | 29.78 | A |
| ATOM | 1293 | HE | ARG | 142 | 12.132 | 9.251 | 4.334 | 0.00 | 0.00 | A |
| ATOM | 1294 | CZ | ARG | 142 | 11.844 | 9.212 | 6.338 | 1.00 | 31.15 | A |
| ATOM | 1295 | NH1 | ARG | 142 | 11.287 | 10.412 | 6.420 | 1.00 | 30.24 | A |
| ATOM | 1296 | HH11 | ARG | 142 | 11.214 | 10.952 | 5.556 | 0.00 | 0.00 | A |
| ATOM | 1297 | HH12 | ARG | 142 | 10.948 | 10.850 | 7.237 | 0.00 | 0.00 | A |
| ATOM | 1298 | NH2 | ARG | 142 | 11.968 | 8.448 | 7.420 | 1.00 | 30.66 | A |
| ATOM | 1299 | HH21 | ARG | 142 | 12.364 | 7.522 | 7.323 | 0.00 | 0.00 | A |
| ATOM | 1300 | HH22 | ARG | 142 | 11.668 | 8.718 | 8.324 | 0.00 | 0.00 | A |
| ATOM | 1301 | C | ARG | 142 | 16.875 | 9.656 | 2.994 | 1.00 | 29.02 | A |
| ATOM | 1302 | O | ARG | 142 | 16.433 | 9.552 | 1.854 | 1.00 | 32.70 | A |
| ATOM | 1303 | N | GLY | 143 | 17.763 | 10.578 | 3.330 | 1.00 | 28.13 | A |
| ATOM | 1304 | H | GLY | 143 | 18.087 | 10.657 | 4.250 | 0.00 | 0.00 | A |
| ATOM | 1305 | CA | GLY | 143 | 18.276 | 11.490 | 2.339 | 1.00 | 24.87 | A |
| ATOM | 1306 | C | GLY | 143 | 17.283 | 12.521 | 1.868 | 1.00 | 26.21 | A |
| ATOM | 1307 | O | GLY | 143 | 17.435 | 13.040 | 0.767 | 1.00 | 29.77 | A |
| ATOM | 1308 | N | GLU | 144 | 16.294 | 12.844 | 2.691 | 1.00 | 25.32 | A |
| ATOM | 1309 | H | GLU | 144 | 16.219 | 12.395 | 3.551 | 0.00 | 0.00 | A |
| ATOM | 1310 | CA | GLU | 144 | 15.295 | 13.839 | 2.326 | 1.00 | 23.67 | A |
| ATOM | 1311 | CB | GLU | 144 | 14.001 | 13.573 | 3.069 | 1.00 | 23.43 | A |
| ATOM | 1312 | CG | GLU | 144 | 13.402 | 12.234 | 2.709 | 1.00 | 26.15 | A |
| ATOM | 1313 | CD | GLU | 144 | 12.232 | 11.840 | 3.581 | 1.00 | 30.70 | A |
| ATOM | 1314 | OE1 | GLU | 144 | 11.706 | 10.728 | 3.372 | 1.00 | 31.13 | A |
| ATOM | 1315 | OE2 | GLU | 144 | 11.824 | 12.623 | 4.473 | 1.00 | 32.72 | A |
| ATOM | 1316 | C | GLU | 144 | 15.764 | 15.257 | 2.592 | 1.00 | 24.68 | A |
| ATOM | 1317 | O | GLU | 144 | 15.230 | 16.208 | 2.027 | 1.00 | 26.50 | A |
| ATOM | 1318 | N | GLY | 145 | 16.768 | 15.413 | 3.441 | 1.00 | 23.89 | A |
| ATOM | 1319 | H | GLY | 145 | 17.192 | 14.650 | 3.890 | 0.00 | 0.00 | A |
| ATOM | 1320 | CA | GLY | 145 | 17.254 | 16.745 | 3.730 | 1.00 | 24.63 | A |
| ATOM | 1321 | C | GLY | 145 | 18.433 | 16.725 | 4.673 | 1.00 | 26.68 | A |
| ATOM | 1322 | O | GLY | 145 | 18.916 | 15.654 | 5.042 | 1.00 | 29.22 | A |
| ATOM | 1323 | N | ILE | 146 | 18.912 | 17.908 | 5.043 | 1.00 | 26.69 | A |
| ATOM | 1324 | H | ILE | 146 | 18.474 | 18.726 | 4.720 | 0.00 | 0.00 | A |
| ATOM | 1325 | CA | ILE | 146 | 20.043 | 18.043 | 5.955 | 1.00 | 26.50 | A |
| ATOM | 1326 | CB | ILE | 146 | 21.264 | 18.733 | 5.275 | 1.00 | 25.26 | A |
| ATOM | 1327 | CG2 | ILE | 146 | 22.370 | 18.969 | 6.276 | 1.00 | 27.32 | A |
| ATOM | 1328 | CG1 | ILE | 146 | 21.823 | 17.858 | 4.159 | 1.00 | 25.91 | A |
| ATOM | 1329 | CD1 | ILE | 146 | 23.050 | 18.446 | 3.487 | 1.00 | 26.47 | A |
| ATOM | 1330 | C | ILE | 146 | 19.573 | 18.903 | 7.118 | 1.00 | 26.22 | A |
| ATOM | 1331 | O | ILE | 146 | 18.806 | 19.846 | 6.933 | 1.00 | 27.98 | A |
| ATOM | 1332 | N | ALA | 147 | 19.992 | 18.549 | 8.320 | 1.00 | 25.37 | A |
| ATOM | 1333 | H | ALA | 147 | 20.605 | 17.786 | 8.415 | 0.00 | 0.00 | A |
| ATOM | 1334 | CA | ALA | 147 | 19.625 | 19.301 | 9.502 | 1.00 | 23.69 | A |
| ATOM | 1335 | CB | ALA | 147 | 18.970 | 18.386 | 10.505 | 1.00 | 21.96 | A |
| ATOM | 1336 | C | ALA | 147 | 20.939 | 19.810 | 10.047 | 1.00 | 24.10 | A |
| ATOM | 1337 | O | ALA | 147 | 22.002 | 19.381 | 9.597 | 1.00 | 26.14 | A |
| ATOM | 1338 | N | CYS | 148 | 20.889 | 20.744 | 10.979 | 1.00 | 24.29 | A |
| ATOM | 1339 | H | CYS | 148 | 20.033 | 21.136 | 11.260 | 0.00 | 0.00 | A |
| ATOM | 1340 | CA | CYS | 148 | 22.116 | 21.242 | 11.582 | 1.00 | 25.66 | A |
| ATOM | 1341 | CB | CYS | 148 | 22.841 | 22.206 | 10.647 | 1.00 | 26.89 | A |
| ATOM | 1342 | SG | CYS | 148 | 24.468 | 22.718 | 11.245 | 1.00 | 34.06 | A |
| ATOM | 1343 | C | CYS | 148 | 21.807 | 21.918 | 12.902 | 1.00 | 25.93 | A |
| ATOM | 1344 | O | CYS | 148 | 20.756 | 22.557 | 13.051 | 1.00 | 26.97 | A |
| ATOM | 1345 | N | GLU | 149 | 22.676 | 21.700 | 13.879 | 1.00 | 25.06 | A |
| ATOM | 1346 | H | GLU | 149 | 23.461 | 21.141 | 13.726 | 0.00 | 0.00 | A |
| ATOM | 1347 | CA | GLU | 149 | 22.524 | 22.303 | 15.194 | 1.00 | 26.90 | A |
| ATOM | 1348 | CB | GLU | 149 | 22.396 | 21.246 | 16.265 | 1.00 | 28.23 | A |
| ATOM | 1349 | CG | GLU | 149 | 21.152 | 20.456 | 16.177 | 1.00 | 33.91 | A |
| ATOM | 1350 | CD | GLU | 149 | 20.684 | 20.056 | 17.530 | 1.00 | 35.88 | A |
| ATOM | 1351 | OE1 | GLU | 149 | 20.459 | 20.958 | 18.356 | 1.00 | 36.03 | A |
| ATOM | 1352 | OE2 | GLU | 149 | 20.591 | 18.846 | 17.774 | 1.00 | 42.55 | A |
| ATOM | 1353 | C | GLU | 149 | 23.765 | 23.093 | 15.495 | 1.00 | 27.06 | A |
| ATOM | 1354 | O | GLU | 149 | 24.850 | 22.752 | 15.010 | 1.00 | 27.63 | A |
| ATOM | 1355 | N | ALA | 150 | 23.631 | 24.104 | 16.343 | 1.00 | 25.61 | A |
| ATOM | 1356 | H | ALA | 150 | 22.751 | 24.305 | 16.727 | 0.00 | 0.00 | A |
| ATOM | 1357 | CA | ALA | 150 | 24.779 | 24.919 | 16.700 | 1.00 | 26.08 | A |
| ATOM | 1358 | CB | ALA | 150 | 25.025 | 25.985 | 15.629 | 1.00 | 24.95 | A |
| ATOM | 1359 | C | ALA | 150 | 24.593 | 25.582 | 18.044 | 1.00 | 26.80 | A |
| ATOM | 1360 | O | ALA | 150 | 23.459 | 25.830 | 18.471 | 1.00 | 26.68 | A |
| ATOM | 1361 | N | VAL | 151 | 25.708 | 25.812 | 18.732 | 1.00 | 25.85 | A |
| ATOM | 1362 | H | VAL | 151 | 26.579 | 25.542 | 18.361 | 0.00 | 0.00 | A |
| ATOM | 1363 | CA | VAL | 151 | 25.688 | 26.506 | 20.012 | 1.00 | 25.22 | A |
| ATOM | 1364 | CB | VAL | 151 | 26.000 | 25.601 | 21.213 | 1.00 | 22.61 | A |
| ATOM | 1365 | CG1 | VAL | 151 | 24.877 | 24.589 | 21.423 | 1.00 | 20.48 | A |
| ATOM | 1366 | CG2 | VAL | 151 | 27.344 | 24.947 | 21.047 | 1.00 | 18.45 | A |
| ATOM | 1367 | C | VAL | 151 | 26.748 | 27.583 | 19.915 | 1.00 | 26.00 | A |
| ATOM | 1368 | O | VAL | 151 | 27.706 | 27.436 | 19.157 | 1.00 | 27.32 | A |
| ATOM | 1369 | N | ALA | 152 | 26.556 | 28.671 | 20.652 | 1.00 | 26.18 | A |
| ATOM | 1370 | H | ALA | 152 | 25.776 | 28.719 | 21.246 | 0.00 | 0.00 | A |
| ATOM | 1371 | CA | ALA | 152 | 27.488 | 29.787 | 20.651 | 1.00 | 26.94 | A |
| ATOM | 1372 | CB | ALA | 152 | 26.992 | 30.885 | 19.733 | 1.00 | 26.41 | A |
| ATOM | 1373 | C | ALA | 152 | 27.642 | 30.333 | 22.055 | 1.00 | 28.03 | A |
| ATOM | 1374 | O | ALA | 152 | 26.744 | 30.191 | 22.883 | 1.00 | 28.91 | A |
| ATOM | 1375 | N | LEU | 153 | 28.795 | 30.935 | 22.322 | 1.00 | 29.73 | A |
| ATOM | 1376 | H | LEU | 153 | 29.482 | 30.982 | 21.624 | 0.00 | 0.00 | A |
| ATOM | 1377 | CA | LEU | 153 | 29.076 | 31.533 | 23.616 | 1.00 | 30.65 | A |
| ATOM | 1378 | CB | LEU | 153 | 30.117 | 30.713 | 24.365 | 1.00 | 31.84 | A |
| ATOM | 1379 | CG | LEU | 153 | 30.312 | 31.036 | 25.842 | 1.00 | 36.39 | A |
| ATOM | 1380 | CD1 | LEU | 153 | 30.512 | 29.749 | 26.611 | 1.00 | 38.53 | A |
| ATOM | 1381 | CD2 | LEU | 153 | 31.507 | 31.966 | 26.042 | 1.00 | 40.18 | A |
| ATOM | 1382 | C | LEU | 153 | 29.609 | 32.924 | 23.325 | 1.00 | 32.49 | A |
| ATOM | 1383 | O | LEU | 153 | 30.600 | 33.066 | 22.604 | 1.00 | 32.27 | A |
| ATOM | 1384 | N | LEU | 154 | 28.882 | 33.940 | 23.788 | 1.00 | 33.11 | A |
| ATOM | 1385 | H | LEU | 154 | 28.071 | 33.740 | 24.285 | 0.00 | 0.00 | A |
| ATOM | 1386 | CA | LEU | 154 | 29.259 | 35.338 | 23.607 | 1.00 | 31.83 | A |
| ATOM | 1387 | CB | LEU | 154 | 28.066 | 36.178 | 23.171 | 1.00 | 28.45 | A |
| ATOM | 1388 | CG | LEU | 154 | 27.485 | 35.857 | 21.805 | 1.00 | 27.49 | A |
| ATOM | 1389 | CD1 | LEU | 154 | 26.307 | 36.757 | 21.557 | 1.00 | 25.20 | A |
| ATOM | 1390 | CD2 | LEU | 154 | 28.544 | 36.035 | 20.736 | 1.00 | 27.94 | A |
| ATOM | 1391 | C | LEU | 154 | 29.793 | 35.885 | 24.911 | 1.00 | 33.13 | A |
| ATOM | 1392 | O | LEU | 154 | 29.465 | 35.390 | 25.989 | 1.00 | 32.32 | A |
| ATOM | 1393 | N | ILE | 155 | 30.592 | 36.936 | 24.810 | 1.00 | 36.54 | A |
| ATOM | 1394 | H | ILE | 155 | 30.784 | 37.313 | 23.926 | 0.00 | 0.00 | A |
| ATOM | 1395 | CA | ILE | 155 | 31.197 | 37.562 | 25.974 | 1.00 | 39.20 | A |
| ATOM | 1396 | CB | ILE | 155 | 32.707 | 37.480 | 25.871 | 1.00 | 40.33 | A |
| ATOM | 1397 | CG2 | ILE | 155 | 33.340 | 38.180 | 27.033 | 1.00 | 44.44 | A |
| ATOM | 1398 | CG1 | ILE | 155 | 33.143 | 36.022 | 25.855 | 1.00 | 40.56 | A |
| ATOM | 1399 | CD1 | ILE | 155 | 34.585 | 35.857 | 25.514 | 1.00 | 42.78 | A |
| ATOM | 1400 | C | ILE | 155 | 30.787 | 39.025 | 26.079 | 1.00 | 40.12 | A |
| ATOM | 1401 | O | ILE | 155 | 30.519 | 39.674 | 25.061 | 1.00 | 43.10 | A |
| ATOM | 1402 | N1 | CMP | 669 | 8.686 | 30.549 | 12.364 | 1.00 | 38.40 | A |
| ATOM | 1403 | C2 | CMP | 669 | 7.627 | 30.697 | 13.280 | 1.00 | 35.68 | A |
| ATOM | 1404 | N3 | CMP | 669 | 6.891 | 29.641 | 13.732 | 1.00 | 33.85 | A |
| ATOM | 1405 | C4 | CMP | 669 | 7.163 | 28.402 | 13.299 | 1.00 | 31.30 | A |
| ATOM | 1406 | C5 | CMP | 669 | 8.196 | 28.191 | 12.400 | 1.00 | 31.13 | A |
| ATOM | 1407 | C6 | CMP | 669 | 8.922 | 29.286 | 11.968 | 1.00 | 34.57 | A |
| ATOM | 1408 | O2 | CMP | 669 | 7.284 | 31.799 | 13.740 | 1.00 | 36.82 | A |
| ATOM | 1409 | N4 | CMP | 669 | 6.423 | 27.394 | 13.748 | 1.00 | 29.67 | A |
| ATOM | 1410 | C1* | CMP | 669 | 9.234 | 31.805 | 12.050 | 1.00 | 42.58 | A |
| ATOM | 1411 | C2* | CMP | 669 | 10.380 | 31.568 | 12.970 | 1.00 | 47.77 | A |
| ATOM | 1412 | O2* | CMP | 669 | 10.165 | 32.303 | 14.186 | 1.00 | 51.39 | A |
| ATOM | 1413 | C3* | CMP | 669 | 11.581 | 32.008 | 12.165 | 1.00 | 46.95 | A |
| ATOM | 1414 | C4* | CMP | 669 | 11.109 | 32.098 | 10.704 | 1.00 | 46.43 | A |
| ATOM | 1415 | O4* | CMP | 669 | 9.730 | 31.773 | 10.761 | 1.00 | 44.13 | A |
| ATOM | 1416 | O3* | CMP | 669 | 11.914 | 33.315 | 12.497 | 1.00 | 47.32 | A |
| ATOM | 1417 | C5* | CMP | 669 | 11.944 | 31.083 | 10.034 | 1.00 | 45.34 | A |
| ATOM | 1418 | O5* | CMP | 669 | 11.092 | 30.258 | 9.238 | 1.00 | 50.10 | A |
| ATOM | 1419 | PA | CMP | 669 | 11.617 | 28.833 | 8.560 | 1.00 | 50.19 | A |
| ATOM | 1420 | O1A | CMP | 669 | 10.986 | 27.655 | 9.312 | 1.00 | 52.54 | A |
| ATOM | 1421 | O2A | CMP | 669 | 11.145 | 28.834 | 7.095 | 1.00 | 52.90 | A |
| ATOM | 1422 | O3A | CMP | 669 | 13.284 | 28.723 | 8.646 | 1.00 | 55.89 | A |
| ATOM | 1423 | ZN | ZN | 300 | 17.558 | 27.745 | 6.895 | 1.00 | 36.09 | A |
| ATOM | 1424 | C4 | CDI | 421 | 16.179 | 34.225 | 4.344 | 1.00 | 47.78 | A |
| ATOM | 1425 | C3 | CDI | 421 | 16.103 | 33.048 | 5.368 | 1.00 | 48.15 | A |
| ATOM | 1426 | OB4 | CDI | 421 | 15.382 | 31.950 | 4.735 | 1.00 | 48.37 | A |
| ATOM | 1427 | PB | CDI | 421 | 15.625 | 30.460 | 4.134 | 1.00 | 50.49 | A |
| ATOM | 1428 | OB2 | CDI | 421 | 14.275 | 29.852 | 3.563 | 1.00 | 48.89 | A |
| ATOM | 1429 | OB3 | CDI | 421 | 16.756 | 30.457 | 2.987 | 1.00 | 45.72 | A |
| ATOM | 1430 | PA | CDI | 421 | 14.965 | 29.544 | 6.563 | 1.00 | 41.22 | A |
| ATOM | 1431 | OA3 | CDI | 421 | 14.553 | 30.965 | 7.209 | 1.00 | 46.68 | A |
| ATOM | 1432 | OA1 | CDI | 421 | 13.700 | 28.652 | 6.256 | 1.00 | 42.46 | A |
| ATOM | 1433 | OA2 | CDI | 421 | 15.975 | 28.721 | 7.472 | 1.00 | 36.91 | A |
| ATOM | 1434 | C1 | CDI | 421 | 15.145 | 32.203 | 7.707 | 1.00 | 47.75 | A |
| ATOM | 1435 | C2 | CDI | 421 | 15.276 | 33.377 | 6.663 | 1.00 | 47.14 | A |
| ATOM | 1436 | O1 | CDI | 421 | 15.876 | 34.454 | 7.389 | 1.00 | 50.89 | A |
| ATOM | 1437 | C5 | CDI | 421 | 17.558 | 32.653 | 5.753 | 1.00 | 46.72 | A |
| ATOM | 1438 | O2 | CDI | 421 | 14.865 | 34.645 | 3.953 | 1.00 | 48.42 | A |
| ATOM | 1439 | OB1 | CDI | 421 | 15.693 | 29.403 | 5.246 | 1.00 | 49.24 | A |
| ATOM | 1440 | OHH | SOL | 500 | 34.567 | 25.567 | 19.304 | 1.00 | 21.50 | A |
| ATOM | 1441 | H1 | SOL | 500 | 34.229 | 24.789 | 19.776 | 0.00 | 0.00 | A |
| ATOM | 1442 | H2 | SOL | 500 | 33.740 | 25.909 | 18.923 | 0.00 | 0.00 | A |
| ATOM | 1443 | OHH | SOL | 501 | 13.687 | 25.725 | 7.989 | 1.00 | 39.44 | A |
| ATOM | 1444 | H1 | SOL | 501 | 14.048 | 24.833 | 7.979 | 0.00 | 0.00 | A |
| ATOM | 1445 | H2 | SOL | 501 | 13.292 | 25.762 | 7.087 | 0.00 | 0.00 | A |
| ATOM | 1446 | OHH | SOL | 502 | 26.621 | 30.165 | 2.340 | 1.00 | 35.30 | A |
| ATOM | 1447 | H1 | SOL | 502 | 25.806 | 30.248 | 1.799 | 0.00 | 0.00 | A |
| ATOM | 1448 | H2 | SOL | 502 | 26.429 | 29.349 | 2.857 | 0.00 | 0.00 | A |
| ATOM | 1449 | OHH | SOL | 504 | 23.232 | 32.682 | 7.613 | 1.00 | 33.61 | A |
| ATOM | 1450 | H1 | SOL | 504 | 23.982 | 33.212 | 7.311 | 0.00 | 0.00 | A |
| ATOM | 1451 | H2 | SOL | 504 | 23.336 | 32.666 | 8.580 | 0.00 | 0.00 | A |
| ATOM | 1452 | OHH | SOL | 506 | 14.480 | 30.595 | 12.781 | 1.00 | 32.91 | A |
| ATOM | 1453 | H1 | SOL | 506 | 13.767 | 30.473 | 13.437 | 0.00 | 0.00 | A |
| ATOM | 1454 | H2 | SOL | 506 | 15.275 | 30.685 | 13.336 | 0.00 | 0.00 | A |
| ATOM | 1455 | OHH | SOL | 507 | 15.417 | 28.587 | 10.502 | 1.00 | 36.64 | A |
| ATOM | 1456 | H1 | SOL | 507 | 15.097 | 29.185 | 11.206 | 0.00 | 0.00 | A |
| ATOM | 1457 | H2 | SOL | 507 | 14.931 | 27.760 | 10.711 | 0.00 | 0.00 | A |
| ATOM | 1458 | OHH | SOL | 509 | 27.035 | 43.720 | 7.653 | 1.00 | 43.22 | A |
| ATOM | 1459 | H1 | SOL | 509 | 27.148 | 43.285 | 8.498 | 0.00 | 0.00 | A |
| ATOM | 1460 | H2 | SOL | 509 | 26.082 | 43.932 | 7.705 | 0.00 | 0.00 | A |
| ATOM | 1461 | OHH | SOL | 510 | 30.943 | 15.399 | −1.988 | 1.00 | 46.57 | A |
| ATOM | 1462 | H1 | SOL | 510 | 30.128 | 15.891 | −2.186 | 0.00 | 0.00 | A |
| ATOM | 1463 | H2 | SOL | 510 | 30.949 | 14.768 | −2.709 | 0.00 | 0.00 | A |
| ATOM | 1464 | OHH | SOL | 511 | 17.796 | 28.161 | 11.843 | 1.00 | 32.41 | A |
| ATOM | 1465 | H1 | SOL | 511 | 16.906 | 28.118 | 11.460 | 0.00 | 0.00 | A |
| ATOM | 1466 | H2 | SOL | 511 | 17.672 | 28.860 | 12.517 | 0.00 | 0.00 | A |
| ATOM | 1467 | OHH | SOL | 512 | 14.032 | 23.548 | 2.498 | 1.00 | 35.90 | A |
| ATOM | 1468 | H1 | SOL | 512 | 13.191 | 23.953 | 2.783 | 0.00 | 0.00 | A |
| ATOM | 1469 | H2 | SOL | 512 | 14.342 | 24.121 | 1.772 | 0.00 | 0.00 | A |
| ATOM | 1470 | OHH | SOL | 513 | 30.183 | 28.791 | −2.286 | 1.00 | 47.00 | A |
| ATOM | 1471 | H1 | SOL | 513 | 30.763 | 29.564 | −2.375 | 0.00 | 0.00 | A |
| ATOM | 1472 | H2 | SOL | 513 | 29.716 | 29.001 | −1.463 | 0.00 | 0.00 | A |
| ATOM | 1473 | OHH | SOL | 514 | 39.483 | 31.332 | 1.778 | 1.00 | 37.59 | A |
| ATOM | 1474 | H1 | SOL | 514 | 38.841 | 30.607 | 1.759 | 0.00 | 0.00 | A |
| ATOM | 1475 | H2 | SOL | 514 | 39.865 | 31.338 | 0.878 | 0.00 | 0.00 | A |
| ATOM | 1476 | OHH | SOL | 515 | 24.779 | 5.067 | 7.879 | 1.00 | 53.99 | A |
| ATOM | 1477 | H1 | SOL | 515 | 24.493 | 5.917 | 7.514 | 0.00 | 0.00 | A |
| ATOM | 1478 | H2 | SOL | 515 | 24.810 | 5.175 | 8.840 | 0.00 | 0.00 | A |
| ATOM | 1479 | OHH | SOL | 516 | 37.994 | 33.584 | 2.226 | 1.00 | 41.42 | A |
| ATOM | 1480 | H1 | SOL | 516 | 38.192 | 34.002 | 3.102 | 0.00 | 0.00 | A |
| ATOM | 1481 | H2 | SOL | 516 | 38.627 | 32.836 | 2.262 | 0.00 | 0.00 | A |
| ATOM | 1482 | OHH | SOL | 517 | 9.698 | 13.452 | 5.976 | 1.00 | 34.80 | A |
| ATOM | 1483 | H1 | SOL | 517 | 8.881 | 13.264 | 5.469 | 0.00 | 0.00 | A |
| ATOM | 1484 | H2 | SOL | 517 | 10.403 | 13.303 | 5.302 | 0.00 | 0.00 | A |
| ATOM | 1485 | OHH | SOL | 518 | 28.592 | 31.404 | 0.614 | 1.00 | 38.16 | A |
| ATOM | 1486 | H1 | SOL | 518 | 27.949 | 30.938 | 1.186 | 0.00 | 0.00 | A |
| ATOM | 1487 | H2 | SOL | 518 | 28.145 | 32.277 | 0.580 | 0.00 | 0.00 | A |
| ATOM | 1488 | OHH | SOL | 519 | 28.910 | 20.728 | −8.224 | 1.00 | 40.61 | A |
| ATOM | 1489 | H1 | SOL | 519 | 29.565 | 20.061 | −7.978 | 0.00 | 0.00 | A |
| ATOM | 1490 | H2 | SOL | 519 | 28.266 | 20.209 | −8.721 | 0.00 | 0.00 | A |
| ATOM | 1491 | OHH | SOL | 520 | 21.687 | 39.021 | 1.304 | 1.00 | 65.80 | A |
| ATOM | 1492 | H1 | SOL | 520 | 21.449 | 39.794 | 0.786 | 0.00 | 0.00 | A |
| ATOM | 1493 | H2 | SOL | 520 | 22.655 | 39.075 | 1.264 | 0.00 | 0.00 | A |
| ATOM | 1494 | OHH | SOL | 521 | 28.954 | 9.757 | 5.702 | 1.00 | 69.84 | A |
| ATOM | 1495 | H1 | SOL | 521 | 28.738 | 9.940 | 4.766 | 0.00 | 0.00 | A |
| ATOM | 1496 | H2 | SOL | 521 | 28.044 | 9.614 | 6.019 | 0.00 | 0.00 | A |
| ATOM | 1497 | OHH | SOL | 523 | 30.266 | 41.417 | 10.179 | 1.00 | 49.70 | A |
| ATOM | 1498 | H1 | SOL | 523 | 30.826 | 40.689 | 10.466 | 0.00 | 0.00 | A |
| ATOM | 1499 | H2 | SOL | 523 | 29.381 | 41.149 | 10.459 | 0.00 | 0.00 | A |
| ATOM | 1500 | OHH | SOL | 524 | 21.253 | 9.787 | 1.438 | 1.00 | 38.76 | A |
| ATOM | 1501 | H1 | SOL | 524 | 20.962 | 10.146 | 2.283 | 0.00 | 0.00 | A |
| ATOM | 1502 | H2 | SOL | 524 | 20.437 | 9.462 | 1.054 | 0.00 | 0.00 | A |
| ATOM | 1503 | OHH | SOL | 525 | 19.929 | 1.467 | 9.971 | 1.00 | 59.36 | A |
| ATOM | 1504 | H1 | SOL | 525 | 19.371 | 1.310 | 10.736 | 0.00 | 0.00 | A |
| ATOM | 1505 | H2 | SOL | 525 | 20.156 | 2.409 | 10.044 | 0.00 | 0.00 | A |
| ATOM | 1506 | OHH | SOL | 526 | 34.771 | 37.192 | 5.186 | 1.00 | 56.98 | A |
| ATOM | 1507 | H1 | SOL | 526 | 34.188 | 36.728 | 5.810 | 0.00 | 0.00 | A |
| ATOM | 1508 | H2 | SOL | 526 | 35.598 | 36.674 | 5.208 | 0.00 | 0.00 | A |
| ATOM | 1509 | OHH | SOL | 527 | 22.788 | 25.120 | −0.048 | 1.00 | 48.13 | A |
| ATOM | 1510 | H1 | SOL | 527 | 22.719 | 25.132 | 0.914 | 0.00 | 0.00 | A |
| ATOM | 1511 | H2 | SOL | 527 | 22.275 | 25.921 | −0.296 | 0.00 | 0.00 | A |
| ATOM | 1512 | OHH | SOL | 528 | 9.086 | 10.014 | 3.927 | 1.00 | 43.84 | A |
| ATOM | 1513 | H1 | SOL | 528 | 8.603 | 10.683 | 3.440 | 0.00 | 0.00 | A |
| ATOM | 1514 | H2 | SOL | 528 | 9.998 | 10.198 | 3.614 | 0.00 | 0.00 | A |
| ATOM | 1515 | OHH | SOL | 529 | 17.341 | 15.147 | 13.553 | 1.00 | 42.96 | A |
| ATOM | 1516 | H1 | SOL | 529 | 16.443 | 15.476 | 13.461 | 0.00 | 0.00 | A |
| ATOM | 1517 | H2 | SOL | 529 | 17.864 | 15.945 | 13.654 | 0.00 | 0.00 | A |
| ATOM | 1518 | OHH | SOL | 530 | 35.613 | 34.205 | 1.352 | 1.00 | 44.53 | A |
| ATOM | 1519 | H1 | SOL | 530 | 35.989 | 35.074 | 1.189 | 0.00 | 0.00 | A |
| ATOM | 1520 | H2 | SOL | 530 | 36.459 | 33.767 | 1.645 | 0.00 | 0.00 | A |
| ATOM | 1521 | OHH | SOL | 531 | 13.208 | 27.540 | 3.365 | 1.00 | 44.73 | A |
| ATOM | 1522 | H1 | SOL | 531 | 12.853 | 26.818 | 3.945 | 0.00 | 0.00 | A |
| ATOM | 1523 | H2 | SOL | 531 | 12.554 | 28.222 | 3.562 | 0.00 | 0.00 | A |
| ATOM | 1524 | OHH | SOL | 532 | 35.616 | 17.691 | 12.757 | 1.00 | 46.29 | A |
| ATOM | 1525 | H1 | SOL | 532 | 34.935 | 18.377 | 12.728 | 0.00 | 0.00 | A |
| ATOM | 1526 | H2 | SOL | 532 | 35.069 | 16.885 | 12.804 | 0.00 | 0.00 | A |
| ATOM | 1527 | OHH | SOL | 533 | 28.748 | 46.308 | 14.888 | 1.00 | 58.51 | A |
| ATOM | 1528 | H1 | SOL | 533 | 28.368 | 46.695 | 14.098 | 0.00 | 0.00 | A |
| ATOM | 1529 | H2 | SOL | 533 | 28.130 | 45.591 | 15.109 | 0.00 | 0.00 | A |
| ATOM | 1530 | OHH | SOL | 535 | 21.394 | 12.858 | 2.239 | 1.00 | 42.02 | A |
| ATOM | 1531 | H1 | SOL | 535 | 22.105 | 12.255 | 2.024 | 0.00 | 0.00 | A |
| ATOM | 1532 | H2 | SOL | 535 | 21.861 | 13.700 | 2.346 | 0.00 | 0.00 | A |
| ATOM | 1533 | OHH | SOL | 536 | 12.916 | 5.087 | 7.255 | 1.00 | 45.93 | A |
| ATOM | 1534 | H1 | SOL | 536 | 12.364 | 4.530 | 6.697 | 0.00 | 0.00 | A |
| ATOM | 1535 | H2 | SOL | 536 | 13.799 | 4.895 | 6.892 | 0.00 | 0.00 | A |
| ATOM | 1536 | OHH | SOL | 537 | 13.990 | 17.912 | −7.363 | 1.00 | 64.03 | A |
| ATOM | 1537 | H1 | SOL | 537 | 13.089 | 17.641 | −7.166 | 0.00 | 0.00 | A |
| ATOM | 1538 | H2 | SOL | 537 | 14.272 | 17.289 | −8.041 | 0.00 | 0.00 | A |
| ATOM | 1539 | OHH | SOL | 538 | 29.683 | 12.112 | −0.139 | 1.00 | 53.96 | A |
| ATOM | 1540 | H1 | SOL | 538 | 28.961 | 11.830 | −0.739 | 0.00 | 0.00 | A |
| ATOM | 1541 | H2 | SOL | 538 | 30.280 | 12.562 | −0.746 | 0.00 | 0.00 | A |
| ATOM | 1542 | OHH | SOL | 539 | 18.915 | 43.372 | 6.906 | 1.00 | 66.68 | A |
| ATOM | 1543 | H1 | SOL | 539 | 18.234 | 42.835 | 6.482 | 0.00 | 0.00 | A |
| ATOM | 1544 | H2 | SOL | 539 | 19.708 | 43.161 | 6.402 | 0.00 | 0.00 | A |
| ATOM | 1545 | OHH | SOL | 540 | 15.767 | 41.795 | 16.405 | 1.00 | 58.97 | A |
| ATOM | 1546 | H1 | SOL | 540 | 16.480 | 41.167 | 16.203 | 0.00 | 0.00 | A |
| ATOM | 1547 | H2 | SOL | 540 | 16.103 | 42.603 | 15.989 | 0.00 | 0.00 | A |
| ATOM | 1548 | OHH | SOL | 541 | 43.675 | 30.697 | 15.504 | 1.00 | 52.11 | A |
| ATOM | 1549 | H1 | SOL | 541 | 43.904 | 30.823 | 14.570 | 0.00 | 0.00 | A |
| ATOM | 1550 | H2 | SOL | 541 | 44.232 | 29.955 | 15.773 | 0.00 | 0.00 | A |
| ATOM | 1551 | OHH | SOL | 542 | 28.639 | 28.629 | −4.553 | 1.00 | 57.47 | A |
| ATOM | 1552 | H1 | SOL | 542 | 27.909 | 29.123 | −4.157 | 0.00 | 0.00 | A |
| ATOM | 1553 | H2 | SOL | 542 | 29.258 | 28.604 | −3.791 | 0.00 | 0.00 | A |
| ATOM | 1554 | OHH | SOL | 543 | 30.880 | 35.768 | 0.983 | 1.00 | 46.52 | A |
| ATOM | 1555 | H1 | SOL | 543 | 31.240 | 35.874 | 0.092 | 0.00 | 0.00 | A |
| ATOM | 1556 | H2 | SOL | 543 | 29.993 | 35.408 | 0.748 | 0.00 | 0.00 | A |
| ATOM | 1557 | OHH | SOL | 545 | 34.116 | 40.786 | 11.676 | 1.00 | 61.39 | A |
| ATOM | 1558 | H1 | SOL | 545 | 33.694 | 40.261 | 10.987 | 0.00 | 0.00 | A |
| ATOM | 1559 | H2 | SOL | 545 | 35.049 | 40.607 | 11.549 | 0.00 | 0.00 | A |
| ATOM | 1560 | OHH | SOL | 546 | 43.206 | 32.097 | 12.827 | 1.00 | 47.63 | A |
| ATOM | 1561 | H1 | SOL | 546 | 42.577 | 32.633 | 12.321 | 0.00 | 0.00 | A |
| ATOM | 1562 | H2 | SOL | 546 | 43.908 | 31.994 | 12.172 | 0.00 | 0.00 | A |
| ATOM | 1563 | OHH | SOL | 547 | 19.004 | 43.743 | 15.170 | 1.00 | 70.46 | A |
| ATOM | 1564 | H1 | SOL | 547 | 19.501 | 43.109 | 15.696 | 0.00 | 0.00 | A |
| ATOM | 1565 | H2 | SOL | 547 | 19.256 | 44.573 | 15.599 | 0.00 | 0.00 | A |
| ATOM | 1566 | OHH | SOL | 549 | 27.508 | 11.208 | −1.632 | 1.00 | 56.30 | A |
| ATOM | 1567 | H1 | SOL | 549 | 27.559 | 10.264 | −1.832 | 0.00 | 0.00 | A |
| ATOM | 1568 | H2 | SOL | 549 | 26.813 | 11.488 | −2.245 | 0.00 | 0.00 | A |
| ATOM | 1569 | OHH | SOL | 550 | 25.930 | 31.130 | −1.783 | 1.00 | 54.46 | A |
| ATOM | 1570 | H1 | SOL | 550 | 25.911 | 32.093 | −1.807 | 0.00 | 0.00 | A |
| ATOM | 1571 | H2 | SOL | 550 | 25.489 | 30.959 | −0.925 | 0.00 | 0.00 | A |
| ATOM | 1572 | OHH | SOL | 551 | 24.034 | 33.005 | −3.291 | 1.00 | 75.47 | A |
| ATOM | 1573 | H1 | SOL | 551 | 23.136 | 33.366 | −3.161 | 0.00 | 0.00 | A |
| ATOM | 1574 | H2 | SOL | 551 | 23.995 | 32.152 | −2.846 | 0.00 | 0.00 | A |
| ATOM | 1575 | OHH | SOL | 554 | 31.449 | 31.231 | 0.488 | 1.00 | 35.34 | A |
| ATOM | 1576 | H1 | SOL | 554 | 31.342 | 30.276 | 0.663 | 0.00 | 0.00 | A |
| ATOM | 1577 | H2 | SOL | 554 | 30.493 | 31.478 | 0.444 | 0.00 | 0.00 | A |
| ATOM | 1578 | OHH | SOL | 555 | 9.846 | 38.866 | 10.474 | 1.00 | 75.90 | A |
| ATOM | 1579 | H1 | SOL | 555 | 10.714 | 39.266 | 10.591 | 0.00 | 0.00 | A |
| ATOM | 1580 | H2 | SOL | 555 | 9.646 | 39.028 | 9.553 | 0.00 | 0.00 | A |
| ATOM | 1581 | OHH | SOL | 556 | 13.060 | 16.343 | −0.241 | 1.00 | 49.86 | A |
| ATOM | 1582 | H1 | SOL | 556 | 13.715 | 16.352 | 0.468 | 0.00 | 0.00 | A |
| ATOM | 1583 | H2 | SOL | 556 | 13.604 | 16.480 | −1.025 | 0.00 | 0.00 | A |
| ATOM | 1584 | OHH | SOL | 557 | 35.039 | 38.372 | 17.347 | 1.00 | 56.28 | A |
| ATOM | 1585 | H1 | SOL | 557 | 35.750 | 38.943 | 17.037 | 0.00 | 0.00 | A |
| ATOM | 1586 | H2 | SOL | 557 | 34.581 | 38.179 | 16.515 | 0.00 | 0.00 | A |
| ATOM | 1587 | OHH | SOL | 558 | 29.262 | 41.364 | 27.524 | 1.00 | 54.52 | A |
| ATOM | 1588 | H1 | SOL | 558 | 29.604 | 41.592 | 26.650 | 0.00 | 0.00 | A |
| ATOM | 1589 | H2 | SOL | 558 | 28.781 | 42.160 | 27.763 | 0.00 | 0.00 | A |
| ATOM | 1590 | OHH | SOL | 560 | 25.196 | 7.130 | 3.066 | 1.00 | 61.58 | A |
| ATOM | 1591 | H1 | SOL | 560 | 25.441 | 7.461 | 3.939 | 0.00 | 0.00 | A |
| ATOM | 1592 | H2 | SOL | 560 | 25.971 | 7.367 | 2.548 | 0.00 | 0.00 | A |
| ATOM | 1593 | OHH | SOL | 561 | 32.518 | 16.115 | −8.072 | 1.00 | 43.55 | A |
| ATOM | 1594 | H1 | SOL | 561 | 31.972 | 15.547 | −7.524 | 0.00 | 0.00 | A |
| ATOM | 1595 | H2 | SOL | 561 | 33.280 | 15.564 | −8.275 | 0.00 | 0.00 | A |
| ATOM | 1596 | OHH | SOL | 563 | 9.305 | 41.251 | 4.170 | 1.00 | 66.69 | A |
| ATOM | 1597 | H1 | SOL | 563 | 9.118 | 42.153 | 4.444 | 0.00 | 0.00 | A |
| ATOM | 1598 | H2 | SOL | 563 | 10.198 | 41.352 | 3.794 | 0.00 | 0.00 | A |
| ATOM | 1599 | OHH | SOL | 564 | 29.327 | 41.916 | 5.176 | 1.00 | 95.89 | A |
| ATOM | 1600 | H1 | SOL | 564 | 30.107 | 42.424 | 5.445 | 0.00 | 0.00 | A |
| ATOM | 1601 | H2 | SOL | 564 | 28.644 | 42.385 | 5.686 | 0.00 | 0.00 | A |
| ATOM | 1602 | OHH | SOL | 568 | 28.580 | 35.745 | 32.916 | 1.00 | 86.87 | A |
| ATOM | 1603 | H1 | SOL | 568 | 28.150 | 34.903 | 33.137 | 0.00 | 0.00 | A |
| ATOM | 1604 | H2 | SOL | 568 | 28.583 | 36.180 | 33.781 | 0.00 | 0.00 | A |
| ATOM | 1605 | OHH | SOL | 571 | 16.100 | 4.301 | 5.537 | 1.00 | 60.63 | A |
| ATOM | 1606 | H1 | SOL | 571 | 16.470 | 4.976 | 6.136 | 0.00 | 0.00 | A |
| ATOM | 1607 | H2 | SOL | 571 | 16.604 | 3.525 | 5.786 | 0.00 | 0.00 | A |
| ATOM | 1608 | OHH | SOL | 573 | 33.217 | 18.856 | −9.572 | 1.00 | 73.74 | A |
| ATOM | 1609 | H1 | SOL | 573 | 34.180 | 18.855 | −9.585 | 0.00 | 0.00 | A |
| ATOM | 1610 | H2 | SOL | 573 | 33.014 | 18.158 | −8.928 | 0.00 | 0.00 | A |
| ATOM | 1611 | OHH | SOL | 574 | 23.718 | 27.419 | −4.837 | 1.00 | 85.27 | A |
| ATOM | 1612 | H1 | SOL | 574 | 23.602 | 27.892 | −4.008 | 0.00 | 0.00 | A |
| ATOM | 1613 | H2 | SOL | 574 | 23.382 | 26.539 | −4.639 | 0.00 | 0.00 | A |
| ATOM | 1614 | OHH | SOL | 575 | 27.722 | 48.442 | 12.899 | 1.00 | 68.94 | A |
| ATOM | 1615 | H1 | SOL | 575 | 28.435 | 48.746 | 12.322 | 0.00 | 0.00 | A |
| ATOM | 1616 | H2 | SOL | 575 | 27.988 | 48.830 | 13.747 | 0.00 | 0.00 | A |
| ATOM | 1617 | OHH | SOL | 576 | 28.242 | 15.243 | −7.541 | 1.00 | 64.76 | A |
| ATOM | 1618 | H1 | SOL | 576 | 27.575 | 15.525 | −8.171 | 0.00 | 0.00 | A |
| ATOM | 1619 | H2 | SOL | 576 | 28.459 | 14.356 | −7.838 | 0.00 | 0.00 | A |
| ATOM | 1620 | OHH | SOL | 579 | 9.353 | 14.226 | 1.439 | 1.00 | 56.70 | A |
| ATOM | 1621 | H1 | SOL | 579 | 9.955 | 14.830 | 0.994 | 0.00 | 0.00 | A |
| ATOM | 1622 | H2 | SOL | 579 | 9.932 | 13.779 | 2.066 | 0.00 | 0.00 | A |
| ATOM | 1623 | OHH | SOL | 580 | 31.711 | 32.568 | −8.349 | 1.00 | 83.56 | A |
| ATOM | 1624 | H1 | SOL | 580 | 31.628 | 32.366 | −7.412 | 0.00 | 0.00 | A |
| ATOM | 1625 | H2 | SOL | 580 | 32.496 | 33.126 | −8.349 | 0.00 | 0.00 | A |
| ATOM | 1626 | OHH | SOL | 581 | 8.578 | 7.445 | 5.797 | 1.00 | 64.02 | A |
| ATOM | 1627 | H1 | SOL | 581 | 7.685 | 7.753 | 6.005 | 0.00 | 0.00 | A |
| ATOM | 1628 | H2 | SOL | 581 | 8.795 | 8.012 | 5.040 | 0.00 | 0.00 | A |
| ATOM | 1629 | OHH | SOL | 582 | 28.647 | 38.106 | −0.590 | 1.00 | 78.12 | A |
| ATOM | 1630 | H1 | SOL | 582 | 28.375 | 37.171 | −0.560 | 0.00 | 0.00 | A |
| ATOM | 1631 | H2 | SOL | 582 | 27.767 | 38.520 | −0.648 | 0.00 | 0.00 | A |
| ATOM | 1632 | OHH | SOL | 583 | 16.973 | 27.839 | 15.433 | 1.00 | 37.18 | A |
| ATOM | 1633 | H1 | SOL | 583 | 16.809 | 27.328 | 14.619 | 0.00 | 0.00 | A |
| ATOM | 1634 | H2 | SOL | 583 | 17.155 | 28.709 | 14.990 | 0.00 | 0.00 | A |
| ATOM | 1635 | OHH | SOL | 584 | 29.980 | 23.052 | −9.410 | 1.00 | 37.74 | A |
| ATOM | 1636 | H1 | SOL | 584 | 30.624 | 22.499 | −9.854 | 0.00 | 0.00 | A |
| ATOM | 1637 | H2 | SOL | 584 | 29.501 | 22.353 | −8.907 | 0.00 | 0.00 | A |
| ATOM | 1638 | OHH | SOL | 585 | 21.646 | 45.461 | 17.002 | 1.00 | 55.74 | A |
| ATOM | 1639 | H1 | SOL | 585 | 22.463 | 45.030 | 17.288 | 0.00 | 0.00 | A |
| ATOM | 1640 | H2 | SOL | 585 | 21.509 | 46.127 | 17.678 | 0.00 | 0.00 | A |
| ATOM | 1641 | OHH | SOL | 586 | 11.593 | 30.373 | 1.956 | 1.00 | 74.17 | A |
| ATOM | 1642 | H1 | SOL | 586 | 10.943 | 29.686 | 2.112 | 0.00 | 0.00 | A |
| ATOM | 1643 | H2 | SOL | 586 | 11.517 | 30.833 | 2.828 | 0.00 | 0.00 | A |
| ATOM | 1644 | OHH | SOL | 588 | 12.372 | 9.439 | 0.881 | 1.00 | 70.04 | A |
| ATOM | 1645 | H1 | SOL | 588 | 13.321 | 9.582 | 0.928 | 0.00 | 0.00 | A |
| ATOM | 1646 | H2 | SOL | 588 | 12.064 | 9.911 | 1.675 | 0.00 | 0.00 | A |
| ATOM | 1647 | OHH | SOL | 589 | 14.767 | 13.345 | −1.957 | 1.00 | 64.33 | A |
| ATOM | 1648 | H1 | SOL | 589 | 14.068 | 13.578 | −2.570 | 0.00 | 0.00 | A |
| ATOM | 1649 | H2 | SOL | 589 | 14.332 | 12.752 | −1.337 | 0.00 | 0.00 | A |
| ATOM | 1650 | OHH | SOL | 590 | 33.526 | 40.123 | 2.689 | 1.00 | 87.57 | A |
| ATOM | 1651 | H1 | SOL | 590 | 34.177 | 40.810 | 2.535 | 0.00 | 0.00 | A |
| ATOM | 1652 | H2 | SOL | 590 | 34.011 | 39.467 | 3.207 | 0.00 | 0.00 | A |
| ATOM | 1653 | OHH | SOL | 592 | 28.640 | 9.715 | 2.253 | 1.00 | 61.78 | A |
| ATOM | 1654 | H1 | SOL | 592 | 27.774 | 10.029 | 1.995 | 0.00 | 0.00 | A |
| ATOM | 1655 | H2 | SOL | 592 | 29.211 | 10.057 | 1.554 | 0.00 | 0.00 | A |
| END | | | | | | | | | | |

ANNEX 5
Coordinates of structure subop

| | | | | | | | | | | |
|---|---|---|---|---|---|---|---|---|---|---|
| ATOM | 1 | CB | MET | 1 | 29.962 | 34.223 | 29.311 | 1.00 | 52.63 | A |
| ATOM | 2 | CG | MET | 1 | 31.362 | 34.497 | 28.846 | 1.00 | 61.65 | A |
| ATOM | 3 | SD | MET | 1 | 32.459 | 33.172 | 29.304 | 1.00 | 74.65 | A |
| ATOM | 4 | CE | MET | 1 | 33.589 | 34.038 | 30.482 | 1.00 | 72.98 | A |
| ATOM | 5 | C | MET | 1 | 27.618 | 34.868 | 28.791 | 1.00 | 44.93 | A |
| ATOM | 6 | O | MET | 1 | 26.901 | 34.556 | 29.739 | 1.00 | 45.18 | A |
| ATOM | 7 | HT1 | MET | 1 | 28.723 | 35.934 | 30.942 | 0.00 | 0.00 | A |
| ATOM | 8 | HT2 | MET | 1 | 28.522 | 37.210 | 29.864 | 0.00 | 0.00 | A |
| ATOM | 9 | N | MET | 1 | 29.134 | 36.411 | 30.109 | 1.00 | 49.87 | A |
| ATOM | 10 | HT3 | MET | 1 | 30.112 | 36.694 | 30.283 | 0.00 | 0.00 | A |
| ATOM | 11 | CA | MET | 1 | 29.029 | 35.383 | 29.027 | 1.00 | 48.64 | A |
| ATOM | 12 | N | ARG | 2 | 27.228 | 34.789 | 27.522 | 1.00 | 41.63 | A |
| ATOM | 13 | H | ARG | 2 | 27.824 | 34.986 | 26.779 | 0.00 | 0.00 | A |
| ATOM | 14 | CA | ARG | 2 | 25.900 | 34.331 | 27.141 | 1.00 | 38.93 | A |
| ATOM | 15 | CB | ARG | 2 | 25.110 | 35.484 | 26.536 | 1.00 | 38.34 | A |
| ATOM | 16 | CG | ARG | 2 | 24.889 | 36.600 | 27.537 | 1.00 | 40.15 | A |
| ATOM | 17 | CD | ARG | 2 | 24.159 | 37.780 | 26.946 | 1.00 | 43.49 | A |
| ATOM | 18 | NE | ARG | 2 | 22.803 | 37.432 | 26.546 | 1.00 | 49.86 | A |
| ATOM | 19 | HE | ARG | 2 | 22.724 | 36.970 | 25.682 | 0.00 | 0.00 | A |
| ATOM | 20 | CZ | ARG | 2 | 21.702 | 37.669 | 27.261 | 1.00 | 52.16 | A |
| ATOM | 21 | NH1 | ARG | 2 | 20.524 | 37.290 | 26.773 | 1.00 | 52.11 | A |
| ATOM | 22 | HH11 | ARG | 2 | 20.441 | 36.817 | 25.892 | 0.00 | 0.00 | A |
| ATOM | 23 | HH12 | ARG | 2 | 19.681 | 37.453 | 27.283 | 0.00 | 0.00 | A |
| ATOM | 24 | NH2 | ARG | 2 | 21.773 | 38.258 | 28.460 | 1.00 | 52.43 | A |
| ATOM | 25 | HH21 | ARG | 2 | 22.640 | 38.522 | 28.875 | 0.00 | 0.00 | A |
| ATOM | 26 | HH22 | ARG | 2 | 20.952 | 38.449 | 29.038 | 0.00 | 0.00 | A |
| ATOM | 27 | C | ARG | 2 | 25.965 | 33.144 | 26.194 | 1.00 | 37.41 | A |
| ATOM | 28 | O | ARG | 2 | 26.865 | 33.052 | 25.375 | 1.00 | 38.48 | A |
| ATOM | 29 | N | ILE | 3 | 24.993 | 32.247 | 26.308 | 1.00 | 36.39 | A |
| ATOM | 30 | H | ILE | 3 | 24.220 | 32.438 | 26.872 | 0.00 | 0.00 | A |
| ATOM | 31 | CA | ILE | 3 | 24.935 | 31.032 | 25.503 | 1.00 | 33.51 | A |
| ATOM | 32 | CB | ILE | 3 | 24.694 | 29.816 | 26.429 | 1.00 | 33.84 | A |
| ATOM | 33 | CG2 | ILE | 3 | 23.364 | 29.945 | 27.128 | 1.00 | 33.49 | A |
| ATOM | 34 | CG1 | ILE | 3 | 24.695 | 28.515 | 25.641 | 1.00 | 36.12 | A |
| ATOM | 35 | CD1 | ILE | 3 | 24.494 | 27.301 | 26.514 | 1.00 | 36.98 | A |
| ATOM | 36 | C | ILE | 3 | 23.805 | 31.111 | 24.494 | 1.00 | 30.73 | A |
| ATOM | 37 | O | ILE | 3 | 22.780 | 31.695 | 24.770 | 1.00 | 30.26 | A |
| ATOM | 38 | N | GLY | 4 | 23.979 | 30.501 | 23.335 | 1.00 | 30.42 | A |
| ATOM | 39 | H | GLY | 4 | 24.812 | 30.021 | 23.143 | 0.00 | 0.00 | A |
| ATOM | 40 | CA | GLY | 4 | 22.925 | 30.528 | 22.337 | 1.00 | 29.96 | A |
| ATOM | 41 | C | GLY | 4 | 22.779 | 29.187 | 21.645 | 1.00 | 30.41 | A |
| ATOM | 42 | O | GLY | 4 | 23.725 | 28.395 | 21.615 | 1.00 | 31.83 | A |
| ATOM | 43 | N | HIS | 5 | 21.600 | 28.914 | 21.101 | 1.00 | 29.48 | A |
| ATOM | 44 | H | HIS | 5 | 20.916 | 29.590 | 21.136 | 0.00 | 0.00 | A |
| ATOM | 45 | CA | HIS | 5 | 21.348 | 27.661 | 20.405 | 1.00 | 28.78 | A |
| ATOM | 46 | CB | HIS | 5 | 20.560 | 26.674 | 21.277 | 1.00 | 27.53 | A |
| ATOM | 47 | CG | HIS | 5 | 20.211 | 25.392 | 20.574 | 1.00 | 28.39 | A |
| ATOM | 48 | CD2 | HIS | 5 | 20.928 | 24.254 | 20.379 | 1.00 | 25.67 | A |
| ATOM | 49 | ND1 | HIS | 5 | 19.008 | 25.203 | 19.922 | 1.00 | 26.84 | A |
| ATOM | 50 | HD1 | HIS | 5 | 18.240 | 25.819 | 19.891 | 0.00 | 0.00 | A |
| ATOM | 51 | CE1 | HIS | 5 | 19.003 | 24.008 | 19.352 | 1.00 | 29.50 | A |
| ATOM | 52 | NE2 | HIS | 5 | 20.153 | 23.413 | 19.616 | 1.00 | 27.00 | A |
| ATOM | 53 | HE2 | HIS | 5 | 20.305 | 22.471 | 19.355 | 0.00 | 0.00 | A |
| ATOM | 54 | C | HIS | 5 | 20.555 | 27.903 | 19.141 | 1.00 | 30.08 | A |
| ATOM | 55 | O | HIS | 5 | 19.550 | 28.629 | 19.153 | 1.00 | 30.89 | A |
| ATOM | 56 | N | GLY | 6 | 20.983 | 27.252 | 18.065 | 1.00 | 28.82 | A |
| ATOM | 57 | H | GLY | 6 | 21.783 | 26.681 | 18.099 | 0.00 | 0.00 | A |
| ATOM | 58 | CA | GLY | 6 | 20.285 | 27.369 | 16.803 | 1.00 | 29.21 | A |
| ATOM | 59 | C | GLY | 6 | 20.037 | 25.986 | 16.233 | 1.00 | 30.47 | A |
| ATOM | 60 | O | GLY | 6 | 20.679 | 25.017 | 16.654 | 1.00 | 32.59 | A |
| ATOM | 61 | N | PHE | 7 | 19.082 | 25.881 | 15.316 | 1.00 | 29.56 | A |
| ATOM | 62 | H | PHE | 7 | 18.574 | 26.672 | 15.013 | 0.00 | 0.00 | A |
| ATOM | 63 | CA | PHE | 7 | 18.766 | 24.614 | 14.673 | 1.00 | 28.22 | A |
| ATOM | 64 | CB | PHE | 7 | 17.794 | 23.818 | 15.532 | 1.00 | 29.32 | A |
| ATOM | 65 | CG | PHE | 7 | 17.322 | 22.558 | 14.889 | 1.00 | 29.49 | A |
| ATOM | 66 | CD1 | PHE | 7 | 18.010 | 21.377 | 15.067 | 1.00 | 30.04 | A |
| ATOM | 67 | CD2 | PHE | 7 | 16.208 | 22.559 | 14.068 | 1.00 | 31.25 | A |
| ATOM | 68 | CE1 | PHE | 7 | 17.599 | 20.215 | 14.430 | 1.00 | 29.25 | A |
| ATOM | 69 | CE2 | PHE | 7 | 15.792 | 21.396 | 13.427 | 1.00 | 29.51 | A |
| ATOM | 70 | CZ | PHE | 7 | 16.491 | 20.226 | 13.609 | 1.00 | 27.89 | A |
| ATOM | 71 | C | PHE | 7 | 18.127 | 24.926 | 13.334 | 1.00 | 28.47 | A |
| ATOM | 72 | O | PHE | 7 | 17.363 | 25.884 | 13.238 | 1.00 | 29.91 | A |
| ATOM | 73 | N | ASP | 8 | 18.443 | 24.146 | 12.303 | 1.00 | 28.72 | A |
| ATOM | 74 | H | ASP | 8 | 19.078 | 23.404 | 12.408 | 0.00 | 0.00 | A |
| ATOM | 75 | CA | ASP | 8 | 17.856 | 24.374 | 10.979 | 1.00 | 29.63 | A |
| ATOM | 76 | CB | ASP | 8 | 18.577 | 25.501 | 10.253 | 1.00 | 32.47 | A |
| ATOM | 77 | CG | ASP | 8 | 17.800 | 26.028 | 9.057 | 1.00 | 34.46 | A |
| ATOM | 78 | OD1 | ASP | 8 | 18.453 | 26.536 | 8.131 | 1.00 | 37.43 | A |
| ATOM | 79 | OD2 | ASP | 8 | 16.552 | 25.962 | 9.030 | 1.00 | 37.51 | A |
| ATOM | 80 | C | ASP | 8 | 17.829 | 23.123 | 10.116 | 1.00 | 29.46 | A |
| ATOM | 81 | O | ASP | 8 | 18.583 | 22.184 | 10.352 | 1.00 | 32.34 | A |
| ATOM | 82 | N | VAL | 9 | 16.940 | 23.106 | 9.131 | 1.00 | 29.31 | A |
| ATOM | 83 | H | VAL | 9 | 16.351 | 23.883 | 9.005 | 0.00 | 0.00 | A |
| ATOM | 84 | CA | VAL | 9 | 16.772 | 21.968 | 8.232 | 1.00 | 28.06 | A |
| ATOM | 85 | CB | VAL | 9 | 15.621 | 21.058 | 8.727 | 1.00 | 27.07 | A |
| ATOM | 86 | CG1 | VAL | 9 | 15.269 | 20.001 | 7.695 | 1.00 | 24.82 | A |
| ATOM | 87 | CG2 | VAL | 9 | 15.991 | 20.412 | 10.031 | 1.00 | 26.44 | A |
| ATOM | 88 | C | VAL | 9 | 16.378 | 22.471 | 6.853 | 1.00 | 30.26 | A |
| ATOM | 89 | O | VAL | 9 | 15.696 | 23.487 | 6.730 | 1.00 | 32.51 | A |
| ATOM | 90 | N | HIS | 10 | 16.870 | 21.813 | 5.811 | 1.00 | 32.35 | A |
| ATOM | 91 | H | HIS | 10 | 17.482 | 21.056 | 5.974 | 0.00 | 0.00 | A |
| ATOM | 92 | CA | HIS | 10 | 16.503 | 22.159 | 4.435 | 1.00 | 32.38 | A |
| ATOM | 93 | CB | HIS | 10 | 17.491 | 23.121 | 3.787 | 1.00 | 32.45 | A |
| ATOM | 94 | CG | HIS | 10 | 17.316 | 24.531 | 4.244 | 1.00 | 36.74 | A |
| ATOM | 95 | CD2 | HIS | 10 | 17.974 | 25.254 | 5.184 | 1.00 | 38.47 | A |
| ATOM | 96 | ND1 | HIS | 10 | 16.290 | 25.333 | 3.796 | 1.00 | 38.43 | A |
| ATOM | 97 | HD1 | HIS | 10 | 15.567 | 25.048 | 3.162 | 0.00 | 0.00 | A |
| ATOM | 98 | CE1 | HIS | 10 | 16.322 | 26.487 | 4.442 | 1.00 | 40.50 | A |
| ATOM | 99 | NE2 | HIS | 10 | 17.336 | 26.467 | 5.292 | 1.00 | 40.65 | A |
| ATOM | 100 | C | HIS | 10 | 16.344 | 20.878 | 3.640 | 1.00 | 32.44 | A |
| ATOM | 101 | O | HIS | 10 | 17.077 | 19.901 | 3.846 | 1.00 | 33.42 | A |
| ATOM | 102 | N | ALA | 11 | 15.319 | 20.846 | 2.806 | 1.00 | 31.37 | A |
| ATOM | 103 | H | ALA | 11 | 14.728 | 21.626 | 2.714 | 0.00 | 0.00 | A |
| ATOM | 104 | CA | ALA | 11 | 15.045 | 19.665 | 2.012 | 1.00 | 31.14 | A |
| ATOM | 105 | CB | ALA | 11 | 13.558 | 19.591 | 1.704 | 1.00 | 31.96 | A |
| ATOM | 106 | C | ALA | 11 | 15.852 | 19.640 | 0.722 | 1.00 | 31.16 | A |
| ATOM | 107 | O | ALA | 11 | 16.132 | 20.691 | 0.139 | 1.00 | 31.48 | A |
| ATOM | 108 | N | PHE | 12 | 16.244 | 18.442 | 0.292 | 1.00 | 30.80 | A |
| ATOM | 109 | H | PHE | 12 | 15.982 | 17.642 | 0.796 | 0.00 | 0.00 | A |
| ATOM | 110 | CA | PHE | 12 | 16.988 | 18.291 | −0.946 | 1.00 | 29.21 | A |
| ATOM | 111 | CB | PHE | 12 | 17.534 | 16.878 | −1.103 | 1.00 | 24.76 | A |
| ATOM | 112 | CG | PHE | 12 | 18.799 | 16.639 | −0.354 | 1.00 | 20.58 | A |
| ATOM | 113 | CD1 | PHE | 12 | 19.885 | 17.472 | −0.531 | 1.00 | 20.76 | A |
| ATOM | 114 | CD2 | PHE | 12 | 18.889 | 15.620 | 0.567 | 1.00 | 18.78 | A |
| ATOM | 115 | CE1 | PHE | 12 | 21.043 | 17.294 | 0.205 | 1.00 | 20.14 | A |
| ATOM | 116 | CE2 | PHE | 12 | 20.041 | 15.436 | 1.305 | 1.00 | 19.08 | A |
| ATOM | 117 | CZ | PHE | 12 | 21.121 | 16.280 | 1.122 | 1.00 | 19.86 | A |
| ATOM | 118 | C | PHE | 12 | 16.016 | 18.577 | −2.061 | 1.00 | 33.33 | A |
| ATOM | 119 | O | PHE | 12 | 14.806 | 18.411 | −1.904 | 1.00 | 35.03 | A |
| ATOM | 120 | N | GLY | 13 | 16.542 | 19.022 | −3.187 | 1.00 | 37.05 | A |
| ATOM | 121 | H | GLY | 13 | 17.492 | 19.157 | −3.305 | 0.00 | 0.00 | A |
| ATOM | 122 | CA | GLY | 13 | 15.696 | 19.326 | −4.312 | 1.00 | 41.25 | A |
| ATOM | 123 | C | GLY | 13 | 16.552 | 19.874 | −5.422 | 1.00 | 45.25 | A |
| ATOM | 124 | O | GLY | 13 | 17.495 | 20.641 | −5.179 | 1.00 | 47.14 | A |
| ATOM | 125 | N | GLY | 14 | 16.257 | 19.430 | −6.637 | 1.00 | 47.30 | A |
| ATOM | 126 | H | GLY | 14 | 15.558 | 18.759 | −6.752 | 0.00 | 0.00 | A |
| ATOM | 127 | CA | GLY | 14 | 16.992 | 19.895 | −7.793 | 1.00 | 50.54 | A |
| ATOM | 128 | C | GLY | 14 | 18.341 | 19.241 | −7.953 | 1.00 | 52.09 | A |
| ATOM | 129 | O | GLY | 14 | 18.606 | 18.176 | −7.378 | 1.00 | 51.16 | A |
| ATOM | 130 | N | GLU | 15 | 19.187 | 19.908 | −8.730 | 1.00 | 54.27 | A |
| ATOM | 131 | H | GLU | 15 | 18.924 | 20.757 | −9.127 | 0.00 | 0.00 | A |
| ATOM | 132 | CA | GLU | 15 | 20.532 | 19.441 | −9.016 | 1.00 | 57.13 | A |
| ATOM | 133 | CB | GLU | 15 | 20.927 | 19.851 | −10.441 | 1.00 | 64.20 | A |
| ATOM | 134 | CG | GLU | 15 | 20.057 | 19.252 | −11.542 | 1.00 | 72.91 | A |
| ATOM | 135 | CD | GLU | 15 | 20.120 | 17.730 | −11.567 | 1.00 | 79.20 | A |
| ATOM | 136 | OE1 | GLU | 15 | 19.107 | 17.080 | −11.207 | 1.00 | 83.00 | A |
| ATOM | 137 | OE2 | GLU | 15 | 21.186 | 17.189 | −11.944 | 1.00 | 82.31 | A |
| ATOM | 138 | C | GLU | 15 | 21.514 | 20.048 | −8.025 | 1.00 | 54.95 | A |
| ATOM | 139 | O | GLU | 15 | 21.261 | 21.130 | −7.483 | 1.00 | 55.59 | A |
| ATOM | 140 | N | GLY | 16 | 22.621 | 19.347 | −7.784 | 1.00 | 52.26 | A |
| ATOM | 141 | H | GLY | 16 | 22.735 | 18.482 | −8.239 | 0.00 | 0.00 | A |
| ATOM | 142 | CA | GLY | 16 | 23.639 | 19.840 | −6.871 | 1.00 | 48.46 | A |
| ATOM | 143 | C | GLY | 16 | 24.331 | 21.061 | −7.448 | 1.00 | 45.84 | A |
| ATOM | 144 | O | GLY | 16 | 23.980 | 21.503 | −8.540 | 1.00 | 47.51 | A |
| ATOM | 145 | N | CPR | 17 | 25.349 | 21.609 | −6.775 | 1.00 | 41.94 | A |
| ATOM | 146 | CD | CPR | 17 | 25.972 | 22.834 | −7.306 | 1.00 | 39.38 | A |
| ATOM | 147 | CA | CPR | 17 | 25.960 | 21.231 | −5.509 | 1.00 | 40.08 | A |
| ATOM | 148 | CB | CPR | 17 | 27.352 | 21.809 | −5.659 | 1.00 | 40.53 | A |
| ATOM | 149 | CG | CPR | 17 | 27.054 | 23.144 | −6.290 | 1.00 | 38.02 | A |
| ATOM | 150 | C | CPR | 17 | 25.210 | 21.918 | −4.375 | 1.00 | 39.29 | A |
| ATOM | 151 | O | CPR | 17 | 24.285 | 22.703 | −4.610 | 1.00 | 42.86 | A |
| ATOM | 152 | N | ILE | 18 | 25.625 | 21.652 | −3.149 | 1.00 | 33.98 | A |
| ATOM | 153 | H | ILE | 18 | 26.394 | 21.069 | −2.996 | 0.00 | 0.00 | A |
| ATOM | 154 | CA | ILE | 18 | 24.983 | 22.253 | −2.008 | 1.00 | 29.60 | A |
| ATOM | 155 | CB | ILE | 18 | 24.595 | 21.187 | −0.959 | 1.00 | 29.23 | A |
| ATOM | 156 | CG2 | ILE | 18 | 23.732 | 20.126 | −1.597 | 1.00 | 29.74 | A |
| ATOM | 157 | CG1 | ILE | 18 | 25.835 | 20.514 | −0.378 | 1.00 | 28.24 | A |
| ATOM | 158 | CD1 | ILE | 18 | 25.505 | 19.420 | 0.602 | 1.00 | 26.36 | A |
| ATOM | 159 | C | ILE | 18 | 25.980 | 23.202 | −1.413 | 1.00 | 28.18 | A |
| ATOM | 160 | O | ILE | 18 | 27.170 | 23.071 | −1.663 | 1.00 | 30.26 | A |
| ATOM | 161 | N | ILE | 19 | 25.499 | 24.173 | −0.648 | 1.00 | 27.10 | A |
| ATOM | 162 | H | ILE | 19 | 24.538 | 24.263 | −0.480 | 0.00 | 0.00 | A |
| ATOM | 163 | CA | ILE | 19 | 26.380 | 25.128 | 0.003 | 1.00 | 24.05 | A |
| ATOM | 164 | CB | ILE | 19 | 26.003 | 26.580 | −0.335 | 1.00 | 20.68 | A |
| ATOM | 165 | CG2 | ILE | 19 | 27.085 | 27.500 | 0.104 | 1.00 | 16.94 | A |
| ATOM | 166 | CG1 | ILE | 19 | 25.810 | 26.768 | −1.838 | 1.00 | 21.49 | A |
| ATOM | 167 | CD1 | ILE | 19 | 27.035 | 26.543 | −2.658 | 1.00 | 24.27 | A |
| ATOM | 168 | C | ILE | 19 | 26.156 | 24.923 | 1.491 | 1.00 | 26.28 | A |
| ATOM | 169 | O | ILE | 19 | 25.030 | 25.086 | 1.956 | 1.00 | 28.20 | A |
| ATOM | 170 | N | ILE | 20 | 27.192 | 24.479 | 2.208 | 1.00 | 25.84 | A |
| ATOM | 171 | H | ILE | 20 | 28.050 | 24.323 | 1.755 | 0.00 | 0.00 | A |
| ATOM | 172 | CA | ILE | 20 | 27.118 | 24.254 | 3.651 | 1.00 | 24.42 | A |
| ATOM | 173 | CB | ILE | 20 | 27.207 | 22.764 | 4.009 | 1.00 | 24.98 | A |
| ATOM | 174 | CG2 | ILE | 20 | 27.050 | 22.589 | 5.511 | 1.00 | 26.34 | A |
| ATOM | 175 | CG1 | ILE | 20 | 26.151 | 21.937 | 3.270 | 1.00 | 25.62 | A |
| ATOM | 176 | CD1 | ILE | 20 | 24.726 | 22.232 | 3.660 | 1.00 | 23.56 | A |
| ATOM | 177 | C | ILE | 20 | 28.333 | 24.897 | 4.297 | 1.00 | 26.42 | A |
| ATOM | 178 | O | ILE | 20 | 29.458 | 24.528 | 3.976 | 1.00 | 31.07 | A |
| ATOM | 179 | N | GLY | 21 | 28.128 | 25.817 | 5.232 | 1.00 | 25.27 | A |
| ATOM | 180 | H | GLY | 21 | 27.239 | 26.062 | 5.486 | 0.00 | 0.00 | A |
| ATOM | 181 | CA | GLY | 21 | 29.248 | 26.466 | 5.896 | 1.00 | 23.72 | A |
| ATOM | 182 | C | GLY | 21 | 30.060 | 27.295 | 4.932 | 1.00 | 24.12 | A |
| ATOM | 183 | O | GLY | 21 | 31.249 | 27.525 | 5.117 | 1.00 | 24.95 | A |
| ATOM | 184 | N | GLY | 22 | 29.408 | 27.741 | 3.874 | 1.00 | 26.31 | A |
| ATOM | 185 | H | GLY | 22 | 28.448 | 27.557 | 3.764 | 0.00 | 0.00 | A |
| ATOM | 186 | CA | GLY | 22 | 30.096 | 28.539 | 2.884 | 1.00 | 27.65 | A |
| ATOM | 187 | C | GLY | 22 | 30.710 | 27.706 | 1.779 | 1.00 | 27.87 | A |
| ATOM | 188 | O | GLY | 22 | 30.843 | 28.182 | 0.655 | 1.00 | 30.93 | A |
| ATOM | 189 | N | VAL | 23 | 31.027 | 26.449 | 2.064 | 1.00 | 25.46 | A |
| ATOM | 190 | H | VAL | 23 | 30.821 | 26.078 | 2.948 | 0.00 | 0.00 | A |
| ATOM | 191 | CA | VAL | 23 | 31.651 | 25.593 | 1.073 | 1.00 | 24.12 | A |
| ATOM | 192 | CB | VAL | 23 | 32.418 | 24.469 | 1.745 | 1.00 | 22.39 | A |
| ATOM | 193 | CG1 | VAL | 23 | 33.115 | 23.635 | 0.726 | 1.00 | 24.07 | A |
| ATOM | 194 | CG2 | VAL | 23 | 33.431 | 25.051 | 2.696 | 1.00 | 24.78 | A |
| ATOM | 195 | C | VAL | 23 | 30.685 | 25.019 | 0.058 | 1.00 | 25.36 | A |
| ATOM | 196 | O | VAL | 23 | 29.579 | 24.605 | 0.395 | 1.00 | 28.86 | A |
| ATOM | 197 | N | ARG | 24 | 31.091 | 25.032 | −1.200 | 1.00 | 25.46 | A |
| ATOM | 198 | H | ARG | 24 | 31.967 | 25.391 | −1.369 | 0.00 | 0.00 | A |
| ATOM | 199 | CA | ARG | 24 | 30.258 | 24.502 | −2.262 | 1.00 | 27.56 | A |
| ATOM | 200 | CB | ARG | 24 | 30.579 | 25.195 | −3.575 | 1.00 | 29.86 | A |
| ATOM | 201 | CG | ARG | 24 | 29.628 | 24.826 | −4.680 | 1.00 | 41.26 | A |
| ATOM | 202 | CD | ARG | 24 | 30.103 | 25.337 | −6.039 | 1.00 | 51.22 | A |
| ATOM | 203 | NE | ARG | 24 | 29.019 | 25.971 | −6.786 | 1.00 | 57.32 | A |
| ATOM | 204 | HE | ARG | 24 | 28.570 | 26.699 | −6.297 | 0.00 | 0.00 | A |
| ATOM | 205 | CZ | ARG | 24 | 28.648 | 25.634 | −8.016 | 1.00 | 61.81 | A |
| ATOM | 206 | NH1 | ARG | 24 | 27.644 | 26.291 | −8.589 | 1.00 | 63.83 | A |
| ATOM | 207 | HH11 | ARG | 24 | 27.179 | 27.035 | −8.097 | 0.00 | 0.00 | A |
| ATOM | 208 | HH12 | ARG | 24 | 27.312 | 26.097 | −9.515 | 0.00 | 0.00 | A |
| ATOM | 209 | NH2 | ARG | 24 | 29.267 | 24.639 | −8.664 | 1.00 | 64.56 | A |
| ATOM | 210 | HH21 | ARG | 24 | 30.016 | 24.145 | −8.217 | 0.00 | 0.00 | A |
| ATOM | 211 | HH22 | ARG | 24 | 29.002 | 24.360 | −9.588 | 0.00 | 0.00 | A |
| ATOM | 212 | C | ARG | 24 | 30.620 | 23.040 | −2.334 | 1.00 | 27.25 | A |
| ATOM | 213 | O | ARG | 24 | 31.692 | 22.691 | −2.799 | 1.00 | 32.64 | A |
| ATOM | 214 | N | ILE | 25 | 29.764 | 22.193 | −1.797 | 1.00 | 25.99 | A |
| ATOM | 215 | H | ILE | 25 | 28.935 | 22.543 | −1.414 | 0.00 | 0.00 | A |
| ATOM | 216 | CA | ILE | 25 | 30.011 | 20.764 | −1.765 | 1.00 | 24.92 | A |
| ATOM | 217 | CB | ILE | 25 | 29.503 | 20.198 | −0.442 | 1.00 | 24.93 | A |
| ATOM | 218 | CG2 | ILE | 25 | 29.585 | 18.713 | −0.437 | 1.00 | 23.98 | A |
| ATOM | 219 | CG1 | ILE | 25 | 30.295 | 20.786 | 0.719 | 1.00 | 23.99 | A |
| ATOM | 220 | CD1 | ILE | 25 | 29.583 | 20.645 | 2.021 | 1.00 | 22.12 | A |
| ATOM | 221 | C | ILE | 25 | 29.273 | 20.071 | −2.890 | 1.00 | 26.06 | A |
| ATOM | 222 | O | ILE | 25 | 28.073 | 20.253 | −3.055 | 1.00 | 30.52 | A |
| ATOM | 223 | N | PRO | 26 | 29.977 | 19.284 | −3.702 | 1.00 | 24.96 | A |
| ATOM | 224 | CD | PRO | 26 | 31.433 | 19.105 | −3.800 | 1.00 | 23.95 | A |
| ATOM | 225 | CA | PRO | 26 | 29.295 | 18.592 | −4.797 | 1.00 | 25.14 | A |
| ATOM | 226 | CB | PRO | 26 | 30.463 | 18.047 | −5.618 | 1.00 | 20.80 | A |
| ATOM | 227 | CG | PRO | 26 | 31.534 | 17.854 | −4.617 | 1.00 | 18.97 | A |
| ATOM | 228 | C | PRO | 26 | 28.394 | 17.466 | −4.289 | 1.00 | 27.42 | A |
| ATOM | 229 | O | PRO | 26 | 28.814 | 16.674 | −3.442 | 1.00 | 29.24 | A |
| ATOM | 230 | N | TYR | 27 | 27.178 | 17.379 | −4.820 | 1.00 | 28.10 | A |
| ATOM | 231 | H | TYR | 27 | 26.867 | 18.001 | −5.509 | 0.00 | 0.00 | A |
| ATOM | 232 | CA | TYR | 27 | 26.239 | 16.336 | −4.417 | 1.00 | 31.96 | A |
| ATOM | 233 | CB | TYR | 27 | 25.482 | 16.759 | −3.165 | 1.00 | 32.60 | A |
| ATOM | 234 | CG | TYR | 27 | 24.597 | 15.686 | −2.575 | 1.00 | 33.02 | A |
| ATOM | 235 | CD1 | TYR | 27 | 25.109 | 14.436 | −2.253 | 1.00 | 31.99 | A |
| ATOM | 236 | CE1 | TYR | 27 | 24.311 | 13.459 | −1.680 | 1.00 | 32.46 | A |
| ATOM | 237 | CD2 | TYR | 27 | 23.253 | 15.934 | −2.310 | 1.00 | 33.37 | A |
| ATOM | 238 | CE2 | TYR | 27 | 22.449 | 14.967 | −1.737 | 1.00 | 34.43 | A |
| ATOM | 239 | CZ | TYR | 27 | 22.984 | 13.727 | −1.424 | 1.00 | 33.33 | A |
| ATOM | 240 | OH | TYR | 27 | 22.188 | 12.755 | −0.859 | 1.00 | 34.28 | A |
| ATOM | 241 | HH | TYR | 27 | 22.739 | 11.955 | −0.811 | 0.00 | 0.00 | A |
| ATOM | 242 | C | TYR | 27 | 25.252 | 16.117 | −5.547 | 1.00 | 35.50 | A |
| ATOM | 243 | O | TYR | 27 | 25.030 | 17.032 | −6.341 | 1.00 | 36.76 | A |
| ATOM | 244 | N | GLU | 28 | 24.655 | 14.923 | −5.614 | 1.00 | 38.61 | A |
| ATOM | 245 | H | GLU | 28 | 24.873 | 14.253 | −4.938 | 0.00 | 0.00 | A |
| ATOM | 246 | CA | GLU | 28 | 23.690 | 14.604 | −6.677 | 1.00 | 41.66 | A |
| ATOM | 247 | CB | GLU | 28 | 23.047 | 13.236 | −6.478 | 1.00 | 44.28 | A |
| ATOM | 248 | CG | GLU | 28 | 23.827 | 12.246 | −5.650 | 1.00 | 54.43 | A |
| ATOM | 249 | CD | GLU | 28 | 22.917 | 11.161 | −5.061 | 1.00 | 60.42 | A |
| ATOM | 250 | OE1 | GLU | 28 | 23.446 | 10.142 | −4.561 | 1.00 | 66.13 | A |
| ATOM | 251 | OE2 | GLU | 28 | 21.673 | 11.337 | −5.073 | 1.00 | 61.99 | A |
| ATOM | 252 | C | GLU | 28 | 22.570 | 15.628 | −6.707 | 1.00 | 40.86 | A |
| ATOM | 253 | O | GLU | 28 | 22.339 | 16.286 | −7.721 | 1.00 | 43.08 | A |
| ATOM | 254 | N | LYS | 29 | 21.868 | 15.738 | −5.587 | 1.00 | 39.17 | A |
| ATOM | 255 | H | LYS | 29 | 22.159 | 15.196 | −4.833 | 0.00 | 0.00 | A |
| ATOM | 256 | CA | LYS | 29 | 20.769 | 16.676 | −5.458 | 1.00 | 36.85 | A |
| ATOM | 257 | CB | LYS | 29 | 19.600 | 16.023 | −4.714 | 1.00 | 35.30 | A |
| ATOM | 258 | CG | LYS | 29 | 19.966 | 14.771 | −3.921 | 1.00 | 34.23 | A |
| ATOM | 259 | CD | LYS | 29 | 18.712 | 14.066 | −3.425 | 1.00 | 36.41 | A |
| ATOM | 260 | CE | LYS | 29 | 19.013 | 12.756 | −2.687 | 1.00 | 37.65 | A |
| ATOM | 261 | NZ | LYS | 29 | 19.568 | 12.901 | −1.303 | 1.00 | 34.69 | A |
| ATOM | 262 | HZ1 | LYS | 29 | 18.892 | 13.364 | −0.654 | 0.00 | 0.00 | A |
| ATOM | 263 | HZ2 | LYS | 29 | 20.500 | 13.371 | −1.289 | 0.00 | 0.00 | A |
| ATOM | 264 | HZ3 | LYS | 29 | 19.744 | 11.945 | −0.943 | 0.00 | 0.00 | A |
| ATOM | 265 | C | LYS | 29 | 21.256 | 17.919 | −4.735 | 1.00 | 36.56 | A |
| ATOM | 266 | O | LYS | 29 | 22.350 | 17.917 | −4.171 | 1.00 | 36.77 | A |
| ATOM | 267 | N | GLY | 30 | 20.457 | 18.980 | −4.787 | 1.00 | 36.51 | A |
| ATOM | 268 | H | GLY | 30 | 19.612 | 18.922 | −5.279 | 0.00 | 0.00 | A |
| ATOM | 269 | CA | GLY | 30 | 20.797 | 20.232 | −4.132 | 1.00 | 35.30 | A |
| ATOM | 270 | C | GLY | 30 | 19.829 | 20.532 | −3.003 | 1.00 | 36.21 | A |
| ATOM | 271 | O | GLY | 30 | 19.037 | 19.664 | −2.630 | 1.00 | 35.69 | A |
| ATOM | 272 | N | LEU | 31 | 19.871 | 21.748 | −2.461 | 1.00 | 36.21 | A |
| ATOM | 273 | H | LEU | 31 | 20.460 | 22.432 | −2.841 | 0.00 | 0.00 | A |
| ATOM | 274 | CA | LEU | 31 | 18.992 | 22.119 | −1.347 | 1.00 | 36.48 | A |
| ATOM | 275 | CB | LEU | 31 | 19.805 | 22.589 | −0.136 | 1.00 | 29.57 | A |
| ATOM | 276 | CG | LEU | 31 | 20.512 | 21.499 | 0.664 | 1.00 | 27.34 | A |
| ATOM | 277 | CD1 | LEU | 31 | 21.354 | 22.077 | 1.790 | 1.00 | 25.59 | A |
| ATOM | 278 | CD2 | LEU | 31 | 19.463 | 20.585 | 1.221 | 1.00 | 27.62 | A |
| ATOM | 279 | C | LEU | 31 | 17.957 | 23.174 | −1.695 | 1.00 | 38.76 | A |
| ATOM | 280 | O | LEU | 31 | 18.275 | 24.195 | −2.293 | 1.00 | 41.30 | A |
| ATOM | 281 | N | LEU | 32 | 16.715 | 22.914 | −1.323 | 1.00 | 40.81 | A |
| ATOM | 282 | H | LEU | 32 | 16.531 | 22.081 | −0.872 | 0.00 | 0.00 | A |
| ATOM | 283 | CA | LEU | 32 | 15.630 | 23.845 | −1.566 | 1.00 | 45.91 | A |
| ATOM | 284 | CB | LEU | 32 | 14.316 | 23.089 | −1.536 | 1.00 | 44.32 | A |
| ATOM | 285 | CG | LEU | 32 | 14.188 | 22.075 | −2.656 | 1.00 | 45.12 | A |
| ATOM | 286 | CD1 | LEU | 32 | 12.850 | 21.384 | −2.546 | 1.00 | 44.88 | A |
| ATOM | 287 | CD2 | LEU | 32 | 14.320 | 22.787 | −3.992 | 1.00 | 45.65 | A |
| ATOM | 288 | C | LEU | 32 | 15.601 | 24.964 | −0.515 | 1.00 | 50.68 | A |
| ATOM | 289 | O | LEU | 32 | 15.556 | 24.684 | 0.695 | 1.00 | 52.06 | A |
| ATOM | 290 | N | ALA | 33 | 15.613 | 26.220 | −0.970 | 1.00 | 54.52 | A |
| ATOM | 291 | H | ALA | 33 | 15.679 | 26.412 | −1.931 | 0.00 | 0.00 | A |
| ATOM | 292 | CA | ALA | 33 | 15.580 | 27.363 | −0.059 | 1.00 | 59.97 | A |
| ATOM | 293 | CB | ALA | 33 | 16.803 | 27.324 | 0.865 | 1.00 | 59.56 | A |
| ATOM | 294 | C | ALA | 33 | 15.463 | 28.757 | −0.722 | 1.00 | 64.08 | A |
| ATOM | 295 | O | ALA | 33 | 15.836 | 28.934 | −1.889 | 1.00 | 65.41 | A |
| ATOM | 296 | N | HIS | 34 | 14.908 | 29.719 | 0.038 | 1.00 | 67.03 | A |
| ATOM | 297 | H | HIS | 34 | 14.587 | 29.447 | 0.922 | 0.00 | 0.00 | A |
| ATOM | 298 | CA | HIS | 34 | 14.741 | 31.131 | −0.373 | 1.00 | 67.24 | A |
| ATOM | 299 | CB | HIS | 34 | 14.000 | 31.907 | 0.751 | 1.00 | 72.32 | A |
| ATOM | 300 | CG | HIS | 34 | 13.873 | 33.401 | 0.546 | 1.00 | 76.89 | A |
| ATOM | 301 | CD2 | HIS | 34 | 14.181 | 34.435 | 1.373 | 1.00 | 75.97 | A |
| ATOM | 302 | ND1 | HIS | 34 | 13.255 | 33.969 | −0.552 | 1.00 | 78.35 | A |
| ATOM | 303 | HD1 | HIS | 34 | 12.889 | 33.487 | −1.322 | 0.00 | 0.00 | A |
| ATOM | 304 | CE1 | HIS | 34 | 13.180 | 35.281 | −0.388 | 1.00 | 76.83 | A |
| ATOM | 305 | NE2 | HIS | 34 | 13.733 | 35.588 | 0.772 | 1.00 | 75.92 | A |
| ATOM | 306 | HE2 | HIS | 34 | 13.711 | 36.481 | 1.195 | 0.00 | 0.00 | A |
| ATOM | 307 | C | HIS | 34 | 16.171 | 31.649 | −0.552 | 1.00 | 65.90 | A |
| ATOM | 308 | O | HIS | 34 | 16.536 | 32.117 | −1.628 | 1.00 | 65.51 | A |
| ATOM | 309 | N | SER | 35 | 16.973 | 31.511 | 0.506 | 1.00 | 64.16 | A |
| ATOM | 310 | H | SER | 35 | 16.636 | 31.093 | 1.320 | 0.00 | 0.00 | A |
| ATOM | 311 | CA | SER | 35 | 18.376 | 31.921 | 0.525 | 1.00 | 60.63 | A |
| ATOM | 312 | CB | SER | 35 | 18.865 | 31.959 | 1.980 | 1.00 | 62.00 | A |
| ATOM | 313 | OG | SER | 35 | 18.815 | 30.658 | 2.570 | 1.00 | 62.99 | A |
| ATOM | 314 | HG | SER | 35 | 19.734 | 30.401 | 2.371 | 0.00 | 0.00 | A |
| ATOM | 315 | C | SER | 35 | 19.153 | 30.857 | −0.245 | 1.00 | 57.29 | A |
| ATOM | 316 | O | SER | 35 | 18.612 | 30.211 | −1.139 | 1.00 | 57.11 | A |
| ATOM | 317 | N | ASP | 36 | 20.417 | 30.666 | 0.109 | 1.00 | 54.08 | A |
| ATOM | 318 | H | ASP | 36 | 20.891 | 31.246 | 0.747 | 0.00 | 0.00 | A |
| ATOM | 319 | CA | ASP | 36 | 21.233 | 29.642 | −0.530 | 1.00 | 51.85 | A |
| ATOM | 320 | CB | ASP | 36 | 22.698 | 30.076 | −0.565 | 1.00 | 49.85 | A |
| ATOM | 321 | CG | ASP | 36 | 23.241 | 30.373 | 0.801 | 1.00 | 50.76 | A |
| ATOM | 322 | OD1 | ASP | 36 | 24.445 | 30.681 | 0.907 | 1.00 | 51.55 | A |
| ATOM | 323 | OD2 | ASP | 36 | 22.458 | 30.302 | 1.775 | 1.00 | 51.70 | A |
| ATOM | 324 | C | ASP | 36 | 21.065 | 28.318 | 0.244 | 1.00 | 51.40 | A |
| ATOM | 325 | O | ASP | 36 | 21.747 | 27.318 | −0.031 | 1.00 | 52.74 | A |
| ATOM | 326 | N | GLY | 37 | 20.163 | 28.336 | 1.230 | 1.00 | 48.41 | A |
| ATOM | 327 | H | GLY | 37 | 19.682 | 29.161 | 1.369 | 0.00 | 0.00 | A |
| ATOM | 328 | CA | GLY | 37 | 19.875 | 27.151 | 2.021 | 1.00 | 41.92 | A |
| ATOM | 329 | C | GLY | 37 | 21.020 | 26.572 | 2.826 | 1.00 | 38.34 | A |
| ATOM | 330 | O | GLY | 37 | 20.995 | 25.390 | 3.186 | 1.00 | 38.23 | A |
| ATOM | 331 | N | ASP | 38 | 21.989 | 27.410 | 3.165 | 1.00 | 33.46 | A |
| ATOM | 332 | H | ASP | 38 | 22.021 | 28.327 | 2.817 | 0.00 | 0.00 | A |
| ATOM | 333 | CA | ASP | 38 | 23.126 | 26.962 | 3.946 | 1.00 | 31.23 | A |
| ATOM | 334 | CB | ASP | 38 | 24.185 | 28.053 | 3.953 | 1.00 | 29.96 | A |
| ATOM | 335 | CG | ASP | 38 | 25.513 | 27.551 | 4.401 | 1.00 | 30.43 | A |
| ATOM | 336 | OD1 | ASP | 38 | 25.554 | 26.670 | 5.275 | 1.00 | 32.57 | A |
| ATOM | 337 | OD2 | ASP | 38 | 26.532 | 28.031 | 3.881 | 1.00 | 36.04 | A |
| ATOM | 338 | C | ASP | 38 | 22.695 | 26.609 | 5.376 | 1.00 | 31.85 | A |
| ATOM | 339 | O | ASP | 38 | 22.786 | 27.426 | 6.295 | 1.00 | 35.84 | A |
| ATOM | 340 | N | VAL | 39 | 22.217 | 25.387 | 5.561 | 1.00 | 30.29 | A |
| ATOM | 341 | H | VAL | 39 | 22.218 | 24.830 | 4.751 | 0.00 | 0.00 | A |
| ATOM | 342 | CA | VAL | 39 | 21.740 | 24.921 | 6.858 | 1.00 | 28.04 | A |
| ATOM | 343 | CB | VAL | 39 | 21.500 | 23.413 | 6.867 | 1.00 | 27.61 | A |
| ATOM | 344 | CG1 | VAL | 39 | 20.493 | 23.070 | 7.911 | 1.00 | 31.92 | A |
| ATOM | 345 | CG2 | VAL | 39 | 21.011 | 22.948 | 5.542 | 1.00 | 32.02 | A |
| ATOM | 346 | C | VAL | 39 | 22.688 | 25.208 | 8.001 | 1.00 | 28.76 | A |
| ATOM | 347 | O | VAL | 39 | 22.249 | 25.612 | 9.079 | 1.00 | 29.24 | A |
| ATOM | 348 | N | ALA | 40 | 23.983 | 25.005 | 7.762 | 1.00 | 27.09 | A |
| ATOM | 349 | H | ALA | 40 | 24.260 | 24.770 | 6.852 | 0.00 | 0.00 | A |
| ATOM | 350 | CA | ALA | 40 | 25.001 | 25.205 | 8.791 | 1.00 | 25.12 | A |
| ATOM | 351 | CB | ALA | 40 | 26.353 | 24.707 | 8.306 | 1.00 | 23.59 | A |
| ATOM | 352 | C | ALA | 40 | 25.110 | 26.652 | 9.225 | 1.00 | 24.93 | A |
| ATOM | 353 | O | ALA | 40 | 25.220 | 26.944 | 10.416 | 1.00 | 25.52 | A |
| ATOM | 354 | N | LEU | 41 | 25.093 | 27.573 | 8.274 | 1.00 | 23.93 | A |
| ATOM | 355 | H | LEU | 41 | 25.009 | 27.326 | 7.322 | 0.00 | 0.00 | A |
| ATOM | 356 | CA | LEU | 41 | 25.207 | 28.970 | 8.657 | 1.00 | 23.03 | A |
| ATOM | 357 | CB | LEU | 41 | 25.775 | 29.816 | 7.535 | 1.00 | 19.10 | A |
| ATOM | 358 | CG | LEU | 41 | 27.207 | 29.415 | 7.166 | 1.00 | 19.20 | A |
| ATOM | 359 | CD1 | LEU | 41 | 27.704 | 30.280 | 6.018 | 1.00 | 21.52 | A |
| ATOM | 360 | CD2 | LEU | 41 | 28.139 | 29.544 | 8.345 | 1.00 | 15.61 | A |
| ATOM | 361 | C | LEU | 41 | 23.909 | 29.531 | 9.215 | 1.00 | 24.96 | A |
| ATOM | 362 | O | LEU | 41 | 23.937 | 30.437 | 10.040 | 1.00 | 27.46 | A |
| ATOM | 363 | N | HIS | 42 | 22.769 | 28.975 | 8.822 | 1.00 | 24.89 | A |
| ATOM | 364 | H | HIS | 42 | 22.812 | 28.245 | 8.169 | 0.00 | 0.00 | A |
| ATOM | 365 | CA | HIS | 42 | 21.523 | 29.459 | 9.403 | 1.00 | 24.51 | A |
| ATOM | 366 | CB | HIS | 42 | 20.294 | 28.854 | 8.744 | 1.00 | 28.41 | A |
| ATOM | 367 | CG | HIS | 42 | 20.033 | 29.363 | 7.365 | 1.00 | 31.02 | A |
| ATOM | 368 | CD2 | HIS | 42 | 20.727 | 30.239 | 6.600 | 1.00 | 29.56 | A |
| ATOM | 369 | ND1 | HIS | 42 | 18.947 | 28.956 | 6.613 | 1.00 | 36.32 | A |
| ATOM | 370 | CE1 | HIS | 42 | 18.991 | 29.569 | 5.440 | 1.00 | 35.41 | A |
| ATOM | 371 | NE2 | HIS | 42 | 20.059 | 30.350 | 5.409 | 1.00 | 32.24 | A |
| ATOM | 372 | HE2 | HIS | 42 | 20.390 | 30.943 | 4.681 | 0.00 | 0.00 | A |
| ATOM | 373 | C | HIS | 42 | 21.549 | 29.028 | 10.848 | 1.00 | 23.69 | A |
| ATOM | 374 | O | HIS | 42 | 21.398 | 29.846 | 11.739 | 1.00 | 27.63 | A |
| ATOM | 375 | N | ALA | 43 | 21.825 | 27.753 | 11.087 | 1.00 | 22.23 | A |
| ATOM | 376 | H | ALA | 43 | 22.013 | 27.125 | 10.359 | 0.00 | 0.00 | A |
| ATOM | 377 | CA | ALA | 43 | 21.855 | 27.262 | 12.448 | 1.00 | 19.62 | A |
| ATOM | 378 | CB | ALA | 43 | 22.177 | 25.796 | 12.490 | 1.00 | 18.99 | A |
| ATOM | 379 | C | ALA | 43 | 22.843 | 28.070 | 13.251 | 1.00 | 21.22 | A |
| ATOM | 380 | O | ALA | 43 | 22.501 | 28.552 | 14.319 | 1.00 | 26.43 | A |
| ATOM | 381 | N | LEU | 44 | 24.026 | 28.328 | 12.703 | 1.00 | 22.40 | A |
| ATOM | 382 | H | LEU | 44 | 24.243 | 27.979 | 11.813 | 0.00 | 0.00 | A |
| ATOM | 383 | CA | LEU | 44 | 25.027 | 29.114 | 13.438 | 1.00 | 22.69 | A |
| ATOM | 384 | CB | LEU | 44 | 26.350 | 29.199 | 12.663 | 1.00 | 16.66 | A |
| ATOM | 385 | CG | LEU | 44 | 27.404 | 30.156 | 13.232 | 1.00 | 14.73 | A |
| ATOM | 386 | CD1 | LEU | 44 | 27.760 | 29.786 | 14.653 | 1.00 | 12.76 | A |
| ATOM | 387 | CD2 | LEU | 44 | 28.649 | 30.132 | 12.368 | 1.00 | 12.68 | A |
| ATOM | 388 | C | LEU | 44 | 24.527 | 30.519 | 13.776 | 1.00 | 24.10 | A |
| ATOM | 389 | O | LEU | 44 | 24.678 | 30.982 | 14.907 | 1.00 | 26.06 | A |
| ATOM | 390 | N | THR | 45 | 23.917 | 31.182 | 12.798 | 1.00 | 25.51 | A |
| ATOM | 391 | H | THR | 45 | 23.784 | 30.766 | 11.921 | 0.00 | 0.00 | A |
| ATOM | 392 | CA | THR | 45 | 23.398 | 32.538 | 12.964 | 1.00 | 25.86 | A |
| ATOM | 393 | CB | THR | 45 | 22.731 | 33.009 | 11.668 | 1.00 | 24.86 | A |
| ATOM | 394 | OG1 | THR | 45 | 23.692 | 32.962 | 10.604 | 1.00 | 25.33 | A |
| ATOM | 395 | HG1 | THR | 45 | 24.445 | 33.518 | 10.807 | 0.00 | 0.00 | A |
| ATOM | 396 | CG2 | THR | 45 | 22.184 | 34.423 | 11.814 | 1.00 | 24.66 | A |
| ATOM | 397 | C | THR | 45 | 22.402 | 32.642 | 14.121 | 1.00 | 28.14 | A |
| ATOM | 398 | O | THR | 45 | 22.522 | 33.519 | 14.980 | 1.00 | 30.79 | A |
| ATOM | 399 | N | ASP | 46 | 21.421 | 31.750 | 14.146 | 1.00 | 26.75 | A |
| ATOM | 400 | H | ASP | 46 | 21.329 | 31.089 | 13.423 | 0.00 | 0.00 | A |
| ATOM | 401 | CA | ASP | 46 | 20.434 | 31.743 | 15.205 | 1.00 | 24.52 | A |
| ATOM | 402 | CB | ASP | 46 | 19.475 | 30.598 | 14.994 | 1.00 | 26.82 | A |
| ATOM | 403 | CG | ASP | 46 | 18.305 | 30.970 | 14.149 | 1.00 | 30.17 | A |
| ATOM | 404 | OD1 | ASP | 46 | 17.470 | 30.079 | 13.883 | 1.00 | 34.74 | A |
| ATOM | 405 | OD2 | ASP | 46 | 18.208 | 32.143 | 13.761 | 1.00 | 30.76 | A |
| ATOM | 406 | C | ASP | 46 | 21.069 | 31.557 | 16.563 | 1.00 | 24.69 | A |
| ATOM | 407 | O | ASP | 46 | 20.557 | 32.044 | 17.559 | 1.00 | 25.32 | A |
| ATOM | 408 | N | ALA | 47 | 22.145 | 30.784 | 16.618 | 1.00 | 24.43 | A |
| ATOM | 409 | H | ALA | 47 | 22.469 | 30.367 | 15.789 | 0.00 | 0.00 | A |
| ATOM | 410 | CA | ALA | 47 | 22.808 | 30.536 | 17.882 | 1.00 | 24.93 | A |
| ATOM | 411 | CB | ALA | 47 | 23.874 | 29.500 | 17.724 | 1.00 | 26.61 | A |
| ATOM | 412 | C | ALA | 47 | 23.399 | 31.820 | 18.400 | 1.00 | 26.94 | A |
| ATOM | 413 | O | ALA | 47 | 23.284 | 32.113 | 19.587 | 1.00 | 28.62 | A |
| ATOM | 414 | N | LEU | 48 | 24.029 | 32.583 | 17.505 | 1.00 | 28.67 | A |
| ATOM | 415 | H | LEU | 48 | 24.078 | 32.259 | 16.579 | 0.00 | 0.00 | A |
| ATOM | 416 | CA | LEU | 48 | 24.651 | 33.870 | 17.852 | 1.00 | 27.90 | A |
| ATOM | 417 | CB | LEU | 48 | 25.496 | 34.380 | 16.687 | 1.00 | 25.91 | A |
| ATOM | 418 | CG | LEU | 48 | 26.744 | 33.557 | 16.351 | 1.00 | 26.67 | A |
| ATOM | 419 | CD1 | LEU | 48 | 27.262 | 33.963 | 14.997 | 1.00 | 25.57 | A |
| ATOM | 420 | CD2 | LEU | 48 | 27.821 | 33.745 | 17.426 | 1.00 | 23.31 | A |
| ATOM | 421 | C | LEU | 48 | 23.578 | 34.896 | 18.222 | 1.00 | 28.79 | A |
| ATOM | 422 | O | LEU | 48 | 23.641 | 35.511 | 19.284 | 1.00 | 32.12 | A |
| ATOM | 423 | N | LEU | 49 | 22.583 | 35.072 | 17.358 | 1.00 | 28.14 | A |
| ATOM | 424 | H | LEU | 49 | 22.582 | 34.567 | 16.522 | 0.00 | 0.00 | A |
| ATOM | 425 | CA | LEU | 49 | 21.487 | 35.993 | 17.643 | 1.00 | 26.15 | A |
| ATOM | 426 | CB | LEU | 49 | 20.460 | 35.970 | 16.518 | 1.00 | 24.50 | A |
| ATOM | 427 | CG | LEU | 49 | 20.932 | 36.598 | 15.215 | 1.00 | 23.51 | A |
| ATOM | 428 | CD1 | LEU | 49 | 19.845 | 36.474 | 14.169 | 1.00 | 22.06 | A |
| ATOM | 429 | CD2 | LEU | 49 | 21.297 | 38.055 | 15.456 | 1.00 | 20.33 | A |
| ATOM | 430 | C | LEU | 49 | 20.826 | 35.549 | 18.942 | 1.00 | 26.40 | A |
| ATOM | 431 | O | LEU | 49 | 20.511 | 36.373 | 19.785 | 1.00 | 28.17 | A |
| ATOM | 432 | N | GLY | 50 | 20.650 | 34.242 | 19.107 | 1.00 | 26.69 | A |
| ATOM | 433 | H | GLY | 50 | 20.931 | 33.637 | 18.399 | 0.00 | 0.00 | A |
| ATOM | 434 | CA | GLY | 50 | 20.048 | 33.700 | 20.313 | 1.00 | 28.15 | A |
| ATOM | 435 | C | GLY | 50 | 20.789 | 34.128 | 21.568 | 1.00 | 29.68 | A |
| ATOM | 436 | O | GLY | 50 | 20.181 | 34.639 | 22.497 | 1.00 | 33.11 | A |
| ATOM | 437 | N | ALA | 51 | 22.106 | 33.965 | 21.587 | 1.00 | 29.26 | A |
| ATOM | 438 | H | ALA | 51 | 22.542 | 33.541 | 20.817 | 0.00 | 0.00 | A |
| ATOM | 439 | CA | ALA | 51 | 22.901 | 34.359 | 22.737 | 1.00 | 28.13 | A |
| ATOM | 440 | CB | ALA | 51 | 24.307 | 33.854 | 22.588 | 1.00 | 26.67 | A |
| ATOM | 441 | C | ALA | 51 | 22.905 | 35.875 | 22.924 | 1.00 | 29.71 | A |
| ATOM | 442 | O | ALA | 51 | 23.142 | 36.370 | 24.017 | 1.00 | 32.11 | A |
| ATOM | 443 | N | ALA | 52 | 22.671 | 36.622 | 21.858 | 1.00 | 30.50 | A |
| ATOM | 444 | H | ALA | 52 | 22.536 | 36.190 | 20.987 | 0.00 | 0.00 | A |
| ATOM | 445 | CA | ALA | 52 | 22.653 | 38.078 | 21.956 | 1.00 | 30.50 | A |
| ATOM | 446 | CB | ALA | 52 | 23.080 | 38.696 | 20.638 | 1.00 | 28.66 | A |
| ATOM | 447 | C | ALA | 52 | 21.269 | 38.570 | 22.320 | 1.00 | 30.01 | A |
| ATOM | 448 | O | ALA | 52 | 21.080 | 39.748 | 22.579 | 1.00 | 34.80 | A |
| ATOM | 449 | N | ALA | 53 | 20.306 | 37.660 | 22.339 | 1.00 | 29.91 | A |
| ATOM | 450 | H | ALA | 53 | 20.523 | 36.727 | 22.124 | 0.00 | 0.00 | A |
| ATOM | 451 | CA | ALA | 53 | 18.904 | 37.971 | 22.632 | 1.00 | 28.51 | A |
| ATOM | 452 | CB | ALA | 53 | 18.760 | 38.647 | 23.976 | 1.00 | 27.64 | A |
| ATOM | 453 | C | ALA | 53 | 18.317 | 38.844 | 21.538 | 1.00 | 28.42 | A |
| ATOM | 454 | O | ALA | 53 | 17.545 | 39.755 | 21.812 | 1.00 | 31.64 | A |
| ATOM | 455 | N | LEU | 54 | 18.704 | 38.584 | 20.296 | 1.00 | 26.86 | A |
| ATOM | 456 | H | LEU | 54 | 19.336 | 37.854 | 20.138 | 0.00 | 0.00 | A |
| ATOM | 457 | CA | LEU | 54 | 18.191 | 39.355 | 19.183 | 1.00 | 24.75 | A |
| ATOM | 458 | CB | LEU | 54 | 19.329 | 39.848 | 18.288 | 1.00 | 25.73 | A |
| ATOM | 459 | CG | LEU | 54 | 20.369 | 40.761 | 18.962 | 1.00 | 24.74 | A |
| ATOM | 460 | CD1 | LEU | 54 | 21.500 | 41.101 | 18.017 | 1.00 | 20.59 | A |
| ATOM | 461 | CD2 | LEU | 54 | 19.698 | 42.018 | 19.421 | 1.00 | 23.57 | A |
| ATOM | 462 | C | LEU | 54 | 17.143 | 38.580 | 18.397 | 1.00 | 25.21 | A |
| ATOM | 463 | O | LEU | 54 | 16.660 | 39.034 | 17.364 | 1.00 | 27.05 | A |
| ATOM | 464 | N | GLY | 55 | 16.735 | 37.439 | 18.923 | 1.00 | 26.88 | A |
| ATOM | 465 | H | GLY | 55 | 17.102 | 37.093 | 19.768 | 0.00 | 0.00 | A |
| ATOM | 466 | CA | GLY | 55 | 15.704 | 36.664 | 18.265 | 1.00 | 29.06 | A |
| ATOM | 467 | C | GLY | 55 | 16.218 | 35.536 | 17.419 | 1.00 | 32.14 | A |
| ATOM | 468 | O | GLY | 55 | 16.748 | 34.554 | 17.948 | 1.00 | 31.73 | A |
| ATOM | 469 | N | ASP | 56 | 16.045 | 35.678 | 16.107 | 1.00 | 34.49 | A |
| ATOM | 470 | H | ASP | 56 | 15.606 | 36.460 | 15.722 | 0.00 | 0.00 | A |
| ATOM | 471 | CA | ASP | 56 | 16.468 | 34.675 | 15.145 | 1.00 | 36.60 | A |
| ATOM | 472 | CB | ASP | 56 | 15.489 | 33.490 | 15.144 | 1.00 | 36.58 | A |
| ATOM | 473 | CG | ASP | 56 | 14.094 | 33.861 | 14.653 | 1.00 | 37.68 | A |
| ATOM | 474 | OD1 | ASP | 56 | 13.999 | 34.687 | 13.724 | 1.00 | 37.97 | A |
| ATOM | 475 | OD2 | ASP | 56 | 13.090 | 33.310 | 15.169 | 1.00 | 37.56 | A |
| ATOM | 476 | C | ASP | 56 | 16.633 | 35.266 | 13.735 | 1.00 | 38.92 | A |
| ATOM | 477 | O | ASP | 56 | 16.233 | 36.405 | 13.469 | 1.00 | 40.18 | A |
| ATOM | 478 | N | ILE | 57 | 17.152 | 34.455 | 12.820 | 1.00 | 40.46 | A |
| ATOM | 479 | H | ILE | 57 | 17.280 | 33.536 | 13.084 | 0.00 | 0.00 | A |
| ATOM | 480 | CA | ILE | 57 | 17.418 | 34.860 | 11.447 | 1.00 | 40.58 | A |
| ATOM | 481 | CB | ILE | 57 | 18.151 | 33.714 | 10.672 | 1.00 | 37.87 | A |
| ATOM | 482 | CG2 | ILE | 57 | 17.185 | 32.653 | 10.173 | 1.00 | 36.56 | A |
| ATOM | 483 | CG1 | ILE | 57 | 18.925 | 34.277 | 9.499 | 1.00 | 37.95 | A |
| ATOM | 484 | CD1 | ILE | 57 | 19.577 | 33.205 | 8.687 | 1.00 | 40.74 | A |
| ATOM | 485 | C | ILE | 57 | 16.165 | 35.347 | 10.716 | 1.00 | 42.57 | A |
| ATOM | 486 | O | ILE | 57 | 16.182 | 36.405 | 10.093 | 1.00 | 42.45 | A |
| ATOM | 487 | N | GLY | 58 | 15.058 | 34.633 | 10.882 | 1.00 | 44.81 | A |
| ATOM | 488 | H | GLY | 58 | 15.050 | 33.879 | 11.515 | 0.00 | 0.00 | A |
| ATOM | 489 | CA | GLY | 58 | 13.822 | 35.010 | 10.220 | 1.00 | 50.33 | A |
| ATOM | 490 | C | GLY | 58 | 13.205 | 36.289 | 10.752 | 1.00 | 54.11 | A |
| ATOM | 491 | O | GLY | 58 | 12.212 | 36.779 | 10.218 | 1.00 | 56.15 | A |
| ATOM | 492 | N | LYS | 59 | 13.736 | 36.790 | 11.855 | 1.00 | 57.85 | A |
| ATOM | 493 | H | LYS | 59 | 14.426 | 36.283 | 12.339 | 0.00 | 0.00 | A |
| ATOM | 494 | CA | LYS | 59 | 13.229 | 38.024 | 12.423 | 1.00 | 61.69 | A |
| ATOM | 495 | CB | LYS | 59 | 13.457 | 38.071 | 13.936 | 1.00 | 64.55 | A |
| ATOM | 496 | CG | LYS | 59 | 13.014 | 39.365 | 14.597 | 1.00 | 67.40 | A |
| ATOM | 497 | CD | LYS | 59 | 13.396 | 39.378 | 16.062 | 1.00 | 71.44 | A |
| ATOM | 498 | CE | LYS | 59 | 13.779 | 40.782 | 16.526 | 1.00 | 75.40 | A |
| ATOM | 499 | NZ | LYS | 59 | 14.401 | 40.784 | 17.891 | 1.00 | 78.67 | A |
| ATOM | 500 | HZ1 | LYS | 59 | 14.668 | 41.742 | 18.185 | 0.00 | 0.00 | A |
| ATOM | 501 | HZ2 | LYS | 59 | 15.249 | 40.170 | 17.860 | 0.00 | 0.00 | A |
| ATOM | 502 | HZ3 | LYS | 59 | 13.715 | 40.392 | 18.565 | 0.00 | 0.00 | A |
| ATOM | 503 | C | LYS | 59 | 13.985 | 39.146 | 11.747 | 1.00 | 62.99 | A |
| ATOM | 504 | O | LYS | 59 | 13.380 | 40.061 | 11.210 | 1.00 | 65.98 | A |
| ATOM | 505 | N | LEU | 60 | 15.309 | 39.058 | 11.749 | 1.00 | 63.24 | A |
| ATOM | 506 | H | LEU | 60 | 15.724 | 38.273 | 12.166 | 0.00 | 0.00 | A |
| ATOM | 507 | CA | LEU | 60 | 16.133 | 40.082 | 11.120 | 1.00 | 64.25 | A |
| ATOM | 508 | CB | LEU | 60 | 17.598 | 39.892 | 11.495 | 1.00 | 62.01 | A |
| ATOM | 509 | CG | LEU | 60 | 18.060 | 40.343 | 12.873 | 1.00 | 60.09 | A |
| ATOM | 510 | CD1 | LEU | 60 | 17.318 | 39.592 | 13.967 | 1.00 | 57.96 | A |
| ATOM | 511 | CD2 | LEU | 60 | 19.562 | 40.113 | 12.955 | 1.00 | 59.64 | A |
| ATOM | 512 | C | LEU | 60 | 16.016 | 40.129 | 9.592 | 1.00 | 66.25 | A |
| ATOM | 513 | O | LEU | 60 | 15.972 | 41.211 | 9.005 | 1.00 | 67.84 | A |
| ATOM | 514 | N | PHE | 61 | 16.000 | 38.963 | 8.952 | 1.00 | 67.62 | A |
| ATOM | 515 | H | PHE | 61 | 16.024 | 38.131 | 9.459 | 0.00 | 0.00 | A |
| ATOM | 516 | CA | PHE | 61 | 15.920 | 38.890 | 7.500 | 1.00 | 69.09 | A |
| ATOM | 517 | CB | PHE | 61 | 17.234 | 38.341 | 6.923 | 1.00 | 67.05 | A |
| ATOM | 518 | CG | PHE | 61 | 18.454 | 38.726 | 7.710 | 1.00 | 64.58 | A |
| ATOM | 519 | CD1 | PHE | 61 | 18.883 | 40.041 | 7.756 | 1.00 | 63.51 | A |
| ATOM | 520 | CD2 | PHE | 61 | 19.144 | 37.772 | 8.449 | 1.00 | 65.04 | A |
| ATOM | 521 | CE1 | PHE | 61 | 19.977 | 40.403 | 8.533 | 1.00 | 64.54 | A |
| ATOM | 522 | CE2 | PHE | 61 | 20.241 | 38.123 | 9.231 | 1.00 | 65.04 | A |
| ATOM | 523 | CZ | PHE | 61 | 20.658 | 39.442 | 9.275 | 1.00 | 64.92 | A |
| ATOM | 524 | C | PHE | 61 | 14.761 | 37.991 | 7.077 | 1.00 | 73.13 | A |
| ATOM | 525 | O | PHE | 61 | 14.954 | 36.808 | 6.803 | 1.00 | 73.94 | A |
| ATOM | 526 | N | PRO | 62 | 13.545 | 38.553 | 6.987 | 1.00 | 76.93 | A |
| ATOM | 527 | CD | PRO | 62 | 13.254 | 39.962 | 7.302 | 1.00 | 78.61 | A |
| ATOM | 528 | CA | PRO | 62 | 12.313 | 37.860 | 6.601 | 1.00 | 80.94 | A |
| ATOM | 529 | CB | PRO | 62 | 11.360 | 39.012 | 6.312 | 1.00 | 78.76 | A |
| ATOM | 530 | CG | PRO | 62 | 11.733 | 39.980 | 7.360 | 1.00 | 78.88 | A |
| ATOM | 531 | C | PRO | 62 | 12.389 | 36.898 | 5.417 | 1.00 | 85.73 | A |
| ATOM | 532 | O | PRO | 62 | 12.815 | 37.256 | 4.313 | 1.00 | 85.79 | A |
| ATOM | 533 | N | ASP | 63 | 11.891 | 35.690 | 5.662 | 1.00 | 90.76 | A |
| ATOM | 534 | H | ASP | 63 | 11.573 | 35.490 | 6.564 | 0.00 | 0.00 | A |
| ATOM | 535 | CA | ASP | 63 | 11.839 | 34.617 | 4.671 | 1.00 | 94.44 | A |
| ATOM | 536 | CB | ASP | 63 | 11.105 | 33.414 | 5.292 | 1.00 | 94.82 | A |
| ATOM | 537 | CG | ASP | 63 | 11.585 | 32.074 | 4.749 | 1.00 | 94.81 | A |
| ATOM | 538 | OD1 | ASP | 63 | 12.810 | 31.886 | 4.583 | 1.00 | 95.75 | A |
| ATOM | 539 | OD2 | ASP | 63 | 10.733 | 31.191 | 4.518 | 1.00 | 94.23 | A |
| ATOM | 540 | C | ASP | 63 | 11.080 | 35.118 | 3.431 | 1.00 | 96.02 | A |
| ATOM | 541 | O | ASP | 63 | 11.437 | 34.811 | 2.288 | 1.00 | 96.14 | A |
| ATOM | 542 | N | THR | 64 | 10.069 | 35.948 | 3.677 | 1.00 | 97.90 | A |
| ATOM | 543 | H | THR | 64 | 9.857 | 36.179 | 4.600 | 0.00 | 0.00 | A |
| ATOM | 544 | CA | THR | 64 | 9.227 | 36.510 | 2.623 | 1.00 | 99.75 | A |
| ATOM | 545 | CB | THR | 64 | 7.839 | 36.890 | 3.180 | 1.00 | 100.00 | A |
| ATOM | 546 | OG1 | THR | 64 | 7.999 | 37.727 | 4.338 | 1.00 | 100.00 | A |
| ATOM | 547 | HG1 | THR | 64 | 8.175 | 38.629 | 4.046 | 0.00 | 0.00 | A |
| ATOM | 548 | CG2 | THR | 64 | 7.050 | 35.633 | 3.554 | 1.00 | 100.00 | A |
| ATOM | 549 | C | THR | 64 | 9.799 | 37.716 | 1.868 | 1.00 | 99.98 | A |
| ATOM | 550 | O | THR | 64 | 9.396 | 37.976 | 0.730 | 1.00 | 100.00 | A |
| ATOM | 551 | N | ASP | 65 | 10.693 | 38.471 | 2.506 | 1.00 | 99.66 | A |
| ATOM | 552 | H | ASP | 65 | 11.009 | 38.234 | 3.398 | 0.00 | 0.00 | A |
| ATOM | 553 | CA | ASP | 65 | 11.294 | 39.632 | 1.856 | 1.00 | 99.22 | A |
| ATOM | 554 | CB | ASP | 65 | 12.192 | 40.387 | 2.838 | 1.00 | 98.59 | A |
| ATOM | 555 | CG | ASP | 65 | 12.582 | 41.774 | 2.343 | 1.00 | 98.43 | A |
| ATOM | 556 | OD1 | ASP | 65 | 13.186 | 41.885 | 1.252 | 1.00 | 98.79 | A |
| ATOM | 557 | OD2 | ASP | 65 | 12.299 | 42.757 | 3.060 | 1.00 | 97.43 | A |
| ATOM | 558 | C | ASP | 65 | 12.095 | 39.097 | 0.660 | 1.00 | 99.82 | A |
| ATOM | 559 | O | ASP | 65 | 13.013 | 38.271 | 0.823 | 1.00 | 99.02 | A |
| ATOM | 560 | N | PRO | 66 | 11.716 | 39.521 | −0.567 | 1.00 | 100.00 | A |
| ATOM | 561 | CD | PRO | 66 | 10.638 | 40.509 | −0.785 | 1.00 | 100.00 | A |
| ATOM | 562 | CA | PRO | 66 | 12.327 | 39.136 | −1.850 | 1.00 | 100.00 | A |
| ATOM | 563 | CB | PRO | 66 | 11.464 | 39.879 | −2.879 | 1.00 | 100.00 | A |
| ATOM | 564 | CG | PRO | 66 | 11.002 | 41.098 | −2.129 | 1.00 | 100.00 | A |
| ATOM | 565 | C | PRO | 66 | 13.828 | 39.405 | −2.053 | 1.00 | 100.00 | A |
| ATOM | 566 | O | PRO | 66 | 14.459 | 38.752 | −2.893 | 1.00 | 100.00 | A |
| ATOM | 567 | N | ALA | 67 | 14.401 | 40.339 | −1.292 | 1.00 | 99.87 | A |
| ATOM | 568 | H | ALA | 67 | 13.867 | 40.834 | −0.622 | 0.00 | 0.00 | A |
| ATOM | 569 | CA | ALA | 67 | 15.830 | 40.661 | −1.409 | 1.00 | 99.67 | A |
| ATOM | 570 | CB | ALA | 67 | 16.143 | 41.932 | −0.620 | 1.00 | 99.96 | A |
| ATOM | 571 | C | ALA | 67 | 16.731 | 39.498 | −0.941 | 1.00 | 98.83 | A |
| ATOM | 572 | O | ALA | 67 | 17.858 | 39.310 | −1.429 | 1.00 | 98.18 | A |
| ATOM | 573 | N | PHE | 68 | 16.212 | 38.711 | −0.004 | 1.00 | 96.83 | A |
| ATOM | 574 | H | PHE | 68 | 15.318 | 38.924 | 0.345 | 0.00 | 0.00 | A |
| ATOM | 575 | CA | PHE | 68 | 16.936 | 37.572 | 0.536 | 1.00 | 94.17 | A |
| ATOM | 576 | CB | PHE | 68 | 16.424 | 37.248 | 1.935 | 1.00 | 93.68 | A |
| ATOM | 577 | CG | PHE | 68 | 16.255 | 38.449 | 2.796 | 1.00 | 92.75 | A |
| ATOM | 578 | CD1 | PHE | 68 | 15.087 | 38.642 | 3.509 | 1.00 | 92.82 | A |
| ATOM | 579 | CD2 | PHE | 68 | 17.256 | 39.411 | 2.870 | 1.00 | 92.49 | A |
| ATOM | 580 | CE1 | PHE | 68 | 14.912 | 39.784 | 4.289 | 1.00 | 93.37 | A |
| ATOM | 581 | CE2 | PHE | 68 | 17.091 | 40.557 | 3.646 | 1.00 | 93.07 | A |
| ATOM | 582 | CZ | PHE | 68 | 15.914 | 40.744 | 4.358 | 1.00 | 92.90 | A |
| ATOM | 583 | C | PHE | 68 | 16.778 | 36.354 | −0.359 | 1.00 | 92.77 | A |
| ATOM | 584 | O | PHE | 68 | 17.168 | 35.247 | 0.019 | 1.00 | 92.99 | A |
| ATOM | 585 | N | LYS | 69 | 16.170 | 36.541 | −1.524 | 1.00 | 90.94 | A |
| ATOM | 586 | H | LYS | 69 | 15.902 | 37.432 | −1.832 | 0.00 | 0.00 | A |
| ATOM | 587 | CA | LYS | 69 | 15.979 | 35.438 | −2.445 | 1.00 | 89.95 | A |
| ATOM | 588 | CB | LYS | 69 | 14.896 | 35.762 | −3.469 | 1.00 | 92.31 | A |
| ATOM | 589 | CG | LYS | 69 | 14.495 | 34.562 | −4.301 | 1.00 | 95.88 | A |
| ATOM | 590 | CD | LYS | 69 | 14.257 | 34.956 | −5.748 | 1.00 | 99.53 | A |
| ATOM | 591 | CE | LYS | 69 | 14.335 | 33.738 | −6.666 | 1.00 | 100.00 | A |
| ATOM | 592 | NZ | LYS | 69 | 14.309 | 34.114 | −8.111 | 1.00 | 100.00 | A |
| ATOM | 593 | HZ1 | LYS | 69 | 14.382 | 33.251 | −8.687 | 0.00 | 0.00 | A |
| ATOM | 594 | HZ2 | LYS | 69 | 15.104 | 34.750 | −8.317 | 0.00 | 0.00 | A |
| ATOM | 595 | HZ3 | LYS | 69 | 13.408 | 34.593 | −8.315 | 0.00 | 0.00 | A |
| ATOM | 596 | C | LYS | 69 | 17.306 | 35.129 | −3.140 | 1.00 | 88.12 | A |
| ATOM | 597 | O | LYS | 69 | 17.767 | 35.883 | −4.006 | 1.00 | 88.21 | A |
| ATOM | 598 | N | GLY | 70 | 17.916 | 34.024 | −2.718 | 1.00 | 85.08 | A |
| ATOM | 599 | H | GLY | 70 | 17.533 | 33.522 | −1.989 | 0.00 | 0.00 | A |
| ATOM | 600 | CA | GLY | 70 | 19.190 | 33.584 | −3.254 | 1.00 | 79.78 | A |
| ATOM | 601 | C | GLY | 70 | 20.317 | 34.159 | −2.419 | 1.00 | 76.22 | A |
| ATOM | 602 | O | GLY | 70 | 21.492 | 33.883 | −2.682 | 1.00 | 76.33 | A |
| ATOM | 603 | N | ALA | 71 | 19.949 | 34.916 | −1.380 | 1.00 | 72.78 | A |
| ATOM | 604 | H | ALA | 71 | 18.997 | 35.025 | −1.198 | 0.00 | 0.00 | A |
| ATOM | 605 | CA | ALA | 71 | 20.909 | 35.577 | −0.488 | 1.00 | 69.50 | A |
| ATOM | 606 | CB | ALA | 71 | 20.182 | 36.318 | 0.648 | 1.00 | 67.54 | A |
| ATOM | 607 | C | ALA | 71 | 22.010 | 34.676 | 0.079 | 1.00 | 66.00 | A |
| ATOM | 608 | O | ALA | 71 | 21.754 | 33.572 | 0.574 | 1.00 | 69.09 | A |
| ATOM | 609 | N | ASP | 72 | 23.237 | 35.175 | −0.015 | 1.00 | 58.89 | A |
| ATOM | 610 | H | ASP | 72 | 23.377 | 36.064 | −0.403 | 0.00 | 0.00 | A |
| ATOM | 611 | CA | ASP | 72 | 24.425 | 34.499 | 0.467 | 1.00 | 50.29 | A |
| ATOM | 612 | CB | ASP | 72 | 25.624 | 35.328 | −0.004 | 1.00 | 49.48 | A |
| ATOM | 613 | CG | ASP | 72 | 26.937 | 34.867 | 0.559 | 1.00 | 51.87 | A |
| ATOM | 614 | OD1 | ASP | 72 | 27.069 | 34.752 | 1.787 | 1.00 | 58.78 | A |
| ATOM | 615 | OD2 | ASP | 72 | 27.891 | 34.698 | −0.220 | 1.00 | 52.96 | A |
| ATOM | 616 | C | ASP | 72 | 24.294 | 34.448 | 1.997 | 1.00 | 46.29 | A |
| ATOM | 617 | O | ASP | 72 | 24.260 | 35.483 | 2.662 | 1.00 | 46.35 | A |
| ATOM | 618 | N | SER | 73 | 24.162 | 33.249 | 2.552 | 1.00 | 40.41 | A |
| ATOM | 619 | H | SER | 73 | 24.166 | 32.449 | 1.974 | 0.00 | 0.00 | A |
| ATOM | 620 | CA | SER | 73 | 24.021 | 33.107 | 3.988 | 1.00 | 36.55 | A |
| ATOM | 621 | CB | SER | 73 | 23.797 | 31.656 | 4.374 | 1.00 | 37.80 | A |
| ATOM | 622 | OG | SER | 73 | 22.470 | 31.246 | 4.085 | 1.00 | 39.02 | A |
| ATOM | 623 | HG | SER | 73 | 22.733 | 30.451 | 3.595 | 0.00 | 0.00 | A |
| ATOM | 624 | C | SER | 73 | 25.164 | 33.687 | 4.799 | 1.00 | 35.32 | A |
| ATOM | 625 | O | SER | 73 | 25.001 | 33.946 | 5.994 | 1.00 | 37.10 | A |
| ATOM | 626 | N | ARG | 74 | 26.329 | 33.854 | 4.186 | 1.00 | 32.72 | A |
| ATOM | 627 | H | ARG | 74 | 26.433 | 33.582 | 3.246 | 0.00 | 0.00 | A |
| ATOM | 628 | CA | ARG | 74 | 27.452 | 34.442 | 4.896 | 1.00 | 32.85 | A |
| ATOM | 629 | CB | ARG | 74 | 28.768 | 34.262 | 4.157 | 1.00 | 30.87 | A |
| ATOM | 630 | CG | ARG | 74 | 29.291 | 32.853 | 4.140 | 1.00 | 31.13 | A |
| ATOM | 631 | CD | ARG | 74 | 30.595 | 32.794 | 3.374 | 1.00 | 33.89 | A |
| ATOM | 632 | NE | ARG | 74 | 31.667 | 33.487 | 4.083 | 1.00 | 38.69 | A |
| ATOM | 633 | HE | ARG | 74 | 31.461 | 33.811 | 4.980 | 0.00 | 0.00 | A |
| ATOM | 634 | CZ | ARG | 74 | 32.892 | 33.690 | 3.606 | 1.00 | 39.76 | A |
| ATOM | 635 | NH1 | ARG | 74 | 33.793 | 34.322 | 4.348 | 1.00 | 43.59 | A |
| ATOM | 636 | HH11 | ARG | 74 | 33.521 | 34.627 | 5.278 | 0.00 | 0.00 | A |
| ATOM | 637 | HH12 | ARG | 74 | 34.763 | 34.523 | 4.121 | 0.00 | 0.00 | A |
| ATOM | 638 | NH2 | ARG | 74 | 33.215 | 33.284 | 2.387 | 1.00 | 38.65 | A |
| ATOM | 639 | HH21 | ARG | 74 | 32.543 | 32.815 | 1.805 | 0.00 | 0.00 | A |
| ATOM | 640 | HH22 | ARG | 74 | 34.144 | 33.422 | 2.032 | 0.00 | 0.00 | A |
| ATOM | 641 | C | ARG | 74 | 27.150 | 35.910 | 5.018 | 1.00 | 35.25 | A |
| ATOM | 642 | O | ARG | 74 | 27.612 | 36.563 | 5.944 | 1.00 | 37.83 | A |
| ATOM | 643 | N | GLU | 75 | 26.396 | 36.449 | 4.068 | 1.00 | 38.00 | A |
| ATOM | 644 | H | GLU | 75 | 26.107 | 35.914 | 3.289 | 0.00 | 0.00 | A |
| ATOM | 645 | CA | GLU | 75 | 26.025 | 37.855 | 4.137 | 1.00 | 41.91 | A |
| ATOM | 646 | CB | GLU | 75 | 25.272 | 38.298 | 2.900 | 1.00 | 47.23 | A |
| ATOM | 647 | CG | GLU | 75 | 26.137 | 38.858 | 1.805 | 1.00 | 57.23 | A |
| ATOM | 648 | CD | GLU | 75 | 25.298 | 39.591 | 0.772 | 1.00 | 64.29 | A |
| ATOM | 649 | OE1 | GLU | 75 | 25.021 | 40.792 | 0.997 | 1.00 | 67.70 | A |
| ATOM | 650 | OE2 | GLU | 75 | 24.890 | 38.965 | −0.239 | 1.00 | 67.50 | A |
| ATOM | 651 | C | GLU | 75 | 25.140 | 38.052 | 5.352 | 1.00 | 40.94 | A |
| ATOM | 652 | O | GLU | 75 | 25.371 | 38.949 | 6.155 | 1.00 | 43.39 | A |
| ATOM | 653 | N | LEU | 76 | 24.134 | 37.202 | 5.501 | 1.00 | 38.04 | A |
| ATOM | 654 | H | LEU | 76 | 24.001 | 36.521 | 4.806 | 0.00 | 0.00 | A |
| ATOM | 655 | CA | LEU | 76 | 23.254 | 37.302 | 6.650 | 1.00 | 35.70 | A |
| ATOM | 656 | CB | LEU | 76 | 22.138 | 36.271 | 6.568 | 1.00 | 39.63 | A |
| ATOM | 657 | CG | LEU | 76 | 21.312 | 36.292 | 5.282 | 1.00 | 42.54 | A |
| ATOM | 658 | CD1 | LEU | 76 | 20.119 | 35.376 | 5.446 | 1.00 | 44.33 | A |
| ATOM | 659 | CD2 | LEU | 76 | 20.837 | 37.701 | 4.985 | 1.00 | 45.69 | A |
| ATOM | 660 | C | LEU | 76 | 24.059 | 37.080 | 7.916 | 1.00 | 33.52 | A |
| ATOM | 661 | O | LEU | 76 | 23.874 | 37.784 | 8.898 | 1.00 | 34.49 | A |
| ATOM | 662 | N | LEU | 77 | 24.965 | 36.111 | 7.894 | 1.00 | 31.57 | A |
| ATOM | 663 | H | LEU | 77 | 25.086 | 35.561 | 7.093 | 0.00 | 0.00 | A |
| ATOM | 664 | CA | LEU | 77 | 25.777 | 35.842 | 9.067 | 1.00 | 30.39 | A |
| ATOM | 665 | CB | LEU | 77 | 26.742 | 34.685 | 8.816 | 1.00 | 28.75 | A |
| ATOM | 666 | CG | LEU | 77 | 27.762 | 34.433 | 9.937 | 1.00 | 28.05 | A |
| ATOM | 667 | CD1 | LEU | 77 | 27.044 | 34.201 | 11.255 | 1.00 | 25.52 | A |
| ATOM | 668 | CD2 | LEU | 77 | 28.659 | 33.258 | 9.589 | 1.00 | 22.53 | A |
| ATOM | 669 | C | LEU | 77 | 26.556 | 37.075 | 9.496 | 1.00 | 31.14 | A |
| ATOM | 670 | O | LEU | 77 | 26.525 | 37.455 | 10.662 | 1.00 | 32.46 | A |
| ATOM | 671 | N | ARG | 78 | 27.223 | 37.722 | 8.549 | 1.00 | 32.65 | A |
| ATOM | 672 | H | ARG | 78 | 27.191 | 37.393 | 7.628 | 0.00 | 0.00 | A |
| ATOM | 673 | CA | ARG | 78 | 28.021 | 38.900 | 8.866 | 1.00 | 34.44 | A |
| ATOM | 674 | CB | ARG | 78 | 28.841 | 39.339 | 7.657 | 1.00 | 34.46 | A |
| ATOM | 675 | CG | ARG | 78 | 29.878 | 38.331 | 7.209 | 1.00 | 37.09 | A |
| ATOM | 676 | CD | ARG | 78 | 30.672 | 38.838 | 6.015 | 1.00 | 40.02 | A |
| ATOM | 677 | NE | ARG | 78 | 30.774 | 37.832 | 4.958 | 1.00 | 48.15 | A |
| ATOM | 678 | HE | ARG | 78 | 31.366 | 37.072 | 5.199 | 0.00 | 0.00 | A |
| ATOM | 679 | CZ | ARG | 78 | 30.091 | 37.883 | 3.815 | 1.00 | 51.62 | A |
| ATOM | 680 | NH1 | ARG | 78 | 30.229 | 36.923 | 2.897 | 1.00 | 54.51 | A |
| ATOM | 681 | HH11 | ARG | 78 | 30.817 | 36.139 | 3.091 | 0.00 | 0.00 | A |
| ATOM | 682 | HH12 | ARG | 78 | 29.703 | 36.895 | 2.035 | 0.00 | 0.00 | A |
| ATOM | 683 | NH2 | ARG | 78 | 29.263 | 38.903 | 3.589 | 1.00 | 53.87 | A |
| ATOM | 684 | HH21 | ARG | 78 | 29.151 | 39.621 | 4.281 | 0.00 | 0.00 | A |
| ATOM | 685 | HH22 | ARG | 78 | 28.696 | 38.979 | 2.758 | 0.00 | 0.00 | A |
| ATOM | 686 | C | ARG | 78 | 27.213 | 40.068 | 9.426 | 1.00 | 35.38 | A |
| ATOM | 687 | O | ARG | 78 | 27.694 | 40.779 | 10.304 | 1.00 | 37.61 | A |
| ATOM | 688 | N | GLU | 79 | 25.992 | 40.256 | 8.928 | 1.00 | 35.23 | A |
| ATOM | 689 | H | GLU | 79 | 25.671 | 39.668 | 8.212 | 0.00 | 0.00 | A |
| ATOM | 690 | CA | GLU | 79 | 25.115 | 41.323 | 9.397 | 1.00 | 36.05 | A |
| ATOM | 691 | CB | GLU | 79 | 23.888 | 41.457 | 8.492 | 1.00 | 37.93 | A |
| ATOM | 692 | CG | GLU | 79 | 22.874 | 42.523 | 8.922 | 1.00 | 43.20 | A |
| ATOM | 693 | CD | GLU | 79 | 23.438 | 43.957 | 8.978 | 1.00 | 49.20 | A |
| ATOM | 694 | OE1 | GLU | 79 | 24.641 | 44.191 | 8.707 | 1.00 | 52.30 | A |
| ATOM | 695 | OE2 | GLU | 79 | 22.657 | 44.874 | 9.305 | 1.00 | 50.39 | A |
| ATOM | 696 | C | GLU | 79 | 24.666 | 41.023 | 10.818 | 1.00 | 38.06 | A |
| ATOM | 697 | O | GLU | 79 | 24.827 | 41.850 | 11.716 | 1.00 | 40.86 | A |
| ATOM | 698 | N | ALA | 80 | 24.101 | 39.837 | 11.021 | 1.00 | 37.90 | A |
| ATOM | 699 | H | ALA | 80 | 23.991 | 39.234 | 10.255 | 0.00 | 0.00 | A |
| ATOM | 700 | CA | ALA | 80 | 23.653 | 39.421 | 12.335 | 1.00 | 35.54 | A |
| ATOM | 701 | CB | ALA | 80 | 23.245 | 37.981 | 12.306 | 1.00 | 36.59 | A |
| ATOM | 702 | C | ALA | 80 | 24.800 | 39.616 | 13.308 | 1.00 | 36.02 | A |
| ATOM | 703 | O | ALA | 80 | 24.589 | 40.058 | 14.433 | 1.00 | 37.90 | A |
| ATOM | 704 | N | TRP | 81 | 26.021 | 39.335 | 12.857 | 1.00 | 34.84 | A |
| ATOM | 705 | H | TRP | 81 | 26.136 | 38.989 | 11.946 | 0.00 | 0.00 | A |
| ATOM | 706 | CA | TRP | 81 | 27.202 | 39.501 | 13.702 | 1.00 | 34.08 | A |
| ATOM | 707 | CB | TRP | 81 | 28.410 | 38.781 | 13.096 | 1.00 | 28.57 | A |
| ATOM | 708 | CG | TRP | 81 | 29.659 | 38.869 | 13.918 | 1.00 | 25.44 | A |
| ATOM | 709 | CD2 | TRP | 81 | 29.830 | 38.498 | 15.301 | 1.00 | 24.78 | A |
| ATOM | 710 | CE2 | TRP | 81 | 31.162 | 38.794 | 15.648 | 1.00 | 23.97 | A |
| ATOM | 711 | CE3 | TRP | 81 | 28.988 | 37.948 | 16.275 | 1.00 | 25.49 | A |
| ATOM | 712 | CD1 | TRP | 81 | 30.855 | 39.346 | 13.506 | 1.00 | 26.77 | A |
| ATOM | 713 | NE1 | TRP | 81 | 31.765 | 39.309 | 14.536 | 1.00 | 27.33 | A |
| ATOM | 714 | HE1 | TRP | 81 | 32.716 | 39.564 | 14.484 | 0.00 | 0.00 | A |
| ATOM | 715 | CZ2 | TRP | 81 | 31.675 | 38.563 | 16.924 | 1.00 | 22.40 | A |
| ATOM | 716 | CZ3 | TRP | 81 | 29.498 | 37.717 | 17.544 | 1.00 | 23.10 | A |
| ATOM | 717 | CH2 | TRP | 81 | 30.830 | 38.025 | 17.855 | 1.00 | 23.72 | A |
| ATOM | 718 | C | TRP | 81 | 27.513 | 40.981 | 13.943 | 1.00 | 37.02 | A |
| ATOM | 719 | O | TRP | 81 | 27.911 | 41.367 | 15.041 | 1.00 | 37.25 | A |
| ATOM | 720 | N | ARG | 82 | 27.320 | 41.814 | 12.926 | 1.00 | 39.86 | A |
| ATOM | 721 | H | ARG | 82 | 27.011 | 41.462 | 12.064 | 0.00 | 0.00 | A |
| ATOM | 722 | CA | ARG | 82 | 27.571 | 43.242 | 13.065 | 1.00 | 41.81 | A |
| ATOM | 723 | CB | ARG | 82 | 27.288 | 43.978 | 11.760 | 1.00 | 44.88 | A |
| ATOM | 724 | CG | ARG | 82 | 27.469 | 45.492 | 11.862 | 1.00 | 51.33 | A |
| ATOM | 725 | CD | ARG | 82 | 26.946 | 46.249 | 10.625 | 1.00 | 55.23 | A |
| ATOM | 726 | NE | ARG | 82 | 25.485 | 46.234 | 10.481 | 1.00 | 56.62 | A |
| ATOM | 727 | HE | ARG | 82 | 25.149 | 45.720 | 9.704 | 0.00 | 0.00 | A |
| ATOM | 728 | CZ | ARG | 82 | 24.636 | 46.835 | 11.309 | 1.00 | 57.16 | A |
| ATOM | 729 | NH1 | ARG | 82 | 23.333 | 46.763 | 11.082 | 1.00 | 58.31 | A |
| ATOM | 730 | HH11 | ARG | 82 | 23.054 | 46.251 | 10.259 | 0.00 | 0.00 | A |
| ATOM | 731 | HH12 | ARG | 82 | 22.619 | 47.176 | 11.639 | 0.00 | 0.00 | A |
| ATOM | 732 | NH2 | ARG | 82 | 25.089 | 47.494 | 12.371 | 1.00 | 58.27 | A |
| ATOM | 733 | HH21 | ARG | 82 | 26.076 | 47.534 | 12.546 | 0.00 | 0.00 | A |
| ATOM | 734 | HH22 | ARG | 82 | 24.487 | 47.959 | 13.020 | 0.00 | 0.00 | A |
| ATOM | 735 | C | ARG | 82 | 26.634 | 43.770 | 14.130 | 1.00 | 43.13 | A |
| ATOM | 736 | O | ARG | 82 | 27.050 | 44.464 | 15.060 | 1.00 | 44.01 | A |
| ATOM | 737 | N | ARG | 83 | 25.364 | 43.422 | 13.988 | 1.00 | 43.63 | A |
| ATOM | 738 | H | ARG | 83 | 25.125 | 42.843 | 13.239 | 0.00 | 0.00 | A |
| ATOM | 739 | CA | ARG | 83 | 24.345 | 43.853 | 14.923 | 1.00 | 45.45 | A |
| ATOM | 740 | CB | ARG | 83 | 22.979 | 43.373 | 14.459 | 1.00 | 46.37 | A |
| ATOM | 741 | CG | ARG | 83 | 22.706 | 43.775 | 13.048 | 1.00 | 52.37 | A |
| ATOM | 742 | CD | ARG | 83 | 21.240 | 43.723 | 12.718 | 1.00 | 60.02 | A |
| ATOM | 743 | NE | ARG | 83 | 21.063 | 44.018 | 11.303 | 1.00 | 66.19 | A |
| ATOM | 744 | HE | ARG | 83 | 21.906 | 44.111 | 10.818 | 0.00 | 0.00 | A |
| ATOM | 745 | CZ | ARG | 83 | 19.895 | 44.084 | 10.671 | 1.00 | 69.32 | A |
| ATOM | 746 | NH1 | ARG | 83 | 19.870 | 44.358 | 9.368 | 1.00 | 72.83 | A |
| ATOM | 747 | HH11 | ARG | 83 | 20.769 | 44.495 | 8.908 | 0.00 | 0.00 | A |
| ATOM | 748 | HH12 | ARG | 83 | 19.046 | 44.414 | 8.805 | 0.00 | 0.00 | A |
| ATOM | 749 | NH2 | ARG | 83 | 18.761 | 43.870 | 11.334 | 1.00 | 72.50 | A |
| ATOM | 750 | HH21 | ARG | 83 | 18.789 | 43.652 | 12.313 | 0.00 | 0.00 | A |
| ATOM | 751 | HH22 | ARG | 83 | 17.859 | 43.892 | 10.894 | 0.00 | 0.00 | A |
| ATOM | 752 | C | ARG | 83 | 24.636 | 43.347 | 16.325 | 1.00 | 46.09 | A |
| ATOM | 753 | O | ARG | 83 | 24.457 | 44.079 | 17.310 | 1.00 | 48.29 | A |
| ATOM | 754 | N | ILE | 84 | 25.114 | 42.110 | 16.414 | 1.00 | 43.31 | A |
| ATOM | 755 | H | ILE | 84 | 25.236 | 41.576 | 15.602 | 0.00 | 0.00 | A |
| ATOM | 756 | CA | ILE | 84 | 25.425 | 41.522 | 17.702 | 1.00 | 41.01 | A |
| ATOM | 757 | CB | ILE | 84 | 25.775 | 40.028 | 17.554 | 1.00 | 41.01 | A |
| ATOM | 758 | CG2 | ILE | 84 | 26.346 | 39.478 | 18.852 | 1.00 | 39.70 | A |
| ATOM | 759 | CG1 | ILE | 84 | 24.530 | 39.242 | 17.135 | 1.00 | 37.86 | A |
| ATOM | 760 | CD1 | ILE | 84 | 24.825 | 37.844 | 16.710 | 1.00 | 35.45 | A |
| ATOM | 761 | C | ILE | 84 | 26.560 | 42.277 | 18.376 | 1.00 | 41.06 | A |
| ATOM | 762 | O | ILE | 84 | 26.479 | 42.606 | 19.554 | 1.00 | 41.58 | A |
| ATOM | 763 | N | GLN | 85 | 27.600 | 42.591 | 17.619 | 1.00 | 41.70 | A |
| ATOM | 764 | H | GLN | 85 | 27.599 | 42.334 | 16.675 | 0.00 | 0.00 | A |
| ATOM | 765 | CA | GLN | 85 | 28.739 | 43.305 | 18.176 | 1.00 | 44.62 | A |
| ATOM | 766 | CB | GLN | 85 | 29.852 | 43.428 | 17.146 | 1.00 | 46.34 | A |
| ATOM | 767 | CG | GLN | 85 | 30.418 | 42.104 | 16.693 | 1.00 | 51.43 | A |
| ATOM | 768 | CD | GLN | 85 | 31.683 | 42.268 | 15.880 | 1.00 | 54.36 | A |
| ATOM | 769 | OE1 | GLN | 85 | 32.789 | 42.110 | 16.397 | 1.00 | 57.50 | A |
| ATOM | 770 | NE2 | GLN | 85 | 31.530 | 42.587 | 14.599 | 1.00 | 56.44 | A |
| ATOM | 771 | HE21 | GLN | 85 | 30.623 | 42.693 | 14.249 | 0.00 | 0.00 | A |
| ATOM | 772 | HE22 | GLN | 85 | 32.349 | 42.692 | 14.078 | 0.00 | 0.00 | A |
| ATOM | 773 | C | GLN | 85 | 28.338 | 44.687 | 18.651 | 1.00 | 45.56 | A |
| ATOM | 774 | O | GLN | 85 | 28.828 | 45.167 | 19.675 | 1.00 | 46.65 | A |
| ATOM | 775 | N | ALA | 86 | 27.461 | 45.327 | 17.885 | 1.00 | 45.95 | A |
| ATOM | 776 | H | ALA | 86 | 27.146 | 44.889 | 17.066 | 0.00 | 0.00 | A |
| ATOM | 777 | CA | ALA | 86 | 26.965 | 46.658 | 18.207 | 1.00 | 45.73 | A |
| ATOM | 778 | CB | ALA | 86 | 26.020 | 47.146 | 17.136 | 1.00 | 46.24 | A |
| ATOM | 779 | C | ALA | 86 | 26.253 | 46.628 | 19.538 | 1.00 | 46.82 | A |
| ATOM | 780 | O | ALA | 86 | 26.351 | 47.575 | 20.303 | 1.00 | 50.37 | A |
| ATOM | 781 | N | LYS | 87 | 25.534 | 45.541 | 19.818 | 1.00 | 47.14 | A |
| ATOM | 782 | H | LYS | 87 | 25.465 | 44.820 | 19.156 | 0.00 | 0.00 | A |
| ATOM | 783 | CA | LYS | 87 | 24.830 | 45.409 | 21.091 | 1.00 | 45.26 | A |
| ATOM | 784 | CB | LYS | 87 | 23.826 | 44.247 | 21.043 | 1.00 | 46.60 | A |
| ATOM | 785 | CG | LYS | 87 | 22.704 | 44.342 | 22.089 | 1.00 | 51.56 | A |
| ATOM | 786 | CD | LYS | 87 | 21.957 | 43.004 | 22.311 | 1.00 | 53.53 | A |
| ATOM | 787 | CE | LYS | 87 | 20.940 | 43.086 | 23.475 | 1.00 | 54.41 | A |
| ATOM | 788 | NZ | LYS | 87 | 20.820 | 41.817 | 24.280 | 1.00 | 52.49 | A |
| ATOM | 789 | HZ1 | LYS | 87 | 20.144 | 41.923 | 25.083 | 0.00 | 0.00 | A |
| ATOM | 790 | HZ2 | LYS | 87 | 21.737 | 41.574 | 24.700 | 0.00 | 0.00 | A |
| ATOM | 791 | HZ3 | LYS | 87 | 20.526 | 41.020 | 23.682 | 0.00 | 0.00 | A |
| ATOM | 792 | C | LYS | 87 | 25.865 | 45.210 | 22.220 | 1.00 | 44.28 | A |
| ATOM | 793 | O | LYS | 87 | 25.503 | 45.017 | 23.380 | 1.00 | 44.29 | A |
| ATOM | 794 | N | GLY | 88 | 27.149 | 45.231 | 21.861 | 1.00 | 42.24 | A |
| ATOM | 795 | H | GLY | 88 | 27.420 | 45.316 | 20.936 | 0.00 | 0.00 | A |
| ATOM | 796 | CA | GLY | 88 | 28.214 | 45.100 | 22.832 | 1.00 | 41.90 | A |
| ATOM | 797 | C | GLY | 88 | 28.833 | 43.734 | 23.059 | 1.00 | 44.70 | A |
| ATOM | 798 | O | GLY | 88 | 29.646 | 43.574 | 23.972 | 1.00 | 47.95 | A |
| ATOM | 799 | N | TYR | 89 | 28.523 | 42.750 | 22.224 | 1.00 | 44.81 | A |
| ATOM | 800 | H | TYR | 89 | 27.952 | 42.926 | 21.450 | 0.00 | 0.00 | A |
| ATOM | 801 | CA | TYR | 89 | 29.079 | 41.418 | 22.442 | 1.00 | 41.14 | A |
| ATOM | 802 | CB | TYR | 89 | 28.023 | 40.353 | 22.151 | 1.00 | 39.42 | A |
| ATOM | 803 | CG | TYR | 89 | 26.771 | 40.490 | 22.978 | 1.00 | 37.02 | A |
| ATOM | 804 | CD1 | TYR | 89 | 25.698 | 41.242 | 22.516 | 1.00 | 37.68 | A |
| ATOM | 805 | CE1 | TYR | 89 | 24.520 | 41.335 | 23.242 | 1.00 | 39.43 | A |
| ATOM | 806 | CD2 | TYR | 89 | 26.639 | 39.836 | 24.202 | 1.00 | 34.82 | A |
| ATOM | 807 | CE2 | TYR | 89 | 25.464 | 39.924 | 24.943 | 1.00 | 36.55 | A |
| ATOM | 808 | CZ | TYR | 89 | 24.402 | 40.674 | 24.451 | 1.00 | 40.43 | A |
| ATOM | 809 | OH | TYR | 89 | 23.205 | 40.763 | 25.140 | 1.00 | 44.43 | A |
| ATOM | 810 | HH | TYR | 89 | 23.317 | 40.299 | 25.977 | 0.00 | 0.00 | A |
| ATOM | 811 | C | TYR | 89 | 30.343 | 41.116 | 21.653 | 1.00 | 40.19 | A |
| ATOM | 812 | O | TYR | 89 | 30.662 | 41.801 | 20.686 | 1.00 | 40.57 | A |
| ATOM | 813 | N | THR | 90 | 31.081 | 40.113 | 22.118 | 1.00 | 39.81 | A |
| ATOM | 814 | H | THR | 90 | 30.797 | 39.650 | 22.935 | 0.00 | 0.00 | A |
| ATOM | 815 | CA | THR | 90 | 32.303 | 39.646 | 21.472 | 1.00 | 40.28 | A |
| ATOM | 816 | CB | THR | 90 | 33.575 | 40.028 | 22.253 | 1.00 | 40.25 | A |
| ATOM | 817 | OG1 | THR | 90 | 33.448 | 39.634 | 23.623 | 1.00 | 44.55 | A |
| ATOM | 818 | HG1 | THR | 90 | 32.759 | 40.181 | 24.018 | 0.00 | 0.00 | A |
| ATOM | 819 | CG2 | THR | 90 | 33.794 | 41.500 | 22.195 | 1.00 | 40.88 | A |
| ATOM | 820 | C | THR | 90 | 32.173 | 38.135 | 21.446 | 1.00 | 38.82 | A |
| ATOM | 821 | O | THR | 90 | 31.545 | 37.557 | 22.333 | 1.00 | 39.78 | A |
| ATOM | 822 | N | LEU | 91 | 32.759 | 37.498 | 20.443 | 1.00 | 36.74 | A |
| ATOM | 823 | H | LEU | 91 | 33.280 | 37.999 | 19.785 | 0.00 | 0.00 | A |
| ATOM | 824 | CA | LEU | 91 | 32.665 | 36.049 | 20.311 | 1.00 | 35.28 | A |
| ATOM | 825 | CB | LEU | 91 | 33.105 | 35.620 | 18.917 | 1.00 | 29.08 | A |
| ATOM | 826 | CG | LEU | 91 | 32.733 | 34.201 | 18.528 | 1.00 | 25.21 | A |
| ATOM | 827 | CD1 | LEU | 91 | 31.266 | 34.188 | 18.173 | 1.00 | 27.56 | A |
| ATOM | 828 | CD2 | LEU | 91 | 33.541 | 33.763 | 17.346 | 1.00 | 23.92 | A |
| ATOM | 829 | C | LEU | 91 | 33.467 | 35.257 | 21.340 | 1.00 | 37.01 | A |
| ATOM | 830 | O | LEU | 91 | 34.619 | 35.578 | 21.620 | 1.00 | 40.47 | A |
| ATOM | 831 | N | GLY | 92 | 32.836 | 34.238 | 21.915 | 1.00 | 37.24 | A |
| ATOM | 832 | H | GLY | 92 | 31.901 | 34.081 | 21.688 | 0.00 | 0.00 | A |
| ATOM | 833 | CA | GLY | 92 | 33.504 | 33.369 | 22.867 | 1.00 | 34.94 | A |
| ATOM | 834 | C | GLY | 92 | 33.987 | 32.243 | 21.979 | 1.00 | 34.60 | A |
| ATOM | 835 | O | GLY | 92 | 35.179 | 32.068 | 21.775 | 1.00 | 38.02 | A |
| ATOM | 836 | N | ASN | 93 | 33.039 | 31.511 | 21.407 | 1.00 | 32.07 | A |
| ATOM | 837 | H | ASN | 93 | 32.098 | 31.713 | 21.597 | 0.00 | 0.00 | A |
| ATOM | 838 | CA | ASN | 93 | 33.326 | 30.424 | 20.482 | 1.00 | 26.94 | A |
| ATOM | 839 | CB | ASN | 93 | 34.199 | 29.357 | 21.108 | 1.00 | 27.02 | A |
| ATOM | 840 | CG | ASN | 93 | 33.450 | 28.492 | 22.078 | 1.00 | 29.80 | A |
| ATOM | 841 | OD1 | ASN | 93 | 33.345 | 27.286 | 21.888 | 1.00 | 28.34 | A |
| ATOM | 842 | ND2 | ASN | 93 | 32.945 | 29.098 | 23.144 | 1.00 | 33.69 | A |
| ATOM | 843 | HD21 | ASN | 93 | 33.112 | 30.057 | 23.247 | 0.00 | 0.00 | A |
| ATOM | 844 | HD22 | ASN | 93 | 32.424 | 28.566 | 23.771 | 0.00 | 0.00 | A |
| ATOM | 845 | C | ASN | 93 | 32.022 | 29.808 | 20.034 | 1.00 | 25.91 | A |
| ATOM | 846 | O | ASN | 93 | 30.979 | 29.998 | 20.669 | 1.00 | 23.90 | A |
| ATOM | 847 | N | VAL | 94 | 32.081 | 29.102 | 18.917 | 1.00 | 25.02 | A |
| ATOM | 848 | H | VAL | 94 | 32.941 | 28.985 | 18.452 | 0.00 | 0.00 | A |
| ATOM | 849 | CA | VAL | 94 | 30.917 | 28.447 | 18.356 | 1.00 | 24.27 | A |
| ATOM | 850 | CB | VAL | 94 | 30.448 | 29.163 | 17.071 | 1.00 | 23.55 | A |
| ATOM | 851 | CG1 | VAL | 94 | 30.331 | 30.654 | 17.322 | 1.00 | 22.32 | A |
| ATOM | 852 | CG2 | VAL | 94 | 31.406 | 28.903 | 15.943 | 1.00 | 21.89 | A |
| ATOM | 853 | C | VAL | 94 | 31.265 | 26.997 | 18.031 | 1.00 | 24.45 | A |
| ATOM | 854 | O | VAL | 94 | 32.449 | 26.645 | 17.868 | 1.00 | 27.29 | A |
| ATOM | 855 | N | ASP | 95 | 30.240 | 26.154 | 18.013 | 1.00 | 23.44 | A |
| ATOM | 856 | H | ASP | 95 | 29.338 | 26.473 | 18.231 | 0.00 | 0.00 | A |
| ATOM | 857 | CA | ASP | 95 | 30.392 | 24.745 | 17.688 | 1.00 | 21.25 | A |
| ATOM | 858 | CB | ASP | 95 | 30.422 | 23.884 | 18.939 | 1.00 | 23.01 | A |
| ATOM | 859 | CG | ASP | 95 | 30.791 | 22.452 | 18.639 | 1.00 | 26.62 | A |
| ATOM | 860 | OD1 | ASP | 95 | 30.651 | 21.578 | 19.506 | 1.00 | 29.80 | A |
| ATOM | 861 | OD2 | ASP | 95 | 31.223 | 22.167 | 17.513 | 1.00 | 32.05 | A |
| ATOM | 862 | C | ASP | 95 | 29.179 | 24.382 | 16.863 | 1.00 | 22.63 | A |
| ATOM | 863 | O | ASP | 95 | 28.036 | 24.684 | 17.259 | 1.00 | 25.02 | A |
| ATOM | 864 | N | VAL | 96 | 29.430 | 23.797 | 15.694 | 1.00 | 19.17 | A |
| ATOM | 865 | H | VAL | 96 | 30.368 | 23.615 | 15.474 | 0.00 | 0.00 | A |
| ATOM | 866 | CA | VAL | 96 | 28.375 | 23.395 | 14.769 | 1.00 | 17.05 | A |
| ATOM | 867 | CB | VAL | 96 | 28.592 | 24.083 | 13.407 | 1.00 | 15.66 | A |
| ATOM | 868 | CG1 | VAL | 96 | 27.452 | 23.799 | 12.455 | 1.00 | 14.07 | A |
| ATOM | 869 | CG2 | VAL | 96 | 28.738 | 25.563 | 13.606 | 1.00 | 12.94 | A |
| ATOM | 870 | C | VAL | 96 | 28.339 | 21.859 | 14.598 | 1.00 | 18.22 | A |
| ATOM | 871 | O | VAL | 96 | 29.372 | 21.181 | 14.637 | 1.00 | 20.48 | A |
| ATOM | 872 | N | THR | 97 | 27.151 | 21.299 | 14.459 | 1.00 | 17.29 | A |
| ATOM | 873 | H | THR | 97 | 26.346 | 21.854 | 14.443 | 0.00 | 0.00 | A |
| ATOM | 874 | CA | THR | 97 | 27.014 | 19.872 | 14.283 | 1.00 | 19.85 | A |
| ATOM | 875 | CB | THR | 97 | 26.326 | 19.235 | 15.476 | 1.00 | 19.40 | A |
| ATOM | 876 | OG1 | THR | 97 | 27.101 | 19.467 | 16.656 | 1.00 | 25.91 | A |
| ATOM | 877 | HG1 | THR | 97 | 27.890 | 18.953 | 16.453 | 0.00 | 0.00 | A |
| ATOM | 878 | CG2 | THR | 97 | 26.193 | 17.751 | 15.264 | 1.00 | 17.54 | A |
| ATOM | 879 | C | THR | 97 | 26.105 | 19.693 | 13.097 | 1.00 | 23.19 | A |
| ATOM | 880 | O | THR | 97 | 24.924 | 20.017 | 13.192 | 1.00 | 28.25 | A |
| ATOM | 881 | N | ILE | 98 | 26.659 | 19.260 | 11.969 | 1.00 | 22.00 | A |
| ATOM | 882 | H | ILE | 98 | 27.616 | 19.070 | 11.946 | 0.00 | 0.00 | A |
| ATOM | 883 | CA | ILE | 98 | 25.885 | 19.032 | 10.753 | 1.00 | 20.74 | A |
| ATOM | 884 | CB | ILE | 98 | 26.765 | 19.161 | 9.514 | 1.00 | 21.16 | A |
| ATOM | 885 | CG2 | ILE | 98 | 25.971 | 18.822 | 8.266 | 1.00 | 17.85 | A |
| ATOM | 886 | CG1 | ILE | 98 | 27.372 | 20.563 | 9.462 | 1.00 | 20.63 | A |
| ATOM | 887 | CD1 | ILE | 98 | 28.524 | 20.693 | 8.513 | 1.00 | 21.51 | A |
| ATOM | 888 | C | ILE | 98 | 25.366 | 17.612 | 10.820 | 1.00 | 22.10 | A |
| ATOM | 889 | O | ILE | 98 | 26.138 | 16.671 | 11.029 | 1.00 | 26.94 | A |
| ATOM | 890 | N | ILE | 99 | 24.062 | 17.451 | 10.684 | 1.00 | 20.82 | A |
| ATOM | 891 | H | ILE | 99 | 23.482 | 18.216 | 10.495 | 0.00 | 0.00 | A |
| ATOM | 892 | CA | ILE | 99 | 23.460 | 16.130 | 10.752 | 1.00 | 21.43 | A |
| ATOM | 893 | CB | ILE | 99 | 22.244 | 16.135 | 11.687 | 1.00 | 17.80 | A |
| ATOM | 894 | CG2 | ILE | 99 | 21.659 | 14.770 | 11.782 | 1.00 | 14.32 | A |
| ATOM | 895 | CG1 | ILE | 99 | 22.677 | 16.586 | 13.076 | 1.00 | 18.10 | A |
| ATOM | 896 | CD1 | ILE | 99 | 21.577 | 17.117 | 13.907 | 1.00 | 15.38 | A |
| ATOM | 897 | C | ILE | 99 | 23.039 | 15.784 | 9.340 | 1.00 | 23.75 | A |
| ATOM | 898 | O | ILE | 99 | 22.059 | 16.316 | 8.841 | 1.00 | 26.97 | A |
| ATOM | 899 | N | ALA | 100 | 23.814 | 14.938 | 8.676 | 1.00 | 24.64 | A |
| ATOM | 900 | H | ALA | 100 | 24.611 | 14.553 | 9.104 | 0.00 | 0.00 | A |
| ATOM | 901 | CA | ALA | 100 | 23.513 | 14.548 | 7.310 | 1.00 | 26.07 | A |
| ATOM | 902 | CB | ALA | 100 | 24.136 | 15.531 | 6.343 | 1.00 | 25.49 | A |
| ATOM | 903 | C | ALA | 100 | 24.065 | 13.159 | 7.064 | 1.00 | 29.22 | A |
| ATOM | 904 | O | ALA | 100 | 25.136 | 12.819 | 7.573 | 1.00 | 30.46 | A |
| ATOM | 905 | N | GLN | 101 | 23.305 | 12.343 | 6.334 | 1.00 | 29.41 | A |
| ATOM | 906 | H | GLN | 101 | 22.448 | 12.686 | 6.001 | 0.00 | 0.00 | A |
| ATOM | 907 | CA | GLN | 101 | 23.718 | 10.977 | 6.003 | 1.00 | 29.10 | A |
| ATOM | 908 | CB | GLN | 101 | 22.516 | 10.180 | 5.486 | 1.00 | 31.28 | A |
| ATOM | 909 | CG | GLN | 101 | 22.748 | 8.697 | 5.291 | 1.00 | 30.93 | A |
| ATOM | 910 | CD | GLN | 101 | 22.941 | 7.981 | 6.592 | 1.00 | 32.69 | A |
| ATOM | 911 | OE1 | GLN | 101 | 23.689 | 7.010 | 6.677 | 1.00 | 38.81 | A |
| ATOM | 912 | NE2 | GLN | 101 | 22.265 | 8.452 | 7.627 | 1.00 | 33.76 | A |
| ATOM | 913 | HE21 | GLN | 101 | 21.629 | 9.188 | 7.509 | 0.00 | 0.00 | A |
| ATOM | 914 | HE22 | GLN | 101 | 22.475 | 8.030 | 8.481 | 0.00 | 0.00 | A |
| ATOM | 915 | C | GLN | 101 | 24.779 | 11.078 | 4.918 | 1.00 | 27.91 | A |
| ATOM | 916 | O | GLN | 101 | 25.688 | 10.262 | 4.827 | 1.00 | 29.56 | A |
| ATOM | 917 | N | ALA | 102 | 24.620 | 12.088 | 4.079 | 1.00 | 28.48 | A |
| ATOM | 918 | H | ALA | 102 | 23.852 | 12.693 | 4.164 | 0.00 | 0.00 | A |
| ATOM | 919 | CA | ALA | 102 | 25.529 | 12.375 | 2.986 | 1.00 | 27.81 | A |
| ATOM | 920 | CB | ALA | 102 | 25.379 | 11.347 | 1.908 | 1.00 | 26.45 | A |
| ATOM | 921 | C | ALA | 102 | 25.083 | 13.737 | 2.487 | 1.00 | 28.36 | A |
| ATOM | 922 | O | ALA | 102 | 23.899 | 14.070 | 2.616 | 1.00 | 29.75 | A |
| ATOM | 923 | N | PRO | 103 | 25.974 | 14.487 | 1.804 | 1.00 | 28.84 | A |
| ATOM | 924 | CD | PRO | 103 | 25.591 | 15.762 | 1.164 | 1.00 | 28.31 | A |
| ATOM | 925 | CA | PRO | 103 | 27.359 | 14.139 | 1.465 | 1.00 | 28.46 | A |
| ATOM | 926 | CB | PRO | 103 | 27.719 | 15.186 | 0.409 | 1.00 | 25.60 | A |
| ATOM | 927 | CG | PRO | 103 | 26.919 | 16.358 | 0.801 | 1.00 | 25.38 | A |
| ATOM | 928 | C | PRO | 103 | 28.347 | 14.116 | 2.628 | 1.00 | 31.59 | A |
| ATOM | 929 | O | PRO | 103 | 27.978 | 14.392 | 3.772 | 1.00 | 35.44 | A |
| ATOM | 930 | N | LYS | 104 | 29.593 | 13.740 | 2.333 | 1.00 | 32.69 | A |
| ATOM | 931 | H | LYS | 104 | 29.817 | 13.535 | 1.404 | 0.00 | 0.00 | A |
| ATOM | 932 | CA | LYS | 104 | 30.657 | 13.662 | 3.340 | 1.00 | 30.58 | A |
| ATOM | 933 | CB | LYS | 104 | 31.821 | 12.831 | 2.798 | 1.00 | 32.54 | A |
| ATOM | 934 | CG | LYS | 104 | 32.845 | 12.424 | 3.840 | 1.00 | 37.79 | A |
| ATOM | 935 | CD | LYS | 104 | 32.225 | 11.458 | 4.827 | 1.00 | 45.14 | A |
| ATOM | 936 | CE | LYS | 104 | 33.218 | 10.983 | 5.881 | 1.00 | 49.57 | A |
| ATOM | 937 | NZ | LYS | 104 | 32.616 | 9.902 | 6.738 | 1.00 | 54.87 | A |
| ATOM | 938 | HZ1 | LYS | 104 | 32.368 | 9.088 | 6.139 | 0.00 | 0.00 | A |
| ATOM | 939 | HZ2 | LYS | 104 | 31.761 | 10.242 | 7.223 | 0.00 | 0.00 | A |
| ATOM | 940 | HZ3 | LYS | 104 | 33.311 | 9.600 | 7.452 | 0.00 | 0.00 | A |
| ATOM | 941 | C | LYS | 104 | 31.136 | 15.073 | 3.641 | 1.00 | 30.14 | A |
| ATOM | 942 | O | LYS | 104 | 31.777 | 15.709 | 2.804 | 1.00 | 34.01 | A |
| ATOM | 943 | N | MET | 105 | 30.830 | 15.568 | 4.826 | 1.00 | 25.53 | A |
| ATOM | 944 | H | MET | 105 | 30.282 | 15.038 | 5.433 | 0.00 | 0.00 | A |
| ATOM | 945 | CA | MET | 105 | 31.220 | 16.908 | 5.175 | 1.00 | 22.89 | A |
| ATOM | 946 | CB | MET | 105 | 30.408 | 17.383 | 6.366 | 1.00 | 22.69 | A |
| ATOM | 947 | CG | MET | 105 | 28.914 | 17.332 | 6.160 | 1.00 | 25.26 | A |
| ATOM | 948 | SD | MET | 105 | 28.444 | 18.320 | 4.749 | 1.00 | 27.75 | A |
| ATOM | 949 | CE | MET | 105 | 26.705 | 17.837 | 4.522 | 1.00 | 22.62 | A |
| ATOM | 950 | C | MET | 105 | 32.675 | 16.990 | 5.539 | 1.00 | 24.55 | A |
| ATOM | 951 | O | MET | 105 | 33.337 | 17.980 | 5.260 | 1.00 | 28.11 | A |
| ATOM | 952 | N | LEU | 106 | 33.202 | 15.917 | 6.086 | 1.00 | 25.36 | A |
| ATOM | 953 | H | LEU | 106 | 32.664 | 15.120 | 6.118 | 0.00 | 0.00 | A |
| ATOM | 954 | CA | LEU | 106 | 34.572 | 15.931 | 6.569 | 1.00 | 29.44 | A |
| ATOM | 955 | CB | LEU | 106 | 35.067 | 14.523 | 6.881 | 1.00 | 33.70 | A |
| ATOM | 956 | CG | LEU | 106 | 36.272 | 14.558 | 7.833 | 1.00 | 37.95 | A |
| ATOM | 957 | CD1 | LEU | 106 | 35.946 | 15.379 | 9.101 | 1.00 | 38.15 | A |
| ATOM | 958 | CD2 | LEU | 106 | 36.670 | 13.140 | 8.204 | 1.00 | 40.76 | A |
| ATOM | 959 | C | LEU | 106 | 35.654 | 16.702 | 5.825 | 1.00 | 29.32 | A |
| ATOM | 960 | O | LEU | 106 | 36.290 | 17.581 | 6.387 | 1.00 | 31.29 | A |
| ATOM | 961 | N | PRO | 107 | 35.876 | 16.399 | 4.553 | 1.00 | 29.19 | A |
| ATOM | 962 | CD | PRO | 107 | 35.246 | 15.384 | 3.694 | 1.00 | 29.61 | A |
| ATOM | 963 | CA | PRO | 107 | 36.923 | 17.129 | 3.835 | 1.00 | 29.15 | A |
| ATOM | 964 | CB | PRO | 107 | 36.976 | 16.394 | 2.496 | 1.00 | 30.23 | A |
| ATOM | 965 | CG | PRO | 107 | 35.576 | 15.890 | 2.320 | 1.00 | 28.09 | A |
| ATOM | 966 | C | PRO | 107 | 36.714 | 18.626 | 3.636 | 1.00 | 29.69 | A |
| ATOM | 967 | O | PRO | 107 | 37.662 | 19.355 | 3.328 | 1.00 | 29.34 | A |
| ATOM | 968 | N | HIS | 108 | 35.476 | 19.081 | 3.794 | 1.00 | 30.02 | A |
| ATOM | 969 | H | HIS | 108 | 34.783 | 18.465 | 4.109 | 0.00 | 0.00 | A |
| ATOM | 970 | CA | HIS | 108 | 35.138 | 20.487 | 3.586 | 1.00 | 29.58 | A |
| ATOM | 971 | CB | HIS | 108 | 33.765 | 20.575 | 2.947 | 1.00 | 27.33 | A |
| ATOM | 972 | CG | HIS | 108 | 33.623 | 19.716 | 1.738 | 1.00 | 26.43 | A |
| ATOM | 973 | CD2 | HIS | 108 | 32.974 | 18.545 | 1.550 | 1.00 | 28.75 | A |
| ATOM | 974 | ND1 | HIS | 108 | 34.233 | 20.012 | 0.540 | 1.00 | 28.00 | A |
| ATOM | 975 | HD1 | HIS | 108 | 34.717 | 20.839 | 0.335 | 0.00 | 0.00 | A |
| ATOM | 976 | CE1 | HIS | 108 | 33.970 | 19.058 | −0.336 | 1.00 | 27.12 | A |
| ATOM | 977 | NE2 | HIS | 108 | 33.208 | 18.155 | 0.253 | 1.00 | 31.32 | A |
| ATOM | 978 | HE2 | HIS | 108 | 32.838 | 17.343 | −0.163 | 0.00 | 0.00 | A |
| ATOM | 979 | C | HIS | 108 | 35.161 | 21.340 | 4.843 | 1.00 | 30.69 | A |
| ATOM | 980 | O | HIS | 108 | 35.093 | 22.569 | 4.779 | 1.00 | 32.65 | A |
| ATOM | 981 | N | ILE | 109 | 35.302 | 20.697 | 5.987 | 1.00 | 28.24 | A |
| ATOM | 982 | H | ILE | 109 | 35.411 | 19.721 | 5.996 | 0.00 | 0.00 | A |
| ATOM | 983 | CA | ILE | 109 | 35.298 | 21.413 | 7.234 | 1.00 | 23.92 | A |
| ATOM | 984 | CB | ILE | 109 | 35.141 | 20.442 | 8.395 | 1.00 | 22.78 | A |
| ATOM | 985 | CG2 | ILE | 109 | 35.385 | 21.131 | 9.708 | 1.00 | 19.58 | A |
| ATOM | 986 | CG1 | ILE | 109 | 33.726 | 19.857 | 8.338 | 1.00 | 20.82 | A |
| ATOM | 987 | CD1 | ILE | 109 | 33.548 | 18.605 | 9.093 | 1.00 | 21.50 | A |
| ATOM | 988 | C | ILE | 109 | 36.402 | 22.425 | 7.451 | 1.00 | 26.23 | A |
| ATOM | 989 | O | ILE | 109 | 36.133 | 23.509 | 7.958 | 1.00 | 32.63 | A |
| ATOM | 990 | N | PRO | 110 | 37.652 | 22.124 | 7.065 | 1.00 | 26.64 | A |
| ATOM | 991 | CD | PRO | 110 | 38.229 | 20.895 | 6.505 | 1.00 | 27.77 | A |
| ATOM | 992 | CA | PRO | 110 | 38.704 | 23.125 | 7.282 | 1.00 | 25.96 | A |
| ATOM | 993 | CB | PRO | 110 | 39.905 | 22.494 | 6.608 | 1.00 | 24.86 | A |
| ATOM | 994 | CG | PRO | 110 | 39.689 | 21.056 | 6.846 | 1.00 | 24.40 | A |
| ATOM | 995 | C | PRO | 110 | 38.341 | 24.434 | 6.607 | 1.00 | 27.69 | A |
| ATOM | 996 | O | PRO | 110 | 38.423 | 25.511 | 7.215 | 1.00 | 27.07 | A |
| ATOM | 997 | N | GLN | 111 | 37.909 | 24.321 | 5.352 | 1.00 | 29.37 | A |
| ATOM | 998 | H | GLN | 111 | 37.856 | 23.431 | 4.947 | 0.00 | 0.00 | A |
| ATOM | 999 | CA | GLN | 111 | 37.500 | 25.481 | 4.566 | 1.00 | 29.01 | A |
| ATOM | 1000 | CB | GLN | 111 | 37.243 | 25.071 | 3.120 | 1.00 | 26.32 | A |
| ATOM | 1001 | CG | GLN | 111 | 37.017 | 26.226 | 2.172 | 1.00 | 24.89 | A |
| ATOM | 1002 | CD | GLN | 111 | 38.087 | 27.278 | 2.259 | 1.00 | 23.81 | A |
| ATOM | 1003 | OE1 | GLN | 111 | 37.789 | 28.452 | 2.372 | 1.00 | 31.55 | A |
| ATOM | 1004 | NE2 | GLN | 111 | 39.338 | 26.867 | 2.229 | 1.00 | 26.26 | A |
| ATOM | 1005 | HE21 | GLN | 111 | 39.484 | 25.910 | 2.210 | 0.00 | 0.00 | A |
| ATOM | 1006 | HE22 | GLN | 111 | 40.024 | 27.571 | 2.227 | 0.00 | 0.00 | A |
| ATOM | 1007 | C | GLN | 111 | 36.259 | 26.131 | 5.182 | 1.00 | 30.54 | A |
| ATOM | 1008 | O | GLN | 111 | 36.150 | 27.351 | 5.196 | 1.00 | 35.14 | A |
| ATOM | 1009 | N | MET | 112 | 35.333 | 25.320 | 5.696 | 1.00 | 30.78 | A |
| ATOM | 1010 | H | MET | 112 | 35.453 | 24.352 | 5.634 | 0.00 | 0.00 | A |
| ATOM | 1011 | CA | MET | 112 | 34.124 | 25.831 | 6.345 | 1.00 | 27.53 | A |
| ATOM | 1012 | CB | MET | 112 | 33.280 | 24.694 | 6.913 | 1.00 | 27.13 | A |
| ATOM | 1013 | CG | MET | 112 | 32.235 | 24.127 | 5.984 | 1.00 | 25.22 | A |
| ATOM | 1014 | SD | MET | 112 | 31.275 | 22.888 | 6.846 | 1.00 | 25.29 | A |
| ATOM | 1015 | CE | MET | 112 | 30.638 | 22.029 | 5.536 | 1.00 | 24.12 | A |
| ATOM | 1016 | C | MET | 112 | 34.560 | 26.700 | 7.500 | 1.00 | 28.92 | A |
| ATOM | 1017 | O | MET | 112 | 34.046 | 27.804 | 7.677 | 1.00 | 31.65 | A |
| ATOM | 1018 | N | ARG | 113 | 35.529 | 26.211 | 8.274 | 1.00 | 28.19 | A |
| ATOM | 1019 | H | ARG | 113 | 35.910 | 25.342 | 8.057 | 0.00 | 0.00 | A |
| ATOM | 1020 | CA | ARG | 113 | 36.040 | 26.957 | 9.426 | 1.00 | 29.54 | A |
| ATOM | 1021 | CB | ARG | 113 | 36.968 | 26.099 | 10.270 | 1.00 | 25.68 | A |
| ATOM | 1022 | CG | ARG | 113 | 36.273 | 25.006 | 10.983 | 1.00 | 23.70 | A |
| ATOM | 1023 | CD | ARG | 113 | 37.267 | 24.163 | 11.680 | 1.00 | 22.63 | A |
| ATOM | 1024 | NE | ARG | 113 | 37.843 | 24.852 | 12.819 | 1.00 | 24.17 | A |
| ATOM | 1025 | HE | ARG | 113 | 37.310 | 25.589 | 13.199 | 0.00 | 0.00 | A |
| ATOM | 1026 | CZ | ARG | 113 | 39.027 | 24.549 | 13.340 | 1.00 | 26.90 | A |
| ATOM | 1027 | NH1 | ARG | 113 | 39.487 | 25.205 | 14.401 | 1.00 | 24.81 | A |
| ATOM | 1028 | HH11 | ARG | 113 | 38.897 | 25.929 | 14.799 | 0.00 | 0.00 | A |
| ATOM | 1029 | HH12 | ARG | 113 | 40.350 | 25.021 | 14.873 | 0.00 | 0.00 | A |
| ATOM | 1030 | NH2 | ARG | 113 | 39.776 | 23.618 | 12.760 | 1.00 | 27.84 | A |
| ATOM | 1031 | HH21 | ARG | 113 | 39.427 | 23.147 | 11.950 | 0.00 | 0.00 | A |
| ATOM | 1032 | HH22 | ARG | 113 | 40.662 | 23.354 | 13.138 | 0.00 | 0.00 | A |
| ATOM | 1033 | C | ARG | 113 | 36.761 | 28.246 | 9.060 | 1.00 | 31.05 | A |
| ATOM | 1034 | O | ARG | 113 | 36.826 | 29.161 | 9.869 | 1.00 | 33.27 | A |
| ATOM | 1035 | N | VAL | 114 | 37.350 | 28.293 | 7.871 | 1.00 | 31.23 | A |
| ATOM | 1036 | H | VAL | 114 | 37.314 | 27.501 | 7.296 | 0.00 | 0.00 | A |
| ATOM | 1037 | CA | VAL | 114 | 38.063 | 29.476 | 7.405 | 1.00 | 29.99 | A |
| ATOM | 1038 | CB | VAL | 114 | 38.876 | 29.140 | 6.155 | 1.00 | 29.99 | A |
| ATOM | 1039 | CG1 | VAL | 114 | 39.383 | 30.393 | 5.498 | 1.00 | 29.97 | A |
| ATOM | 1040 | CG2 | VAL | 114 | 40.021 | 28.209 | 6.522 | 1.00 | 29.75 | A |
| ATOM | 1041 | C | VAL | 114 | 37.057 | 30.581 | 7.092 | 1.00 | 31.42 | A |
| ATOM | 1042 | O | VAL | 114 | 37.240 | 31.737 | 7.484 | 1.00 | 33.80 | A |
| ATOM | 1043 | N | PHE | 115 | 35.990 | 30.207 | 6.397 | 1.00 | 29.02 | A |
| ATOM | 1044 | H | PHE | 115 | 35.925 | 29.271 | 6.099 | 0.00 | 0.00 | A |
| ATOM | 1045 | CA | PHE | 115 | 34.933 | 31.135 | 6.048 | 1.00 | 27.18 | A |
| ATOM | 1046 | CB | PHE | 115 | 33.887 | 30.422 | 5.214 | 1.00 | 23.61 | A |
| ATOM | 1047 | CG | PHE | 115 | 34.290 | 30.215 | 3.806 | 1.00 | 22.50 | A |
| ATOM | 1048 | CD1 | PHE | 115 | 33.589 | 29.341 | 2.997 | 1.00 | 24.86 | A |
| ATOM | 1049 | CD2 | PHE | 115 | 35.322 | 30.947 | 3.257 | 1.00 | 23.68 | A |
| ATOM | 1050 | CE1 | PHE | 115 | 33.908 | 29.212 | 1.664 | 1.00 | 22.96 | A |
| ATOM | 1051 | CE2 | PHE | 115 | 35.649 | 30.821 | 1.917 | 1.00 | 22.85 | A |
| ATOM | 1052 | CZ | PHE | 115 | 34.937 | 29.955 | 1.123 | 1.00 | 22.00 | A |
| ATOM | 1053 | C | PHE | 115 | 34.258 | 31.694 | 7.290 | 1.00 | 28.13 | A |
| ATOM | 1054 | O | PHE | 115 | 34.139 | 32.903 | 7.443 | 1.00 | 29.19 | A |
| ATOM | 1055 | N | ILE | 116 | 33.803 | 30.807 | 8.169 | 1.00 | 27.94 | A |
| ATOM | 1056 | H | ILE | 116 | 33.909 | 29.847 | 7.979 | 0.00 | 0.00 | A |
| ATOM | 1057 | CA | ILE | 116 | 33.129 | 31.227 | 9.387 | 1.00 | 27.20 | A |
| ATOM | 1058 | CB | ILE | 116 | 32.650 | 30.028 | 10.218 | 1.00 | 26.48 | A |
| ATOM | 1059 | CG2 | ILE | 116 | 32.060 | 30.511 | 11.522 | 1.00 | 26.73 | A |
| ATOM | 1060 | CG1 | ILE | 116 | 31.599 | 29.235 | 9.436 | 1.00 | 26.91 | A |
| ATOM | 1061 | CD1 | ILE | 116 | 31.164 | 27.945 | 10.105 | 1.00 | 23.85 | A |
| ATOM | 1062 | C | ILE | 116 | 33.996 | 32.128 | 10.251 | 1.00 | 27.34 | A |
| ATOM | 1063 | O | ILE | 116 | 33.555 | 33.185 | 10.664 | 1.00 | 30.09 | A |
| ATOM | 1064 | N | ALA | 117 | 35.230 | 31.727 | 10.519 | 1.00 | 28.85 | A |
| ATOM | 1065 | H | ALA | 117 | 35.566 | 30.875 | 10.164 | 0.00 | 0.00 | A |
| ATOM | 1066 | CA | ALA | 117 | 36.123 | 32.535 | 11.350 | 1.00 | 30.45 | A |
| ATOM | 1067 | CB | ALA | 117 | 37.439 | 31.834 | 11.571 | 1.00 | 31.08 | A |
| ATOM | 1068 | C | ALA | 117 | 36.358 | 33.877 | 10.706 | 1.00 | 32.39 | A |
| ATOM | 1069 | O | ALA | 117 | 36.632 | 34.854 | 11.388 | 1.00 | 33.20 | A |
| ATOM | 1070 | N | GLU | 118 | 36.305 | 33.912 | 9.381 | 1.00 | 35.98 | A |
| ATOM | 1071 | H | GLU | 118 | 36.186 | 33.097 | 8.852 | 0.00 | 0.00 | A |
| ATOM | 1072 | CA | GLU | 118 | 36.475 | 35.168 | 8.670 | 1.00 | 37.92 | A |
| ATOM | 1073 | CB | GLU | 118 | 36.563 | 34.950 | 7.158 | 1.00 | 42.92 | A |
| ATOM | 1074 | CG | GLU | 118 | 37.970 | 34.659 | 6.628 | 1.00 | 51.90 | A |
| ATOM | 1075 | CD | GLU | 118 | 38.066 | 34.762 | 5.098 | 1.00 | 56.76 | A |
| ATOM | 1076 | OE1 | GLU | 118 | 39.155 | 34.434 | 4.572 | 1.00 | 58.80 | A |
| ATOM | 1077 | OE2 | GLU | 118 | 37.066 | 35.161 | 4.426 | 1.00 | 56.13 | A |
| ATOM | 1078 | C | GLU | 118 | 35.272 | 36.039 | 8.986 | 1.00 | 36.35 | A |
| ATOM | 1079 | O | GLU | 118 | 35.413 | 37.090 | 9.592 | 1.00 | 35.36 | A |
| ATOM | 1080 | N | ASP | 119 | 34.088 | 35.553 | 8.622 | 1.00 | 35.47 | A |
| ATOM | 1081 | H | ASP | 119 | 34.041 | 34.690 | 8.164 | 0.00 | 0.00 | A |
| ATOM | 1082 | CA | ASP | 119 | 32.837 | 36.262 | 8.845 | 1.00 | 33.93 | A |
| ATOM | 1083 | CB | ASP | 119 | 31.658 | 35.370 | 8.471 | 1.00 | 35.10 | A |
| ATOM | 1084 | CG | ASP | 119 | 31.610 | 35.033 | 6.996 | 1.00 | 37.67 | A |
| ATOM | 1085 | OD1 | ASP | 119 | 30.794 | 34.161 | 6.637 | 1.00 | 38.81 | A |
| ATOM | 1086 | OD2 | ASP | 119 | 32.356 | 35.635 | 6.187 | 1.00 | 35.75 | A |
| ATOM | 1087 | C | ASP | 119 | 32.658 | 36.743 | 10.282 | 1.00 | 34.15 | A |
| ATOM | 1088 | O | ASP | 119 | 32.042 | 37.779 | 10.520 | 1.00 | 36.18 | A |
| ATOM | 1089 | N | LEU | 120 | 33.181 | 35.983 | 11.238 | 1.00 | 32.94 | A |
| ATOM | 1090 | H | LEU | 120 | 33.634 | 35.159 | 10.969 | 0.00 | 0.00 | A |
| ATOM | 1091 | CA | LEU | 120 | 33.057 | 36.333 | 12.646 | 1.00 | 32.55 | A |
| ATOM | 1092 | CB | LEU | 120 | 32.908 | 35.069 | 13.493 | 1.00 | 29.86 | A |
| ATOM | 1093 | CG | LEU | 120 | 31.676 | 34.214 | 13.211 | 1.00 | 28.39 | A |
| ATOM | 1094 | CD1 | LEU | 120 | 31.666 | 33.004 | 14.124 | 1.00 | 27.63 | A |
| ATOM | 1095 | CD2 | LEU | 120 | 30.427 | 35.048 | 13.405 | 1.00 | 27.40 | A |
| ATOM | 1096 | C | LEU | 120 | 34.245 | 37.136 | 13.146 | 1.00 | 34.93 | A |
| ATOM | 1097 | O | LEU | 120 | 34.213 | 37.687 | 14.245 | 1.00 | 37.86 | A |
| ATOM | 1098 | N | GLY | 121 | 35.311 | 37.162 | 12.357 | 1.00 | 36.43 | A |
| ATOM | 1099 | H | GLY | 121 | 35.313 | 36.684 | 11.505 | 0.00 | 0.00 | A |
| ATOM | 1100 | CA | GLY | 121 | 36.501 | 37.894 | 12.740 | 1.00 | 35.75 | A |
| ATOM | 1101 | C | GLY | 121 | 37.178 | 37.320 | 13.962 | 1.00 | 37.82 | A |
| ATOM | 1102 | O | GLY | 121 | 37.576 | 38.074 | 14.845 | 1.00 | 42.07 | A |
| ATOM | 1103 | N | CYS | 122 | 37.318 | 35.998 | 14.020 | 1.00 | 38.40 | A |
| ATOM | 1104 | H | CYS | 122 | 37.028 | 35.447 | 13.261 | 0.00 | 0.00 | A |
| ATOM | 1105 | CA | CYS | 122 | 37.964 | 35.328 | 15.153 | 1.00 | 39.41 | A |
| ATOM | 1106 | CB | CYS | 122 | 36.945 | 34.507 | 15.937 | 1.00 | 37.17 | A |
| ATOM | 1107 | SG | CYS | 122 | 36.146 | 33.232 | 14.975 | 1.00 | 31.14 | A |
| ATOM | 1108 | C | CYS | 122 | 39.015 | 34.398 | 14.596 | 1.00 | 41.74 | A |
| ATOM | 1109 | O | CYS | 122 | 39.247 | 34.392 | 13.392 | 1.00 | 43.67 | A |
| ATOM | 1110 | N | HIS | 123 | 39.668 | 33.626 | 15.457 | 1.00 | 45.03 | A |
| ATOM | 1111 | H | HIS | 123 | 39.376 | 33.620 | 16.395 | 0.00 | 0.00 | A |
| ATOM | 1112 | CA | HIS | 123 | 40.664 | 32.677 | 14.974 | 1.00 | 50.03 | A |
| ATOM | 1113 | CB | HIS | 123 | 41.734 | 32.311 | 16.024 | 1.00 | 64.56 | A |
| ATOM | 1114 | CG | HIS | 123 | 42.050 | 33.404 | 17.009 | 1.00 | 81.64 | A |
| ATOM | 1115 | CD2 | HIS | 123 | 41.248 | 34.139 | 17.823 | 1.00 | 86.90 | A |
| ATOM | 1116 | ND1 | HIS | 123 | 43.342 | 33.812 | 17.280 | 1.00 | 88.26 | A |
| ATOM | 1117 | HD1 | HIS | 123 | 44.164 | 33.503 | 16.837 | 0.00 | 0.00 | A |
| ATOM | 1118 | CE1 | HIS | 123 | 43.323 | 34.746 | 18.218 | 1.00 | 90.93 | A |
| ATOM | 1119 | NE2 | HIS | 123 | 42.064 | 34.963 | 18.564 | 1.00 | 91.75 | A |
| ATOM | 1120 | HE2 | HIS | 123 | 41.744 | 35.572 | 19.267 | 0.00 | 0.00 | A |
| ATOM | 1121 | C | HIS | 123 | 39.840 | 31.441 | 14.716 | 1.00 | 46.69 | A |
| ATOM | 1122 | O | HIS | 123 | 38.776 | 31.270 | 15.299 | 1.00 | 45.10 | A |
| ATOM | 1123 | N | MET | 124 | 40.338 | 30.567 | 13.858 | 1.00 | 44.77 | A |
| ATOM | 1124 | H | MET | 124 | 41.167 | 30.765 | 13.378 | 0.00 | 0.00 | A |
| ATOM | 1125 | CA | MET | 124 | 39.632 | 29.336 | 13.564 | 1.00 | 42.57 | A |
| ATOM | 1126 | CB | MET | 124 | 40.436 | 28.462 | 12.608 | 1.00 | 42.31 | A |
| ATOM | 1127 | CG | MET | 124 | 40.263 | 28.742 | 11.150 | 1.00 | 43.76 | A |
| ATOM | 1128 | SD | MET | 124 | 41.359 | 27.661 | 10.222 | 1.00 | 47.19 | A |
| ATOM | 1129 | CE | MET | 124 | 40.461 | 26.135 | 10.250 | 1.00 | 48.89 | A |
| ATOM | 1130 | C | MET | 124 | 39.483 | 28.572 | 14.858 | 1.00 | 42.03 | A |
| ATOM | 1131 | O | MET | 124 | 38.580 | 27.759 | 14.996 | 1.00 | 44.04 | A |
| ATOM | 1132 | N | ASP | 125 | 40.390 | 28.815 | 15.795 | 1.00 | 40.95 | A |
| ATOM | 1133 | H | ASP | 125 | 41.097 | 29.468 | 15.660 | 0.00 | 0.00 | A |
| ATOM | 1134 | CA | ASP | 125 | 40.380 | 28.108 | 17.067 | 1.00 | 42.02 | A |
| ATOM | 1135 | CB | ASP | 125 | 41.595 | 28.509 | 17.901 | 1.00 | 52.60 | A |
| ATOM | 1136 | CG | ASP | 125 | 42.101 | 27.372 | 18.789 | 1.00 | 63.14 | A |
| ATOM | 1137 | OD1 | ASP | 125 | 43.305 | 27.042 | 18.650 | 1.00 | 69.07 | A |
| ATOM | 1138 | OD2 | ASP | 125 | 41.318 | 26.806 | 19.613 | 1.00 | 65.60 | A |
| ATOM | 1139 | C | ASP | 125 | 39.104 | 28.317 | 17.864 | 1.00 | 38.07 | A |
| ATOM | 1140 | O | ASP | 125 | 38.752 | 27.507 | 18.714 | 1.00 | 36.19 | A |
| ATOM | 1141 | N | ASP | 126 | 38.406 | 29.406 | 17.588 | 1.00 | 34.39 | A |
| ATOM | 1142 | H | ASP | 126 | 38.718 | 30.063 | 16.938 | 0.00 | 0.00 | A |
| ATOM | 1143 | CA | ASP | 126 | 37.167 | 29.689 | 18.278 | 1.00 | 30.28 | A |
| ATOM | 1144 | CB | ASP | 126 | 37.005 | 31.185 | 18.444 | 1.00 | 31.50 | A |
| ATOM | 1145 | CG | ASP | 126 | 38.133 | 31.795 | 19.202 | 1.00 | 34.50 | A |
| ATOM | 1146 | OD1 | ASP | 126 | 38.444 | 32.966 | 18.917 | 1.00 | 39.77 | A |
| ATOM | 1147 | OD2 | ASP | 126 | 38.727 | 31.103 | 20.062 | 1.00 | 36.20 | A |
| ATOM | 1148 | C | ASP | 126 | 35.999 | 29.156 | 17.484 | 1.00 | 28.73 | A |
| ATOM | 1149 | O | ASP | 126 | 34.850 | 29.413 | 17.825 | 1.00 | 31.02 | A |
| ATOM | 1150 | N | VAL | 127 | 36.288 | 28.406 | 16.429 | 1.00 | 25.83 | A |
| ATOM | 1151 | H | VAL | 127 | 37.214 | 28.205 | 16.212 | 0.00 | 0.00 | A |
| ATOM | 1152 | CA | VAL | 127 | 35.256 | 27.862 | 15.569 | 1.00 | 23.89 | A |
| ATOM | 1153 | CB | VAL | 127 | 35.231 | 28.599 | 14.223 | 1.00 | 22.97 | A |
| ATOM | 1154 | CG1 | VAL | 127 | 34.192 | 27.997 | 13.327 | 1.00 | 26.09 | A |
| ATOM | 1155 | CG2 | VAL | 127 | 34.927 | 30.066 | 14.434 | 1.00 | 23.33 | A |
| ATOM | 1156 | C | VAL | 127 | 35.464 | 26.383 | 15.303 | 1.00 | 24.47 | A |
| ATOM | 1157 | O | VAL | 127 | 36.514 | 25.970 | 14.813 | 1.00 | 24.00 | A |
| ATOM | 1158 | N | ASN | 128 | 34.450 | 25.587 | 15.607 | 1.00 | 25.25 | A |
| ATOM | 1159 | H | ASN | 128 | 33.629 | 25.954 | 16.008 | 0.00 | 0.00 | A |
| ATOM | 1160 | CA | ASN | 128 | 34.511 | 24.149 | 15.381 | 1.00 | 25.99 | A |
| ATOM | 1161 | CB | ASN | 128 | 34.586 | 23.420 | 16.724 | 1.00 | 29.64 | A |
| ATOM | 1162 | CG | ASN | 128 | 34.928 | 21.949 | 16.575 | 1.00 | 30.61 | A |
| ATOM | 1163 | OD1 | ASN | 128 | 36.071 | 21.590 | 16.308 | 1.00 | 33.30 | A |
| ATOM | 1164 | ND2 | ASN | 128 | 33.945 | 21.092 | 16.773 | 1.00 | 33.38 | A |
| ATOM | 1165 | HD21 | ASN | 128 | 33.072 | 21.473 | 17.026 | 0.00 | 0.00 | A |
| ATOM | 1166 | HD22 | ASN | 128 | 34.122 | 20.134 | 16.670 | 0.00 | 0.00 | A |
| ATOM | 1167 | C | ASN | 128 | 33.279 | 23.687 | 14.585 | 1.00 | 25.09 | A |
| ATOM | 1168 | O | ASN | 128 | 32.193 | 24.257 | 14.719 | 1.00 | 26.50 | A |
| ATOM | 1169 | N | VAL | 129 | 33.465 | 22.714 | 13.699 | 1.00 | 22.54 | A |
| ATOM | 1170 | H | VAL | 129 | 34.346 | 22.300 | 13.573 | 0.00 | 0.00 | A |
| ATOM | 1171 | CA | VAL | 129 | 32.365 | 22.176 | 12.906 | 1.00 | 19.85 | A |
| ATOM | 1172 | CB | VAL | 129 | 32.386 | 22.684 | 11.461 | 1.00 | 15.64 | A |
| ATOM | 1173 | CG1 | VAL | 129 | 31.288 | 22.028 | 10.675 | 1.00 | 17.08 | A |
| ATOM | 1174 | CG2 | VAL | 129 | 32.201 | 24.169 | 11.417 | 1.00 | 13.92 | A |
| ATOM | 1175 | C | VAL | 129 | 32.556 | 20.666 | 12.887 | 1.00 | 21.67 | A |
| ATOM | 1176 | O | VAL | 129 | 33.684 | 20.192 | 12.828 | 1.00 | 23.70 | A |
| ATOM | 1177 | N | LYS | 130 | 31.479 | 19.907 | 13.019 | 1.00 | 21.70 | A |
| ATOM | 1178 | H | LYS | 130 | 30.589 | 20.310 | 13.113 | 0.00 | 0.00 | A |
| ATOM | 1179 | CA | LYS | 130 | 31.590 | 18.455 | 12.989 | 1.00 | 23.02 | A |
| ATOM | 1180 | CB | LYS | 130 | 31.653 | 17.873 | 14.397 | 1.00 | 24.96 | A |
| ATOM | 1181 | CG | LYS | 130 | 30.365 | 17.939 | 15.183 | 1.00 | 26.97 | A |
| ATOM | 1182 | CD | LYS | 130 | 30.584 | 17.490 | 16.613 | 1.00 | 24.71 | A |
| ATOM | 1183 | CE | LYS | 130 | 31.087 | 18.625 | 17.452 | 1.00 | 22.91 | A |
| ATOM | 1184 | NZ | LYS | 130 | 30.057 | 19.691 | 17.524 | 1.00 | 21.04 | A |
| ATOM | 1185 | HZ1 | LYS | 130 | 30.485 | 20.410 | 18.151 | 0.00 | 0.00 | A |
| ATOM | 1186 | HZ2 | LYS | 130 | 29.202 | 19.389 | 18.005 | 0.00 | 0.00 | A |
| ATOM | 1187 | HZ3 | LYS | 130 | 29.891 | 20.204 | 16.637 | 0.00 | 0.00 | A |
| ATOM | 1188 | C | LYS | 130 | 30.381 | 17.939 | 12.258 | 1.00 | 24.73 | A |
| ATOM | 1189 | O | LYS | 130 | 29.464 | 18.716 | 11.965 | 1.00 | 27.86 | A |
| ATOM | 1190 | N | ALA | 131 | 30.356 | 16.647 | 11.962 | 1.00 | 23.88 | A |
| ATOM | 1191 | H | ALA | 131 | 31.087 | 16.045 | 12.258 | 0.00 | 0.00 | A |
| ATOM | 1192 | CA | ALA | 131 | 29.226 | 16.088 | 11.244 | 1.00 | 22.87 | A |
| ATOM | 1193 | CB | ALA | 131 | 29.556 | 15.982 | 9.779 | 1.00 | 21.64 | A |
| ATOM | 1194 | C | ALA | 131 | 28.834 | 14.733 | 11.789 | 1.00 | 25.34 | A |
| ATOM | 1195 | O | ALA | 131 | 29.617 | 14.085 | 12.497 | 1.00 | 25.97 | A |
| ATOM | 1196 | N | THR | 132 | 27.601 | 14.327 | 11.503 | 1.00 | 25.94 | A |
| ATOM | 1197 | H | THR | 132 | 26.979 | 14.889 | 10.999 | 0.00 | 0.00 | A |
| ATOM | 1198 | CA | THR | 132 | 27.124 | 13.030 | 11.933 | 1.00 | 28.47 | A |
| ATOM | 1199 | CB | THR | 132 | 26.683 | 13.043 | 13.400 | 1.00 | 31.26 | A |
| ATOM | 1200 | OG1 | THR | 132 | 26.505 | 11.694 | 13.850 | 1.00 | 37.32 | A |
| ATOM | 1201 | HG1 | THR | 132 | 26.405 | 11.726 | 14.811 | 0.00 | 0.00 | A |
| ATOM | 1202 | CG2 | THR | 132 | 25.367 | 13.788 | 13.564 | 1.00 | 32.90 | A |
| ATOM | 1203 | C | THR | 132 | 25.956 | 12.589 | 11.077 | 1.00 | 28.81 | A |
| ATOM | 1204 | O | THR | 132 | 25.256 | 13.418 | 10.497 | 1.00 | 29.53 | A |
| ATOM | 1205 | N | THR | 133 | 25.770 | 11.280 | 10.963 | 1.00 | 29.72 | A |
| ATOM | 1206 | H | THR | 133 | 26.336 | 10.669 | 11.477 | 0.00 | 0.00 | A |
| ATOM | 1207 | CA | THR | 133 | 24.648 | 10.751 | 10.195 | 1.00 | 29.86 | A |
| ATOM | 1208 | CB | THR | 133 | 25.012 | 9.503 | 9.346 | 1.00 | 28.71 | A |
| ATOM | 1209 | OG1 | THR | 133 | 25.238 | 8.382 | 10.199 | 1.00 | 27.75 | A |
| ATOM | 1210 | HG1 | THR | 133 | 25.961 | 8.463 | 10.831 | 0.00 | 0.00 | A |
| ATOM | 1211 | CG2 | THR | 133 | 26.238 | 9.729 | 8.509 | 1.00 | 27.82 | A |
| ATOM | 1212 | C | THR | 133 | 23.670 | 10.285 | 11.243 | 1.00 | 30.68 | A |
| ATOM | 1213 | O | THR | 133 | 24.014 | 10.198 | 12.425 | 1.00 | 32.02 | A |
| ATOM | 1214 | N | THR | 134 | 22.455 | 9.982 | 10.824 | 1.00 | 29.98 | A |
| ATOM | 1215 | H | THR | 134 | 22.165 | 10.127 | 9.906 | 0.00 | 0.00 | A |
| ATOM | 1216 | CA | THR | 134 | 21.474 | 9.476 | 11.766 | 1.00 | 31.97 | A |
| ATOM | 1217 | CB | THR | 134 | 20.210 | 10.303 | 11.697 | 1.00 | 29.14 | A |
| ATOM | 1218 | OG1 | THR | 134 | 19.783 | 10.397 | 10.338 | 1.00 | 31.67 | A |
| ATOM | 1219 | HG1 | THR | 134 | 18.819 | 10.518 | 10.331 | 0.00 | 0.00 | A |
| ATOM | 1220 | CG2 | THR | 134 | 20.513 | 11.684 | 12.174 | 1.00 | 26.94 | A |
| ATOM | 1221 | C | THR | 134 | 21.234 | 7.975 | 11.487 | 1.00 | 34.41 | A |
| ATOM | 1222 | O | THR | 134 | 20.143 | 7.435 | 11.703 | 1.00 | 36.08 | A |
| ATOM | 1223 | N | GLU | 135 | 22.282 | 7.328 | 10.974 | 1.00 | 34.44 | A |
| ATOM | 1224 | H | GLU | 135 | 23.136 | 7.796 | 10.872 | 0.00 | 0.00 | A |
| ATOM | 1225 | CA | GLU | 135 | 22.301 | 5.904 | 10.649 | 1.00 | 34.92 | A |
| ATOM | 1226 | CB | GLU | 135 | 22.448 | 5.092 | 11.926 | 1.00 | 37.94 | A |
| ATOM | 1227 | CG | GLU | 135 | 23.610 | 5.554 | 12.782 | 1.00 | 46.91 | A |
| ATOM | 1228 | CD | GLU | 135 | 24.759 | 4.578 | 12.776 | 1.00 | 53.68 | A |
| ATOM | 1229 | OE1 | GLU | 135 | 25.908 | 5.005 | 12.500 | 1.00 | 54.16 | A |
| ATOM | 1230 | OE2 | GLU | 135 | 24.504 | 3.383 | 13.078 | 1.00 | 59.91 | A |
| ATOM | 1231 | C | GLU | 135 | 21.115 | 5.424 | 9.838 | 1.00 | 32.81 | A |
| ATOM | 1232 | O | GLU | 135 | 20.434 | 4.476 | 10.202 | 1.00 | 33.96 | A |
| ATOM | 1233 | N | LYS | 136 | 20.891 | 6.080 | 8.711 | 1.00 | 32.41 | A |
| ATOM | 1234 | H | LYS | 136 | 21.495 | 6.788 | 8.450 | 0.00 | 0.00 | A |
| ATOM | 1235 | CA | LYS | 136 | 19.792 | 5.743 | 7.825 | 1.00 | 32.02 | A |
| ATOM | 1236 | CB | LYS | 136 | 19.952 | 4.325 | 7.307 | 1.00 | 33.56 | A |
| ATOM | 1237 | CG | LYS | 136 | 21.043 | 4.174 | 6.273 | 1.00 | 38.46 | A |
| ATOM | 1238 | CD | LYS | 136 | 20.608 | 4.810 | 4.980 | 1.00 | 46.59 | A |
| ATOM | 1239 | CE | LYS | 136 | 21.547 | 4.452 | 3.838 | 1.00 | 54.78 | A |
| ATOM | 1240 | NZ | LYS | 136 | 21.009 | 4.962 | 2.534 | 1.00 | 60.41 | A |
| ATOM | 1241 | HZ1 | LYS | 136 | 21.658 | 4.723 | 1.761 | 0.00 | 0.00 | A |
| ATOM | 1242 | HZ2 | LYS | 136 | 20.904 | 5.996 | 2.605 | 0.00 | 0.00 | A |
| ATOM | 1243 | HZ3 | LYS | 136 | 20.073 | 4.543 | 2.367 | 0.00 | 0.00 | A |
| ATOM | 1244 | C | LYS | 136 | 18.402 | 5.952 | 8.413 | 1.00 | 31.66 | A |
| ATOM | 1245 | O | LYS | 136 | 17.406 | 5.706 | 7.741 | 1.00 | 34.88 | A |
| ATOM | 1246 | N | LEU | 137 | 18.329 | 6.448 | 9.642 | 1.00 | 29.30 | A |
| ATOM | 1247 | H | LEU | 137 | 19.126 | 6.654 | 10.165 | 0.00 | 0.00 | A |
| ATOM | 1248 | CA | LEU | 137 | 17.052 | 6.714 | 10.278 | 1.00 | 26.15 | A |
| ATOM | 1249 | CB | LEU | 137 | 17.161 | 6.485 | 11.784 | 1.00 | 25.03 | A |
| ATOM | 1250 | CG | LEU | 137 | 17.562 | 5.102 | 12.264 | 1.00 | 21.54 | A |
| ATOM | 1251 | CD1 | LEU | 137 | 17.596 | 5.086 | 13.761 | 1.00 | 21.89 | A |
| ATOM | 1252 | CD2 | LEU | 137 | 16.552 | 4.130 | 11.780 | 1.00 | 19.81 | A |
| ATOM | 1253 | C | LEU | 137 | 16.616 | 8.166 | 10.044 | 1.00 | 26.29 | A |
| ATOM | 1254 | O | LEU | 137 | 17.451 | 9.080 | 9.977 | 1.00 | 27.61 | A |
| ATOM | 1255 | N | GLY | 138 | 15.306 | 8.369 | 9.924 | 1.00 | 23.39 | A |
| ATOM | 1256 | H | GLY | 138 | 14.740 | 7.572 | 9.944 | 0.00 | 0.00 | A |
| ATOM | 1257 | CA | GLY | 138 | 14.758 | 9.705 | 9.761 | 1.00 | 21.88 | A |
| ATOM | 1258 | C | GLY | 138 | 14.825 | 10.366 | 8.405 | 1.00 | 24.04 | A |
| ATOM | 1259 | O | GLY | 138 | 15.345 | 9.791 | 7.455 | 1.00 | 27.06 | A |
| ATOM | 1260 | N | PHE | 139 | 14.312 | 11.590 | 8.309 | 1.00 | 22.08 | A |
| ATOM | 1261 | H | PHE | 139 | 13.962 | 12.047 | 9.100 | 0.00 | 0.00 | A |
| ATOM | 1262 | CA | PHE | 139 | 14.326 | 12.275 | 7.037 | 1.00 | 21.96 | A |
| ATOM | 1263 | CB | PHE | 139 | 13.520 | 13.573 | 7.081 | 1.00 | 22.31 | A |
| ATOM | 1264 | CG | PHE | 139 | 14.159 | 14.694 | 7.866 | 1.00 | 25.89 | A |
| ATOM | 1265 | CD1 | PHE | 139 | 15.099 | 15.530 | 7.280 | 1.00 | 26.36 | A |
| ATOM | 1266 | CD2 | PHE | 139 | 13.766 | 14.963 | 9.168 | 1.00 | 23.00 | A |
| ATOM | 1267 | CE1 | PHE | 139 | 15.626 | 16.606 | 7.975 | 1.00 | 23.91 | A |
| ATOM | 1268 | CE2 | PHE | 139 | 14.297 | 16.046 | 9.865 | 1.00 | 19.11 | A |
| ATOM | 1269 | CZ | PHE | 139 | 15.223 | 16.862 | 9.266 | 1.00 | 20.65 | A |
| ATOM | 1270 | C | PHE | 139 | 15.752 | 12.493 | 6.593 | 1.00 | 23.69 | A |
| ATOM | 1271 | O | PHE | 139 | 16.040 | 12.523 | 5.411 | 1.00 | 25.47 | A |
| ATOM | 1272 | N | THR | 140 | 16.656 | 12.598 | 7.555 | 1.00 | 25.92 | A |
| ATOM | 1273 | H | THR | 140 | 16.419 | 12.553 | 8.499 | 0.00 | 0.00 | A |
| ATOM | 1274 | CA | THR | 140 | 18.061 | 12.789 | 7.247 | 1.00 | 27.92 | A |
| ATOM | 1275 | CB | THR | 140 | 18.852 | 13.277 | 8.473 | 1.00 | 25.74 | A |
| ATOM | 1276 | OG1 | THR | 140 | 18.504 | 12.475 | 9.610 | 1.00 | 29.71 | A |
| ATOM | 1277 | HG1 | THR | 140 | 19.075 | 12.761 | 10.332 | 0.00 | 0.00 | A |
| ATOM | 1278 | CG2 | THR | 140 | 18.549 | 14.734 | 8.760 | 1.00 | 23.98 | A |
| ATOM | 1279 | C | THR | 140 | 18.615 | 11.449 | 6.802 | 1.00 | 30.25 | A |
| ATOM | 1280 | O | THR | 140 | 19.300 | 11.370 | 5.784 | 1.00 | 32.63 | A |
| ATOM | 1281 | N | GLY | 141 | 18.311 | 10.399 | 7.566 | 1.00 | 30.57 | A |
| ATOM | 1282 | H | GLY | 141 | 17.791 | 10.512 | 8.388 | 0.00 | 0.00 | A |
| ATOM | 1283 | CA | GLY | 141 | 18.783 | 9.066 | 7.236 | 1.00 | 27.52 | A |
| ATOM | 1284 | C | GLY | 141 | 18.269 | 8.621 | 5.887 | 1.00 | 28.40 | A |
| ATOM | 1285 | O | GLY | 141 | 18.932 | 7.879 | 5.169 | 1.00 | 31.36 | A |
| ATOM | 1286 | N | ARG | 142 | 17.101 | 9.115 | 5.512 | 1.00 | 27.14 | A |
| ATOM | 1287 | H | ARG | 142 | 16.632 | 9.732 | 6.100 | 0.00 | 0.00 | A |
| ATOM | 1288 | CA | ARG | 142 | 16.529 | 8.752 | 4.237 | 1.00 | 26.43 | A |
| ATOM | 1289 | CB | ARG | 142 | 15.022 | 8.774 | 4.315 | 1.00 | 24.81 | A |
| ATOM | 1290 | CG | ARG | 142 | 14.487 | 7.713 | 5.206 | 1.00 | 27.61 | A |
| ATOM | 1291 | CD | ARG | 142 | 13.017 | 7.558 | 4.976 | 1.00 | 30.19 | A |
| ATOM | 1292 | NE | ARG | 142 | 12.382 | 8.836 | 5.192 | 1.00 | 30.84 | A |
| ATOM | 1293 | HE | ARG | 142 | 12.329 | 9.363 | 4.379 | 0.00 | 0.00 | A |
| ATOM | 1294 | CZ | ARG | 142 | 11.960 | 9.248 | 6.373 | 1.00 | 33.19 | A |
| ATOM | 1295 | NH1 | ARG | 142 | 11.412 | 10.443 | 6.498 | 1.00 | 36.93 | A |
| ATOM | 1296 | HH11 | ARG | 142 | 11.365 | 11.001 | 5.637 | 0.00 | 0.00 | A |
| ATOM | 1297 | HH12 | ARG | 142 | 11.078 | 10.870 | 7.318 | 0.00 | 0.00 | A |
| ATOM | 1298 | NH2 | ARG | 142 | 12.061 | 8.443 | 7.417 | 1.00 | 34.52 | A |
| ATOM | 1299 | HH21 | ARG | 142 | 12.463 | 7.531 | 7.275 | 0.00 | 0.00 | A |
| ATOM | 1300 | HH22 | ARG | 142 | 11.754 | 8.692 | 8.326 | 0.00 | 0.00 | A |
| ATOM | 1301 | C | ARG | 142 | 17.001 | 9.662 | 3.120 | 1.00 | 27.65 | A |
| ATOM | 1302 | O | ARG | 142 | 16.570 | 9.537 | 1.976 | 1.00 | 30.73 | A |
| ATOM | 1303 | N | GLY | 143 | 17.873 | 10.596 | 3.451 | 1.00 | 26.31 | A |
| ATOM | 1304 | H | GLY | 143 | 18.182 | 10.681 | 4.371 | 0.00 | 0.00 | A |
| ATOM | 1305 | CA | GLY | 143 | 18.382 | 11.491 | 2.436 | 1.00 | 26.04 | A |
| ATOM | 1306 | C | GLY | 143 | 17.366 | 12.493 | 1.954 | 1.00 | 26.67 | A |
| ATOM | 1307 | O | GLY | 143 | 17.518 | 13.039 | 0.853 | 1.00 | 31.16 | A |
| ATOM | 1308 | N | GLU | 144 | 16.348 | 12.753 | 2.768 | 1.00 | 25.56 | A |
| ATOM | 1309 | H | GLU | 144 | 16.269 | 12.266 | 3.607 | 0.00 | 0.00 | A |
| ATOM | 1310 | CA | GLU | 144 | 15.309 | 13.705 | 2.423 | 1.00 | 22.74 | A |
| ATOM | 1311 | CB | GLU | 144 | 14.054 | 13.424 | 3.221 | 1.00 | 22.07 | A |
| ATOM | 1312 | CG | GLU | 144 | 13.480 | 12.061 | 2.943 | 1.00 | 25.86 | A |
| ATOM | 1313 | CD | GLU | 144 | 12.239 | 11.751 | 3.758 | 1.00 | 30.35 | A |
| ATOM | 1314 | OE1 | GLU | 144 | 11.601 | 10.711 | 3.465 | 1.00 | 29.02 | A |
| ATOM | 1315 | OE2 | GLU | 144 | 11.898 | 12.525 | 4.698 | 1.00 | 33.79 | A |
| ATOM | 1316 | C | GLU | 144 | 15.751 | 15.137 | 2.642 | 1.00 | 23.10 | A |
| ATOM | 1317 | O | GLU | 144 | 15.248 | 16.038 | 1.978 | 1.00 | 24.19 | A |
| ATOM | 1318 | N | GLY | 145 | 16.704 | 15.348 | 3.546 | 1.00 | 21.95 | A |
| ATOM | 1319 | H | GLY | 145 | 17.099 | 14.603 | 4.047 | 0.00 | 0.00 | A |
| ATOM | 1320 | CA | GLY | 145 | 17.183 | 16.695 | 3.820 | 1.00 | 21.94 | A |
| ATOM | 1321 | C | GLY | 145 | 18.362 | 16.701 | 4.766 | 1.00 | 23.67 | A |
| ATOM | 1322 | O | GLY | 145 | 18.848 | 15.640 | 5.154 | 1.00 | 27.13 | A |
| ATOM | 1323 | N | ILE | 146 | 18.868 | 17.882 | 5.098 | 1.00 | 23.66 | A |
| ATOM | 1324 | H | ILE | 146 | 18.457 | 18.703 | 4.749 | 0.00 | 0.00 | A |
| ATOM | 1325 | CA | ILE | 146 | 20.004 | 17.995 | 6.011 | 1.00 | 22.98 | A |
| ATOM | 1326 | CB | ILE | 146 | 21.224 | 18.739 | 5.382 | 1.00 | 22.94 | A |
| ATOM | 1327 | CG2 | ILE | 146 | 22.337 | 18.889 | 6.388 | 1.00 | 26.90 | A |
| ATOM | 1328 | CG1 | ILE | 146 | 21.852 | 17.946 | 4.255 | 1.00 | 23.49 | A |
| ATOM | 1329 | CD1 | ILE | 146 | 23.118 | 18.578 | 3.774 | 1.00 | 25.00 | A |
| ATOM | 1330 | C | ILE | 146 | 19.515 | 18.842 | 7.163 | 1.00 | 23.17 | A |
| ATOM | 1331 | O | ILE | 146 | 18.695 | 19.738 | 6.973 | 1.00 | 27.99 | A |
| ATOM | 1332 | N | ALA | 147 | 20.007 | 18.561 | 8.356 | 1.00 | 20.78 | A |
| ATOM | 1333 | H | ALA | 147 | 20.679 | 17.851 | 8.461 | 0.00 | 0.00 | A |
| ATOM | 1334 | CA | ALA | 147 | 19.635 | 19.321 | 9.530 | 1.00 | 18.10 | A |
| ATOM | 1335 | CB | ALA | 147 | 18.906 | 18.436 | 10.503 | 1.00 | 18.01 | A |
| ATOM | 1336 | C | ALA | 147 | 20.958 | 19.749 | 10.105 | 1.00 | 18.07 | A |
| ATOM | 1337 | O | ALA | 147 | 21.989 | 19.230 | 9.713 | 1.00 | 20.10 | A |
| ATOM | 1338 | N | CYS | 148 | 20.950 | 20.729 | 10.987 | 1.00 | 19.44 | A |
| ATOM | 1339 | H | CYS | 148 | 20.113 | 21.186 | 11.220 | 0.00 | 0.00 | A |
| ATOM | 1340 | CA | CYS | 148 | 22.179 | 21.176 | 11.612 | 1.00 | 21.10 | A |
| ATOM | 1341 | CB | CYS | 148 | 22.950 | 22.088 | 10.679 | 1.00 | 24.72 | A |
| ATOM | 1342 | SG | CYS | 148 | 24.473 | 22.729 | 11.412 | 1.00 | 36.01 | A |
| ATOM | 1343 | C | CYS | 148 | 21.872 | 21.897 | 12.910 | 1.00 | 21.84 | A |
| ATOM | 1344 | O | CYS | 148 | 20.861 | 22.591 | 13.021 | 1.00 | 23.33 | A |
| ATOM | 1345 | N | GLU | 149 | 22.710 | 21.679 | 13.912 | 1.00 | 21.80 | A |
| ATOM | 1346 | H | GLU | 149 | 23.480 | 21.092 | 13.789 | 0.00 | 0.00 | A |
| ATOM | 1347 | CA | GLU | 149 | 22.542 | 22.322 | 15.208 | 1.00 | 23.33 | A |
| ATOM | 1348 | CB | GLU | 149 | 22.391 | 21.297 | 16.298 | 1.00 | 21.78 | A |
| ATOM | 1349 | CG | GLU | 149 | 21.179 | 20.496 | 16.175 | 1.00 | 27.92 | A |
| ATOM | 1350 | CD | GLU | 149 | 20.722 | 20.061 | 17.518 | 1.00 | 33.04 | A |
| ATOM | 1351 | OE1 | GLU | 149 | 20.545 | 20.949 | 18.381 | 1.00 | 34.62 | A |
| ATOM | 1352 | OE2 | GLU | 149 | 20.604 | 18.840 | 17.721 | 1.00 | 38.76 | A |
| ATOM | 1353 | C | GLU | 149 | 23.791 | 23.111 | 15.502 | 1.00 | 23.69 | A |
| ATOM | 1354 | O | GLU | 149 | 24.850 | 22.810 | 14.950 | 1.00 | 27.17 | A |
| ATOM | 1355 | N | ALA | 150 | 23.693 | 24.083 | 16.399 | 1.00 | 21.91 | A |
| ATOM | 1356 | H | ALA | 150 | 22.832 | 24.274 | 16.829 | 0.00 | 0.00 | A |
| ATOM | 1357 | CA | ALA | 150 | 24.855 | 24.888 | 16.735 | 1.00 | 22.23 | A |
| ATOM | 1358 | CB | ALA | 150 | 25.104 | 25.921 | 15.661 | 1.00 | 22.94 | A |
| ATOM | 1359 | C | ALA | 150 | 24.688 | 25.579 | 18.054 | 1.00 | 21.56 | A |
| ATOM | 1360 | O | ALA | 150 | 23.568 | 25.826 | 18.500 | 1.00 | 23.41 | A |
| ATOM | 1361 | N | VAL | 151 | 25.804 | 25.827 | 18.714 | 1.00 | 21.13 | A |
| ATOM | 1362 | H | VAL | 151 | 26.673 | 25.561 | 18.343 | 0.00 | 0.00 | A |
| ATOM | 1363 | CA | VAL | 151 | 25.773 | 26.544 | 19.968 | 1.00 | 21.99 | A |
| ATOM | 1364 | CB | VAL | 151 | 26.038 | 25.647 | 21.169 | 1.00 | 19.52 | A |
| ATOM | 1365 | CG1 | VAL | 151 | 24.895 | 24.669 | 21.352 | 1.00 | 18.30 | A |
| ATOM | 1366 | CG2 | VAL | 151 | 27.353 | 24.952 | 21.016 | 1.00 | 17.36 | A |
| ATOM | 1367 | C | VAL | 151 | 26.854 | 27.596 | 19.872 | 1.00 | 24.67 | A |
| ATOM | 1368 | O | VAL | 151 | 27.799 | 27.445 | 19.096 | 1.00 | 28.39 | A |
| ATOM | 1369 | N | ALA | 152 | 26.686 | 28.676 | 20.625 | 1.00 | 26.23 | A |
| ATOM | 1370 | H | ALA | 152 | 25.895 | 28.733 | 21.205 | 0.00 | 0.00 | A |
| ATOM | 1371 | CA | ALA | 152 | 27.637 | 29.781 | 20.653 | 1.00 | 26.91 | A |
| ATOM | 1372 | CB | ALA | 152 | 27.222 | 30.843 | 19.683 | 1.00 | 25.69 | A |
| ATOM | 1373 | C | ALA | 152 | 27.727 | 30.377 | 22.052 | 1.00 | 28.23 | A |
| ATOM | 1374 | O | ALA | 152 | 26.777 | 30.309 | 22.836 | 1.00 | 30.70 | A |
| ATOM | 1375 | N | LEU | 153 | 28.887 | 30.927 | 22.374 | 1.00 | 28.90 | A |
| ATOM | 1376 | H | LEU | 153 | 29.614 | 30.923 | 21.718 | 0.00 | 0.00 | A |
| ATOM | 1377 | CA | LEU | 153 | 29.099 | 31.552 | 23.660 | 1.00 | 28.89 | A |
| ATOM | 1378 | CB | LEU | 153 | 30.127 | 30.764 | 24.440 | 1.00 | 28.40 | A |
| ATOM | 1379 | CG | LEU | 153 | 30.339 | 31.140 | 25.895 | 1.00 | 31.89 | A |
| ATOM | 1380 | CD1 | LEU | 153 | 30.578 | 29.892 | 26.700 | 1.00 | 33.79 | A |
| ATOM | 1381 | CD2 | LEU | 153 | 31.532 | 32.071 | 26.020 | 1.00 | 37.99 | A |
| ATOM | 1382 | C | LEU | 153 | 29.608 | 32.949 | 23.340 | 1.00 | 31.48 | A |
| ATOM | 1383 | O | LEU | 153 | 30.561 | 33.092 | 22.573 | 1.00 | 33.68 | A |
| ATOM | 1384 | N | LEU | 154 | 28.889 | 33.969 | 23.803 | 1.00 | 30.64 | A |
| ATOM | 1385 | H | LEU | 154 | 28.095 | 33.789 | 24.322 | 0.00 | 0.00 | A |
| ATOM | 1386 | CA | LEU | 154 | 29.268 | 35.355 | 23.582 | 1.00 | 27.82 | A |
| ATOM | 1387 | CB | LEU | 154 | 28.091 | 36.184 | 23.111 | 1.00 | 25.01 | A |
| ATOM | 1388 | CG | LEU | 154 | 27.412 | 35.772 | 21.816 | 1.00 | 23.83 | A |
| ATOM | 1389 | CD1 | LEU | 154 | 26.184 | 36.643 | 21.637 | 1.00 | 20.87 | A |
| ATOM | 1390 | CD2 | LEU | 154 | 28.368 | 35.877 | 20.638 | 1.00 | 20.24 | A |
| ATOM | 1391 | C | LEU | 154 | 29.756 | 35.900 | 24.900 | 1.00 | 29.35 | A |
| ATOM | 1392 | O | LEU | 154 | 29.374 | 35.420 | 25.962 | 1.00 | 26.36 | A |
| ATOM | 1393 | N | ILE | 155 | 30.548 | 36.957 | 24.822 | 1.00 | 33.77 | A |
| ATOM | 1394 | H | ILE | 155 | 30.733 | 37.349 | 23.950 | 0.00 | 0.00 | A |
| ATOM | 1395 | CA | ILE | 155 | 31.147 | 37.565 | 25.994 | 1.00 | 37.56 | A |
| ATOM | 1396 | CB | ILE | 155 | 32.649 | 37.529 | 25.835 | 1.00 | 38.25 | A |
| ATOM | 1397 | CG2 | ILE | 155 | 33.312 | 38.264 | 26.951 | 1.00 | 41.51 | A |
| ATOM | 1398 | CG1 | ILE | 155 | 33.113 | 36.083 | 25.796 | 1.00 | 39.34 | A |
| ATOM | 1399 | CD1 | ILE | 155 | 34.560 | 35.958 | 25.502 | 1.00 | 43.17 | A |
| ATOM | 1400 | C | ILE | 155 | 30.698 | 38.998 | 26.260 | 1.00 | 39.78 | A |
| ATOM | 1401 | O | ILE | 155 | 30.220 | 39.685 | 25.358 | 1.00 | 45.46 | A |
| ATOM | 1402 | ZN | ZN | 156 | 17.514 | 27.639 | 6.845 | 1.00 | 46.53 | A |
| ATOM | 1403 | C1 | SUB | 669 | 15.216 | 31.821 | 7.568 | 1.00 | 71.79 | A |
| ATOM | 1404 | N1 | SUB | 669 | 8.512 | 30.521 | 12.641 | 1.00 | 34.81 | A |
| ATOM | 1405 | C3 | SUB | 669 | 7.404 | 30.610 | 13.395 | 1.00 | 35.06 | A |
| ATOM | 1406 | N3 | SUB | 669 | 6.724 | 29.477 | 13.678 | 1.00 | 33.19 | A |
| ATOM | 1407 | C4 | SUB | 669 | 7.117 | 28.284 | 13.237 | 1.00 | 30.19 | A |
| ATOM | 1408 | C5 | SUB | 669 | 8.331 | 28.194 | 12.419 | 1.00 | 29.30 | A |
| ATOM | 1409 | C6 | SUB | 669 | 8.970 | 29.334 | 12.161 | 1.00 | 31.06 | A |
| ATOM | 1410 | O8 | SUB | 669 | 7.012 | 31.682 | 13.821 | 1.00 | 37.83 | A |
| ATOM | 1411 | N4 | SUB | 669 | 6.389 | 27.217 | 13.562 | 1.00 | 29.45 | A |
| ATOM | 1412 | C1′ | SUB | 669 | 9.270 | 31.736 | 12.314 | 1.00 | 39.26 | A |
| ATOM | 1413 | C2′ | SUB | 669 | 10.512 | 32.023 | 13.152 | 1.00 | 44.03 | A |
| ATOM | 1414 | O2′ | SUB | 669 | 10.305 | 33.151 | 14.018 | 1.00 | 50.70 | A |
| ATOM | 1415 | C3′ | SUB | 669 | 11.651 | 32.240 | 12.149 | 1.00 | 44.36 | A |
| ATOM | 1416 | C4′ | SUB | 669 | 10.987 | 32.244 | 10.754 | 1.00 | 42.71 | A |
| ATOM | 1417 | O4′ | SUB | 669 | 9.678 | 31.693 | 10.926 | 1.00 | 39.67 | A |
| ATOM | 1418 | O3′ | SUB | 669 | 12.253 | 33.510 | 12.342 | 1.00 | 46.07 | A |
| ATOM | 1419 | C5′ | SUB | 669 | 11.869 | 31.442 | 9.714 | 1.00 | 45.27 | A |
| ATOM | 1420 | O5′ | SUB | 669 | 11.440 | 30.076 | 9.471 | 1.00 | 50.96 | A |
| ATOM | 1421 | PA | SUB | 669 | 12.155 | 28.998 | 8.477 | 1.00 | 49.68 | A |
| ATOM | 1422 | O1A | SUB | 669 | 11.881 | 27.525 | 9.034 | 1.00 | 53.26 | A |
| ATOM | 1423 | O2A | SUB | 669 | 11.541 | 29.133 | 7.002 | 1.00 | 55.80 | A |
| ATOM | 1424 | O3A | SUB | 669 | 13.758 | 29.217 | 8.557 | 1.00 | 59.44 | A |
| ATOM | 1425 | PB | SUB | 669 | 14.699 | 29.269 | 7.221 | 1.00 | 62.77 | A |
| ATOM | 1426 | O1B | SUB | 669 | 16.173 | 28.784 | 7.652 | 1.00 | 58.86 | A |
| ATOM | 1427 | O2B | SUB | 669 | 14.788 | 30.775 | 6.696 | 1.00 | 67.21 | A |
| ATOM | 1428 | O3B | SUB | 669 | 14.191 | 28.335 | 6.019 | 1.00 | 63.75 | A |
| ATOM | 1429 | C27 | SUB | 669 | 15.158 | 33.136 | 6.741 | 1.00 | 73.86 | A |
| ATOM | 1430 | C28 | SUB | 669 | 16.061 | 33.211 | 5.457 | 1.00 | 74.19 | A |
| ATOM | 1431 | C29 | SUB | 669 | 15.597 | 34.476 | 4.643 | 1.00 | 74.40 | A |
| ATOM | 1432 | O30 | SUB | 669 | 16.370 | 34.642 | 3.439 | 1.00 | 76.36 | A |
| ATOM | 1433 | O31 | SUB | 669 | 15.895 | 32.070 | 4.562 | 1.00 | 74.90 | A |
| ATOM | 1434 | C32 | SUB | 669 | 17.563 | 33.361 | 5.828 | 1.00 | 72.22 | A |
| ATOM | 1435 | O33 | SUB | 669 | 15.560 | 34.235 | 7.570 | 1.00 | 78.73 | A |
| END | | | | | | | | | | |

ANNEX 6
coordinates of structure subs

| | | | | | | | | | | |
|---|---|---|---|---|---|---|---|---|---|---|
| ATOM | 1 | CB | MET | 1 | 30.210 | 34.084 | 29.135 | 1.00 | 54.37 | A |
| ATOM | 2 | CG | MET | 1 | 31.670 | 34.410 | 29.042 | 1.00 | 60.18 | A |
| ATOM | 3 | SD | MET | 1 | 32.637 | 32.911 | 29.183 | 1.00 | 70.78 | A |
| ATOM | 4 | CE | MET | 1 | 33.690 | 33.062 | 27.721 | 1.00 | 65.61 | A |
| ATOM | 5 | C | MET | 1 | 27.870 | 34.769 | 28.759 | 1.00 | 50.44 | A |
| ATOM | 6 | O | MET | 1 | 27.206 | 34.443 | 29.739 | 1.00 | 51.39 | A |
| ATOM | 7 | HT1 | MET | 1 | 29.025 | 35.666 | 30.875 | 0.00 | 0.00 | A |
| ATOM | 8 | HT2 | MET | 1 | 28.743 | 37.020 | 29.919 | 0.00 | 0.00 | A |
| ATOM | 9 | N | MET | 1 | 29.395 | 36.231 | 30.079 | 1.00 | 53.68 | A |
| ATOM | 10 | HT3 | MET | 1 | 30.367 | 36.535 | 30.255 | 0.00 | 0.00 | A |
| ATOM | 11 | CA | MET | 1 | 29.290 | 35.279 | 28.928 | 1.00 | 52.53 | A |
| ATOM | 12 | N | ARG | 2 | 27.419 | 34.668 | 27.516 | 1.00 | 48.38 | A |
| ATOM | 13 | H | ARG | 2 | 27.983 | 34.842 | 26.737 | 0.00 | 0.00 | A |
| ATOM | 14 | CA | ARG | 2 | 26.073 | 34.194 | 27.240 | 1.00 | 46.90 | A |
| ATOM | 15 | CB | ARG | 2 | 25.225 | 35.332 | 26.700 | 1.00 | 46.27 | A |
| ATOM | 16 | CG | ARG | 2 | 24.897 | 36.327 | 27.779 | 1.00 | 48.58 | A |
| ATOM | 17 | CD | ARG | 2 | 24.366 | 37.607 | 27.212 | 1.00 | 50.52 | A |
| ATOM | 18 | NE | ARG | 2 | 23.066 | 37.422 | 26.597 | 1.00 | 52.42 | A |
| ATOM | 19 | HE | ARG | 2 | 23.052 | 36.890 | 25.770 | 0.00 | 0.00 | A |
| ATOM | 20 | CZ | ARG | 2 | 21.923 | 37.895 | 27.085 | 1.00 | 53.98 | A |
| ATOM | 21 | NH1 | ARG | 2 | 20.802 | 37.664 | 26.425 | 1.00 | 56.61 | A |
| ATOM | 22 | HH11 | ARG | 2 | 20.817 | 37.125 | 25.579 | 0.00 | 0.00 | A |
| ATOM | 23 | HH12 | ARG | 2 | 19.928 | 38.026 | 26.751 | 0.00 | 0.00 | A |
| ATOM | 24 | NH2 | ARG | 2 | 21.887 | 38.565 | 28.236 | 1.00 | 54.43 | A |
| ATOM | 25 | HH21 | ARG | 2 | 22.680 | 38.720 | 28.819 | 0.00 | 0.00 | A |
| ATOM | 26 | HH22 | ARG | 2 | 20.992 | 38.895 | 28.602 | 0.00 | 0.00 | A |
| ATOM | 27 | C | ARG | 2 | 26.080 | 33.022 | 26.286 | 1.00 | 45.74 | A |
| ATOM | 28 | O | ARG | 2 | 26.973 | 32.898 | 25.449 | 1.00 | 47.13 | A |
| ATOM | 29 | N | ILE | 3 | 25.075 | 32.168 | 26.409 | 1.00 | 43.22 | A |
| ATOM | 30 | H | ILE | 3 | 24.324 | 32.377 | 26.998 | 0.00 | 0.00 | A |
| ATOM | 31 | CA | ILE | 3 | 24.974 | 30.988 | 25.569 | 1.00 | 41.71 | A |
| ATOM | 32 | CB | ILE | 3 | 24.562 | 29.797 | 26.426 | 1.00 | 43.50 | A |
| ATOM | 33 | CG2 | ILE | 3 | 23.115 | 29.919 | 26.816 | 1.00 | 43.43 | A |
| ATOM | 34 | CG1 | ILE | 3 | 24.800 | 28.489 | 25.686 | 1.00 | 47.16 | A |
| ATOM | 35 | CD1 | ILE | 3 | 24.448 | 27.276 | 26.507 | 1.00 | 50.04 | A |
| ATOM | 36 | C | ILE | 3 | 23.954 | 31.221 | 24.454 | 1.00 | 38.66 | A |
| ATOM | 37 | O | ILE | 3 | 23.266 | 32.226 | 24.448 | 1.00 | 38.64 | A |
| ATOM | 38 | N | GLY | 4 | 23.867 | 30.306 | 23.504 | 1.00 | 36.81 | A |
| ATOM | 39 | H | GLY | 4 | 24.470 | 29.539 | 23.472 | 0.00 | 0.00 | A |
| ATOM | 40 | CA | GLY | 4 | 22.912 | 30.468 | 22.427 | 1.00 | 37.68 | A |
| ATOM | 41 | C | GLY | 4 | 22.752 | 29.181 | 21.646 | 1.00 | 38.03 | A |
| ATOM | 42 | O | GLY | 4 | 23.720 | 28.442 | 21.454 | 1.00 | 40.63 | A |
| ATOM | 43 | N | HIS | 5 | 21.542 | 28.889 | 21.193 | 1.00 | 35.84 | A |
| ATOM | 44 | H | HIS | 5 | 20.808 | 29.516 | 21.367 | 0.00 | 0.00 | A |
| ATOM | 45 | CA | HIS | 5 | 21.325 | 27.662 | 20.445 | 1.00 | 34.92 | A |
| ATOM | 46 | CB | HIS | 5 | 20.524 | 26.668 | 21.264 | 1.00 | 31.56 | A |
| ATOM | 47 | CG | HIS | 5 | 20.136 | 25.441 | 20.508 | 1.00 | 28.95 | A |
| ATOM | 48 | CD2 | HIS | 5 | 20.652 | 24.189 | 20.512 | 1.00 | 27.06 | A |
| ATOM | 49 | ND1 | HIS | 5 | 19.056 | 25.408 | 19.652 | 1.00 | 27.85 | A |
| ATOM | 50 | HD1 | HIS | 5 | 18.423 | 26.135 | 19.459 | 0.00 | 0.00 | A |
| ATOM | 51 | CE1 | HIS | 5 | 18.919 | 24.186 | 19.167 | 1.00 | 29.70 | A |
| ATOM | 52 | NE2 | HIS | 5 | 19.873 | 23.427 | 19.675 | 1.00 | 27.18 | A |
| ATOM | 53 | HE2 | HIS | 5 | 19.868 | 22.433 | 19.551 | 0.00 | 0.00 | A |
| ATOM | 54 | C | HIS | 5 | 20.606 | 27.924 | 19.153 | 1.00 | 35.77 | A |
| ATOM | 55 | O | HIS | 5 | 19.651 | 28.698 | 19.127 | 1.00 | 38.12 | A |
| ATOM | 56 | N | GLY | 6 | 21.024 | 27.219 | 18.104 | 1.00 | 36.03 | A |
| ATOM | 57 | H | GLY | 6 | 21.764 | 26.575 | 18.185 | 0.00 | 0.00 | A |
| ATOM | 58 | CA | GLY | 6 | 20.419 | 27.375 | 16.792 | 1.00 | 35.49 | A |
| ATOM | 59 | C | GLY | 6 | 20.117 | 26.035 | 16.162 | 1.00 | 34.68 | A |
| ATOM | 60 | O | GLY | 6 | 20.626 | 25.012 | 16.634 | 1.00 | 35.54 | A |
| ATOM | 61 | N | PHE | 7 | 19.311 | 26.038 | 15.102 | 1.00 | 32.49 | A |
| ATOM | 62 | H | PHE | 7 | 18.948 | 26.880 | 14.740 | 0.00 | 0.00 | A |
| ATOM | 63 | CA | PHE | 7 | 18.931 | 24.805 | 14.427 | 1.00 | 31.89 | A |
| ATOM | 64 | CB | PHE | 7 | 17.981 | 24.013 | 15.325 | 1.00 | 30.27 | A |
| ATOM | 65 | CG | PHE | 7 | 17.403 | 22.797 | 14.680 | 1.00 | 29.32 | A |
| ATOM | 66 | CD1 | PHE | 7 | 18.032 | 21.572 | 14.790 | 1.00 | 31.55 | A |
| ATOM | 67 | CD2 | PHE | 7 | 16.227 | 22.867 | 13.961 | 1.00 | 30.73 | A |
| ATOM | 68 | CE1 | PHE | 7 | 17.493 | 20.423 | 14.186 | 1.00 | 31.39 | A |
| ATOM | 69 | CE2 | PHE | 7 | 15.687 | 21.724 | 13.355 | 1.00 | 32.45 | A |
| ATOM | 70 | CZ | PHE | 7 | 16.324 | 20.502 | 13.469 | 1.00 | 27.62 | A |
| ATOM | 71 | C | PHE | 7 | 18.218 | 25.119 | 13.129 | 1.00 | 33.78 | A |
| ATOM | 72 | O | PHE | 7 | 17.311 | 25.956 | 13.118 | 1.00 | 34.93 | A |
| ATOM | 73 | N | ASP | 8 | 18.614 | 24.451 | 12.047 | 1.00 | 34.43 | A |
| ATOM | 74 | H | ASP | 8 | 19.346 | 23.799 | 12.110 | 0.00 | 0.00 | A |
| ATOM | 75 | CA | ASP | 8 | 17.964 | 24.637 | 10.748 | 1.00 | 36.71 | A |
| ATOM | 76 | CB | ASP | 8 | 18.666 | 25.722 | 9.909 | 1.00 | 39.26 | A |
| ATOM | 77 | CG | ASP | 8 | 17.748 | 26.317 | 8.811 | 1.00 | 45.10 | A |
| ATOM | 78 | OD1 | ASP | 8 | 18.260 | 26.782 | 7.760 | 1.00 | 44.84 | A |
| ATOM | 79 | OD2 | ASP | 8 | 16.506 | 26.323 | 8.997 | 1.00 | 47.92 | A |
| ATOM | 80 | C | ASP | 8 | 17.877 | 23.306 | 9.971 | 1.00 | 36.82 | A |
| ATOM | 81 | O | ASP | 8 | 18.570 | 22.330 | 10.292 | 1.00 | 38.64 | A |
| ATOM | 82 | N | VAL | 9 | 16.985 | 23.255 | 8.989 | 1.00 | 34.51 | A |
| ATOM | 83 | H | VAL | 9 | 16.466 | 24.074 | 8.777 | 0.00 | 0.00 | A |
| ATOM | 84 | CA | VAL | 9 | 16.784 | 22.077 | 8.162 | 1.00 | 31.92 | A |
| ATOM | 85 | CB | VAL | 9 | 15.617 | 21.242 | 8.673 | 1.00 | 29.67 | A |
| ATOM | 86 | CG1 | VAL | 9 | 15.214 | 20.220 | 7.637 | 1.00 | 27.07 | A |
| ATOM | 87 | CG2 | VAL | 9 | 15.992 | 20.566 | 9.968 | 1.00 | 29.55 | A |
| ATOM | 88 | C | VAL | 9 | 16.416 | 22.574 | 6.781 | 1.00 | 34.74 | A |
| ATOM | 89 | O | VAL | 9 | 15.861 | 23.657 | 6.643 | 1.00 | 36.47 | A |
| ATOM | 90 | N | HIS | 10 | 16.767 | 21.812 | 5.754 | 1.00 | 36.89 | A |
| ATOM | 91 | H | HIS | 10 | 17.251 | 20.971 | 5.918 | 0.00 | 0.00 | A |
| ATOM | 92 | CA | HIS | 10 | 16.438 | 22.182 | 4.378 | 1.00 | 39.20 | A |
| ATOM | 93 | CB | HIS | 10 | 17.512 | 23.061 | 3.730 | 1.00 | 42.35 | A |
| ATOM | 94 | CG | HIS | 10 | 17.273 | 24.530 | 3.902 | 1.00 | 45.47 | A |
| ATOM | 95 | CD2 | HIS | 10 | 17.983 | 25.481 | 4.556 | 1.00 | 46.89 | A |
| ATOM | 96 | ND1 | HIS | 10 | 16.172 | 25.169 | 3.379 | 1.00 | 45.88 | A |
| ATOM | 97 | HD1 | HIS | 10 | 15.387 | 24.772 | 2.920 | 0.00 | 0.00 | A |
| ATOM | 98 | CE1 | HIS | 10 | 16.212 | 26.449 | 3.703 | 1.00 | 48.01 | A |
| ATOM | 99 | NE2 | HIS | 10 | 17.302 | 26.665 | 4.416 | 1.00 | 47.26 | A |
| ATOM | 100 | C | HIS | 10 | 16.256 | 20.924 | 3.574 | 1.00 | 39.02 | A |
| ATOM | 101 | O | HIS | 10 | 17.011 | 19.957 | 3.721 | 1.00 | 37.81 | A |
| ATOM | 102 | N | ALA | 11 | 15.216 | 20.925 | 2.761 | 1.00 | 38.76 | A |
| ATOM | 103 | H | ALA | 11 | 14.629 | 21.719 | 2.733 | 0.00 | 0.00 | A |
| ATOM | 104 | CA | ALA | 11 | 14.910 | 19.779 | 1.942 | 1.00 | 39.11 | A |
| ATOM | 105 | CB | ALA | 11 | 13.452 | 19.820 | 1.544 | 1.00 | 41.39 | A |
| ATOM | 106 | C | ALA | 11 | 15.792 | 19.766 | 0.707 | 1.00 | 39.76 | A |
| ATOM | 107 | O | ALA | 11 | 16.093 | 20.820 | 0.146 | 1.00 | 42.40 | A |
| ATOM | 108 | N | PHE | 12 | 16.242 | 18.579 | 0.316 | 1.00 | 40.19 | A |
| ATOM | 109 | H | PHE | 12 | 15.975 | 17.780 | 0.818 | 0.00 | 0.00 | A |
| ATOM | 110 | CA | PHE | 12 | 17.058 | 18.424 | −0.881 | 1.00 | 40.48 | A |
| ATOM | 111 | CB | PHE | 12 | 17.522 | 16.985 | −1.029 | 1.00 | 36.59 | A |
| ATOM | 112 | CG | PHE | 12 | 18.795 | 16.691 | −0.337 | 1.00 | 33.79 | A |
| ATOM | 113 | CD1 | PHE | 12 | 19.887 | 17.528 | −0.487 | 1.00 | 32.25 | A |
| ATOM | 114 | CD2 | PHE | 12 | 18.914 | 15.565 | 0.453 | 1.00 | 32.15 | A |
| ATOM | 115 | CE1 | PHE | 12 | 21.080 | 17.247 | 0.140 | 1.00 | 31.86 | A |
| ATOM | 116 | CE2 | PHE | 12 | 20.105 | 15.273 | 1.084 | 1.00 | 34.24 | A |
| ATOM | 117 | CZ | PHE | 12 | 21.193 | 16.117 | 0.928 | 1.00 | 32.28 | A |
| ATOM | 118 | C | PHE | 12 | 16.134 | 18.725 | −2.040 | 1.00 | 43.89 | A |
| ATOM | 119 | O | PHE | 12 | 14.924 | 18.498 | −1.939 | 1.00 | 45.01 | A |
| ATOM | 120 | N | GLY | 13 | 16.690 | 19.193 | −3.148 | 1.00 | 45.84 | A |
| ATOM | 121 | H | GLY | 13 | 17.641 | 19.340 | −3.238 | 0.00 | 0.00 | A |
| ATOM | 122 | CA | GLY | 13 | 15.860 | 19.497 | −4.292 | 1.00 | 49.75 | A |
| ATOM | 123 | C | GLY | 13 | 16.677 | 20.003 | −5.453 | 1.00 | 53.50 | A |
| ATOM | 124 | O | GLY | 13 | 17.602 | 20.799 | −5.283 | 1.00 | 55.37 | A |
| ATOM | 125 | N | GLY | 14 | 16.344 | 19.525 | −6.642 | 1.00 | 55.18 | A |
| ATOM | 126 | H | GLY | 14 | 15.633 | 18.862 | −6.720 | 0.00 | 0.00 | A |
| ATOM | 127 | CA | GLY | 14 | 17.063 | 19.952 | −7.822 | 1.00 | 59.23 | A |
| ATOM | 128 | C | GLY | 14 | 18.460 | 19.379 | −7.902 | 1.00 | 61.46 | A |
| ATOM | 129 | O | GLY | 14 | 18.792 | 18.405 | −7.217 | 1.00 | 61.87 | A |
| ATOM | 130 | N | GLU | 15 | 19.270 | 19.996 | −8.752 | 1.00 | 62.98 | A |
| ATOM | 131 | H | GLU | 15 | 18.953 | 20.758 | −9.269 | 0.00 | 0.00 | A |
| ATOM | 132 | CA | GLU | 15 | 20.645 | 19.581 | −8.965 | 1.00 | 63.50 | A |
| ATOM | 133 | CB | GLU | 15 | 21.164 | 20.176 | −10.273 | 1.00 | 68.29 | A |
| ATOM | 134 | CG | GLU | 15 | 20.276 | 19.956 | −11.467 | 1.00 | 76.05 | A |
| ATOM | 135 | CD | GLU | 15 | 20.217 | 18.504 | −11.862 | 1.00 | 81.07 | A |
| ATOM | 136 | OE1 | GLU | 15 | 19.334 | 17.778 | −11.342 | 1.00 | 83.81 | A |
| ATOM | 137 | OE2 | GLU | 15 | 21.063 | 18.097 | −12.689 | 1.00 | 83.98 | A |
| ATOM | 138 | C | GLU | 15 | 21.503 | 20.140 | −7.854 | 1.00 | 61.92 | A |
| ATOM | 139 | O | GLU | 15 | 21.125 | 21.118 | −7.202 | 1.00 | 62.79 | A |
| ATOM | 140 | N | GLY | 16 | 22.657 | 19.518 | −7.642 | 1.00 | 59.51 | A |
| ATOM | 141 | H | GLY | 16 | 22.855 | 18.701 | −8.146 | 0.00 | 0.00 | A |
| ATOM | 142 | CA | GLY | 16 | 23.590 | 20.022 | −6.656 | 1.00 | 55.92 | A |
| ATOM | 143 | C | GLY | 16 | 24.333 | 21.188 | −7.302 | 1.00 | 52.55 | A |
| ATOM | 144 | O | GLY | 16 | 23.943 | 21.656 | −8.374 | 1.00 | 53.74 | A |
| ATOM | 145 | N | CPR | 17 | 25.397 | 21.702 | −6.680 | 1.00 | 47.77 | A |
| ATOM | 146 | CD | CPR | 17 | 26.192 | 22.755 | −7.336 | 1.00 | 45.97 | A |
| ATOM | 147 | CA | CPR | 17 | 26.002 | 21.314 | −5.412 | 1.00 | 44.26 | A |
| ATOM | 148 | CB | CPR | 17 | 27.414 | 21.847 | −5.569 | 1.00 | 45.74 | A |
| ATOM | 149 | CG | CPR | 17 | 27.166 | 23.155 | −6.263 | 1.00 | 45.53 | A |
| ATOM | 150 | C | CPR | 17 | 25.262 | 22.039 | −4.292 | 1.00 | 40.84 | A |
| ATOM | 151 | O | CPR | 17 | 24.333 | 22.807 | −4.539 | 1.00 | 42.02 | A |
| ATOM | 152 | N | ILE | 18 | 25.675 | 21.809 | −3.062 | 1.00 | 35.55 | A |
| ATOM | 153 | H | ILE | 18 | 26.431 | 21.221 | −2.885 | 0.00 | 0.00 | A |
| ATOM | 154 | CA | ILE | 18 | 25.031 | 22.465 | −1.955 | 1.00 | 31.75 | A |
| ATOM | 155 | CB | ILE | 18 | 24.520 | 21.435 | −0.953 | 1.00 | 31.58 | A |
| ATOM | 156 | CG2 | ILE | 18 | 23.749 | 20.364 | −1.696 | 1.00 | 33.50 | A |
| ATOM | 157 | CG1 | ILE | 18 | 25.675 | 20.754 | −0.229 | 1.00 | 30.95 | A |
| ATOM | 158 | CD1 | ILE | 18 | 25.208 | 19.793 | 0.829 | 1.00 | 31.28 | A |
| ATOM | 159 | C | ILE | 18 | 26.038 | 23.386 | −1.305 | 1.00 | 30.47 | A |
| ATOM | 160 | O | ILE | 18 | 27.221 | 23.367 | −1.651 | 1.00 | 28.16 | A |
| ATOM | 161 | N | ILE | 19 | 25.571 | 24.236 | −0.404 | 1.00 | 29.27 | A |
| ATOM | 162 | H | ILE | 19 | 24.623 | 24.274 | −0.159 | 0.00 | 0.00 | A |
| ATOM | 163 | CA | ILE | 19 | 26.485 | 25.131 | 0.281 | 1.00 | 27.03 | A |
| ATOM | 164 | CB | ILE | 19 | 26.199 | 26.567 | −0.031 | 1.00 | 24.23 | A |
| ATOM | 165 | CG2 | ILE | 19 | 27.354 | 27.406 | 0.434 | 1.00 | 26.37 | A |
| ATOM | 166 | CG1 | ILE | 19 | 25.975 | 26.742 | −1.527 | 1.00 | 25.55 | A |
| ATOM | 167 | CD1 | ILE | 19 | 27.148 | 26.396 | −2.381 | 1.00 | 27.49 | A |
| ATOM | 168 | C | ILE | 19 | 26.307 | 24.927 | 1.766 | 1.00 | 27.53 | A |
| ATOM | 169 | O | ILE | 19 | 25.189 | 24.998 | 2.271 | 1.00 | 31.49 | A |
| ATOM | 170 | N | ILE | 20 | 27.396 | 24.620 | 2.455 | 1.00 | 25.41 | A |
| ATOM | 171 | H | ILE | 20 | 28.265 | 24.567 | 2.000 | 0.00 | 0.00 | A |
| ATOM | 172 | CA | ILE | 20 | 27.348 | 24.386 | 3.888 | 1.00 | 25.14 | A |
| ATOM | 173 | CB | ILE | 20 | 27.464 | 22.891 | 4.209 | 1.00 | 24.05 | A |
| ATOM | 174 | CG2 | ILE | 20 | 27.337 | 22.684 | 5.699 | 1.00 | 25.85 | A |
| ATOM | 175 | CG1 | ILE | 20 | 26.425 | 22.067 | 3.441 | 1.00 | 21.20 | A |
| ATOM | 176 | CD1 | ILE | 20 | 25.002 | 22.255 | 3.891 | 1.00 | 18.83 | A |
| ATOM | 177 | C | ILE | 20 | 28.549 | 25.085 | 4.514 | 1.00 | 26.74 | A |
| ATOM | 178 | O | ILE | 20 | 29.671 | 24.941 | 4.027 | 1.00 | 27.38 | A |
| ATOM | 179 | N | GLY | 21 | 28.324 | 25.844 | 5.581 | 1.00 | 26.87 | A |
| ATOM | 180 | H | GLY | 21 | 27.407 | 25.973 | 5.884 | 0.00 | 0.00 | A |
| ATOM | 181 | CA | GLY | 21 | 29.419 | 26.545 | 6.227 | 1.00 | 25.83 | A |
| ATOM | 182 | C | GLY | 21 | 30.244 | 27.324 | 5.221 | 1.00 | 25.50 | A |
| ATOM | 183 | O | GLY | 21 | 31.454 | 27.489 | 5.379 | 1.00 | 25.95 | A |
| ATOM | 184 | N | GLY | 22 | 29.602 | 27.724 | 4.134 | 1.00 | 25.14 | A |
| ATOM | 185 | H | GLY | 22 | 28.668 | 27.494 | 4.001 | 0.00 | 0.00 | A |
| ATOM | 186 | CA | GLY | 22 | 30.285 | 28.488 | 3.113 | 1.00 | 27.65 | A |
| ATOM | 187 | C | GLY | 22 | 30.906 | 27.710 | 1.966 | 1.00 | 29.70 | A |
| ATOM | 188 | O | GLY | 22 | 31.176 | 28.295 | 0.907 | 1.00 | 32.98 | A |
| ATOM | 189 | N | VAL | 23 | 31.117 | 26.409 | 2.135 | 1.00 | 27.51 | A |
| ATOM | 190 | H | VAL | 23 | 30.857 | 25.982 | 2.977 | 0.00 | 0.00 | A |
| ATOM | 191 | CA | VAL | 23 | 31.730 | 25.618 | 1.076 | 1.00 | 27.40 | A |
| ATOM | 192 | CB | VAL | 23 | 32.576 | 24.487 | 1.656 | 1.00 | 25.36 | A |
| ATOM | 193 | CG1 | VAL | 23 | 33.212 | 23.679 | 0.554 | 1.00 | 25.45 | A |
| ATOM | 194 | CG2 | VAL | 23 | 33.638 | 25.059 | 2.543 | 1.00 | 25.83 | A |
| ATOM | 195 | C | VAL | 23 | 30.763 | 25.035 | 0.055 | 1.00 | 29.13 | A |
| ATOM | 196 | O | VAL | 23 | 29.741 | 24.447 | 0.407 | 1.00 | 31.93 | A |
| ATOM | 197 | N | ARG | 24 | 31.064 | 25.251 | −1.218 | 1.00 | 28.82 | A |
| ATOM | 198 | H | ARG | 24 | 31.809 | 25.822 | −1.389 | 0.00 | 0.00 | A |
| ATOM | 199 | CA | ARG | 24 | 30.250 | 24.703 | −2.288 | 1.00 | 28.63 | A |
| ATOM | 200 | CB | ARG | 24 | 30.595 | 25.369 | −3.616 | 1.00 | 31.26 | A |
| ATOM | 201 | CG | ARG | 24 | 29.645 | 25.000 | −4.744 | 1.00 | 39.80 | A |
| ATOM | 202 | CD | ARG | 24 | 30.133 | 25.532 | −6.093 | 1.00 | 49.09 | A |
| ATOM | 203 | NE | ARG | 24 | 29.063 | 26.136 | −6.889 | 1.00 | 55.73 | A |
| ATOM | 204 | HE | ARG | 24 | 28.657 | 26.937 | −6.484 | 0.00 | 0.00 | A |
| ATOM | 205 | CZ | ARG | 24 | 28.650 | 25.686 | −8.074 | 1.00 | 59.79 | A |
| ATOM | 206 | NH1 | ARG | 24 | 27.671 | 26.327 | −8.705 | 1.00 | 63.53 | A |
| ATOM | 207 | HH11 | ARG | 24 | 27.247 | 27.145 | −8.304 | 0.00 | 0.00 | A |
| ATOM | 208 | HH12 | ARG | 24 | 27.315 | 26.036 | −9.597 | 0.00 | 0.00 | A |
| ATOM | 209 | NH2 | ARG | 24 | 29.201 | 24.597 | −8.624 | 1.00 | 60.14 | A |
| ATOM | 210 | HH21 | ARG | 24 | 29.933 | 24.116 | −8.135 | 0.00 | 0.00 | A |
| ATOM | 211 | HH22 | ARG | 24 | 28.904 | 24.223 | −9.505 | 0.00 | 0.00 | A |
| ATOM | 212 | C | ARG | 24 | 30.643 | 23.237 | −2.320 | 1.00 | 27.78 | A |
| ATOM | 213 | O | ARG | 24 | 31.782 | 22.904 | −2.623 | 1.00 | 31.16 | A |
| ATOM | 214 | N | ILE | 25 | 29.739 | 22.369 | −1.911 | 1.00 | 26.03 | A |
| ATOM | 215 | H | ILE | 25 | 28.878 | 22.692 | −1.599 | 0.00 | 0.00 | A |
| ATOM | 216 | CA | ILE | 25 | 30.022 | 20.948 | −1.880 | 1.00 | 23.57 | A |
| ATOM | 217 | CB | ILE | 25 | 29.555 | 20.347 | −0.577 | 1.00 | 22.81 | A |
| ATOM | 218 | CG2 | ILE | 25 | 29.649 | 18.862 | −0.642 | 1.00 | 22.68 | A |
| ATOM | 219 | CG1 | ILE | 25 | 30.375 | 20.905 | 0.578 | 1.00 | 23.00 | A |
| ATOM | 220 | CD1 | ILE | 25 | 29.878 | 20.447 | 1.912 | 1.00 | 24.04 | A |
| ATOM | 221 | C | ILE | 25 | 29.267 | 20.257 | −2.973 | 1.00 | 25.56 | A |
| ATOM | 222 | O | ILE | 25 | 28.050 | 20.380 | −3.059 | 1.00 | 29.78 | A |
| ATOM | 223 | N | PRO | 26 | 29.959 | 19.477 | −3.803 | 1.00 | 27.04 | A |
| ATOM | 224 | CD | PRO | 26 | 31.409 | 19.226 | −3.844 | 1.00 | 25.27 | A |
| ATOM | 225 | CA | PRO | 26 | 29.266 | 18.778 | −4.889 | 1.00 | 26.93 | A |
| ATOM | 226 | CB | PRO | 26 | 30.426 | 18.264 | −5.732 | 1.00 | 25.31 | A |
| ATOM | 227 | CG | PRO | 26 | 31.504 | 18.017 | −4.721 | 1.00 | 22.81 | A |
| ATOM | 228 | C | PRO | 26 | 28.411 | 17.634 | −4.355 | 1.00 | 28.76 | A |
| ATOM | 229 | O | PRO | 26 | 28.841 | 16.935 | −3.439 | 1.00 | 30.11 | A |
| ATOM | 230 | N | TYR | 27 | 27.200 | 17.471 | −4.895 | 1.00 | 31.27 | A |
| ATOM | 231 | H | TYR | 27 | 26.869 | 18.075 | −5.592 | 0.00 | 0.00 | A |
| ATOM | 232 | CA | TYR | 27 | 26.277 | 16.387 | −4.498 | 1.00 | 35.93 | A |
| ATOM | 233 | CB | TYR | 27 | 25.560 | 16.717 | −3.195 | 1.00 | 34.75 | A |
| ATOM | 234 | CG | TYR | 27 | 24.652 | 15.629 | −2.644 | 1.00 | 32.44 | A |
| ATOM | 235 | CD1 | TYR | 27 | 25.171 | 14.430 | −2.177 | 1.00 | 31.62 | A |
| ATOM | 236 | CE1 | TYR | 27 | 24.359 | 13.488 | −1.532 | 1.00 | 32.17 | A |
| ATOM | 237 | CD2 | TYR | 27 | 23.287 | 15.859 | −2.470 | 1.00 | 33.85 | A |
| ATOM | 238 | CE2 | TYR | 27 | 22.473 | 14.928 | −1.828 | 1.00 | 34.54 | A |
| ATOM | 239 | CZ | TYR | 27 | 23.017 | 13.747 | −1.354 | 1.00 | 33.05 | A |
| ATOM | 240 | OH | TYR | 27 | 22.224 | 12.860 | −0.658 | 1.00 | 32.73 | A |
| ATOM | 241 | HH | TYR | 27 | 22.777 | 12.076 | −0.521 | 0.00 | 0.00 | A |
| ATOM | 242 | C | TYR | 27 | 25.246 | 16.253 | −5.598 | 1.00 | 39.95 | A |
| ATOM | 243 | O | TYR | 27 | 25.002 | 17.229 | −6.317 | 1.00 | 40.51 | A |
| ATOM | 244 | N | GLU | 28 | 24.626 | 15.075 | −5.717 | 1.00 | 44.34 | A |
| ATOM | 245 | H | GLU | 28 | 24.829 | 14.361 | −5.080 | 0.00 | 0.00 | A |
| ATOM | 246 | CA | GLU | 28 | 23.626 | 14.845 | −6.773 | 1.00 | 49.45 | A |
| ATOM | 247 | CB | GLU | 28 | 22.988 | 13.456 | −6.692 | 1.00 | 55.03 | A |
| ATOM | 248 | CG | GLU | 28 | 23.784 | 12.405 | −5.954 | 1.00 | 68.23 | A |
| ATOM | 249 | CD | GLU | 28 | 22.900 | 11.596 | −5.004 | 1.00 | 76.75 | A |
| ATOM | 250 | OE1 | GLU | 28 | 22.887 | 10.343 | −5.107 | 1.00 | 81.42 | A |
| ATOM | 251 | OE2 | GLU | 28 | 22.214 | 12.223 | −4.150 | 1.00 | 80.48 | A |
| ATOM | 252 | C | GLU | 28 | 22.520 | 15.876 | −6.674 | 1.00 | 48.18 | A |
| ATOM | 253 | O | GLU | 28 | 22.342 | 16.705 | −7.567 | 1.00 | 50.54 | A |
| ATOM | 254 | N | LYS | 29 | 21.767 | 15.813 | −5.589 | 1.00 | 45.41 | A |
| ATOM | 255 | H | LYS | 29 | 21.986 | 15.137 | −4.920 | 0.00 | 0.00 | A |
| ATOM | 256 | CA | LYS | 29 | 20.696 | 16.762 | −5.407 | 1.00 | 44.45 | A |
| ATOM | 257 | CB | LYS | 29 | 19.529 | 16.135 | −4.628 | 1.00 | 45.58 | A |
| ATOM | 258 | CG | LYS | 29 | 19.871 | 14.927 | −3.743 | 1.00 | 45.23 | A |
| ATOM | 259 | CD | LYS | 29 | 18.585 | 14.233 | −3.245 | 1.00 | 46.32 | A |
| ATOM | 260 | CE | LYS | 29 | 18.848 | 12.899 | −2.538 | 1.00 | 44.83 | A |
| ATOM | 261 | NZ | LYS | 29 | 19.536 | 13.029 | −1.218 | 1.00 | 45.96 | A |
| ATOM | 262 | HZ1 | LYS | 29 | 18.927 | 13.518 | −0.529 | 0.00 | 0.00 | A |
| ATOM | 263 | HZ2 | LYS | 29 | 20.479 | 13.476 | −1.295 | 0.00 | 0.00 | A |
| ATOM | 264 | HZ3 | LYS | 29 | 19.717 | 12.074 | −0.863 | 0.00 | 0.00 | A |
| ATOM | 265 | C | LYS | 29 | 21.216 | 18.021 | −4.731 | 1.00 | 43.42 | A |
| ATOM | 266 | O | LYS | 29 | 22.336 | 18.039 | −4.221 | 1.00 | 42.67 | A |
| ATOM | 267 | N | GLY | 30 | 20.442 | 19.095 | −4.830 | 1.00 | 41.62 | A |
| ATOM | 268 | H | GLY | 30 | 19.620 | 19.053 | −5.360 | 0.00 | 0.00 | A |
| ATOM | 269 | CA | GLY | 30 | 20.807 | 20.342 | −4.195 | 1.00 | 40.62 | A |
| ATOM | 270 | C | GLY | 30 | 19.865 | 20.571 | −3.026 | 1.00 | 41.93 | A |
| ATOM | 271 | O | GLY | 30 | 19.242 | 19.620 | −2.538 | 1.00 | 39.89 | A |
| ATOM | 272 | N | LEU | 31 | 19.751 | 21.823 | −2.581 | 1.00 | 43.44 | A |
| ATOM | 273 | H | LEU | 31 | 20.233 | 22.543 | −3.042 | 0.00 | 0.00 | A |
| ATOM | 274 | CA | LEU | 31 | 18.873 | 22.190 | −1.463 | 1.00 | 44.71 | A |
| ATOM | 275 | CB | LEU | 31 | 19.696 | 22.646 | −0.253 | 1.00 | 39.48 | A |
| ATOM | 276 | CG | LEU | 31 | 20.399 | 21.538 | 0.521 | 1.00 | 36.76 | A |
| ATOM | 277 | CD1 | LEU | 31 | 21.341 | 22.113 | 1.545 | 1.00 | 38.88 | A |
| ATOM | 278 | CD2 | LEU | 31 | 19.365 | 20.677 | 1.191 | 1.00 | 38.74 | A |
| ATOM | 279 | C | LEU | 31 | 17.902 | 23.297 | −1.862 | 1.00 | 47.59 | A |
| ATOM | 280 | O | LEU | 31 | 18.270 | 24.219 | −2.591 | 1.00 | 51.08 | A |
| ATOM | 281 | N | LEU | 32 | 16.672 | 23.214 | −1.376 | 1.00 | 48.29 | A |
| ATOM | 282 | H | LEU | 32 | 16.438 | 22.463 | −0.791 | 0.00 | 0.00 | A |
| ATOM | 283 | CA | LEU | 32 | 15.660 | 24.218 | −1.679 | 1.00 | 51.81 | A |
| ATOM | 284 | CB | LEU | 32 | 14.309 | 23.535 | −1.757 | 1.00 | 51.36 | A |
| ATOM | 285 | CG | LEU | 32 | 14.324 | 22.320 | −2.669 | 1.00 | 52.32 | A |
| ATOM | 286 | CD1 | LEU | 32 | 13.006 | 21.595 | −2.526 | 1.00 | 53.29 | A |
| ATOM | 287 | CD2 | LEU | 32 | 14.579 | 22.749 | −4.114 | 1.00 | 52.50 | A |
| ATOM | 288 | C | LEU | 32 | 15.616 | 25.311 | −0.607 | 1.00 | 54.99 | A |
| ATOM | 289 | O | LEU | 32 | 15.501 | 24.999 | 0.582 | 1.00 | 56.76 | A |
| ATOM | 290 | N | ALA | 33 | 15.695 | 26.581 | −1.011 | 1.00 | 57.94 | A |
| ATOM | 291 | H | ALA | 33 | 15.808 | 26.813 | −1.960 | 0.00 | 0.00 | A |
| ATOM | 292 | CA | ALA | 33 | 15.658 | 27.694 | −0.048 | 1.00 | 61.39 | A |
| ATOM | 293 | CB | ALA | 33 | 16.895 | 27.653 | 0.853 | 1.00 | 61.12 | A |
| ATOM | 294 | C | ALA | 33 | 15.545 | 29.080 | −0.706 | 1.00 | 63.74 | A |
| ATOM | 295 | O | ALA | 33 | 15.921 | 29.249 | −1.874 | 1.00 | 65.92 | A |
| ATOM | 296 | N | HIS | 34 | 15.004 | 30.054 | 0.038 | 1.00 | 63.62 | A |
| ATOM | 297 | H | HIS | 34 | 14.692 | 29.818 | 0.935 | 0.00 | 0.00 | A |
| ATOM | 298 | CA | HIS | 34 | 14.857 | 31.435 | −0.453 | 1.00 | 62.55 | A |
| ATOM | 299 | CB | HIS | 34 | 13.967 | 32.275 | 0.500 | 1.00 | 65.76 | A |
| ATOM | 300 | CG | HIS | 34 | 14.069 | 33.771 | 0.329 | 1.00 | 68.89 | A |
| ATOM | 301 | CD2 | HIS | 34 | 14.364 | 34.746 | 1.226 | 1.00 | 68.32 | A |
| ATOM | 302 | ND1 | HIS | 34 | 13.748 | 34.425 | −0.844 | 1.00 | 70.36 | A |
| ATOM | 303 | HD1 | HIS | 34 | 13.480 | 34.010 | −1.688 | 0.00 | 0.00 | A |
| ATOM | 304 | CE1 | HIS | 34 | 13.832 | 35.732 | −0.660 | 1.00 | 68.73 | A |
| ATOM | 305 | NE2 | HIS | 34 | 14.204 | 35.953 | 0.588 | 1.00 | 67.83 | A |
| ATOM | 306 | HE2 | HIS | 34 | 14.224 | 36.830 | 1.040 | 0.00 | 0.00 | A |
| ATOM | 307 | C | HIS | 34 | 16.260 | 32.013 | −0.590 | 1.00 | 59.89 | A |
| ATOM | 308 | O | HIS | 34 | 16.556 | 32.657 | −1.586 | 1.00 | 59.91 | A |
| ATOM | 309 | N | SER | 35 | 17.115 | 31.764 | 0.402 | 1.00 | 57.11 | A |
| ATOM | 310 | H | SER | 35 | 16.855 | 31.216 | 1.162 | 0.00 | 0.00 | A |
| ATOM | 311 | CA | SER | 35 | 18.498 | 32.231 | 0.375 | 1.00 | 53.10 | A |
| ATOM | 312 | CB | SER | 35 | 19.009 | 32.473 | 1.799 | 1.00 | 52.79 | A |
| ATOM | 313 | OG | SER | 35 | 19.334 | 31.250 | 2.456 | 1.00 | 51.98 | A |
| ATOM | 314 | HG | SER | 35 | 20.296 | 31.166 | 2.287 | 0.00 | 0.00 | A |
| ATOM | 315 | C | SER | 35 | 19.260 | 31.072 | −0.250 | 1.00 | 51.44 | A |
| ATOM | 316 | O | SER | 35 | 18.658 | 30.223 | −0.899 | 1.00 | 50.19 | A |
| ATOM | 317 | N | ASP | 36 | 20.569 | 31.009 | −0.016 | 1.00 | 50.81 | A |
| ATOM | 318 | H | ASP | 36 | 21.055 | 31.702 | 0.488 | 0.00 | 0.00 | A |
| ATOM | 319 | CA | ASP | 36 | 21.403 | 29.920 | −0.539 | 1.00 | 48.26 | A |
| ATOM | 320 | CB | ASP | 36 | 22.885 | 30.294 | −0.461 | 1.00 | 45.43 | A |
| ATOM | 321 | CG | ASP | 36 | 23.349 | 30.512 | 0.955 | 1.00 | 46.06 | A |
| ATOM | 322 | OD1 | ASP | 36 | 24.576 | 30.518 | 1.193 | 1.00 | 47.59 | A |
| ATOM | 323 | OD2 | ASP | 36 | 22.477 | 30.684 | 1.838 | 1.00 | 44.68 | A |
| ATOM | 324 | C | ASP | 36 | 21.146 | 28.639 | 0.270 | 1.00 | 46.72 | A |
| ATOM | 325 | O | ASP | 36 | 21.698 | 27.577 | −0.034 | 1.00 | 46.96 | A |
| ATOM | 326 | N | GLY | 37 | 20.334 | 28.765 | 1.320 | 1.00 | 44.13 | A |
| ATOM | 327 | H | GLY | 37 | 19.985 | 29.642 | 1.530 | 0.00 | 0.00 | A |
| ATOM | 328 | CA | GLY | 37 | 19.992 | 27.625 | 2.149 | 1.00 | 41.31 | A |
| ATOM | 329 | C | GLY | 37 | 21.159 | 26.941 | 2.832 | 1.00 | 39.74 | A |
| ATOM | 330 | O | GLY | 37 | 21.151 | 25.715 | 3.012 | 1.00 | 39.00 | A |
| ATOM | 331 | N | ASP | 38 | 22.175 | 27.711 | 3.201 | 1.00 | 36.39 | A |
| ATOM | 332 | H | ASP | 38 | 22.208 | 28.658 | 2.954 | 0.00 | 0.00 | A |
| ATOM | 333 | CA | ASP | 38 | 23.319 | 27.128 | 3.885 | 1.00 | 34.45 | A |
| ATOM | 334 | CB | ASP | 38 | 24.502 | 28.093 | 3.892 | 1.00 | 32.32 | A |
| ATOM | 335 | CG | ASP | 38 | 25.750 | 27.490 | 4.502 | 1.00 | 30.63 | A |
| ATOM | 336 | OD1 | ASP | 38 | 25.653 | 26.670 | 5.447 | 1.00 | 29.53 | A |
| ATOM | 337 | OD2 | ASP | 38 | 26.850 | 27.859 | 4.052 | 1.00 | 30.94 | A |
| ATOM | 338 | C | ASP | 38 | 22.862 | 26.832 | 5.306 | 1.00 | 35.00 | A |
| ATOM | 339 | O | ASP | 38 | 22.793 | 27.718 | 6.160 | 1.00 | 39.04 | A |
| ATOM | 340 | N | VAL | 39 | 22.525 | 25.582 | 5.554 | 1.00 | 32.02 | A |
| ATOM | 341 | H | VAL | 39 | 22.602 | 24.965 | 4.796 | 0.00 | 0.00 | A |
| ATOM | 342 | CA | VAL | 39 | 22.061 | 25.189 | 6.857 | 1.00 | 28.66 | A |
| ATOM | 343 | CB | VAL | 39 | 21.681 | 23.738 | 6.845 | 1.00 | 29.65 | A |
| ATOM | 344 | CG1 | VAL | 39 | 20.941 | 23.392 | 8.091 | 1.00 | 34.08 | A |
| ATOM | 345 | CG2 | VAL | 39 | 20.820 | 23.464 | 5.652 | 1.00 | 32.88 | A |
| ATOM | 346 | C | VAL | 39 | 23.092 | 25.439 | 7.948 | 1.00 | 28.36 | A |
| ATOM | 347 | O | VAL | 39 | 22.782 | 26.079 | 8.939 | 1.00 | 30.38 | A |
| ATOM | 348 | N | ALA | 40 | 24.325 | 24.981 | 7.753 | 1.00 | 28.14 | A |
| ATOM | 349 | H | ALA | 40 | 24.540 | 24.577 | 6.889 | 0.00 | 0.00 | A |
| ATOM | 350 | CA | ALA | 40 | 25.379 | 25.147 | 8.763 | 1.00 | 25.09 | A |
| ATOM | 351 | CB | ALA | 40 | 26.731 | 24.765 | 8.203 | 1.00 | 23.04 | A |
| ATOM | 352 | C | ALA | 40 | 25.435 | 26.562 | 9.261 | 1.00 | 23.98 | A |
| ATOM | 353 | O | ALA | 40 | 25.454 | 26.804 | 10.462 | 1.00 | 24.14 | A |
| ATOM | 354 | N | LEU | 41 | 25.407 | 27.508 | 8.336 | 1.00 | 22.42 | A |
| ATOM | 355 | H | LEU | 41 | 25.320 | 27.276 | 7.383 | 0.00 | 0.00 | A |
| ATOM | 356 | CA | LEU | 41 | 25.483 | 28.898 | 8.732 | 1.00 | 21.89 | A |
| ATOM | 357 | CB | LEU | 41 | 25.954 | 29.766 | 7.579 | 1.00 | 19.03 | A |
| ATOM | 358 | CG | LEU | 41 | 27.341 | 29.385 | 7.053 | 1.00 | 17.34 | A |
| ATOM | 359 | CD1 | LEU | 41 | 27.810 | 30.464 | 6.110 | 1.00 | 16.36 | A |
| ATOM | 360 | CD2 | LEU | 41 | 28.329 | 29.216 | 8.186 | 1.00 | 13.65 | A |
| ATOM | 361 | C | LEU | 41 | 24.213 | 29.435 | 9.369 | 1.00 | 23.47 | A |
| ATOM | 362 | O | LEU | 41 | 24.295 | 30.114 | 10.385 | 1.00 | 25.77 | A |
| ATOM | 363 | N | HIS | 42 | 23.043 | 29.129 | 8.815 | 1.00 | 23.88 | A |
| ATOM | 364 | H | HIS | 42 | 23.029 | 28.566 | 8.010 | 0.00 | 0.00 | A |
| ATOM | 365 | CA | HIS | 42 | 21.806 | 29.599 | 9.437 | 1.00 | 24.61 | A |
| ATOM | 366 | CB | HIS | 42 | 20.563 | 29.043 | 8.735 | 1.00 | 27.60 | A |
| ATOM | 367 | CG | HIS | 42 | 20.374 | 29.550 | 7.336 | 1.00 | 34.05 | A |
| ATOM | 368 | CD2 | HIS | 42 | 21.056 | 30.477 | 6.620 | 1.00 | 35.84 | A |
| ATOM | 369 | ND1 | HIS | 42 | 19.382 | 29.077 | 6.500 | 1.00 | 35.97 | A |
| ATOM | 370 | CE1 | HIS | 42 | 19.465 | 29.688 | 5.330 | 1.00 | 36.48 | A |
| ATOM | 371 | NE2 | HIS | 42 | 20.471 | 30.542 | 5.377 | 1.00 | 35.58 | A |
| ATOM | 372 | HE2 | HIS | 42 | 20.750 | 31.147 | 4.656 | 0.00 | 0.00 | A |
| ATOM | 373 | C | HIS | 42 | 21.830 | 29.118 | 10.891 | 1.00 | 24.68 | A |
| ATOM | 374 | O | HIS | 42 | 21.683 | 29.904 | 11.826 | 1.00 | 27.42 | A |
| ATOM | 375 | N | ALA | 43 | 22.140 | 27.849 | 11.091 | 1.00 | 22.92 | A |
| ATOM | 376 | H | ALA | 43 | 22.337 | 27.264 | 10.332 | 0.00 | 0.00 | A |
| ATOM | 377 | CA | ALA | 43 | 22.186 | 27.327 | 12.439 | 1.00 | 23.18 | A |
| ATOM | 378 | CB | ALA | 43 | 22.612 | 25.892 | 12.428 | 1.00 | 24.33 | A |
| ATOM | 379 | C | ALA | 43 | 23.129 | 28.165 | 13.290 | 1.00 | 24.33 | A |
| ATOM | 380 | O | ALA | 43 | 22.746 | 28.613 | 14.368 | 1.00 | 25.69 | A |
| ATOM | 381 | N | LEU | 44 | 24.334 | 28.428 | 12.790 | 1.00 | 23.76 | A |
| ATOM | 382 | H | LEU | 44 | 24.578 | 28.072 | 11.908 | 0.00 | 0.00 | A |
| ATOM | 383 | CA | LEU | 44 | 25.298 | 29.230 | 13.541 | 1.00 | 23.83 | A |
| ATOM | 384 | CB | LEU | 44 | 26.595 | 29.389 | 12.761 | 1.00 | 18.87 | A |
| ATOM | 385 | CG | LEU | 44 | 27.608 | 30.327 | 13.409 | 1.00 | 16.75 | A |
| ATOM | 386 | CD1 | LEU | 44 | 28.019 | 29.774 | 14.734 | 1.00 | 15.34 | A |
| ATOM | 387 | CD2 | LEU | 44 | 28.820 | 30.478 | 12.528 | 1.00 | 15.97 | A |
| ATOM | 388 | C | LEU | 44 | 24.723 | 30.612 | 13.861 | 1.00 | 28.05 | A |
| ATOM | 389 | O | LEU | 44 | 24.771 | 31.070 | 15.011 | 1.00 | 29.79 | A |
| ATOM | 390 | N | THR | 45 | 24.132 | 31.241 | 12.851 | 1.00 | 28.94 | A |
| ATOM | 391 | H | THR | 45 | 24.041 | 30.802 | 11.994 | 0.00 | 0.00 | A |
| ATOM | 392 | CA | THR | 45 | 23.544 | 32.563 | 12.984 | 1.00 | 30.15 | A |
| ATOM | 393 | CB | THR | 45 | 22.864 | 32.982 | 11.688 | 1.00 | 29.50 | A |
| ATOM | 394 | OG1 | THR | 45 | 23.775 | 32.813 | 10.597 | 1.00 | 32.02 | A |
| ATOM | 395 | HG1 | THR | 45 | 24.583 | 33.296 | 10.779 | 0.00 | 0.00 | A |
| ATOM | 396 | CG2 | THR | 45 | 22.417 | 34.431 | 11.768 | 1.00 | 29.14 | A |
| ATOM | 397 | C | THR | 45 | 22.513 | 32.656 | 14.111 | 1.00 | 30.78 | A |
| ATOM | 398 | O | THR | 45 | 22.568 | 33.568 | 14.938 | 1.00 | 31.32 | A |
| ATOM | 399 | N | ASP | 46 | 21.562 | 31.737 | 14.139 | 1.00 | 29.38 | A |
| ATOM | 400 | H | ASP | 46 | 21.507 | 31.036 | 13.454 | 0.00 | 0.00 | A |
| ATOM | 401 | CA | ASP | 46 | 20.561 | 31.790 | 15.181 | 1.00 | 30.15 | A |
| ATOM | 402 | CB | ASP | 46 | 19.559 | 30.666 | 15.044 | 1.00 | 32.23 | A |
| ATOM | 403 | CG | ASP | 46 | 18.406 | 31.035 | 14.186 | 1.00 | 34.62 | A |
| ATOM | 404 | OD1 | ASP | 46 | 17.518 | 30.181 | 13.981 | 1.00 | 41.00 | A |
| ATOM | 405 | OD2 | ASP | 46 | 18.387 | 32.181 | 13.715 | 1.00 | 34.80 | A |
| ATOM | 406 | C | ASP | 46 | 21.201 | 31.677 | 16.522 | 1.00 | 30.28 | A |
| ATOM | 407 | O | ASP | 46 | 20.897 | 32.450 | 17.411 | 1.00 | 32.31 | A |
| ATOM | 408 | N | ALA | 47 | 22.095 | 30.709 | 16.669 | 1.00 | 29.35 | A |
| ATOM | 409 | H | ALA | 47 | 22.303 | 30.142 | 15.891 | 0.00 | 0.00 | A |
| ATOM | 410 | CA | ALA | 47 | 22.755 | 30.495 | 17.939 | 1.00 | 31.05 | A |
| ATOM | 411 | CB | ALA | 47 | 23.748 | 29.351 | 17.831 | 1.00 | 32.64 | A |
| ATOM | 412 | C | ALA | 47 | 23.452 | 31.776 | 18.369 | 1.00 | 33.92 | A |
| ATOM | 413 | O | ALA | 47 | 23.427 | 32.141 | 19.554 | 1.00 | 34.86 | A |
| ATOM | 414 | N | LEU | 48 | 24.053 | 32.468 | 17.400 | 1.00 | 34.01 | A |
| ATOM | 415 | H | LEU | 48 | 24.031 | 32.121 | 16.483 | 0.00 | 0.00 | A |
| ATOM | 416 | CA | LEU | 48 | 24.749 | 33.723 | 17.675 | 1.00 | 31.58 | A |
| ATOM | 417 | CB | LEU | 48 | 25.555 | 34.184 | 16.463 | 1.00 | 29.45 | A |
| ATOM | 418 | CG | LEU | 48 | 26.955 | 33.597 | 16.349 | 1.00 | 29.57 | A |
| ATOM | 419 | CD1 | LEU | 48 | 27.607 | 34.147 | 15.120 | 1.00 | 31.27 | A |
| ATOM | 420 | CD2 | LEU | 48 | 27.772 | 33.965 | 17.566 | 1.00 | 28.68 | A |
| ATOM | 421 | C | LEU | 48 | 23.762 | 34.801 | 18.085 | 1.00 | 30.35 | A |
| ATOM | 422 | O | LEU | 48 | 23.969 | 35.471 | 19.093 | 1.00 | 30.98 | A |
| ATOM | 423 | N | LEU | 49 | 22.670 | 34.932 | 17.334 | 1.00 | 28.73 | A |
| ATOM | 424 | H | LEU | 49 | 22.530 | 34.329 | 16.585 | 0.00 | 0.00 | A |
| ATOM | 425 | CA | LEU | 49 | 21.651 | 35.925 | 17.632 | 1.00 | 29.07 | A |
| ATOM | 426 | CB | LEU | 49 | 20.620 | 36.007 | 16.510 | 1.00 | 27.47 | A |
| ATOM | 427 | CG | LEU | 49 | 21.100 | 36.705 | 15.237 | 1.00 | 27.15 | A |
| ATOM | 428 | CD1 | LEU | 49 | 19.933 | 36.888 | 14.300 | 1.00 | 27.33 | A |
| ATOM | 429 | CD2 | LEU | 49 | 21.710 | 38.059 | 15.560 | 1.00 | 24.21 | A |
| ATOM | 430 | C | LEU | 49 | 20.963 | 35.612 | 18.948 | 1.00 | 31.23 | A |
| ATOM | 431 | O | LEU | 49 | 20.627 | 36.523 | 19.707 | 1.00 | 32.53 | A |
| ATOM | 432 | N | GLY | 50 | 20.804 | 34.321 | 19.228 | 1.00 | 33.10 | A |
| ATOM | 433 | H | GLY | 50 | 21.185 | 33.687 | 18.612 | 0.00 | 0.00 | A |
| ATOM | 434 | CA | GLY | 50 | 20.166 | 33.867 | 20.450 | 1.00 | 33.56 | A |
| ATOM | 435 | C | GLY | 50 | 20.964 | 34.323 | 21.654 | 1.00 | 36.09 | A |
| ATOM | 436 | O | GLY | 50 | 20.408 | 34.845 | 22.621 | 1.00 | 39.16 | A |
| ATOM | 437 | N | ALA | 51 | 22.280 | 34.163 | 21.591 | 1.00 | 35.37 | A |
| ATOM | 438 | H | ALA | 51 | 22.677 | 33.714 | 20.814 | 0.00 | 0.00 | A |
| ATOM | 439 | CA | ALA | 51 | 23.128 | 34.591 | 22.687 | 1.00 | 35.30 | A |
| ATOM | 440 | CB | ALA | 51 | 24.550 | 34.206 | 22.411 | 1.00 | 35.41 | A |
| ATOM | 441 | C | ALA | 51 | 23.003 | 36.105 | 22.857 | 1.00 | 35.83 | A |
| ATOM | 442 | O | ALA | 51 | 22.910 | 36.623 | 23.965 | 1.00 | 37.53 | A |
| ATOM | 443 | N | ALA | 52 | 22.943 | 36.813 | 21.744 | 1.00 | 35.15 | A |
| ATOM | 444 | H | ALA | 52 | 23.002 | 36.346 | 20.881 | 0.00 | 0.00 | A |
| ATOM | 445 | CA | ALA | 52 | 22.823 | 38.258 | 21.778 | 1.00 | 35.40 | A |
| ATOM | 446 | CB | ALA | 52 | 23.097 | 38.819 | 20.405 | 1.00 | 39.66 | A |
| ATOM | 447 | C | ALA | 52 | 21.454 | 38.703 | 22.246 | 1.00 | 33.57 | A |
| ATOM | 448 | O | ALA | 52 | 21.247 | 39.868 | 22.562 | 1.00 | 34.43 | A |
| ATOM | 449 | N | ALA | 53 | 20.517 | 37.771 | 22.269 | 1.00 | 33.47 | A |
| ATOM | 450 | H | ALA | 53 | 20.737 | 36.859 | 21.981 | 0.00 | 0.00 | A |
| ATOM | 451 | CA | ALA | 53 | 19.148 | 38.053 | 22.676 | 1.00 | 33.19 | A |
| ATOM | 452 | CB | ALA | 53 | 19.121 | 38.768 | 24.012 | 1.00 | 32.74 | A |
| ATOM | 453 | C | ALA | 53 | 18.489 | 38.906 | 21.628 | 1.00 | 32.79 | A |
| ATOM | 454 | O | ALA | 53 | 17.690 | 39.764 | 21.953 | 1.00 | 33.08 | A |
| ATOM | 455 | N | LEU | 54 | 18.870 | 38.711 | 20.373 | 1.00 | 34.72 | A |
| ATOM | 456 | H | LEU | 54 | 19.548 | 38.036 | 20.172 | 0.00 | 0.00 | A |
| ATOM | 457 | CA | LEU | 54 | 18.285 | 39.481 | 19.283 | 1.00 | 36.61 | A |
| ATOM | 458 | CB | LEU | 54 | 19.375 | 39.972 | 18.323 | 1.00 | 35.12 | A |
| ATOM | 459 | CG | LEU | 54 | 20.607 | 40.626 | 18.961 | 1.00 | 34.22 | A |
| ATOM | 460 | CD1 | LEU | 54 | 21.617 | 40.973 | 17.885 | 1.00 | 33.59 | A |
| ATOM | 461 | CD2 | LEU | 54 | 20.234 | 41.855 | 19.745 | 1.00 | 34.10 | A |
| ATOM | 462 | C | LEU | 54 | 17.220 | 38.678 | 18.524 | 1.00 | 38.57 | A |
| ATOM | 463 | O | LEU | 54 | 16.732 | 39.119 | 17.481 | 1.00 | 38.85 | A |
| ATOM | 464 | N | GLY | 55 | 16.855 | 37.510 | 19.054 | 1.00 | 41.26 | A |
| ATOM | 465 | H | GLY | 55 | 17.254 | 37.185 | 19.883 | 0.00 | 0.00 | A |
| ATOM | 466 | CA | GLY | 55 | 15.841 | 36.682 | 18.417 | 1.00 | 44.13 | A |
| ATOM | 467 | C | GLY | 55 | 16.415 | 35.651 | 17.467 | 1.00 | 46.32 | A |
| ATOM | 468 | O | GLY | 55 | 17.186 | 34.783 | 17.890 | 1.00 | 46.61 | A |
| ATOM | 469 | N | ASP | 56 | 16.045 | 35.738 | 16.190 | 1.00 | 48.25 | A |
| ATOM | 470 | H | ASP | 56 | 15.427 | 36.433 | 15.884 | 0.00 | 0.00 | A |
| ATOM | 471 | CA | ASP | 56 | 16.537 | 34.804 | 15.183 | 1.00 | 48.69 | A |
| ATOM | 472 | CB | ASP | 56 | 15.656 | 33.537 | 15.126 | 1.00 | 51.39 | A |
| ATOM | 473 | CG | ASP | 56 | 14.300 | 33.760 | 14.438 | 1.00 | 53.95 | A |
| ATOM | 474 | OD1 | ASP | 56 | 13.916 | 34.916 | 14.159 | 1.00 | 55.33 | A |
| ATOM | 475 | OD2 | ASP | 56 | 13.603 | 32.754 | 14.175 | 1.00 | 55.00 | A |
| ATOM | 476 | C | ASP | 56 | 16.695 | 35.430 | 13.796 | 1.00 | 48.46 | A |
| ATOM | 477 | O | ASP | 56 | 16.286 | 36.563 | 13.552 | 1.00 | 48.08 | A |
| ATOM | 478 | N | ILE | 57 | 17.301 | 34.671 | 12.894 | 1.00 | 50.37 | A |
| ATOM | 479 | H | ILE | 57 | 17.550 | 33.774 | 13.194 | 0.00 | 0.00 | A |
| ATOM | 480 | CA | ILE | 57 | 17.557 | 35.085 | 11.522 | 1.00 | 51.04 | A |
| ATOM | 481 | CB | ILE | 57 | 18.259 | 33.936 | 10.744 | 1.00 | 48.89 | A |
| ATOM | 482 | CG2 | ILE | 57 | 17.370 | 32.710 | 10.675 | 1.00 | 50.23 | A |
| ATOM | 483 | CG1 | ILE | 57 | 18.596 | 34.352 | 9.325 | 1.00 | 49.19 | A |
| ATOM | 484 | CD1 | ILE | 57 | 19.106 | 33.192 | 8.488 | 1.00 | 50.37 | A |
| ATOM | 485 | C | ILE | 57 | 16.246 | 35.454 | 10.845 | 1.00 | 53.96 | A |
| ATOM | 486 | O | ILE | 57 | 16.213 | 36.325 | 9.991 | 1.00 | 53.58 | A |
| ATOM | 487 | N | GLY | 58 | 15.160 | 34.834 | 11.286 | 1.00 | 58.46 | A |
| ATOM | 488 | H | GLY | 58 | 15.209 | 34.195 | 12.036 | 0.00 | 0.00 | A |
| ATOM | 489 | CA | GLY | 58 | 13.861 | 35.097 | 10.703 | 1.00 | 65.93 | A |
| ATOM | 490 | C | GLY | 58 | 13.279 | 36.460 | 11.011 | 1.00 | 71.39 | A |
| ATOM | 491 | O | GLY | 58 | 12.573 | 37.030 | 10.182 | 1.00 | 73.60 | A |
| ATOM | 492 | N | LYS | 59 | 13.524 | 36.980 | 12.205 | 1.00 | 76.35 | A |
| ATOM | 493 | H | LYS | 59 | 14.023 | 36.454 | 12.872 | 0.00 | 0.00 | A |
| ATOM | 494 | CA | LYS | 59 | 13.005 | 38.303 | 12.548 | 1.00 | 82.67 | A |
| ATOM | 495 | CB | LYS | 59 | 13.109 | 38.576 | 14.072 | 1.00 | 85.68 | A |
| ATOM | 496 | CG | LYS | 59 | 12.192 | 39.710 | 14.642 | 1.00 | 88.86 | A |
| ATOM | 497 | CD | LYS | 59 | 10.700 | 39.273 | 14.734 | 1.00 | 91.34 | A |
| ATOM | 498 | CE | LYS | 59 | 9.745 | 40.338 | 15.347 | 1.00 | 90.66 | A |
| ATOM | 499 | NZ | LYS | 59 | 8.328 | 39.844 | 15.576 | 1.00 | 85.90 | A |
| ATOM | 500 | HZ1 | LYS | 59 | 7.726 | 40.621 | 15.916 | 0.00 | 0.00 | A |
| ATOM | 501 | HZ2 | LYS | 59 | 8.332 | 39.081 | 16.284 | 0.00 | 0.00 | A |
| ATOM | 502 | HZ3 | LYS | 59 | 7.923 | 39.476 | 14.690 | 0.00 | 0.00 | A |
| ATOM | 503 | C | LYS | 59 | 13.824 | 39.344 | 11.772 | 1.00 | 84.14 | A |
| ATOM | 504 | O | LYS | 59 | 13.316 | 40.418 | 11.440 | 1.00 | 87.87 | A |
| ATOM | 505 | N | LEU | 60 | 15.067 | 39.001 | 11.437 | 1.00 | 82.86 | A |
| ATOM | 506 | H | LEU | 60 | 15.392 | 38.114 | 11.695 | 0.00 | 0.00 | A |
| ATOM | 507 | CA | LEU | 60 | 15.955 | 39.926 | 10.734 | 1.00 | 82.21 | A |
| ATOM | 508 | CB | LEU | 60 | 17.358 | 39.848 | 11.333 | 1.00 | 80.33 | A |
| ATOM | 509 | CG | LEU | 60 | 17.621 | 40.566 | 12.654 | 1.00 | 79.26 | A |
| ATOM | 510 | CD1 | LEU | 60 | 16.708 | 40.055 | 13.758 | 1.00 | 79.53 | A |
| ATOM | 511 | CD2 | LEU | 60 | 19.076 | 40.364 | 13.020 | 1.00 | 78.64 | A |
| ATOM | 512 | C | LEU | 60 | 16.068 | 39.880 | 9.204 | 1.00 | 82.49 | A |
| ATOM | 513 | O | LEU | 60 | 16.277 | 40.924 | 8.568 | 1.00 | 83.08 | A |
| ATOM | 514 | N | PHE | 61 | 15.969 | 38.694 | 8.608 | 1.00 | 81.98 | A |
| ATOM | 515 | H | PHE | 61 | 15.774 | 37.895 | 9.131 | 0.00 | 0.00 | A |
| ATOM | 516 | CA | PHE | 61 | 16.120 | 38.571 | 7.156 | 1.00 | 81.94 | A |
| ATOM | 517 | CB | PHE | 61 | 17.546 | 38.105 | 6.829 | 1.00 | 79.88 | A |
| ATOM | 518 | CG | PHE | 61 | 18.601 | 38.708 | 7.721 | 1.00 | 78.93 | A |
| ATOM | 519 | CD1 | PHE | 61 | 18.888 | 40.068 | 7.666 | 1.00 | 79.31 | A |
| ATOM | 520 | CD2 | PHE | 61 | 19.273 | 37.921 | 8.654 | 1.00 | 78.93 | A |
| ATOM | 521 | CE1 | PHE | 61 | 19.823 | 40.632 | 8.535 | 1.00 | 80.26 | A |
| ATOM | 522 | CE2 | PHE | 61 | 20.212 | 38.475 | 9.528 | 1.00 | 77.92 | A |
| ATOM | 523 | CZ | PHE | 61 | 20.487 | 39.829 | 9.471 | 1.00 | 78.35 | A |
| ATOM | 524 | C | PHE | 61 | 15.090 | 37.634 | 6.508 | 1.00 | 83.30 | A |
| ATOM | 525 | O | PHE | 61 | 15.436 | 36.552 | 6.026 | 1.00 | 84.15 | A |
| ATOM | 526 | N | PRO | 62 | 13.821 | 38.082 | 6.429 | 1.00 | 84.34 | A |
| ATOM | 527 | CD | PRO | 62 | 13.474 | 39.413 | 6.965 | 1.00 | 83.44 | A |
| ATOM | 528 | CA | PRO | 62 | 12.618 | 37.436 | 5.878 | 1.00 | 85.96 | A |
| ATOM | 529 | CB | PRO | 62 | 11.662 | 38.611 | 5.723 | 1.00 | 84.33 | A |
| ATOM | 530 | CG | PRO | 62 | 11.963 | 39.404 | 6.937 | 1.00 | 84.12 | A |
| ATOM | 531 | C | PRO | 62 | 12.673 | 36.607 | 4.587 | 1.00 | 87.87 | A |
| ATOM | 532 | O | PRO | 62 | 13.316 | 36.981 | 3.603 | 1.00 | 87.54 | A |
| ATOM | 533 | N | ASP | 63 | 11.935 | 35.498 | 4.596 | 1.00 | 90.63 | A |
| ATOM | 534 | H | ASP | 63 | 11.479 | 35.210 | 5.421 | 0.00 | 0.00 | A |
| ATOM | 535 | CA | ASP | 63 | 11.832 | 34.611 | 3.442 | 1.00 | 93.59 | A |
| ATOM | 536 | CB | ASP | 63 | 10.951 | 33.392 | 3.749 | 1.00 | 94.11 | A |
| ATOM | 537 | CG | ASP | 63 | 11.301 | 32.722 | 5.057 | 1.00 | 94.98 | A |
| ATOM | 538 | OD1 | ASP | 63 | 10.844 | 33.220 | 6.107 | 1.00 | 95.77 | A |
| ATOM | 539 | OD2 | ASP | 63 | 12.014 | 31.696 | 5.036 | 1.00 | 95.99 | A |
| ATOM | 540 | C | ASP | 63 | 11.126 | 35.420 | 2.370 | 1.00 | 95.99 | A |
| ATOM | 541 | O | ASP | 63 | 11.470 | 35.350 | 1.189 | 1.00 | 97.75 | A |
| ATOM | 542 | N | THR | 64 | 10.124 | 36.180 | 2.805 | 1.00 | 97.86 | A |
| ATOM | 543 | H | THR | 64 | 9.918 | 36.165 | 3.760 | 0.00 | 0.00 | A |
| ATOM | 544 | CA | THR | 64 | 9.312 | 37.025 | 1.928 | 1.00 | 99.80 | A |
| ATOM | 545 | CB | THR | 64 | 8.170 | 37.697 | 2.715 | 1.00 | 100.00 | A |
| ATOM | 546 | OG1 | THR | 64 | 8.714 | 38.419 | 3.834 | 1.00 | 100.00 | A |
| ATOM | 547 | HG1 | THR | 64 | 7.996 | 38.903 | 4.261 | 0.00 | 0.00 | A |
| ATOM | 548 | CG2 | THR | 64 | 7.178 | 36.643 | 3.213 | 1.00 | 100.00 | A |
| ATOM | 549 | C | THR | 64 | 10.086 | 38.116 | 1.184 | 1.00 | 100.00 | A |
| ATOM | 550 | O | THR | 64 | 9.882 | 38.308 | −0.024 | 1.00 | 100.00 | A |
| ATOM | 551 | N | ASP | 65 | 10.929 | 38.856 | 1.908 | 1.00 | 100.00 | A |
| ATOM | 552 | H | ASP | 65 | 11.033 | 38.684 | 2.862 | 0.00 | 0.00 | A |
| ATOM | 553 | CA | ASP | 65 | 11.714 | 39.917 | 1.290 | 1.00 | 100.00 | A |
| ATOM | 554 | CB | ASP | 65 | 12.570 | 40.663 | 2.316 | 1.00 | 99.58 | A |
| ATOM | 555 | CG | ASP | 65 | 13.199 | 41.931 | 1.743 | 1.00 | 100.00 | A |
| ATOM | 556 | OD1 | ASP | 65 | 13.838 | 41.861 | 0.667 | 1.00 | 100.00 | A |
| ATOM | 557 | OD2 | ASP | 65 | 13.047 | 43.005 | 2.362 | 1.00 | 100.00 | A |
| ATOM | 558 | C | ASP | 65 | 12.586 | 39.294 | 0.207 | 1.00 | 100.00 | A |
| ATOM | 559 | O | ASP | 65 | 13.502 | 38.505 | 0.488 | 1.00 | 99.16 | A |
| ATOM | 560 | N | PRO | 66 | 12.290 | 39.631 | −1.058 | 1.00 | 100.00 | A |
| ATOM | 561 | CD | PRO | 66 | 11.279 | 40.653 | −1.384 | 1.00 | 100.00 | A |
| ATOM | 562 | CA | PRO | 66 | 12.963 | 39.170 | −2.276 | 1.00 | 100.00 | A |
| ATOM | 563 | CB | PRO | 66 | 12.237 | 39.949 | −3.373 | 1.00 | 100.00 | A |
| ATOM | 564 | CG | PRO | 66 | 11.809 | 41.212 | −2.667 | 1.00 | 100.00 | A |
| ATOM | 565 | C | PRO | 66 | 14.475 | 39.398 | −2.325 | 1.00 | 100.00 | A |
| ATOM | 566 | O | PRO | 66 | 15.199 | 38.624 | −2.962 | 1.00 | 100.00 | A |
| ATOM | 567 | N | ALA | 67 | 14.955 | 40.443 | −1.655 | 1.00 | 99.00 | A |
| ATOM | 568 | H | ALA | 67 | 14.353 | 41.027 | −1.132 | 0.00 | 0.00 | A |
| ATOM | 569 | CA | ALA | 67 | 16.386 | 40.739 | −1.639 | 1.00 | 98.20 | A |
| ATOM | 570 | CB | ALA | 67 | 16.646 | 42.021 | −0.853 | 1.00 | 99.56 | A |
| ATOM | 571 | C | ALA | 67 | 17.176 | 39.571 | −1.034 | 1.00 | 96.59 | A |
| ATOM | 572 | O | ALA | 67 | 18.321 | 39.299 | −1.410 | 1.00 | 95.75 | A |
| ATOM | 573 | N | PHE | 68 | 16.529 | 38.856 | −0.124 | 1.00 | 94.54 | A |
| ATOM | 574 | H | PHE | 68 | 15.613 | 39.118 | 0.122 | 0.00 | 0.00 | A |
| ATOM | 575 | CA | PHE | 68 | 17.150 | 37.728 | 0.539 | 1.00 | 92.56 | A |
| ATOM | 576 | CB | PHE | 68 | 16.497 | 37.527 | 1.904 | 1.00 | 93.21 | A |
| ATOM | 577 | CG | PHE | 68 | 16.397 | 38.794 | 2.709 | 1.00 | 93.98 | A |
| ATOM | 578 | CD1 | PHE | 68 | 15.301 | 39.035 | 3.525 | 1.00 | 94.45 | A |
| ATOM | 579 | CD2 | PHE | 68 | 17.402 | 39.759 | 2.641 | 1.00 | 94.64 | A |
| ATOM | 580 | CE1 | PHE | 68 | 15.206 | 40.218 | 4.265 | 1.00 | 94.66 | A |
| ATOM | 581 | CE2 | PHE | 68 | 17.315 | 40.945 | 3.378 | 1.00 | 94.74 | A |
| ATOM | 582 | CZ | PHE | 68 | 16.214 | 41.173 | 4.191 | 1.00 | 94.36 | A |
| ATOM | 583 | C | PHE | 68 | 17.068 | 36.468 | −0.309 | 1.00 | 91.02 | A |
| ATOM | 584 | O | PHE | 68 | 17.317 | 35.365 | 0.179 | 1.00 | 89.78 | A |
| ATOM | 585 | N | LYS | 69 | 16.703 | 36.631 | −1.577 | 1.00 | 90.57 | A |
| ATOM | 586 | H | LYS | 69 | 16.563 | 37.521 | −1.960 | 0.00 | 0.00 | A |
| ATOM | 587 | CA | LYS | 69 | 16.603 | 35.505 | −2.494 | 1.00 | 91.37 | A |
| ATOM | 588 | CB | LYS | 69 | 15.688 | 35.842 | −3.666 | 1.00 | 92.63 | A |
| ATOM | 589 | CG | LYS | 69 | 15.421 | 34.659 | −4.576 | 1.00 | 96.69 | A |
| ATOM | 590 | CD | LYS | 69 | 14.780 | 35.094 | −5.888 | 1.00 | 100.00 | A |
| ATOM | 591 | CE | LYS | 69 | 14.689 | 33.930 | −6.877 | 1.00 | 100.00 | A |
| ATOM | 592 | NZ | LYS | 69 | 14.189 | 34.361 | −8.219 | 1.00 | 100.00 | A |
| ATOM | 593 | HZ1 | LYS | 69 | 14.148 | 33.533 | −8.849 | 0.00 | 0.00 | A |
| ATOM | 594 | HZ2 | LYS | 69 | 14.833 | 35.072 | −8.618 | 0.00 | 0.00 | A |
| ATOM | 595 | HZ3 | LYS | 69 | 13.236 | 34.764 | −8.118 | 0.00 | 0.00 | A |
| ATOM | 596 | C | LYS | 69 | 18.006 | 35.163 | −3.000 | 1.00 | 91.17 | A |
| ATOM | 597 | O | LYS | 69 | 18.775 | 36.062 | −3.350 | 1.00 | 92.34 | A |
| ATOM | 598 | N | GLY | 70 | 18.335 | 33.867 | −3.016 | 1.00 | 89.22 | A |
| ATOM | 599 | H | GLY | 70 | 17.689 | 33.181 | −2.806 | 0.00 | 0.00 | A |
| ATOM | 600 | CA | GLY | 70 | 19.649 | 33.401 | −3.437 | 1.00 | 85.18 | A |
| ATOM | 601 | C | GLY | 70 | 20.750 | 33.991 | −2.569 | 1.00 | 82.41 | A |
| ATOM | 602 | O | GLY | 70 | 21.943 | 33.751 | −2.799 | 1.00 | 81.68 | A |
| ATOM | 603 | N | ALA | 71 | 20.327 | 34.696 | −1.519 | 1.00 | 80.11 | A |
| ATOM | 604 | H | ALA | 71 | 19.380 | 34.743 | −1.311 | 0.00 | 0.00 | A |
| ATOM | 605 | CA | ALA | 71 | 21.220 | 35.386 | −0.597 | 1.00 | 77.36 | A |
| ATOM | 606 | CB | ALA | 71 | 20.413 | 36.093 | 0.505 | 1.00 | 76.77 | A |
| ATOM | 607 | C | ALA | 71 | 22.343 | 34.556 | 0.012 | 1.00 | 74.26 | A |
| ATOM | 608 | O | ALA | 71 | 22.130 | 33.465 | 0.552 | 1.00 | 75.56 | A |
| ATOM | 609 | N | ASP | 72 | 23.545 | 35.103 | −0.101 | 1.00 | 68.61 | A |
| ATOM | 610 | H | ASP | 72 | 23.646 | 35.966 | −0.547 | 0.00 | 0.00 | A |
| ATOM | 611 | CA | ASP | 72 | 24.740 | 34.499 | 0.433 | 1.00 | 63.13 | A |
| ATOM | 612 | CB | ASP | 72 | 25.927 | 35.348 | −0.023 | 1.00 | 64.22 | A |
| ATOM | 613 | CG | ASP | 72 | 27.233 | 34.917 | 0.590 | 1.00 | 67.88 | A |
| ATOM | 614 | OD1 | ASP | 72 | 27.396 | 35.062 | 1.820 | 1.00 | 72.46 | A |
| ATOM | 615 | OD2 | ASP | 72 | 28.121 | 34.463 | −0.158 | 1.00 | 68.97 | A |
| ATOM | 616 | C | ASP | 72 | 24.568 | 34.520 | 1.962 | 1.00 | 59.50 | A |
| ATOM | 617 | O | ASP | 72 | 24.640 | 35.577 | 2.594 | 1.00 | 60.40 | A |
| ATOM | 618 | N | SER | 73 | 24.282 | 33.367 | 2.556 | 1.00 | 54.03 | A |
| ATOM | 619 | H | SER | 73 | 24.197 | 32.548 | 2.012 | 0.00 | 0.00 | A |
| ATOM | 620 | CA | SER | 73 | 24.089 | 33.303 | 3.997 | 1.00 | 48.00 | A |
| ATOM | 621 | CB | SER | 73 | 23.843 | 31.873 | 4.452 | 1.00 | 47.13 | A |
| ATOM | 622 | OG | SER | 73 | 22.514 | 31.485 | 4.180 | 1.00 | 46.04 | A |
| ATOM | 623 | HG | SER | 73 | 22.769 | 30.715 | 3.649 | 0.00 | 0.00 | A |
| ATOM | 624 | C | SER | 73 | 25.222 | 33.901 | 4.811 | 1.00 | 44.99 | A |
| ATOM | 625 | O | SER | 73 | 24.999 | 34.342 | 5.942 | 1.00 | 44.54 | A |
| ATOM | 626 | N | ARG | 74 | 26.432 | 33.911 | 4.259 | 1.00 | 40.57 | A |
| ATOM | 627 | H | ARG | 74 | 26.566 | 33.589 | 3.338 | 0.00 | 0.00 | A |
| ATOM | 628 | CA | ARG | 74 | 27.550 | 34.473 | 4.989 | 1.00 | 39.47 | A |
| ATOM | 629 | CB | ARG | 74 | 28.850 | 34.320 | 4.250 | 1.00 | 37.75 | A |
| ATOM | 630 | CG | ARG | 74 | 29.246 | 32.927 | 4.015 | 1.00 | 38.53 | A |
| ATOM | 631 | CD | ARG | 74 | 30.555 | 32.933 | 3.291 | 1.00 | 42.12 | A |
| ATOM | 632 | NE | ARG | 74 | 31.597 | 33.551 | 4.102 | 1.00 | 42.22 | A |
| ATOM | 633 | HE | ARG | 74 | 31.325 | 33.928 | 4.970 | 0.00 | 0.00 | A |
| ATOM | 634 | CZ | ARG | 74 | 32.873 | 33.619 | 3.748 | 1.00 | 43.91 | A |
| ATOM | 635 | NH1 | ARG | 74 | 33.749 | 34.192 | 4.561 | 1.00 | 48.23 | A |
| ATOM | 636 | HH11 | ARG | 74 | 33.426 | 34.551 | 5.452 | 0.00 | 0.00 | A |
| ATOM | 637 | HH12 | ARG | 74 | 34.742 | 34.310 | 4.413 | 0.00 | 0.00 | A |
| ATOM | 638 | NH2 | ARG | 74 | 33.271 | 33.120 | 2.580 | 1.00 | 43.15 | A |
| ATOM | 639 | HH21 | ARG | 74 | 32.611 | 32.684 | 1.960 | 0.00 | 0.00 | A |
| ATOM | 640 | HH22 | ARG | 74 | 34.236 | 33.153 | 2.303 | 0.00 | 0.00 | A |
| ATOM | 641 | C | ARG | 74 | 27.293 | 35.934 | 5.190 | 1.00 | 40.66 | A |
| ATOM | 642 | O | ARG | 74 | 27.756 | 36.511 | 6.165 | 1.00 | 42.69 | A |
| ATOM | 643 | N | GLU | 75 | 26.594 | 36.558 | 4.251 | 1.00 | 40.66 | A |
| ATOM | 644 | H | GLU | 75 | 26.323 | 36.086 | 3.428 | 0.00 | 0.00 | A |
| ATOM | 645 | CA | GLU | 75 | 26.287 | 37.966 | 4.418 | 1.00 | 43.69 | A |
| ATOM | 646 | CB | GLU | 75 | 25.596 | 38.541 | 3.193 | 1.00 | 48.70 | A |
| ATOM | 647 | CG | GLU | 75 | 26.382 | 38.299 | 1.930 | 1.00 | 60.49 | A |
| ATOM | 648 | CD | GLU | 75 | 26.342 | 39.469 | 0.973 | 1.00 | 67.19 | A |
| ATOM | 649 | OE1 | GLU | 75 | 27.341 | 40.237 | 0.967 | 1.00 | 73.04 | A |
| ATOM | 650 | OE2 | GLU | 75 | 25.332 | 39.610 | 0.235 | 1.00 | 68.85 | A |
| ATOM | 651 | C | GLU | 75 | 25.381 | 38.054 | 5.624 | 1.00 | 41.95 | A |
| ATOM | 652 | O | GLU | 75 | 25.731 | 38.676 | 6.626 | 1.00 | 42.62 | A |
| ATOM | 653 | N | LEU | 76 | 24.270 | 37.334 | 5.575 | 1.00 | 39.44 | A |
| ATOM | 654 | H | LEU | 76 | 24.102 | 36.788 | 4.776 | 0.00 | 0.00 | A |
| ATOM | 655 | CA | LEU | 76 | 23.341 | 37.350 | 6.687 | 1.00 | 38.36 | A |
| ATOM | 656 | CB | LEU | 76 | 22.278 | 36.267 | 6.524 | 1.00 | 42.91 | A |
| ATOM | 657 | CG | LEU | 76 | 21.344 | 36.488 | 5.334 | 1.00 | 44.80 | A |
| ATOM | 658 | CD1 | LEU | 76 | 20.286 | 35.397 | 5.230 | 1.00 | 47.42 | A |
| ATOM | 659 | CD2 | LEU | 76 | 20.686 | 37.824 | 5.516 | 1.00 | 46.89 | A |
| ATOM | 660 | C | LEU | 76 | 24.100 | 37.151 | 7.978 | 1.00 | 35.33 | A |
| ATOM | 661 | O | LEU | 76 | 23.910 | 37.900 | 8.922 | 1.00 | 36.74 | A |
| ATOM | 662 | N | LEU | 77 | 25.033 | 36.209 | 7.980 | 1.00 | 32.26 | A |
| ATOM | 663 | H | LEU | 77 | 25.204 | 35.702 | 7.167 | 0.00 | 0.00 | A |
| ATOM | 664 | CA | LEU | 77 | 25.814 | 35.934 | 9.175 | 1.00 | 32.74 | A |
| ATOM | 665 | CB | LEU | 77 | 26.788 | 34.785 | 8.935 | 1.00 | 30.27 | A |
| ATOM | 666 | CG | LEU | 77 | 27.811 | 34.555 | 10.048 | 1.00 | 25.16 | A |
| ATOM | 667 | CD1 | LEU | 77 | 27.089 | 34.175 | 11.322 | 1.00 | 25.07 | A |
| ATOM | 668 | CD2 | LEU | 77 | 28.789 | 33.475 | 9.638 | 1.00 | 23.86 | A |
| ATOM | 669 | C | LEU | 77 | 26.598 | 37.145 | 9.635 | 1.00 | 34.45 | A |
| ATOM | 670 | O | LEU | 77 | 26.495 | 37.559 | 10.791 | 1.00 | 34.03 | A |
| ATOM | 671 | N | ARG | 78 | 27.385 | 37.703 | 8.722 | 1.00 | 36.15 | A |
| ATOM | 672 | H | ARG | 78 | 27.400 | 37.329 | 7.819 | 0.00 | 0.00 | A |
| ATOM | 673 | CA | ARG | 78 | 28.222 | 38.857 | 9.022 | 1.00 | 39.09 | A |
| ATOM | 674 | CB | ARG | 78 | 29.013 | 39.291 | 7.780 | 1.00 | 40.57 | A |
| ATOM | 675 | CG | ARG | 78 | 29.996 | 38.253 | 7.241 | 1.00 | 44.47 | A |
| ATOM | 676 | CD | ARG | 78 | 30.703 | 38.746 | 5.979 | 1.00 | 48.34 | A |
| ATOM | 677 | NE | ARG | 78 | 30.627 | 37.787 | 4.875 | 1.00 | 55.63 | A |
| ATOM | 678 | HE | ARG | 78 | 31.081 | 36.930 | 5.097 | 0.00 | 0.00 | A |
| ATOM | 679 | CZ | ARG | 78 | 29.982 | 38.012 | 3.726 | 1.00 | 59.12 | A |
| ATOM | 680 | NH1 | ARG | 78 | 29.963 | 37.083 | 2.772 | 1.00 | 59.24 | A |
| ATOM | 681 | HH11 | ARG | 78 | 30.389 | 36.187 | 2.898 | 0.00 | 0.00 | A |
| ATOM | 682 | HH12 | ARG | 78 | 29.441 | 37.202 | 1.912 | 0.00 | 0.00 | A |
| ATOM | 683 | NH2 | ARG | 78 | 29.346 | 39.167 | 3.527 | 1.00 | 62.68 | A |
| ATOM | 684 | HH21 | ARG | 78 | 29.329 | 39.877 | 4.231 | 0.00 | 0.00 | A |
| ATOM | 685 | HH22 | ARG | 78 | 28.815 | 39.364 | 2.677 | 0.00 | 0.00 | A |
| ATOM | 686 | C | ARG | 78 | 27.415 | 40.026 | 9.574 | 1.00 | 40.22 | A |
| ATOM | 687 | O | ARG | 78 | 27.884 | 40.739 | 10.464 | 1.00 | 41.23 | A |
| ATOM | 688 | N | GLU | 79 | 26.200 | 40.208 | 9.057 | 1.00 | 40.87 | A |
| ATOM | 689 | H | GLU | 79 | 25.883 | 39.601 | 8.355 | 0.00 | 0.00 | A |
| ATOM | 690 | CA | GLU | 79 | 25.322 | 41.286 | 9.505 | 1.00 | 41.35 | A |
| ATOM | 691 | CB | GLU | 79 | 24.148 | 41.471 | 8.541 | 1.00 | 41.31 | A |
| ATOM | 692 | CG | GLU | 79 | 23.137 | 42.543 | 8.959 | 1.00 | 46.26 | A |
| ATOM | 693 | CD | GLU | 79 | 23.647 | 43.992 | 8.847 | 1.00 | 52.53 | A |
| ATOM | 694 | OE1 | GLU | 79 | 24.859 | 44.234 | 8.621 | 1.00 | 56.78 | A |
| ATOM | 695 | OE2 | GLU | 79 | 22.813 | 44.914 | 8.993 | 1.00 | 54.04 | A |
| ATOM | 696 | C | GLU | 79 | 24.806 | 40.978 | 10.903 | 1.00 | 41.50 | A |
| ATOM | 697 | O | GLU | 79 | 24.934 | 41.794 | 11.826 | 1.00 | 43.56 | A |
| ATOM | 698 | N | ALA | 80 | 24.231 | 39.795 | 11.067 | 1.00 | 40.34 | A |
| ATOM | 699 | H | ALA | 80 | 24.154 | 39.193 | 10.300 | 0.00 | 0.00 | A |
| ATOM | 700 | CA | ALA | 80 | 23.722 | 39.401 | 12.361 | 1.00 | 38.50 | A |
| ATOM | 701 | CB | ALA | 80 | 23.218 | 37.997 | 12.314 | 1.00 | 38.29 | A |
| ATOM | 702 | C | ALA | 80 | 24.888 | 39.525 | 13.327 | 1.00 | 38.93 | A |
| ATOM | 703 | O | ALA | 80 | 24.712 | 39.951 | 14.462 | 1.00 | 39.92 | A |
| ATOM | 704 | N | TRP | 81 | 26.095 | 39.248 | 12.845 | 1.00 | 38.89 | A |
| ATOM | 705 | H | TRP | 81 | 26.189 | 38.979 | 11.916 | 0.00 | 0.00 | A |
| ATOM | 706 | CA | TRP | 81 | 27.270 | 39.362 | 13.696 | 1.00 | 40.90 | A |
| ATOM | 707 | CB | TRP | 81 | 28.503 | 38.741 | 13.050 | 1.00 | 35.57 | A |
| ATOM | 708 | CG | TRP | 81 | 29.729 | 38.853 | 13.914 | 1.00 | 30.15 | A |
| ATOM | 709 | CD2 | TRP | 81 | 29.848 | 38.483 | 15.294 | 1.00 | 25.94 | A |
| ATOM | 710 | CE2 | TRP | 81 | 31.170 | 38.782 | 15.695 | 1.00 | 24.78 | A |
| ATOM | 711 | CE3 | TRP | 81 | 28.971 | 37.925 | 16.226 | 1.00 | 26.30 | A |
| ATOM | 712 | CD1 | TRP | 81 | 30.945 | 39.344 | 13.546 | 1.00 | 30.72 | A |
| ATOM | 713 | NE1 | TRP | 81 | 31.819 | 39.304 | 14.610 | 1.00 | 28.04 | A |
| ATOM | 714 | HE1 | TRP | 81 | 32.775 | 39.549 | 14.586 | 0.00 | 0.00 | A |
| ATOM | 715 | CZ2 | TRP | 81 | 31.635 | 38.546 | 16.986 | 1.00 | 23.98 | A |
| ATOM | 716 | CZ3 | TRP | 81 | 29.434 | 37.685 | 17.512 | 1.00 | 27.28 | A |
| ATOM | 717 | CH2 | TRP | 81 | 30.758 | 37.997 | 17.880 | 1.00 | 25.88 | A |
| ATOM | 718 | C | TRP | 81 | 27.554 | 40.820 | 14.015 | 1.00 | 45.31 | A |
| ATOM | 719 | O | TRP | 81 | 27.923 | 41.145 | 15.144 | 1.00 | 48.12 | A |
| ATOM | 720 | N | ARG | 82 | 27.397 | 41.694 | 13.021 | 1.00 | 48.82 | A |
| ATOM | 721 | H | ARG | 82 | 27.121 | 41.368 | 12.140 | 0.00 | 0.00 | A |
| ATOM | 722 | CA | ARG | 82 | 27.631 | 43.125 | 13.214 | 1.00 | 51.16 | A |
| ATOM | 723 | CB | ARG | 82 | 27.320 | 43.928 | 11.946 | 1.00 | 55.67 | A |
| ATOM | 724 | CG | ARG | 82 | 27.481 | 45.454 | 12.126 | 1.00 | 62.40 | A |
| ATOM | 725 | CD | ARG | 82 | 27.078 | 46.261 | 10.873 | 1.00 | 66.23 | A |
| ATOM | 726 | NE | ARG | 82 | 25.644 | 46.180 | 10.598 | 1.00 | 68.88 | A |
| ATOM | 727 | HE | ARG | 82 | 25.401 | 45.636 | 9.805 | 0.00 | 0.00 | A |
| ATOM | 728 | CZ | ARG | 82 | 24.705 | 46.773 | 11.330 | 1.00 | 70.59 | A |
| ATOM | 729 | NH1 | ARG | 82 | 23.428 | 46.628 | 11.008 | 1.00 | 70.90 | A |
| ATOM | 730 | HH11 | ARG | 82 | 23.243 | 46.088 | 10.178 | 0.00 | 0.00 | A |
| ATOM | 731 | HH12 | ARG | 82 | 22.658 | 47.037 | 11.489 | 0.00 | 0.00 | A |
| ATOM | 732 | NH2 | ARG | 82 | 25.044 | 47.539 | 12.366 | 1.00 | 73.55 | A |
| ATOM | 733 | HH21 | ARG | 82 | 26.015 | 47.670 | 12.584 | 0.00 | 0.00 | A |
| ATOM | 734 | HH22 | ARG | 82 | 24.375 | 48.011 | 12.943 | 0.00 | 0.00 | A |
| ATOM | 735 | C | ARG | 82 | 26.737 | 43.625 | 14.323 | 1.00 | 50.35 | A |
| ATOM | 736 | O | ARG | 82 | 27.219 | 44.083 | 15.361 | 1.00 | 50.43 | A |
| ATOM | 737 | N | ARG | 83 | 25.433 | 43.492 | 14.107 | 1.00 | 49.55 | A |
| ATOM | 738 | H | ARG | 83 | 25.156 | 43.044 | 13.279 | 0.00 | 0.00 | A |
| ATOM | 739 | CA | ARG | 83 | 24.444 | 43.932 | 15.074 | 1.00 | 51.28 | A |
| ATOM | 740 | CB | ARG | 83 | 23.047 | 43.550 | 14.597 | 1.00 | 54.08 | A |
| ATOM | 741 | CG | ARG | 83 | 22.798 | 44.048 | 13.195 | 1.00 | 60.67 | A |
| ATOM | 742 | CD | ARG | 83 | 21.381 | 43.846 | 12.733 | 1.00 | 67.28 | A |
| ATOM | 743 | NE | ARG | 83 | 21.274 | 44.146 | 11.305 | 1.00 | 74.78 | A |
| ATOM | 744 | HE | ARG | 83 | 22.116 | 44.336 | 10.824 | 0.00 | 0.00 | A |
| ATOM | 745 | CZ | ARG | 83 | 20.143 | 44.105 | 10.599 | 1.00 | 78.71 | A |
| ATOM | 746 | NH1 | ARG | 83 | 20.157 | 44.396 | 9.297 | 1.00 | 81.57 | A |
| ATOM | 747 | HH11 | ARG | 83 | 21.043 | 44.618 | 8.854 | 0.00 | 0.00 | A |
| ATOM | 748 | HH12 | ARG | 83 | 19.355 | 44.371 | 8.702 | 0.00 | 0.00 | A |
| ATOM | 749 | NH2 | ARG | 83 | 19.001 | 43.761 | 11.186 | 1.00 | 81.77 | A |
| ATOM | 750 | HH21 | ARG | 83 | 18.991 | 43.520 | 12.160 | 0.00 | 0.00 | A |
| ATOM | 751 | HH22 | ARG | 83 | 18.130 | 43.700 | 10.690 | 0.00 | 0.00 | A |
| ATOM | 752 | C | ARG | 83 | 24.745 | 43.374 | 16.460 | 1.00 | 50.32 | A |
| ATOM | 753 | O | ARG | 83 | 24.608 | 44.079 | 17.465 | 1.00 | 50.88 | A |
| ATOM | 754 | N | ILE | 84 | 25.234 | 42.141 | 16.507 | 1.00 | 48.38 | A |
| ATOM | 755 | H | ILE | 84 | 25.350 | 41.622 | 15.683 | 0.00 | 0.00 | A |
| ATOM | 756 | CA | ILE | 84 | 25.578 | 41.525 | 17.778 | 1.00 | 48.08 | A |
| ATOM | 757 | CB | ILE | 84 | 25.959 | 40.041 | 17.591 | 1.00 | 47.86 | A |
| ATOM | 758 | CG2 | ILE | 84 | 26.522 | 39.462 | 18.886 | 1.00 | 47.48 | A |
| ATOM | 759 | CG1 | ILE | 84 | 24.728 | 39.245 | 17.174 | 1.00 | 47.12 | A |
| ATOM | 760 | CD1 | ILE | 84 | 25.039 | 37.834 | 16.797 | 1.00 | 48.73 | A |
| ATOM | 761 | C | ILE | 84 | 26.727 | 42.282 | 18.451 | 1.00 | 47.05 | A |
| ATOM | 762 | O | ILE | 84 | 26.673 | 42.586 | 19.645 | 1.00 | 45.94 | A |
| ATOM | 763 | N | GLN | 85 | 27.751 | 42.611 | 17.676 | 1.00 | 46.98 | A |
| ATOM | 764 | H | GLN | 85 | 27.729 | 42.373 | 16.724 | 0.00 | 0.00 | A |
| ATOM | 765 | CA | GLN | 85 | 28.895 | 43.318 | 18.223 | 1.00 | 48.79 | A |
| ATOM | 766 | CB | GLN | 85 | 30.000 | 43.448 | 17.185 | 1.00 | 50.08 | A |
| ATOM | 767 | CG | GLN | 85 | 30.688 | 42.138 | 16.878 | 1.00 | 53.33 | A |
| ATOM | 768 | CD | GLN | 85 | 31.848 | 42.294 | 15.918 | 1.00 | 54.89 | A |
| ATOM | 769 | OE1 | GLN | 85 | 33.001 | 42.077 | 16.286 | 1.00 | 56.61 | A |
| ATOM | 770 | NE2 | GLN | 85 | 31.549 | 42.660 | 14.673 | 1.00 | 55.74 | A |
| ATOM | 771 | HE21 | GLN | 85 | 30.611 | 42.808 | 14.440 | 0.00 | 0.00 | A |
| ATOM | 772 | HE22 | GLN | 85 | 32.298 | 42.746 | 14.053 | 0.00 | 0.00 | A |
| ATOM | 773 | C | GLN | 85 | 28.482 | 44.681 | 18.717 | 1.00 | 49.22 | A |
| ATOM | 774 | O | GLN | 85 | 29.008 | 45.173 | 19.718 | 1.00 | 50.10 | A |
| ATOM | 775 | N | ALA | 86 | 27.522 | 45.278 | 18.019 | 1.00 | 48.34 | A |
| ATOM | 776 | H | ALA | 86 | 27.154 | 44.815 | 17.238 | 0.00 | 0.00 | A |
| ATOM | 777 | CA | ALA | 86 | 27.012 | 46.588 | 18.385 | 1.00 | 48.58 | A |
| ATOM | 778 | CB | ALA | 86 | 26.001 | 47.069 | 17.376 | 1.00 | 49.64 | A |
| ATOM | 779 | C | ALA | 86 | 26.368 | 46.483 | 19.749 | 1.00 | 49.30 | A |
| ATOM | 780 | O | ALA | 86 | 26.564 | 47.351 | 20.600 | 1.00 | 52.84 | A |
| ATOM | 781 | N | LYS | 87 | 25.649 | 45.392 | 19.988 | 1.00 | 47.54 | A |
| ATOM | 782 | H | LYS | 87 | 25.536 | 44.708 | 19.293 | 0.00 | 0.00 | A |
| ATOM | 783 | CA | LYS | 87 | 25.019 | 45.214 | 21.283 | 1.00 | 46.71 | A |
| ATOM | 784 | CB | LYS | 87 | 24.063 | 44.021 | 21.270 | 1.00 | 47.13 | A |
| ATOM | 785 | CG | LYS | 87 | 22.912 | 44.155 | 22.267 | 1.00 | 49.79 | A |
| ATOM | 786 | CD | LYS | 87 | 22.104 | 42.853 | 22.445 | 1.00 | 51.88 | A |
| ATOM | 787 | CE | LYS | 87 | 21.010 | 42.981 | 23.531 | 1.00 | 50.36 | A |
| ATOM | 788 | NZ | LYS | 87 | 20.829 | 41.733 | 24.325 | 1.00 | 47.38 | A |
| ATOM | 789 | HZ1 | LYS | 87 | 20.124 | 41.875 | 25.096 | 0.00 | 0.00 | A |
| ATOM | 790 | HZ2 | LYS | 87 | 21.715 | 41.481 | 24.811 | 0.00 | 0.00 | A |
| ATOM | 791 | HZ3 | LYS | 87 | 20.540 | 40.939 | 23.728 | 0.00 | 0.00 | A |
| ATOM | 792 | C | LYS | 87 | 26.123 | 45.031 | 22.332 | 1.00 | 47.40 | A |
| ATOM | 793 | O | LYS | 87 | 25.847 | 44.756 | 23.495 | 1.00 | 48.61 | A |
| ATOM | 794 | N | GLY | 88 | 27.375 | 45.150 | 21.902 | 1.00 | 47.77 | A |
| ATOM | 795 | H | GLY | 88 | 27.621 | 45.274 | 20.981 | 0.00 | 0.00 | A |
| ATOM | 796 | CA | GLY | 88 | 28.497 | 45.028 | 22.806 | 1.00 | 52.16 | A |
| ATOM | 797 | C | GLY | 88 | 28.976 | 43.625 | 23.155 | 1.00 | 55.12 | A |
| ATOM | 798 | O | GLY | 88 | 29.582 | 43.427 | 24.219 | 1.00 | 57.62 | A |
| ATOM | 799 | N | TYR | 89 | 28.720 | 42.642 | 22.295 | 1.00 | 55.10 | A |
| ATOM | 800 | H | TYR | 89 | 28.246 | 42.832 | 21.459 | 0.00 | 0.00 | A |
| ATOM | 801 | CA | TYR | 89 | 29.178 | 41.284 | 22.589 | 1.00 | 52.66 | A |
| ATOM | 802 | CB | TYR | 89 | 28.057 | 40.249 | 22.386 | 1.00 | 50.97 | A |
| ATOM | 803 | CG | TYR | 89 | 26.827 | 40.439 | 23.261 | 1.00 | 48.53 | A |
| ATOM | 804 | CD1 | TYR | 89 | 25.639 | 40.934 | 22.723 | 1.00 | 48.39 | A |
| ATOM | 805 | CE1 | TYR | 89 | 24.495 | 41.091 | 23.503 | 1.00 | 46.87 | A |
| ATOM | 806 | CD2 | TYR | 89 | 26.841 | 40.107 | 24.614 | 1.00 | 48.16 | A |
| ATOM | 807 | CE2 | TYR | 89 | 25.690 | 40.266 | 25.413 | 1.00 | 49.29 | A |
| ATOM | 808 | CZ | TYR | 89 | 24.521 | 40.761 | 24.843 | 1.00 | 49.10 | A |
| ATOM | 809 | OH | TYR | 89 | 23.382 | 40.955 | 25.606 | 1.00 | 50.09 | A |
| ATOM | 810 | HH | TYR | 89 | 23.603 | 40.837 | 26.537 | 0.00 | 0.00 | A |
| ATOM | 811 | C | TYR | 89 | 30.385 | 40.940 | 21.721 | 1.00 | 51.44 | A |
| ATOM | 812 | O | TYR | 89 | 30.676 | 41.627 | 20.740 | 1.00 | 51.77 | A |
| ATOM | 813 | N | THR | 90 | 31.114 | 39.910 | 22.126 | 1.00 | 50.40 | A |
| ATOM | 814 | H | THR | 90 | 30.891 | 39.457 | 22.965 | 0.00 | 0.00 | A |
| ATOM | 815 | CA | THR | 90 | 32.280 | 39.443 | 21.394 | 1.00 | 51.69 | A |
| ATOM | 816 | CB | THR | 90 | 33.564 | 39.962 | 21.999 | 1.00 | 53.08 | A |
| ATOM | 817 | OG1 | THR | 90 | 33.507 | 39.817 | 23.422 | 1.00 | 56.38 | A |
| ATOM | 818 | HG1 | THR | 90 | 32.785 | 40.345 | 23.783 | 0.00 | 0.00 | A |
| ATOM | 819 | CG2 | THR | 90 | 33.742 | 41.406 | 21.648 | 1.00 | 56.98 | A |
| ATOM | 820 | C | THR | 90 | 32.288 | 37.932 | 21.453 | 1.00 | 50.53 | A |
| ATOM | 821 | O | THR | 90 | 31.923 | 37.336 | 22.477 | 1.00 | 49.59 | A |
| ATOM | 822 | N | LEU | 91 | 32.738 | 37.322 | 20.362 | 1.00 | 48.12 | A |
| ATOM | 823 | H | LEU | 91 | 33.083 | 37.857 | 19.619 | 0.00 | 0.00 | A |
| ATOM | 824 | CA | LEU | 91 | 32.754 | 35.873 | 20.241 | 1.00 | 44.77 | A |
| ATOM | 825 | CB | LEU | 91 | 33.167 | 35.463 | 18.836 | 1.00 | 40.48 | A |
| ATOM | 826 | CG | LEU | 91 | 32.735 | 34.053 | 18.486 | 1.00 | 38.36 | A |
| ATOM | 827 | CD1 | LEU | 91 | 31.240 | 34.027 | 18.311 | 1.00 | 41.67 | A |
| ATOM | 828 | CD2 | LEU | 91 | 33.391 | 33.647 | 17.211 | 1.00 | 39.76 | A |
| ATOM | 829 | C | LEU | 91 | 33.562 | 35.089 | 21.263 | 1.00 | 43.74 | A |
| ATOM | 830 | O | LEU | 91 | 34.758 | 35.300 | 21.445 | 1.00 | 44.61 | A |
| ATOM | 831 | N | GLY | 92 | 32.863 | 34.215 | 21.969 | 1.00 | 43.20 | A |
| ATOM | 832 | H | GLY | 92 | 31.900 | 34.176 | 21.829 | 0.00 | 0.00 | A |
| ATOM | 833 | CA | GLY | 92 | 33.508 | 33.359 | 22.939 | 1.00 | 42.61 | A |
| ATOM | 834 | C | GLY | 92 | 34.012 | 32.235 | 22.070 | 1.00 | 41.85 | A |
| ATOM | 835 | O | GLY | 92 | 35.211 | 31.998 | 22.000 | 1.00 | 46.57 | A |
| ATOM | 836 | N | ASN | 93 | 33.082 | 31.573 | 21.384 | 1.00 | 37.54 | A |
| ATOM | 837 | H | ASN | 93 | 32.140 | 31.840 | 21.477 | 0.00 | 0.00 | A |
| ATOM | 838 | CA | ASN | 93 | 33.377 | 30.479 | 20.458 | 1.00 | 32.87 | A |
| ATOM | 839 | CB | ASN | 93 | 34.188 | 29.379 | 21.109 | 1.00 | 30.40 | A |
| ATOM | 840 | CG | ASN | 93 | 33.424 | 28.681 | 22.180 | 1.00 | 31.60 | A |
| ATOM | 841 | OD1 | ASN | 93 | 33.347 | 27.461 | 22.198 | 1.00 | 30.63 | A |
| ATOM | 842 | ND2 | ASN | 93 | 32.836 | 29.452 | 23.090 | 1.00 | 33.68 | A |
| ATOM | 843 | HD21 | ASN | 93 | 32.936 | 30.415 | 23.047 | 0.00 | 0.00 | A |
| ATOM | 844 | HD22 | ASN | 93 | 32.317 | 29.002 | 23.781 | 0.00 | 0.00 | A |
| ATOM | 845 | C | ASN | 93 | 32.063 | 29.889 | 20.002 | 1.00 | 31.30 | A |
| ATOM | 846 | O | ASN | 93 | 31.026 | 30.080 | 20.644 | 1.00 | 30.67 | A |
| ATOM | 847 | N | VAL | 94 | 32.114 | 29.170 | 18.892 | 1.00 | 29.84 | A |
| ATOM | 848 | H | VAL | 94 | 32.974 | 29.020 | 18.438 | 0.00 | 0.00 | A |
| ATOM | 849 | CA | VAL | 94 | 30.936 | 28.547 | 18.326 | 1.00 | 28.71 | A |
| ATOM | 850 | CB | VAL | 94 | 30.491 | 29.262 | 17.041 | 1.00 | 26.56 | A |
| ATOM | 851 | CG1 | VAL | 94 | 30.169 | 30.708 | 17.332 | 1.00 | 27.50 | A |
| ATOM | 852 | CG2 | VAL | 94 | 31.576 | 29.185 | 15.998 | 1.00 | 27.05 | A |
| ATOM | 853 | C | VAL | 94 | 31.259 | 27.100 | 17.990 | 1.00 | 29.69 | A |
| ATOM | 854 | O | VAL | 94 | 32.422 | 26.749 | 17.732 | 1.00 | 31.55 | A |
| ATOM | 855 | N | ASP | 95 | 30.231 | 26.261 | 18.038 | 1.00 | 29.21 | A |
| ATOM | 856 | H | ASP | 95 | 29.341 | 26.584 | 18.288 | 0.00 | 0.00 | A |
| ATOM | 857 | CA | ASP | 95 | 30.358 | 24.853 | 17.717 | 1.00 | 25.98 | A |
| ATOM | 858 | CB | ASP | 95 | 30.364 | 23.993 | 18.975 | 1.00 | 26.33 | A |
| ATOM | 859 | CG | ASP | 95 | 30.752 | 22.560 | 18.688 | 1.00 | 29.22 | A |
| ATOM | 860 | OD1 | ASP | 95 | 31.043 | 21.793 | 19.627 | 1.00 | 31.70 | A |
| ATOM | 861 | OD2 | ASP | 95 | 30.770 | 22.171 | 17.510 | 1.00 | 31.46 | A |
| ATOM | 862 | C | ASP | 95 | 29.150 | 24.511 | 16.872 | 1.00 | 25.28 | A |
| ATOM | 863 | O | ASP | 95 | 28.003 | 24.781 | 17.271 | 1.00 | 26.63 | A |
| ATOM | 864 | N | VAL | 96 | 29.414 | 23.948 | 15.699 | 1.00 | 21.48 | A |
| ATOM | 865 | H | VAL | 96 | 30.347 | 23.732 | 15.502 | 0.00 | 0.00 | A |
| ATOM | 866 | CA | VAL | 96 | 28.370 | 23.571 | 14.764 | 1.00 | 20.69 | A |
| ATOM | 867 | CB | VAL | 96 | 28.559 | 24.315 | 13.438 | 1.00 | 17.65 | A |
| ATOM | 868 | CG1 | VAL | 96 | 27.429 | 23.976 | 12.457 | 1.00 | 14.81 | A |
| ATOM | 869 | CG2 | VAL | 96 | 28.618 | 25.800 | 13.700 | 1.00 | 14.55 | A |
| ATOM | 870 | C | VAL | 96 | 28.370 | 22.062 | 14.511 | 1.00 | 22.28 | A |
| ATOM | 871 | O | VAL | 96 | 29.417 | 21.446 | 14.312 | 1.00 | 23.85 | A |
| ATOM | 872 | N | THR | 97 | 27.195 | 21.459 | 14.520 | 1.00 | 22.37 | A |
| ATOM | 873 | H | THR | 97 | 26.385 | 21.977 | 14.662 | 0.00 | 0.00 | A |
| ATOM | 874 | CA | THR | 97 | 27.090 | 20.036 | 14.277 | 1.00 | 24.11 | A |
| ATOM | 875 | CB | THR | 97 | 26.451 | 19.342 | 15.463 | 1.00 | 23.64 | A |
| ATOM | 876 | OG1 | THR | 97 | 27.254 | 19.560 | 16.624 | 1.00 | 28.34 | A |
| ATOM | 877 | HG1 | THR | 97 | 28.136 | 19.404 | 16.269 | 0.00 | 0.00 | A |
| ATOM | 878 | CG2 | THR | 97 | 26.341 | 17.877 | 15.214 | 1.00 | 22.64 | A |
| ATOM | 879 | C | THR | 97 | 26.184 | 19.858 | 13.075 | 1.00 | 26.92 | A |
| ATOM | 880 | O | THR | 97 | 25.045 | 20.330 | 13.085 | 1.00 | 30.16 | A |
| ATOM | 881 | N | ILE | 98 | 26.702 | 19.239 | 12.020 | 1.00 | 28.47 | A |
| ATOM | 882 | H | ILE | 98 | 27.629 | 18.923 | 12.043 | 0.00 | 0.00 | A |
| ATOM | 883 | CA | ILE | 98 | 25.916 | 18.997 | 10.810 | 1.00 | 27.52 | A |
| ATOM | 884 | CB | ILE | 98 | 26.772 | 19.065 | 9.561 | 1.00 | 24.94 | A |
| ATOM | 885 | CG2 | ILE | 98 | 25.912 | 18.830 | 8.338 | 1.00 | 23.03 | A |
| ATOM | 886 | CG1 | ILE | 98 | 27.463 | 20.418 | 9.490 | 1.00 | 24.43 | A |
| ATOM | 887 | CD1 | ILE | 98 | 28.555 | 20.465 | 8.482 | 1.00 | 26.74 | A |
| ATOM | 888 | C | ILE | 98 | 25.376 | 17.593 | 10.899 | 1.00 | 28.50 | A |
| ATOM | 889 | O | ILE | 98 | 26.138 | 16.641 | 11.069 | 1.00 | 32.70 | A |
| ATOM | 890 | N | ILE | 99 | 24.066 | 17.454 | 10.835 | 1.00 | 26.36 | A |
| ATOM | 891 | H | ILE | 99 | 23.476 | 18.224 | 10.687 | 0.00 | 0.00 | A |
| ATOM | 892 | CA | ILE | 99 | 23.477 | 16.130 | 10.905 | 1.00 | 23.28 | A |
| ATOM | 893 | CB | ILE | 99 | 22.292 | 16.089 | 11.863 | 1.00 | 20.87 | A |
| ATOM | 894 | CG2 | ILE | 99 | 21.782 | 14.676 | 11.983 | 1.00 | 19.16 | A |
| ATOM | 895 | CG1 | ILE | 99 | 22.736 | 16.586 | 13.230 | 1.00 | 19.32 | A |
| ATOM | 896 | CD1 | ILE | 99 | 21.613 | 16.952 | 14.126 | 1.00 | 18.53 | A |
| ATOM | 897 | C | ILE | 99 | 23.017 | 15.862 | 9.499 | 1.00 | 22.56 | A |
| ATOM | 898 | O | ILE | 99 | 21.967 | 16.331 | 9.088 | 1.00 | 23.50 | A |
| ATOM | 899 | N | ALA | 100 | 23.840 | 15.162 | 8.740 | 1.00 | 22.47 | A |
| ATOM | 900 | H | ALA | 100 | 24.678 | 14.819 | 9.121 | 0.00 | 0.00 | A |
| ATOM | 901 | CA | ALA | 100 | 23.515 | 14.861 | 7.364 | 1.00 | 24.34 | A |
| ATOM | 902 | CB | ALA | 100 | 24.115 | 15.917 | 6.455 | 1.00 | 24.86 | A |
| ATOM | 903 | C | ALA | 100 | 24.054 | 13.484 | 7.027 | 1.00 | 26.12 | A |
| ATOM | 904 | O | ALA | 100 | 25.068 | 13.067 | 7.570 | 1.00 | 25.13 | A |
| ATOM | 905 | N | GLN | 101 | 23.328 | 12.750 | 6.190 | 1.00 | 30.20 | A |
| ATOM | 906 | H | GLN | 101 | 22.495 | 13.128 | 5.836 | 0.00 | 0.00 | A |
| ATOM | 907 | CA | GLN | 101 | 23.743 | 11.403 | 5.794 | 1.00 | 32.72 | A |
| ATOM | 908 | CB | GLN | 101 | 22.543 | 10.593 | 5.302 | 1.00 | 36.25 | A |
| ATOM | 909 | CG | GLN | 101 | 22.812 | 9.113 | 5.111 | 1.00 | 37.82 | A |
| ATOM | 910 | CD | GLN | 101 | 22.853 | 8.372 | 6.419 | 1.00 | 41.25 | A |
| ATOM | 911 | OE1 | GLN | 101 | 23.512 | 7.344 | 6.538 | 1.00 | 44.59 | A |
| ATOM | 912 | NE2 | GLN | 101 | 22.129 | 8.877 | 7.415 | 1.00 | 41.70 | A |
| ATOM | 913 | HE21 | GLN | 101 | 21.571 | 9.668 | 7.268 | 0.00 | 0.00 | A |
| ATOM | 914 | HE22 | GLN | 101 | 22.208 | 8.420 | 8.271 | 0.00 | 0.00 | A |
| ATOM | 915 | C | GLN | 101 | 24.732 | 11.538 | 4.661 | 1.00 | 32.61 | A |
| ATOM | 916 | O | GLN | 101 | 25.614 | 10.699 | 4.491 | 1.00 | 32.65 | A |
| ATOM | 917 | N | ALA | 102 | 24.528 | 12.575 | 3.855 | 1.00 | 31.25 | A |
| ATOM | 918 | H | ALA | 102 | 23.781 | 13.194 | 3.998 | 0.00 | 0.00 | A |
| ATOM | 919 | CA | ALA | 102 | 25.381 | 12.854 | 2.717 | 1.00 | 30.26 | A |
| ATOM | 920 | CB | ALA | 102 | 25.123 | 11.858 | 1.638 | 1.00 | 31.87 | A |
| ATOM | 921 | C | ALA | 102 | 25.056 | 14.246 | 2.215 | 1.00 | 30.69 | A |
| ATOM | 922 | O | ALA | 102 | 23.915 | 14.689 | 2.322 | 1.00 | 33.23 | A |
| ATOM | 923 | N | PRO | 103 | 26.013 | 14.897 | 1.540 | 1.00 | 29.49 | A |
| ATOM | 924 | CD | PRO | 103 | 25.786 | 16.217 | 0.934 | 1.00 | 27.63 | A |
| ATOM | 925 | CA | PRO | 103 | 27.359 | 14.405 | 1.223 | 1.00 | 29.62 | A |
| ATOM | 926 | CB | PRO | 103 | 27.785 | 15.321 | 0.089 | 1.00 | 27.24 | A |
| ATOM | 927 | CG | PRO | 103 | 27.166 | 16.596 | 0.476 | 1.00 | 27.65 | A |
| ATOM | 928 | C | PRO | 103 | 28.351 | 14.441 | 2.387 | 1.00 | 31.08 | A |
| ATOM | 929 | O | PRO | 103 | 28.035 | 14.923 | 3.476 | 1.00 | 34.18 | A |
| ATOM | 930 | N | LYS | 104 | 29.548 | 13.913 | 2.149 | 1.00 | 31.23 | A |
| ATOM | 931 | H | LYS | 104 | 29.737 | 13.555 | 1.260 | 0.00 | 0.00 | A |
| ATOM | 932 | CA | LYS | 104 | 30.600 | 13.868 | 3.160 | 1.00 | 30.55 | A |
| ATOM | 933 | CB | LYS | 104 | 31.747 | 13.005 | 2.647 | 1.00 | 32.11 | A |
| ATOM | 934 | CG | LYS | 104 | 32.732 | 12.586 | 3.710 | 1.00 | 39.62 | A |
| ATOM | 935 | CD | LYS | 104 | 32.126 | 11.534 | 4.617 | 1.00 | 47.76 | A |
| ATOM | 936 | CE | LYS | 104 | 33.138 | 10.969 | 5.605 | 1.00 | 51.39 | A |
| ATOM | 937 | NZ | LYS | 104 | 32.555 | 9.780 | 6.303 | 1.00 | 58.65 | A |
| ATOM | 938 | HZ1 | LYS | 104 | 32.310 | 9.059 | 5.593 | 0.00 | 0.00 | A |
| ATOM | 939 | HZ2 | LYS | 104 | 31.692 | 10.041 | 6.822 | 0.00 | 0.00 | A |
| ATOM | 940 | HZ3 | LYS | 104 | 33.237 | 9.373 | 6.976 | 0.00 | 0.00 | A |
| ATOM | 941 | C | LYS | 104 | 31.118 | 15.274 | 3.521 | 1.00 | 30.70 | A |
| ATOM | 942 | O | LYS | 104 | 31.940 | 15.856 | 2.804 | 1.00 | 33.15 | A |
| ATOM | 943 | N | MET | 105 | 30.641 | 15.810 | 4.636 | 1.00 | 27.17 | A |
| ATOM | 944 | H | MET | 105 | 29.957 | 15.309 | 5.127 | 0.00 | 0.00 | A |
| ATOM | 945 | CA | MET | 105 | 31.038 | 17.131 | 5.077 | 1.00 | 23.11 | A |
| ATOM | 946 | CB | MET | 105 | 30.221 | 17.522 | 6.287 | 1.00 | 20.55 | A |
| ATOM | 947 | CG | MET | 105 | 28.752 | 17.435 | 6.040 | 1.00 | 20.86 | A |
| ATOM | 948 | SD | MET | 105 | 28.348 | 18.475 | 4.664 | 1.00 | 24.64 | A |
| ATOM | 949 | CE | MET | 105 | 26.592 | 18.112 | 4.428 | 1.00 | 25.36 | A |
| ATOM | 950 | C | MET | 105 | 32.498 | 17.220 | 5.442 | 1.00 | 24.75 | A |
| ATOM | 951 | O | MET | 105 | 33.165 | 18.190 | 5.112 | 1.00 | 26.42 | A |
| ATOM | 952 | N | LEU | 106 | 33.012 | 16.164 | 6.045 | 1.00 | 26.60 | A |
| ATOM | 953 | H | LEU | 106 | 32.428 | 15.424 | 6.141 | 0.00 | 0.00 | A |
| ATOM | 954 | CA | LEU | 106 | 34.384 | 16.131 | 6.530 | 1.00 | 30.92 | A |
| ATOM | 955 | CB | LEU | 106 | 34.840 | 14.710 | 6.830 | 1.00 | 33.23 | A |
| ATOM | 956 | CG | LEU | 106 | 36.193 | 14.730 | 7.550 | 1.00 | 35.71 | A |
| ATOM | 957 | CD1 | LEU | 106 | 36.080 | 15.518 | 8.860 | 1.00 | 34.86 | A |
| ATOM | 958 | CD2 | LEU | 106 | 36.661 | 13.316 | 7.817 | 1.00 | 39.13 | A |
| ATOM | 959 | C | LEU | 106 | 35.502 | 16.878 | 5.815 | 1.00 | 33.00 | A |
| ATOM | 960 | O | LEU | 106 | 36.145 | 17.730 | 6.415 | 1.00 | 34.83 | A |
| ATOM | 961 | N | PRO | 107 | 35.783 | 16.551 | 4.550 | 1.00 | 34.66 | A |
| ATOM | 962 | CD | PRO | 107 | 35.070 | 15.630 | 3.653 | 1.00 | 35.54 | A |
| ATOM | 963 | CA | PRO | 107 | 36.860 | 17.245 | 3.830 | 1.00 | 34.02 | A |
| ATOM | 964 | CB | PRO | 107 | 36.856 | 16.551 | 2.475 | 1.00 | 33.94 | A |
| ATOM | 965 | CG | PRO | 107 | 35.418 | 16.196 | 2.296 | 1.00 | 35.46 | A |
| ATOM | 966 | C | PRO | 107 | 36.682 | 18.750 | 3.654 | 1.00 | 34.13 | A |
| ATOM | 967 | O | PRO | 107 | 37.658 | 19.471 | 3.440 | 1.00 | 35.83 | A |
| ATOM | 968 | N | HIS | 108 | 35.445 | 19.228 | 3.729 | 1.00 | 32.20 | A |
| ATOM | 969 | H | HIS | 108 | 34.708 | 18.628 | 3.974 | 0.00 | 0.00 | A |
| ATOM | 970 | CA | HIS | 108 | 35.186 | 20.648 | 3.539 | 1.00 | 32.18 | A |
| ATOM | 971 | CB | HIS | 108 | 33.823 | 20.831 | 2.899 | 1.00 | 29.32 | A |
| ATOM | 972 | CG | HIS | 108 | 33.598 | 19.930 | 1.737 | 1.00 | 30.49 | A |
| ATOM | 973 | CD2 | HIS | 108 | 32.999 | 18.719 | 1.654 | 1.00 | 32.25 | A |
| ATOM | 974 | ND1 | HIS | 108 | 34.077 | 20.210 | 0.477 | 1.00 | 32.65 | A |
| ATOM | 975 | HD1 | HIS | 108 | 34.500 | 21.047 | 0.187 | 0.00 | 0.00 | A |
| ATOM | 976 | CE1 | HIS | 108 | 33.789 | 19.205 | −0.333 | 1.00 | 33.70 | A |
| ATOM | 977 | NE2 | HIS | 108 | 33.135 | 18.287 | 0.357 | 1.00 | 33.09 | A |
| ATOM | 978 | HE2 | HIS | 108 | 32.792 | 17.434 | 0.009 | 0.00 | 0.00 | A |
| ATOM | 979 | C | HIS | 108 | 35.255 | 21.453 | 4.822 | 1.00 | 32.37 | A |
| ATOM | 980 | O | HIS | 108 | 35.450 | 22.665 | 4.802 | 1.00 | 35.13 | A |
| ATOM | 981 | N | ILE | 109 | 35.165 | 20.769 | 5.946 | 1.00 | 30.80 | A |
| ATOM | 982 | H | ILE | 109 | 35.109 | 19.791 | 5.914 | 0.00 | 0.00 | A |
| ATOM | 983 | CA | ILE | 109 | 35.169 | 21.441 | 7.223 | 1.00 | 28.67 | A |
| ATOM | 984 | CB | ILE | 109 | 35.079 | 20.428 | 8.358 | 1.00 | 25.44 | A |
| ATOM | 985 | CG2 | ILE | 109 | 35.055 | 21.141 | 9.682 | 1.00 | 24.26 | A |
| ATOM | 986 | CG1 | ILE | 109 | 33.800 | 19.595 | 8.170 | 1.00 | 23.97 | A |
| ATOM | 987 | CD1 | ILE | 109 | 33.542 | 18.564 | 9.221 | 1.00 | 21.85 | A |
| ATOM | 988 | C | ILE | 109 | 36.221 | 22.524 | 7.476 | 1.00 | 31.02 | A |
| ATOM | 989 | O | ILE | 109 | 35.858 | 23.625 | 7.868 | 1.00 | 34.59 | A |
| ATOM | 990 | N | PRO | 110 | 37.508 | 22.285 | 7.157 | 1.00 | 31.82 | A |
| ATOM | 991 | CD | PRO | 110 | 38.108 | 21.141 | 6.464 | 1.00 | 33.75 | A |
| ATOM | 992 | CA | PRO | 110 | 38.532 | 23.318 | 7.398 | 1.00 | 32.00 | A |
| ATOM | 993 | CB | PRO | 110 | 39.808 | 22.675 | 6.868 | 1.00 | 31.54 | A |
| ATOM | 994 | CG | PRO | 110 | 39.527 | 21.221 | 6.952 | 1.00 | 34.69 | A |
| ATOM | 995 | C | PRO | 110 | 38.242 | 24.608 | 6.641 | 1.00 | 31.15 | A |
| ATOM | 996 | O | PRO | 110 | 38.387 | 25.710 | 7.179 | 1.00 | 30.73 | A |
| ATOM | 997 | N | GLN | 111 | 37.861 | 24.469 | 5.378 | 1.00 | 29.83 | A |
| ATOM | 998 | H | GLN | 111 | 37.780 | 23.576 | 4.984 | 0.00 | 0.00 | A |
| ATOM | 999 | CA | GLN | 111 | 37.531 | 25.636 | 4.585 | 1.00 | 29.52 | A |
| ATOM | 1000 | CB | GLN | 111 | 37.184 | 25.221 | 3.166 | 1.00 | 27.95 | A |
| ATOM | 1001 | CG | GLN | 111 | 36.951 | 26.377 | 2.247 | 1.00 | 26.61 | A |
| ATOM | 1002 | CD | GLN | 111 | 38.113 | 27.314 | 2.235 | 1.00 | 26.95 | A |
| ATOM | 1003 | OE1 | GLN | 111 | 37.945 | 28.506 | 2.399 | 1.00 | 31.59 | A |
| ATOM | 1004 | NE2 | GLN | 111 | 39.309 | 26.780 | 2.081 | 1.00 | 28.41 | A |
| ATOM | 1005 | HE21 | GLN | 111 | 39.362 | 25.808 | 2.012 | 0.00 | 0.00 | A |
| ATOM | 1006 | HE22 | GLN | 111 | 40.046 | 27.428 | 2.045 | 0.00 | 0.00 | A |
| ATOM | 1007 | C | GLN | 111 | 36.348 | 26.360 | 5.238 | 1.00 | 31.21 | A |
| ATOM | 1008 | O | GLN | 111 | 36.301 | 27.589 | 5.241 | 1.00 | 34.73 | A |
| ATOM | 1009 | N | MET | 112 | 35.415 | 25.595 | 5.811 | 1.00 | 30.63 | A |
| ATOM | 1010 | H | MET | 112 | 35.502 | 24.621 | 5.771 | 0.00 | 0.00 | A |
| ATOM | 1011 | CA | MET | 112 | 34.248 | 26.160 | 6.487 | 1.00 | 29.57 | A |
| ATOM | 1012 | CB | MET | 112 | 33.338 | 25.064 | 7.035 | 1.00 | 29.32 | A |
| ATOM | 1013 | CG | MET | 112 | 32.466 | 24.379 | 6.023 | 1.00 | 29.15 | A |
| ATOM | 1014 | SD | MET | 112 | 31.270 | 23.304 | 6.822 | 1.00 | 28.95 | A |
| ATOM | 1015 | CE | MET | 112 | 31.593 | 21.844 | 5.973 | 1.00 | 28.88 | A |
| ATOM | 1016 | C | MET | 112 | 34.742 | 26.983 | 7.655 | 1.00 | 29.94 | A |
| ATOM | 1017 | O | MET | 112 | 34.348 | 28.136 | 7.833 | 1.00 | 28.77 | A |
| ATOM | 1018 | N | ARG | 113 | 35.629 | 26.385 | 8.444 | 1.00 | 29.79 | A |
| ATOM | 1019 | H | ARG | 113 | 35.903 | 25.477 | 8.220 | 0.00 | 0.00 | A |
| ATOM | 1020 | CA | ARG | 113 | 36.184 | 27.066 | 9.603 | 1.00 | 31.35 | A |
| ATOM | 1021 | CB | ARG | 113 | 37.147 | 26.168 | 10.365 | 1.00 | 26.63 | A |
| ATOM | 1022 | CG | ARG | 113 | 36.504 | 24.924 | 10.854 | 1.00 | 26.05 | A |
| ATOM | 1023 | CD | ARG | 113 | 37.494 | 24.063 | 11.574 | 1.00 | 28.17 | A |
| ATOM | 1024 | NE | ARG | 113 | 37.869 | 24.664 | 12.841 | 1.00 | 29.99 | A |
| ATOM | 1025 | HE | ARG | 113 | 37.174 | 25.212 | 13.261 | 0.00 | 0.00 | A |
| ATOM | 1026 | CZ | ARG | 113 | 39.058 | 24.511 | 13.409 | 1.00 | 33.94 | A |
| ATOM | 1027 | NH1 | ARG | 113 | 39.313 | 25.096 | 14.570 | 1.00 | 35.54 | A |
| ATOM | 1028 | HH11 | ARG | 113 | 38.591 | 25.682 | 14.975 | 0.00 | 0.00 | A |
| ATOM | 1029 | HH12 | ARG | 113 | 40.169 | 25.023 | 15.081 | 0.00 | 0.00 | A |
| ATOM | 1030 | NH2 | ARG | 113 | 40.005 | 23.804 | 12.797 | 1.00 | 37.16 | A |
| ATOM | 1031 | HH21 | ARG | 113 | 39.804 | 23.364 | 11.923 | 0.00 | 0.00 | A |
| ATOM | 1032 | HH22 | ARG | 113 | 40.895 | 23.648 | 13.225 | 0.00 | 0.00 | A |
| ATOM | 1033 | C | ARG | 113 | 36.879 | 28.340 | 9.160 | 1.00 | 32.51 | A |
| ATOM | 1034 | O | ARG | 113 | 36.861 | 29.340 | 9.870 | 1.00 | 34.70 | A |
| ATOM | 1035 | N | VAL | 114 | 37.457 | 28.323 | 7.970 | 1.00 | 32.05 | A |
| ATOM | 1036 | H | VAL | 114 | 37.453 | 27.508 | 7.430 | 0.00 | 0.00 | A |
| ATOM | 1037 | CA | VAL | 114 | 38.114 | 29.513 | 7.471 | 1.00 | 33.20 | A |
| ATOM | 1038 | CB | VAL | 114 | 38.882 | 29.211 | 6.214 | 1.00 | 35.24 | A |
| ATOM | 1039 | CG1 | VAL | 114 | 39.283 | 30.505 | 5.527 | 1.00 | 36.47 | A |
| ATOM | 1040 | CG2 | VAL | 114 | 40.099 | 28.370 | 6.573 | 1.00 | 39.01 | A |
| ATOM | 1041 | C | VAL | 114 | 37.089 | 30.598 | 7.185 | 1.00 | 31.95 | A |
| ATOM | 1042 | O | VAL | 114 | 37.251 | 31.743 | 7.599 | 1.00 | 31.85 | A |
| ATOM | 1043 | N | PHE | 115 | 36.021 | 30.215 | 6.503 | 1.00 | 29.67 | A |
| ATOM | 1044 | H | PHE | 115 | 35.953 | 29.278 | 6.215 | 0.00 | 0.00 | A |
| ATOM | 1045 | CA | PHE | 115 | 34.959 | 31.140 | 6.165 | 1.00 | 29.11 | A |
| ATOM | 1046 | CB | PHE | 115 | 33.934 | 30.432 | 5.305 | 1.00 | 26.27 | A |
| ATOM | 1047 | CG | PHE | 115 | 34.351 | 30.262 | 3.894 | 1.00 | 25.94 | A |
| ATOM | 1048 | CD1 | PHE | 115 | 33.697 | 29.361 | 3.076 | 1.00 | 25.63 | A |
| ATOM | 1049 | CD2 | PHE | 115 | 35.351 | 31.049 | 3.356 | 1.00 | 26.42 | A |
| ATOM | 1050 | CE1 | PHE | 115 | 34.027 | 29.256 | 1.745 | 1.00 | 26.24 | A |
| ATOM | 1051 | CE2 | PHE | 115 | 35.687 | 30.948 | 2.022 | 1.00 | 27.52 | A |
| ATOM | 1052 | CZ | PHE | 115 | 35.021 | 30.049 | 1.216 | 1.00 | 26.42 | A |
| ATOM | 1053 | C | PHE | 115 | 34.249 | 31.701 | 7.383 | 1.00 | 31.12 | A |
| ATOM | 1054 | O | PHE | 115 | 33.966 | 32.900 | 7.464 | 1.00 | 31.91 | A |
| ATOM | 1055 | N | ILE | 116 | 33.954 | 30.827 | 8.333 | 1.00 | 31.88 | A |
| ATOM | 1056 | H | ILE | 116 | 34.229 | 29.901 | 8.225 | 0.00 | 0.00 | A |
| ATOM | 1057 | CA | ILE | 116 | 33.236 | 31.237 | 9.520 | 1.00 | 31.22 | A |
| ATOM | 1058 | CB | ILE | 116 | 32.717 | 30.029 | 10.283 | 1.00 | 27.39 | A |
| ATOM | 1059 | CG2 | ILE | 116 | 32.012 | 30.477 | 11.539 | 1.00 | 26.34 | A |
| ATOM | 1060 | CG1 | ILE | 116 | 31.756 | 29.252 | 9.379 | 1.00 | 26.71 | A |
| ATOM | 1061 | CD1 | ILE | 116 | 31.384 | 27.882 | 9.877 | 1.00 | 27.87 | A |
| ATOM | 1062 | C | ILE | 116 | 34.067 | 32.122 | 10.412 | 1.00 | 33.95 | A |
| ATOM | 1063 | O | ILE | 116 | 33.584 | 33.141 | 10.894 | 1.00 | 35.42 | A |
| ATOM | 1064 | N | ALA | 117 | 35.332 | 31.764 | 10.591 | 1.00 | 37.02 | A |
| ATOM | 1065 | H | ALA | 117 | 35.689 | 30.965 | 10.149 | 0.00 | 0.00 | A |
| ATOM | 1066 | CA | ALA | 117 | 36.226 | 32.543 | 11.445 | 1.00 | 38.79 | A |
| ATOM | 1067 | CB | ALA | 117 | 37.526 | 31.814 | 11.671 | 1.00 | 38.83 | A |
| ATOM | 1068 | C | ALA | 117 | 36.485 | 33.900 | 10.840 | 1.00 | 39.68 | A |
| ATOM | 1069 | O | ALA | 117 | 36.752 | 34.863 | 11.553 | 1.00 | 40.73 | A |
| ATOM | 1070 | N | GLU | 118 | 36.443 | 33.967 | 9.517 | 1.00 | 42.66 | A |
| ATOM | 1071 | H | GLU | 118 | 36.327 | 33.160 | 8.974 | 0.00 | 0.00 | A |
| ATOM | 1072 | CA | GLU | 118 | 36.637 | 35.238 | 8.839 | 1.00 | 45.20 | A |
| ATOM | 1073 | CB | GLU | 118 | 36.726 | 35.067 | 7.319 | 1.00 | 50.39 | A |
| ATOM | 1074 | CG | GLU | 118 | 38.042 | 34.483 | 6.820 | 1.00 | 57.15 | A |
| ATOM | 1075 | CD | GLU | 118 | 38.282 | 34.755 | 5.343 | 1.00 | 61.48 | A |
| ATOM | 1076 | OE1 | GLU | 118 | 39.442 | 34.557 | 4.918 | 1.00 | 63.37 | A |
| ATOM | 1077 | OE2 | GLU | 118 | 37.329 | 35.169 | 4.616 | 1.00 | 62.08 | A |
| ATOM | 1078 | C | GLU | 118 | 35.436 | 36.087 | 9.167 | 1.00 | 42.71 | A |
| ATOM | 1079 | O | GLU | 118 | 35.557 | 37.101 | 9.844 | 1.00 | 42.34 | A |
| ATOM | 1080 | N | ASP | 119 | 34.269 | 35.617 | 8.745 | 1.00 | 41.12 | A |
| ATOM | 1081 | H | ASP | 119 | 34.224 | 34.776 | 8.240 | 0.00 | 0.00 | A |
| ATOM | 1082 | CA | ASP | 119 | 33.026 | 36.324 | 8.976 | 1.00 | 41.07 | A |
| ATOM | 1083 | CB | ASP | 119 | 31.858 | 35.423 | 8.611 | 1.00 | 39.39 | A |
| ATOM | 1084 | CG | ASP | 119 | 31.783 | 35.145 | 7.139 | 1.00 | 39.80 | A |
| ATOM | 1085 | OD1 | ASP | 119 | 30.943 | 34.318 | 6.745 | 1.00 | 42.66 | A |
| ATOM | 1086 | OD2 | ASP | 119 | 32.545 | 35.754 | 6.361 | 1.00 | 40.36 | A |
| ATOM | 1087 | C | ASP | 119 | 32.875 | 36.845 | 10.408 | 1.00 | 42.19 | A |
| ATOM | 1088 | O | ASP | 119 | 32.472 | 37.995 | 10.620 | 1.00 | 43.47 | A |
| ATOM | 1089 | N | LEU | 120 | 33.216 | 36.008 | 11.383 | 1.00 | 42.63 | A |
| ATOM | 1090 | H | LEU | 120 | 33.516 | 35.114 | 11.121 | 0.00 | 0.00 | A |
| ATOM | 1091 | CA | LEU | 120 | 33.120 | 36.377 | 12.788 | 1.00 | 42.88 | A |
| ATOM | 1092 | CB | LEU | 120 | 32.993 | 35.121 | 13.637 | 1.00 | 41.15 | A |
| ATOM | 1093 | CG | LEU | 120 | 31.785 | 34.289 | 13.225 | 1.00 | 39.92 | A |
| ATOM | 1094 | CD1 | LEU | 120 | 31.668 | 33.041 | 14.067 | 1.00 | 40.97 | A |
| ATOM | 1095 | CD2 | LEU | 120 | 30.560 | 35.136 | 13.365 | 1.00 | 39.73 | A |
| ATOM | 1096 | C | LEU | 120 | 34.324 | 37.201 | 13.237 | 1.00 | 45.85 | A |
| ATOM | 1097 | O | LEU | 120 | 34.260 | 37.928 | 14.231 | 1.00 | 47.14 | A |
| ATOM | 1098 | N | GLY | 121 | 35.421 | 37.084 | 12.500 | 1.00 | 47.34 | A |
| ATOM | 1099 | H | GLY | 121 | 35.436 | 36.498 | 11.719 | 0.00 | 0.00 | A |
| ATOM | 1100 | CA | GLY | 121 | 36.621 | 37.827 | 12.829 | 1.00 | 49.33 | A |
| ATOM | 1101 | C | GLY | 121 | 37.319 | 37.290 | 14.058 | 1.00 | 50.68 | A |
| ATOM | 1102 | O | GLY | 121 | 37.770 | 38.058 | 14.909 | 1.00 | 53.99 | A |
| ATOM | 1103 | N | CYS | 122 | 37.417 | 35.971 | 14.149 | 1.00 | 50.76 | A |
| ATOM | 1104 | H | CYS | 122 | 37.094 | 35.415 | 13.410 | 0.00 | 0.00 | A |
| ATOM | 1105 | CA | CYS | 122 | 38.065 | 35.319 | 15.280 | 1.00 | 51.22 | A |
| ATOM | 1106 | CB | CYS | 122 | 37.057 | 34.473 | 16.035 | 1.00 | 52.74 | A |
| ATOM | 1107 | SG | CYS | 122 | 36.242 | 33.287 | 14.965 | 1.00 | 53.81 | A |
| ATOM | 1108 | C | CYS | 122 | 39.125 | 34.419 | 14.707 | 1.00 | 50.42 | A |
| ATOM | 1109 | O | CYS | 122 | 39.486 | 34.559 | 13.545 | 1.00 | 49.50 | A |
| ATOM | 1110 | N | HIS | 123 | 39.643 | 33.507 | 15.516 | 1.00 | 51.98 | A |
| ATOM | 1111 | H | HIS | 123 | 39.294 | 33.376 | 16.435 | 0.00 | 0.00 | A |
| ATOM | 1112 | CA | HIS | 123 | 40.656 | 32.591 | 15.020 | 1.00 | 56.96 | A |
| ATOM | 1113 | CB | HIS | 123 | 41.771 | 32.355 | 16.048 | 1.00 | 69.26 | A |
| ATOM | 1114 | CG | HIS | 123 | 42.182 | 33.586 | 16.802 | 1.00 | 84.01 | A |
| ATOM | 1115 | CD2 | HIS | 123 | 42.592 | 33.750 | 18.085 | 1.00 | 89.51 | A |
| ATOM | 1116 | ND1 | HIS | 123 | 42.165 | 34.850 | 16.243 | 1.00 | 90.35 | A |
| ATOM | 1117 | HD1 | HIS | 123 | 41.947 | 35.077 | 15.308 | 0.00 | 0.00 | A |
| ATOM | 1118 | CE1 | HIS | 123 | 42.541 | 35.738 | 17.149 | 1.00 | 92.99 | A |
| ATOM | 1119 | NE2 | HIS | 123 | 42.805 | 35.097 | 18.275 | 1.00 | 94.06 | A |
| ATOM | 1120 | HE2 | HIS | 123 | 43.069 | 35.512 | 19.127 | 0.00 | 0.00 | A |
| ATOM | 1121 | C | HIS | 123 | 39.906 | 31.308 | 14.805 | 1.00 | 52.96 | A |
| ATOM | 1122 | O | HIS | 123 | 38.875 | 31.098 | 15.422 | 1.00 | 52.69 | A |
| ATOM | 1123 | N | MET | 124 | 40.412 | 30.455 | 13.925 | 1.00 | 49.89 | A |
| ATOM | 1124 | H | MET | 124 | 41.211 | 30.696 | 13.413 | 0.00 | 0.00 | A |
| ATOM | 1125 | CA | MET | 124 | 39.769 | 29.178 | 13.662 | 1.00 | 47.86 | A |
| ATOM | 1126 | CB | MET | 124 | 40.640 | 28.276 | 12.781 | 1.00 | 49.15 | A |
| ATOM | 1127 | CG | MET | 124 | 40.475 | 28.448 | 11.283 | 1.00 | 52.46 | A |
| ATOM | 1128 | SD | MET | 124 | 41.620 | 27.366 | 10.393 | 1.00 | 58.55 | A |
| ATOM | 1129 | CE | MET | 124 | 40.527 | 26.128 | 9.732 | 1.00 | 58.50 | A |
| ATOM | 1130 | C | MET | 124 | 39.547 | 28.470 | 14.975 | 1.00 | 46.91 | A |
| ATOM | 1131 | O | MET | 124 | 38.577 | 27.744 | 15.122 | 1.00 | 48.89 | A |
| ATOM | 1132 | N | ASP | 125 | 40.437 | 28.694 | 15.936 | 1.00 | 45.88 | A |
| ATOM | 1133 | H | ASP | 125 | 41.185 | 29.301 | 15.802 | 0.00 | 0.00 | A |
| ATOM | 1134 | CA | ASP | 125 | 40.335 | 28.040 | 17.232 | 1.00 | 46.00 | A |
| ATOM | 1135 | CB | ASP | 125 | 41.573 | 28.341 | 18.081 | 1.00 | 55.26 | A |
| ATOM | 1136 | CG | ASP | 125 | 41.897 | 27.223 | 19.086 | 1.00 | 62.69 | A |
| ATOM | 1137 | OD1 | ASP | 125 | 43.092 | 26.858 | 19.200 | 1.00 | 66.81 | A |
| ATOM | 1138 | OD2 | ASP | 125 | 40.980 | 26.700 | 19.771 | 1.00 | 67.20 | A |
| ATOM | 1139 | C | ASP | 125 | 39.066 | 28.425 | 17.983 | 1.00 | 42.67 | A |
| ATOM | 1140 | O | ASP | 125 | 38.779 | 27.895 | 19.041 | 1.00 | 40.92 | A |
| ATOM | 1141 | N | ASP | 126 | 38.296 | 29.346 | 17.440 | 1.00 | 41.20 | A |
| ATOM | 1142 | H | ASP | 126 | 38.536 | 29.812 | 16.635 | 0.00 | 0.00 | A |
| ATOM | 1143 | CA | ASP | 126 | 37.063 | 29.725 | 18.090 | 1.00 | 40.27 | A |
| ATOM | 1144 | CB | ASP | 126 | 37.004 | 31.229 | 18.281 | 1.00 | 43.61 | A |
| ATOM | 1145 | CG | ASP | 126 | 38.161 | 31.746 | 19.094 | 1.00 | 47.71 | A |
| ATOM | 1146 | OD1 | ASP | 126 | 38.666 | 32.845 | 18.767 | 1.00 | 52.25 | A |
| ATOM | 1147 | OD2 | ASP | 126 | 38.594 | 31.036 | 20.033 | 1.00 | 49.57 | A |
| ATOM | 1148 | C | ASP | 126 | 35.894 | 29.247 | 17.265 | 1.00 | 38.35 | A |
| ATOM | 1149 | O | ASP | 126 | 34.742 | 29.459 | 17.621 | 1.00 | 42.60 | A |
| ATOM | 1150 | N | VAL | 127 | 36.182 | 28.577 | 16.165 | 1.00 | 34.02 | A |
| ATOM | 1151 | H | VAL | 127 | 37.105 | 28.423 | 15.929 | 0.00 | 0.00 | A |
| ATOM | 1152 | CA | VAL | 127 | 35.136 | 28.069 | 15.312 | 1.00 | 32.29 | A |
| ATOM | 1153 | CB | VAL | 127 | 35.158 | 28.760 | 13.954 | 1.00 | 31.30 | A |
| ATOM | 1154 | CG1 | VAL | 127 | 34.239 | 28.051 | 12.991 | 1.00 | 31.01 | A |
| ATOM | 1155 | CG2 | VAL | 127 | 34.722 | 30.192 | 14.108 | 1.00 | 33.28 | A |
| ATOM | 1156 | C | VAL | 127 | 35.353 | 26.592 | 15.102 | 1.00 | 33.23 | A |
| ATOM | 1157 | O | VAL | 127 | 36.385 | 26.190 | 14.556 | 1.00 | 34.57 | A |
| ATOM | 1158 | N | ASN | 128 | 34.406 | 25.777 | 15.556 | 1.00 | 32.68 | A |
| ATOM | 1159 | H | ASN | 128 | 33.621 | 26.124 | 16.039 | 0.00 | 0.00 | A |
| ATOM | 1160 | CA | ASN | 128 | 34.504 | 24.329 | 15.370 | 1.00 | 32.63 | A |
| ATOM | 1161 | CB | ASN | 128 | 34.710 | 23.610 | 16.699 | 1.00 | 34.36 | A |
| ATOM | 1162 | CG | ASN | 128 | 34.891 | 22.120 | 16.519 | 1.00 | 35.95 | A |
| ATOM | 1163 | OD1 | ASN | 128 | 35.663 | 21.678 | 15.669 | 1.00 | 37.95 | A |
| ATOM | 1164 | ND2 | ASN | 128 | 34.165 | 21.336 | 17.300 | 1.00 | 36.62 | A |
| ATOM | 1165 | HD21 | ASN | 128 | 33.548 | 21.783 | 17.926 | 0.00 | 0.00 | A |
| ATOM | 1166 | HD22 | ASN | 128 | 34.268 | 20.365 | 17.213 | 0.00 | 0.00 | A |
| ATOM | 1167 | C | ASN | 128 | 33.264 | 23.771 | 14.678 | 1.00 | 30.10 | A |
| ATOM | 1168 | O | ASN | 128 | 32.140 | 24.114 | 15.038 | 1.00 | 33.07 | A |
| ATOM | 1169 | N | VAL | 129 | 33.467 | 22.947 | 13.661 | 1.00 | 25.50 | A |
| ATOM | 1170 | H | VAL | 129 | 34.372 | 22.654 | 13.423 | 0.00 | 0.00 | A |
| ATOM | 1171 | CA | VAL | 129 | 32.357 | 22.352 | 12.937 | 1.00 | 23.81 | A |
| ATOM | 1172 | CB | VAL | 129 | 32.326 | 22.841 | 11.501 | 1.00 | 21.59 | A |
| ATOM | 1173 | CG1 | VAL | 129 | 31.347 | 22.038 | 10.681 | 1.00 | 22.11 | A |
| ATOM | 1174 | CG2 | VAL | 129 | 31.942 | 24.278 | 11.476 | 1.00 | 22.98 | A |
| ATOM | 1175 | C | VAL | 129 | 32.643 | 20.866 | 12.967 | 1.00 | 25.99 | A |
| ATOM | 1176 | O | VAL | 129 | 33.803 | 20.481 | 13.080 | 1.00 | 30.68 | A |
| ATOM | 1177 | N | LYS | 130 | 31.605 | 20.036 | 12.939 | 1.00 | 25.04 | A |
| ATOM | 1178 | H | LYS | 130 | 30.695 | 20.407 | 12.893 | 0.00 | 0.00 | A |
| ATOM | 1179 | CA | LYS | 130 | 31.760 | 18.575 | 12.970 | 1.00 | 25.19 | A |
| ATOM | 1180 | CB | LYS | 130 | 31.748 | 18.045 | 14.412 | 1.00 | 23.24 | A |
| ATOM | 1181 | CG | LYS | 130 | 30.415 | 18.264 | 15.129 | 1.00 | 24.63 | A |
| ATOM | 1182 | CD | LYS | 130 | 30.367 | 17.568 | 16.484 | 1.00 | 26.28 | A |
| ATOM | 1183 | CE | LYS | 130 | 31.075 | 18.354 | 17.574 | 1.00 | 25.97 | A |
| ATOM | 1184 | NZ | LYS | 130 | 30.390 | 19.643 | 17.857 | 1.00 | 23.43 | A |
| ATOM | 1185 | HZ1 | LYS | 130 | 30.873 | 20.172 | 18.622 | 0.00 | 0.00 | A |
| ATOM | 1186 | HZ2 | LYS | 130 | 29.423 | 19.518 | 18.182 | 0.00 | 0.00 | A |
| ATOM | 1187 | HZ3 | LYS | 130 | 30.427 | 20.348 | 17.088 | 0.00 | 0.00 | A |
| ATOM | 1188 | C | LYS | 130 | 30.556 | 18.025 | 12.236 | 1.00 | 26.51 | A |
| ATOM | 1189 | O | LYS | 130 | 29.576 | 18.748 | 12.035 | 1.00 | 30.48 | A |
| ATOM | 1190 | N | ALA | 131 | 30.571 | 16.749 | 11.885 | 1.00 | 24.63 | A |
| ATOM | 1191 | H | ALA | 131 | 31.300 | 16.131 | 12.143 | 0.00 | 0.00 | A |
| ATOM | 1192 | CA | ALA | 131 | 29.429 | 16.222 | 11.166 | 1.00 | 24.18 | A |
| ATOM | 1193 | CB | ALA | 131 | 29.714 | 16.202 | 9.689 | 1.00 | 24.48 | A |
| ATOM | 1194 | C | ALA | 131 | 29.012 | 14.851 | 11.634 | 1.00 | 25.49 | A |
| ATOM | 1195 | O | ALA | 131 | 29.799 | 14.123 | 12.237 | 1.00 | 29.99 | A |
| ATOM | 1196 | N | THR | 132 | 27.766 | 14.500 | 11.349 | 1.00 | 23.95 | A |
| ATOM | 1197 | H | THR | 132 | 27.159 | 15.100 | 10.875 | 0.00 | 0.00 | A |
| ATOM | 1198 | CA | THR | 132 | 27.267 | 13.206 | 11.725 | 1.00 | 24.93 | A |
| ATOM | 1199 | CB | THR | 132 | 26.958 | 13.140 | 13.194 | 1.00 | 23.27 | A |
| ATOM | 1200 | OG1 | THR | 132 | 26.730 | 11.767 | 13.548 | 1.00 | 28.28 | A |
| ATOM | 1201 | HG1 | THR | 132 | 26.613 | 11.665 | 14.509 | 0.00 | 0.00 | A |
| ATOM | 1202 | CG2 | THR | 132 | 25.708 | 13.957 | 13.491 | 1.00 | 19.02 | A |
| ATOM | 1203 | C | THR | 132 | 26.000 | 12.858 | 10.981 | 1.00 | 26.68 | A |
| ATOM | 1204 | O | THR | 132 | 25.205 | 13.740 | 10.643 | 1.00 | 24.17 | A |
| ATOM | 1205 | N | THR | 133 | 25.805 | 11.558 | 10.771 | 1.00 | 28.97 | A |
| ATOM | 1206 | H | THR | 133 | 26.450 | 10.936 | 11.160 | 0.00 | 0.00 | A |
| ATOM | 1207 | CA | THR | 133 | 24.618 | 11.050 | 10.089 | 1.00 | 31.70 | A |
| ATOM | 1208 | CB | THR | 133 | 24.931 | 9.858 | 9.150 | 1.00 | 34.98 | A |
| ATOM | 1209 | OG1 | THR | 133 | 25.255 | 8.700 | 9.929 | 1.00 | 35.91 | A |
| ATOM | 1210 | HG1 | THR | 133 | 25.894 | 8.897 | 10.623 | 0.00 | 0.00 | A |
| ATOM | 1211 | CG2 | THR | 133 | 26.077 | 10.177 | 8.206 | 1.00 | 37.36 | A |
| ATOM | 1212 | C | THR | 133 | 23.707 | 10.503 | 11.159 | 1.00 | 29.57 | A |
| ATOM | 1213 | O | THR | 133 | 24.138 | 10.301 | 12.289 | 1.00 | 30.04 | A |
| ATOM | 1214 | N | THR | 134 | 22.475 | 10.193 | 10.782 | 1.00 | 29.56 | A |
| ATOM | 1215 | H | THR | 134 | 22.148 | 10.375 | 9.883 | 0.00 | 0.00 | A |
| ATOM | 1216 | CA | THR | 134 | 21.522 | 9.629 | 11.725 | 1.00 | 32.39 | A |
| ATOM | 1217 | CB | THR | 134 | 20.217 | 10.345 | 11.615 | 1.00 | 29.77 | A |
| ATOM | 1218 | OG1 | THR | 134 | 19.933 | 10.580 | 10.227 | 1.00 | 29.67 | A |
| ATOM | 1219 | HG1 | THR | 134 | 18.966 | 10.650 | 10.151 | 0.00 | 0.00 | A |
| ATOM | 1220 | CG2 | THR | 134 | 20.316 | 11.651 | 12.338 | 1.00 | 28.93 | A |
| ATOM | 1221 | C | THR | 134 | 21.314 | 8.132 | 11.487 | 1.00 | 35.34 | A |
| ATOM | 1222 | O | THR | 134 | 20.278 | 7.568 | 11.846 | 1.00 | 35.23 | A |
| ATOM | 1223 | N | GLU | 135 | 22.316 | 7.501 | 10.878 | 1.00 | 37.89 | A |
| ATOM | 1224 | H | GLU | 135 | 23.146 | 7.984 | 10.687 | 0.00 | 0.00 | A |
| ATOM | 1225 | CA | GLU | 135 | 22.301 | 6.075 | 10.565 | 1.00 | 38.90 | A |
| ATOM | 1226 | CB | GLU | 135 | 22.469 | 5.259 | 11.829 | 1.00 | 43.37 | A |
| ATOM | 1227 | CG | GLU | 135 | 23.687 | 5.681 | 12.603 | 1.00 | 53.29 | A |
| ATOM | 1228 | CD | GLU | 135 | 24.484 | 4.510 | 13.118 | 1.00 | 60.17 | A |
| ATOM | 1229 | OE1 | GLU | 135 | 23.871 | 3.550 | 13.675 | 1.00 | 63.99 | A |
| ATOM | 1230 | OE2 | GLU | 135 | 25.731 | 4.559 | 12.968 | 1.00 | 63.92 | A |
| ATOM | 1231 | C | GLU | 135 | 21.082 | 5.622 | 9.786 | 1.00 | 37.13 | A |
| ATOM | 1232 | O | GLU | 135 | 20.268 | 4.840 | 10.265 | 1.00 | 36.24 | A |
| ATOM | 1233 | N | LYS | 136 | 20.956 | 6.159 | 8.581 | 1.00 | 37.21 | A |
| ATOM | 1234 | H | LYS | 136 | 21.649 | 6.755 | 8.246 | 0.00 | 0.00 | A |
| ATOM | 1235 | CA | LYS | 136 | 19.851 | 5.840 | 7.701 | 1.00 | 38.19 | A |
| ATOM | 1236 | CB | LYS | 136 | 20.004 | 4.417 | 7.195 | 1.00 | 43.97 | A |
| ATOM | 1237 | CG | LYS | 136 | 21.117 | 4.246 | 6.170 | 1.00 | 50.84 | A |
| ATOM | 1238 | CD | LYS | 136 | 20.708 | 4.809 | 4.812 | 1.00 | 57.62 | A |
| ATOM | 1239 | CE | LYS | 136 | 21.616 | 4.287 | 3.690 | 1.00 | 64.46 | A |
| ATOM | 1240 | NZ | LYS | 136 | 21.179 | 4.747 | 2.325 | 1.00 | 68.05 | A |
| ATOM | 1241 | HZ1 | LYS | 136 | 21.828 | 4.373 | 1.606 | 0.00 | 0.00 | A |
| ATOM | 1242 | HZ2 | LYS | 136 | 21.209 | 5.788 | 2.325 | 0.00 | 0.00 | A |
| ATOM | 1243 | HZ3 | LYS | 136 | 20.204 | 4.434 | 2.146 | 0.00 | 0.00 | A |
| ATOM | 1244 | C | LYS | 136 | 18.455 | 6.066 | 8.287 | 1.00 | 36.34 | A |
| ATOM | 1245 | O | LYS | 136 | 17.459 | 5.902 | 7.590 | 1.00 | 36.76 | A |
| ATOM | 1246 | N | LEU | 137 | 18.389 | 6.471 | 9.549 | 1.00 | 34.04 | A |
| ATOM | 1247 | H | LEU | 137 | 19.168 | 6.626 | 10.108 | 0.00 | 0.00 | A |
| ATOM | 1248 | CA | LEU | 137 | 17.130 | 6.749 | 10.220 | 1.00 | 32.46 | A |
| ATOM | 1249 | CB | LEU | 137 | 17.298 | 6.536 | 11.725 | 1.00 | 29.77 | A |
| ATOM | 1250 | CG | LEU | 137 | 17.472 | 5.118 | 12.218 | 1.00 | 26.07 | A |
| ATOM | 1251 | CD1 | LEU | 137 | 17.837 | 5.087 | 13.671 | 1.00 | 25.48 | A |
| ATOM | 1252 | CD2 | LEU | 137 | 16.172 | 4.435 | 11.998 | 1.00 | 29.83 | A |
| ATOM | 1253 | C | LEU | 137 | 16.733 | 8.211 | 9.977 | 1.00 | 33.45 | A |
| ATOM | 1254 | O | LEU | 137 | 17.601 | 9.091 | 9.829 | 1.00 | 33.81 | A |
| ATOM | 1255 | N | GLY | 138 | 15.429 | 8.477 | 9.945 | 1.00 | 31.58 | A |
| ATOM | 1256 | H | GLY | 138 | 14.825 | 7.716 | 10.041 | 0.00 | 0.00 | A |
| ATOM | 1257 | CA | GLY | 138 | 14.959 | 9.848 | 9.760 | 1.00 | 32.69 | A |
| ATOM | 1258 | C | GLY | 138 | 15.041 | 10.489 | 8.379 | 1.00 | 32.55 | A |
| ATOM | 1259 | O | GLY | 138 | 15.660 | 9.947 | 7.470 | 1.00 | 34.54 | A |
| ATOM | 1260 | N | PHE | 139 | 14.427 | 11.661 | 8.217 | 1.00 | 30.47 | A |
| ATOM | 1261 | H | PHE | 139 | 14.001 | 12.101 | 8.980 | 0.00 | 0.00 | A |
| ATOM | 1262 | CA | PHE | 139 | 14.439 | 12.321 | 6.922 | 1.00 | 28.24 | A |
| ATOM | 1263 | CB | PHE | 139 | 13.625 | 13.611 | 6.937 | 1.00 | 29.92 | A |
| ATOM | 1264 | CG | PHE | 139 | 14.272 | 14.750 | 7.671 | 1.00 | 30.30 | A |
| ATOM | 1265 | CD1 | PHE | 139 | 15.145 | 15.610 | 7.015 | 1.00 | 32.38 | A |
| ATOM | 1266 | CD2 | PHE | 139 | 13.930 | 15.029 | 8.981 | 1.00 | 27.03 | A |
| ATOM | 1267 | CE1 | PHE | 139 | 15.657 | 16.738 | 7.660 | 1.00 | 32.69 | A |
| ATOM | 1268 | CE2 | PHE | 139 | 14.440 | 16.157 | 9.632 | 1.00 | 27.75 | A |
| ATOM | 1269 | CZ | PHE | 139 | 15.299 | 17.011 | 8.972 | 1.00 | 28.69 | A |
| ATOM | 1270 | C | PHE | 139 | 15.864 | 12.578 | 6.538 | 1.00 | 26.96 | A |
| ATOM | 1271 | O | PHE | 139 | 16.224 | 12.535 | 5.373 | 1.00 | 27.75 | A |
| ATOM | 1272 | N | THR | 140 | 16.686 | 12.843 | 7.533 | 1.00 | 26.50 | A |
| ATOM | 1273 | H | THR | 140 | 16.397 | 12.902 | 8.462 | 0.00 | 0.00 | A |
| ATOM | 1274 | CA | THR | 140 | 18.079 | 13.053 | 7.255 | 1.00 | 27.88 | A |
| ATOM | 1275 | CB | THR | 140 | 18.824 | 13.538 | 8.485 | 1.00 | 25.49 | A |
| ATOM | 1276 | OG1 | THR | 140 | 18.526 | 12.673 | 9.589 | 1.00 | 27.21 | A |
| ATOM | 1277 | HG1 | THR | 140 | 19.089 | 12.959 | 10.318 | 0.00 | 0.00 | A |
| ATOM | 1278 | CG2 | THR | 140 | 18.407 | 14.945 | 8.802 | 1.00 | 21.70 | A |
| ATOM | 1279 | C | THR | 140 | 18.636 | 11.709 | 6.790 | 1.00 | 29.66 | A |
| ATOM | 1280 | O | THR | 140 | 19.245 | 11.631 | 5.724 | 1.00 | 31.62 | A |
| ATOM | 1281 | N | GLY | 141 | 18.364 | 10.647 | 7.547 | 1.00 | 29.52 | A |
| ATOM | 1282 | H | GLY | 141 | 17.842 | 10.740 | 8.369 | 0.00 | 0.00 | A |
| ATOM | 1283 | CA | GLY | 141 | 18.859 | 9.325 | 7.183 | 1.00 | 29.39 | A |
| ATOM | 1284 | C | GLY | 141 | 18.306 | 8.789 | 5.875 | 1.00 | 29.19 | A |
| ATOM | 1285 | O | GLY | 141 | 18.944 | 8.005 | 5.169 | 1.00 | 29.87 | A |
| ATOM | 1286 | N | ARG | 142 | 17.122 | 9.250 | 5.526 | 1.00 | 28.91 | A |
| ATOM | 1287 | H | ARG | 142 | 16.716 | 9.949 | 6.050 | 0.00 | 0.00 | A |
| ATOM | 1288 | CA | ARG | 142 | 16.502 | 8.811 | 4.310 | 1.00 | 31.05 | A |
| ATOM | 1289 | CB | ARG | 142 | 14.991 | 8.924 | 4.409 | 1.00 | 32.49 | A |
| ATOM | 1290 | CG | ARG | 142 | 14.393 | 7.833 | 5.241 | 1.00 | 40.09 | A |
| ATOM | 1291 | CD | ARG | 142 | 12.953 | 7.628 | 4.872 | 1.00 | 45.98 | A |
| ATOM | 1292 | NE | ARG | 142 | 12.243 | 8.877 | 5.024 | 1.00 | 48.56 | A |
| ATOM | 1293 | HE | ARG | 142 | 11.952 | 9.317 | 4.186 | 0.00 | 0.00 | A |
| ATOM | 1294 | CZ | ARG | 142 | 12.001 | 9.435 | 6.197 | 1.00 | 51.06 | A |
| ATOM | 1295 | NH1 | ARG | 142 | 11.359 | 10.587 | 6.251 | 1.00 | 55.42 | A |
| ATOM | 1296 | HH11 | ARG | 142 | 11.104 | 11.030 | 5.363 | 0.00 | 0.00 | A |
| ATOM | 1297 | HH12 | ARG | 142 | 11.148 | 11.108 | 7.060 | 0.00 | 0.00 | A |
| ATOM | 1298 | NH2 | ARG | 142 | 12.385 | 8.828 | 7.313 | 1.00 | 53.05 | A |
| ATOM | 1299 | HH21 | ARG | 142 | 12.860 | 7.946 | 7.240 | 0.00 | 0.00 | A |
| ATOM | 1300 | HH22 | ARG | 142 | 12.222 | 9.209 | 8.214 | 0.00 | 0.00 | A |
| ATOM | 1301 | C | ARG | 142 | 17.010 | 9.627 | 3.157 | 1.00 | 31.23 | A |
| ATOM | 1302 | O | ARG | 142 | 16.739 | 9.319 | 2.008 | 1.00 | 35.42 | A |
| ATOM | 1303 | N | GLY | 143 | 17.731 | 10.689 | 3.456 | 1.00 | 31.07 | A |
| ATOM | 1304 | H | GLY | 143 | 17.921 | 10.928 | 4.385 | 0.00 | 0.00 | A |
| ATOM | 1305 | CA | GLY | 143 | 18.258 | 11.510 | 2.387 | 1.00 | 31.85 | A |
| ATOM | 1306 | C | GLY | 143 | 17.245 | 12.524 | 1.926 | 1.00 | 30.82 | A |
| ATOM | 1307 | O | GLY | 143 | 17.383 | 13.108 | 0.843 | 1.00 | 32.95 | A |
| ATOM | 1308 | N | GLU | 144 | 16.235 | 12.742 | 2.755 | 1.00 | 29.61 | A |
| ATOM | 1309 | H | GLU | 144 | 16.167 | 12.216 | 3.569 | 0.00 | 0.00 | A |
| ATOM | 1310 | CA | GLU | 144 | 15.197 | 13.699 | 2.447 | 1.00 | 30.32 | A |
| ATOM | 1311 | CB | GLU | 144 | 13.966 | 13.440 | 3.296 | 1.00 | 30.40 | A |
| ATOM | 1312 | CG | GLU | 144 | 13.501 | 12.007 | 3.201 | 1.00 | 37.30 | A |
| ATOM | 1313 | CD | GLU | 144 | 12.065 | 11.812 | 3.617 | 1.00 | 42.14 | A |
| ATOM | 1314 | OE1 | GLU | 144 | 11.448 | 10.832 | 3.141 | 1.00 | 43.64 | A |
| ATOM | 1315 | OE2 | GLU | 144 | 11.554 | 12.606 | 4.447 | 1.00 | 47.15 | A |
| ATOM | 1316 | C | GLU | 144 | 15.688 | 15.116 | 2.641 | 1.00 | 31.47 | A |
| ATOM | 1317 | O | GLU | 144 | 15.199 | 16.019 | 1.966 | 1.00 | 34.37 | A |
| ATOM | 1318 | N | GLY | 145 | 16.668 | 15.315 | 3.523 | 1.00 | 30.95 | A |
| ATOM | 1319 | H | GLY | 145 | 17.047 | 14.570 | 4.037 | 0.00 | 0.00 | A |
| ATOM | 1320 | CA | GLY | 145 | 17.190 | 16.655 | 3.756 | 1.00 | 31.38 | A |
| ATOM | 1321 | C | GLY | 145 | 18.351 | 16.689 | 4.732 | 1.00 | 32.95 | A |
| ATOM | 1322 | O | GLY | 145 | 18.794 | 15.629 | 5.177 | 1.00 | 36.40 | A |
| ATOM | 1323 | N | ILE | 146 | 18.869 | 17.883 | 5.037 | 1.00 | 31.22 | A |
| ATOM | 1324 | H | ILE | 146 | 18.475 | 18.692 | 4.642 | 0.00 | 0.00 | A |
| ATOM | 1325 | CA | ILE | 146 | 19.985 | 18.033 | 5.978 | 1.00 | 29.95 | A |
| ATOM | 1326 | CB | ILE | 146 | 21.189 | 18.819 | 5.403 | 1.00 | 28.34 | A |
| ATOM | 1327 | CG2 | ILE | 146 | 22.278 | 18.899 | 6.427 | 1.00 | 29.68 | A |
| ATOM | 1328 | CG1 | ILE | 146 | 21.822 | 18.129 | 4.214 | 1.00 | 28.92 | A |
| ATOM | 1329 | CD1 | ILE | 146 | 23.089 | 18.839 | 3.773 | 1.00 | 29.05 | A |
| ATOM | 1330 | C | ILE | 146 | 19.493 | 18.888 | 7.123 | 1.00 | 30.40 | A |
| ATOM | 1331 | O | ILE | 146 | 18.724 | 19.826 | 6.907 | 1.00 | 35.89 | A |
| ATOM | 1332 | N | ALA | 147 | 19.970 | 18.595 | 8.325 | 1.00 | 27.69 | A |
| ATOM | 1333 | H | ALA | 147 | 20.623 | 17.869 | 8.434 | 0.00 | 0.00 | A |
| ATOM | 1334 | CA | ALA | 147 | 19.612 | 19.347 | 9.518 | 1.00 | 24.71 | A |
| ATOM | 1335 | CB | ALA | 147 | 18.932 | 18.441 | 10.526 | 1.00 | 23.96 | A |
| ATOM | 1336 | C | ALA | 147 | 20.937 | 19.808 | 10.065 | 1.00 | 23.88 | A |
| ATOM | 1337 | O | ALA | 147 | 21.981 | 19.293 | 9.666 | 1.00 | 26.33 | A |
| ATOM | 1338 | N | CYS | 148 | 20.924 | 20.771 | 10.969 | 1.00 | 22.21 | A |
| ATOM | 1339 | H | CYS | 148 | 20.084 | 21.200 | 11.241 | 0.00 | 0.00 | A |
| ATOM | 1340 | CA | CYS | 148 | 22.169 | 21.236 | 11.549 | 1.00 | 22.25 | A |
| ATOM | 1341 | CB | CYS | 148 | 22.931 | 22.130 | 10.590 | 1.00 | 24.28 | A |
| ATOM | 1342 | SG | CYS | 148 | 24.396 | 22.835 | 11.338 | 1.00 | 32.06 | A |
| ATOM | 1343 | C | CYS | 148 | 21.893 | 22.008 | 12.787 | 1.00 | 21.20 | A |
| ATOM | 1344 | O | CYS | 148 | 20.986 | 22.834 | 12.810 | 1.00 | 24.56 | A |
| ATOM | 1345 | N | GLU | 149 | 22.649 | 21.713 | 13.830 | 1.00 | 20.27 | A |
| ATOM | 1346 | H | GLU | 149 | 23.365 | 21.051 | 13.746 | 0.00 | 0.00 | A |
| ATOM | 1347 | CA | GLU | 149 | 22.502 | 22.394 | 15.102 | 1.00 | 20.76 | A |
| ATOM | 1348 | CB | GLU | 149 | 22.368 | 21.404 | 16.240 | 1.00 | 18.39 | A |
| ATOM | 1349 | CG | GLU | 149 | 21.017 | 20.824 | 16.426 | 1.00 | 21.97 | A |
| ATOM | 1350 | CD | GLU | 149 | 20.883 | 20.257 | 17.816 | 1.00 | 26.71 | A |
| ATOM | 1351 | OE1 | GLU | 149 | 20.787 | 21.054 | 18.769 | 1.00 | 23.86 | A |
| ATOM | 1352 | OE2 | GLU | 149 | 20.965 | 19.023 | 17.966 | 1.00 | 30.52 | A |
| ATOM | 1353 | C | GLU | 149 | 23.778 | 23.157 | 15.321 | 1.00 | 21.72 | A |
| ATOM | 1354 | O | GLU | 149 | 24.803 | 22.848 | 14.693 | 1.00 | 22.13 | A |
| ATOM | 1355 | N | ALA | 150 | 23.735 | 24.112 | 16.246 | 1.00 | 21.15 | A |
| ATOM | 1356 | H | ALA | 150 | 22.894 | 24.290 | 16.720 | 0.00 | 0.00 | A |
| ATOM | 1357 | CA | ALA | 150 | 24.912 | 24.909 | 16.576 | 1.00 | 21.48 | A |
| ATOM | 1358 | CB | ALA | 150 | 25.160 | 25.945 | 15.509 | 1.00 | 19.12 | A |
| ATOM | 1359 | C | ALA | 150 | 24.722 | 25.592 | 17.914 | 1.00 | 23.40 | A |
| ATOM | 1360 | O | ALA | 150 | 23.590 | 25.917 | 18.298 | 1.00 | 25.67 | A |
| ATOM | 1361 | N | VAL | 151 | 25.807 | 25.747 | 18.657 | 1.00 | 21.38 | A |
| ATOM | 1362 | H | VAL | 151 | 26.684 | 25.455 | 18.345 | 0.00 | 0.00 | A |
| ATOM | 1363 | CA | VAL | 151 | 25.721 | 26.432 | 19.927 | 1.00 | 22.10 | A |
| ATOM | 1364 | CB | VAL | 151 | 25.968 | 25.521 | 21.092 | 1.00 | 19.42 | A |
| ATOM | 1365 | CG1 | VAL | 151 | 24.845 | 24.528 | 21.192 | 1.00 | 18.73 | A |
| ATOM | 1366 | CG2 | VAL | 151 | 27.287 | 24.841 | 20.929 | 1.00 | 19.26 | A |
| ATOM | 1367 | C | VAL | 151 | 26.799 | 27.460 | 19.861 | 1.00 | 24.84 | A |
| ATOM | 1368 | O | VAL | 151 | 27.735 | 27.310 | 19.075 | 1.00 | 25.21 | A |
| ATOM | 1369 | N | ALA | 152 | 26.677 | 28.494 | 20.685 | 1.00 | 27.99 | A |
| ATOM | 1370 | H | ALA | 152 | 25.913 | 28.538 | 21.302 | 0.00 | 0.00 | A |
| ATOM | 1371 | CA | ALA | 152 | 27.641 | 29.588 | 20.704 | 1.00 | 29.75 | A |
| ATOM | 1372 | CB | ALA | 152 | 27.276 | 30.612 | 19.653 | 1.00 | 30.42 | A |
| ATOM | 1373 | C | ALA | 152 | 27.745 | 30.273 | 22.059 | 1.00 | 31.98 | A |
| ATOM | 1374 | O | ALA | 152 | 26.775 | 30.348 | 22.827 | 1.00 | 34.03 | A |
| ATOM | 1375 | N | LEU | 153 | 28.915 | 30.836 | 22.314 | 1.00 | 31.23 | A |
| ATOM | 1376 | H | LEU | 153 | 29.615 | 30.813 | 21.635 | 0.00 | 0.00 | A |
| ATOM | 1377 | CA | LEU | 153 | 29.165 | 31.514 | 23.558 | 1.00 | 30.39 | A |
| ATOM | 1378 | CB | LEU | 153 | 30.259 | 30.770 | 24.297 | 1.00 | 32.28 | A |
| ATOM | 1379 | CG | LEU | 153 | 30.229 | 30.871 | 25.816 | 1.00 | 37.59 | A |
| ATOM | 1380 | CD1 | LEU | 153 | 31.222 | 29.890 | 26.445 | 1.00 | 39.50 | A |
| ATOM | 1381 | CD2 | LEU | 153 | 30.561 | 32.289 | 26.215 | 1.00 | 41.56 | A |
| ATOM | 1382 | C | LEU | 153 | 29.624 | 32.912 | 23.206 | 1.00 | 30.50 | A |
| ATOM | 1383 | O | LEU | 153 | 30.523 | 33.064 | 22.390 | 1.00 | 32.26 | A |
| ATOM | 1384 | N | LEU | 154 | 28.965 | 33.925 | 23.761 | 1.00 | 30.97 | A |
| ATOM | 1385 | H | LEU | 154 | 28.232 | 33.725 | 24.371 | 0.00 | 0.00 | A |
| ATOM | 1386 | CA | LEU | 154 | 29.325 | 35.325 | 23.520 | 1.00 | 31.10 | A |
| ATOM | 1387 | CB | LEU | 154 | 28.121 | 36.152 | 23.080 | 1.00 | 26.44 | A |
| ATOM | 1388 | CG | LEU | 154 | 27.448 | 35.907 | 21.745 | 1.00 | 21.46 | A |
| ATOM | 1389 | CD1 | LEU | 154 | 26.310 | 36.915 | 21.578 | 1.00 | 17.33 | A |
| ATOM | 1390 | CD2 | LEU | 154 | 28.481 | 36.035 | 20.651 | 1.00 | 20.27 | A |
| ATOM | 1391 | C | LEU | 154 | 29.834 | 35.912 | 24.825 | 1.00 | 34.52 | A |
| ATOM | 1392 | O | LEU | 154 | 29.581 | 35.364 | 25.906 | 1.00 | 34.84 | A |
| ATOM | 1393 | N | ILE | 155 | 30.485 | 37.068 | 24.735 | 1.00 | 37.91 | A |
| ATOM | 1394 | H | ILE | 155 | 30.625 | 37.486 | 23.863 | 0.00 | 0.00 | A |
| ATOM | 1395 | CA | ILE | 155 | 31.032 | 37.719 | 25.914 | 1.00 | 39.90 | A |
| ATOM | 1396 | CB | ILE | 155 | 32.544 | 37.672 | 25.886 | 1.00 | 39.83 | A |
| ATOM | 1397 | CG2 | ILE | 155 | 33.082 | 38.193 | 27.171 | 1.00 | 42.99 | A |
| ATOM | 1398 | CG1 | ILE | 155 | 33.019 | 36.239 | 25.726 | 1.00 | 40.34 | A |
| ATOM | 1399 | CD1 | ILE | 155 | 34.496 | 36.134 | 25.604 | 1.00 | 43.31 | A |
| ATOM | 1400 | C | ILE | 155 | 30.601 | 39.175 | 26.013 | 1.00 | 42.74 | A |
| ATOM | 1401 | O | ILE | 155 | 30.715 | 39.923 | 25.044 | 1.00 | 47.71 | A |
| ATOM | 1402 | C1 | SUB | 669 | 15.340 | 31.891 | 7.391 | 1.00 | 74.93 | A |
| ATOM | 1403 | N1 | SUB | 669 | 8.304 | 30.677 | 12.872 | 1.00 | 38.48 | A |
| ATOM | 1404 | C3 | SUB | 669 | 7.128 | 30.659 | 13.518 | 1.00 | 39.06 | A |
| ATOM | 1405 | N3 | SUB | 669 | 6.539 | 29.463 | 13.742 | 1.00 | 37.65 | A |
| ATOM | 1406 | C4 | SUB | 669 | 7.089 | 28.308 | 13.346 | 1.00 | 35.64 | A |
| ATOM | 1407 | C5 | SUB | 669 | 8.373 | 28.334 | 12.649 | 1.00 | 35.87 | A |
| ATOM | 1408 | C6 | SUB | 669 | 8.915 | 29.536 | 12.448 | 1.00 | 36.88 | A |
| ATOM | 1409 | O8 | SUB | 669 | 6.588 | 31.683 | 13.897 | 1.00 | 41.17 | A |
| ATOM | 1410 | N4 | SUB | 669 | 6.443 | 27.184 | 13.602 | 1.00 | 35.03 | A |
| ATOM | 1411 | C1′ | SUB | 669 | 8.973 | 31.938 | 12.581 | 1.00 | 41.48 | A |
| ATOM | 1412 | C2′ | SUB | 669 | 10.391 | 32.059 | 13.119 | 1.00 | 45.38 | A |
| ATOM | 1413 | O2′ | SUB | 669 | 10.443 | 33.210 | 13.960 | 1.00 | 50.90 | A |
| ATOM | 1414 | C3′ | SUB | 669 | 11.289 | 32.225 | 11.915 | 1.00 | 46.79 | A |
| ATOM | 1415 | C4′ | SUB | 669 | 10.327 | 32.395 | 10.726 | 1.00 | 47.46 | A |
| ATOM | 1416 | O4′ | SUB | 669 | 9.031 | 32.027 | 11.175 | 1.00 | 42.46 | A |
| ATOM | 1417 | O3′ | SUB | 669 | 12.094 | 33.392 | 12.014 | 1.00 | 50.66 | A |
| ATOM | 1418 | C5′ | SUB | 669 | 10.776 | 31.528 | 9.522 | 1.00 | 54.42 | A |
| ATOM | 1419 | O5′ | SUB | 669 | 11.261 | 30.192 | 9.833 | 1.00 | 64.66 | A |
| ATOM | 1420 | PA | SUB | 669 | 11.798 | 29.171 | 8.682 | 1.00 | 72.84 | A |
| ATOM | 1421 | O1A | SUB | 669 | 10.953 | 27.812 | 8.619 | 1.00 | 72.89 | A |
| ATOM | 1422 | O2A | SUB | 669 | 11.692 | 29.875 | 7.234 | 1.00 | 74.36 | A |
| ATOM | 1423 | O3A | SUB | 669 | 13.350 | 28.818 | 8.921 | 1.00 | 76.33 | A |
| ATOM | 1424 | PB | SUB | 669 | 14.302 | 30.124 | 9.081 | 1.00 | 79.15 | A |
| ATOM | 1425 | O1B | SUB | 669 | 13.878 | 30.945 | 10.405 | 1.00 | 77.17 | A |
| ATOM | 1426 | O2B | SUB | 669 | 14.213 | 31.139 | 7.845 | 1.00 | 75.99 | A |
| ATOM | 1427 | O3B | SUB | 669 | 15.818 | 29.616 | 9.281 | 1.00 | 79.82 | A |
| ATOM | 1428 | C27 | SUB | 669 | 14.904 | 32.785 | 6.218 | 1.00 | 72.53 | A |
| ATOM | 1429 | C28 | SUB | 669 | 16.044 | 33.087 | 5.203 | 1.00 | 72.40 | A |
| ATOM | 1430 | C29 | SUB | 669 | 15.466 | 34.005 | 4.075 | 1.00 | 70.17 | A |
| ATOM | 1431 | O30 | SUB | 669 | 16.494 | 34.337 | 3.123 | 1.00 | 69.39 | A |
| ATOM | 1432 | O31 | SUB | 669 | 16.556 | 31.819 | 4.642 | 1.00 | 71.20 | A |
| ATOM | 1433 | C32 | SUB | 669 | 17.260 | 33.799 | 5.852 | 1.00 | 69.44 | A |
| ATOM | 1434 | O33 | SUB | 669 | 14.421 | 34.031 | 6.748 | 1.00 | 74.76 | A |
| ATOM | 1435 | P34 | SUB | 669 | 15.861 | 30.548 | 3.847 | 1.00 | 70.95 | A |
| ATOM | 1436 | O35 | SUB | 669 | 15.223 | 30.977 | 2.582 | 1.00 | 69.40 | A |
| ATOM | 1437 | O36 | SUB | 669 | 16.923 | 29.547 | 3.505 | 1.00 | 69.83 | A |
| ATOM | 1438 | O37 | SUB | 669 | 14.831 | 29.854 | 4.713 | 1.00 | 69.79 | A |
| END | | | | | | | | | | |

1. A crystal which comprises the protein 2C-methyl-D-erythritol 2,4-cyclodiphosphate synthase with or without zinc.

2. The crystal according to claim 1, characterized by the cubic space group I 2(1)3 and a unit cell with a=144.5±2 Å.

3. The crystal according to claim 1, which effectively diffracts x-rays for the determination of the atomic coordinates of the protein to a resolution better than 5 Å.

4. The crystal according to claim 1, which effectively diffracts x-rays for the determination of the atomic coordinates of the protein to a resolution better than 3.5 Å.

5. The crystal according to claim 1, comprising an organic compound selected from the group consisting of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate and a combination of cytidine monophosphate and 2C-methyl-D-erythritol 2,4-cyclodiphosphate.

6. A method of growing a crystal comprising the protein 2C-methyl-D-erythritol 2,4-cyclodiphosphate synthase and zinc by vapor diffusion using a reservoir solution containing 0.1 M HEPES pH 7.5 and 2 M ammonium formate.

7. Use of a crystal according to claim 1 for the determination of the three dimensional structure of the protein 2C-methyl-D-erythritol 2,4-cyclodiphosphate synthase or the three-dimensional structure of said synthase in complex with a compound selected from the group of 4-diphosphocytidyl-2C-methyl-D-erythritol, 4 diphosphocytidyl-2C-methyl-D-erythritol 2-phosphate, cytidine, cytidine monophosphate, cytidine diphosphate, 2C-methyl-D-erythritol 2,4-cyclodiphosphate and a combination of cytidine monophosphate and 2C-methyl-D-erythritol 2,4-cyclodiphosphate; with or without zinc.

8. A data storage device having stored thereon atomic coordinates of the three-dimensional structure of the protein 2C-methyl-D-erythritol 2,4-cyclodiphosphate synthase or of the three-dimensional structure of said protein in complex with a compound selected from the group of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C methyl-D-erythritol 2,4-cyclodiphosphate or a combination of cytidine monophosphate and 2C-methyl-D-erythritol 2,4-cyclodiphosphate; with or without zinc.

9. A method of using 2C-methyl-D-erythritol 2,4-cyclodiphosphate synthase and atomic coordinates of the three-dimensional structure of said synthase or of a complex of said synthase with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidinediphosphate, 2C-methyl-D-erythritol 2,4-cyclodiphosphate or a combination of cytidine monophosphate and 2C-methyl-D-erythritol 2,4-cyclodiphosphate, with or without zinc, derived from a crystal structure determination in an inhibitor-screening assay, comprising:
(a) selecting a potential inhibitor by performing rational drug design using said atomic coordinates in conjunction with computer modeling;
(b) contacting the potential inhibitor with said synthase with or without zinc; and
(c) detecting binding of the potential inhibitor to said synthase or detecting inhibition of enzymatic activity of said synthase by the potential inhibitor.

10. The method according to claim 9, wherein binding is detected by soaking the crystal with the potential inhibitor or by growing the crystal in the presence of the potential inhibitor and determining the three-dimensional structure of the complex comprising the synthase and the potential inhibitor with or without zinc.

11. A method of identifying a potential inhibitor of 2C-methyl-D-erythritol 2,4-cyclodiphosphate synthase by determining binding interactions between the potential inhibitor and a set of binding interaction sites in a binding cavity of said synthase complexed with a compound selected from the group consisting of 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D erythritol 2,4-cyclodiphosphate, with or without zinc, comprising.
(a) generating the binding cavity on a computer screen;
(b) generating potential inhibitors with their spatial structure on the computer screen; and
(c) selecting potential inhibitors that can bind to at least 3 amino acid residues without steric interference.

12. A computer-assisted method for identifying potential inhibitors of the protein 2C-methyl-D-erythritol 2,4-cyclodiphosphate synthase using a programmed computer comprising a processor, a data storage system, a data input device, and a data output device, comprising the following steps:
(a) inputting into the programmed computer through said input device data comprising: atomic coordinates of a subset of the atoms of a complex of said protein with a compound selected from the following group:4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol 2,4-cyclodiphosphate or a combination of cytidine monophosphate and 2C-methyl-D-erythritol 2,4-cyclodiphosphate, with or without zinc, thereby generating a criteria data set;
(b) comparing, using said processor, the criteria data set to a computer data base of low-molecular weight organic chemical structures stored in the data storage system; and
(c) selecting from said data base, using computer methods, a chemical structure having a portion that is structurally complementary to the criteria data set pertaining to the protein and/or structurally similar to the criteria data set pertaining to a compound of said group and being free of steric interference with the protein.

13. A computer-assisted method for identifying potential inhibitors of the protein 2C-methyl-D-erythritol 2,4-cyclodiphosphate synthase using a programmed computer comprising a processor, a data storage system, a data input device, and a data output device, comprising the following steps:
(a) inputting into the programmed computer through said input device data comprising:
atomic coordinates of a subset of the atoms of a complex of said protein with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidine diphosphate,2C-methyl-D-erythritol-2,4-cyclodiphosphate or a combination of cytidine monophosphate and 2C-methyl-D erythritol 2,4-cyclodiphosphate with or without zinc, thereby generating a criteria data set; and
(b) constructing, using computer methods, a model of a chemical structure having a portion that is structurally complementary to the criteria data set pertaining to the protein and/or structurally similar to the criteria data set pertaining to a compound of said group and being free of steric interference with the protein.

14. A method of identifying a candidate inhibitor capable of binding to and inhibiting the enzymatic activity of 2C-methyl-D-erythritol 2,4-cyclodiphosphate synthase, said method comprising the following steps:
(a) introducing into a computer information derived from atomic coordinates defining a conformation of the active site of said synthase or a complex of said synthase with a compound selected from the following group: 4-diphosphocytidyl-2C-methyl-D-erythritol, 4-diphosphocytidyl-2C-methyl-D-erythritol 2-phosphate, cytidine, cytidine monophosphate, cytidine diphosphate, 2C-methyl-D-erythritol or a combination of cytidine monophosphate and 2C-methyl-D-erythritol 2,4-cyclodiphosphate; with or without zinc, based on three-dimensional structure determination, whereby said program utilizes or displays on the computer screen the structures of said conformation;
(b) generating a three-dimensional representation of at least one of the three pockets of the active site of said synthase and/or a compound of said group by said computer program on a computer screen;
(c) superimposing a model of a candidate inhibitor on the representation of at least one pocket of the active site and/or a compound of said group;
(d) assessing the possibility of bonding and the absence of steric interference of the candidate inhibitor with the active site of the protein; and
(e) incorporating said candidate compound in an activity assay of said synthase; and
determining whether said candidate compound inhibits enzymatic activity of said synthase.

15. The method according to claim 14, wherein information is introduced into the computer derived from atomic coordinates of at least some of the following interactions of the active site:
Ala131#; contacting the face of the cytidyl moiety;
Ala131#; bonding with its carbonyl oxygen to at least one of the 2′-and 3′-hydroxyl groups of the cytidyl moiety;
Asp56 making a hydrogen bond with its carboxyl group to at least one of the 2′-and 3′ hydroxyl groups of the cytidyl moiety;
Gly58 making van der Waals contact with its Cα to at least one of the 2′-and 3′ hydroxyl groups of the cytidyl moiety;
peptide group between Lys104#; andMet105#; hydrogen bonding to N3 of the cytidyl moiety;
Thr133#; supporting the cytidyl moiety and hydrogen bonding with its γ-O or its backbone NH to the α-phosphate;
Lys104#; contacting with its side chain the cytidyl moiety;
Leu106#; contacting with its side chain the cytidyl moiety;
Leu106#; hydrogen bonding with its NH to the carbonyl oxygen of the cytidyl moiety;
Asp63 binding to the β-phosphate of cytidine diphosphate;
His34 hydrogen bonding with its backbone NH group to at least one oxygen atom of the P2 phosphate group of 2C-methyl-D-erythritol 2,4-cyclodiphosphate;
Ser35 hydrogen bonding with its backbone NH group to one oxygen atom of the P2 phosphate group;
Ser35 hydrogen bonding with its γ-OH to one of the oxygen atoms of the P2 phosphate group;
Leu76 making a van der Waals contact with its δ-C to the 2C-methyl group;
Ile57 making a van der Waals contact with δ-C to the 2-methyl group;
lle57 making a van der Waals contact with γ-C to the 2-methyl group;
Phe61 hydrogen bonding with its backbone carbonyl oxygen to the 1-hydroxyl group;
Phe61 hydrogen bonding with its backbone carbonyl oxygen to the 3-hydroxyl group;
Ile57 hydrogen bonding with its backbone carbonyl oxygen to the 3-hydroxyl group;
Ile57 making van der Waals contact with its γ-C to the carbon at the 4-position;
Pro103#; hydrogen bonding with its backbone carbonyl oxygen to the amino group of the cytidyl moiety;
Ala100#; hydrogen bonding with its backbone carbonyl oxygen to the amino group of the cytidyl moiety; and
Ala100#; supporting with its backbone carbonyl oxygen the C5 position of the cytidyl moiety,
wherein amino acids not denoted by #; belonging to one subunit and those denoted by #; belonging to another subunit.

16. The method according to claim 9, wherein the atomic coordinates are determined to a resolution of at least 4 Å.

17. The method according to claim 9, wherein compounds are selected that can bind to at least 5 binding sites of the synthase.

18. A compound having a chemical structure obtained or obtainable by the method of claim 9, said compound being an inhibitor of 2C-methyl-D-erythritol 2,4-cyclodiphosphate synthase.

19. The method according to claim 11, wherein the atomic coordinates are determined to a resolution of at least 4 Å.

20. The method according to claim 11, wherein compounds are selected that can bind to at least 5 binding sites of the synthase.

21. A compound having a chemical structure obtained or obtainable by the method of claim 11, said compound being an inhibitor of 2C-methyl-D-erythritol 2,4-cyclodiphosphate synthase.

22. The method according to claim 12, wherein the atomic coordinates are determined to a resolution of at least 4 Å.

23. The method according to claim 12, wherein compounds are selected that can bind to at least 5 binding sites of the synthase.

24. A compound having a chemical structure obtained or obtainable by the method of claim 12, said compound being an inhibitor of 2C-methyl-D-erythritol 2,4-cyclodiphosphate synthase.

25. The method according to claim 13, wherein the atomic coordinates are determined to a resolution of at least 4 Å.

26. The method according to claim 13, wherein compounds are selected that can bind to at least 5 binding sites of the synthase.

27. A compound having a chemical structure obtained or obtainable by the method of claim 13, said compound being an inhibitor of 2C-methyl-D-erythritol 2,4-cyclodiphosphate synthase.

28. The method according to claim 14, wherein the atomic coordinates are determined to a resolution of at least 4 Å.

29. The method according to claim 14, wherein compounds are selected that can bind to at least 5 binding sites of the synthase.

30. A compound having a chemical structure obtained or obtainable by the method of claim 14, said compound being an inhibitor of 2C-methyl-D-erythritol 2,4-cyclodiphosphate synthase.
